(19) United States
(12) Patent Application Publication
(10) Pub. No.: US 2025/0275474 A1
(43) Pub. Date: Aug. 28, 2025

(54) LIGHT EMITTING ELEMENT, FUSED POLYCYCLIC COMPOUND FOR THE LIGHT EMITTING ELEMENT, AND DISPLAY DEVICE INCLUDING THE LIGHT EMITTING ELEMENT

(71) Applicant: Samsung Display Co., Ltd., Yongin-si (KR)

(72) Inventors: Seonhyoung HUR, Yongin-si (KR); TAEIL KIM, Yongin-si (KR); SUN YOUNG PAK, Yongin-si (KR); MinJae SUNG, Yongin-si (KR); HYUN SHIN, Yongin-si (KR); MUN-KI SIM, Yongin-si (KR); MINJUNG JUNG, Yongin-si (KR)

(73) Assignee: Samsung Display Co., Ltd., Yongin-si (KR)

(21) Appl. No.: 18/978,315

(22) Filed: Dec. 12, 2024

(30) Foreign Application Priority Data
Feb. 28, 2024 (KR) 10-2024-0029240

(51) Int. Cl. H10K 85/60; C07F 5/02; C09K 11/02; C09K 11/06; H10K 50/12; H10K 59/35; H10K 85/30; H10K 85/40

(52) U.S. Cl. CPC H10K 85/658; C07F 5/027; C09K 11/02; C09K 11/06; H10K 85/346; H10K 85/40; H10K 85/654; H10K 85/6572; H10K 85/6574; C09K 2211/1007; C09K 2211/1014; C09K 2211/1022; C09K 2211/1029; C09K 2211/1044; C09K 2211/185; H10K 50/12; H10K 59/35

(57) ABSTRACT

Embodiments provide a fused polycyclic compound, a light emitting element that includes the fused polycyclic compound, and a display device that includes the light emitting element. The light emitting element includes a first electrode, a second electrode disposed on the first electrode, and an emission layer disposed between the first electrode and the second electrode, wherein the emission layer includes the fused polycyclic compound. The fused polycyclic compound is represented by Formula 1, which is explained in the specification.

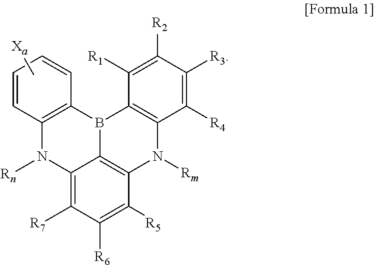

### CROSS-REFERENCE TO RELATED APPLICATION(S)

This application claims priority to and benefits of Korean Patent Application No. 10-2024-0029240 under 35 U.S.C. § 119, filed on Feb. 28, 2024, in the Korean Intellectual Property Office, the entire contents of which are incorporated herein by reference.

### BACKGROUND

### 1. Technical Field

The disclosure relates to a light emitting element, a fused polycyclic compound used in the light emitting element, and a display device including the light emitting element.

### 2. Description of the Related Art

Recently, the development of an organic electroluminescence display device as an image display device is being actively conducted. The organic electroluminescence display device includes so-called a self-luminescent light emitting element in which holes and electrons respectively injected from a first electrode and a second electrode recombine in an emission layer, and thus a luminescent material of the emission layer emits light to implement display.

In the application of a light emitting element to a display device, there is a demand for a light emitting element having improved light efficiency and improved service life, and development on materials for a light emitting element capable of stably attaining such characteristics is continuously required.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having improved light efficiency and service life and a display device including the light emitting element.

The disclosure also provides a fused polycyclic compound which is a material for a light emitting element to improve light efficiency and service life.

According to an embodiment, a light emitting element may include: a first electrode; a second electrode disposed on the first electrode; and an emission layer disposed between the first electrode and the second electrode, wherein the emission layer may include a first compound represented by Formula 1:

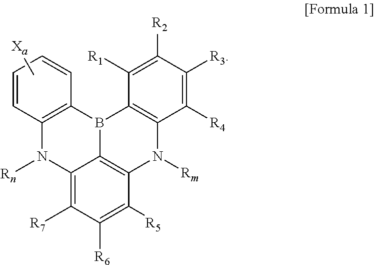

In Formula 1, R₁ to R₇ may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; Xₐ may be a group represented by Formula 2; and Rₙ and Rₘ may each independently be a group represented by Formula 3.

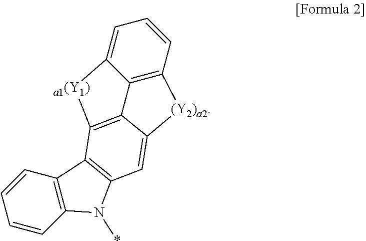

In Formula 2, one of a1 and a2 may be 1, the other of a1 and a2 may be 0; Y₁ and Y₂ may each independently be C(Rₐ)(R_{b}); and Ra and R_{b} may each independently be a substituted or unsubstituted aryl group having 6 to 20 ring-forming carbon atoms, or bonded to each other to form a ring.

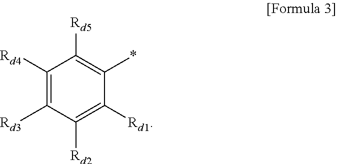

In Formula 3, R_{d1} to R₄₅ may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer may further include at least one of a second compound represented by Formula HT-1, a third compound represented by Formula ET-1, and a fourth compound represented by Formula D-1:

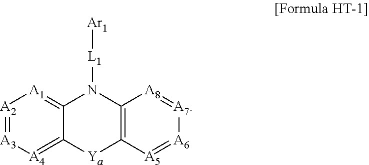

In Formula HT-1, A₁ to A₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₅₂)(R₅₃), or Si(R₅₄)(R₅₅); Ar₁ may be a substituted or unsubstituted aryl group having 6 to 30 ring-forming carbon atoms or a substituted or unsubstituted heteroaryl group having 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring.

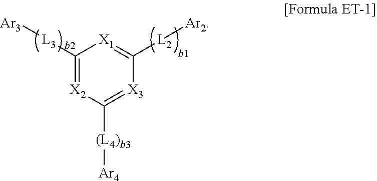

In Formula ET-1, at least one of X₁ to X₃ may each be N; the remainder of X₁ to X₃ may each independently be C(R₅₆); R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

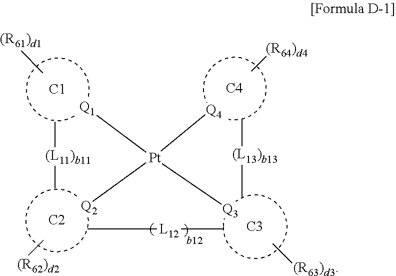

In Formula D-1, Q₁ to Q₄ may each independently be C or N; C₁ to C₄ may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms; L₁₁ to L₁₃ may each independently be a direct linkage, *—O—*, *—S—*,

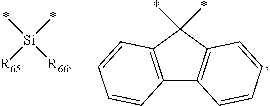

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; and d1 to d4 may each independently be an integer from 0 to 4.

In an embodiment, the first compound may be represented by one of Formula 1-1 to Formula 1-4:

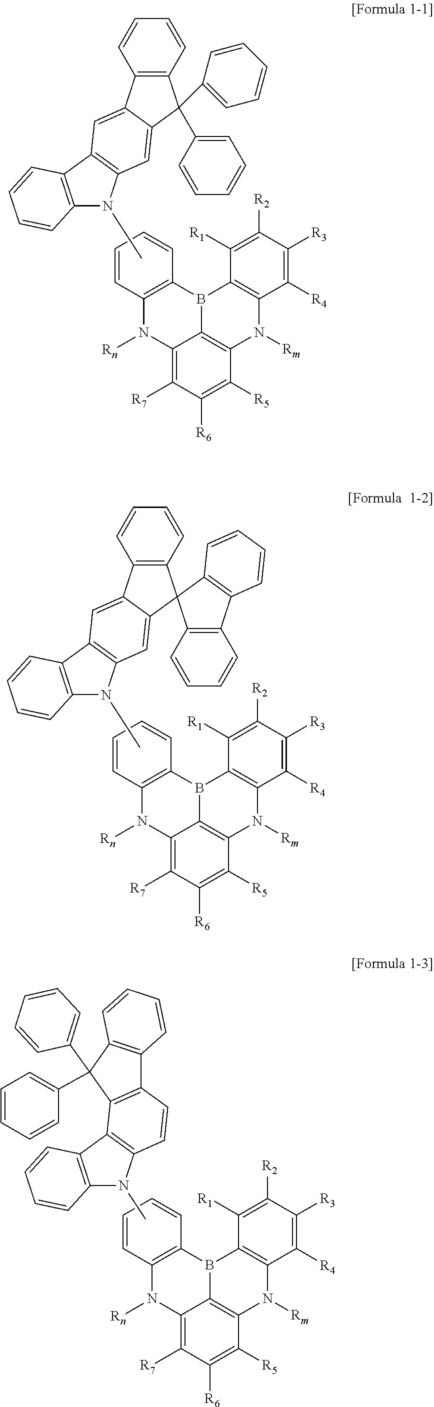

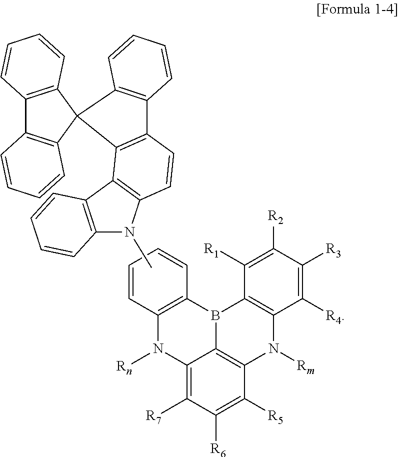

In Formula 1-1 to Formula 1-4, Rₙ, Rₘ, and R₁ to R₇ are the same as defined in Formula 1.

In an embodiment, the first compound may be represented by Formula 1-A:

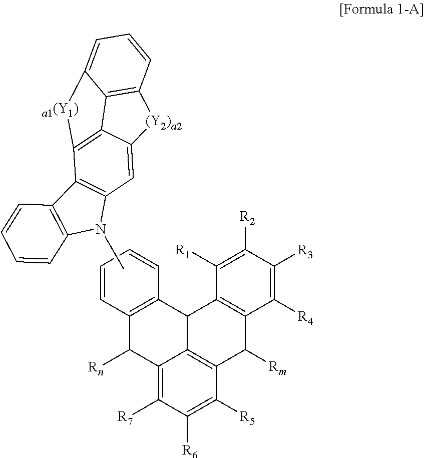

In Formula 1-A, Rₙ, Rₘ, R₁ to R₇, Y₁, Y₂, a1, and a2 are the same as defined in Formula 1 and Formula 2.

In an embodiment, the first compound may be represented by Formula 1-A1:

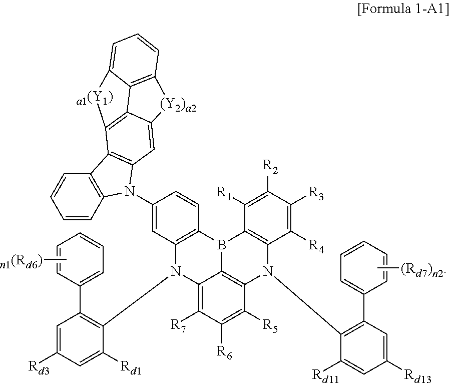

In Formula 1-A1, n1 and n2 may each independently be an integer from 0 to 5; R_{d6} and R_{d7} may each independently be a hydrogen atom, a deuterium atom, or a substituted or unsubstituted alkyl group having 1 to 30 carbon atoms; R_{d11} and R_{d13} may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms; and R₁ to R₇, Y₁, Y₂, a1, a2, R_{d1}, and R_{d3} are the same as defined in Formula 1, Formula 2, and Formula 3.

In an embodiment, the group represented by Formula 3 may be represented by one of Formula 3-1 to Formula 3-8:

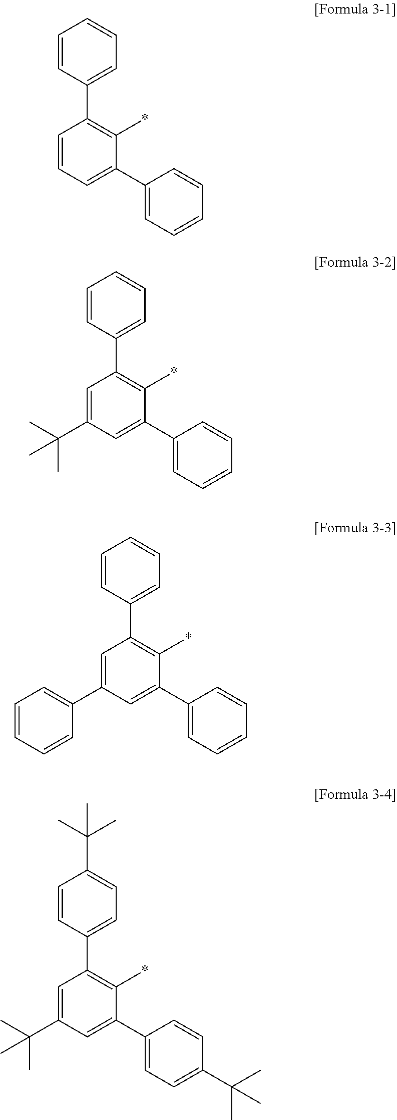 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2ccc(C(C)(C)C)cc2)cc(C(C)(C)C)cc1-c1ccc(C(C)(C)C)cc1]

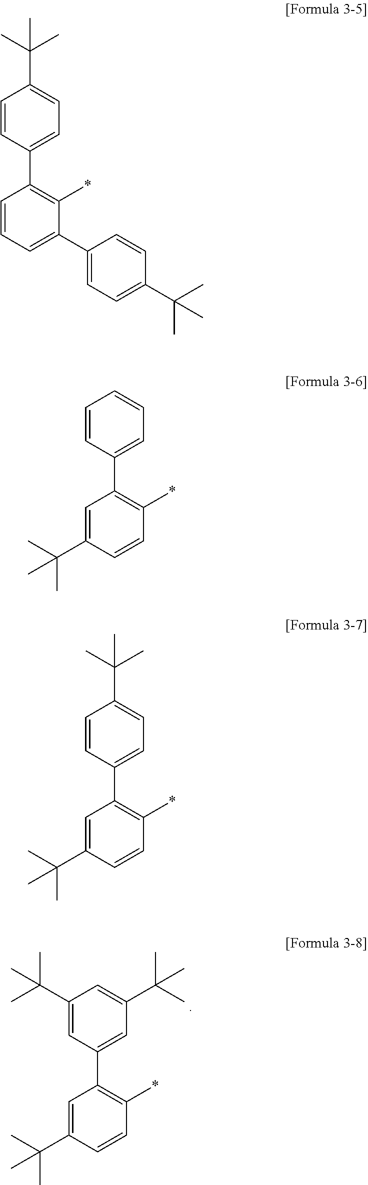

In an embodiment, in Formula 1, R₂ and R₃ may each independently be a hydrogen atom, a substituted or unsubstituted phenyl group, a substituted or unsubstituted dibenzofuran group, a substituted or unsubstituted carbazole group, or a group represented by Formula 2.

In an embodiment, in Formula 1, R₂ and R₃ may each independently be a group represented by one of Formula R-1 to Formula R-10:

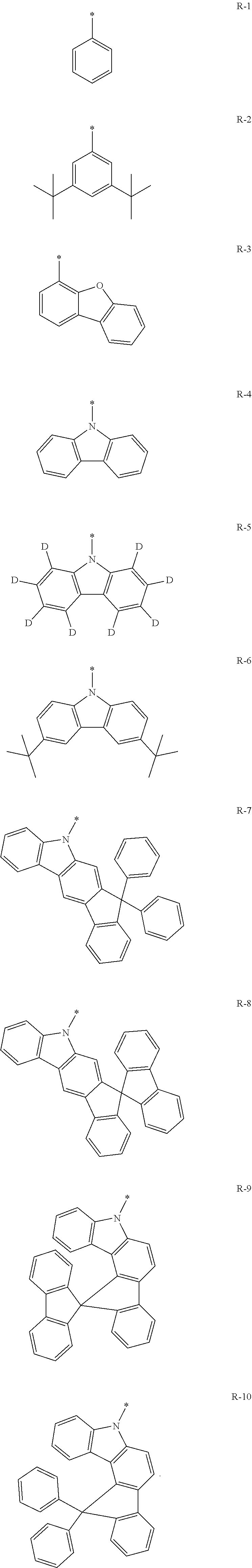

In Formula R-5, D represents a deuterium atom.

In an embodiment, in Formula 1, R₆ may be a hydrogen atom or a substituted or unsubstituted t-butyl group.

In an embodiment, the first compound may include at least one compound selected from Compound Group 1, which is explained below.

According to an embodiment, a fused polycyclic compound may be represented by Formula 1, which is explained herein.

In an embodiment, the fused polycyclic compound may be represented by one of Formula 1-1 to Formula 1-4, which are explained herein.

In an embodiment, the fused polycyclic compound may be represented by Formula 1-A, which is explained herein.

In an embodiment, the fused polycyclic compound may be represented by Formula 1-A1, which is explained herein.

In an embodiment, the group represented by Formula 3 may be represented by one of Formula 3-1 to Formula 3-8, which are explained herein.

In an embodiment, in Formula 1, R₂ and R₃ may each independently be a hydrogen atom, a substituted or unsubstituted phenyl group, a substituted or unsubstituted dibenzofuran group, a substituted or unsubstituted carbazole group, or a group represented by Formula 2.

In an embodiment, in Formula 1, R₂ and R₃ may each independently be a group represented by one of Formula R-l to Formula R-10.

In an embodiment, in Formula 1, R₆ may be a hydrogen atom or a substituted or unsubstituted t-butyl group.

In an embodiment, the fused polycyclic compound may be selected from Compound Group I, which is explained below.

According to an embodiment, a display device may include: a circuit layer disposed on a base layer; and a display element layer disposed on the circuit layer, wherein the display element layer may include a light emitting element, the light emitting element may include a first electrode, a second electrode disposed on the first electrode, and an emission layer disposed between the first electrode and the second electrode, and the emission layer may include a fused polycyclic compound represented by Formula 1, which is explained herein.

In an embodiment, the light emitting element may include a first light emitting element that emits red light, a second light emitting element that emits green light, and a third light emitting element that emits blue light; and the third light emitting element may include the fused polycyclic compound.

In an embodiment, the display device may further include alight control layer, wherein the light control layer may be disposed on the display element layer, and the light control layer may include quantum dots.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a portion of a display device taken along virtual line I-I′ of FIG. 1;

FIG. 3 is a schematic cross-sectional view of a light emitting element of an embodiment;

FIG. 4 is a schematic cross-sectional view of a light emitting element of an embodiment;

FIG. 5 is a schematic cross-sectional view of a light emitting element of an embodiment;

FIG. 6 is a schematic cross-sectional view of a light emitting element of an embodiment;

FIG. 7 is a schematic cross-sectional view of a light emitting element of an embodiment;

FIG. 8A is a schematic view of a three-dimensional image of an Experimental Example Compound;

FIG. 8B is a schematic view of a three-dimensional image of a Comparative Example Compound;

FIG. 9 is a schematic cross-sectional view of a display device according to an embodiment;

FIG. 10 is a schematic cross-sectional view of a display device according to an embodiment;

FIG. 11 is a schematic cross-sectional view of a display device according to an embodiment;

FIG. 12 is a schematic cross-sectional view of a display device according to an embodiment; and

FIG. 13 is a schematic diagram of an interior of a vehicle in which display devices according to embodiments are disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device.

Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, +10%, or +5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring” may refer to a group that is bonded to an adjacent group to form a substituted or unsubstituted hydrocarbon ring or a substituted or unsubstituted heterocycle. The hydrocarbon ring may be aliphatic or aromatic. The heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 30, 5 to 20, or 5 to 10 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

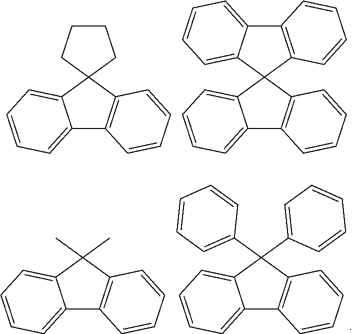

In the specification, a heterocyclic group may be any functional group or substituent derived from a ring that includes at least one of B, O, N, P, Si, and S as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in heterocyclic group may be 2 to 60, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

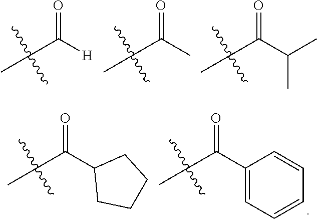

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a t-butylmethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond. In the specification, the symbols

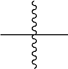

and -* each represent a bond to a neighboring atom in a corresponding formula or moiety.

Hereinafter, embodiments will be described with reference to the accompanying drawings.

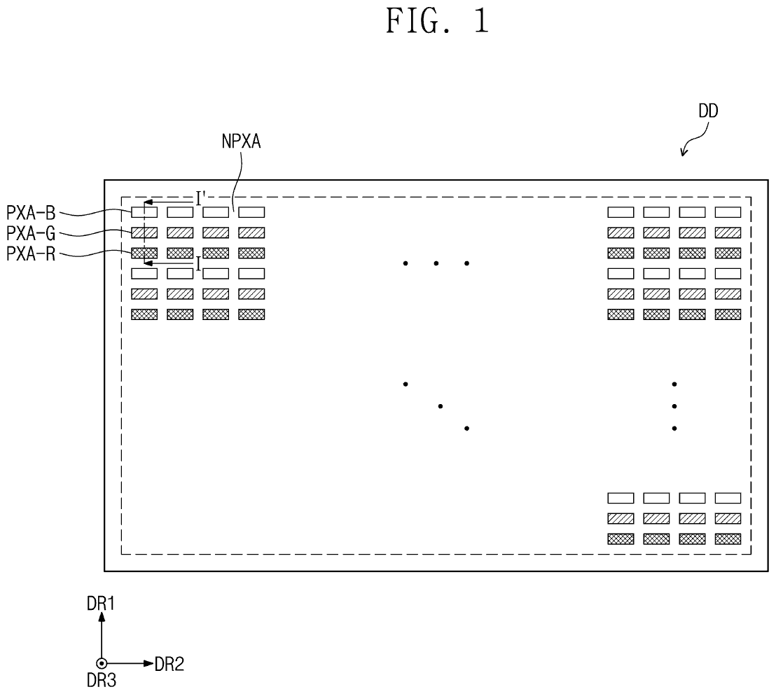

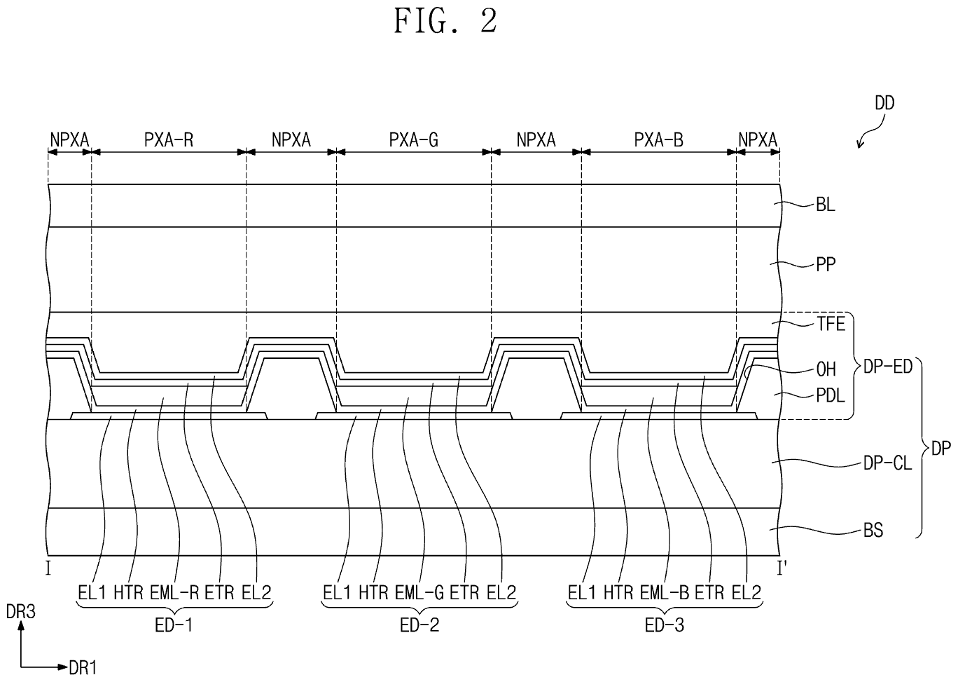

FIG. 1 is a schematic plan view of a display device DD according to an embodiment. FIG. 2 is a schematic cross-sectional view of a display device DD according to an embodiment. FIG. 2 is a schematic cross-sectional view of a portion of the display device DD taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining film PDL, light emitting elements ED-1, ED-2, and ED-3 disposed between portions of the pixel defining film PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

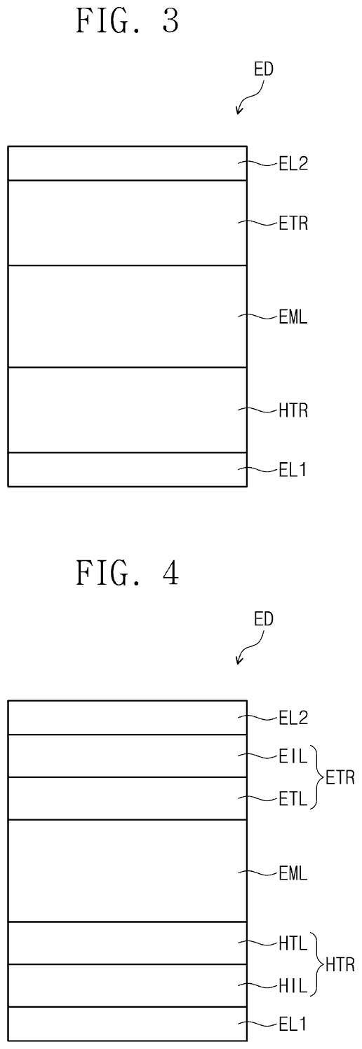

The light emitting elements ED-1, ED-2, and ED-3 may each have a structure of a light emitting element ED of an embodiment according to any of FIGS. 3 to 7, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining film PDL, and the hole transport region HTR, the electron transport region ETR, and the second electrode EL2 are each provided as a common layer for the light emitting elements ED-1, ED-2, and ED-3. However, embodiments are not limited thereto.

Although not shown in FIG. 2, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be areas between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIGS. 3 to 7 are each a schematic cross-sectional view of a light emitting element according to an embodiment. Embodiments provide a light emitting element ED that may include a first electrode EL1, a hole transport region HTR, an emission layer EML, an electron transport region ETR, and a second electrode EL2, which may be stacked in that order.

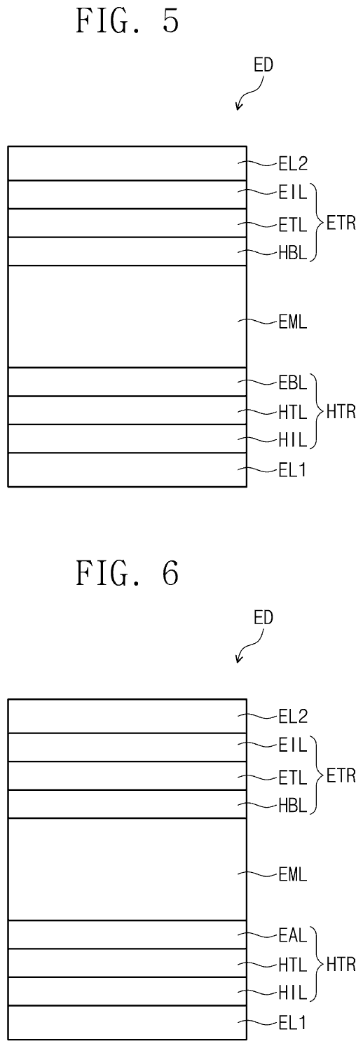

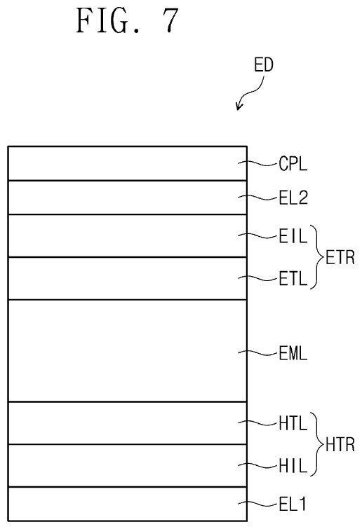

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 3, FIG. 6 is a schematic cross-sectional view of a light emitting element ED according to an embodiment, in which a hole transport region HTR includes a hole injection layer HIL, a hole transport layer HTL, and an emission-auxiliary layer EAL, and an electron transport region ETR includes an electron injection layer EIL, an electron transport layer ETL, and a hole blocking layer HBL. In comparison to FIG. 4, FIG. 7 is a schematic cross-sectional view of a light emitting element ED according to an embodiment that includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 A. For example, the thickness of the first electrode EL1 may be in a range of about 1,000 Å to about 3,000 A.

The hole transport region HTR may be provided on the first electrode EL1. The hole transport region HTR may include at least one of a hole injection layer HIL, a hole transport layer HTL, an emission-auxiliary layer EAL, and an electron blocking layer EBL. A thickness of the hole transport region HTR may be, for example, in a range of about 50 Å to about 15,000 A. In an embodiment, the emission-auxiliary layer EAL may serve as a buffer layer.

The hole transport region HTR may have a structure consisting of a layer consisting of a single material, a structure consisting of a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include a compound represented by Formula H-1:

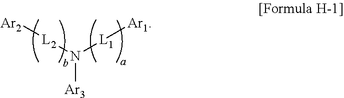

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. when a or b is 2 or greater, multiple L₁ or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Arᵢ to Ar₃ includes an amine group as a substituent. In an embodiment, the compound represented by Formula H-1 may be a carbazole-based compound in which at least one of Arᵢ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

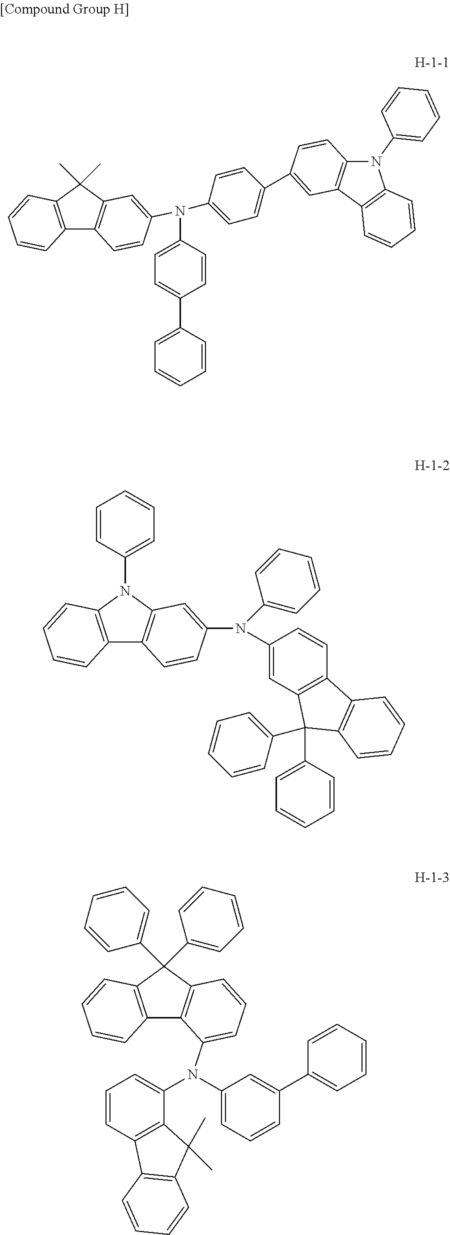 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

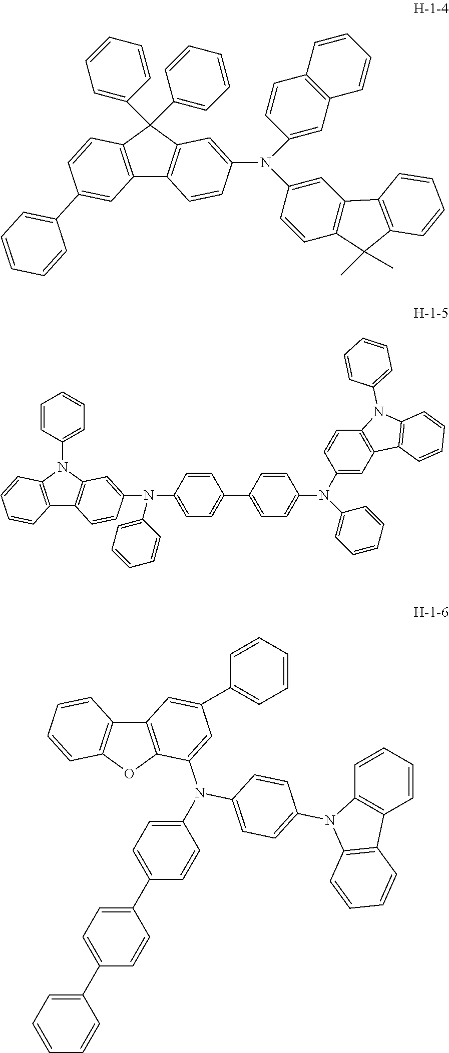 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

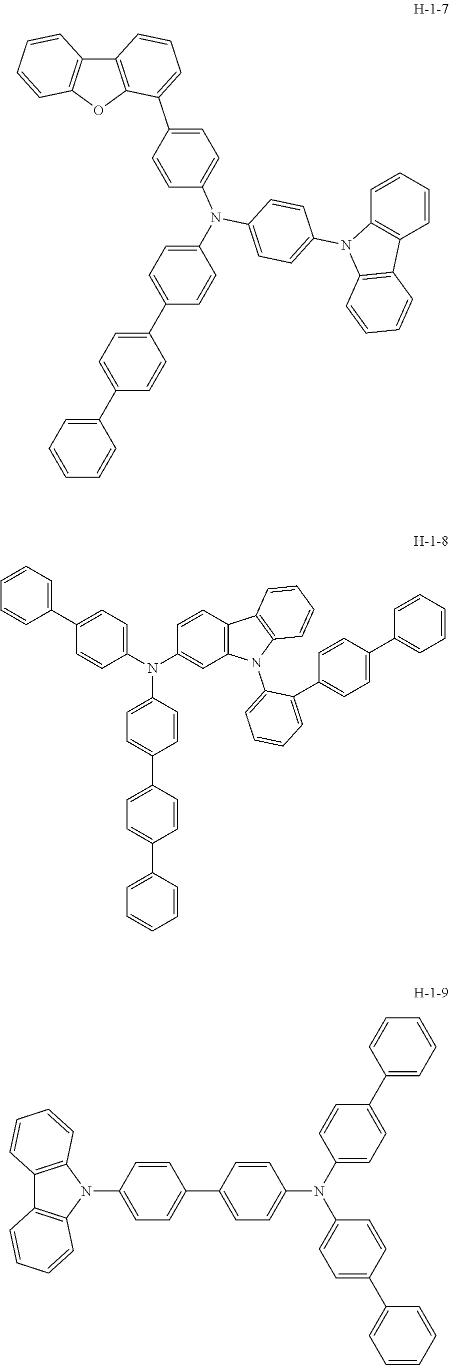 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

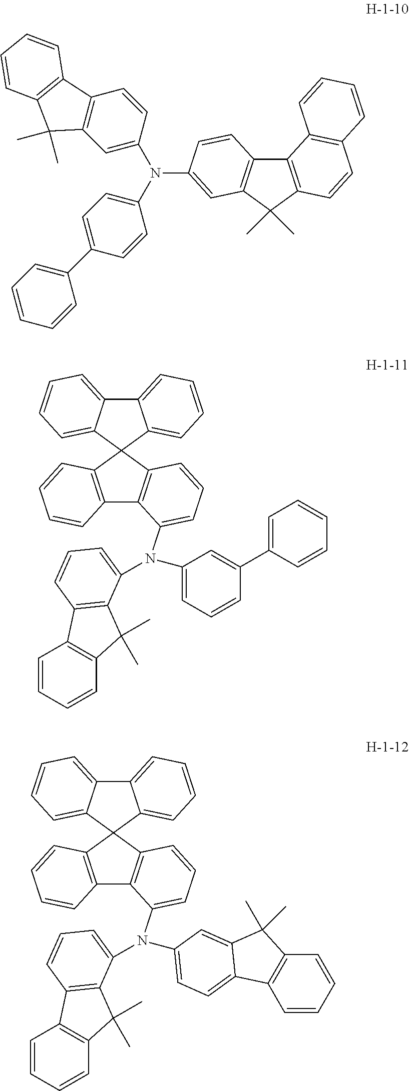 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

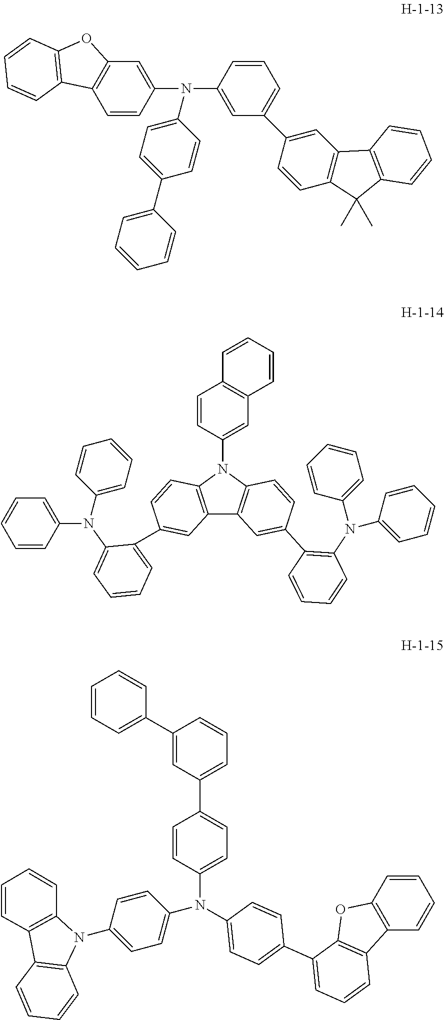 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

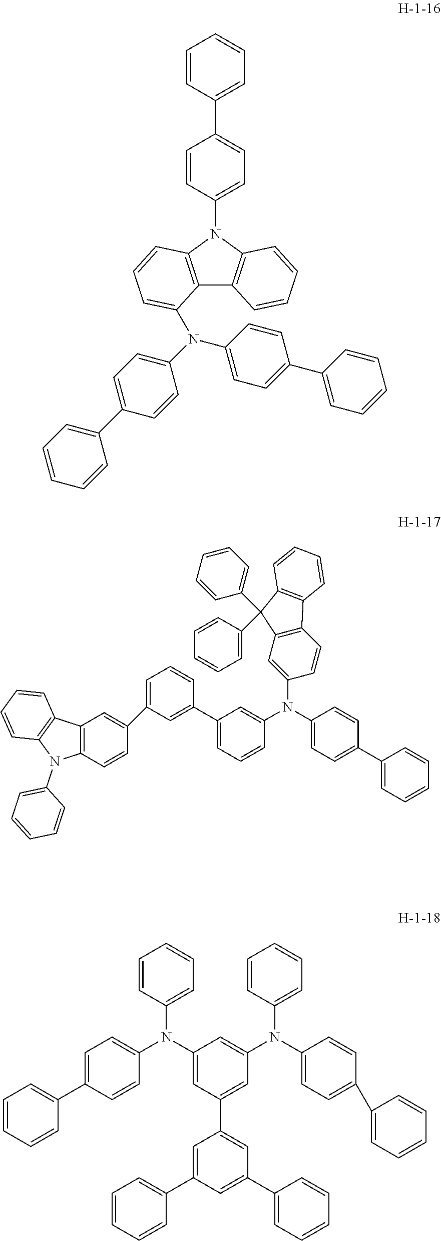 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

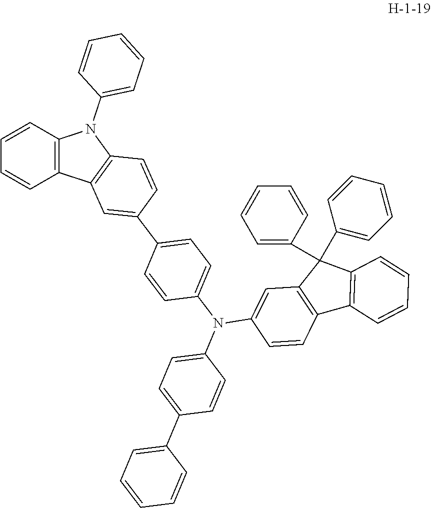 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(Ni-phenyl-N4,N4-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine](TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, an emission-auxiliary layer EAL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes the hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f:2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of an emission-auxiliary layer EAL and an electron blocking layer EBL, in addition to the hole injection layer HIL and the hole transport layer HTL. The emission-auxiliary layer EAL may compensate for a resonance distance according to a wavelength of light emitted from the emission layer EML, and may thus increase light emission efficiency by adjusting hole charge balance. The emission-auxiliary layer EAL may also prevent electron injection into the hole transport region HTR. A material that may be included in the hole transport region HTR may be used as a material in the emission-auxiliary layer EAL. The electron blocking layer EBL may prevent the injection of electrons from an electron transport region ETR to the hole transport region HTR.

In an embodiment, the emission layer EML may include a first compound. The emission layer EML according to an embodiment may further include at least one of a second compound, a third compound, and a fourth compound. The second compound may include a tricyclic fused ring containing a nitrogen atom as a ring-forming atom. The third compound may include a hexagonal ring group containing at least one nitrogen atom as a ring-forming atom. The fourth compound may include an organometallic complex. The second, third, and fourth compounds will be described in more detail later.

In the specification, the first compound may be referred to as a fused polycyclic compound. The fused polycyclic compound according to an embodiment may include, as a central moiety, a pentacyclic fused ring core that includes two nitrogen atoms and a boron atom as ring-forming atoms. The fused polycyclic compound according to an embodiment may include an indenocarbazole moiety and a biphenyl moiety (or terphenyl moiety) directly or indirectly bonded to the central moiety. Accordingly, in the fused polycyclic compound according to an embodiment, energy levels of a higher triplet state (Tn state, where n is an integer of 2 or more) become close to each other, so that reverse inter system crossing (RISC) may be accelerated, and Dexter energy transfer may be prevented. In an embodiment, a light emitting element ED that includes the fused polycyclic compound may exhibit low driving voltage, high luminous efficiency, and long service life characteristics.

The light emitting element ED according to an embodiment may include a fused polycyclic compound according to an embodiment. The fused polycyclic compound according to an embodiment may be represented by Formula 1:

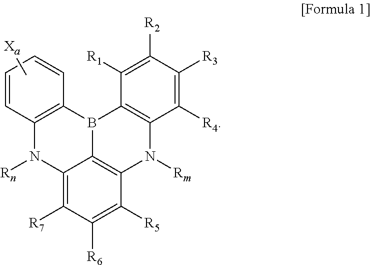

In Formula 1, R₁ to R₇ may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

For example, R₁, R₄, Rs, and R₇ may each be a hydrogen atom. In an embodiment, R₆ may be a hydrogen atom or a substituted or unsubstituted t-butyl group.

In an embodiment, R₂ and R₃ may each independently be a hydrogen atom, a substituted or unsubstituted phenyl group, a substituted or unsubstituted dibenzofuran group, a substituted or unsubstituted carbazole group, or a group represented by Formula 2.

In an embodiment, R₂ and R₃ may each independently be a group represented by one of Formula R-1 to Formula R-10. In Formula R-5, D represents a deuterium atom.

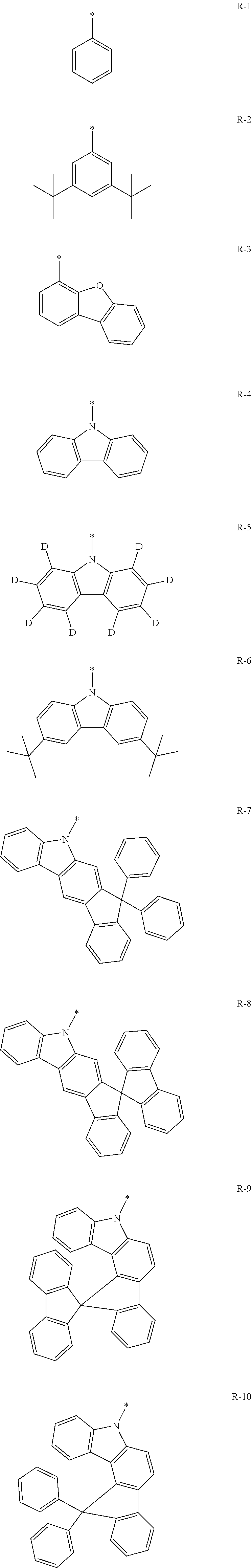

In Formula 1, Xₐ may be a group represented by Formula 2. For example, Xₐ may include an indenocarbazole moiety:

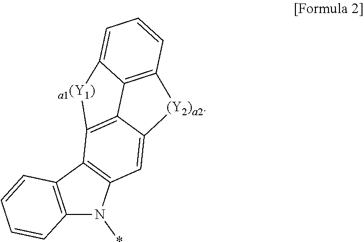

In Formula 2, one of a1 and a2 may be 1, and the other of a1 and a2 may be 0. When al is 1 and a2 is 0, Y₂ may not exist. When al is 0 and a2 is 1, Y₁ may not exist.

In Formula 2, Y₁ and Y₂ may each independently be C(Rₐ)(R_{b}). In Formula 2, Ra and R_{b} may each independently be a substituted or unsubstituted aryl group having 6 to 20 ring-forming carbon atoms, or may be bonded to each other to form a ring. For example, Rₐ and R_{b} may each be an unsubstituted phenyl group. For example, Rₐ and R_{b} may each be an unsubstituted phenyl group, and may be bonded to each other to form a spiro-bifluorene moiety.

In Formula 1, Rₙ and Rₘ may each independently be a group by Formula 3. For example, Rₙ and Rₘ may each independently be a substituted or unsubstituted phenyl group. For example, Rₙ and Rₘ may each independently include a biphenyl moiety and/or a terphenyl moiety.

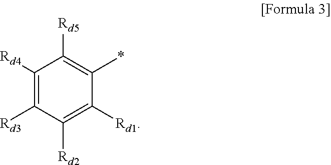

In Formula 3, R_{d1} to R_{d5} may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, R_{d1} and R_{d5} may each independently be a hydrogen atom, an unsubstituted phenyl group, or a phenyl group substituted with a t-butyl group. For example, R_{d}3 may be a hydrogen atom, an unsubstituted t-butyl group, or an unsubstituted phenyl group. For example, R_{d2} and R_{d4} may each be a hydrogen atom. For example, at least one of R_{d1} to R_{d5} may not be a hydrogen atom.

In an embodiment, the group represented by Formula 3 may be represented by one of Formula 3-1 to Formula 3-8. Formula 3-1 to Formula 3-8 each represent a case where R_{d1} to R_{d5} in Formula 3 is further defined.

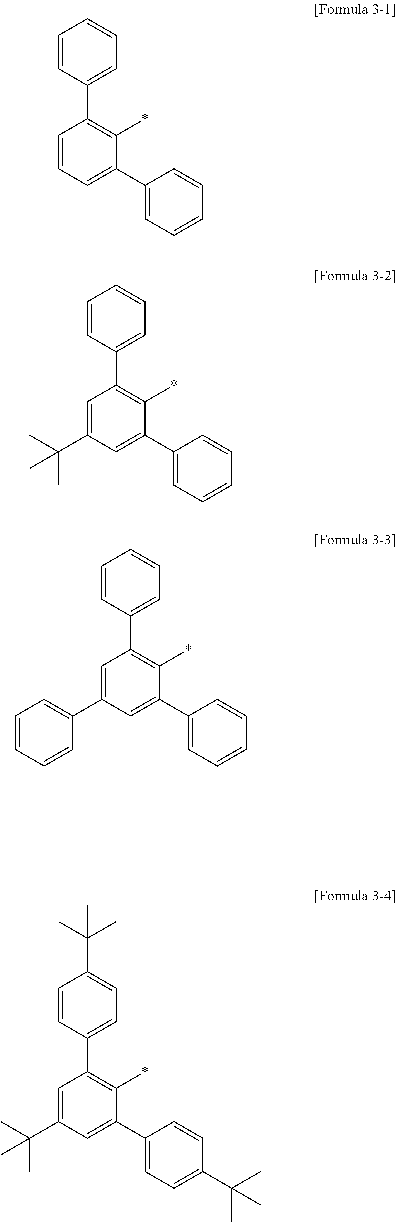 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2ccc(C(C)(C)C)cc2)cc(C(C)(C)C)cc1-c1ccc(C(C)(C)C)cc1]

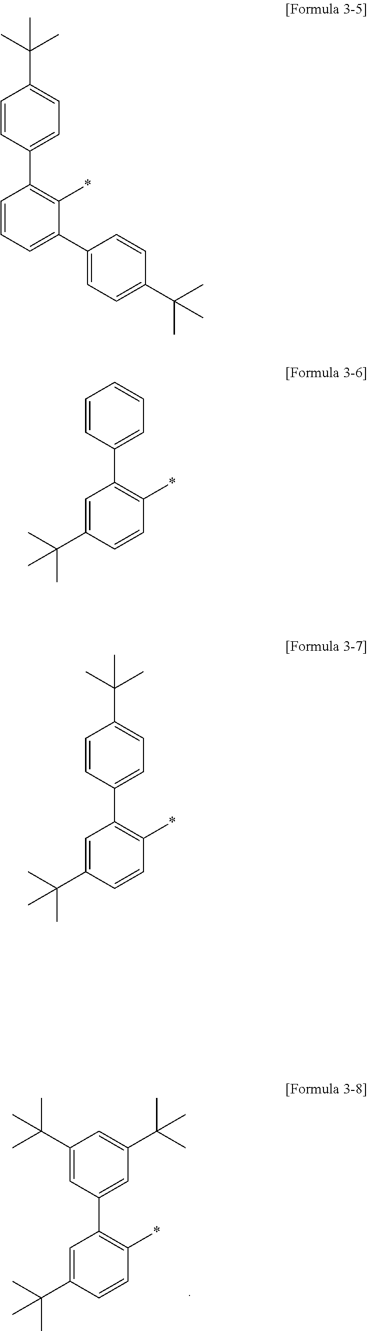

For example, in Formula 1, at least one of R₁ to R₄ and at least one of R₅ to R₇ may not be a hydrogen atom. In Formula 3, at least one of R_{d1} to R_{d5} may not be a hydrogen atom. In the fused polycyclic compound according to an embodiment, at least one of R₁ to R₄, at least one of R₅ to R₇, and at least one of R_{d1} to R_{d5} may be an active site at a para position with respect to the boron atom of Formula 1. As the active site is a substituent rather than a hydrogen atom, it may be possible to preserve material stability and prevent deterioration in the emission layer EML. As at least one of R₁ to R₄, at least one of R₅ to R₇, and at least one of R_{d1} to R_{d5} is not a hydrogen atom, the fused polycyclic compound according to an embodiment may prevent intermolecular interactions and may maximize the prevention of Dexter energy transfer. Accordingly, the fused polycyclic compound represented by Formula 1 may exhibit excellent material stability.

The fused polycyclic compound according to an embodiment may include a deuterium atom. In Formula 1, any hydrogen atom may be substituted with a deuterium atom. For example, in Formula 1, at least one of R₁ to R₇ may include a deuterium atom as a substituent.

In an embodiment, the fused polycyclic compound represented by Formula 1 may be represented by one of Formula 1-1 to Formula 1-4. Formula 1-1 to Formula 1-4 each represent a case where Xₐ in Formula 1 is a group represented by Formula 2, and a1, a2, Y₁, and Y₂ in Formula 2 are further defined.

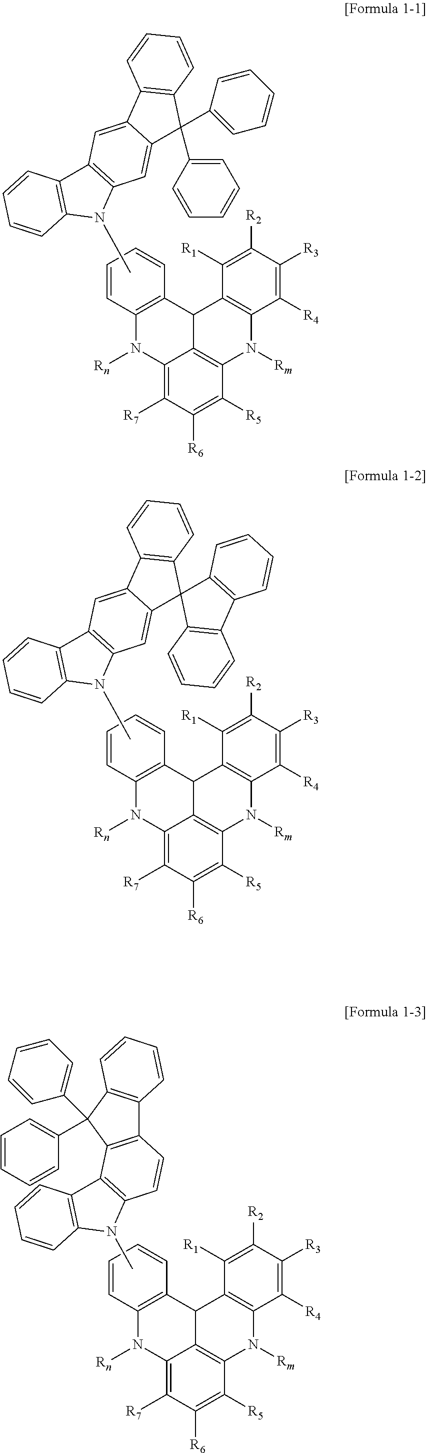

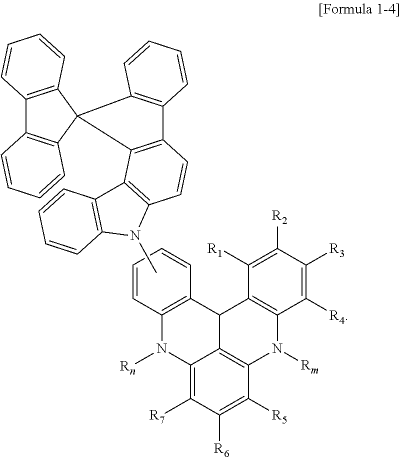

In Formula 1-1 to Formula 1-4, Rₙ, Rₘ, and R₁ to R₇ are the same as defined in Formula 1. Formula 1-1 represents a case where al is 0, a2 is 1, and Y₂ is C(Ph)₂. Formula 1-2 represents a case where al is 0, a2 is 1, Y₂ is C(Ph)₂, and two phenyl groups are bonded to each other to form a spiro-bifluorene moiety. Formula 1-3 represents a case where al is 1, a2 is 0, and Y₁ is C(Ph)₂. Formula 1-4 represents a case where al is 1, a2 is 0, Y₁ is C(Ph)₂, and two phenyl groups are bonded to each other to form a spiro-bifluorene moiety. Here, Ph represents an unsubstituted phenyl group.

In an embodiment, the fused polycyclic compound represented by Formula 1 may be represented by Formula 1-A. Formula 1-A represents a case wherein in Formula 1, the bonding position of Xₐ, which is a group represented by Formula 2, is further defined. Formula 1-A represents a case where Xₐ in Formula 1 is bonded at a para position to the boron atom.

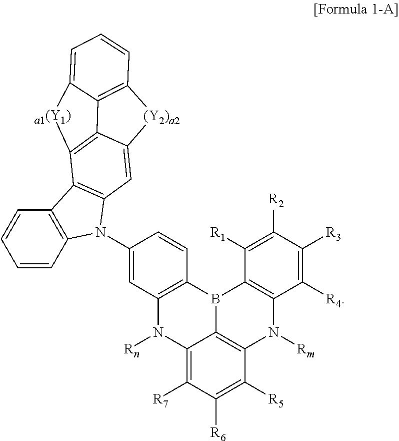

In Formula 1-A, Rₙ, Rₘ, R₁ to R₇, Y₁, Y₂, a1, and a2 are the same as defined in Formula 1 and Formula 2.

In an embodiment, the fused polycyclic compound represented by Formula 1-A may be represented by Formula 1-A1. Formula 1-A1 represents a case where Rₙ and Rₘ in Formula 1-A are each independently a substituted or unsubstituted biphenyl group.

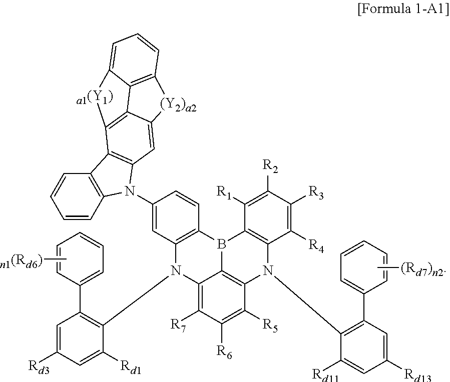

In Formula 1-A1, R₁ to R₇, Y₁, Y₂, a1, a2, R_{d1}, and R_{d3} are the same as defined in Formula 1, Formula 2, and Formula 3. In Formula 1-A1, n1 and n2 may each independently be an integer from 0 to 5. When n1 is 2 or greater, multiple R_{d6} groups may be the same as each other or at least one thereof may be different from the remainder. A case where n1 is 5 and five R_{d6} groups are all hydrogen atoms may be the same as a case where n1 is 0. When n2 is 2 or greater, multiple R_{d7} groups may be the same as each other or at least one thereof may be different from the remainder. A case where n2 is 5 and five R_{d7} groups are all hydrogen atoms may be the same as a case where n2 is 0.

In Formula 1-A1, R_{d6} and R_{d7} may each independently be a hydrogen atom, a deuterium atom, a substituted or unsubstituted aryl group having 1 to 30 ring-forming carbon atoms. For example, R_{d6} and R_{d7} may each independently be a hydrogen atom or an unsubstituted t-butyl group.

In Formula 1-A1, R_{d11} and R_{d13} may each independently be a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, R_{d11} and R_{d}13 may each independently be a hydrogen atom, an unsubstituted t-butyl group, an unsubstituted phenyl group, or a phenyl group substituted with a t-butyl group.

In Formula 1-A1, the biphenyl moiety containing R_{d1}, R_{d3}, and R_{d6} may be represented by one of Formulae 3-1 to 3-8 as described above. In Formula 1-A1, the biphenyl moiety containing R_{d11}, R_{d13}, and R_{d7} may be represented by one of Formulae 3-1 to 3-8 as described above.

In an embodiment, the fused polycyclic compound represented by Formula 1 may be any compound selected from Compound Group 1. In an embodiments, in the light emitting element ED, the emission layer EML may include at least one compound selected from Compound Group 1. In Compound Group 1, D represents a deuterium atom.

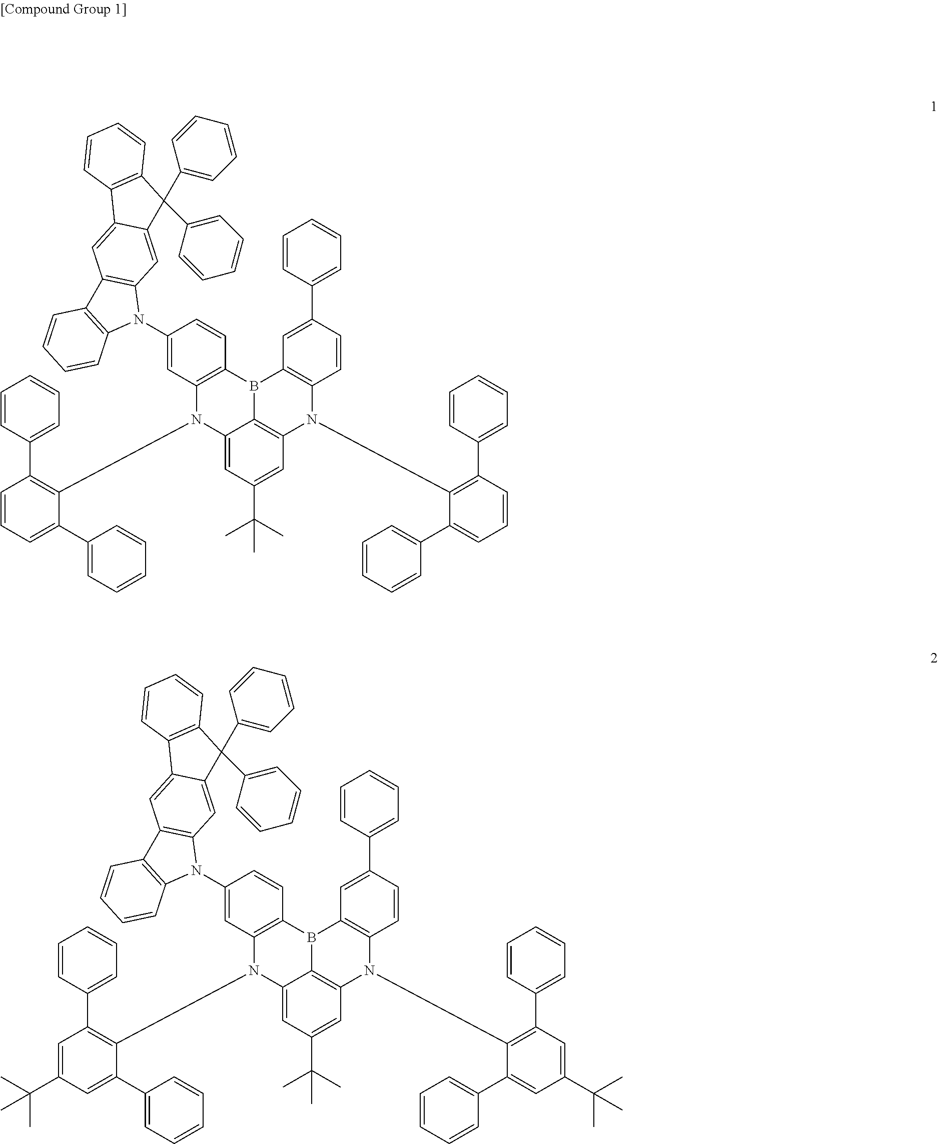 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1cc(-c3ccccc3)ccc1N2c1c(-c2ccccc2)cccc1-c1ccccc1 ; CC(C)(C)c1cc(-c2ccccc2)c(N2c3ccc(-c4ccccc4)cc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1]

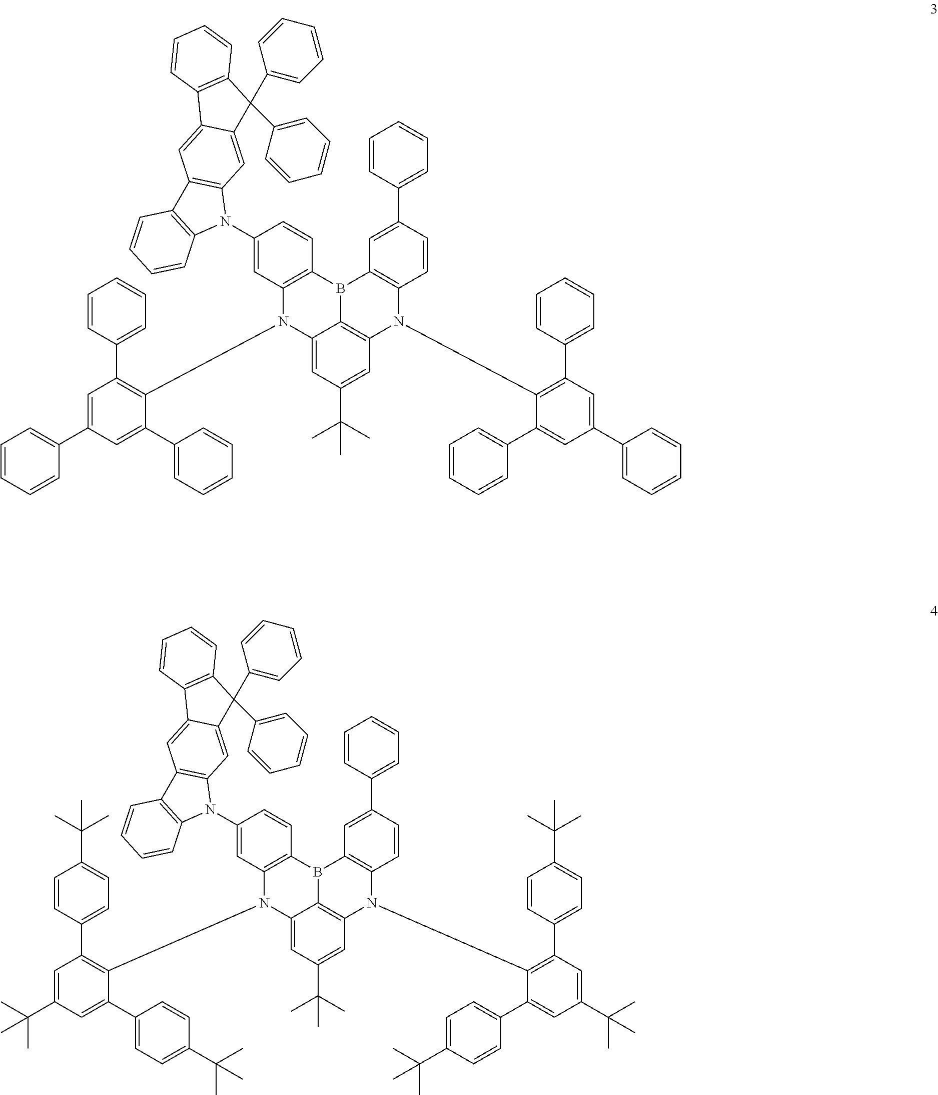 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1cc(-c3ccccc3)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4ccccc4)cc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

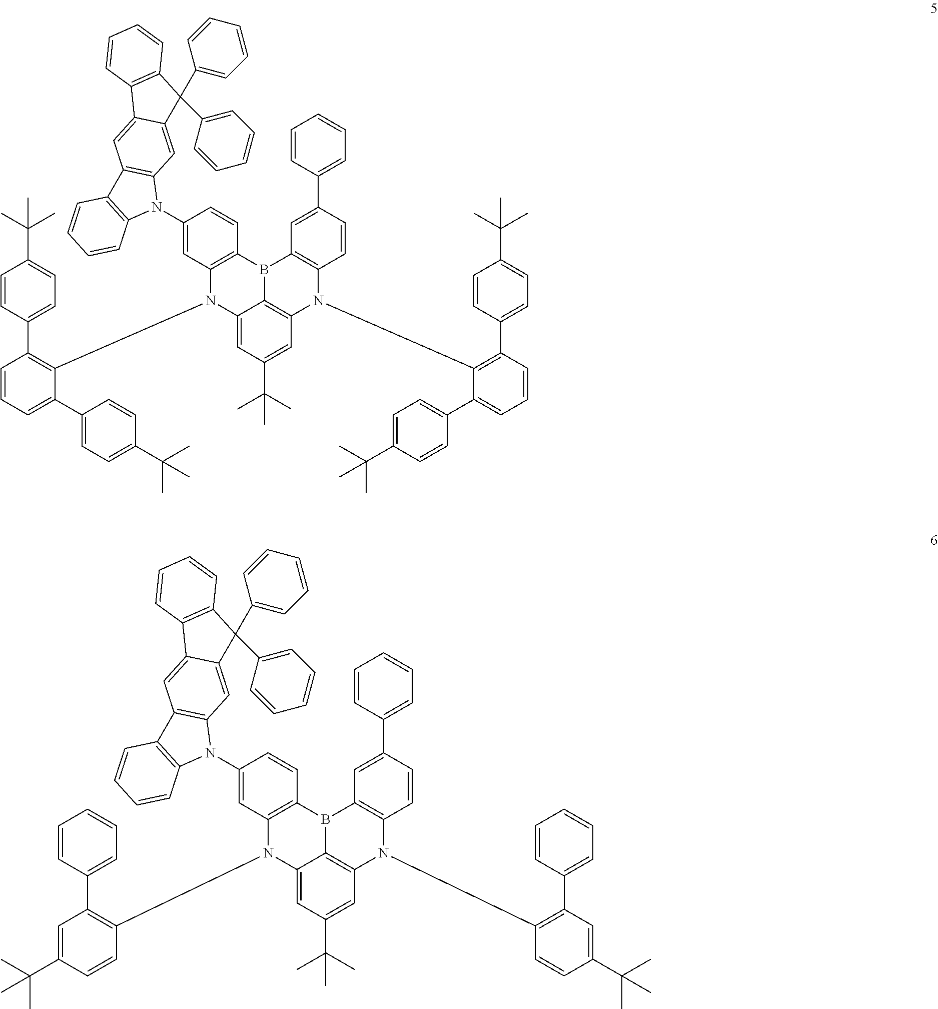

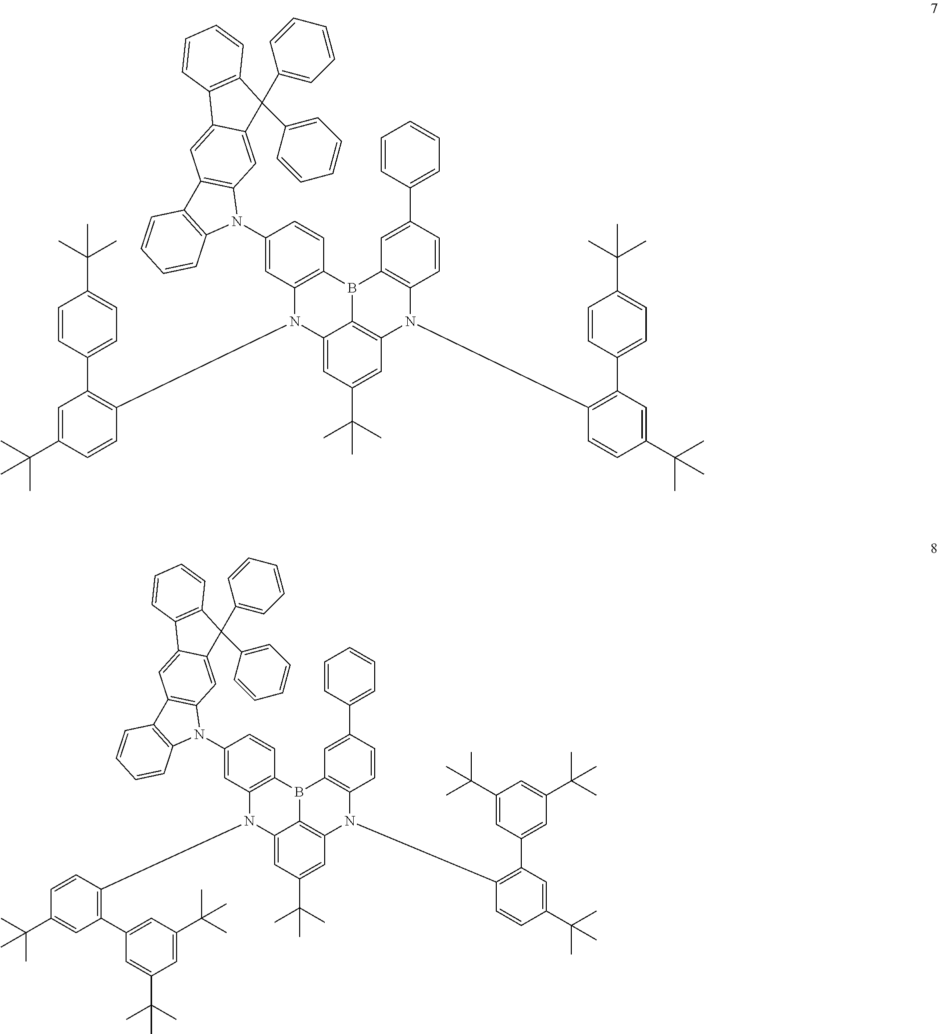

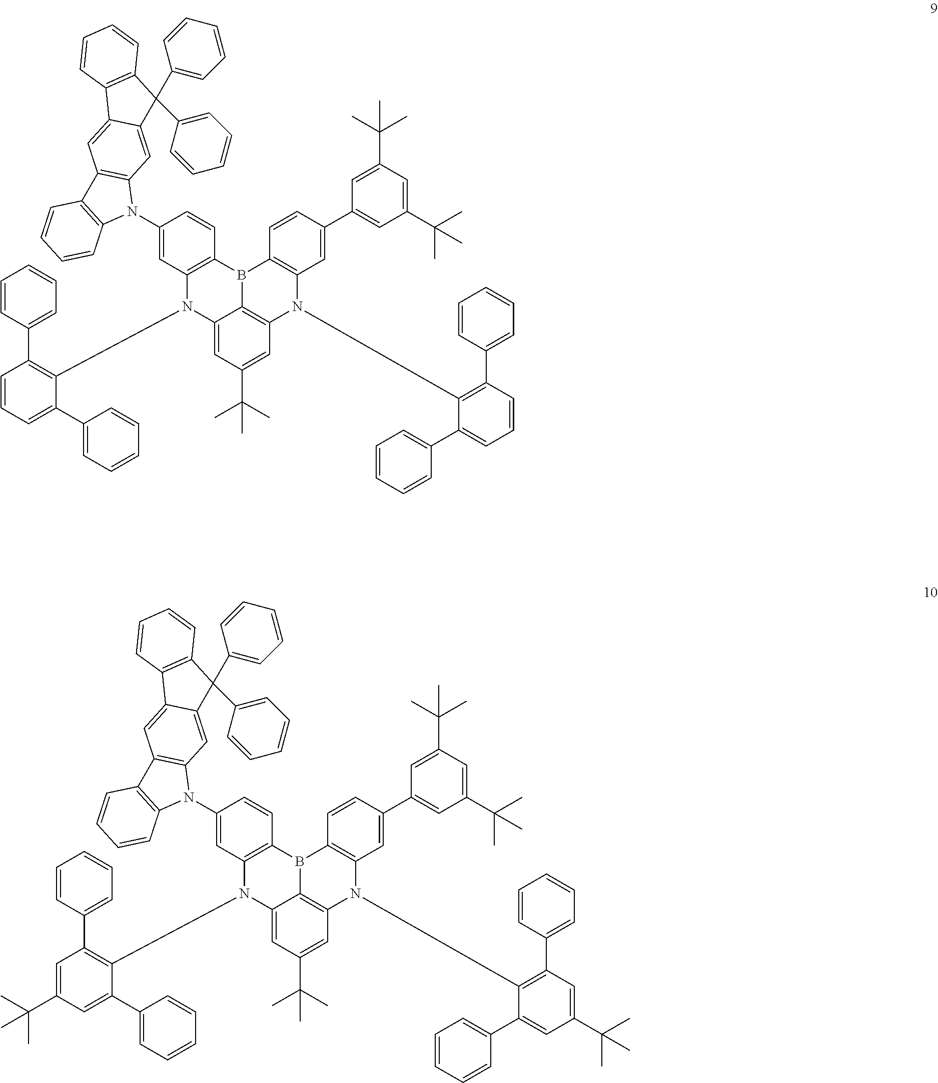 [SMILES: CC(C)(C)c1cc(-c2ccc3c(c2)N(c2c(-c4ccccc4)cccc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cccc2-c2ccccc2)cc(C(C)(C)C)c1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cc(C(C)(C)C)cc2-c2ccccc2)cc(C(C)(C)C)c1]

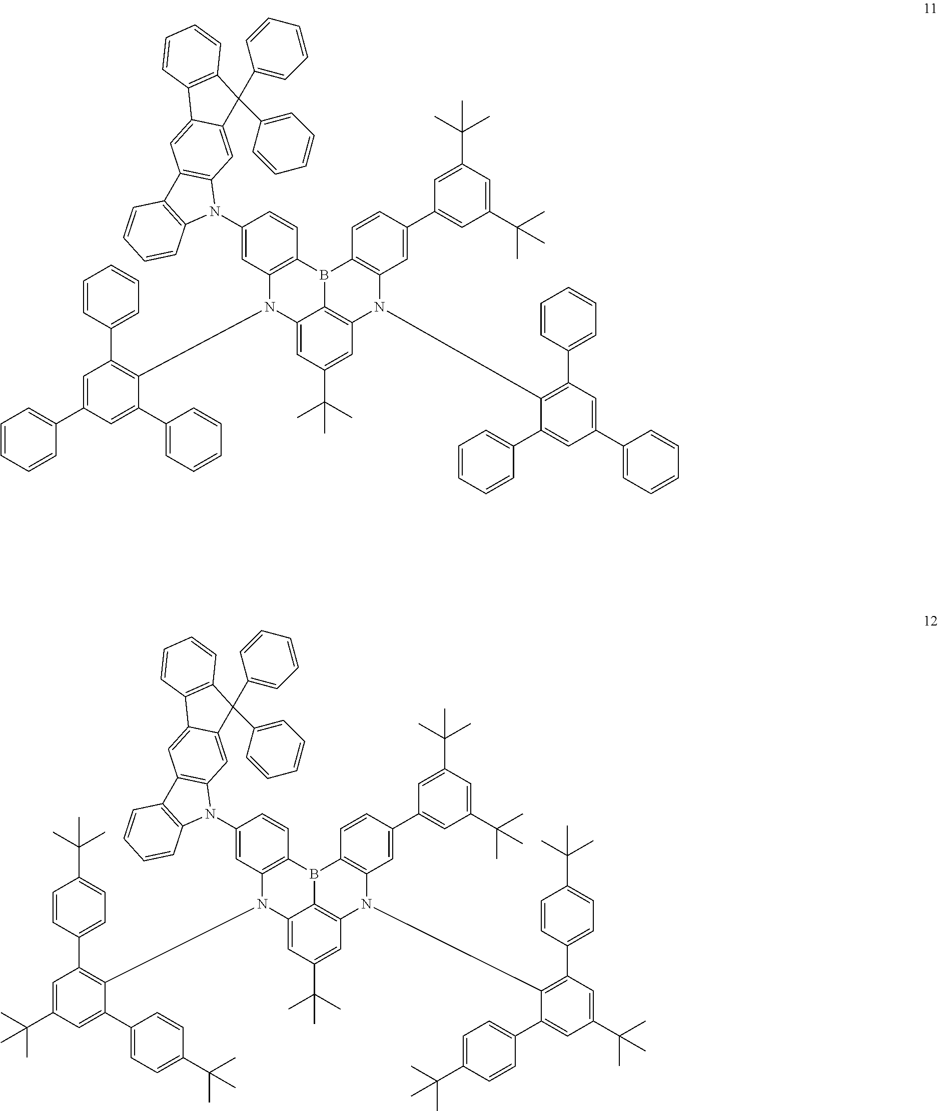 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cc(-c3ccccc3)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

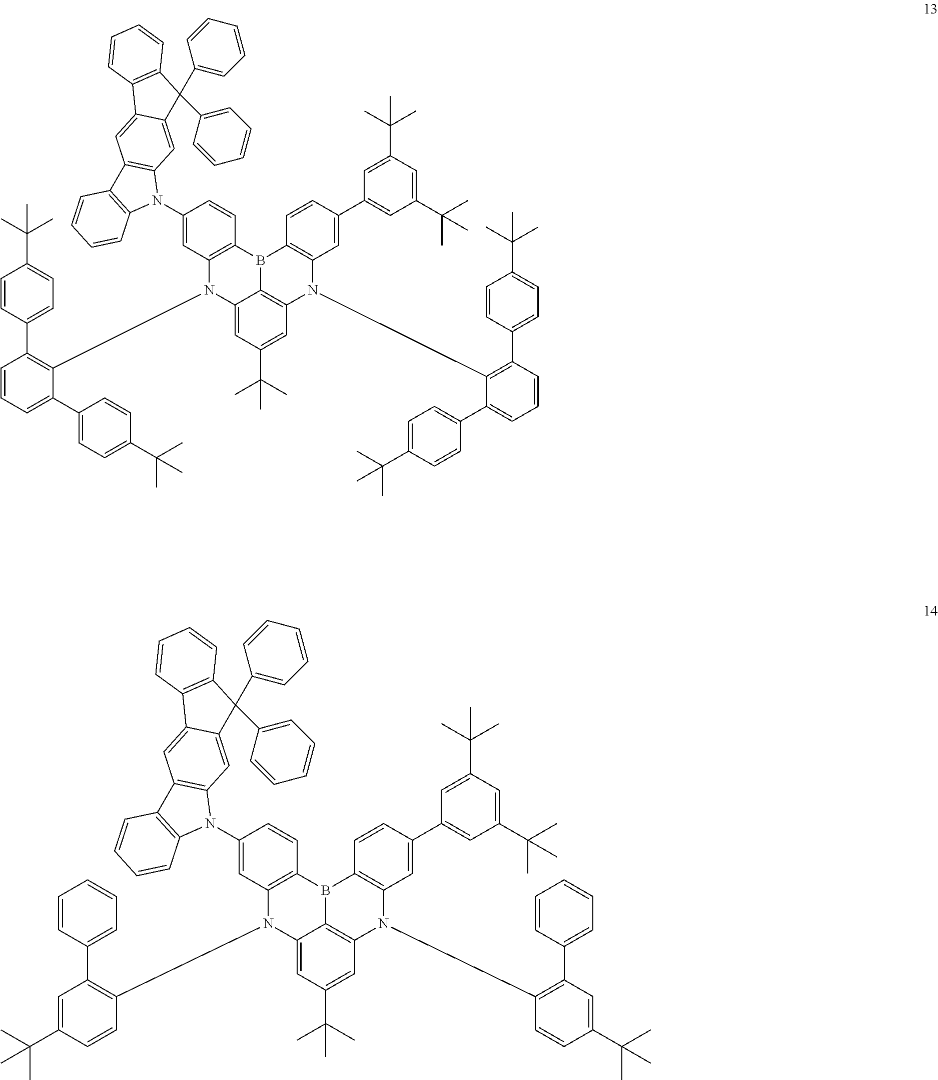

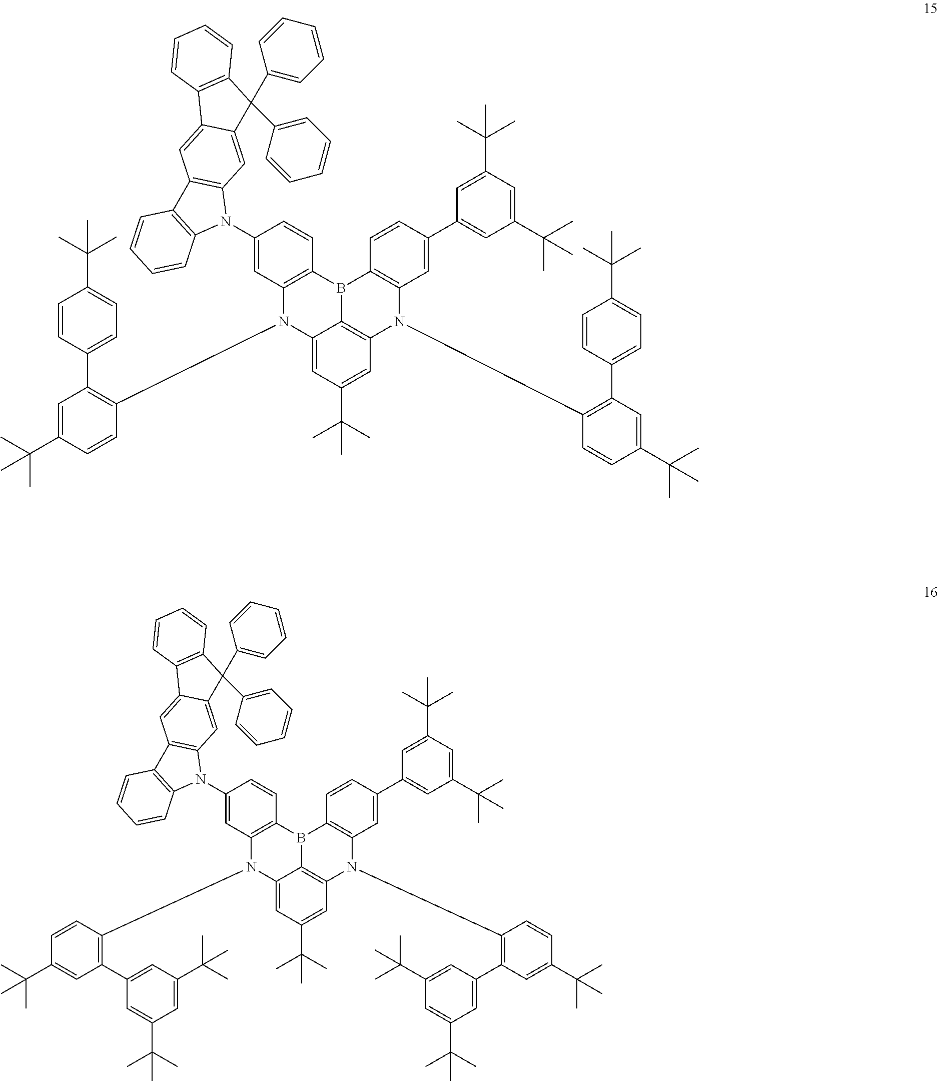

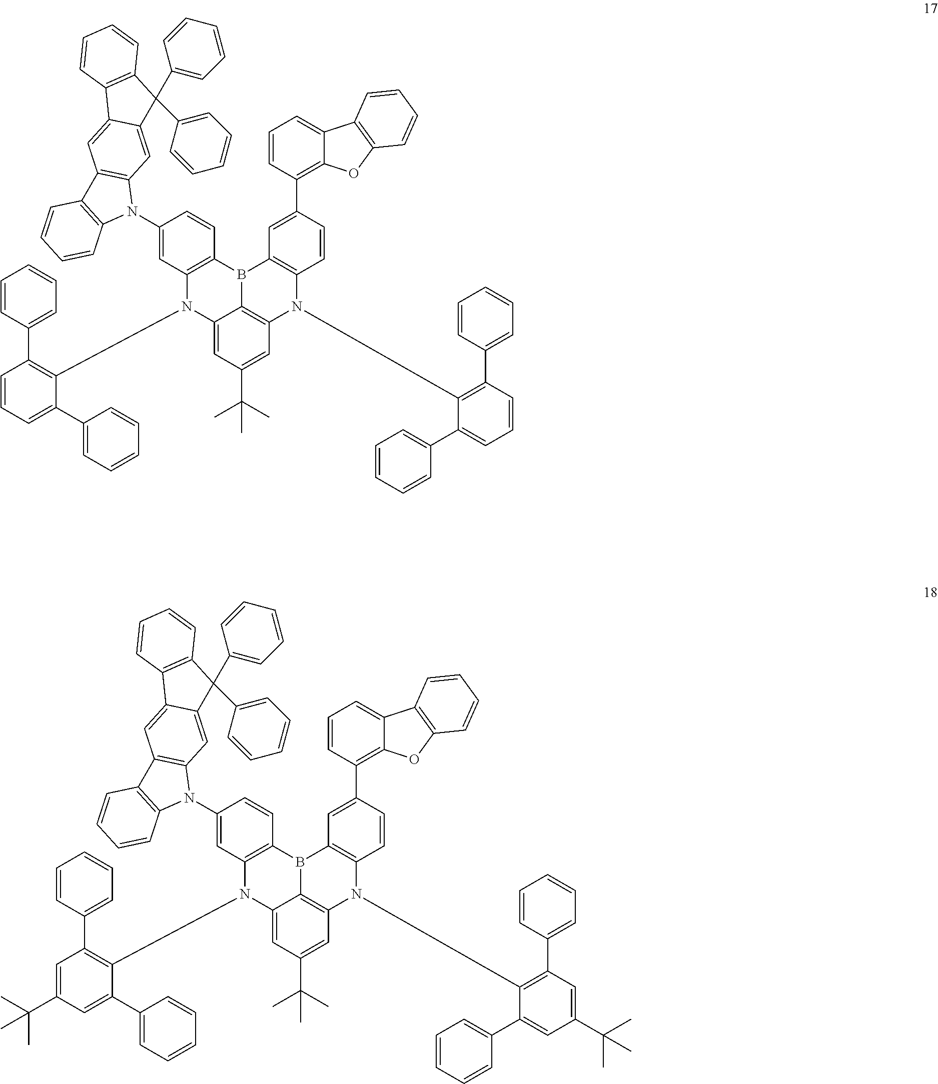 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1cc(-c3cccc4c3oc3ccccc34)ccc1N2c1c(-c2ccccc2)cccc1-c1ccccc1 ; CC(C)(C)c1cc(-c2ccccc2)c(N2c3ccc(-c4cccc5c4oc4ccccc45)cc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1]

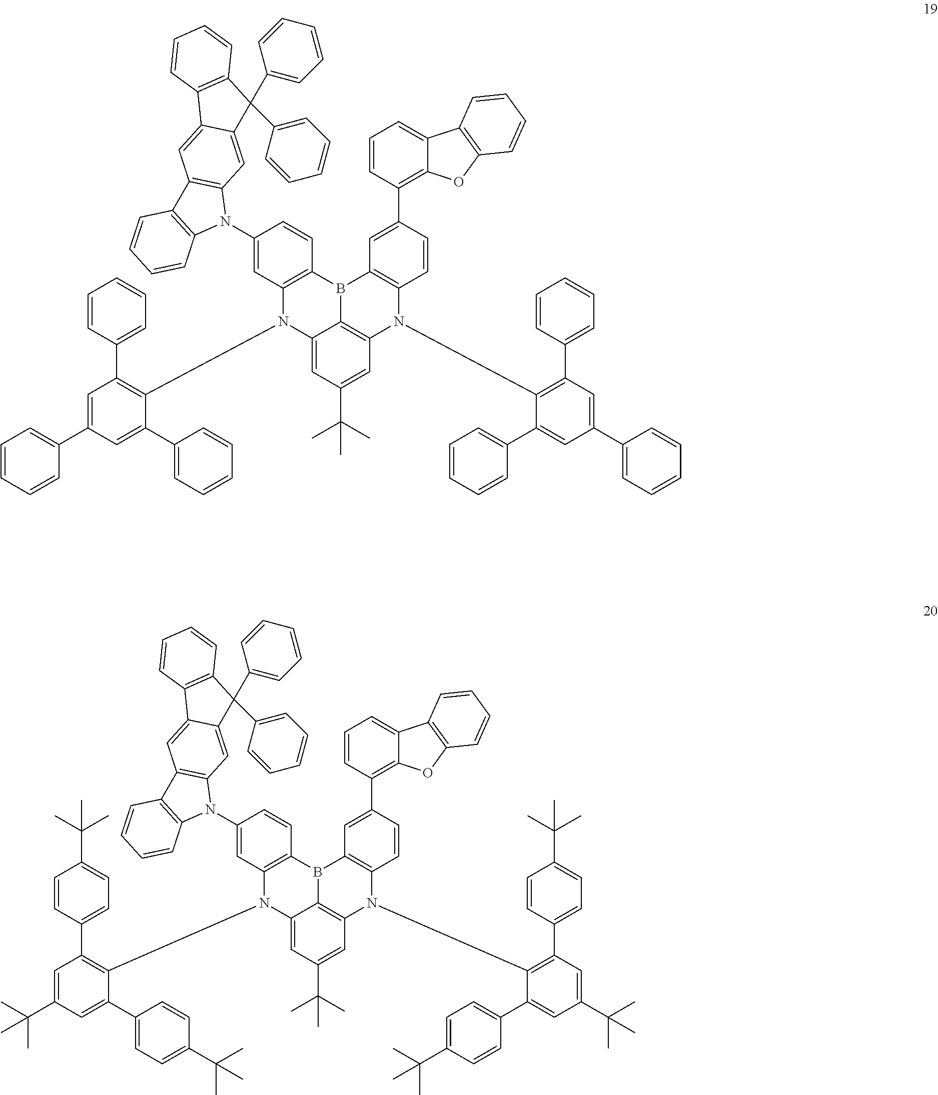 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1cc(-c3cccc4c3oc3ccccc34)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4cccc5c4oc4ccccc45)cc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

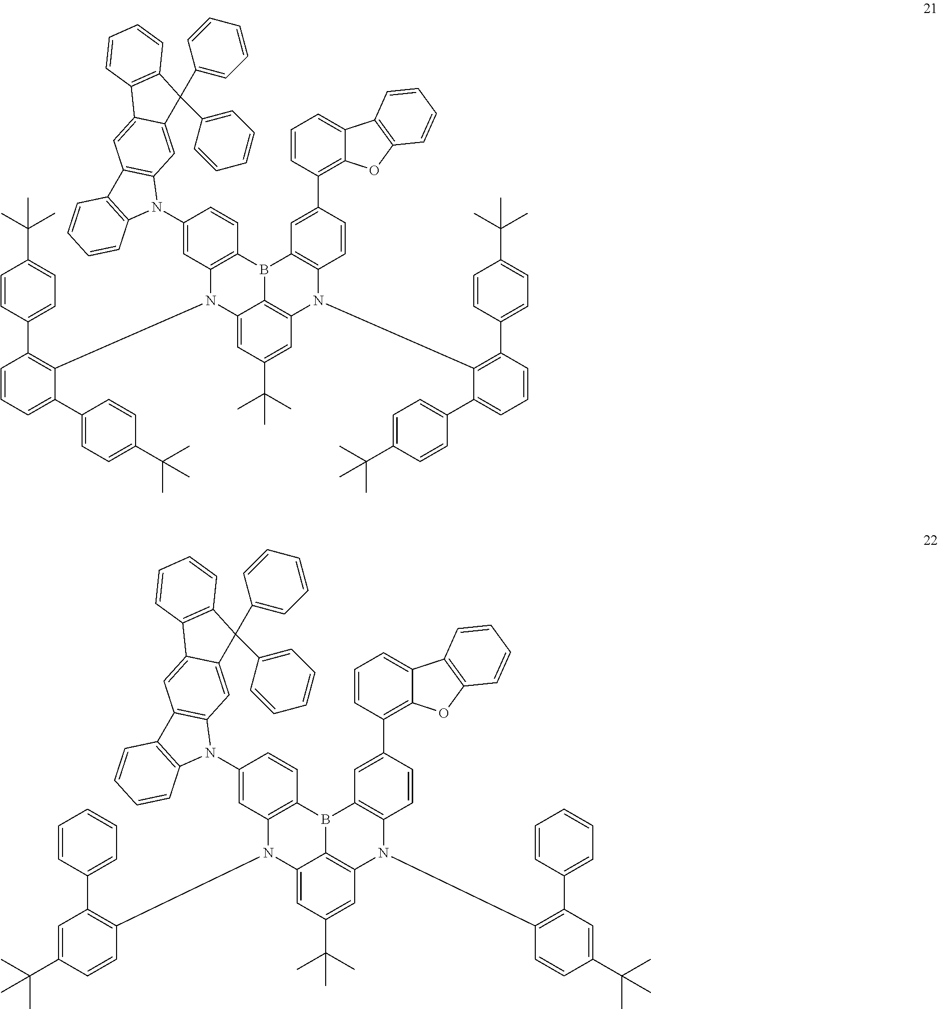

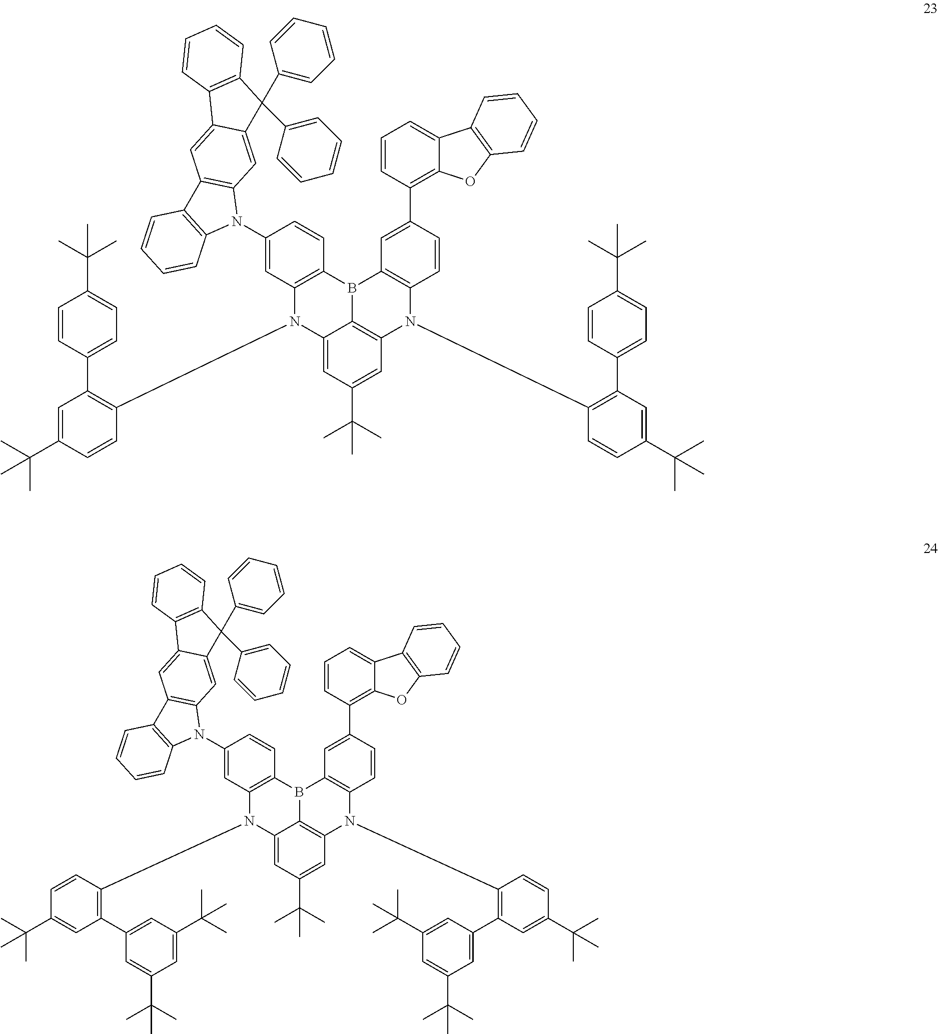

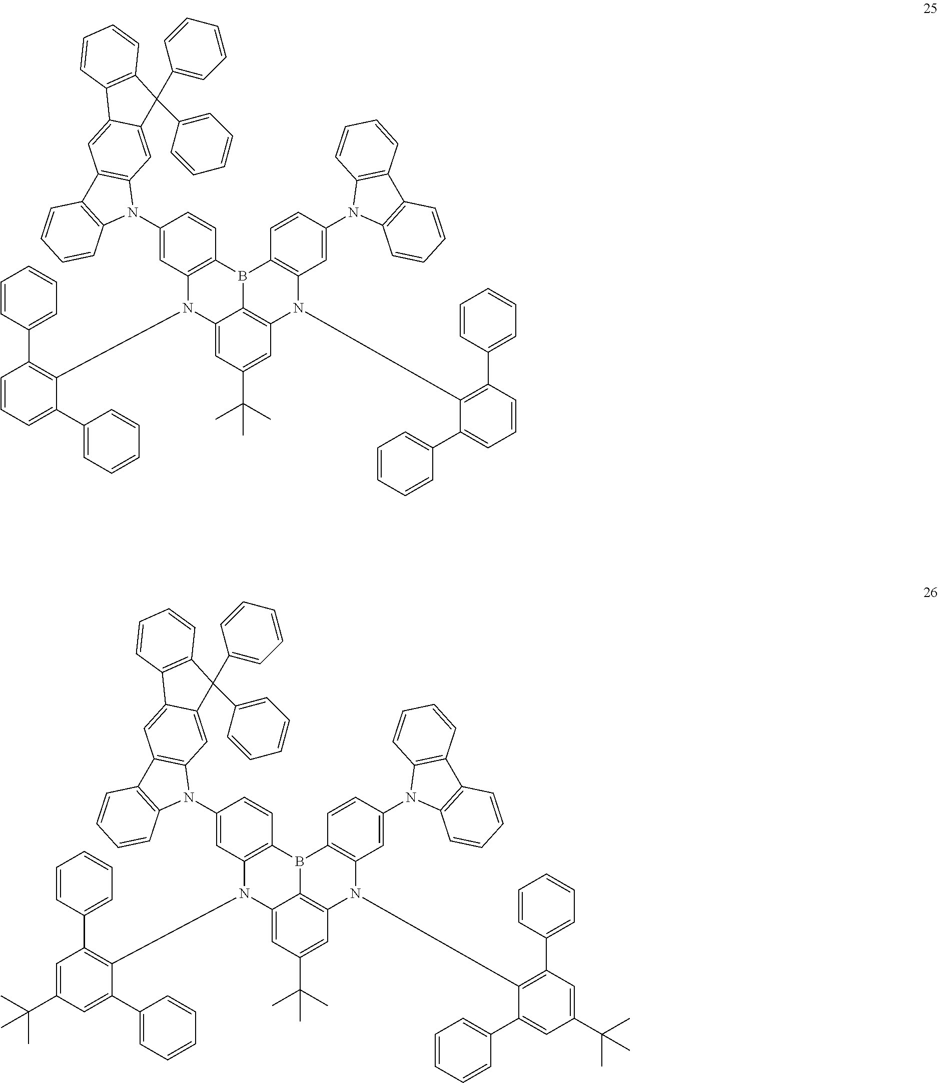 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1ccc(-n3c4ccccc4c4ccccc43)cc1N2c1c(-c2ccccc2)cccc1-c1ccccc1 ; CC(C)(C)c1cc(-c2ccccc2)c(N2c3cc(-n4c5ccccc5c5ccccc54)ccc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1]

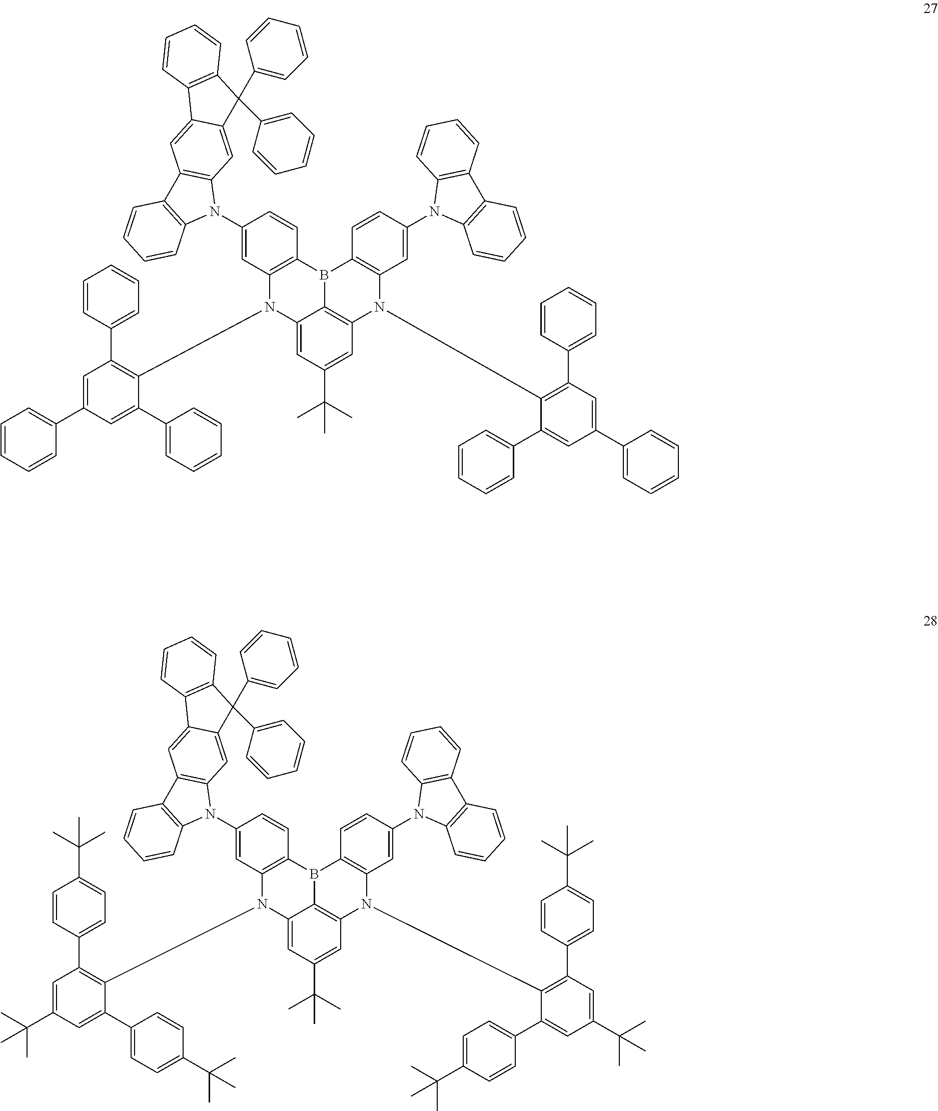 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1ccc(-n3c4ccccc4c4ccccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1]

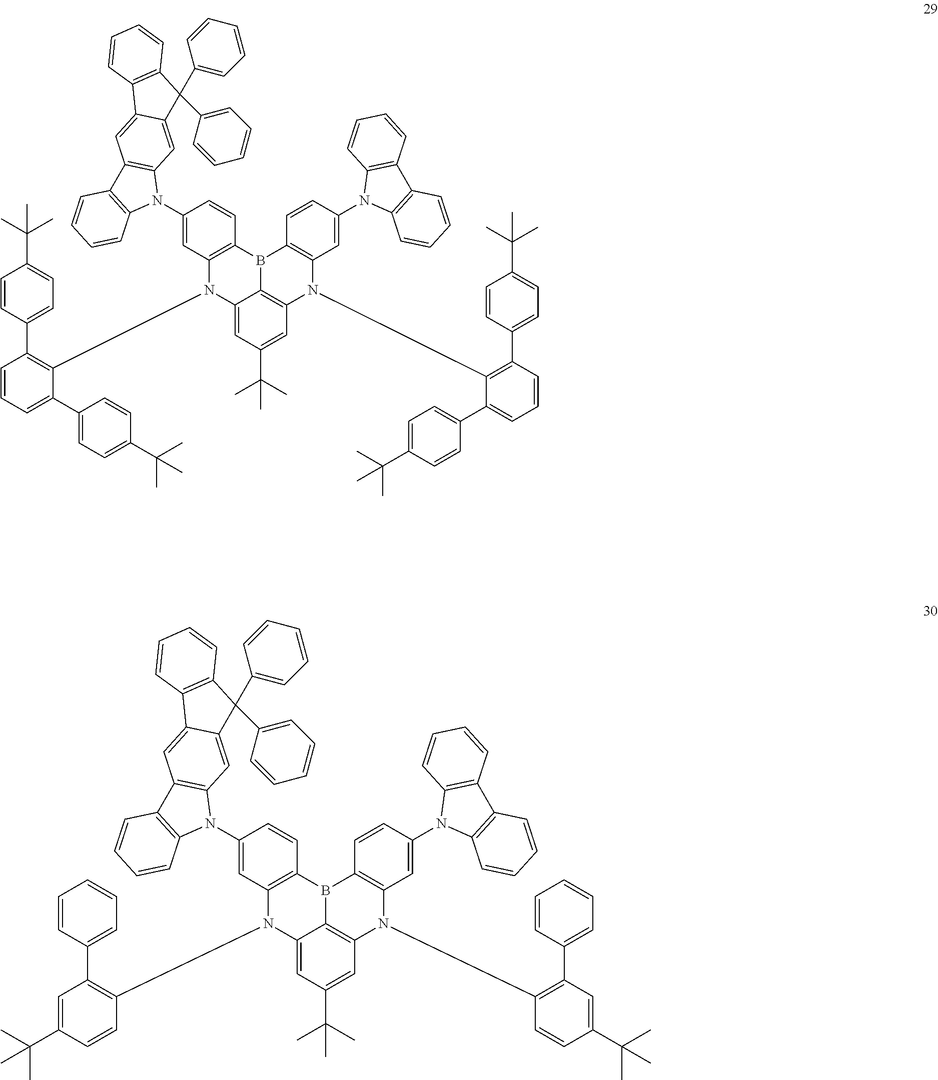

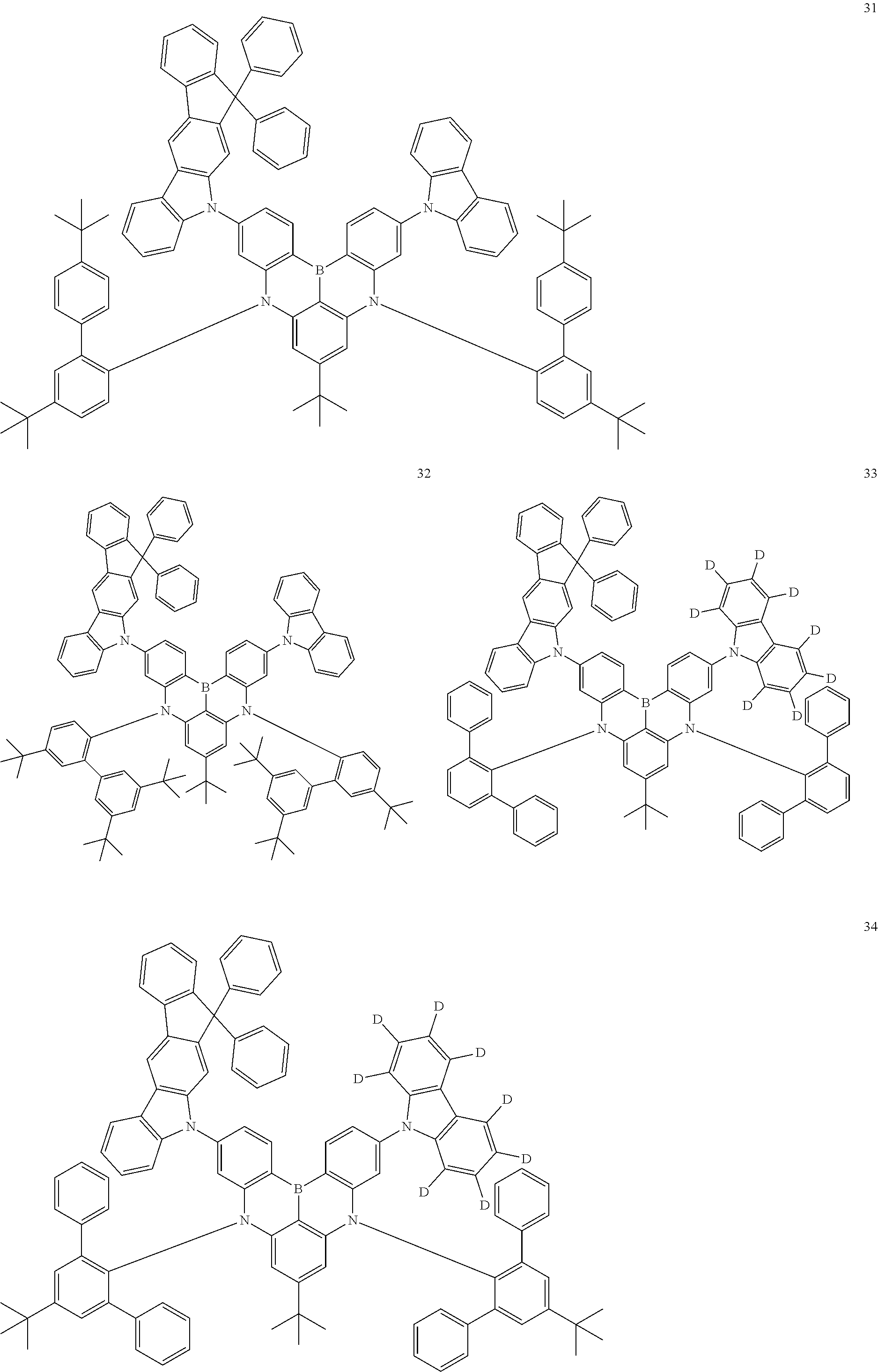

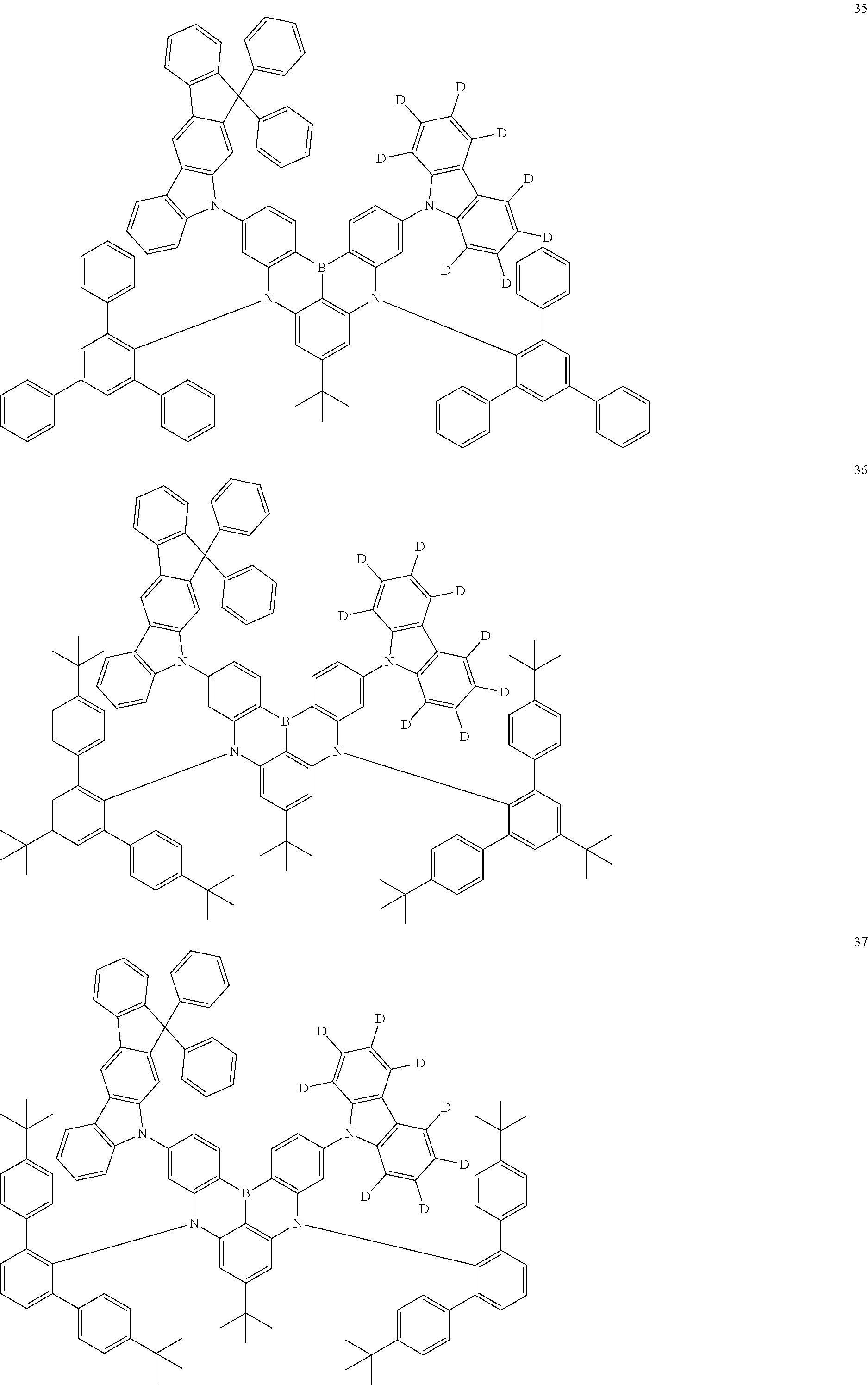

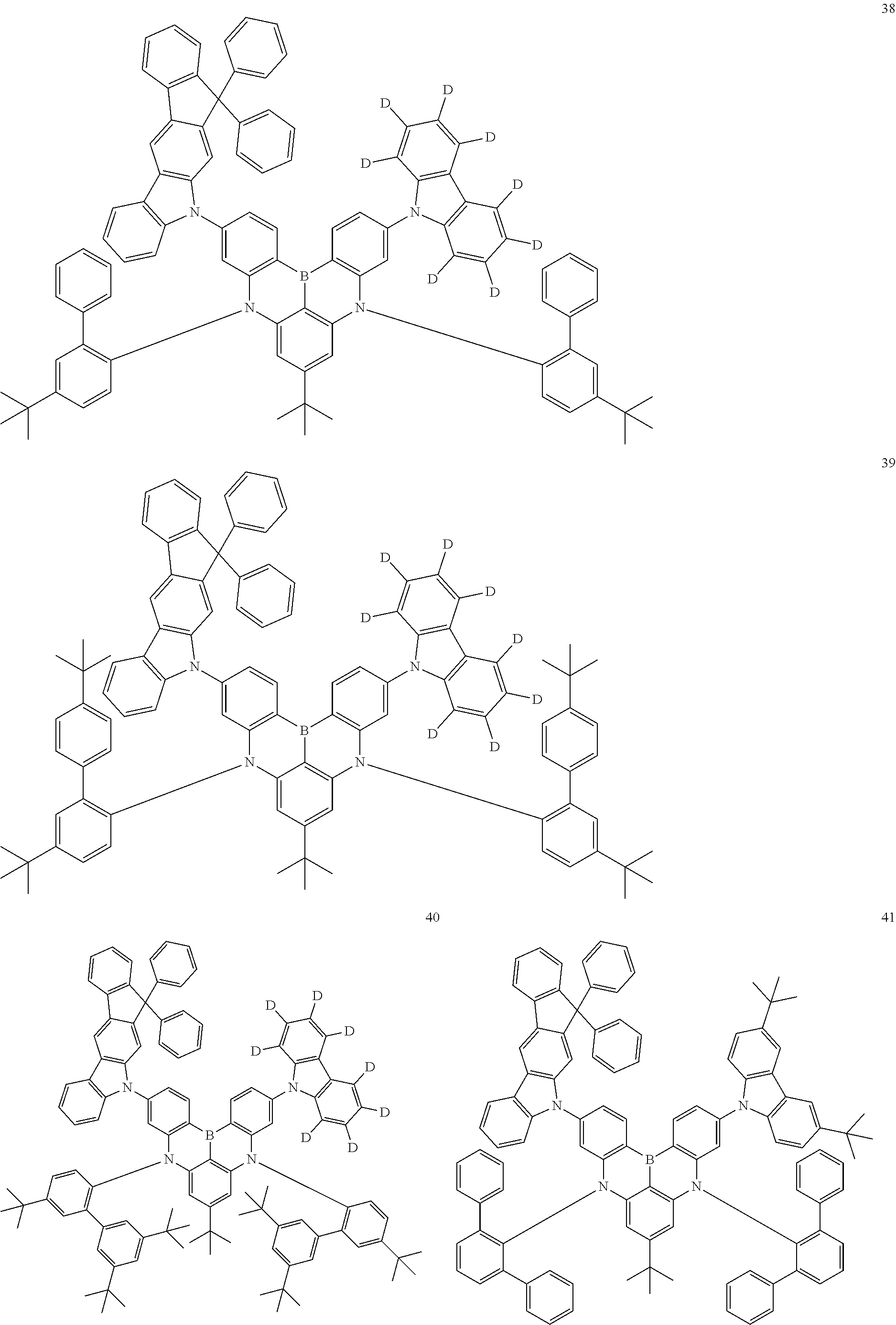

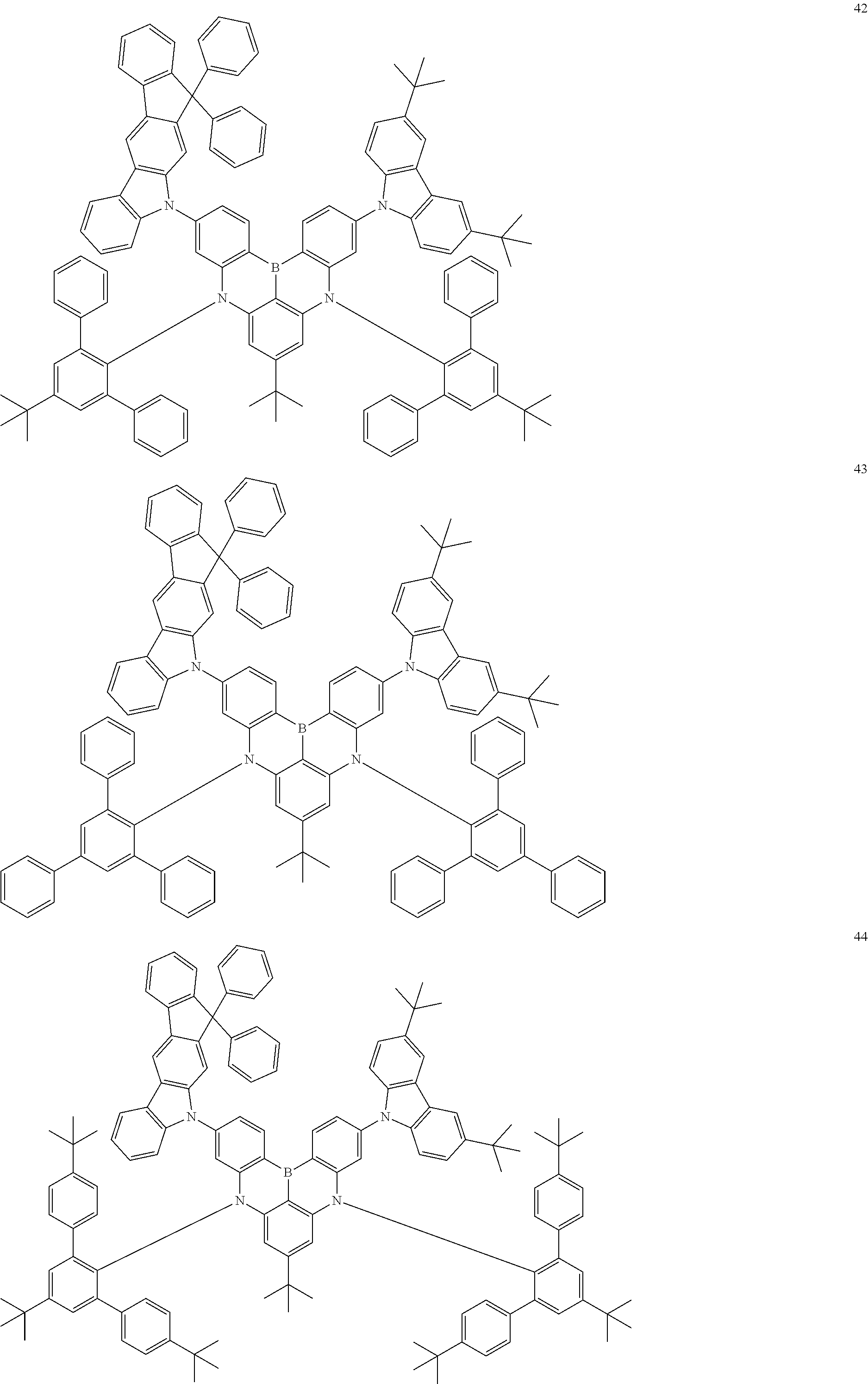

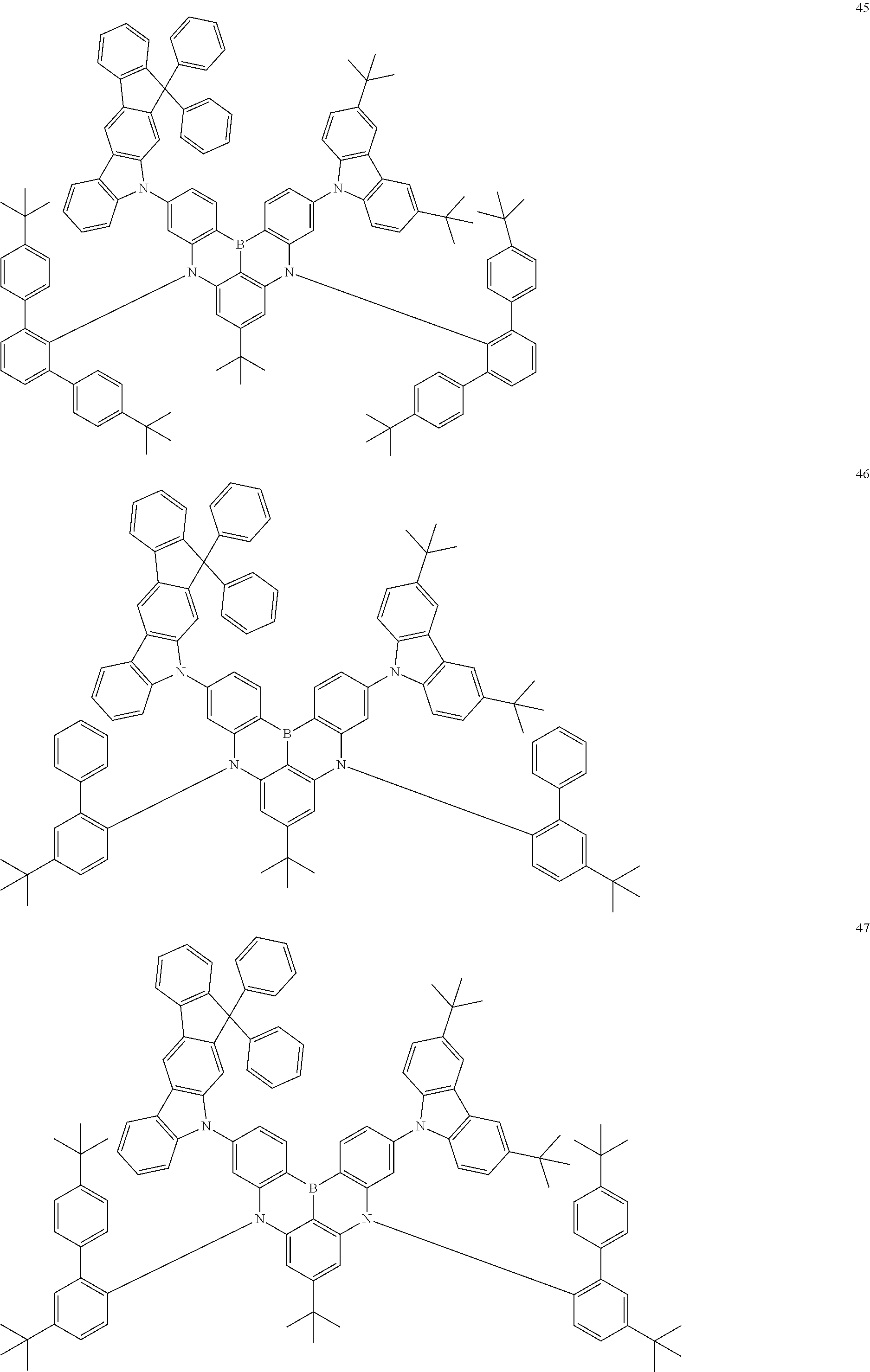

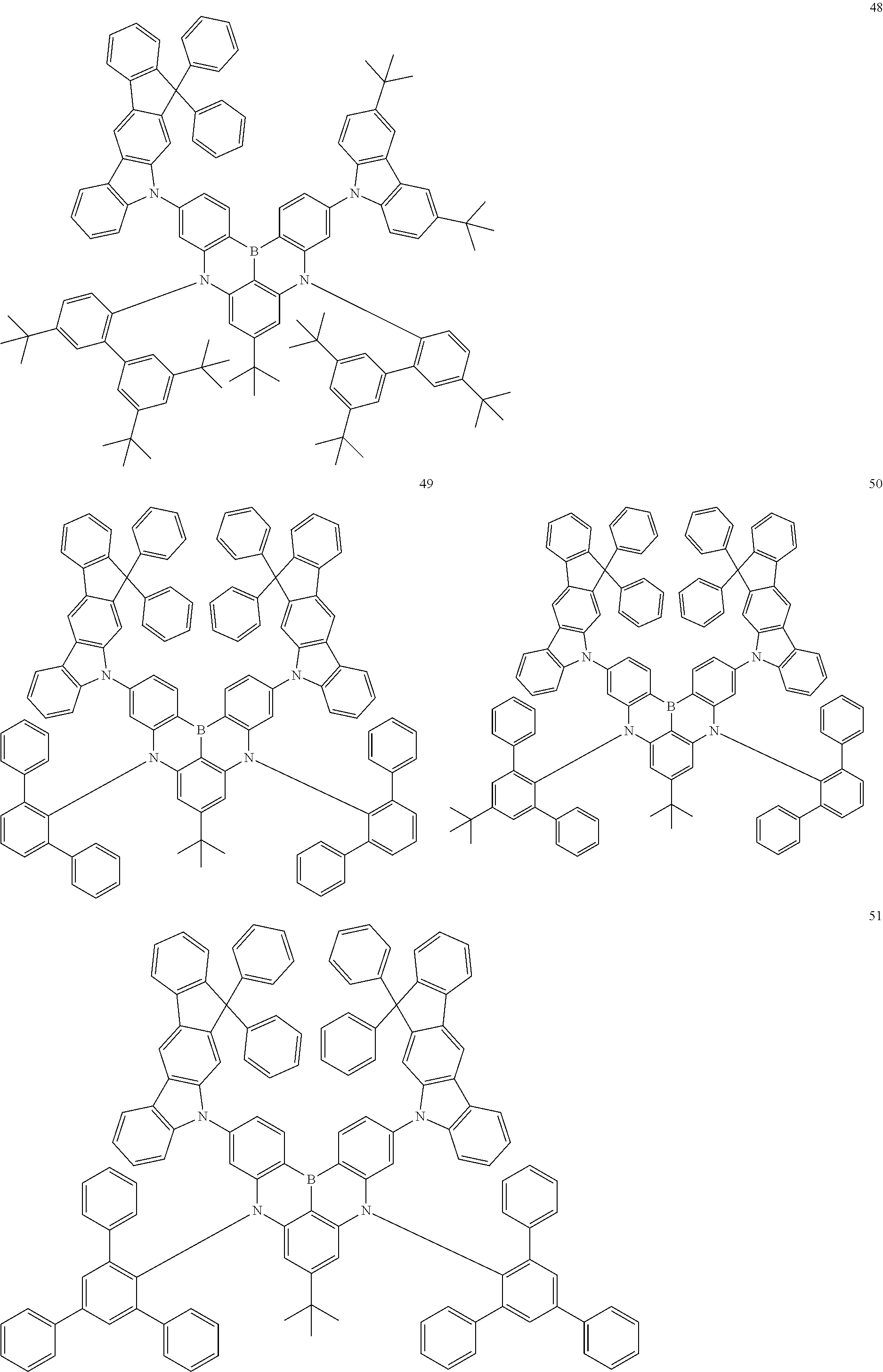

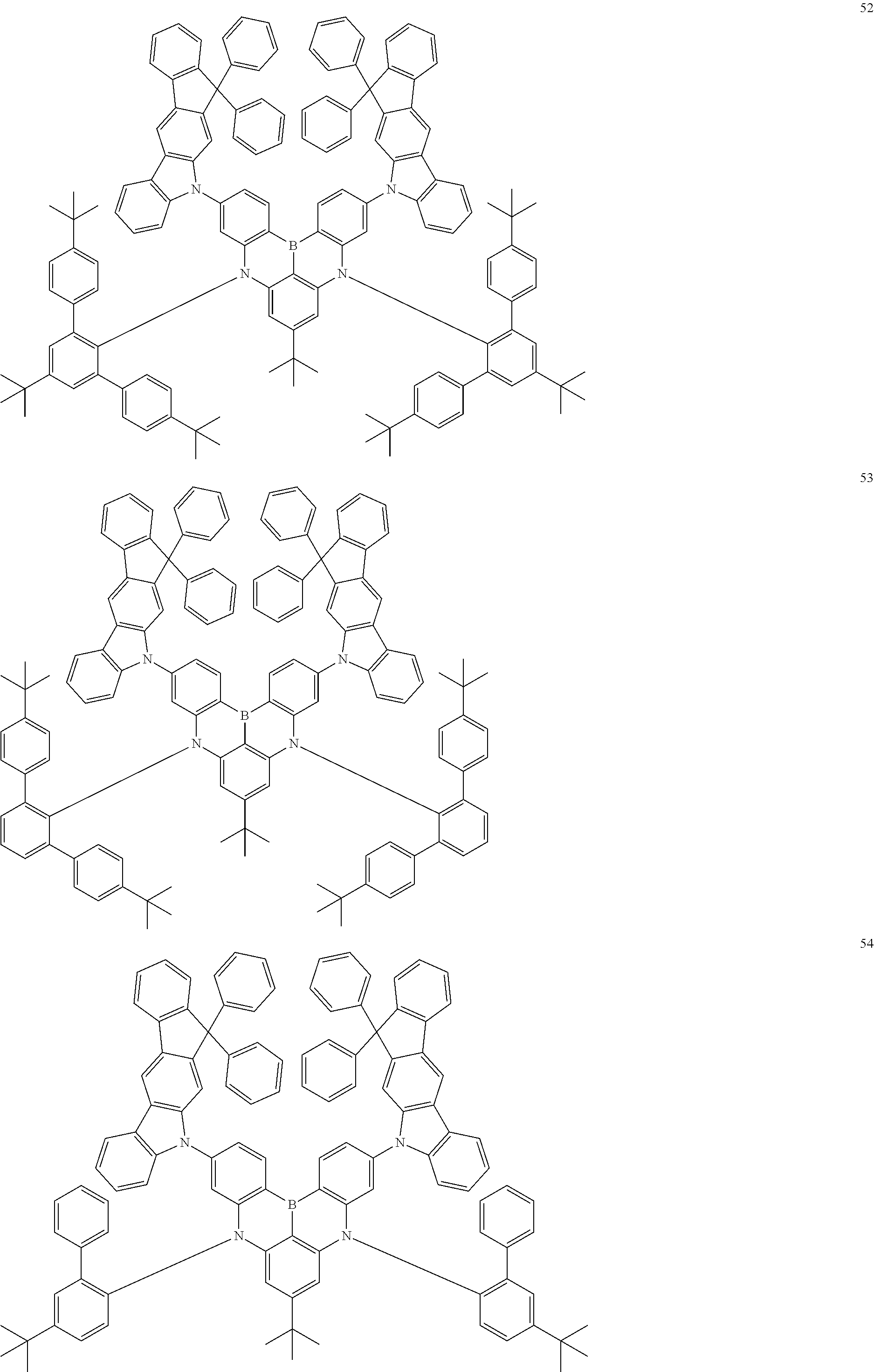

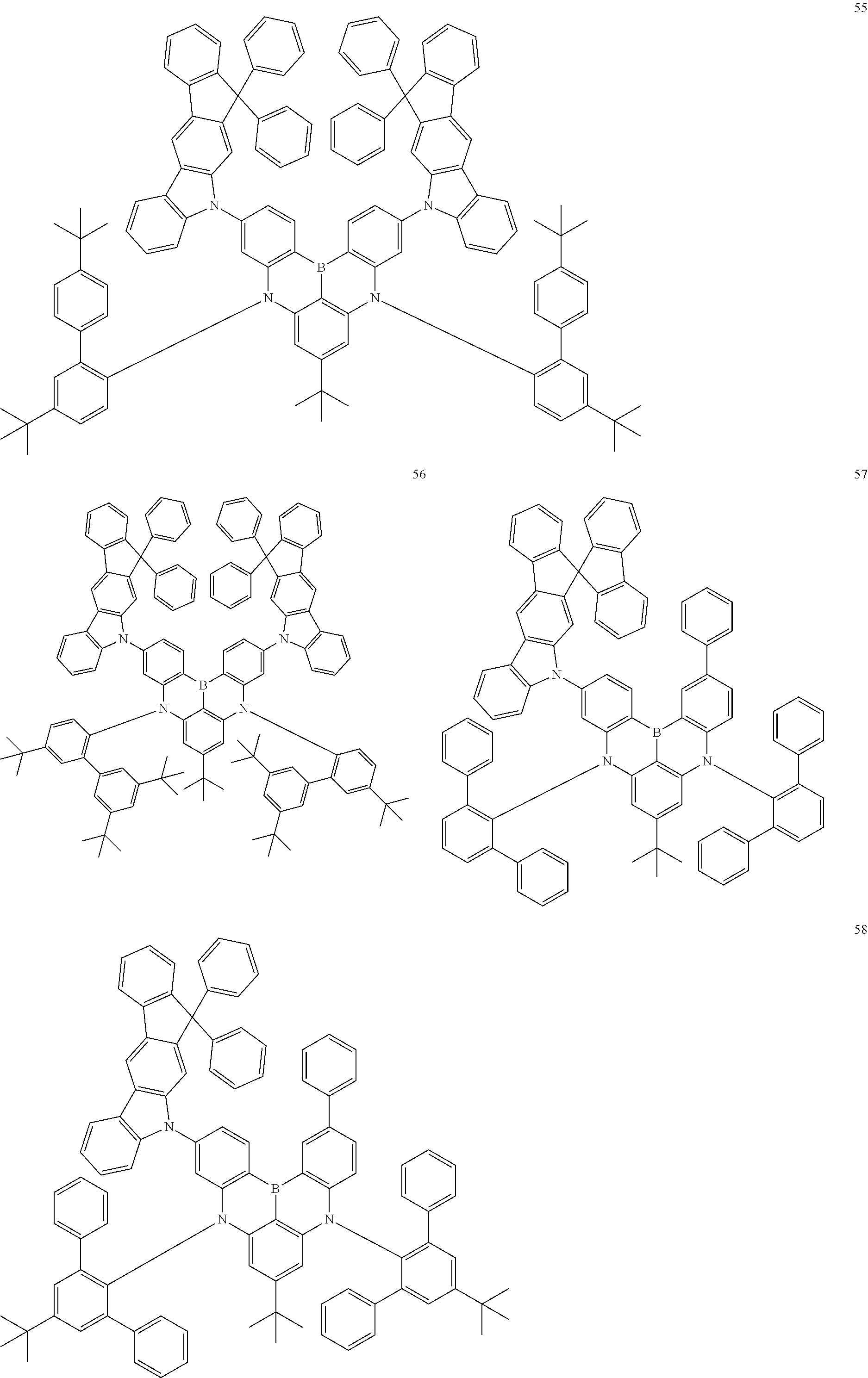

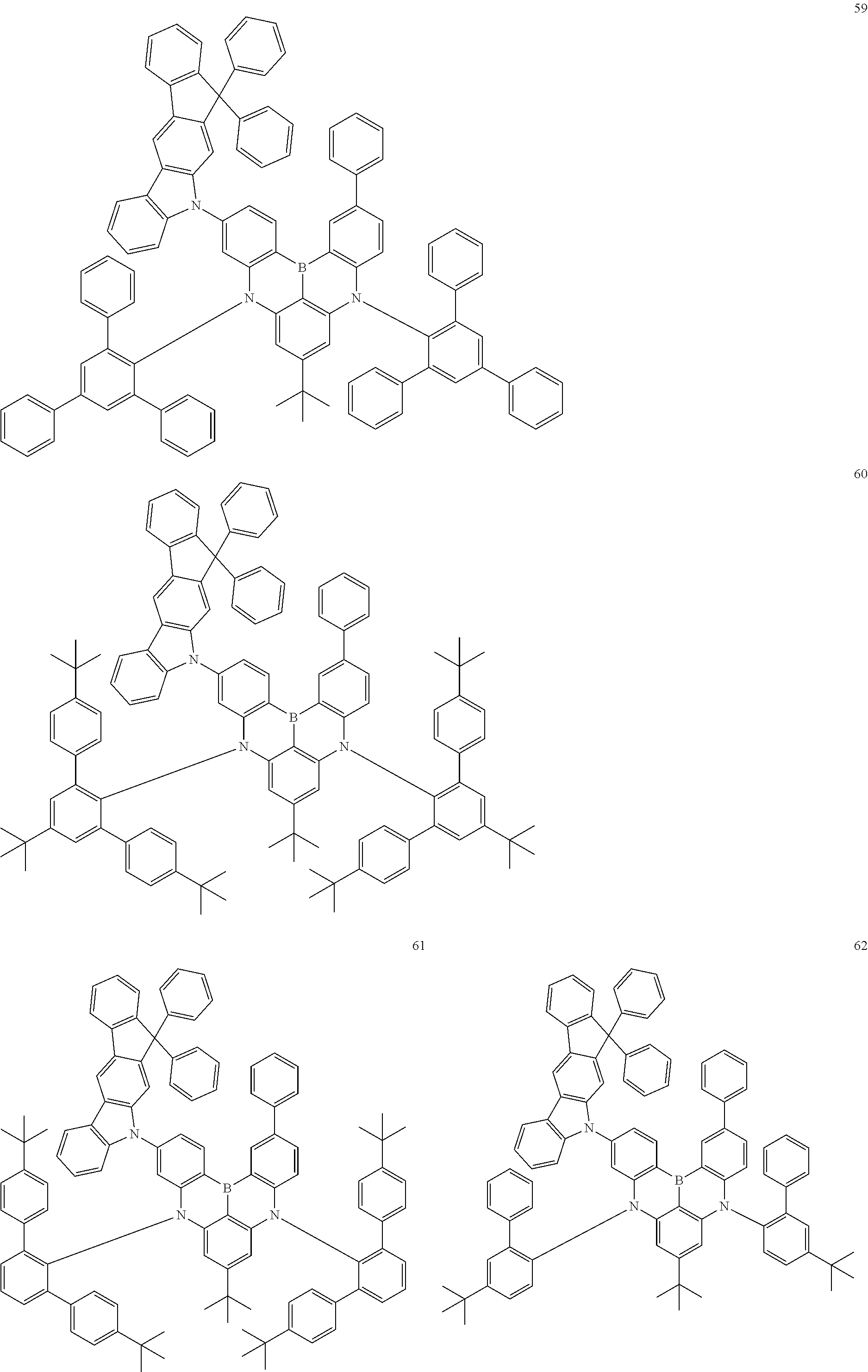

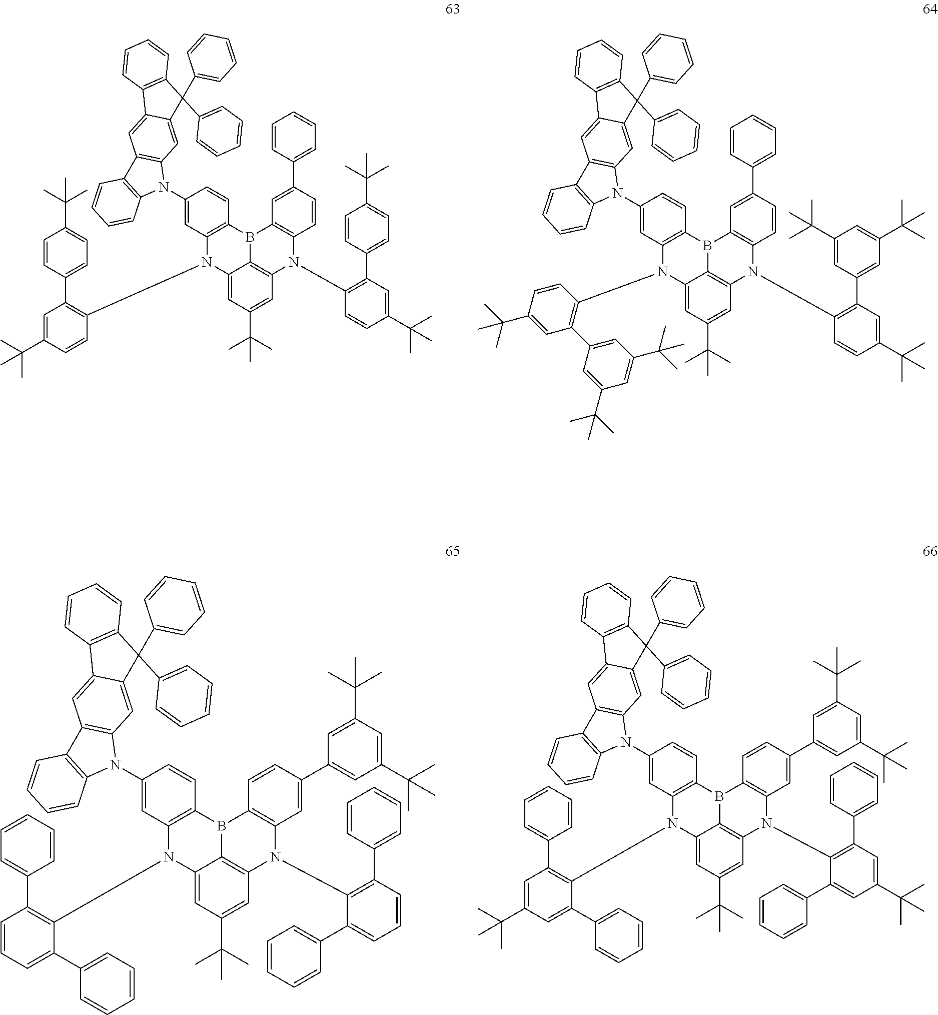

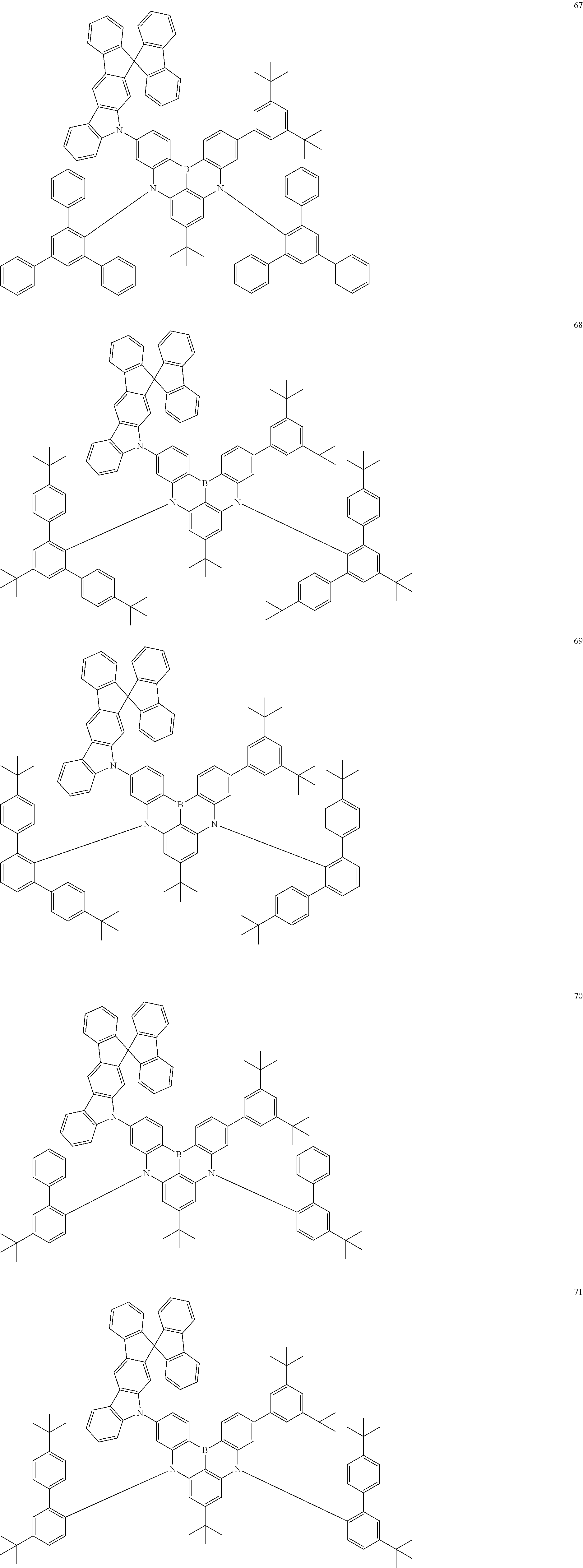

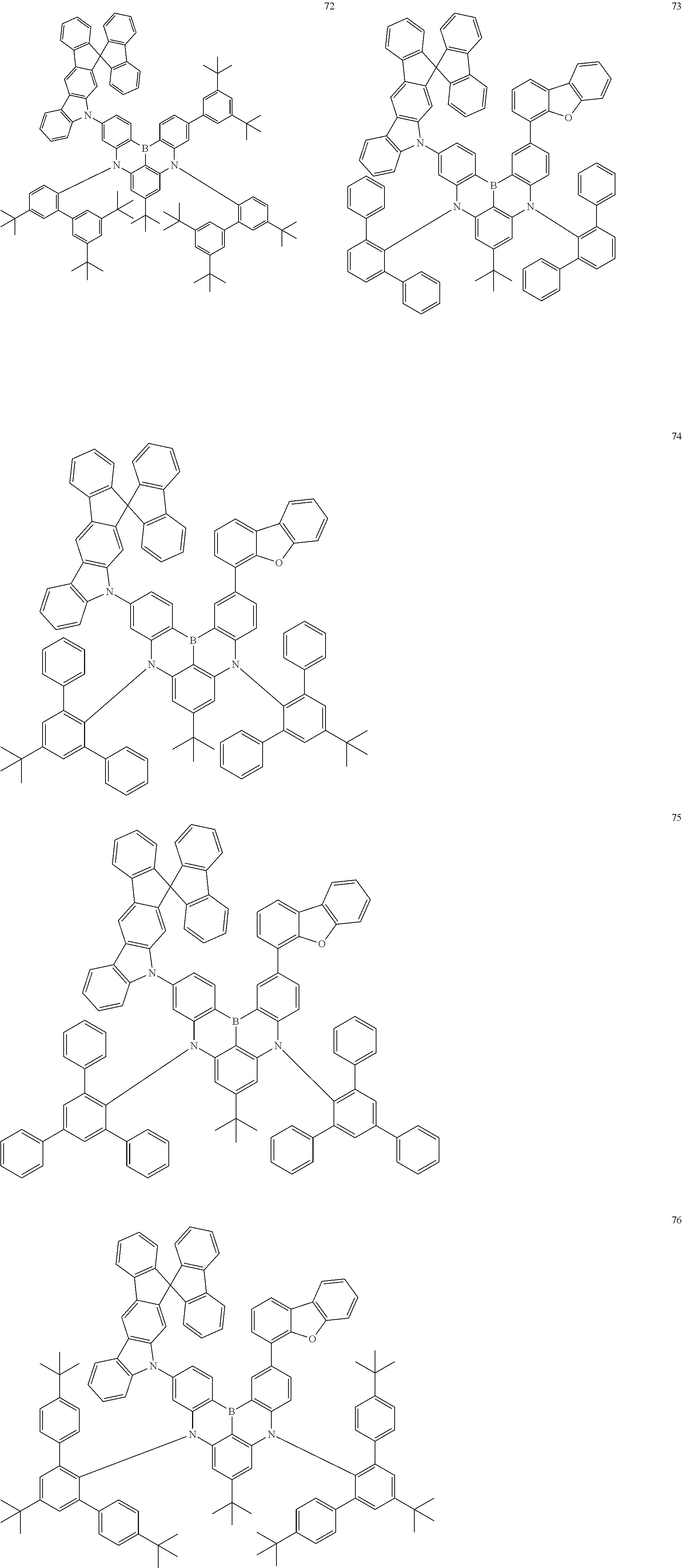

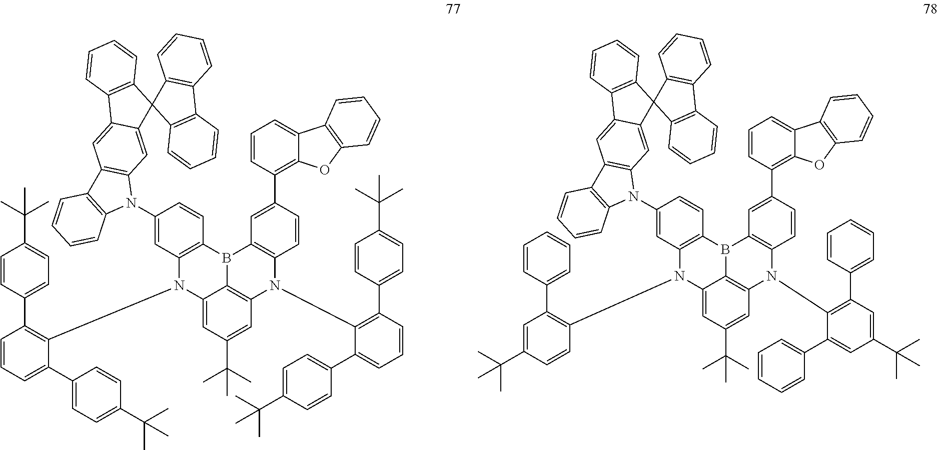 [SMILES: CC(C)(C)c1ccc(-c2cccc(-c3ccc(C(C)(C)C)cc3)c2N2c3ccc(-c4cccc5c4oc4ccccc45)cc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3cc(-n4c5ccccc5c5cc6c(cc54)C4(c5ccccc5-c5ccccc54)c4ccccc4-6)ccc3B3c4cc(-c5cccc6c5oc5ccccc56)ccc4N(c4c(-c5ccccc5)cc(C(C)(C)C)cc4-c4ccccc4)c4cc(C(C)(C)C)cc2c43)c(-c2ccccc2)c1]

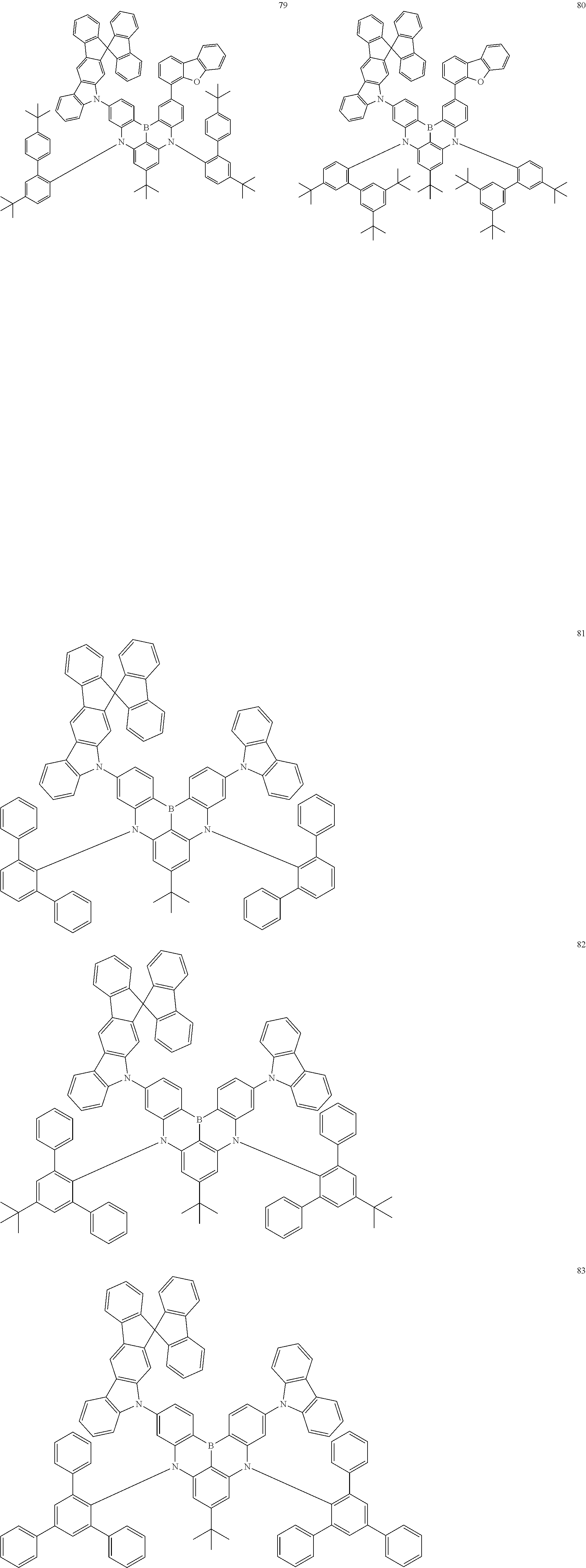

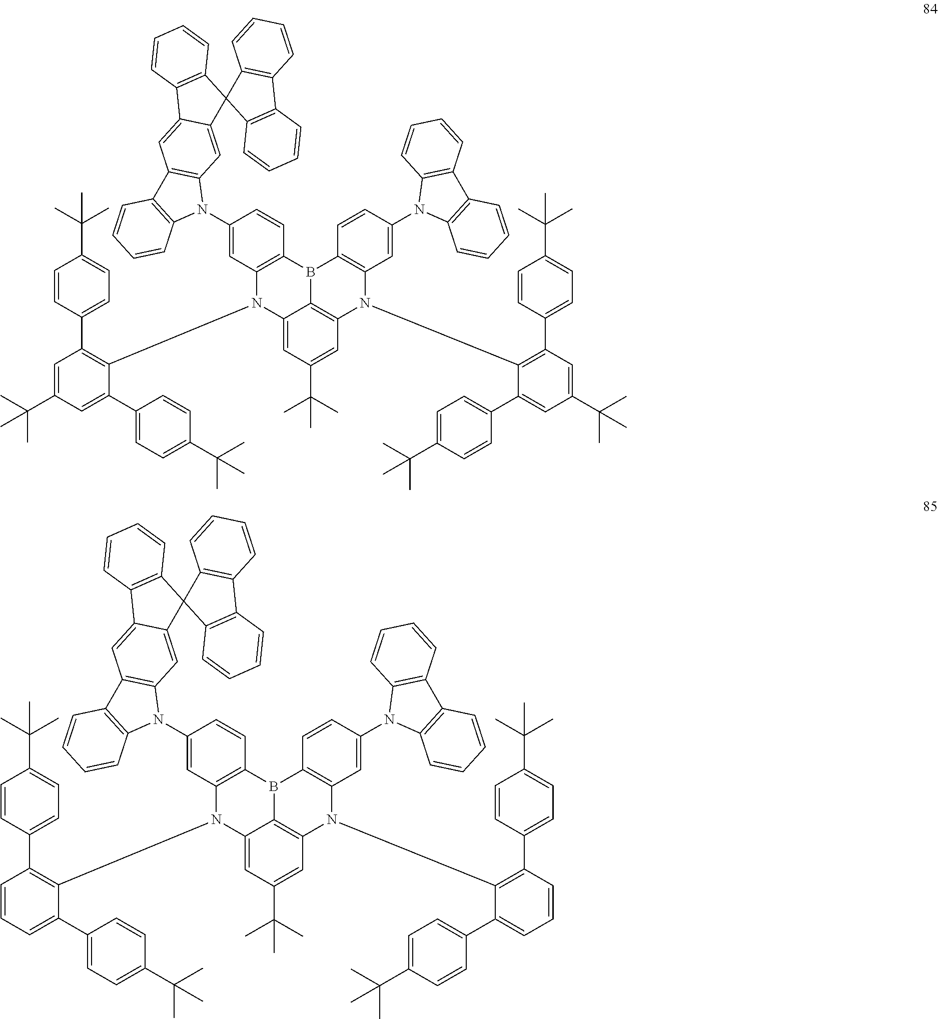

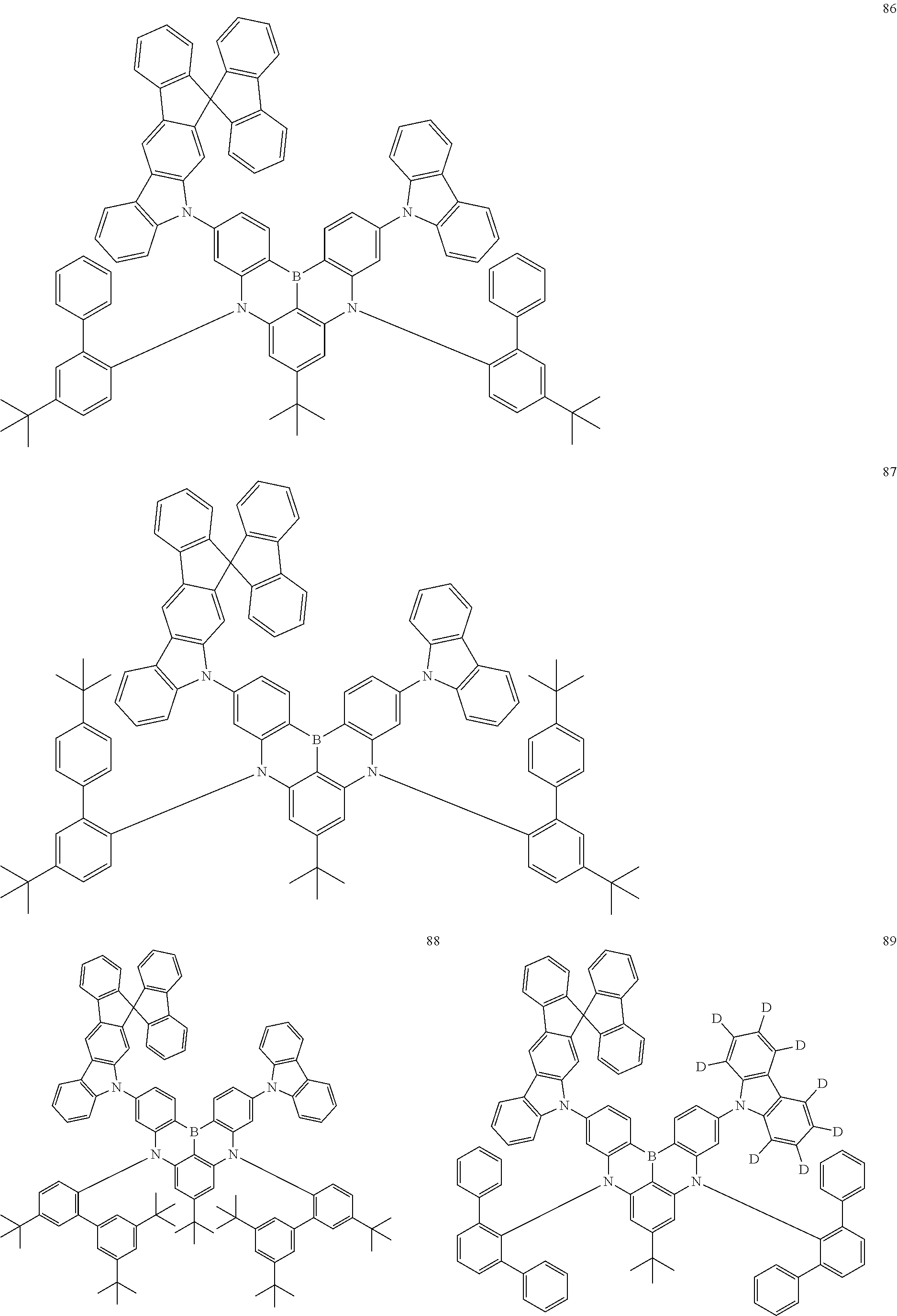

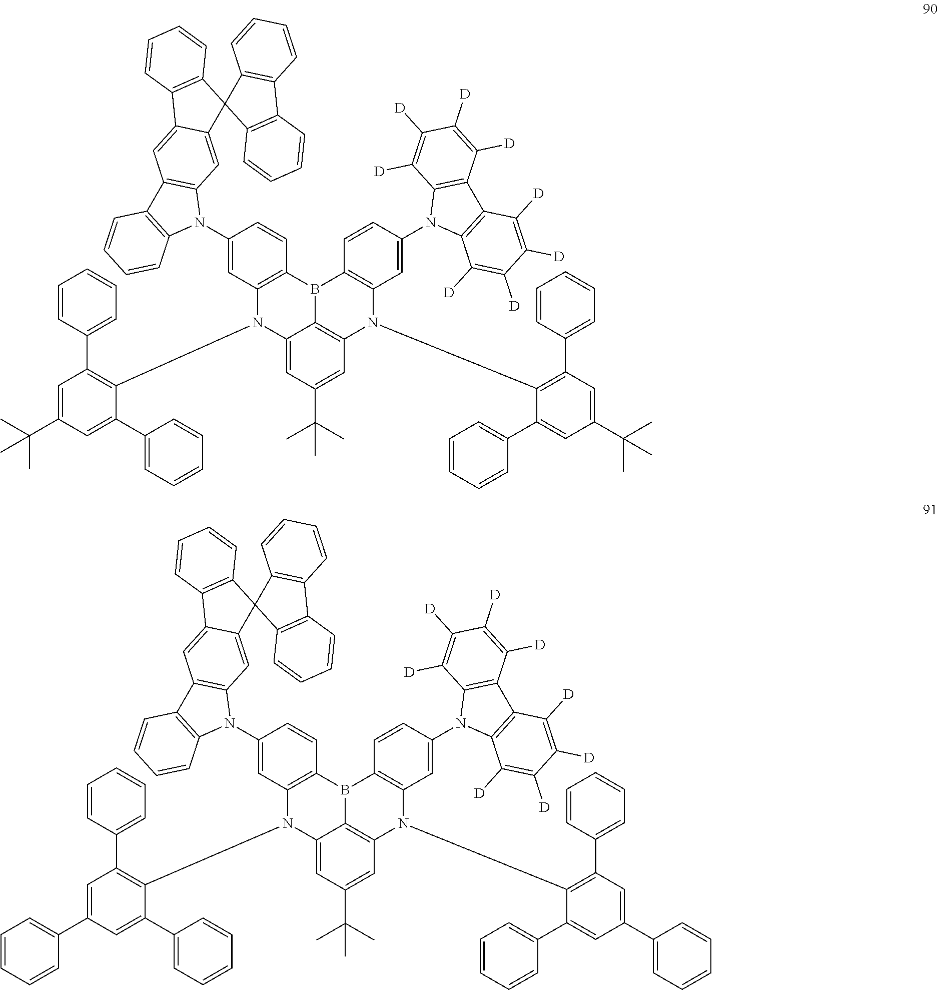 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4cc5c(cc42)C2(c4ccccc4-c4ccccc42)c2ccccc2-5)cc1N3c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-n2c4ccccc4c4cc5c(cc42)C2(c4ccccc4-c4ccccc42)c2ccccc2-5)cc1N3c1c(-c2ccccc2)cc(-c2ccccc2)cc1-c1ccccc1]

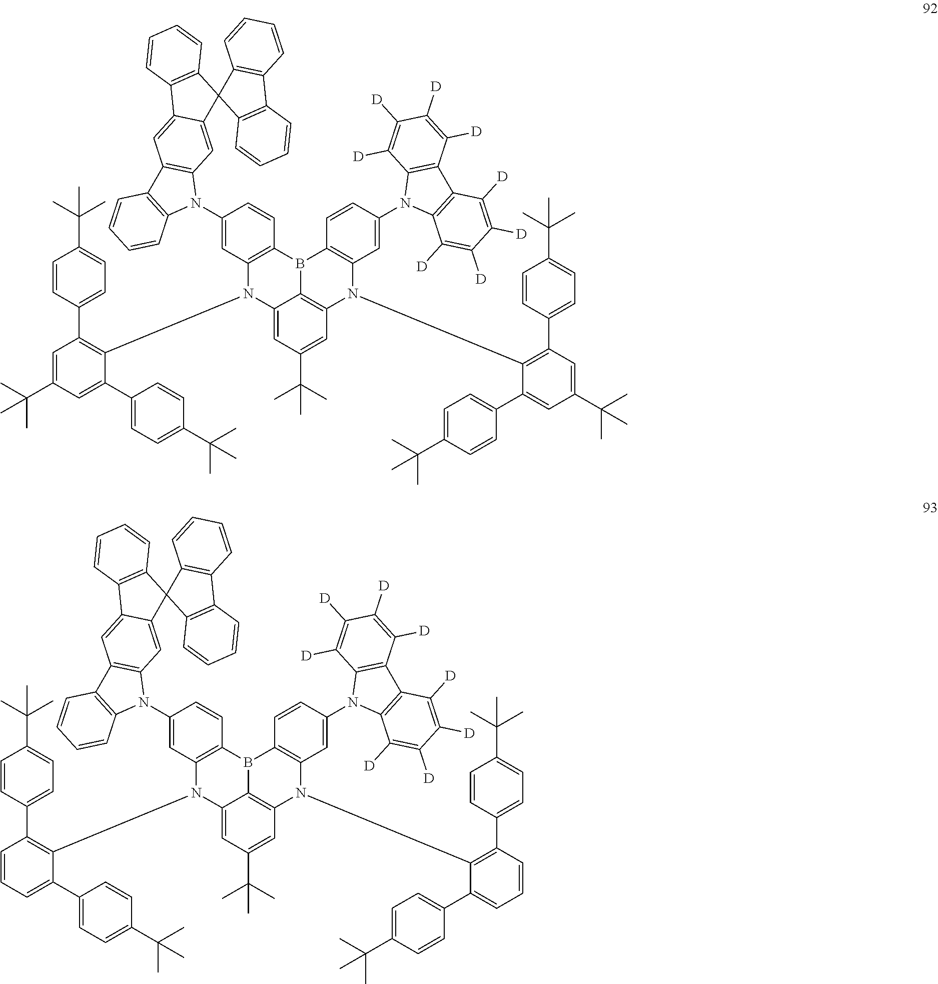

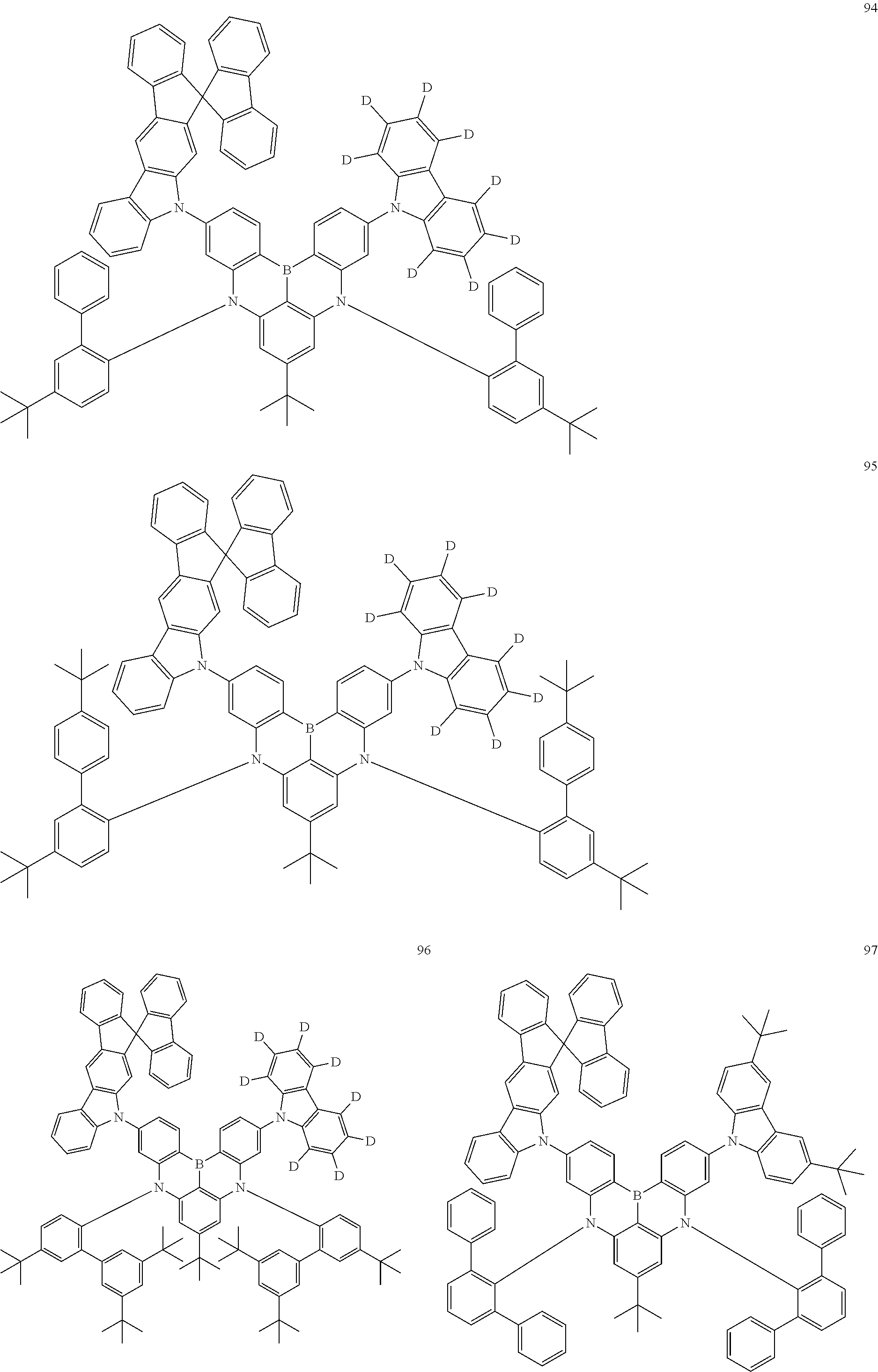

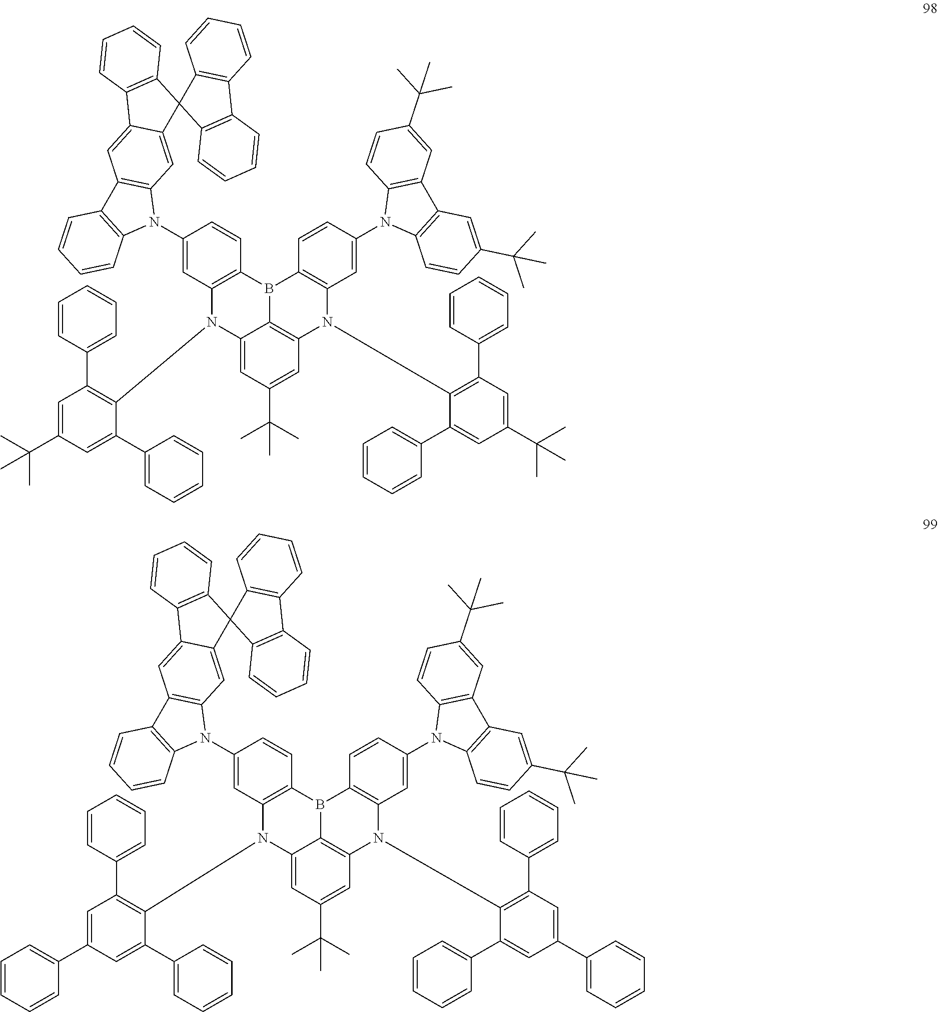

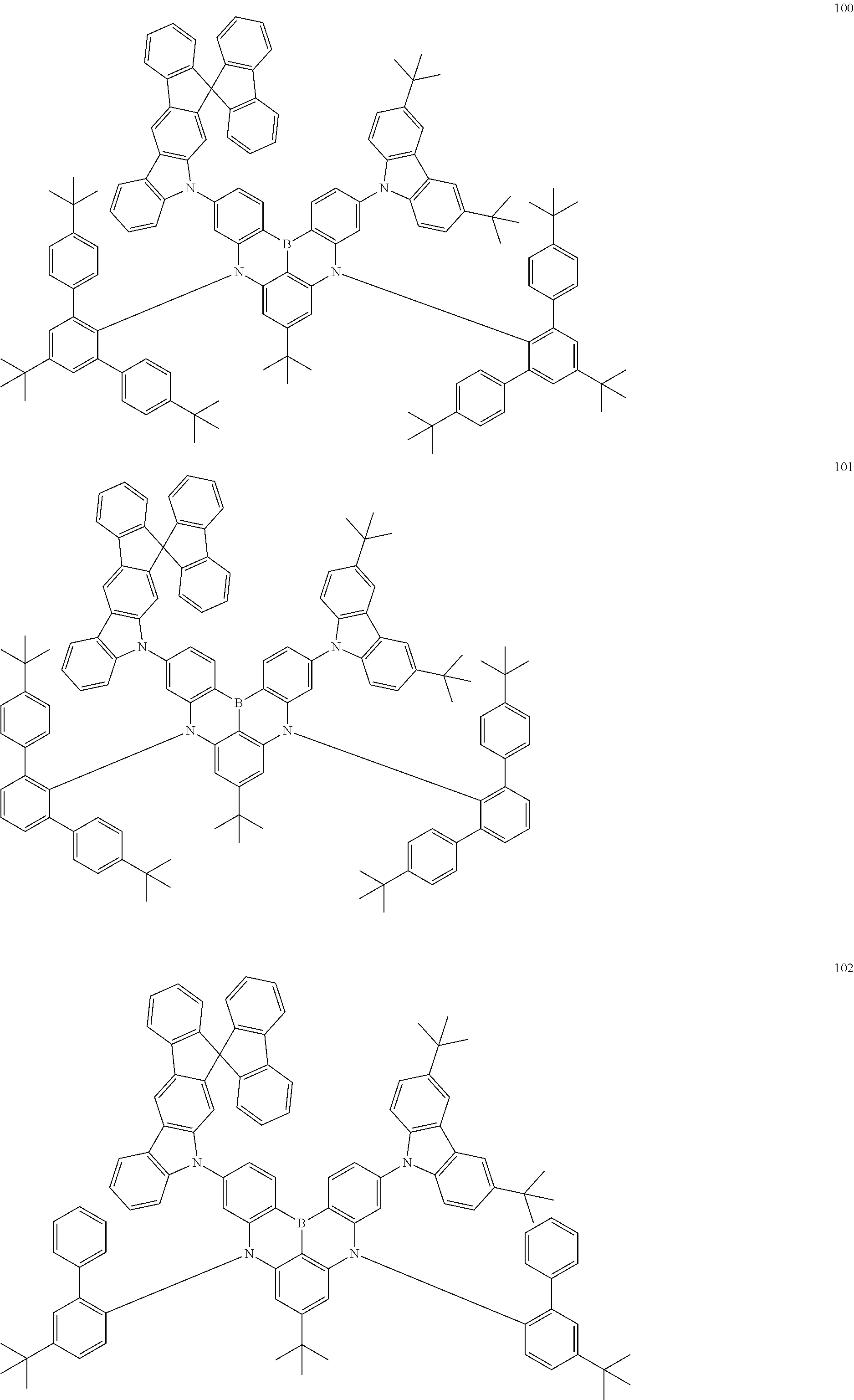

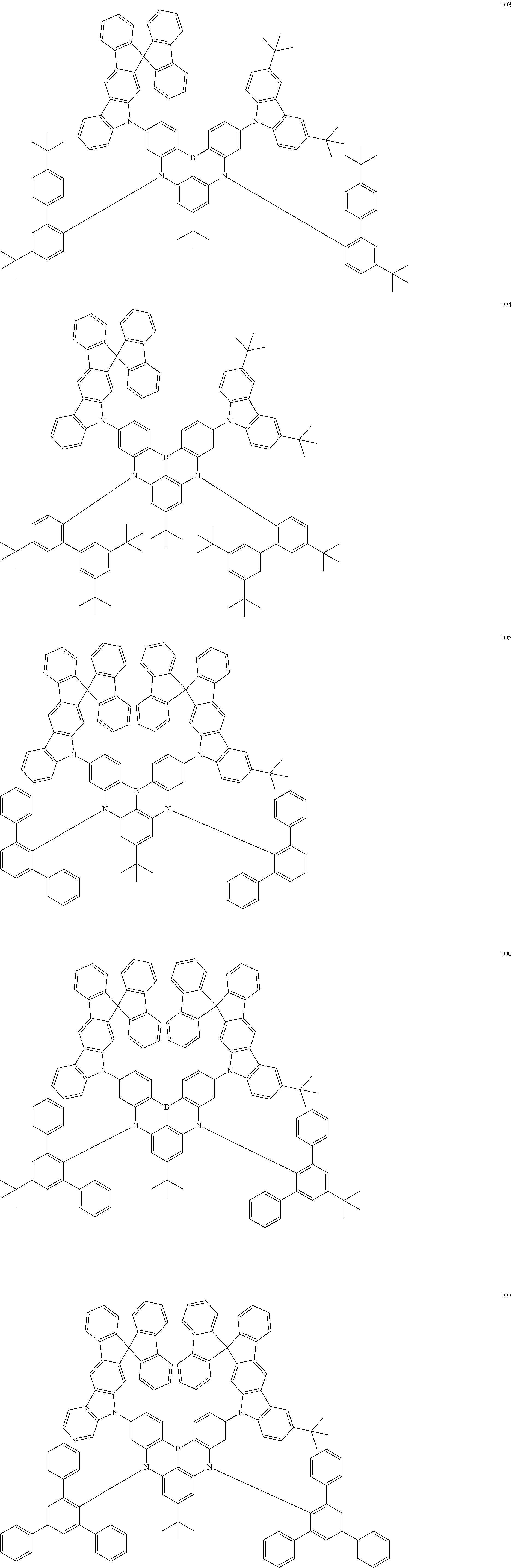

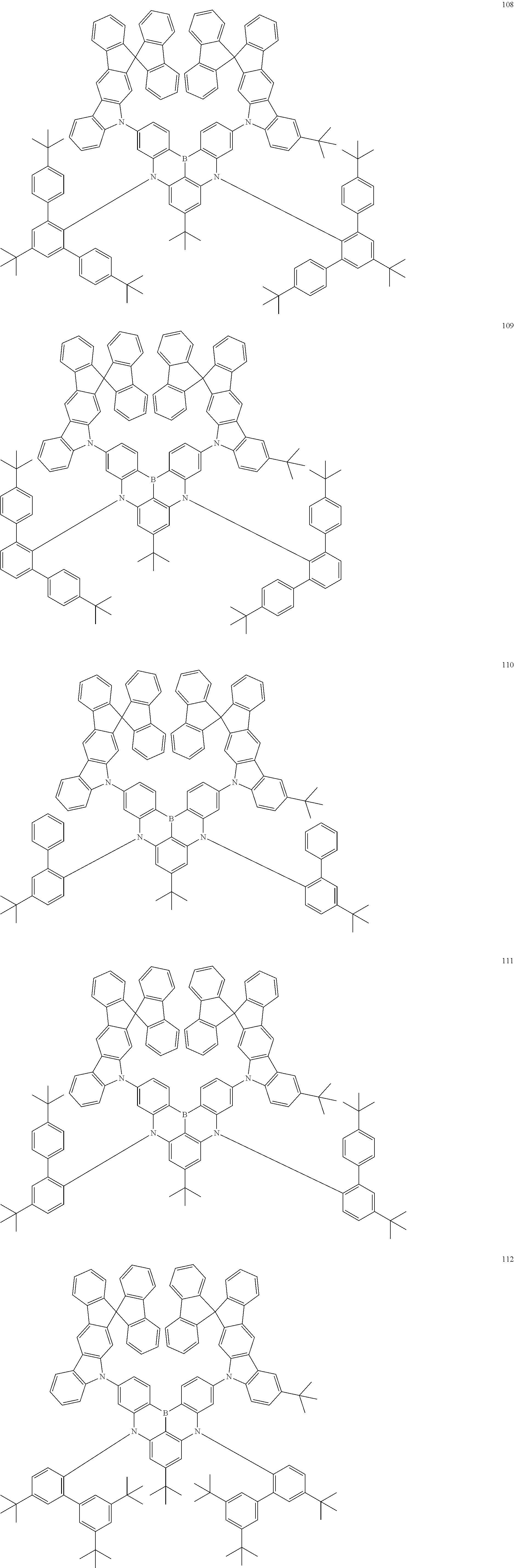

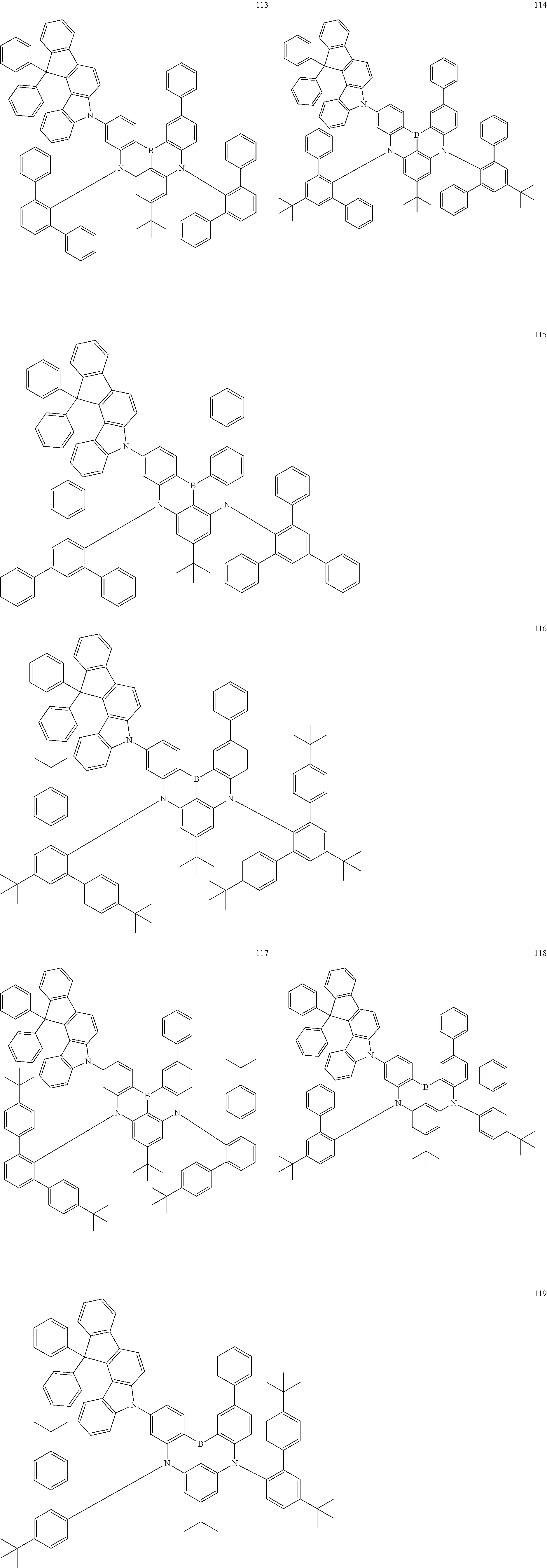

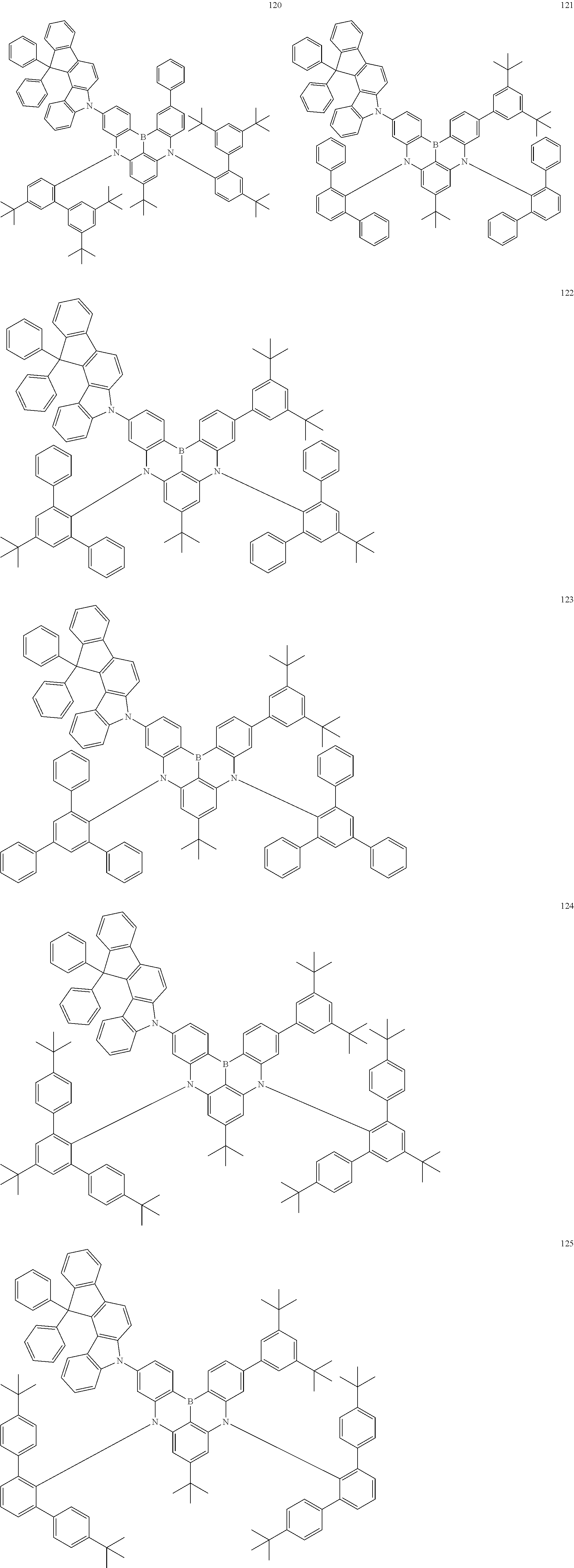

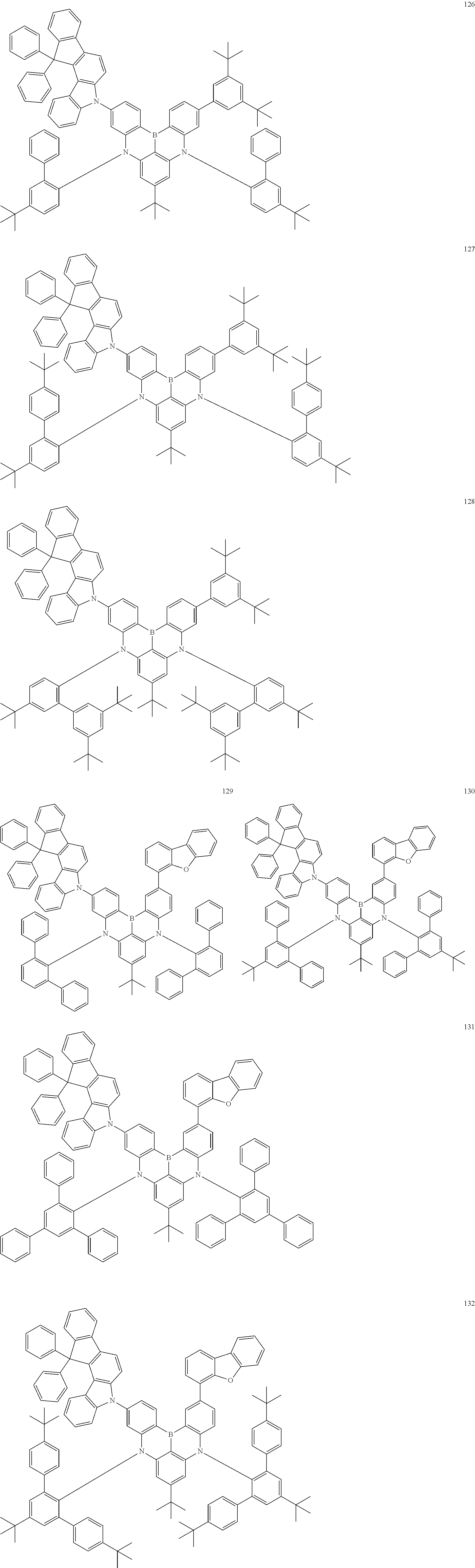

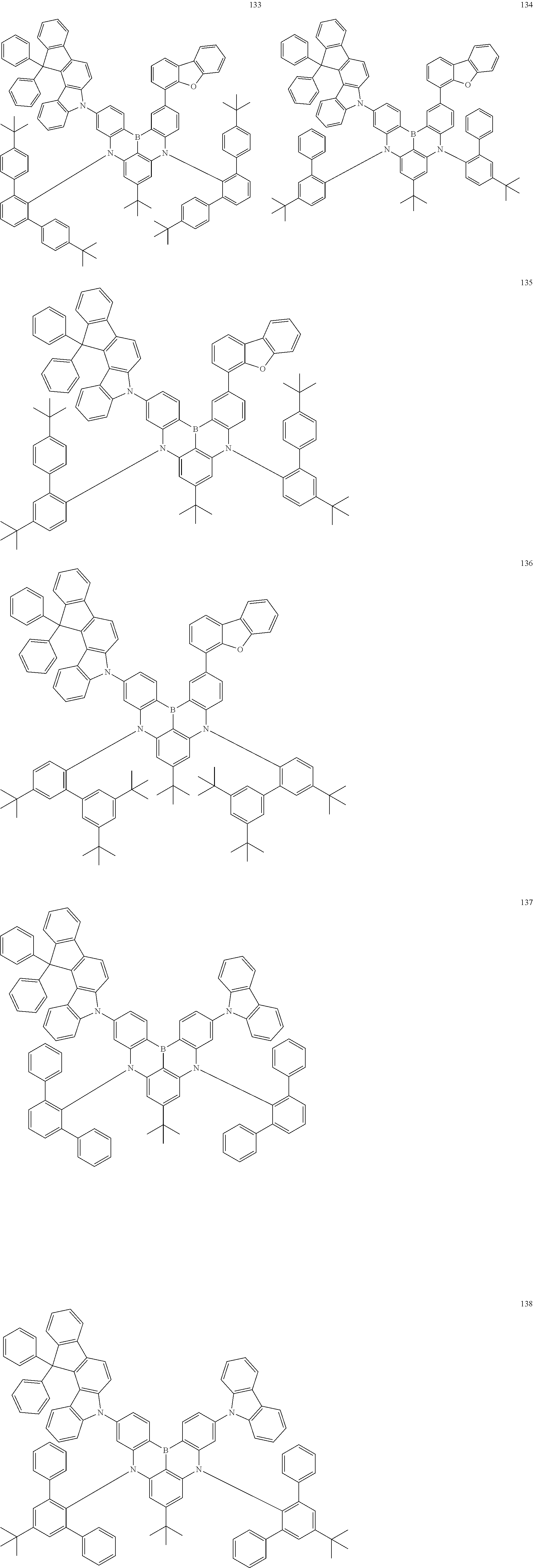

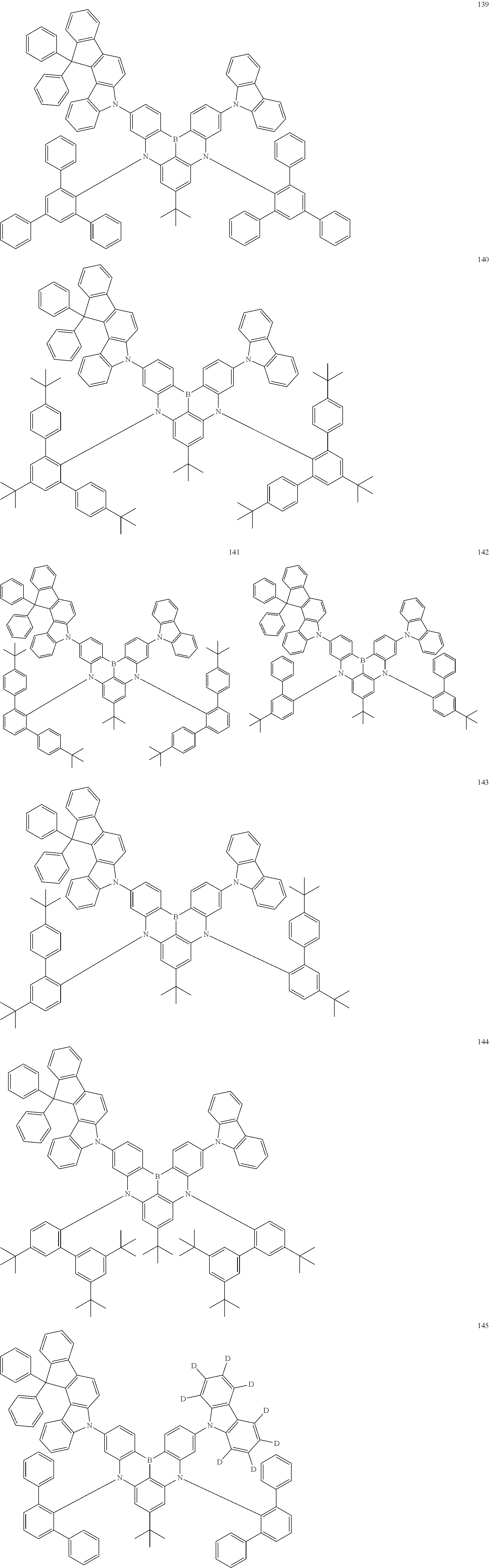

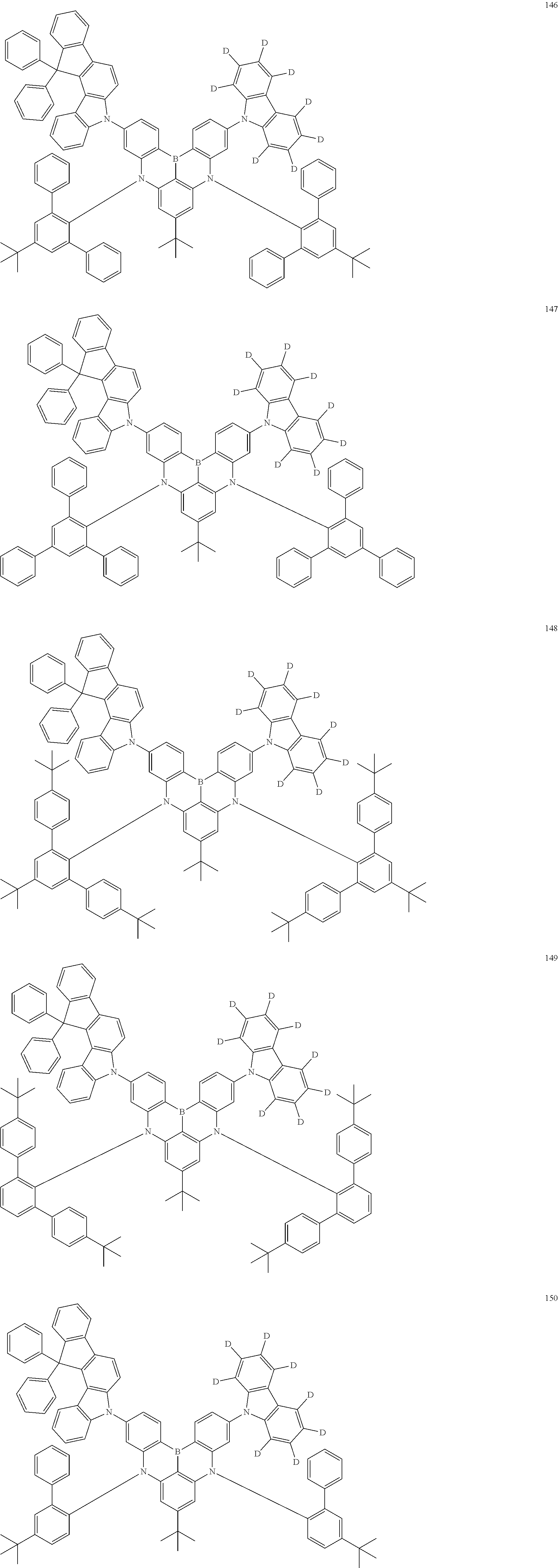

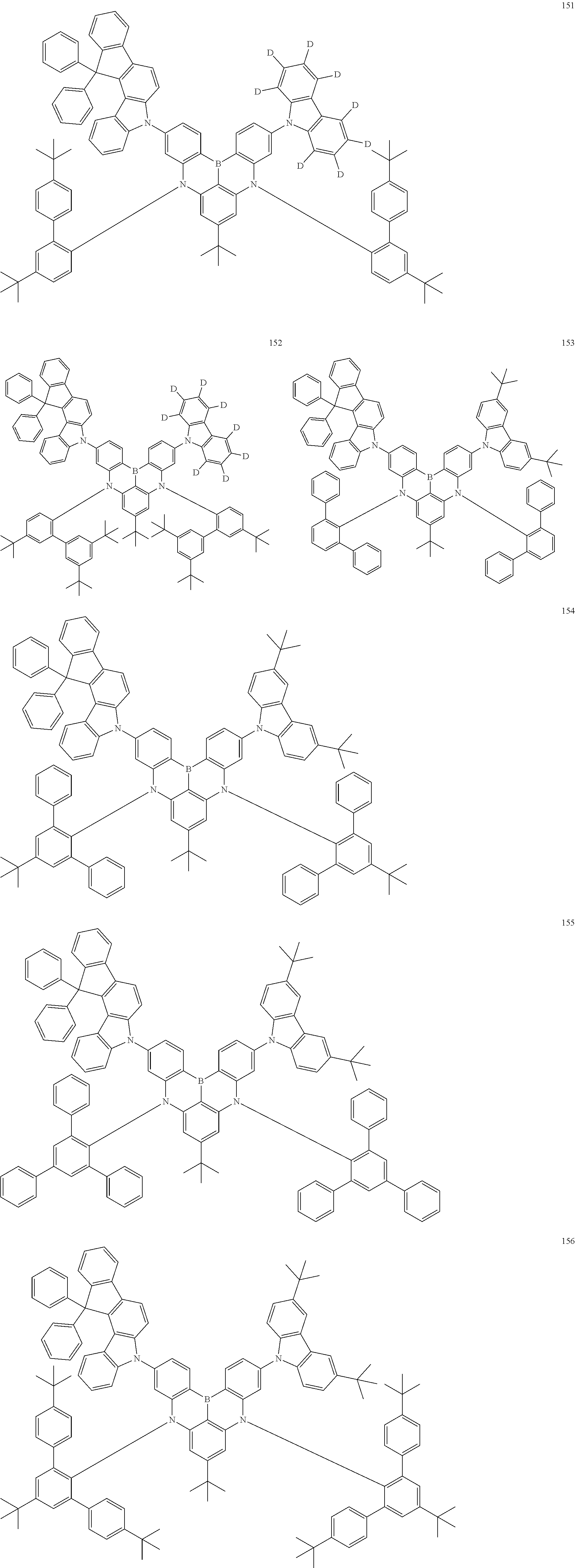

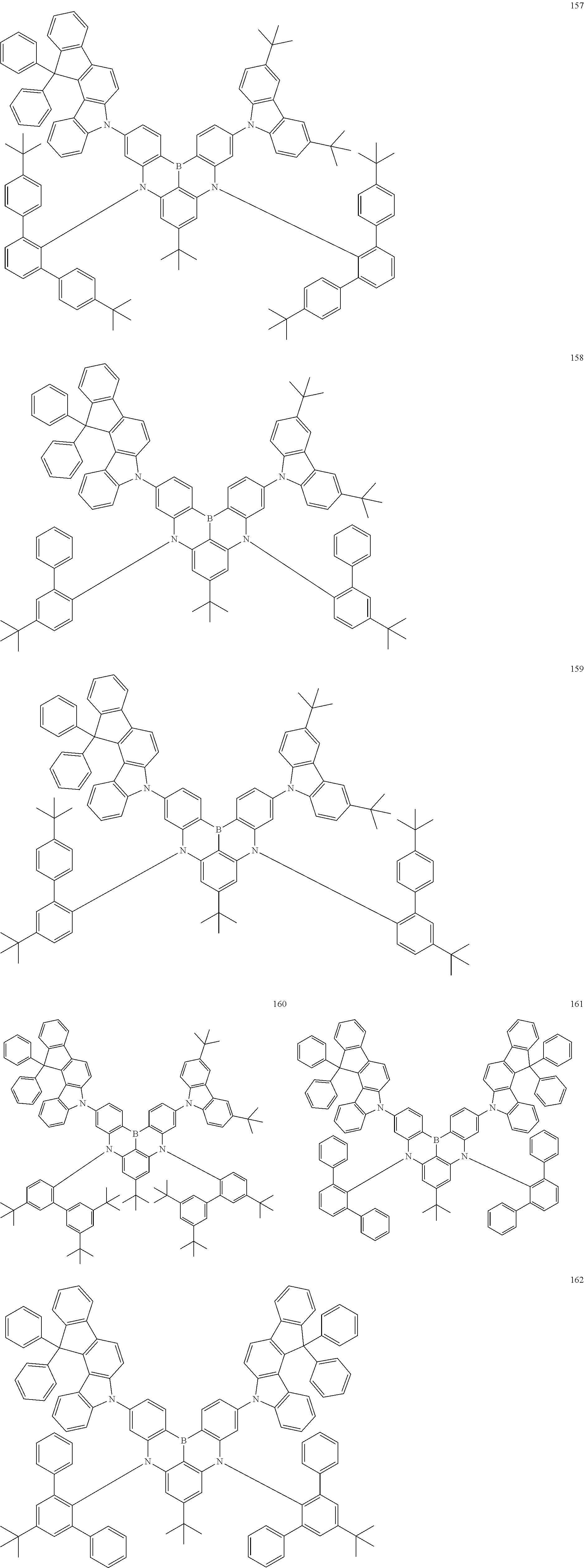

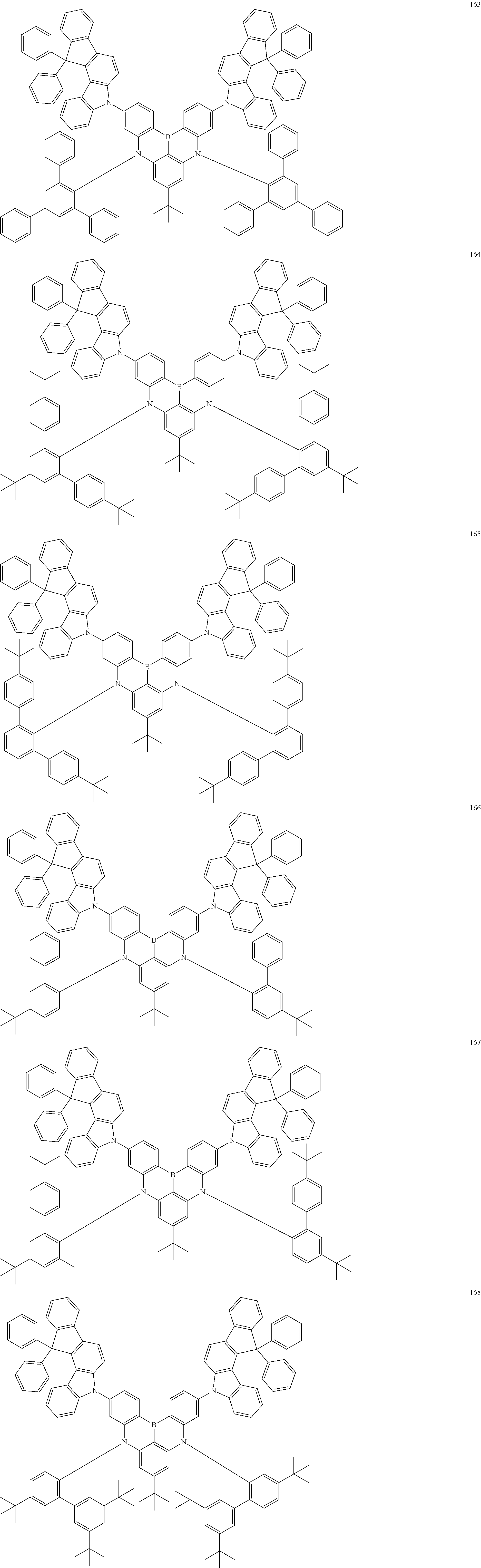

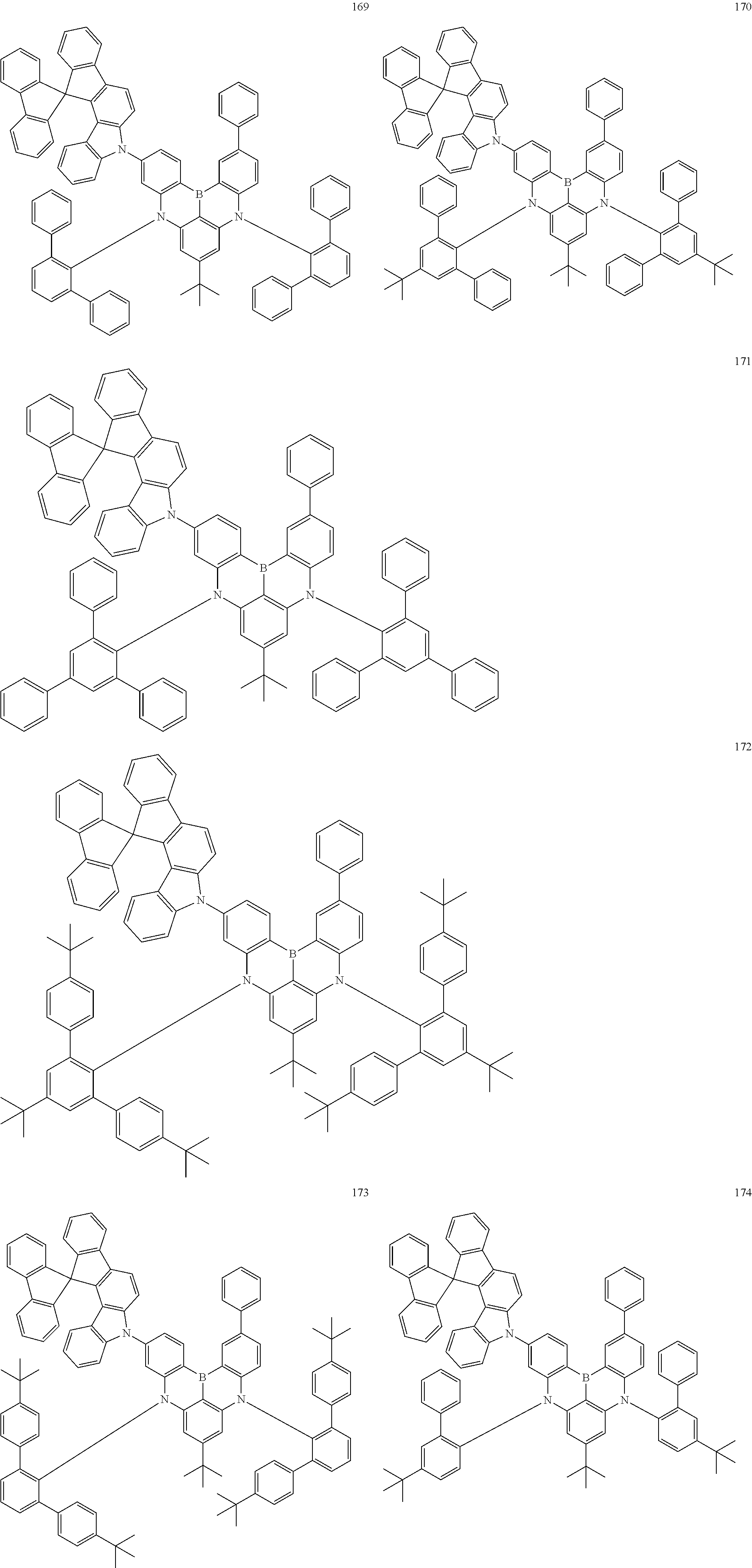

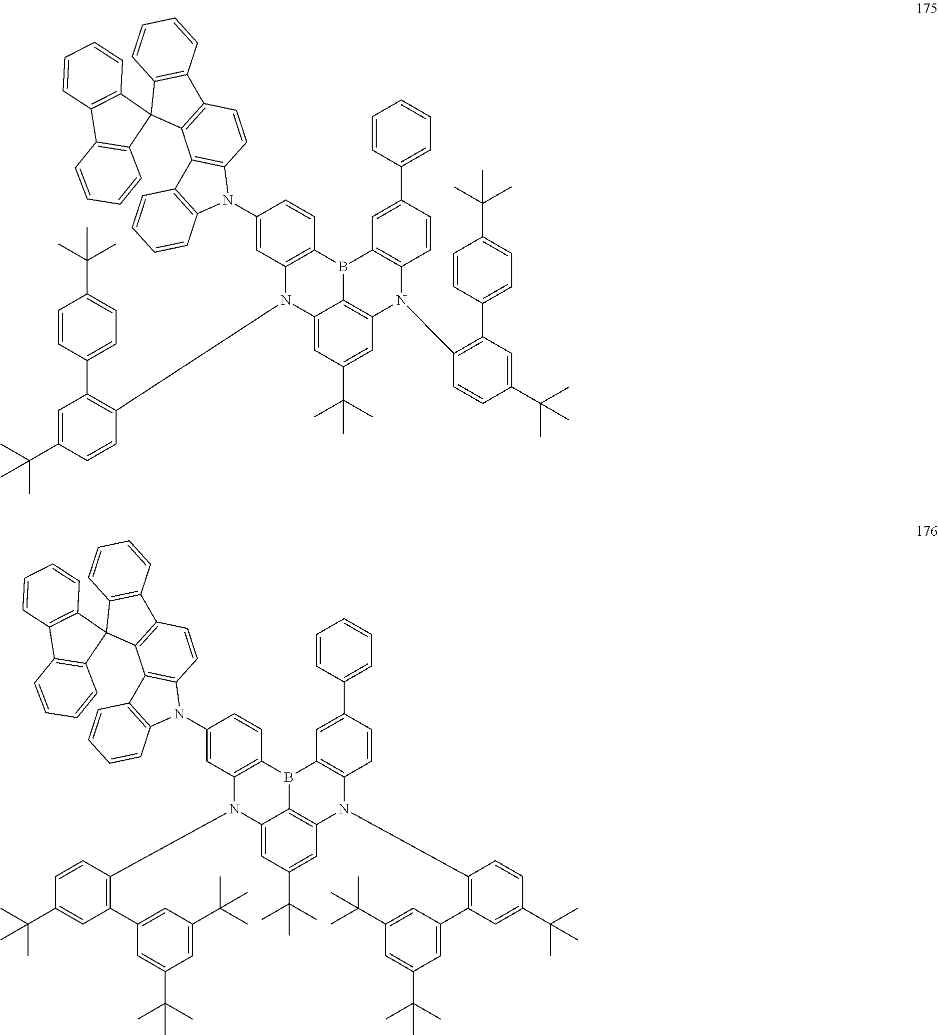

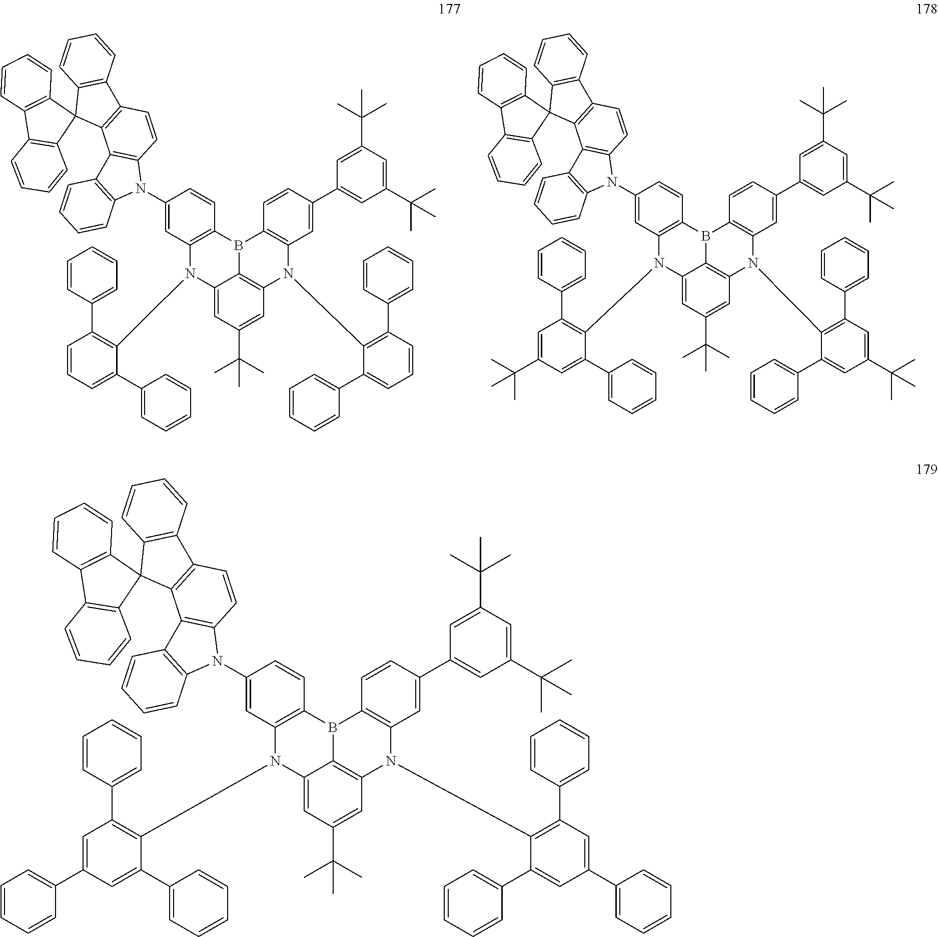

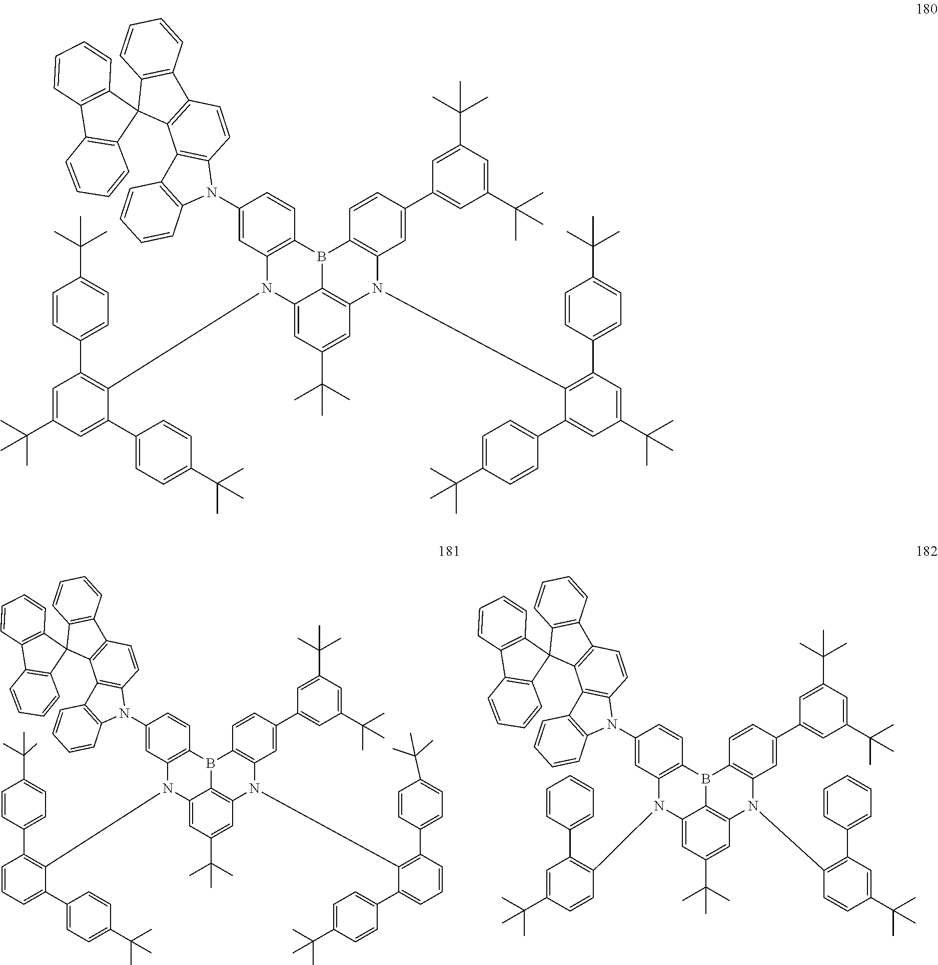

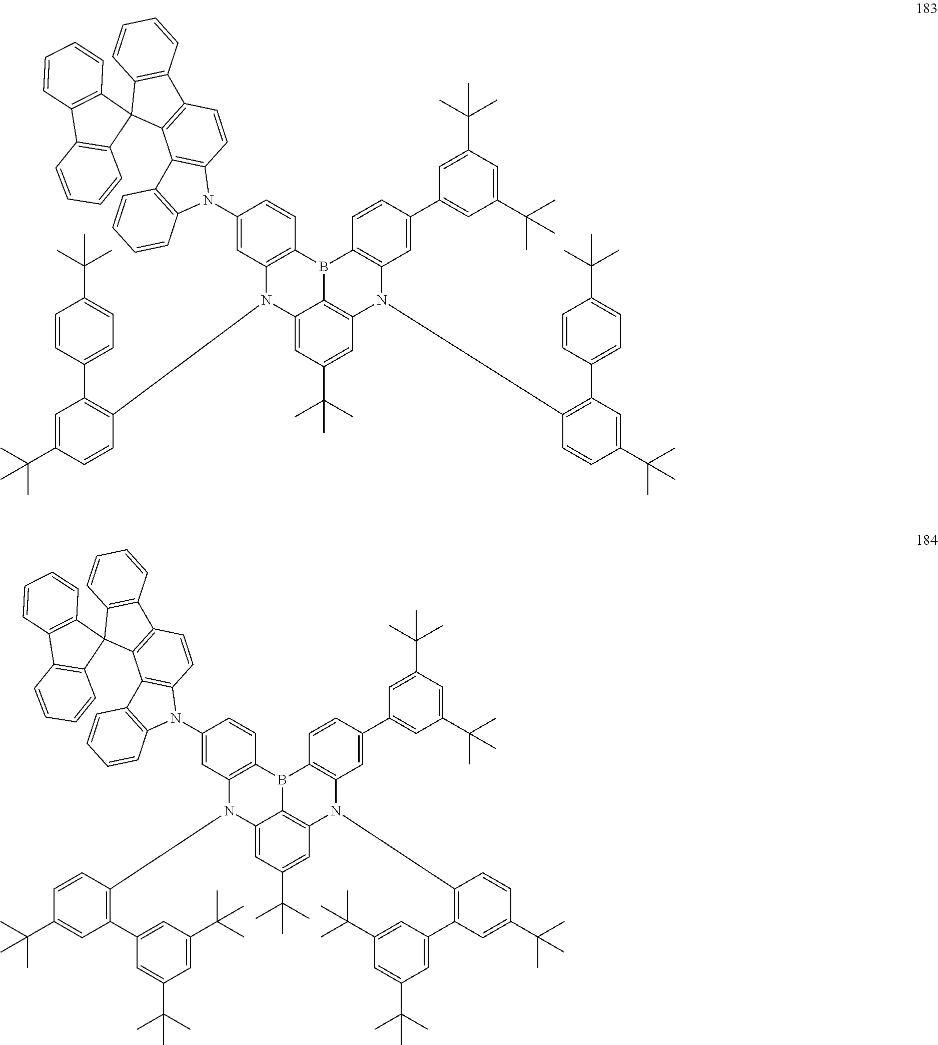

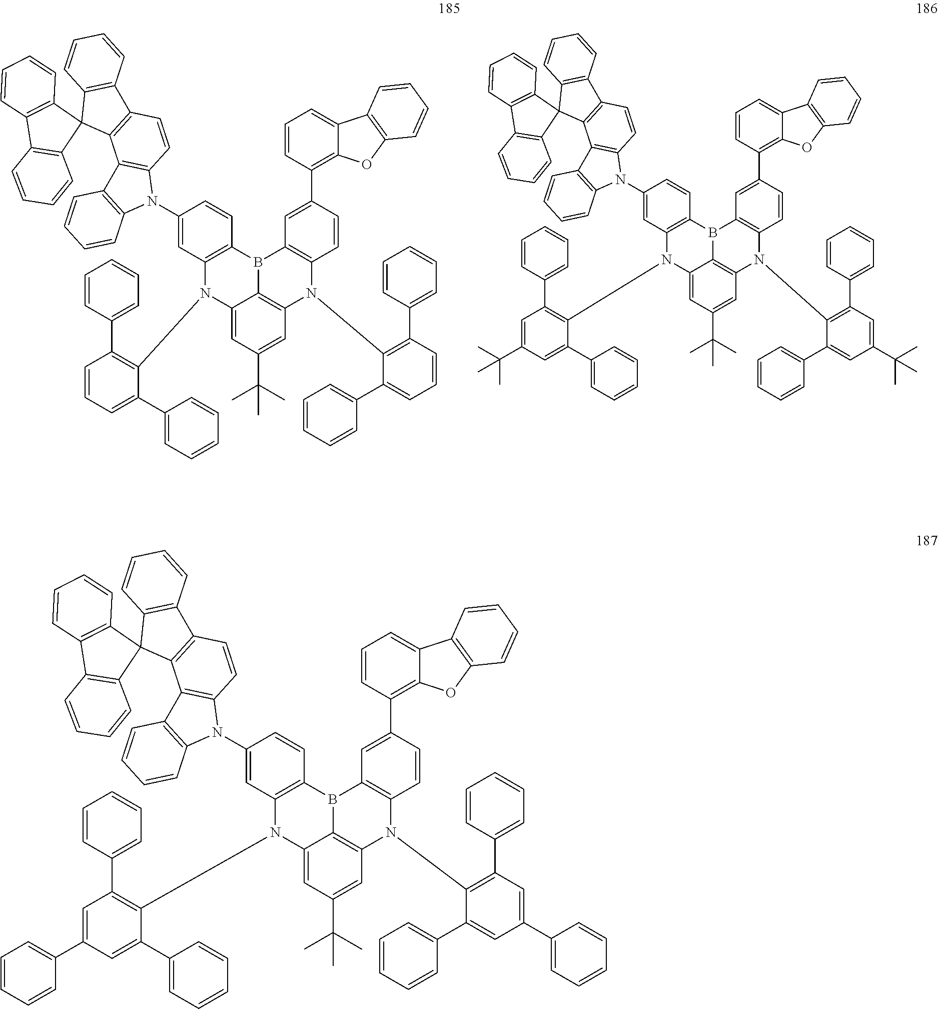

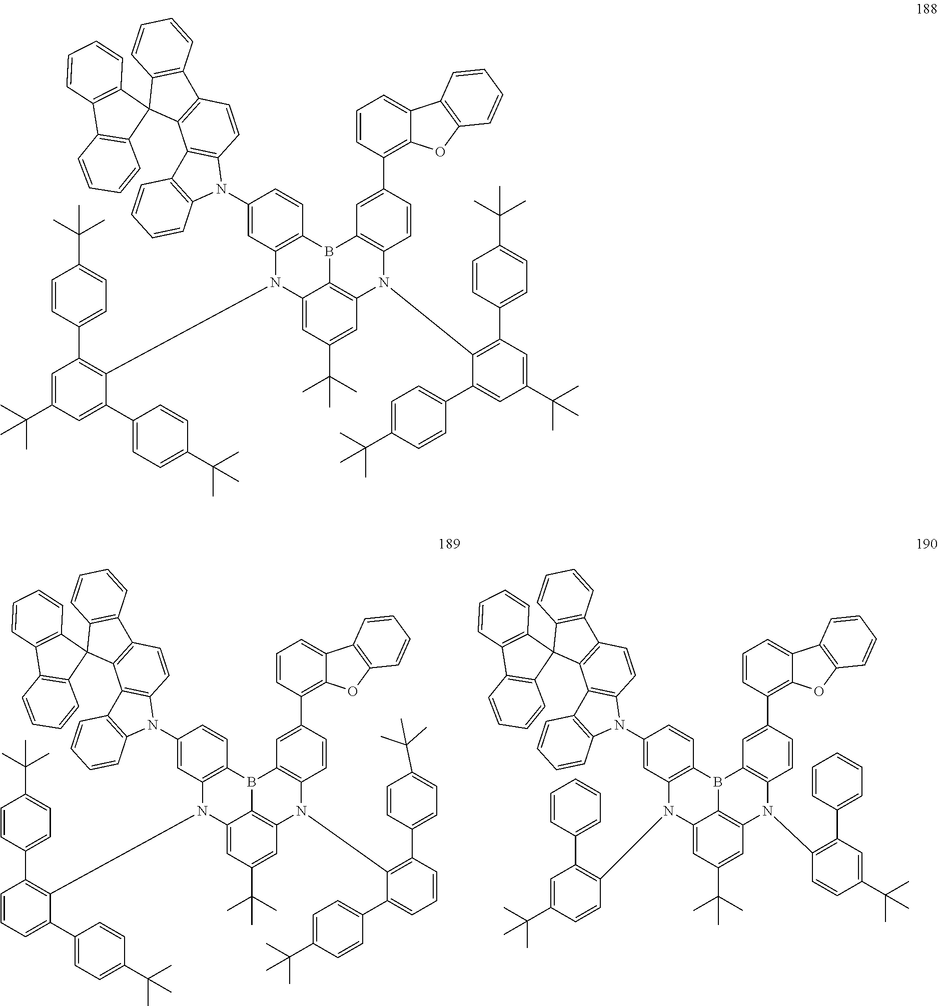

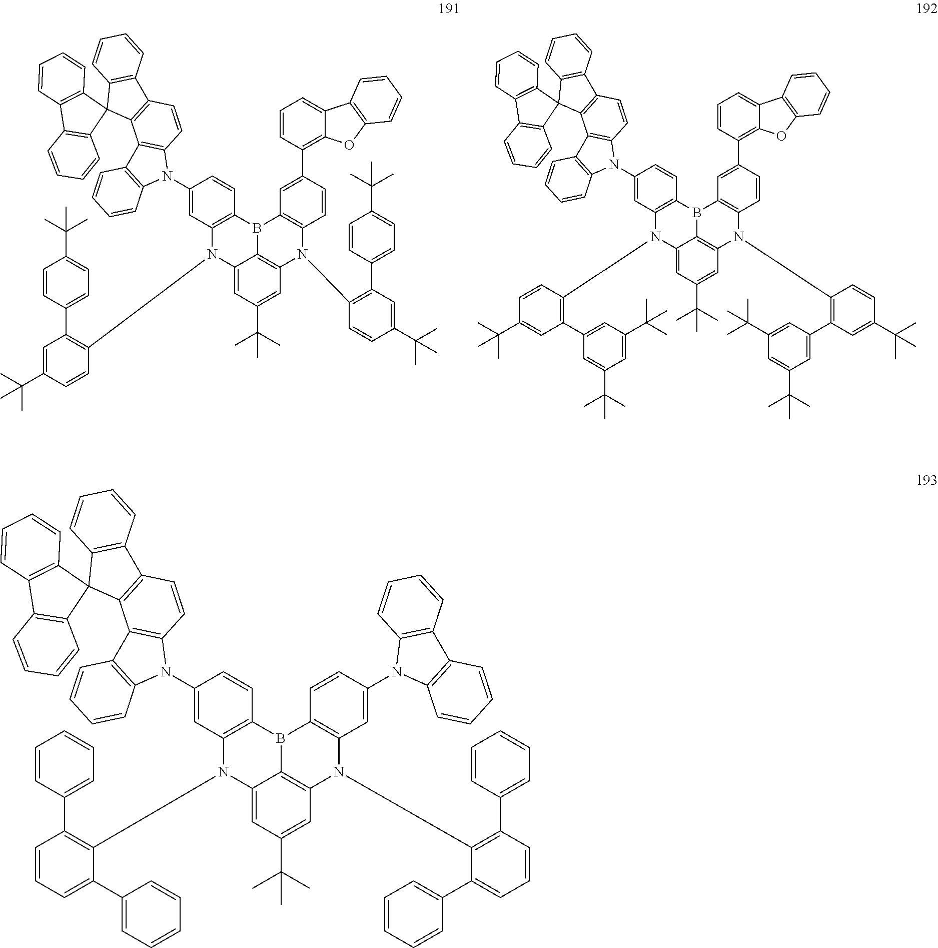

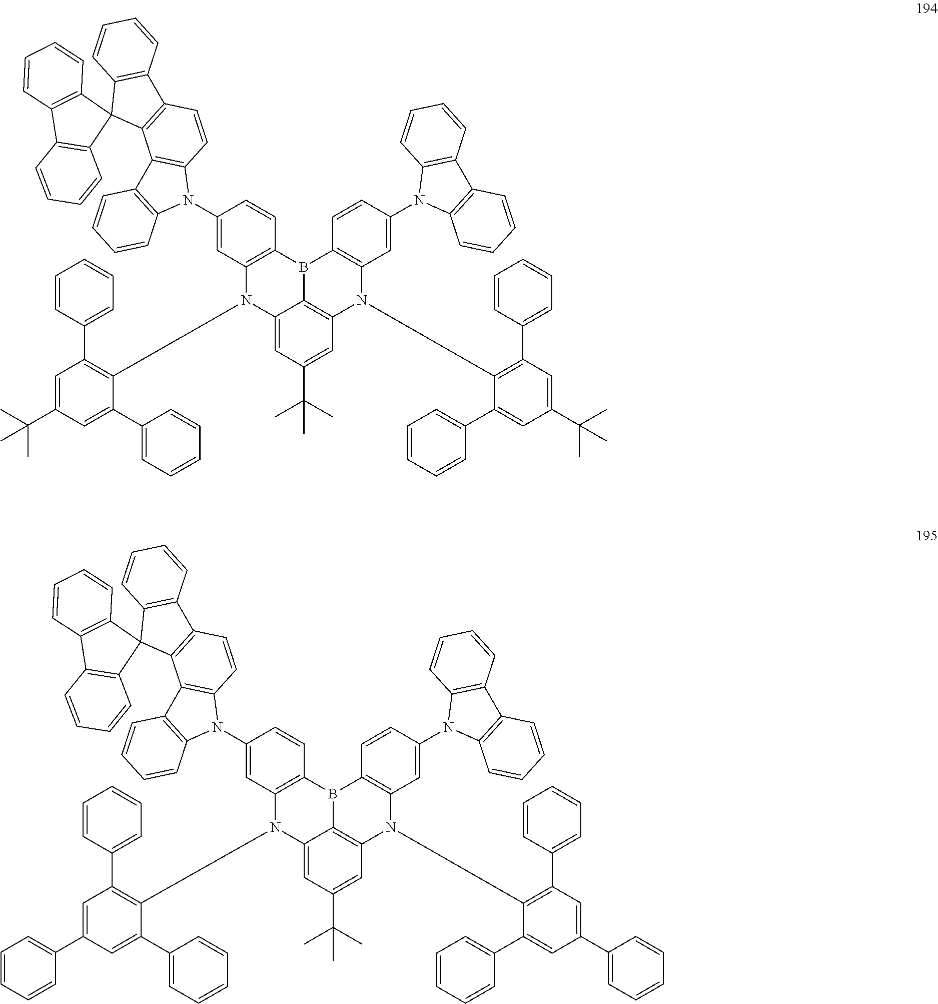 [SMILES: CC(C)(C)c1cc(-c2ccccc2)c(N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1ccc(-n3c4ccccc4c4ccccc43)cc1N2c1c(-c2ccccc2)cc(-c2ccccc2)cc1-c1ccccc1]

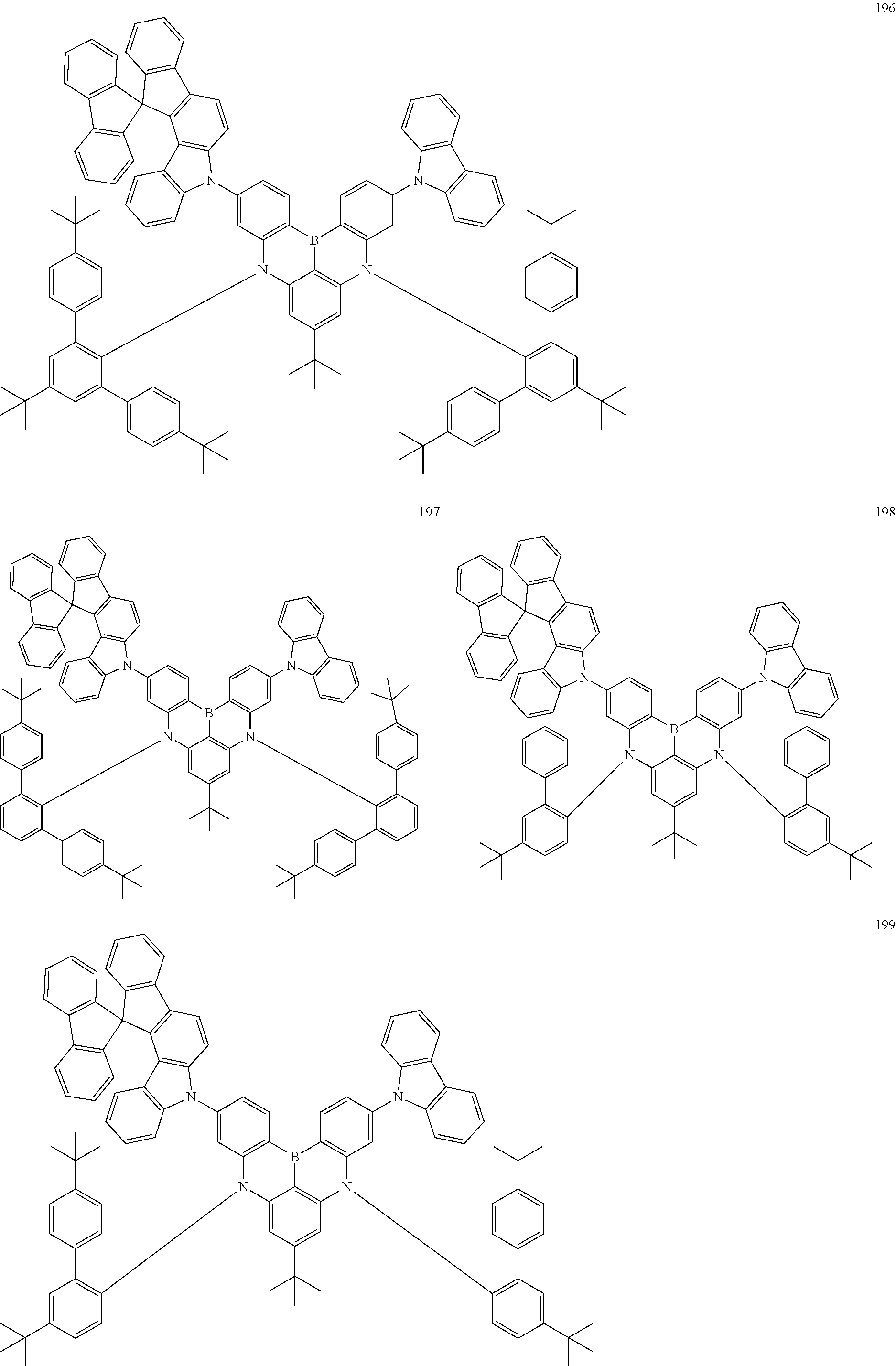

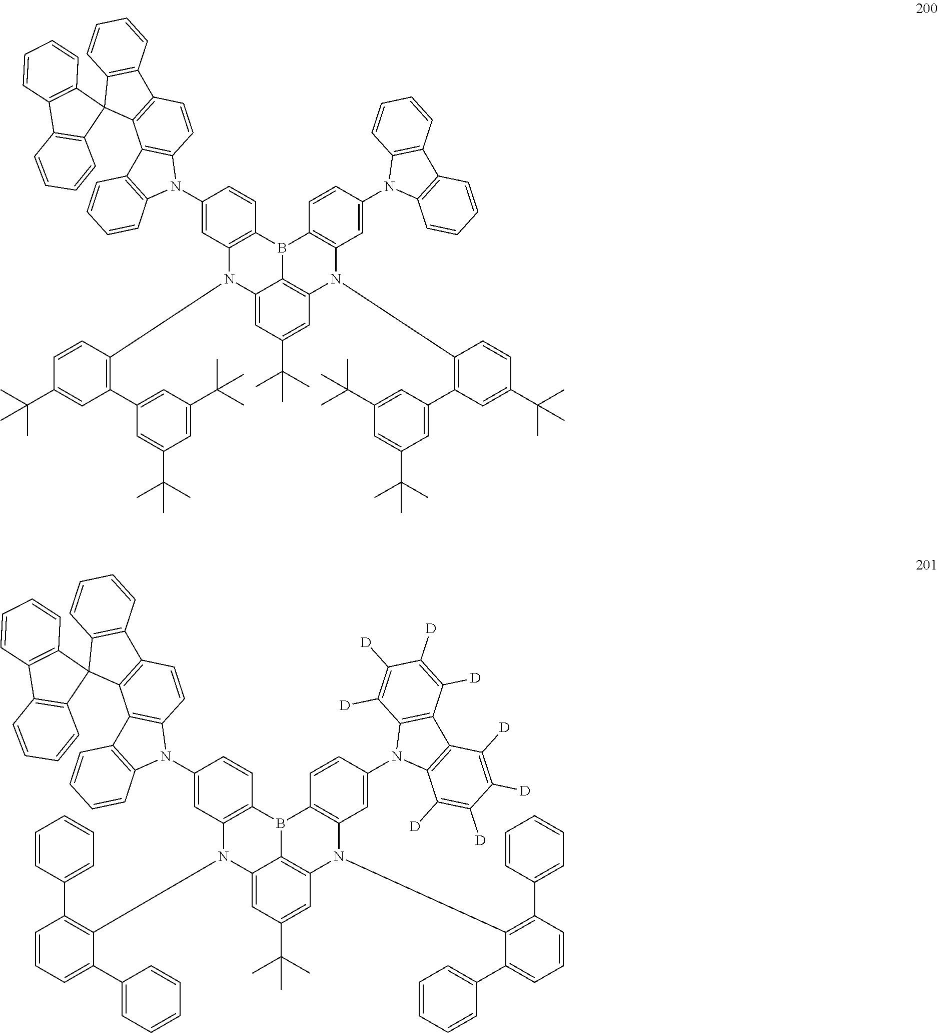 [SMILES: CC(C)(C)c1cc(-c2cc(C(C)(C)C)ccc2N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4ccc(C(C)(C)C)cc4-c4cc(C(C)(C)C)cc(C(C)(C)C)c4)c4cc(C(C)(C)C)cc2c43)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cccc1-c1ccccc1]

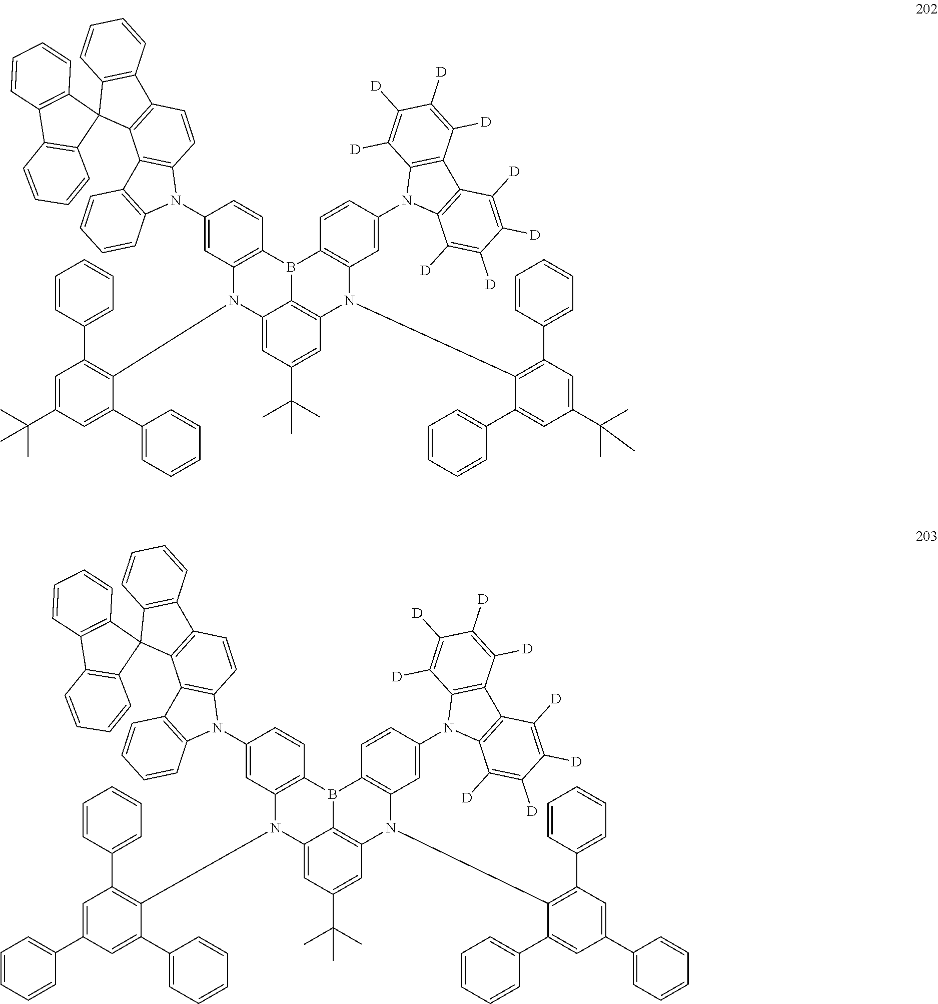 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cc(C(C)(C)C)cc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(-c3ccccc3)cc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cc(-c2ccccc2)cc1-c1ccccc1]

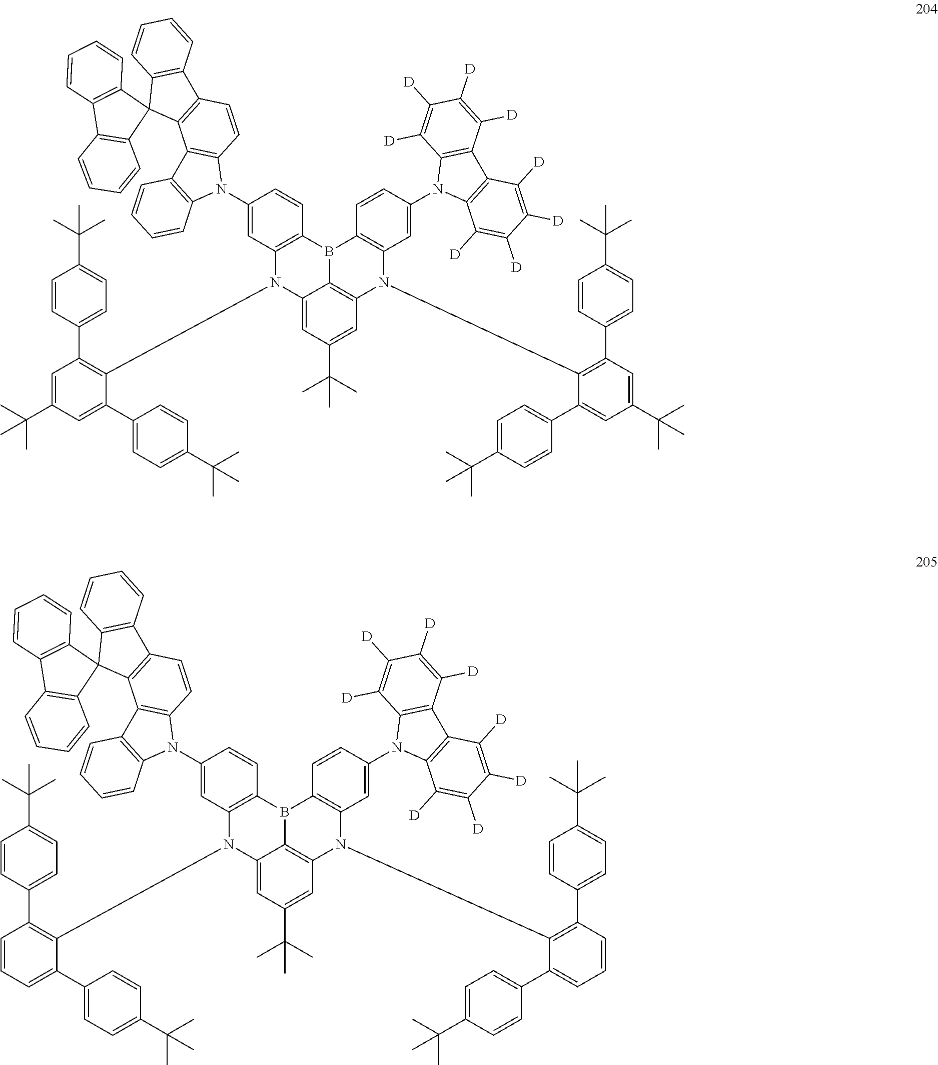

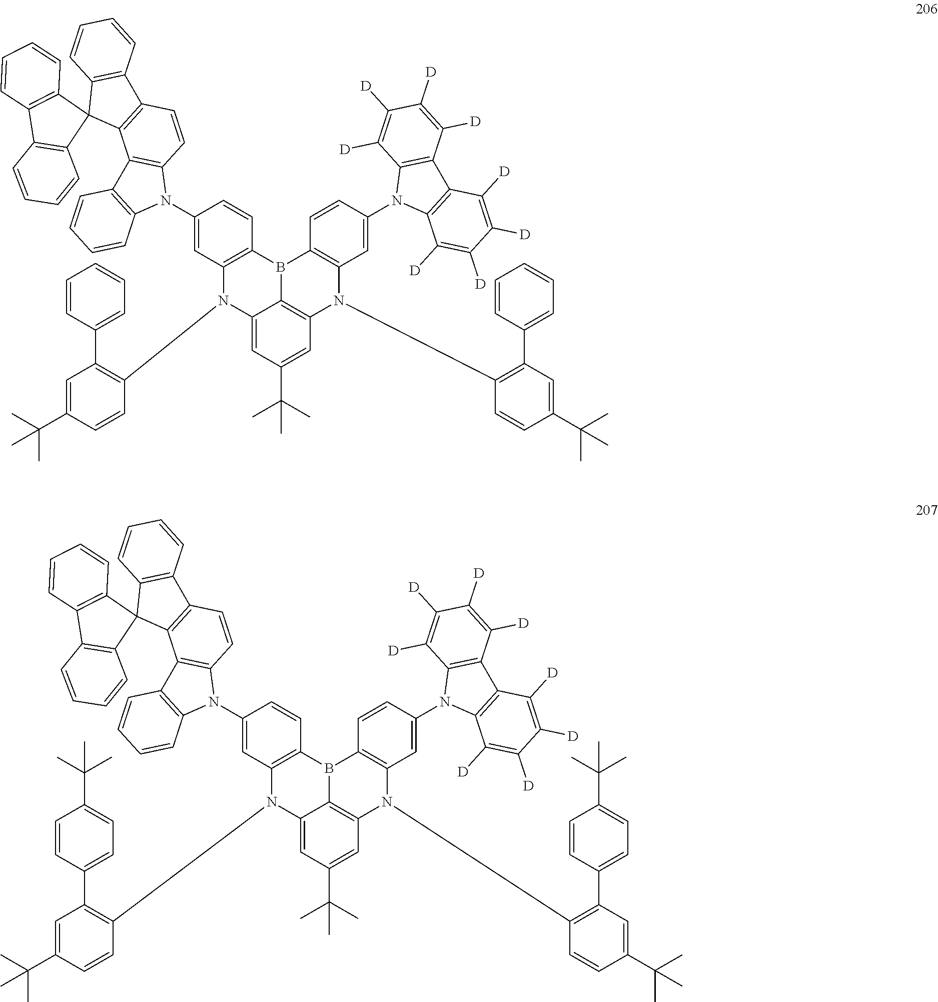

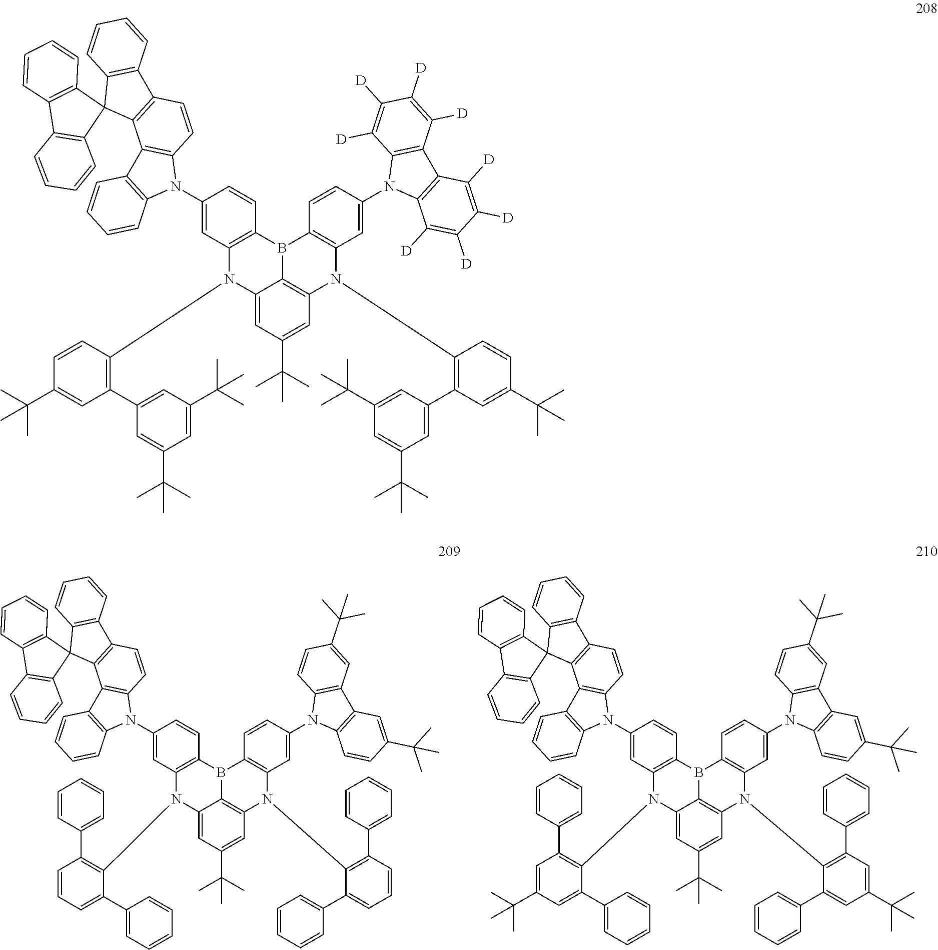

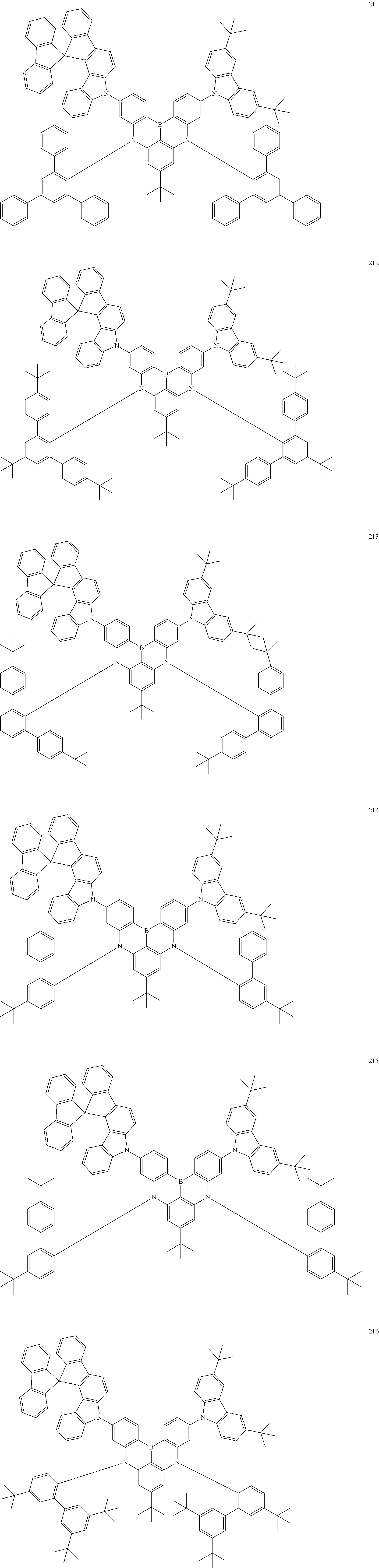

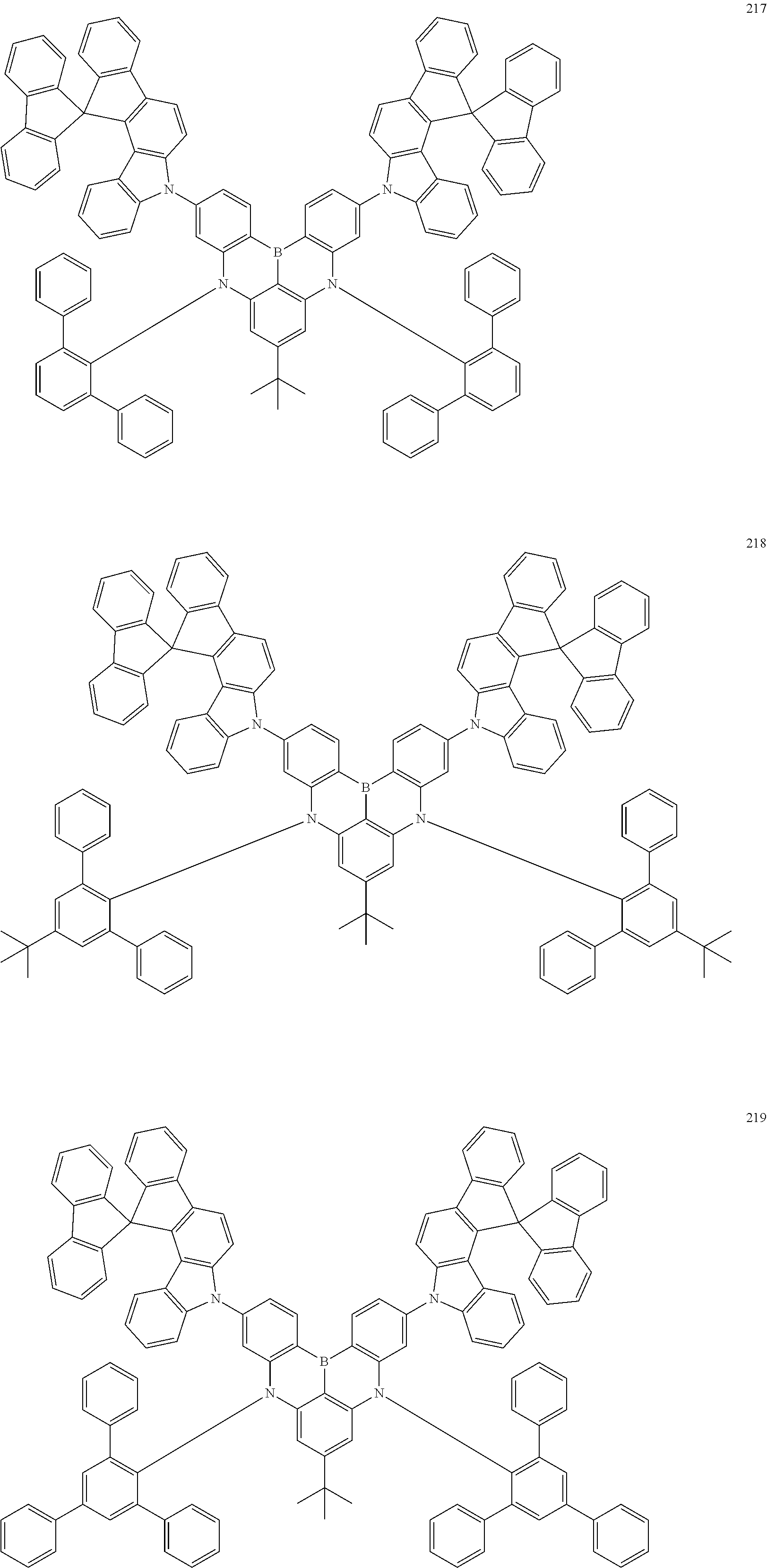

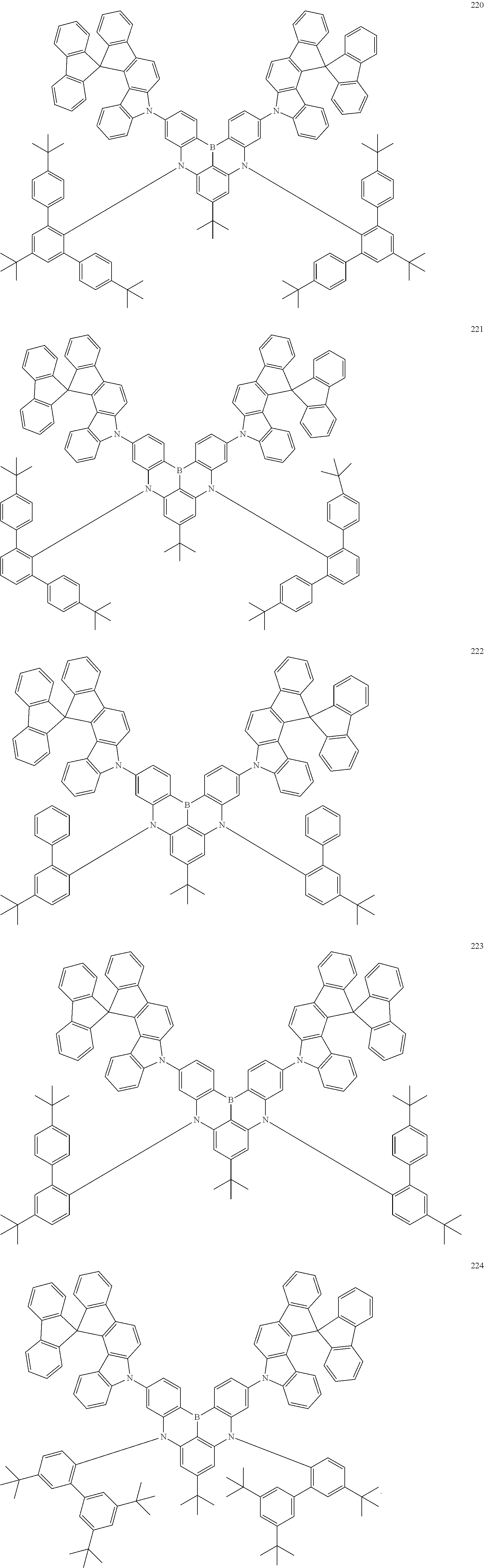

The fused polycyclic compound according to an embodiment may emit blue light. For example, the fused polycyclic compound may be a luminescent material having a central wavelength in a range of about 430 nm to about 490 nm. For example, the fused polycyclic compound may be a luminescent material having a central wavelength in a range of about 450 nm to about 470 nm. The light emitting element ED including the fused polycyclic compound according to an embodiment may emit blue light. For example, in display device DD, the third light emitting element ED-3 that emits blue light may include the fused polycyclic compound.

The emission layer EML may include the fused polycyclic compound as a dopant. The fused polycyclic compound according to an embodiment may emit thermally activated delayed fluorescence (TADF). The fused polycyclic compound may emit light by converting triplet excitons into singlet excitons by a reverse inter system crossing (RISC) mechanism.

The fused polycyclic compound according to an embodiment may be a multiple resonance (MR)-type dopant. The emission layer EML including the fused polycyclic compound, which is a MR-type dopant, may emit light having a narrow full width at half maximum (FWHM). Accordingly, the light emitting element ED including the fused polycyclic compound may emit light having improved color purity.

The fused polycyclic compound of an embodiment includes, as a central structure, a pentacyclic fused ring core that includes two nitrogen atoms and a boron atom as ring-forming atoms, and an indenocarbazole moiety and a biphenyl moiety (or a terphenyl moiety) may each be bonded to the central structure. The biphenyl moiety (or terphenyl moiety) may each be bonded to a nitrogen atom, which is a ring-forming atom of the central structure.

For example, the central structure may be represented by Formula Z-1, and the indenocarbazole moiety may be represented by one of Formula Z-2 to Formula Z-5. In Formula Z-1, P1 to P5 and P11 to P14 each represent a cyclic group. P1 to P5 are cyclic groups that constitute the pentacyclic fused ring core. P11 and P12 are cyclic groups that constitute a biphenyl moiety (or terphenyl moiety), and P13 and P14 are cyclic groups that constitute a biphenyl moiety (or terphenyl moiety). The indenocarbazole moiety may be bonded to P1 of the central structure represented by Formula Z-1 via a nitrogen atom, which is a ring-forming atom of the indenocarbazole moiety.

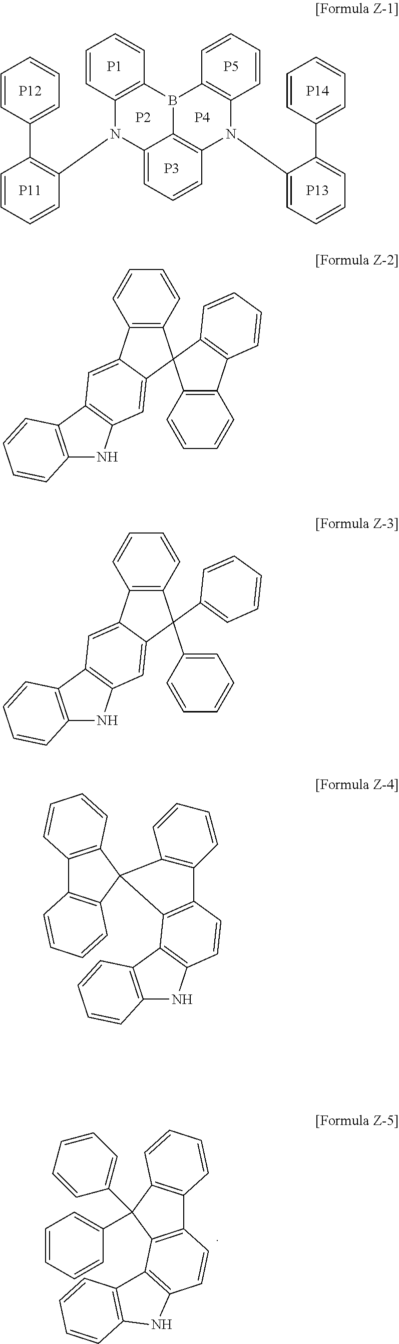

In Formula Z-1, P3, P5, P11, and P13 may each include substituents other than hydrogen atoms. P11 may include P12 as a substituent, and P13 may include P14 as a substituent. P3, P5, P11, and P13 may be active sites at a para position to the boron atom. By including a substituent other than a hydrogen atom at the active site, the fused polycyclic compound may prevent intermolecular interactions and maximize the prevention of Dexter energy transfer. The indenocarbazole moiety represented by one of Formulae Z-2 to Z-5 is a sterically bulky substituent, and may protect the central structure. Accordingly, the fused polycyclic compound according to an embodiment may exhibit excellent material stability.

Formula Z-2 and Formula Z-4 are indenocarbazole moieties which each include a spiro-bifluorene moiety, Formula Z-3 and Formula Z-5 are indenocarbazole moieties which each include two phenyl substituents, and the indenocarbazole moieties represented by Formula Z-2 to Formula Z-5 are bulky substituents that may protect the core to prevent (or minimize) Dexter energy transfer. The indenocarbazole moiety that includes two phenyl substituents or a spiro-bifluorene moiety has stronger electron donating properties than a carbazole group, and may exhibit an effect of improving oscillator strength and absorbance of the fused polycyclic compound. The indenocarbazole moiety that includes two phenyl substituents or a spiro-bifluorene moiety may exhibit a deep highest occupied molecular orbital (HOMO) energy level. The indenocarbazole moiety that includes a spiro-bifluorene moiety has a limited molecular rotation compared to the indenocarbazole moiety that includes two phenyl substituents, thereby emitting light having a narrower FWHM and further reducing planarity, thus exhibiting characteristics effective in suppressing Dexter energy transfer.

The fused polycyclic compound according to an embodiment may be a thermally activated delayed fluorescence material. A thermally activated delayed fluorescence compound exhibits delayed fluorescence when an inter system crossing (ISC) occurs, in which excitons are transferred from a lowest singlet energy level to a triplet energy level, followed by a reverse inter system crossing (RISC) occurs, in which excitons are transferred from a triplet energy level to a lowest singlet energy level, and the compound delayed fluorescence transfers from a singlet energy level to a ground state. The thermally activated delayed fluorescence mechanism may include passing through not only a lowest triplet energy level (T1 level) but also a higher triplet energy level (Tn level, where n is 2 or more) in the processes of inter system crossing (ISC) and reverse inter system crossing (RISC). For example, a higher triplet energy level may include a T2 level, a T3 level, and/or a T4 level.

In the fused polycyclic compound according to an embodiment, a T2 level and a T3 level may exhibit a low energy level equal to or less than about 3.0 eV. Accordingly, in the fused polycyclic compound according to an embodiment, a T2 level and a T3 level may be adjacent to a lowest triplet energy level T1.

The fused polycyclic compound according to an embodiment may include an indenocarbazole moiety, and thus may exhibit a low higher triplet energy level (Tn level) adjacent to a lowest singlet energy level (Si level), and may have an increase in spin-flip. Spin-flip may be a phenomenon in which excitons of a higher triplet energy level (Tn level) are transferred to a lowest singlet energy level (S1 level) by spin-orbit coupling (SOC) between the lowest excited singlet energy level (Si level) and the higher excited triplet energy level (Tn level) adjacent thereto. In the fused polycyclic compound, as a higher triplet energy level (Tn level) adjacent to a lowest singlet energy level (Si level) is low, reverse inter system crossing (RISC) from the higher triplet energy level (Tn level) to the lowest singlet energy level (Si level) is accelerated, and as the delayed fluorescence lifetime (tau) is shortened, luminous efficiency and service life of the light emitting element ED may be improved.

A boron atom, which is a ring-forming atom, includes an empty p orbital, and a compound containing a boron atom exhibits electron deficient properties due to the empty p orbital of the boron atom, and may readily bond to a nucleophile or the like. As a result of such an interaction, a ring group containing a boron atom may deform into a tetrahedral structure, resulting in the deterioration of the light emitting element. A conventional compound containing a boron atom and used as a luminescent material has a planar structure, and such a planar structure may facilitate intermolecular interaction. Intermolecular interactions such as intermolecular aggregation, intermolecular excimer formation, and intermolecular exciplex formation may result in the deterioration of efficiency and service life of the light emitting element.

In contrast, in the fused polycyclic compound according to an embodiment, the indenocarbazole moiety, which is a bulky substituent, protects the ring-forming boron atom, and increases intermolecular distance, thereby preventing (or minimizing) intermolecular interaction and Dexter energy transfer. The indenocarbazole moiety prevents intermolecular aggregation, thereby facilitating the purification of a compound when the compound is synthesized, increasing the stability to resist thermal decomposition in sublimation and purification steps during synthesis, and exhibiting high color purity during light emission.

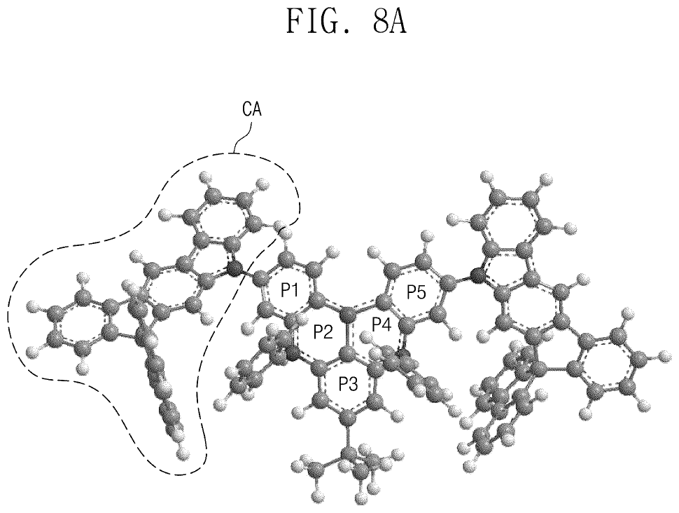

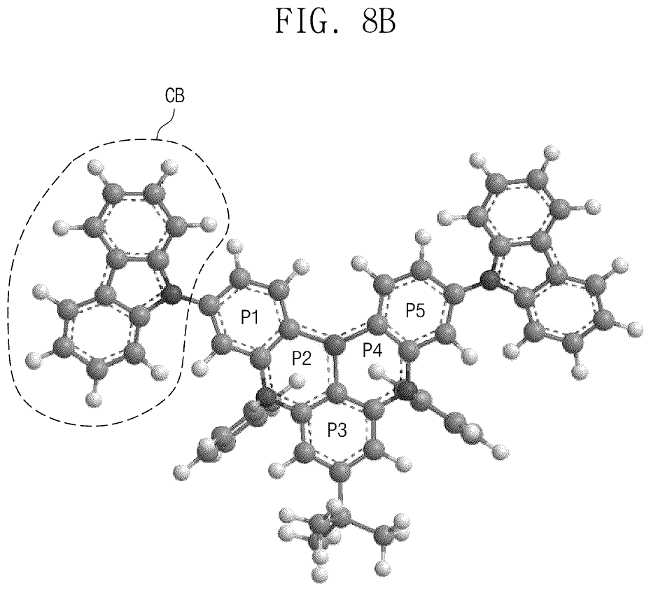

FIG. 8A is a three-dimensional image of Experimental Example Compound E1, and Experimental Example Compound E1 is a compound having a structure similar to that of the fused polycyclic compound according to an embodiment. Experimental Example Compound E1 includes a pentacyclic fused ring core and an indenocarbazole moiety. The pentacyclic fused ring core includes two nitrogen atoms and a boron atom as ring-forming atoms.

FIG. 8B is a three-dimensional image of Comparative Example Compound CX2, and Comparative Example Compound CX2 includes a pentacyclic fused ring core and a carbazole group. Comparative Example Compound CX2 does not include an indenocarbazole substituents but includes a carbazole group. The pentacyclic fused ring core includes two nitrogen atoms and a boron atom as ring-forming atoms. Experimental Example Compound E1 and Comparative Example Compound CX2 have a same structure, except for an indenocarbazole moiety and a carbazole group.

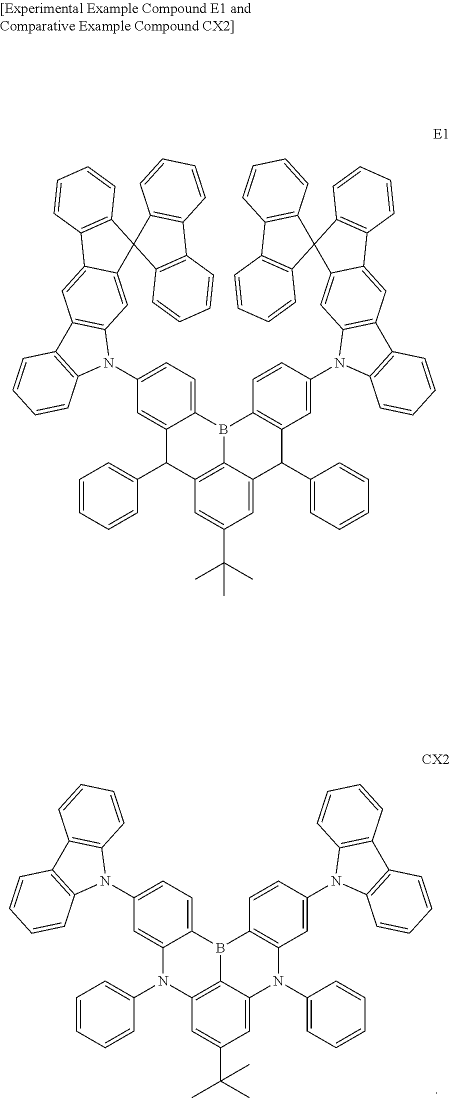 [SMILES: CC(C)(C)c1cc2c3c(c1)C(c1ccccc1)c1cc(-n4c5ccccc5c5cc6c(cc54)C4(c5ccccc5-c5ccccc54)c4ccccc4-6)ccc1B3c1ccc(-n3c4ccccc4c4cc5c(cc43)C3(c4ccccc4-c4ccccc43)c3ccccc3-5)cc1C2c1ccccc1 ; CC(C)(C)c1cc2c3c(c1)N(c1ccccc1)c1cc(-n4c5ccccc5c5ccccc54)ccc1B3c1ccc(-n3c4ccccc4c4ccccc43)cc1N2c1ccccc1]

In FIGS. 8A and 8B, P1 to P5 correspond to P1 to P5 of Formula Z1 as described above. In FIG. 8A, “CA” corresponds to an indenocarbazole moiety, and in FIG. 8B, “CB” corresponds to a carbazole group. The indenocarbazole moiety may be a rigid substituent having stronger electron donating properties than a carbazole group. The compound including the indenocarbazole moiety has a greater degree of conjugation than the compound including the carbazole group, and the bent structure of the indenocarbazole moiety does not affect light emission characteristics, and thus may emit light with high color purity.

Referring to FIGS. 8A and 8B, compared to the carbazole group CB, it may be seen that the indenocarbazole moiety CA protects the central structure with a bent structure. Accordingly, Experimental Example Compound E1 may exhibit excellent material stability. As described above, it may be seen that the fused polycyclic compound according to an embodiment has a structure similar to that of Experimental Example Compound E1 and exhibits excellent material stability. It may also be seen that the light emitting element ED including the fused polycyclic compound having excellent material stability exhibits high luminous efficiency and long service life characteristics.

In an embodiment, the emission layer EML may include the fused polycyclic compound according to an embodiment and may further include at least one of a second compound, a third compound, and a fourth compound.

In an embodiment, the emission layer EML may further include a second compound represented by Formula HT-1. In an embodiment, the second compound may be used as a hole transporting host material in the emission layer EML.

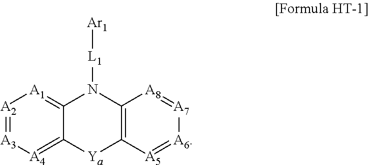

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 are linked to each other via a direct linkage,

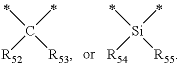

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2. In an embodiment, in light emitting element ED, the second compound may include at least one compound selected from Compound Group 2:

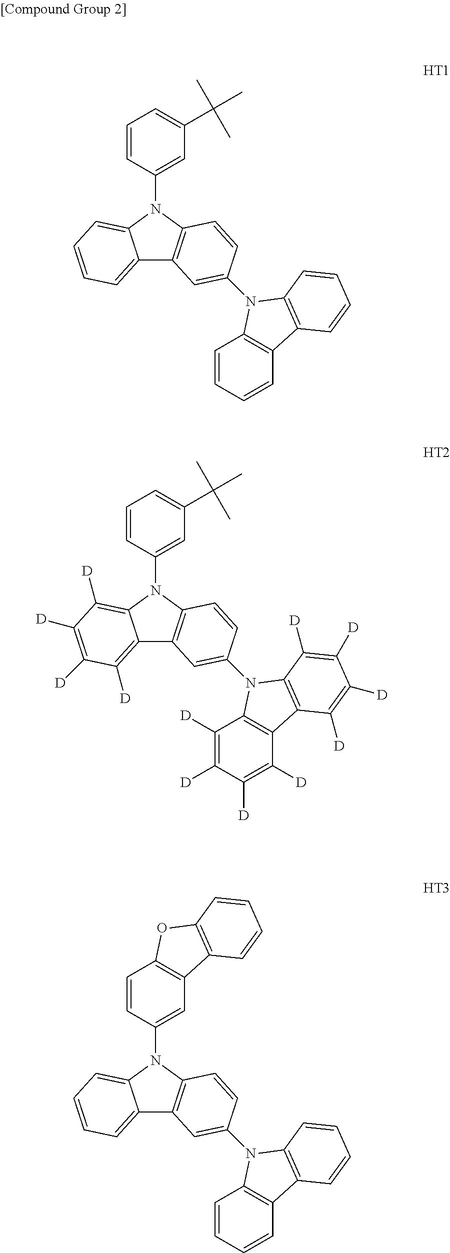 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

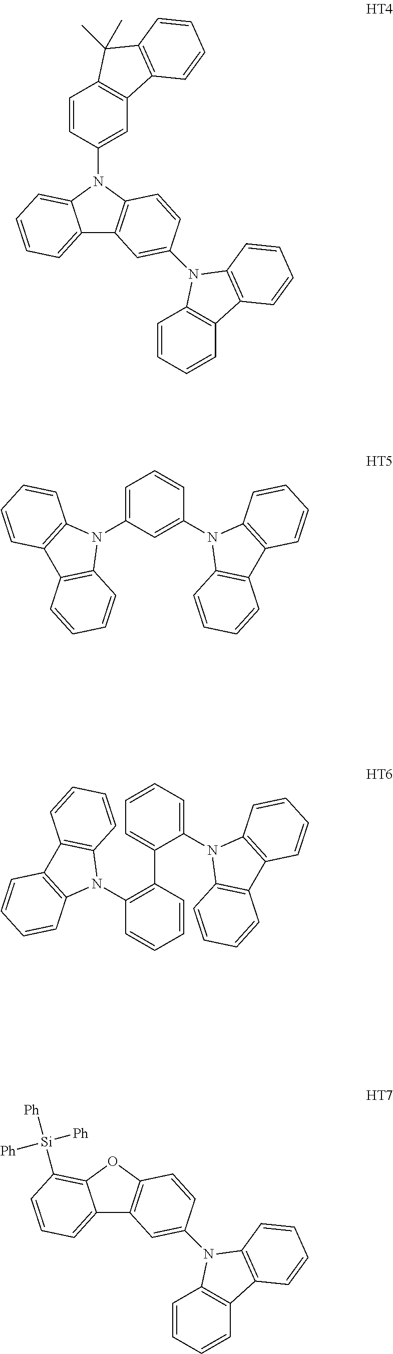 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1]

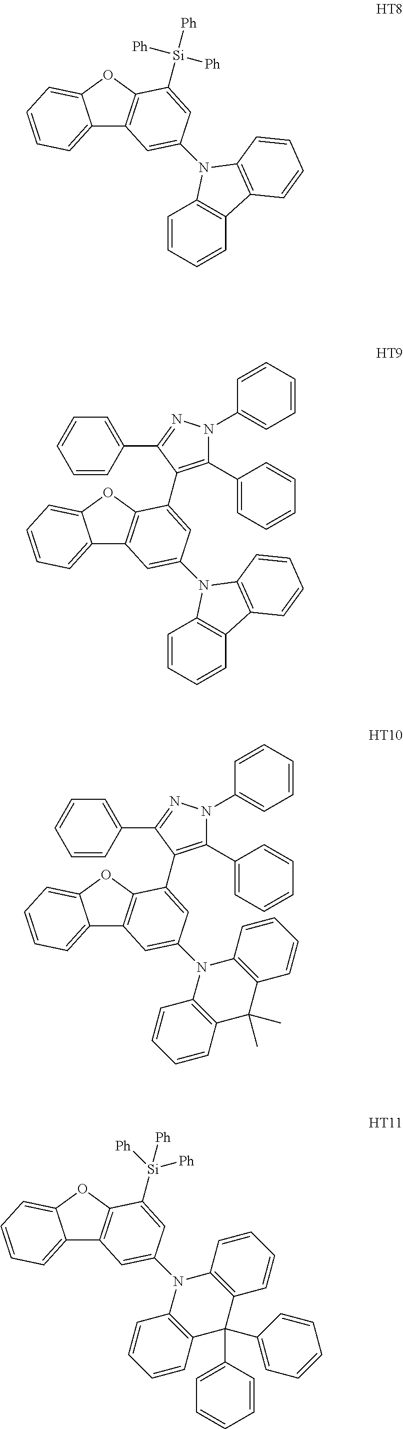 [SMILES: c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1]

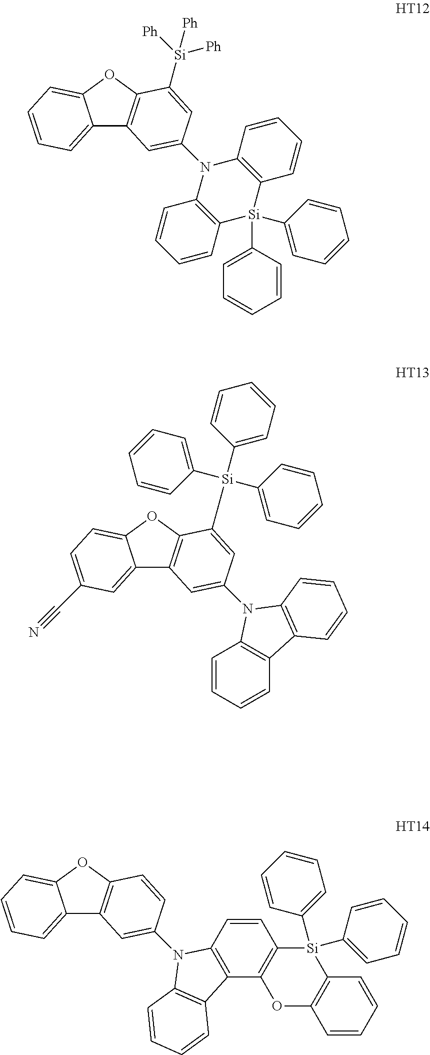 [SMILES: c1ccc([Si]2(c3ccccc3)c3ccccc3N(c3cc([Si](c4ccccc4)(c4ccccc4)c4ccccc4)c4oc5ccccc5c4c3)c3ccccc32)cc1 ; N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1]

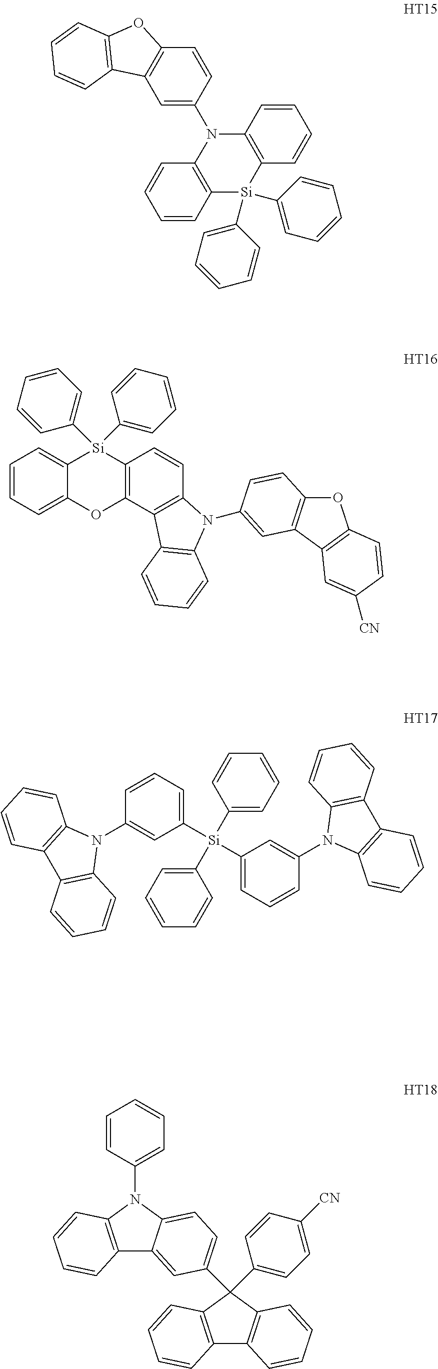 [SMILES: c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1]

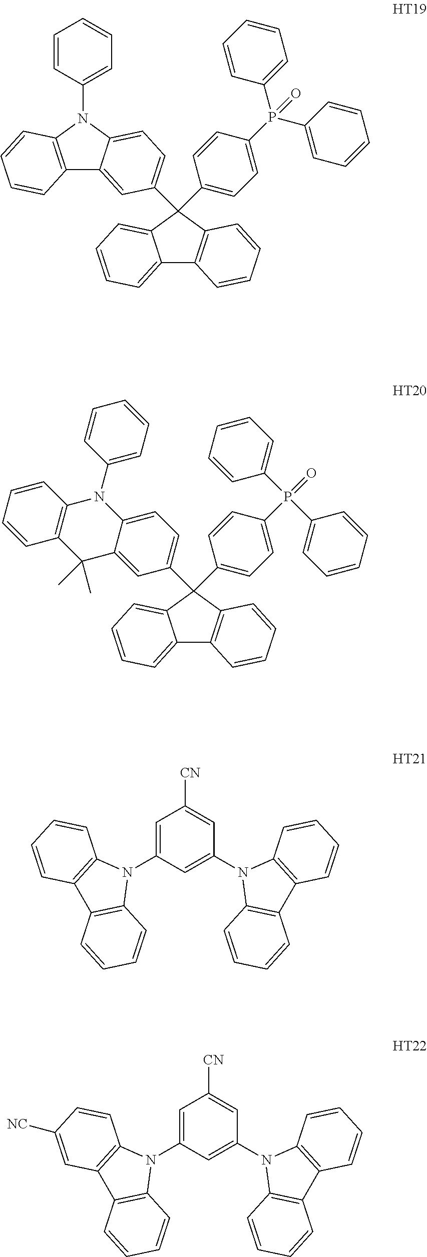 [SMILES: O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

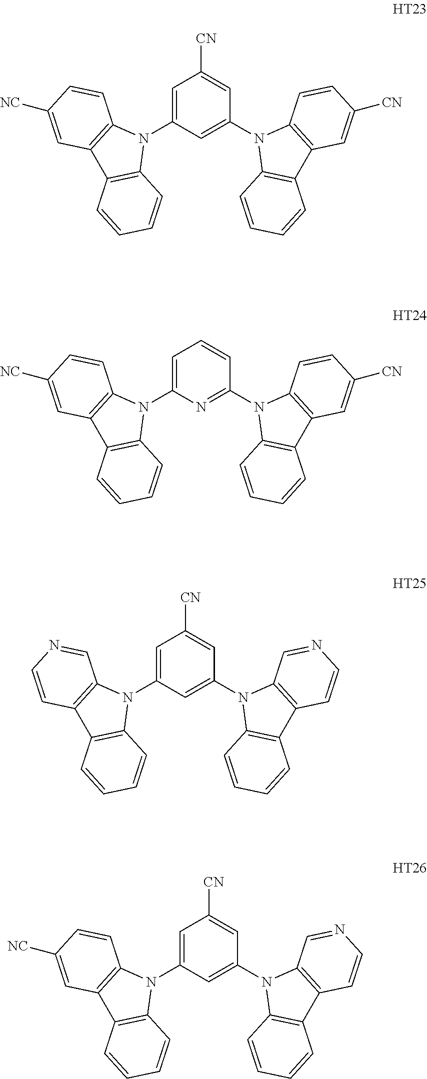 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1]

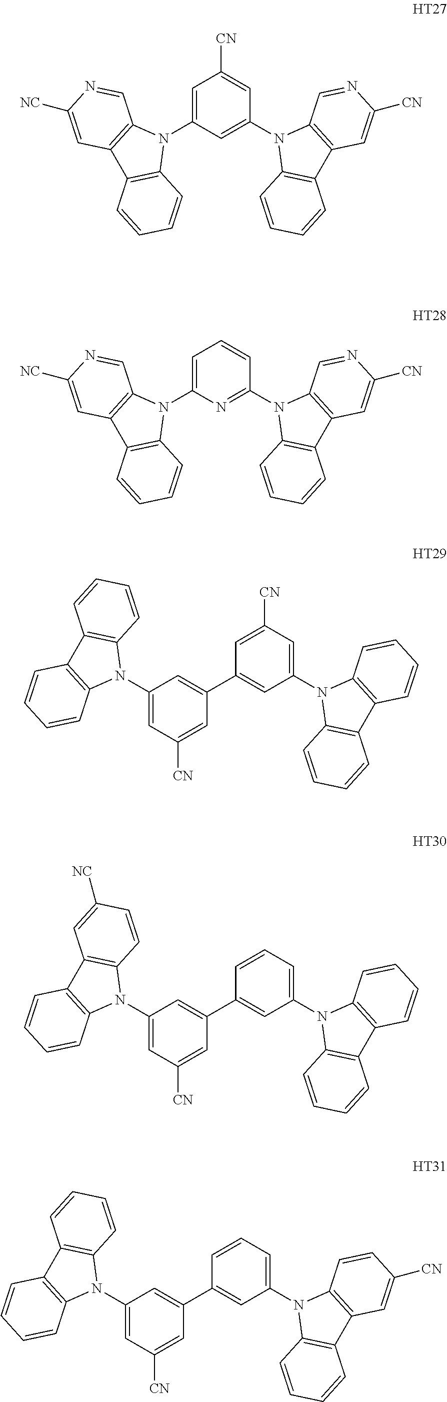 [SMILES: N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1]

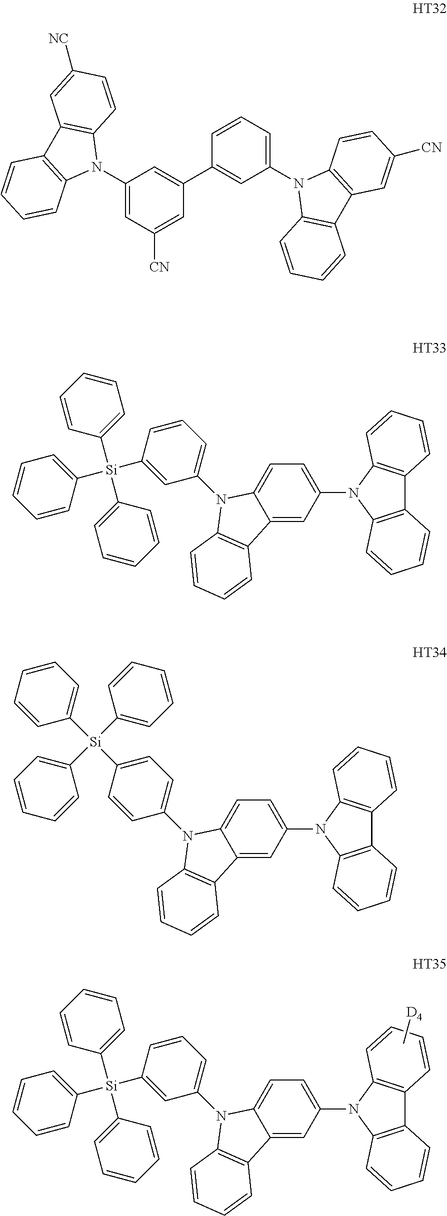

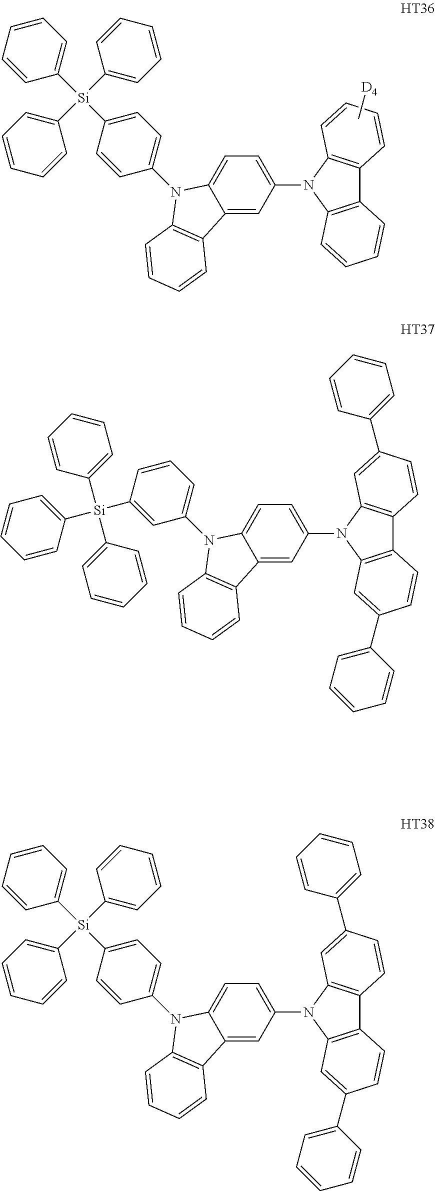

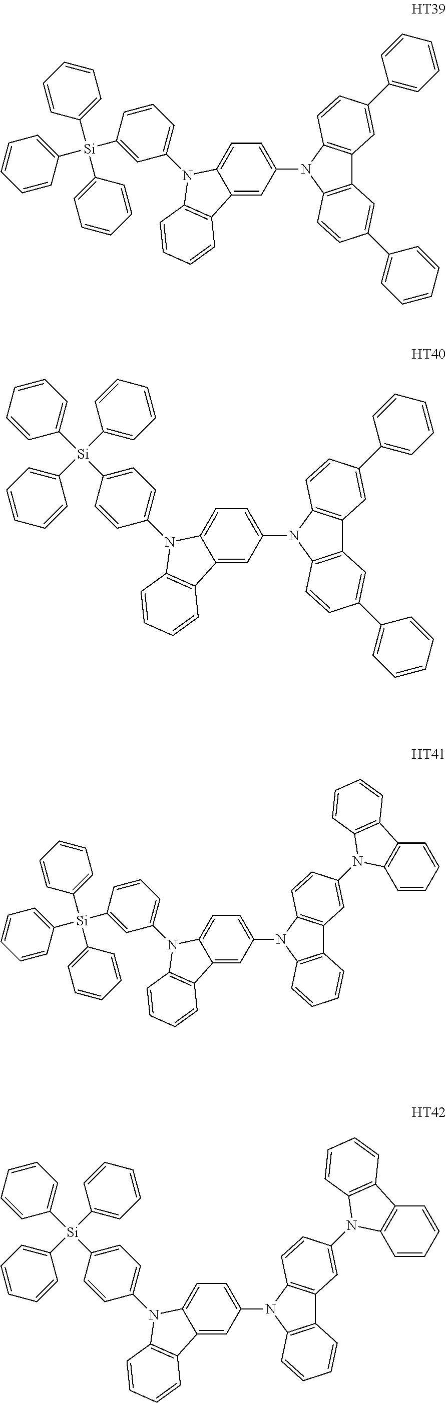 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

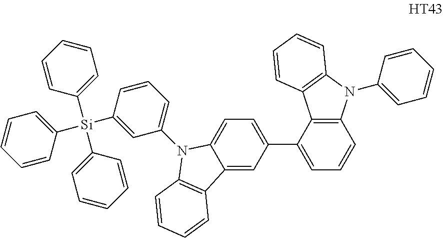 [SMILES: c1ccc(-n2c3ccccc3c3c(-c4ccc5c(c4)c4ccccc4n5-c4cccc([Si](c5ccccc5)(c5ccccc5)c5ccccc5)c4)cccc32)cc1]

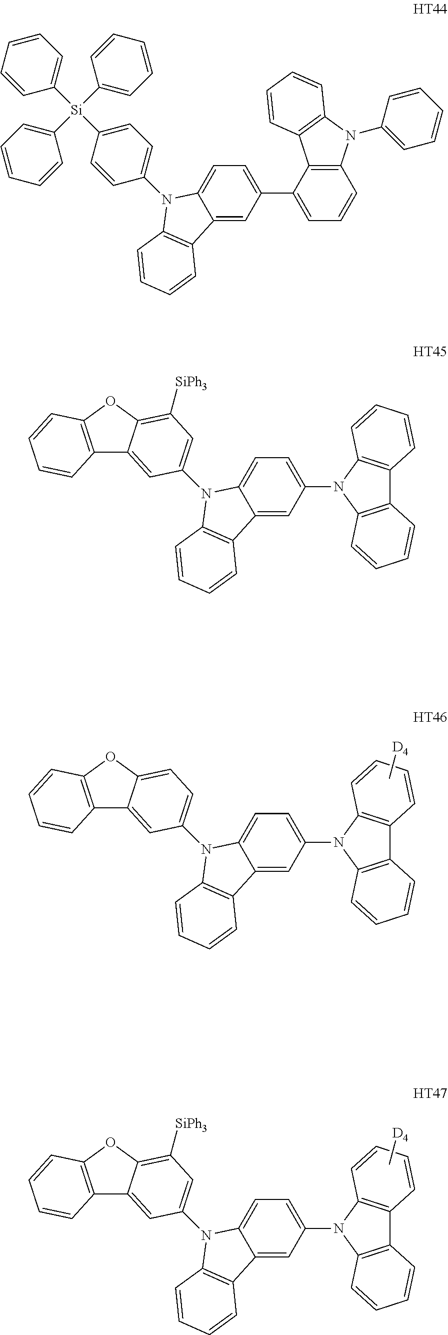

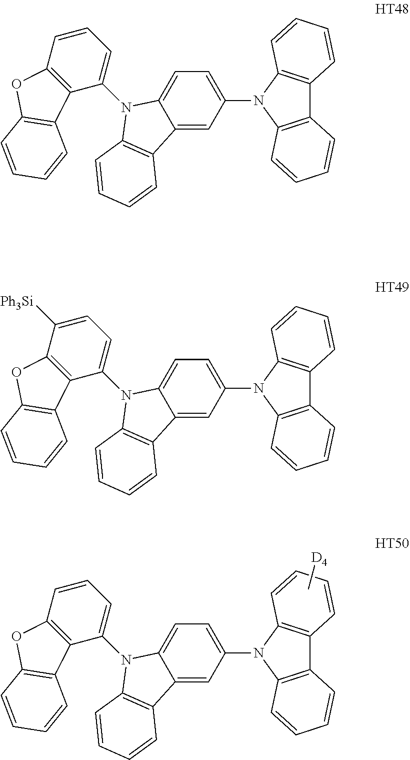

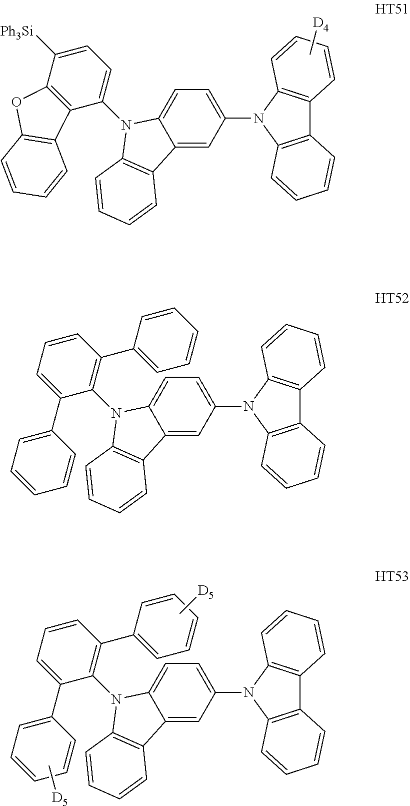

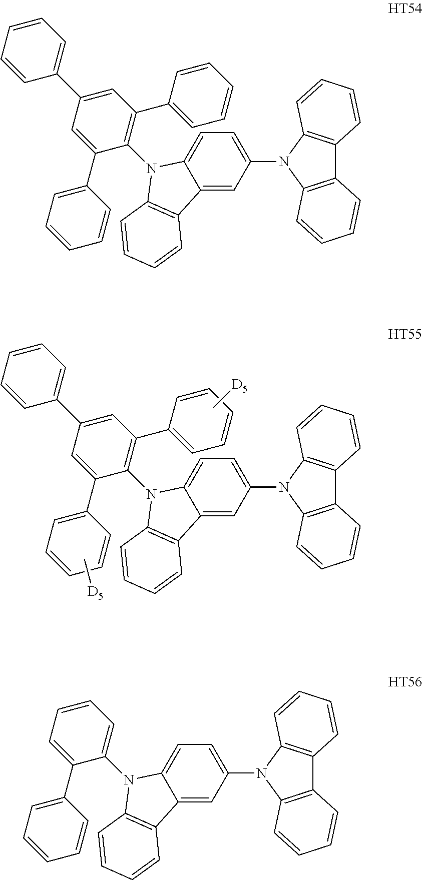

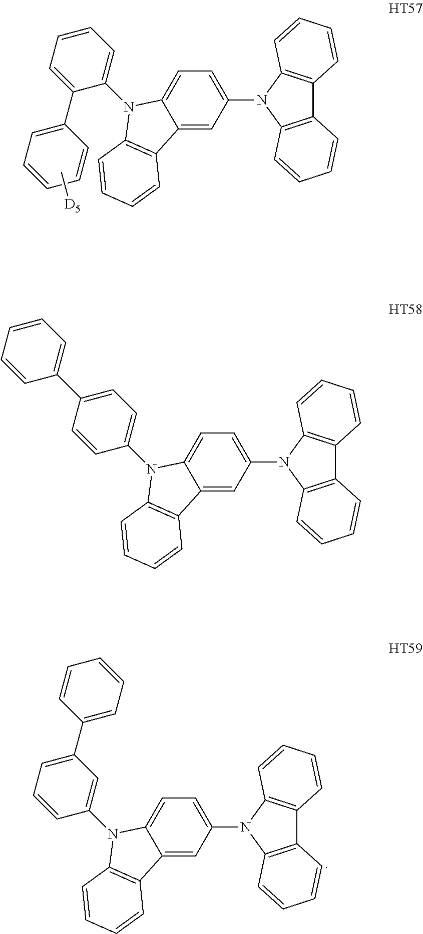

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML.

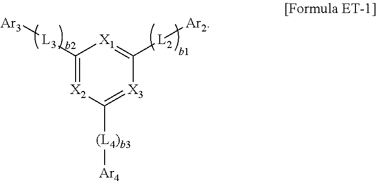

In Formula ET-1, at least one of X₁ to X₃ may each be N, and the remainder of X₁ to X₃ may each independently be C(R₅₆). For example, one of X₁ to X₃ may be N, and the remainder of X₁ to X₃ may each independently be C(R₅₆). Thus, the third compound represented by Formula ET-1 may include a pyridine moiety. As another example, two of X₁ to X₃ may each be N, and the remainder of X₁ to X₃ may be C(R₅₆). Thus, the third compound represented by Formula ET-1 may include a pyrimidine moiety. As yet another example, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 maybe selected from Compound Group 3. In an embodiment, in the light emitting element ED, the third compound may include at least one compound selected from Compound Group 3.

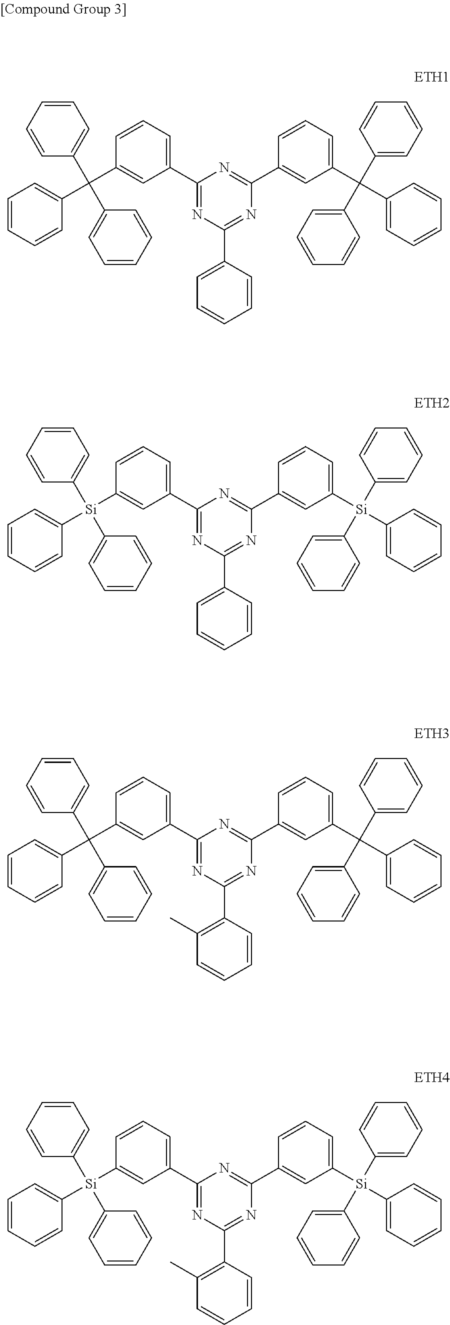 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

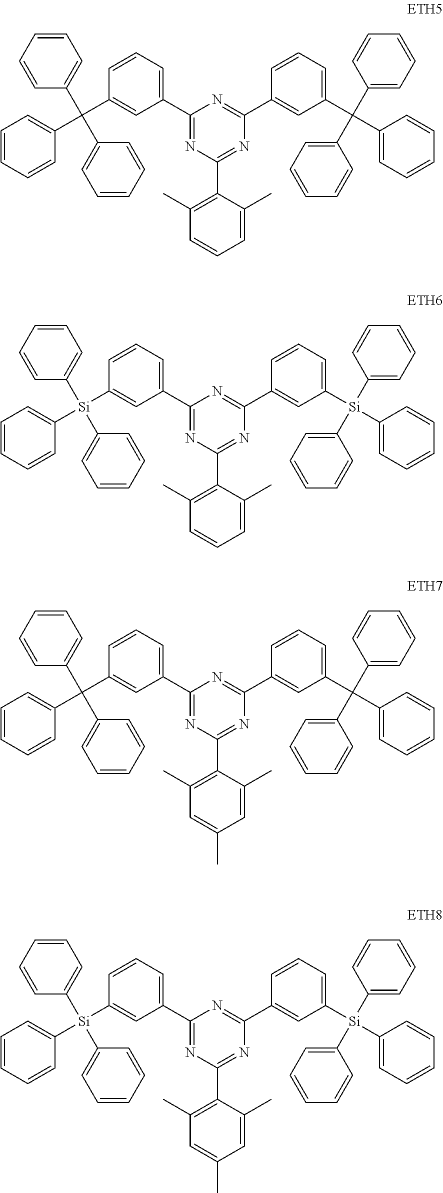 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

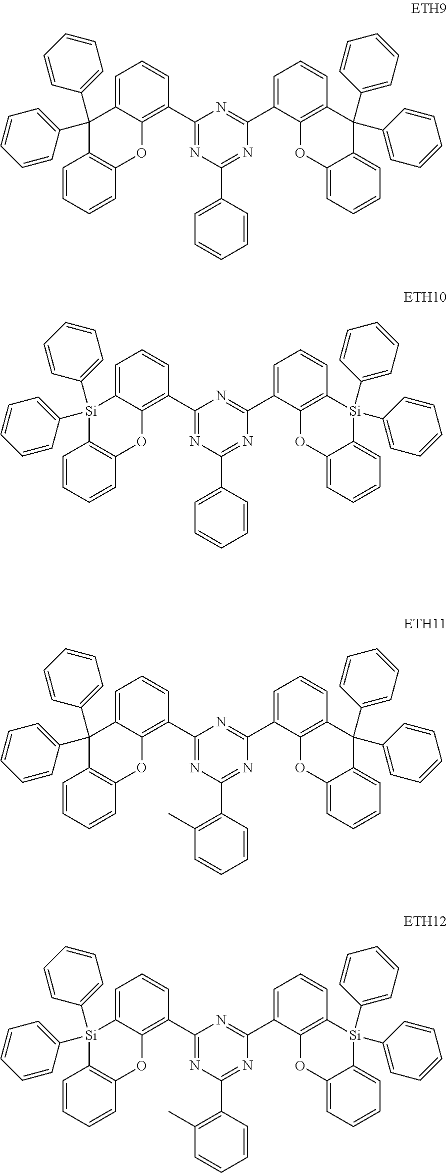 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

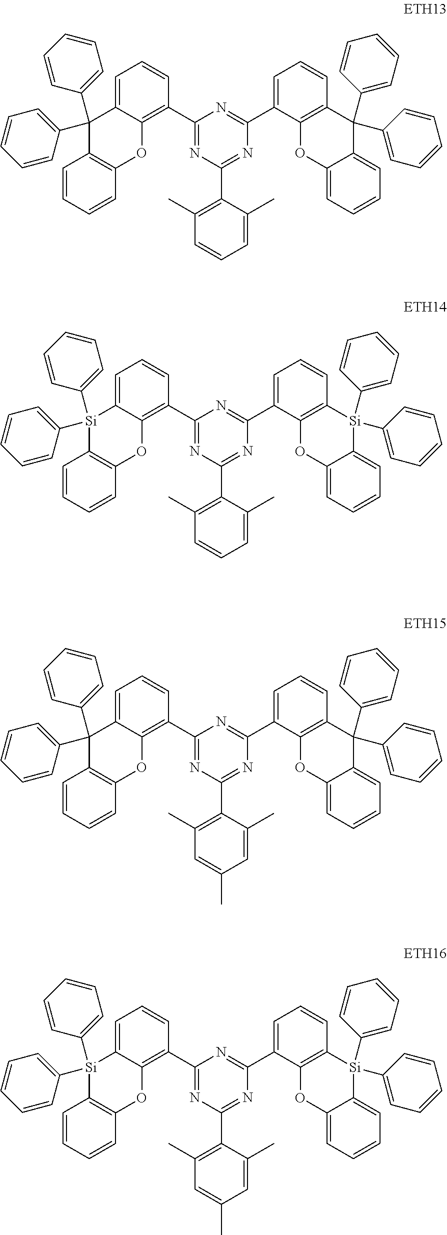 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

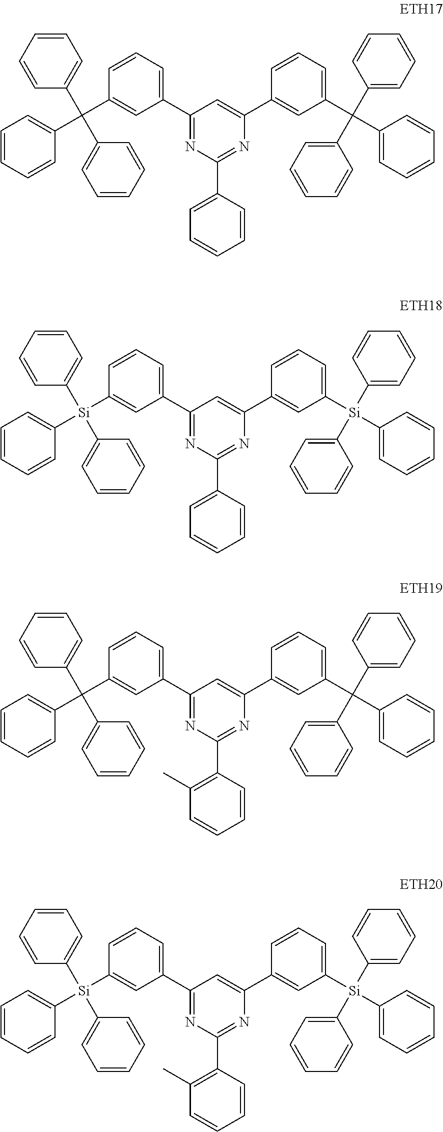 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

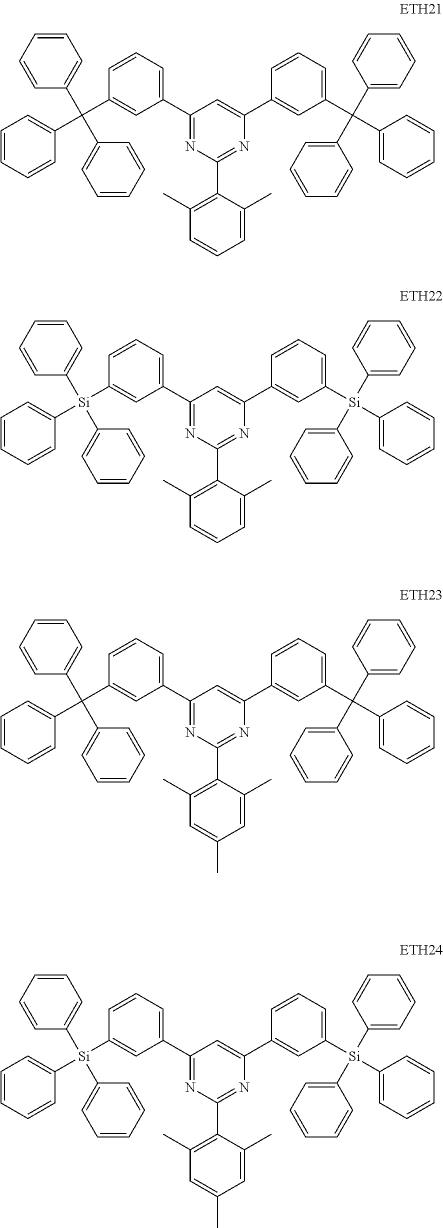 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

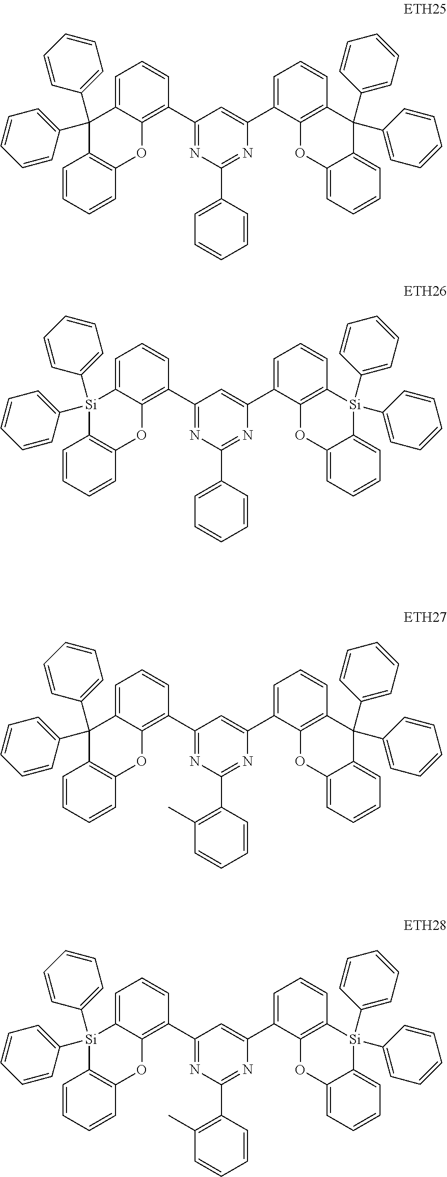 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

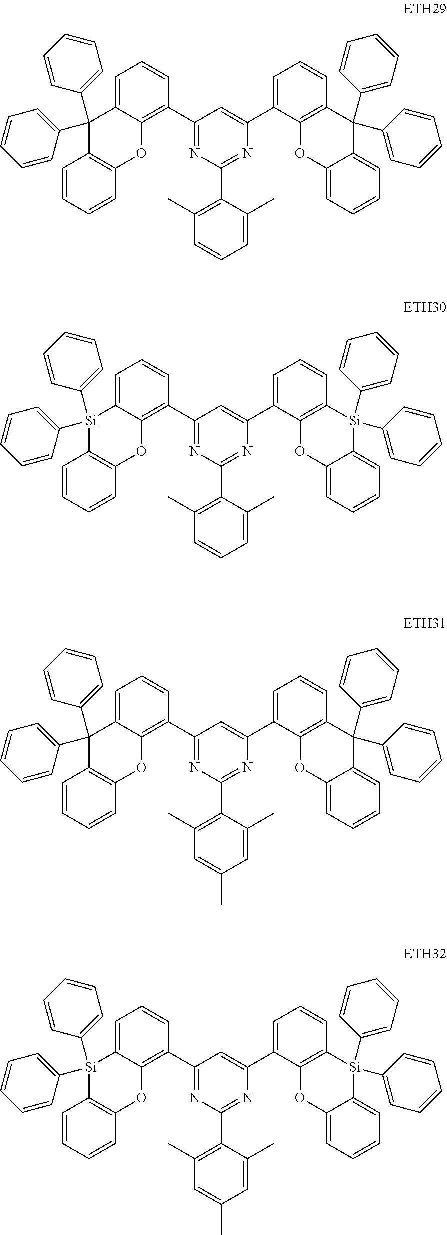 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

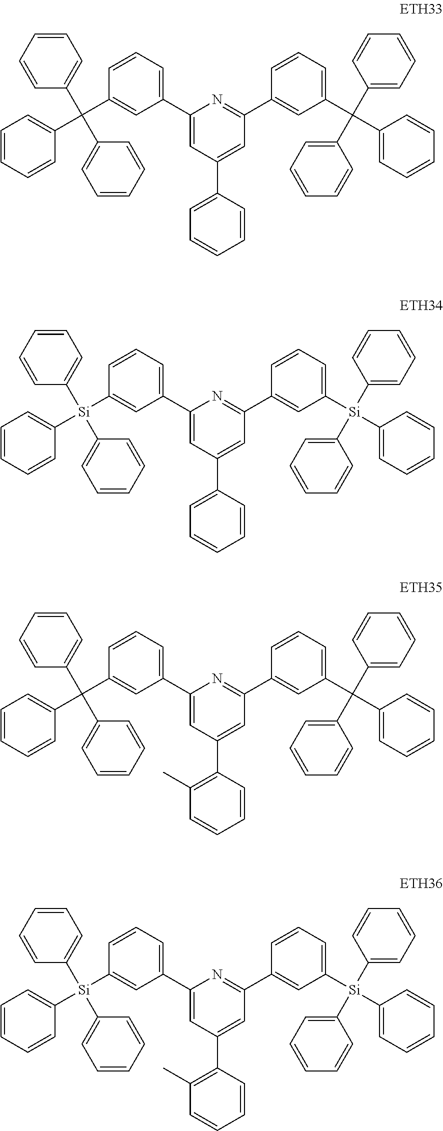 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

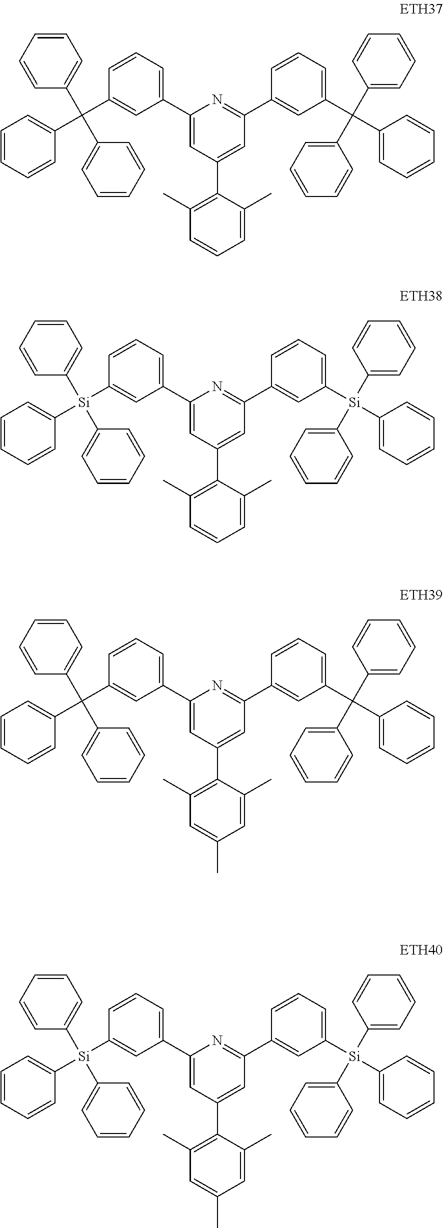 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

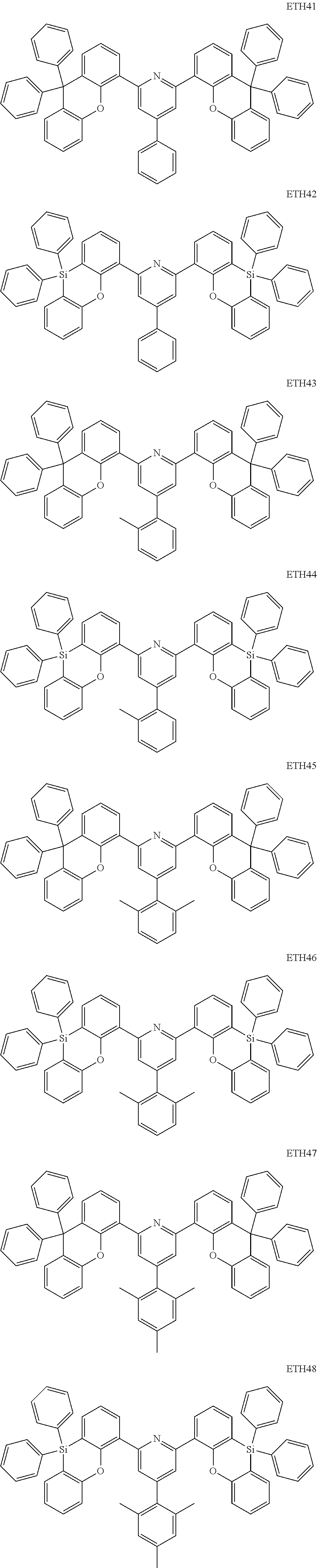

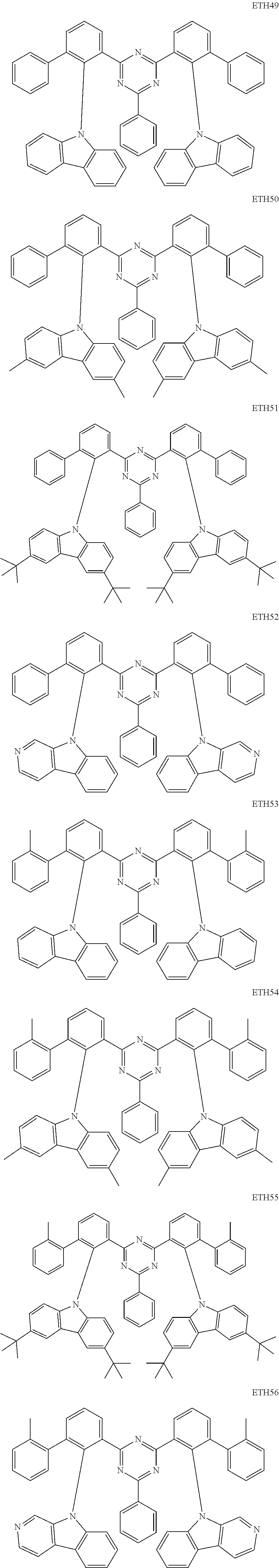

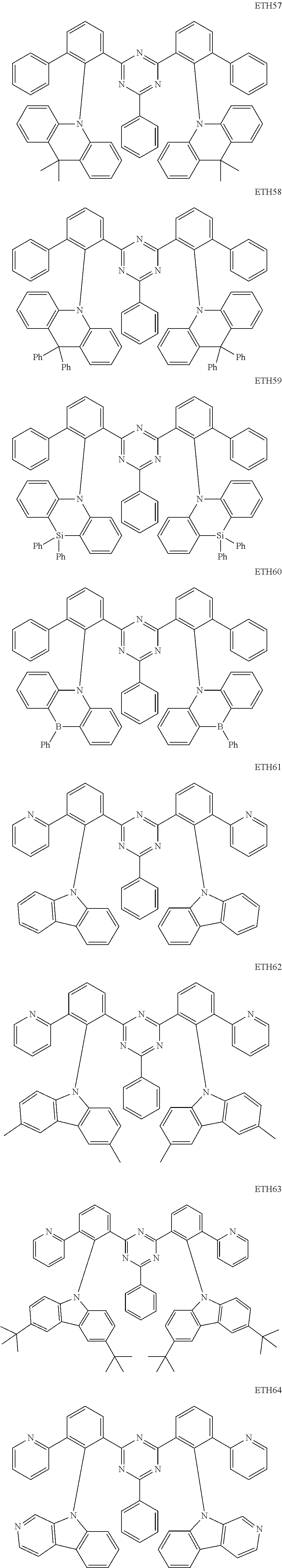

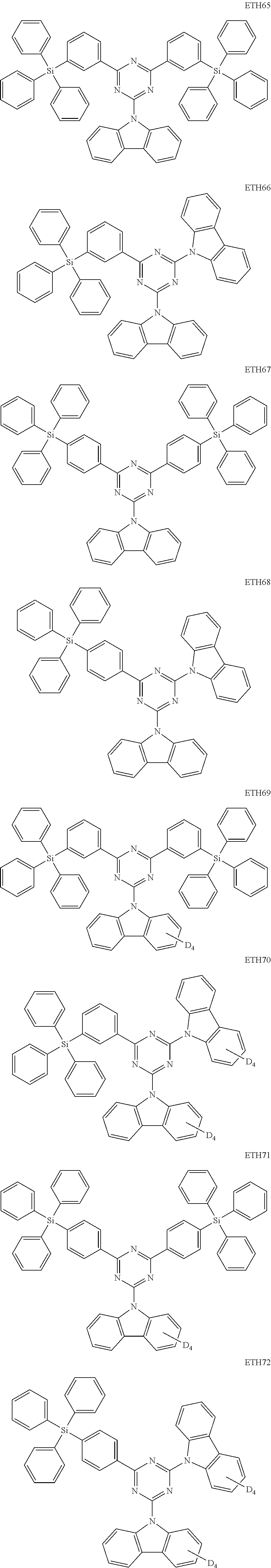

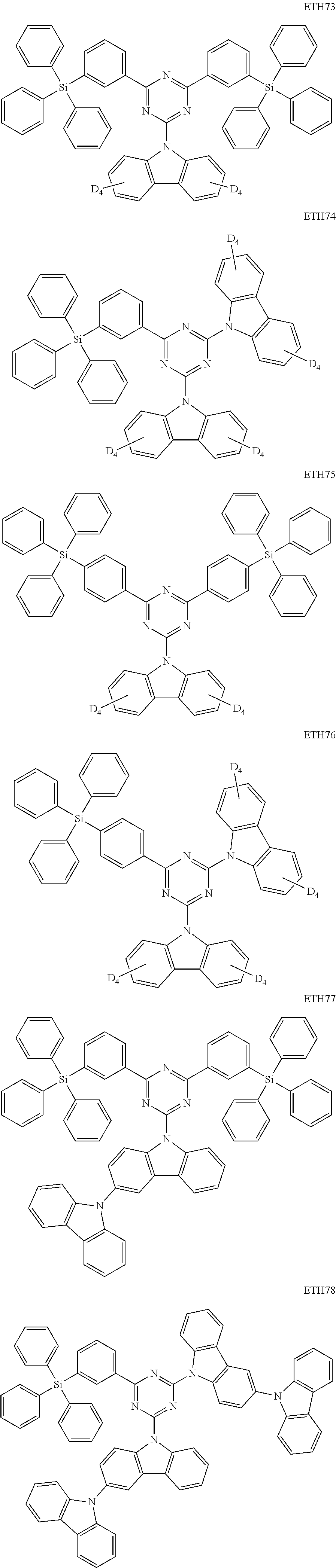

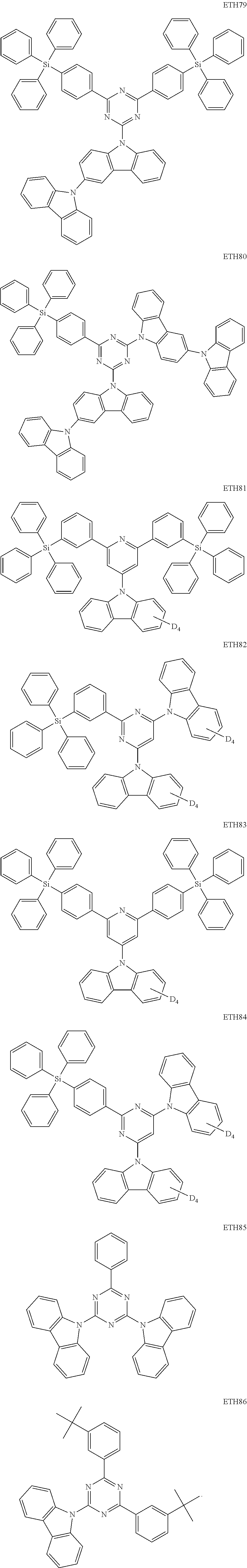

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transport host and an electron transport host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transporting host and the electron transporting host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound, thereby effecting light emission.

In an embodiment, the emission layer EML may further include, as a fourth compound, an organometallic complex that includes platinum (Pt) as a central metal atom and ligands linked to the central metal atom. In an embodiment, the emission layer EML may further include a fourth compound represented by Formula D-1:

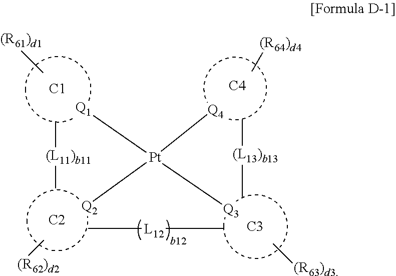

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage, *—O—*, *—S—*,

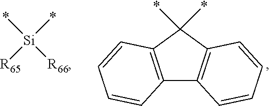

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, -* represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. When d1 to d4 are each 2 or more, multiple groups of each of R₆₁ to R₆₄ may all be the same, or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

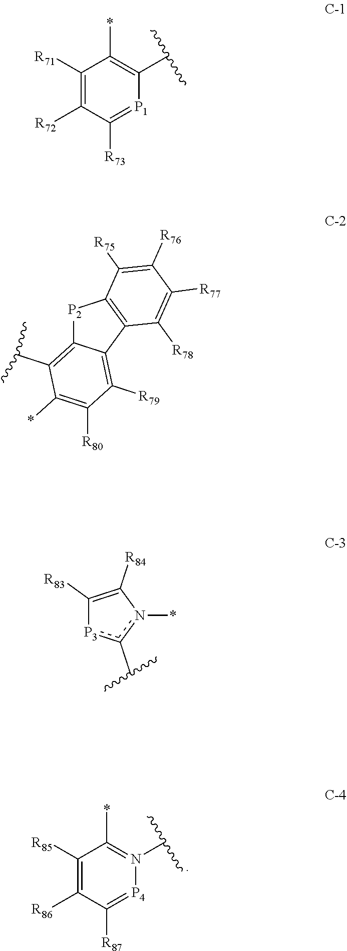

In Formula C-1 to Formula C-4, P₁ may be C—* or C(R₇₄), P₂ may be N—* or N(R₈₁), P₃ may be N—* or N(R₈₂), and P₄ may be C—* or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4,

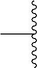

represents a bond to Pt, which is a central metal atom, and -* represents a bond to a neighboring cyclic group (C1 to C4) or to a linking moiety (L₁₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby effecting light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby effecting light emission. In an embodiment, the fourth compound may be a sensitizer. In the light emitting element ED, the fourth compound included in the emission layer EML may serve as a sensitizer that transfers energy from a host (for example, an exciplex host) to the first compound, which is a light emitting dopant. For example, the fourth compound, which serves as an auxiliary dopant, may accelerate energy delivery to the first compound, which serves as a light emitting dopant, thereby increasing an emission ratio of the first compound. Therefore, the emission layer EML may exhibit improved luminous efficiency. When energy transfer to the first compound increases, excitons formed in the emission layer EML may not accumulate and may rapidly emit light, so that deterioration of the light emitting element ED may be reduced. Accordingly, the service life of the light emitting element ED may increase.

The light emitting element ED may include the first compound, the second compound, the third compound, and the fourth compound, and the emission layer EML may include the combination of two host materials and two dopant materials. In the light emitting element ED, the emission layer EML may simultaneously include the second compound and the third compound, which are two different hosts, the first compound that emits delayed fluorescence, and the fourth compound that includes an organometallic complex, and thus the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4.

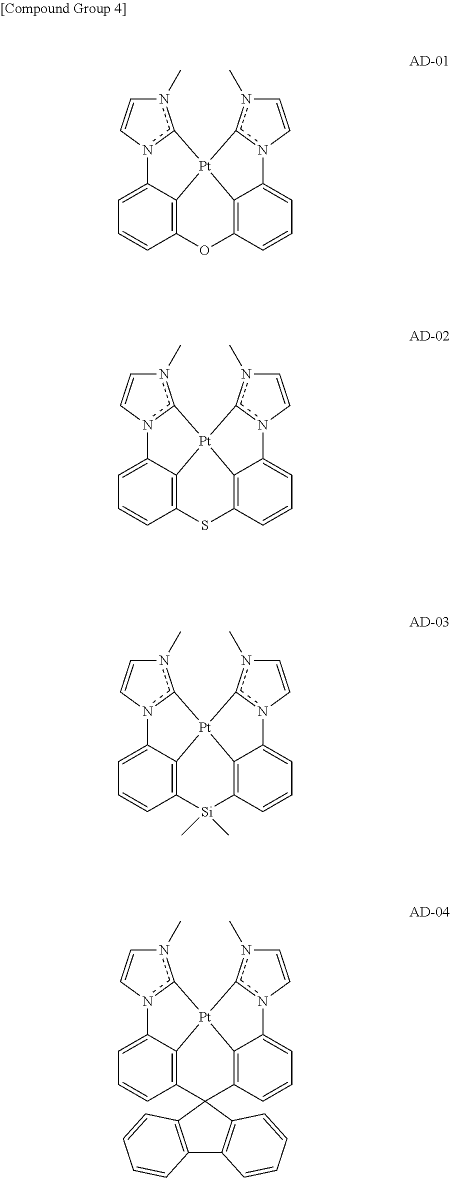

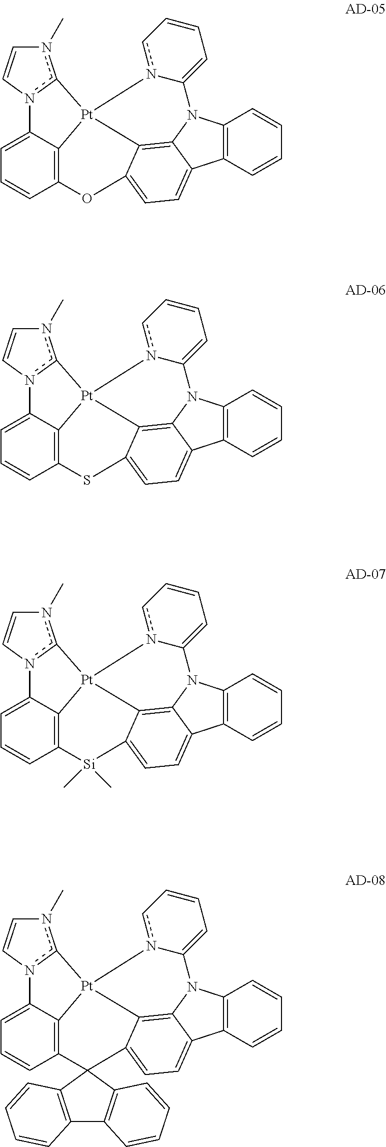

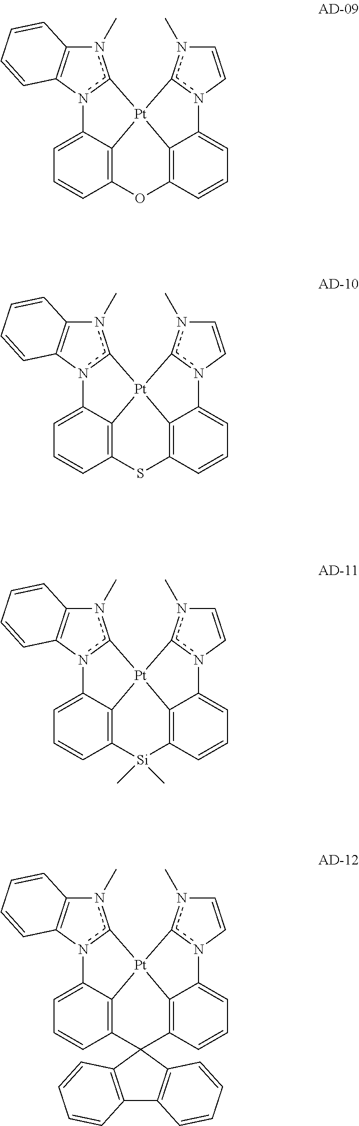

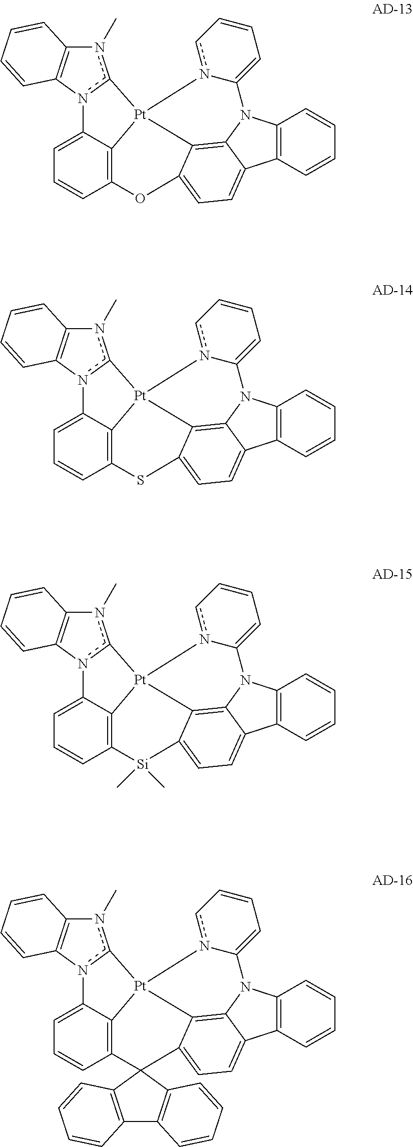

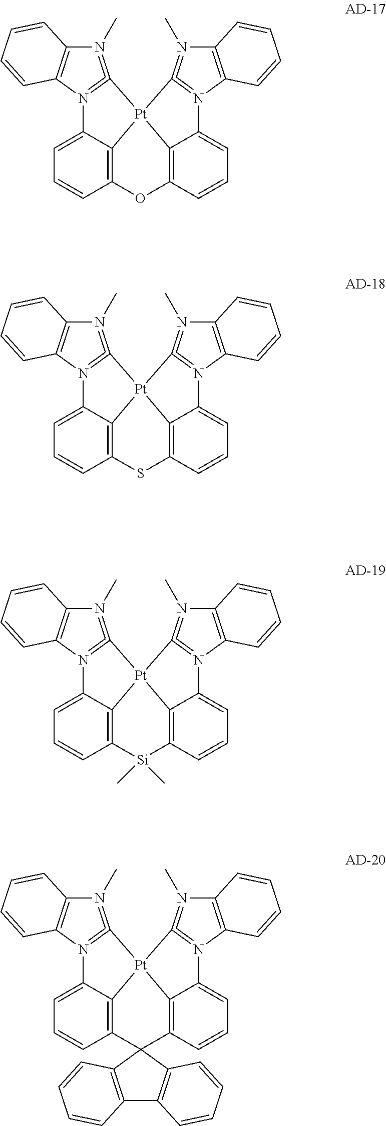

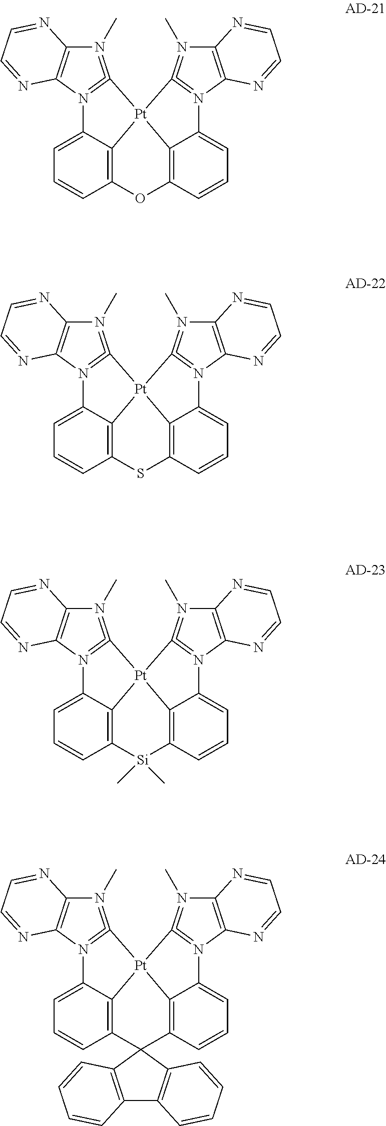

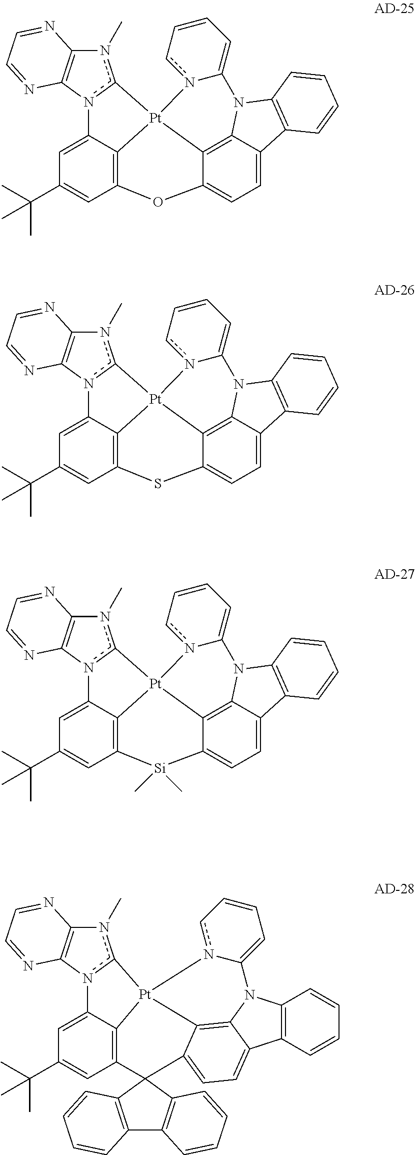

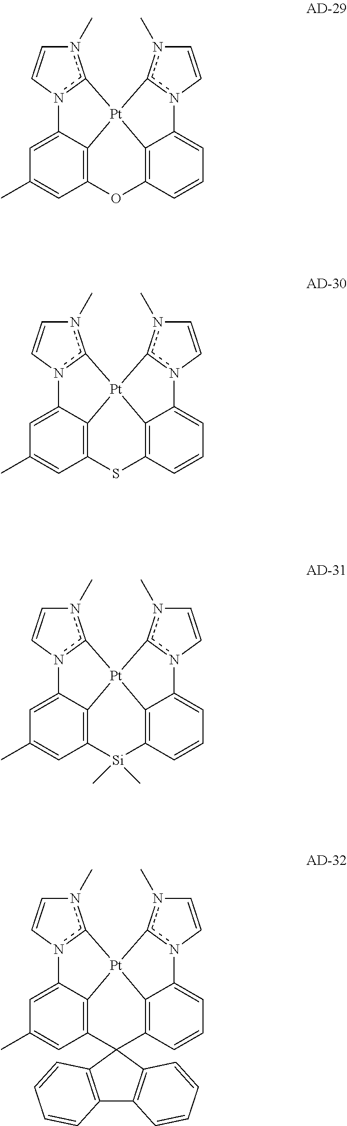

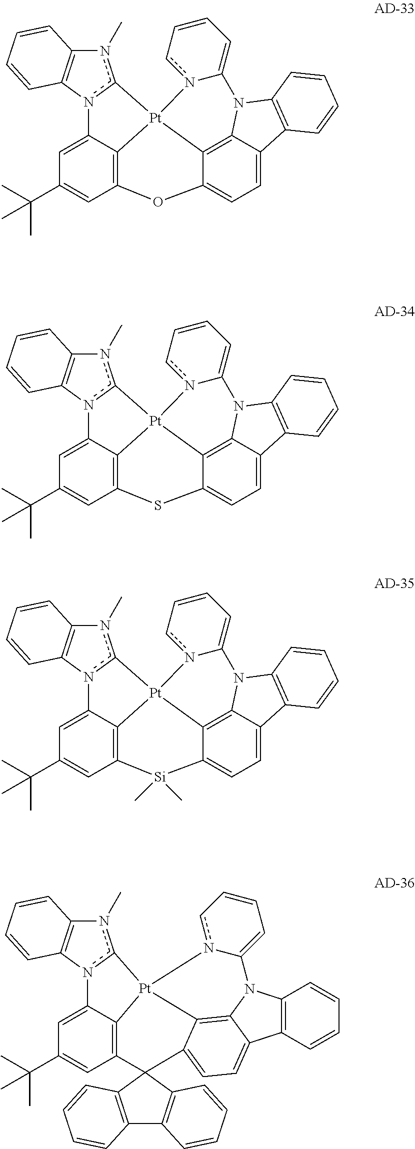

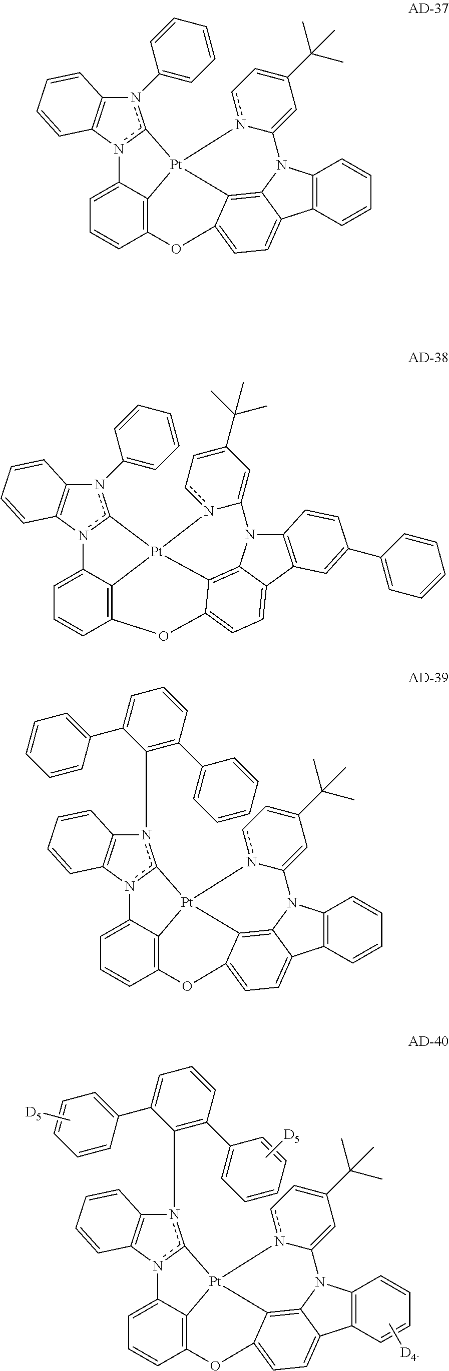

In Compound Group 4, D represents a deuterium atom.

In the light emitting element ED, when the emission layer EML includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the range described above, energy transfer from the second compound and the third compound to the first compound may increase, and thus luminous efficiency and element service life may increase.

In the emission layer EML, a total amount of the second compound and the third compound may be the remainder of the total weight of the first compound, the second compound, and the third compound, excluding the amount of the first compound. For example, a combined amount of the second compound and the third compound in the emission layer EML may be in a range of about 65 wt % to about 95 wt %, with respect to a total weight of the first compound, the second compound, and the third compound.

Within the combined amount of the second compound and the third compound in the emission layer EML, a weight ratio of the second compound to the third compound may be in a range of about 3:7 to about 7:3.

When the amounts of the second compound and the third compound satisfy the above-described ranges and ratios, charge balance characteristics in the emission layer EML may be improved, and thus luminous efficiency and element service life may increase. When the amounts of the second compound and the third compound deviate from the above-described ranges and ratios, charge balance in the emission layer EML may not be achieved, so that luminous efficiency may be reduced and the element may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from a host (for example, an exciplex host) to the first compound, which is a light emitting dopant, may increase, so that an emission ratio may improve. Accordingly, luminous efficiency of the emission layer EML may improve. When the amounts of the first compound, the second compound, the third compound, and the fourth compound included in the emission layer EML satisfy the above-described ranges and ratios, excellent luminous efficiency and long service life may be achieved.

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting elements ED according to embodiments as shown in each of FIGS. 3 to 7, the emission layer EML may further include hosts and dopants of the related art, in addition to the above-described host and dopant.

In an embodiment, the emission layer EML may include a compound represented by Formula E-1. The compound represented by Formula E-1 may be used as a fluorescent host material:

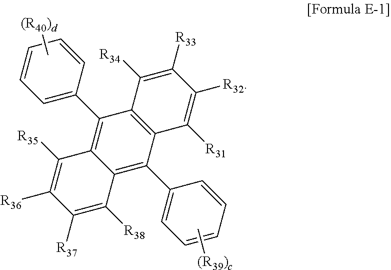

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

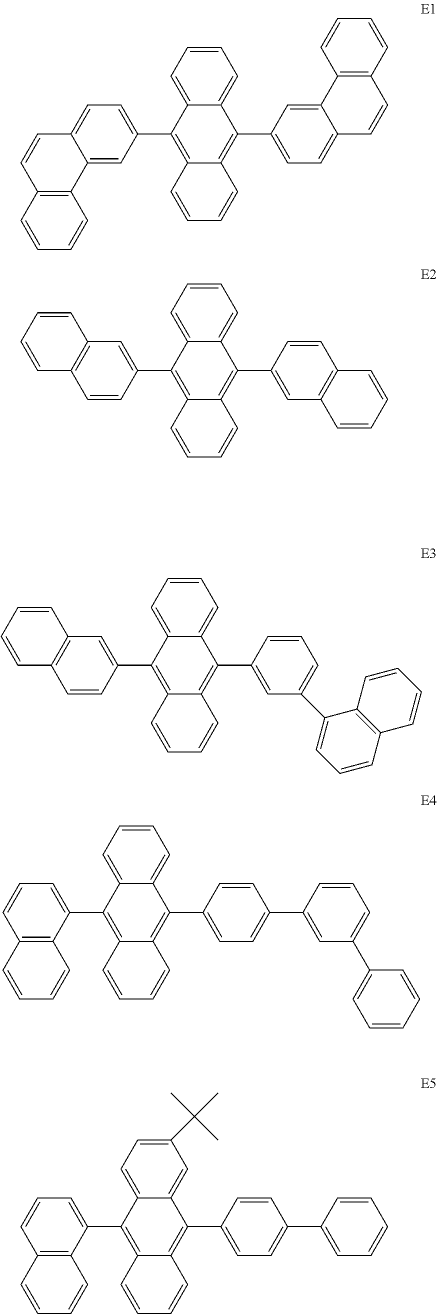

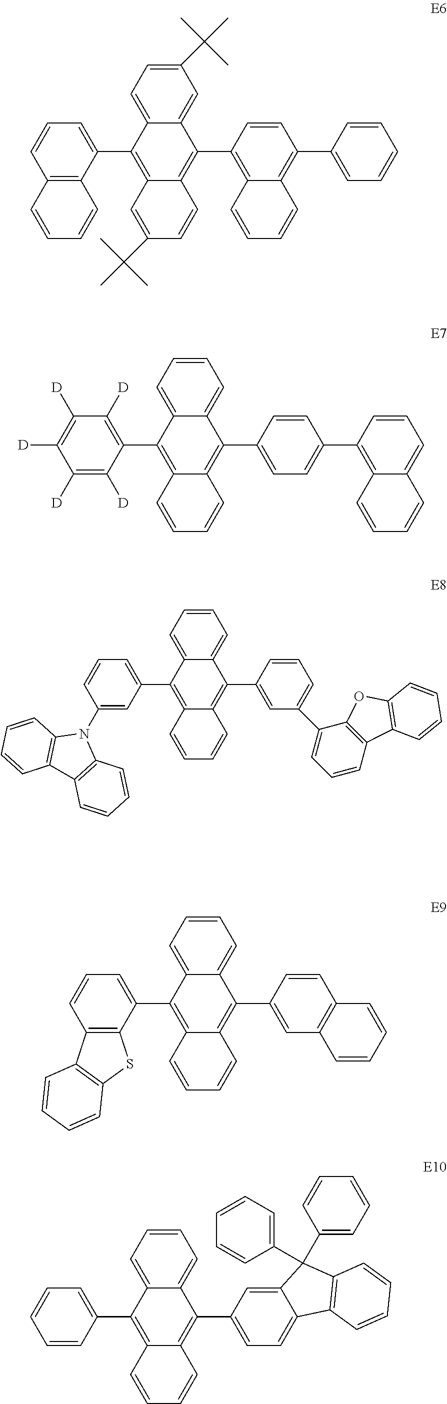

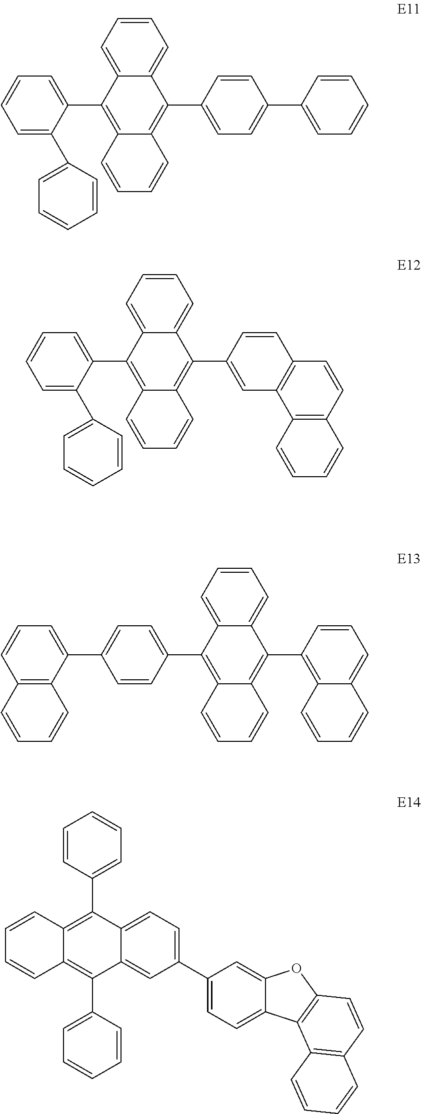

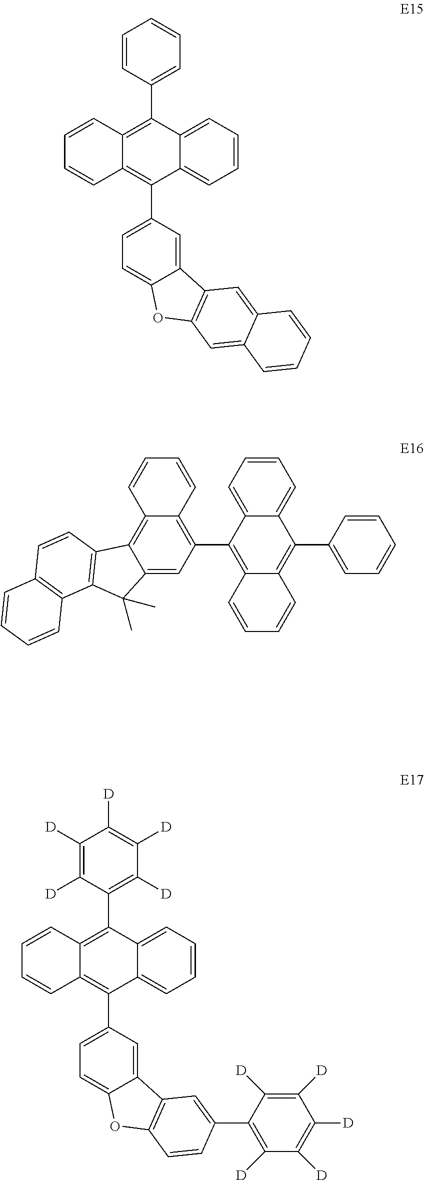

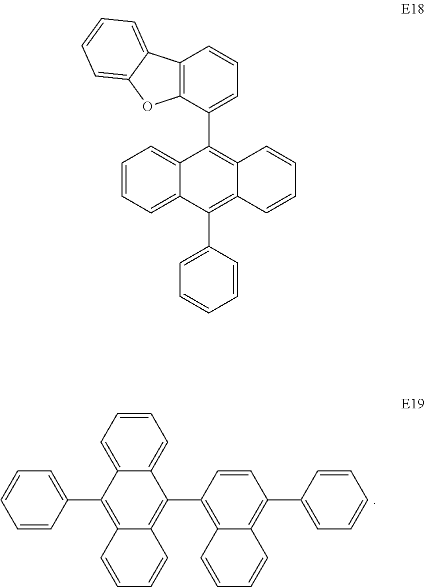

In an embodiment, the emission layer EML may include a compound represented by Formula E-2a or Formula E-2b. The compound represented by Formula E-2a or Formula E-2b below may be used as a phosphorescent host material.

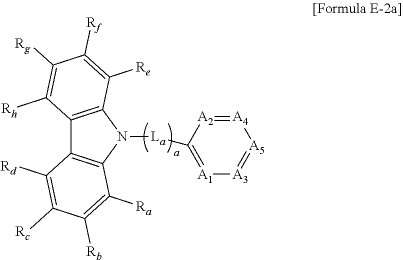

In Formula E-2a, a may be an integer from 0 to 10; and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

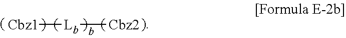

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2.

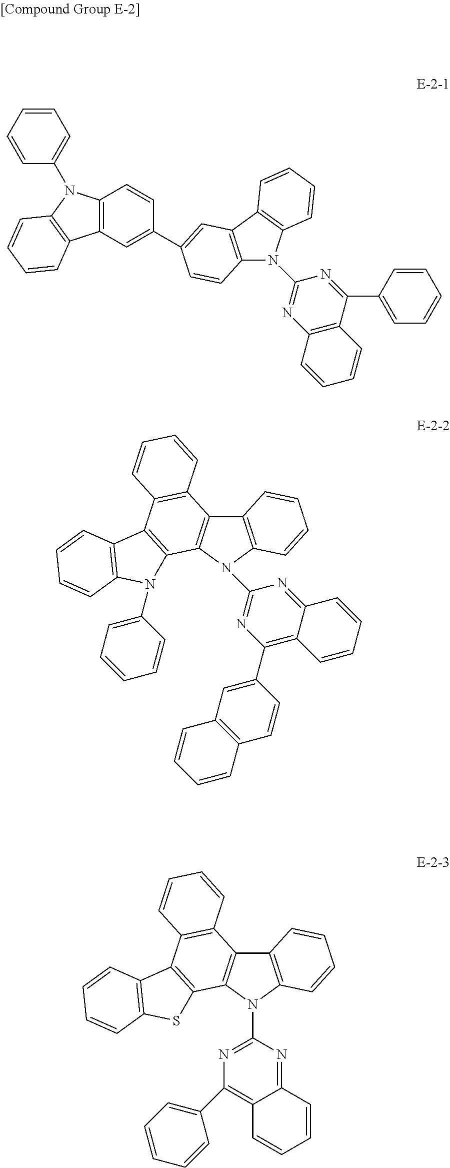 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

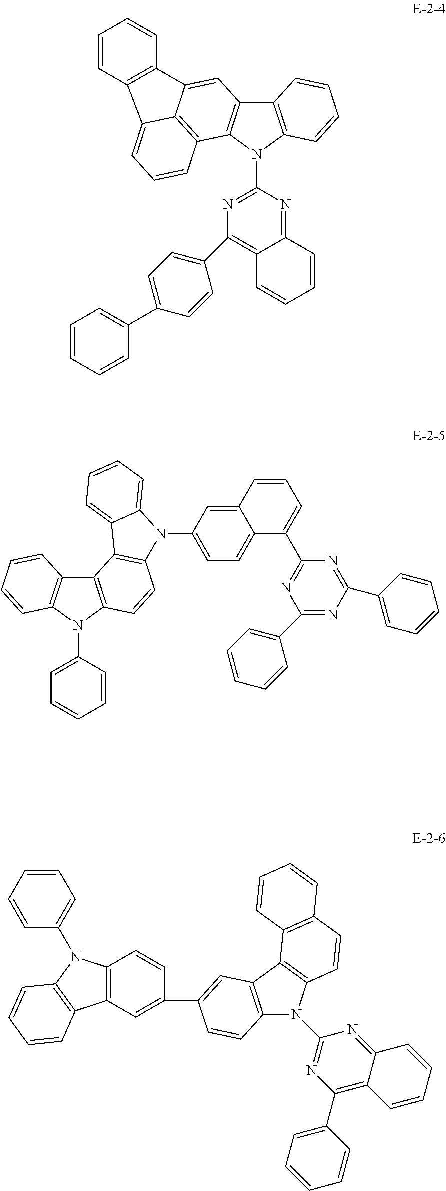 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

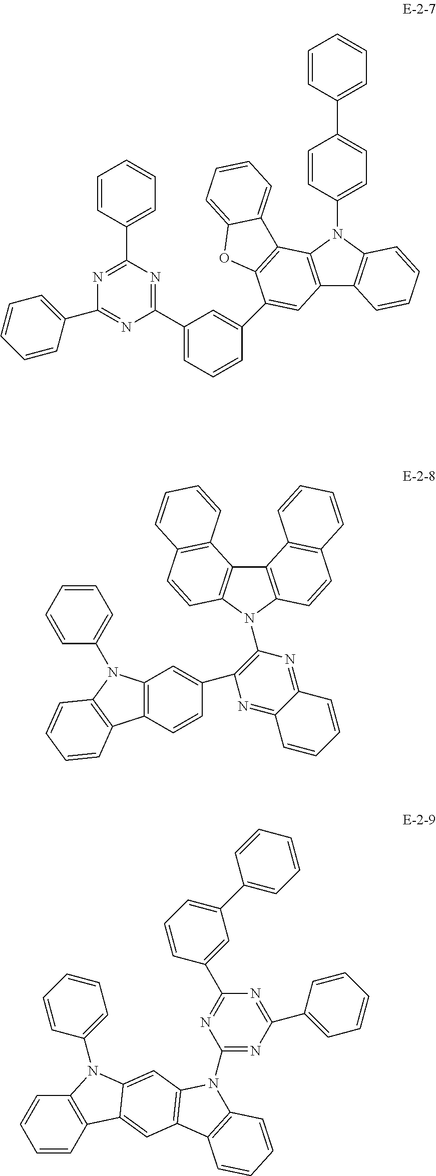 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

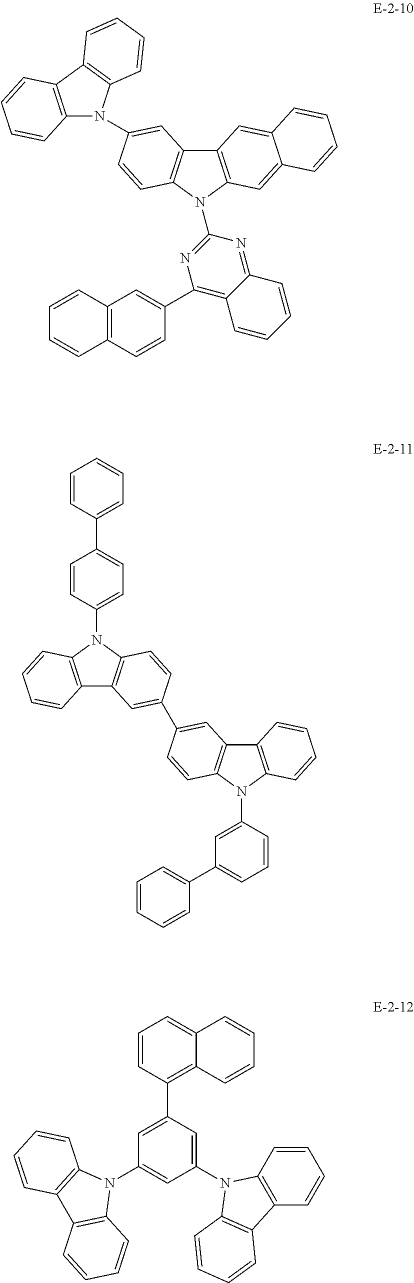 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

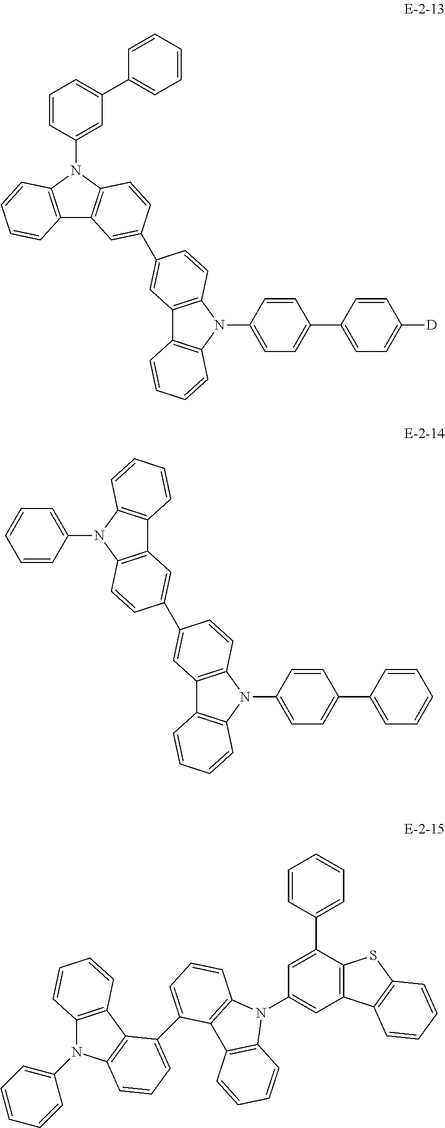 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

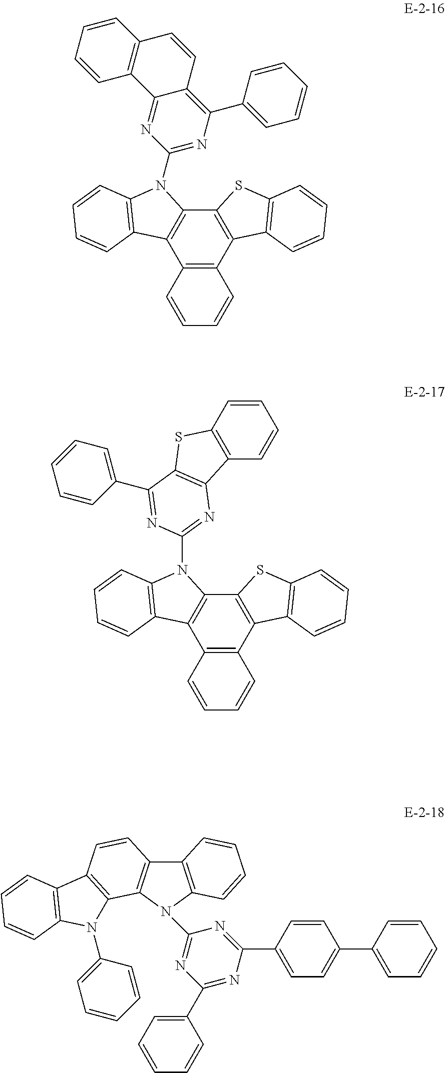 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

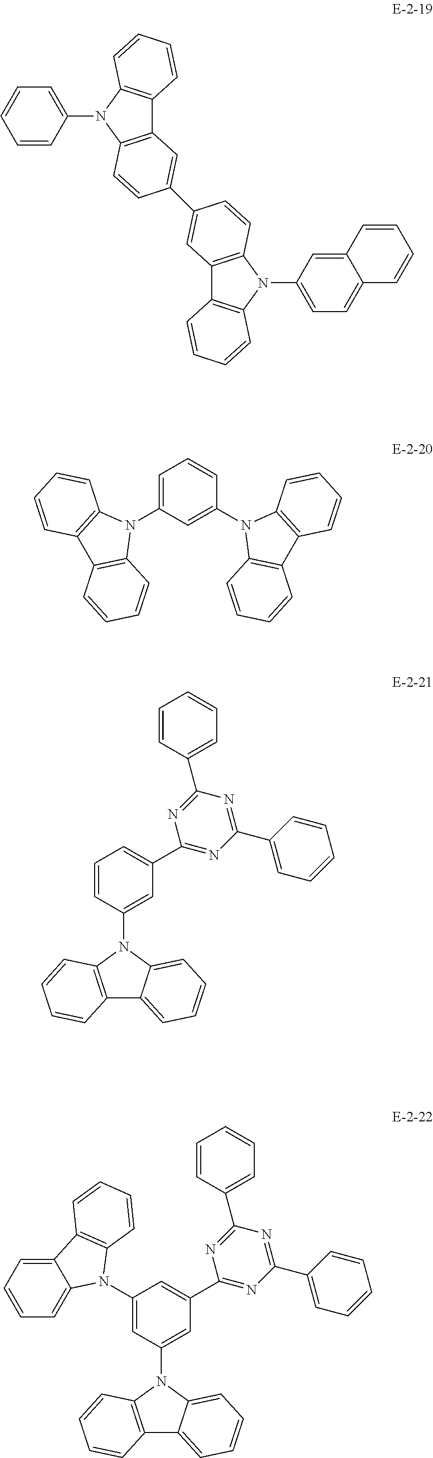 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

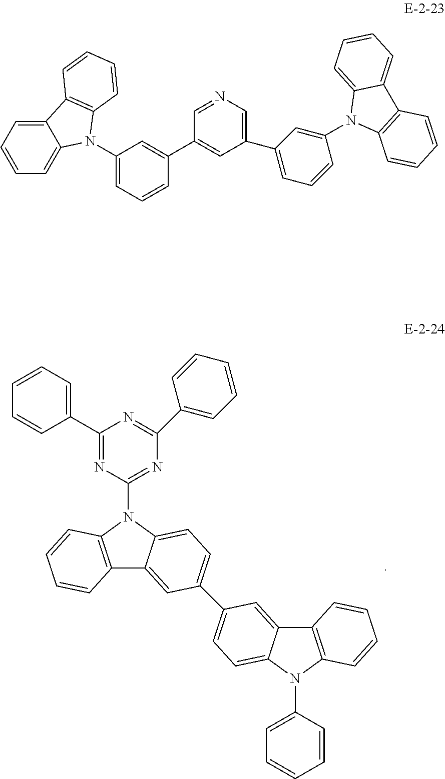 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In an embodiment, the emission layer EML may include a compound represented by Formula M-a. The compound represented by Formula M-a below may be used as a phosphorescent dopant material.

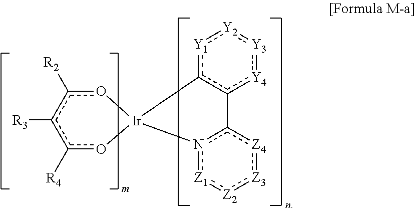

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a maybe any compound selected from Compound M-al to Compound M-a25. However, Compounds M-al to M-a25 are only examples, and the compound represented by Formula M-a is not limited to Compounds M-al to M-a25:

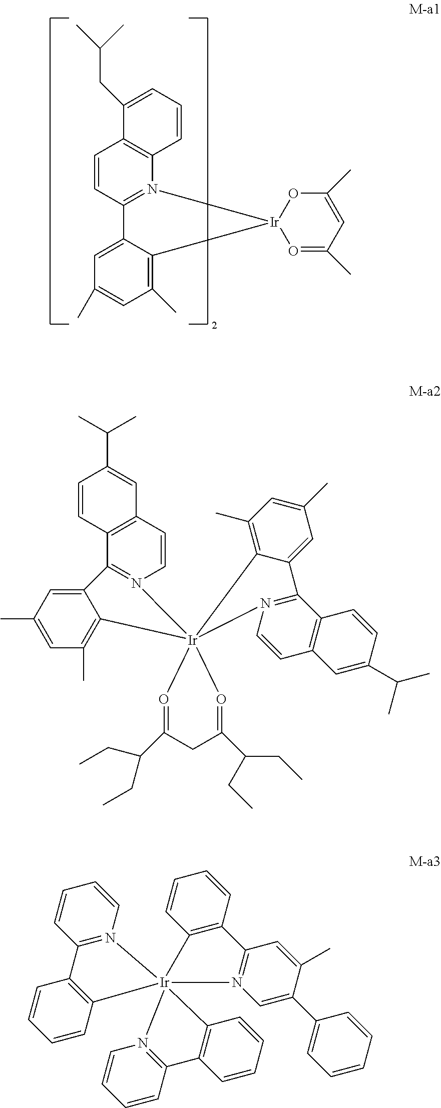

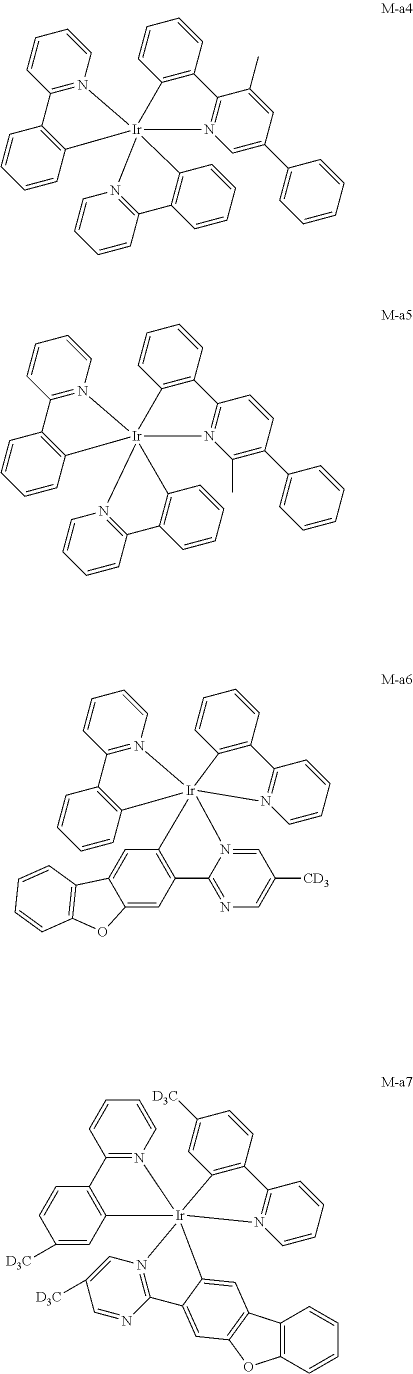

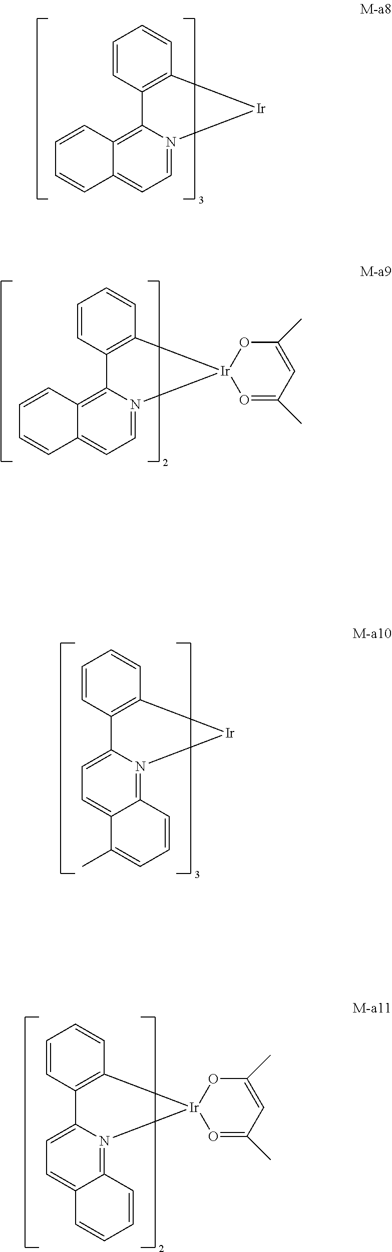

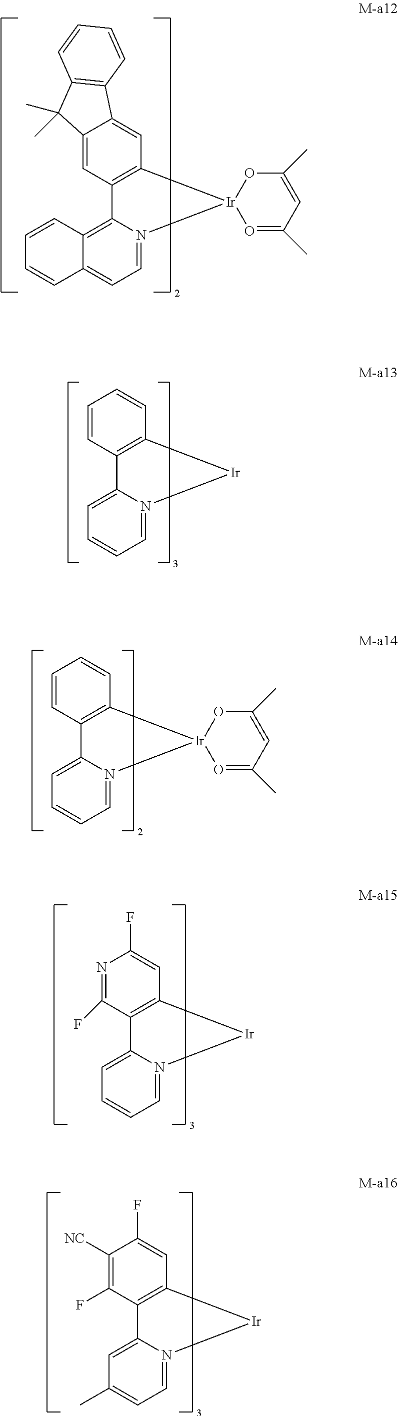

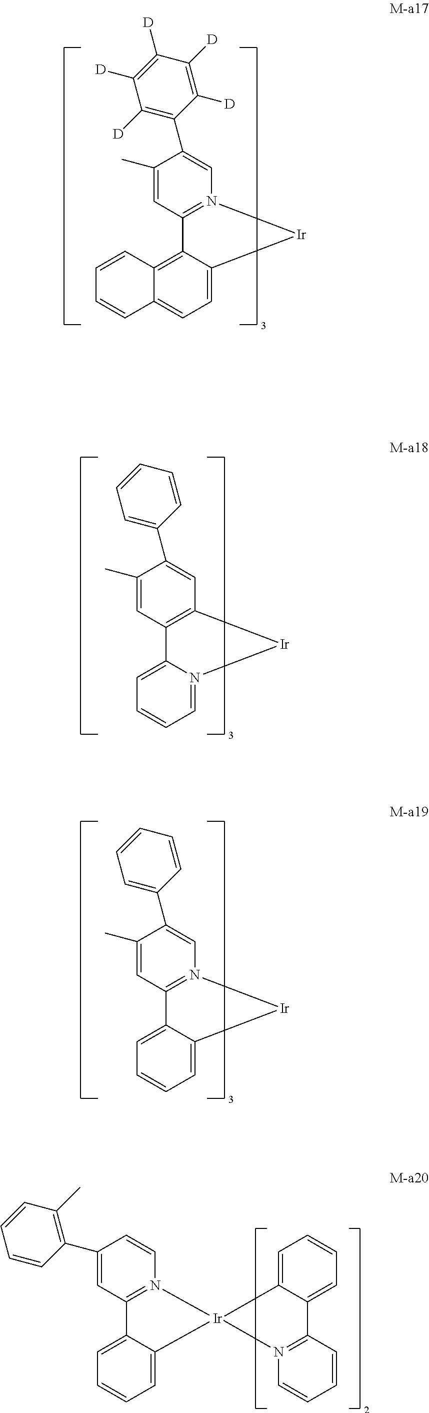

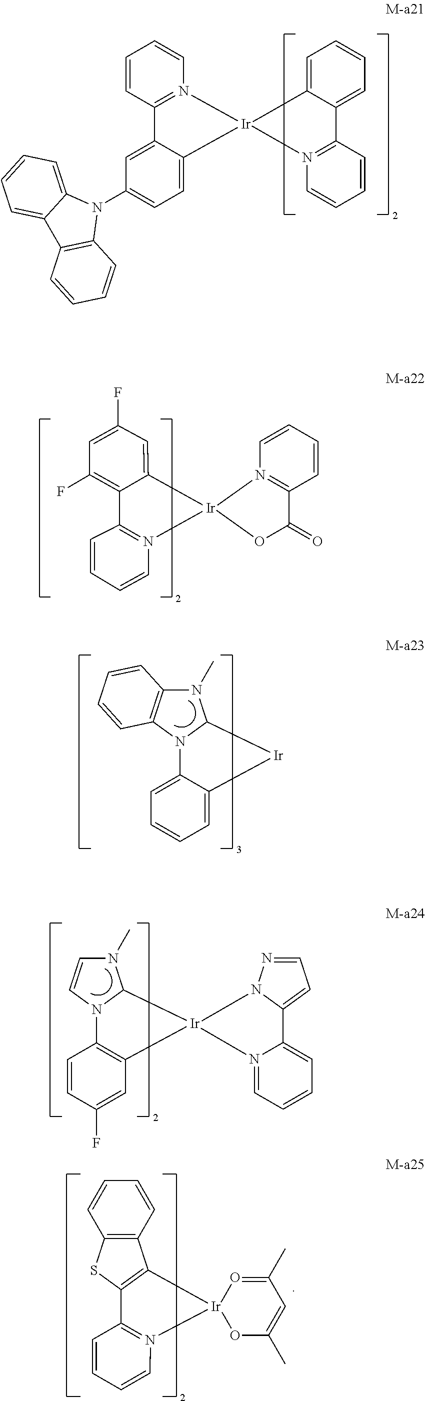

In an embodiment, the emission layer EML may include a compound represented by one of Formula F-a to Formula F-c. The compound represented by one of Formula F-a to Formula F-c may be used as a fluorescence dopant material.

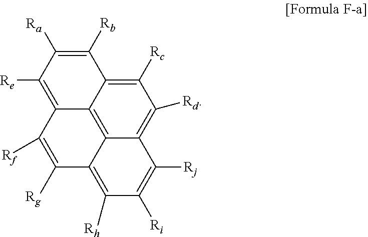

In Formula F-a, two of Rₐ to Rⱼ may each independently be substituted with a group represented by *—NAr₁Ar₂. The remainder of Rₐ to Rⱼ that are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by *—NA₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

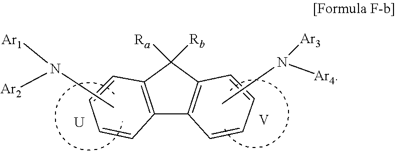

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

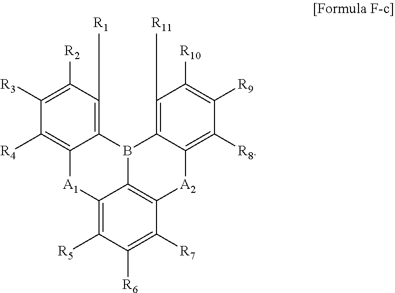

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a fused ring, and/or A₂ may be bonded to R₇ or R₈ to form a fused ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N, C2′)picolinate) (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may include a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof, and any combination thereof.

In an embodiment, a Group II-VI compound may further include a Group I element and/or a Group IV element. Examples of a Group I-II-VI compound may include CuSnS and CuZnS; and examples of a Group II-IV-VI compound may include ZnSnS, etc. Examples of a Group I-II-IV-VI compound may include a quaternary compound such as Cu₂ZnSnS₂, Cu₂ZnSnS₄, Cu₂ZnSnSe₄, Ag₂ZnSnS₂, and any combination thereof.

Examples of a Group II-IV-V compound may include a ternary compound such as ZnSnP, ZnSnP₂, ZnSnAs₂, ZnGeP₂, ZnGeAs₂, CdSnP₂, CdGeP₂, and any combination thereof.

Examples of a Group III-VI compound may include: a binary compound such as GaS, Ga₂S₃, GaSe, Ga₂Se₃, GaTe, InTe, InS, InSe, In₂S₃, or In₂Se₃; a ternary compound such as InGaS₃ or InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and a mixture thereof, a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof, a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, and any combination thereof. In an embodiment, a Group III-V compound may further include a Group II element. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof, a quaternary compound such as SnPbSSe, SnPbSeTe, SnPbSTe, and a mixture thereof, and any combination thereof. Examples of a Group IV element may include Si, Ge, and a mixture thereof Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (where x may be a real number between 0 to 1).

In an embodiment, a quantum dot may have a single structure in which the concentration of each element included in the quantum dot is uniform. In an embodiment, a quantum dot may have a core-shell structure in which a quantum dot material surrounds another quantum dot. For example, a material included in the core may be different from a material included in the shell.

The shell of a quantum dot may serve as a protection layer that presents chemical deformation of the core to maintain semiconductor properties, and/or may serve as a charging layer that imparts electrophoretic properties to the quantum dot. The shell may have a single-layered structure or a multilayered structure. An interface between the core and the shell may have a concentration gradient in which the concentration of an element that is present in the shell decreases towards the core.

In embodiments, the quantum dot may have the above-described core-shell structure that includes a core containing nanocrystals and a shell surrounding the core. Examples of a shell of a quantum dot may include a metal oxide, a non-metal oxide, a semiconductor compound, or a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound such as MgAl₂O₄, CoFe₂O₄, NiFe₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have an FWHM of an emission spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, a quantum dot may have a spherical shape, a pyramidal shape, a multi-arm shape, or a cubic shape, or a quantum dot may be the form of nanoparticles, nanotubes, nanowires, nanofibers, nanoplate particles, etc.

As a size of a quantum dot is adjusted or an elemental ratio in the quantum dot compound is adjusted, an energy band gap may be changed accordingly, so that light in various wavelength ranges may be emitted by a quantum dot emission layer. Therefore, by utilizing a quantum dot as described above (for example, using different sizes of quantum dots or having different elemental ratios in a quantum dot compound), a light emitting element that emits light of various wavelengths may be implemented. For example, the size of the quantum dot or the elemental ratio of the quantum dot compound may be adjusted to emit red light, green light, and/or blue light. For example, quantum dots may be configured to emit white light by combining various colors of light.

In the light emitting elements ED according to embodiments as shown in each of FIGS. 3 to 7, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In an embodiment, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

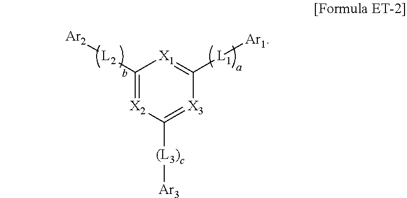

In Formula ET-2, at least one of X₁ to X₃ may each be N; and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Arₙ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalen-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

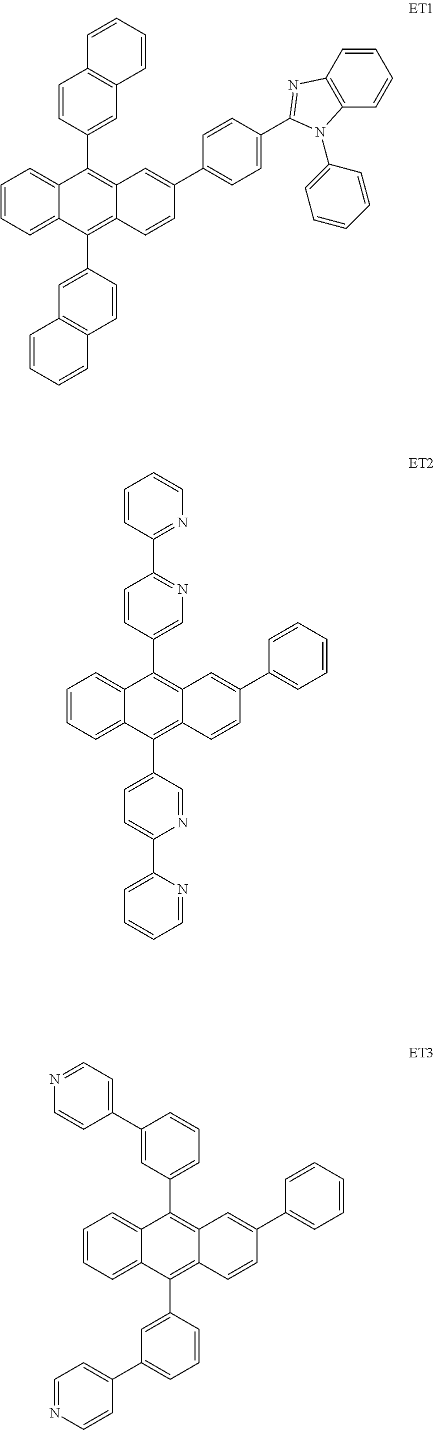 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

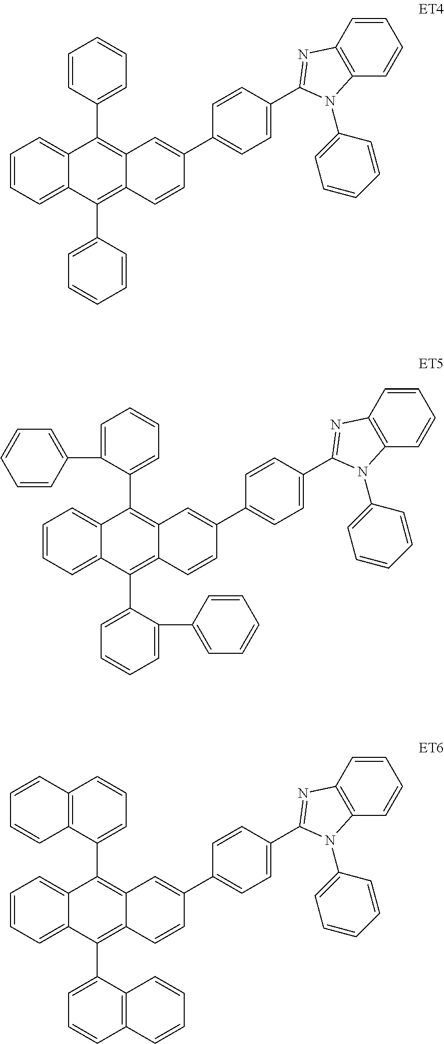 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

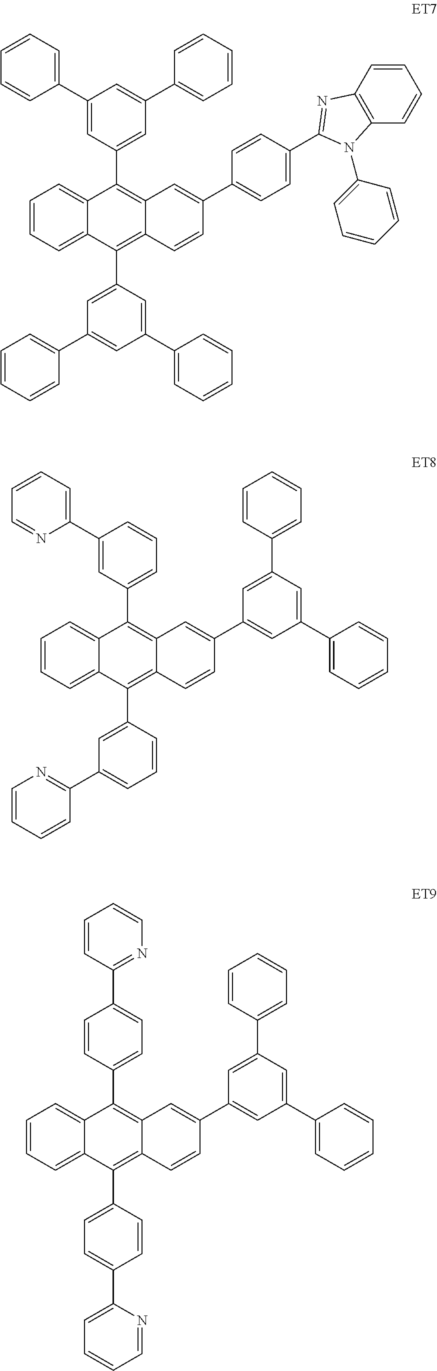 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

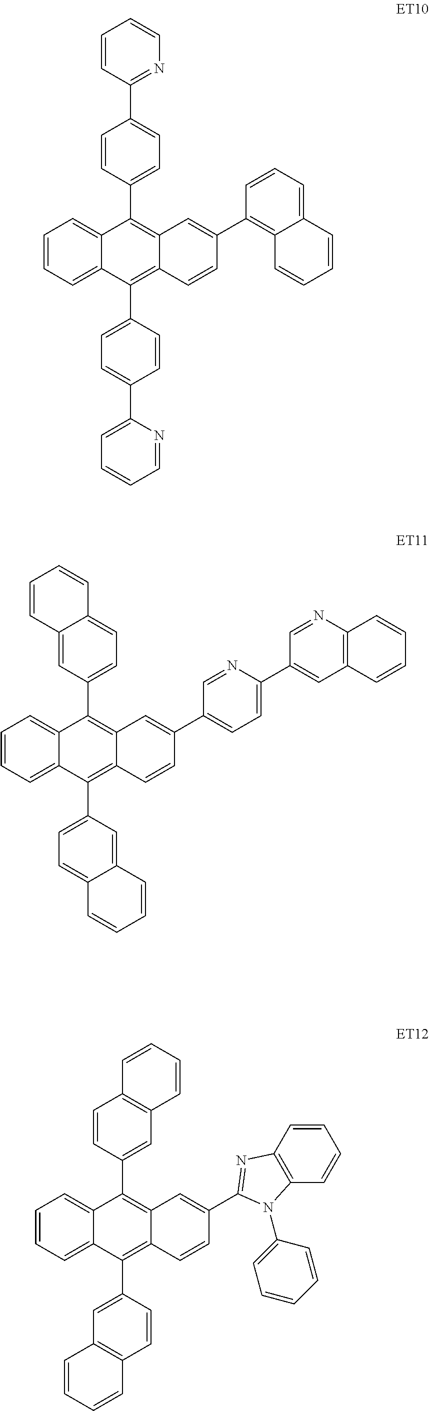 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

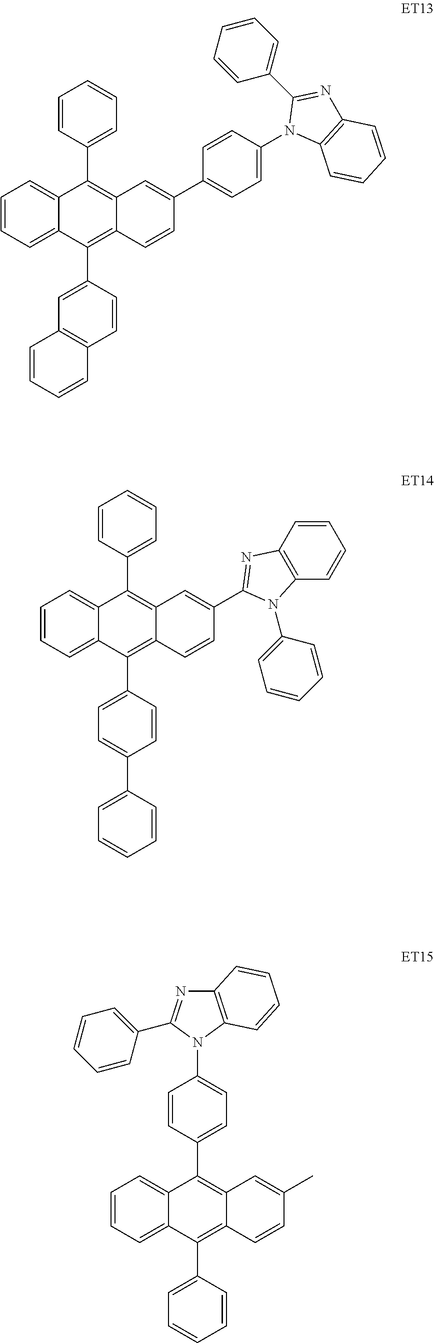 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

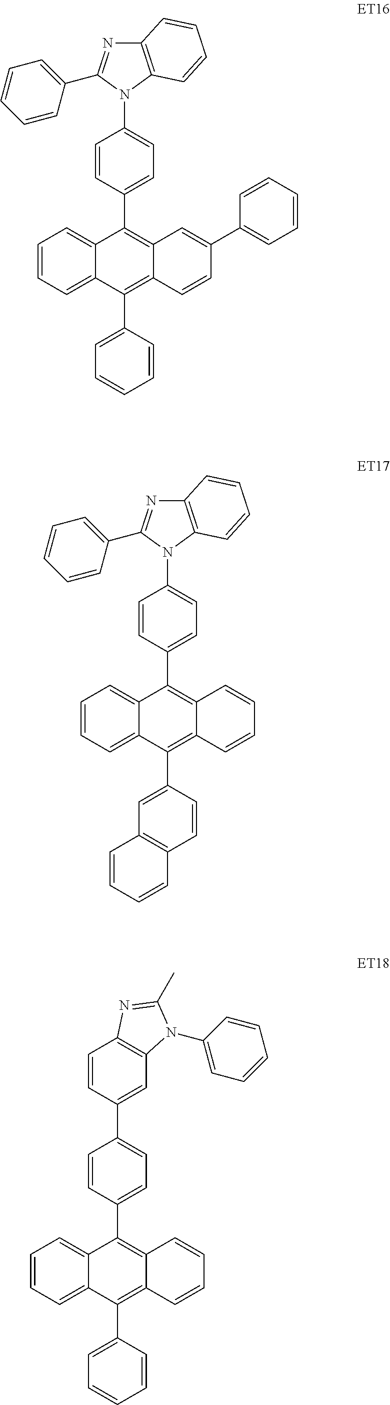 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

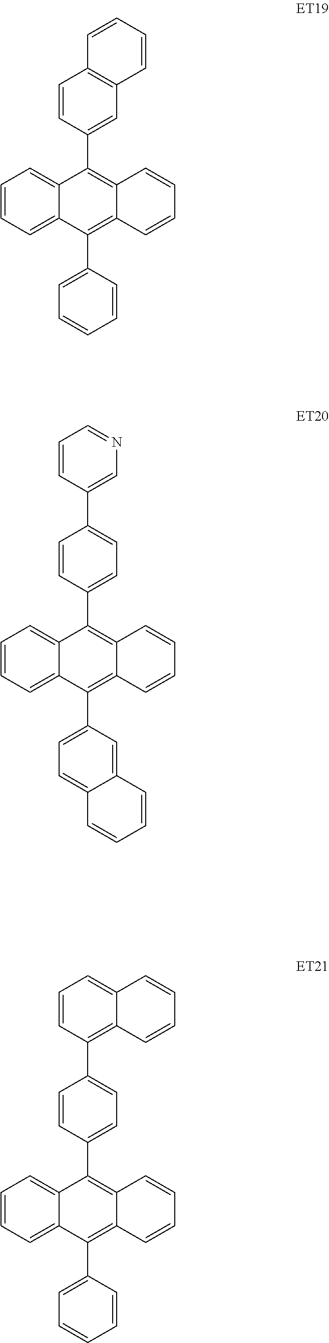

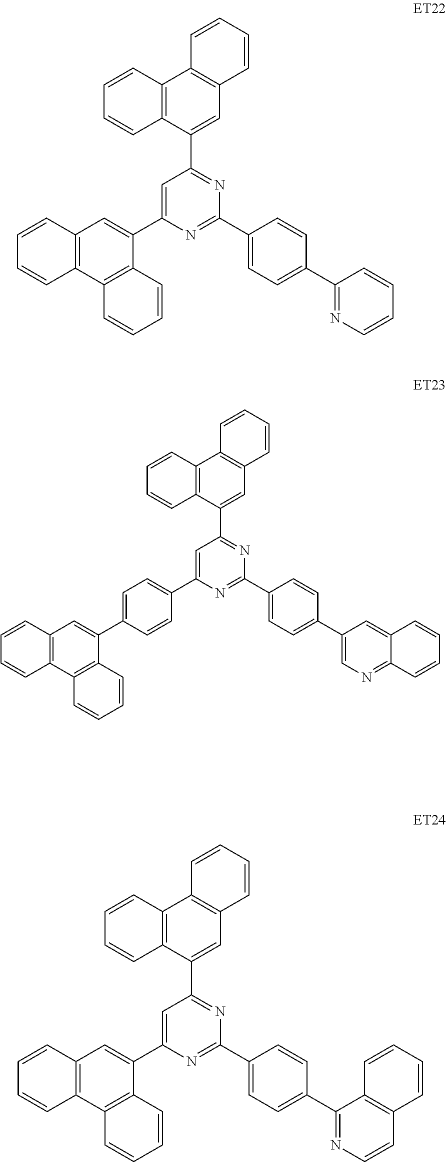 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

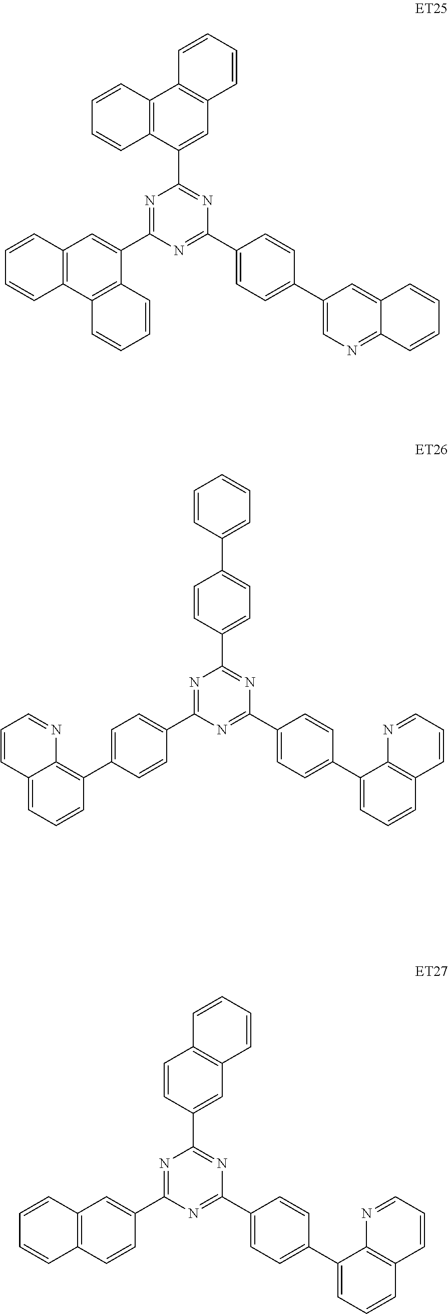 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

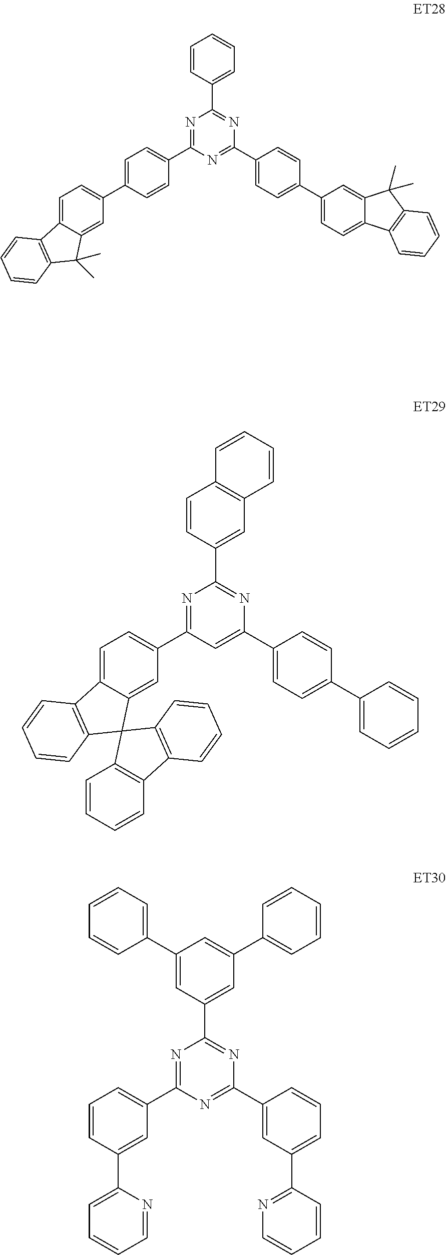 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

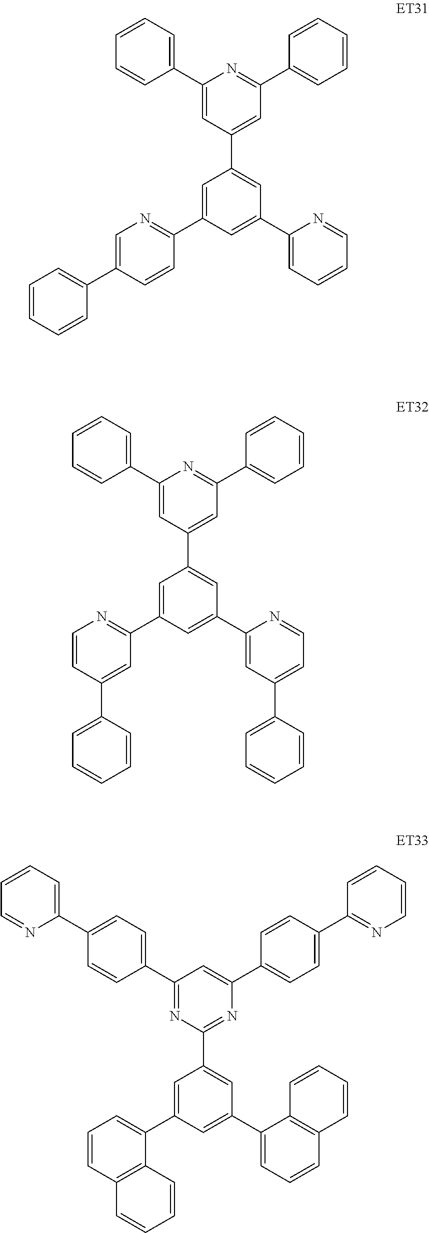 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

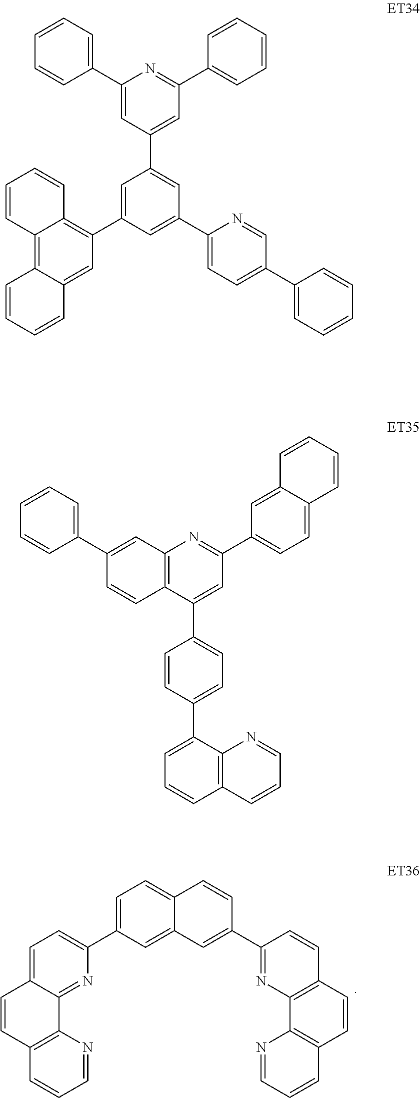 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of the metal halide and the lanthanide. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Lig), etc., but embodiments are not limited thereto. The electron transport region ETR may also be formed of a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof(e.g., AgMg, AgYb, or MgYb). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

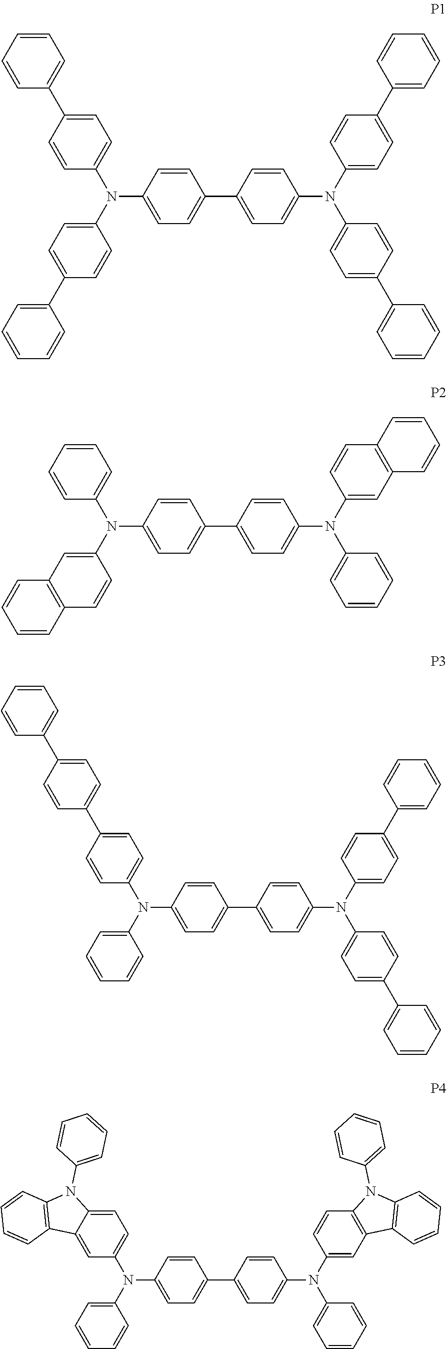 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

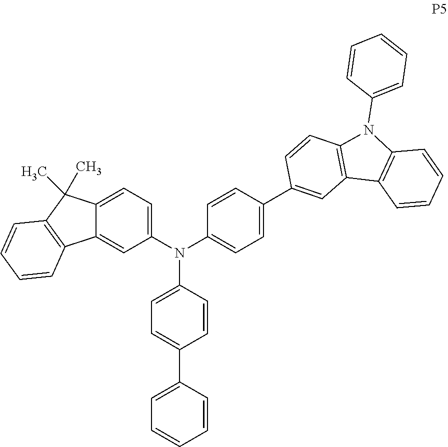 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

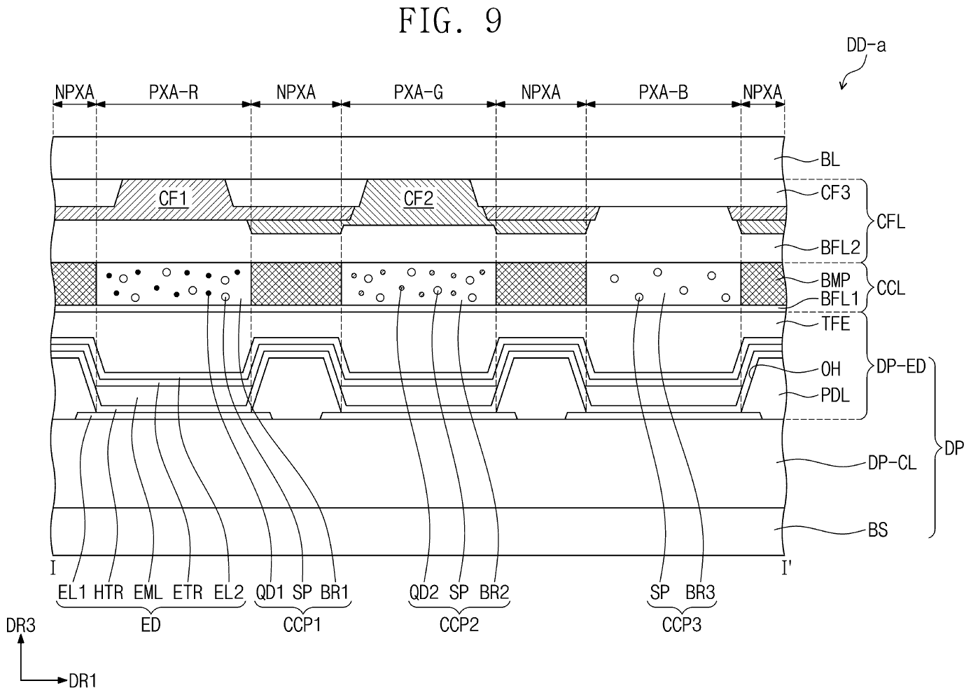

FIGS. 9 to 12 are each a schematic cross-sectional view of a display device according to an embodiment. In the descriptions of the display devices according to embodiments as shown in FIGS. 9 to 12, the features which have been described above with respect to FIGS. 1 to 7 will not be described again, and the differing features will be described.

Referring to FIG. 9, the display device DD-a according to an embodiment may include a display panel DP including a display element layer DP-ED, a light control layer CCL disposed on the display panel DP, and a color filter layer CFL. In an embodiment shown in FIG. 9, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 9 may be same as a structure of a light emitting element ED according to one of FIGS. 3 to 7 as described above.

The light emitting element ED according to an embodiment shown in FIG. 9 may include the fused polycyclic compound according to an embodiment. The light emitting element ED including the fused polycyclic compound according to an embodiment may exhibit high luminous efficiency and long service life characteristics.

Referring to FIG. 9, the emission layer EML may be disposed in an opening OH defined in a pixel defining film PDL. For example, the emission layer EML, which is separated by the pixel defining film PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for each of the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 9, divided patterns BMP may be disposed between the light control parts CCP1, CCP2, and CCP3, which are spaced apart from each other, but embodiments are not limited thereto. In FIG. 9, it is shown that the divided patterns BMP do not overlap the light control parts CCP1, CCP2, and CCP3, but the edges of the light control parts CCP1, CCP2, and CCP3 may overlap at least a portion the divided patterns BMP.

The light control layer CCL may include a first light control part CCP1 containing a first quantum dot QD1 that converts first color light provided from the light emitting element ED into second color light, a second light control part CCP2 containing a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light, which is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2 and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3 and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic material. The barrier layers BFL1 and BFL2 may be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate boundaries between adjacent filters CF1, CF2, and CF3. In an embodiment, the light shielding part (not shown) may be formed of a blue filter.

The first filter CF1, the second filter CF2, and the third filter CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

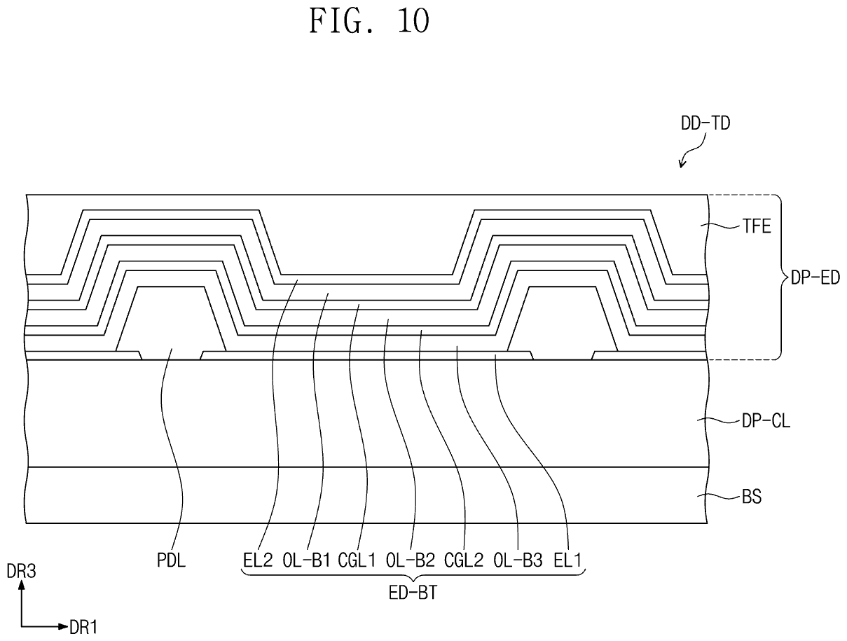

FIG. 10 is a schematic cross-sectional view of a portion of a display device according to an embodiment. In the display device DD-TD according to an embodiment, the light emitting element ED-BT may include light emitting structures OL-B1, OL-B2, and OL-B3. The light emitting element ED-BT may include a first electrode EL1 and a second electrode EL2 which face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 9), and an electron transport region ETR, which may be disposed in that order between the first electrode EL1 and the second electrode EL2. For example, the light emitting element ED-BT included in the display device DD-TD may be a light emitting element having a tandem structure that includes multiple emission layers.

The light emitting element ED-BT may include a fused polycyclic compound according to an embodiment. At least one of the light emitting structures OL-B1, OL-B2, and OL-B3 may each independently include the fused polycyclic compound according to an embodiment. The light emitting element ED-BT including the fused polycyclic compound may exhibit high luminous efficiency and long service life characteristics.

In an embodiment illustrated in FIG. 10, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges different from each other, may emit white light.

Charge generation layers CGL1 and CGL2 may each be disposed between two adjacent light emitting structures among the light emitting structures OL-B1, OL-B2, and OL-B3. Charge generation layers CGL1 and CGL2 may each independently include a p-type charge generation layer and/or an n-type charge generation layer.

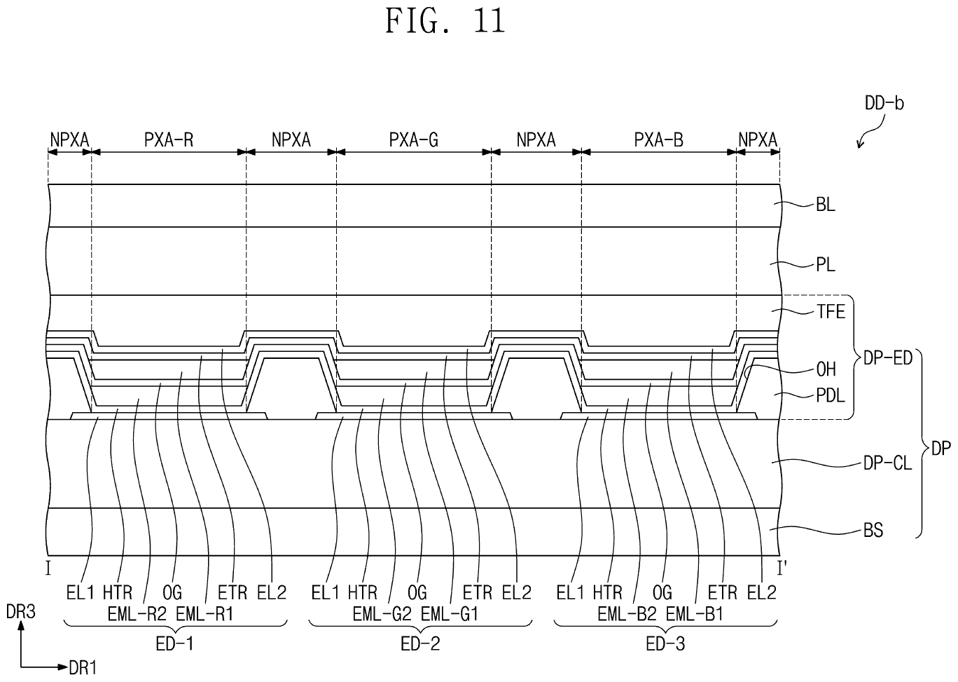

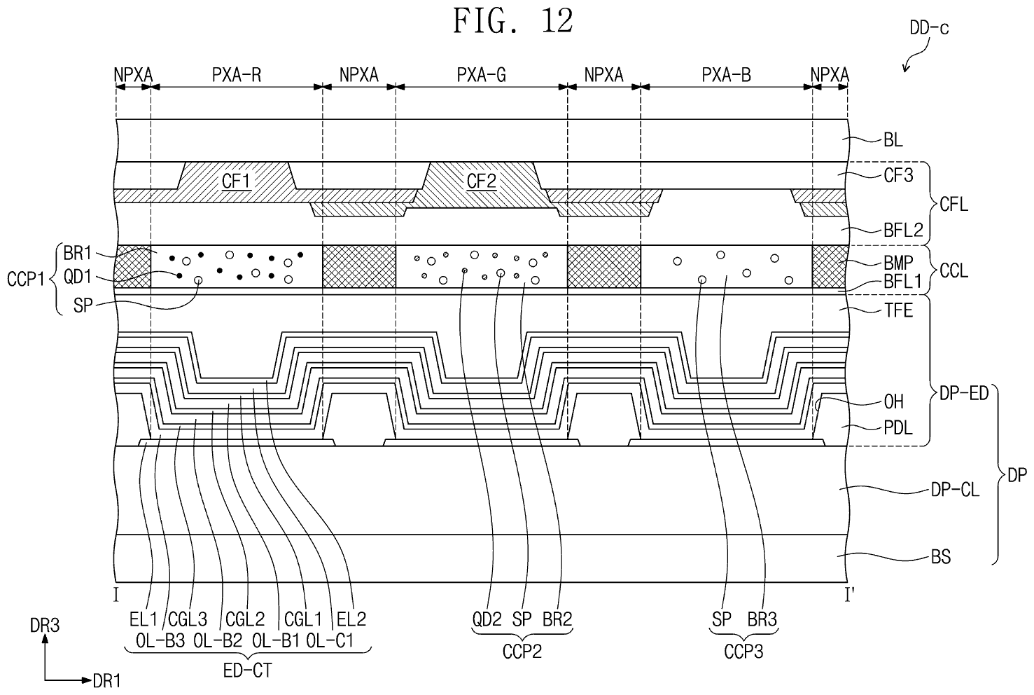

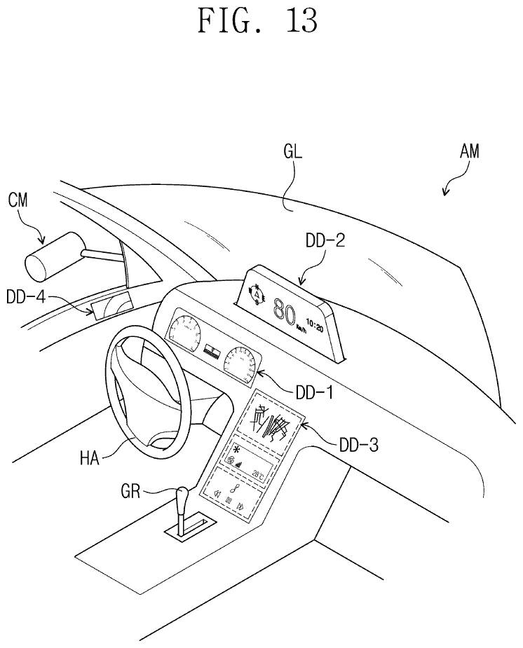

FIG. 11 is a schematic cross-sectional view of a display device DD-b according to an embodiment. FIG. 12 is a schematic cross-sectional view of a display device DD-c according to an embodiment.

Referring to FIG. 11, the display device DD-b according to an embodiment may include light emitting elements ED-1, ED-2, and ED-3 in which two emission layers are stacked. In comparison to the display device DD shown in FIG. 2, the embodiment shown in FIG. 11 is different at least in that the first to third light emitting elements ED-1, ED-2, and ED-3 each include two emission layers that are stacked in the thickness direction. In each of the first to third light emitting elements ED-1, ED-2, and ED-3, the two emission layers may emit light in a same wavelength region.

At least one of the light emitting elements ED-1, ED-2, and ED-3 may each independently include a fused polycyclic compound according to an embodiment, thereby exhibiting high luminous efficiency and long service life characteristics.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer E-L-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for each of the first to third light emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be disposed between the emission auxiliary part OG and the electron transport region ETR. The second red emission layer EML-R2, the second green emission layer EML-G2, and the second blue emission layer EML-B2 may each be disposed between the hole transport region HTR and the emission auxiliary part OG.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

In contrast to FIGS. 10 and 11, FIG. 12 shows a display device DD-c that is different at least in that it includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are stacked in a thickness direction between the first electrode EL1 and the second electrode EL2.

Charge generation layers CGL1, CGL2, and CGL3 may each be disposed between two adjacent light emitting structures among the first to fourth light emitting structures OL-B1, OL-B2, OL-B3, and OL-C1. The charge generation layers CGL1, CGL2, and CGL3 may each independently include a p-type charge generation layer and/or an n-type charge generation layer.

At least one of the light emitting structures OL-B1, OL-B2, OL-B3, and OL-C1 may each independently include the fused polycyclic compound according to an embodiment. A light emitting structure (at least one of OL-B1, OL-B2, OL-B3, and OL-C1) including the fused polycyclic compound may exhibit high luminous efficiency and long service life characteristics.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

In an embodiment, an electronic device may include a display device that includes multiple light emitting elements, and a control part that controls the display device. The electronic device may be a device that is activated by an electrical signal. The electronic device may include display devices according to various embodiments. Examples of an electronic device may include large, medium-sized, and small devices, such as a television set, a monitor, a billboard, a personal computer, a laptop computer, a personal digital terminal, a display device for a vehicle, a game console, a portable electronic device, or a camera.

FIG. 13 is a schematic perspective view of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c, as described above with reference to FIGS. 1, 2, and 9 to 12.

At least one of the first to fourth display devices DD-1, DD-2, DD-3, and DD-4 may each independently include the fused polycyclic compound according to an embodiment. A display device (at least one of the first to fourth display devices DD-1, DD-2, DD-3, and DD-4) including the fused polycyclic compound may exhibit high luminous efficiency and long service life characteristics.

FIG. 13 illustrates a vehicle AM, but this is only an example, and the first to fourth display devices DD-1, DD-2, DD-3, and DD-4 may be disposed in various transportation means such as a bicycle, a motorcycle, a train, a ship, or an airplane. In an embodiment, at least one of the first to fourth display devices DD-1, DD-2, DD-3, and DD-4 each having a structure according to one of display devices DD, DD-TD, DD-a, DD-b, and DD-c, may be included in a personal computer, a laptop computer, a personal digital terminal, a game console, a portable electronic device, a television, a monitor, an outdoor billboard, or the like. However, these are merely provided as examples, and the display device may be included in other electronic devices.

At least one of the first to fourth display devices DD-1, DD-2, DD-3, and DD-4 may each independently include a light emitting element ED according to an embodiment as described with reference to any of FIGS. 3 to 7.

Referring to FIG. 13, the vehicle AM may include a steering wheel HA and a gearshift GR for operating the vehicle AM. The vehicle AM may include a front window GL that is disposed so as to face the driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), an image that represents a fuel gauge, etc. The first scale and the second scale may each be represented by a digital image.

The second display device DD-2 may be disposed in a second region facing the driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed and may further include information such as the current time. Although not shown in the drawings, in an embodiment, the second information of the second display device DD-2 may be displayed by being projected onto the front window GL.

The third display device DD-3 may be disposed in a third region that is adjacent to the gearshift GR. For example, the third display device DD-3 may be disposed between the driver's seat and a passenger seat and may be a center information display (CID) for the vehicle AM that displays third information. The passenger seat may be a seat that is spaced apart from the driver's seat, and the gearshift GR may be disposed between the driver's seat and the passenger seat. The third information may include information about traffic (e.g., navigation information), about music or radio that is playing, about a video (or an image) that is displayed, about temperatures inside the vehicle AM, etc.

The fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM disposed on the exterior of the vehicle AM. The fourth information may include an exterior image of the vehicle AM.

The first to fourth information as described above are only provided as examples, and the first to fourth display devices DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, a fused polycyclic according to an embodiment and a light emitting element according to an embodiment will be described in detail with reference to the Examples and the Comparative Examples. The Examples described below are only provided to assist in understanding the disclosure, and the scope thereof is not limited thereto.

### Example

### 1. Synthesis of Fused Polycyclic Compounds

A synthesis method for the fused polycyclic compound according to embodiments will be described by illustrating synthesis methods of Compounds 13, 20, 99, 106, 119, 133, 179, and 209. In the following descriptions, the synthesis method for the fused polycyclic compound is only provided as an example, and the synthesis method for the fused polycyclic compound according to an embodiment is not limited to the Examples below.

### (1) Synthesis of Compound 13

Compound 13 according to an embodiment may be synthesized by, for example, the steps shown in Reaction Scheme 1 below:

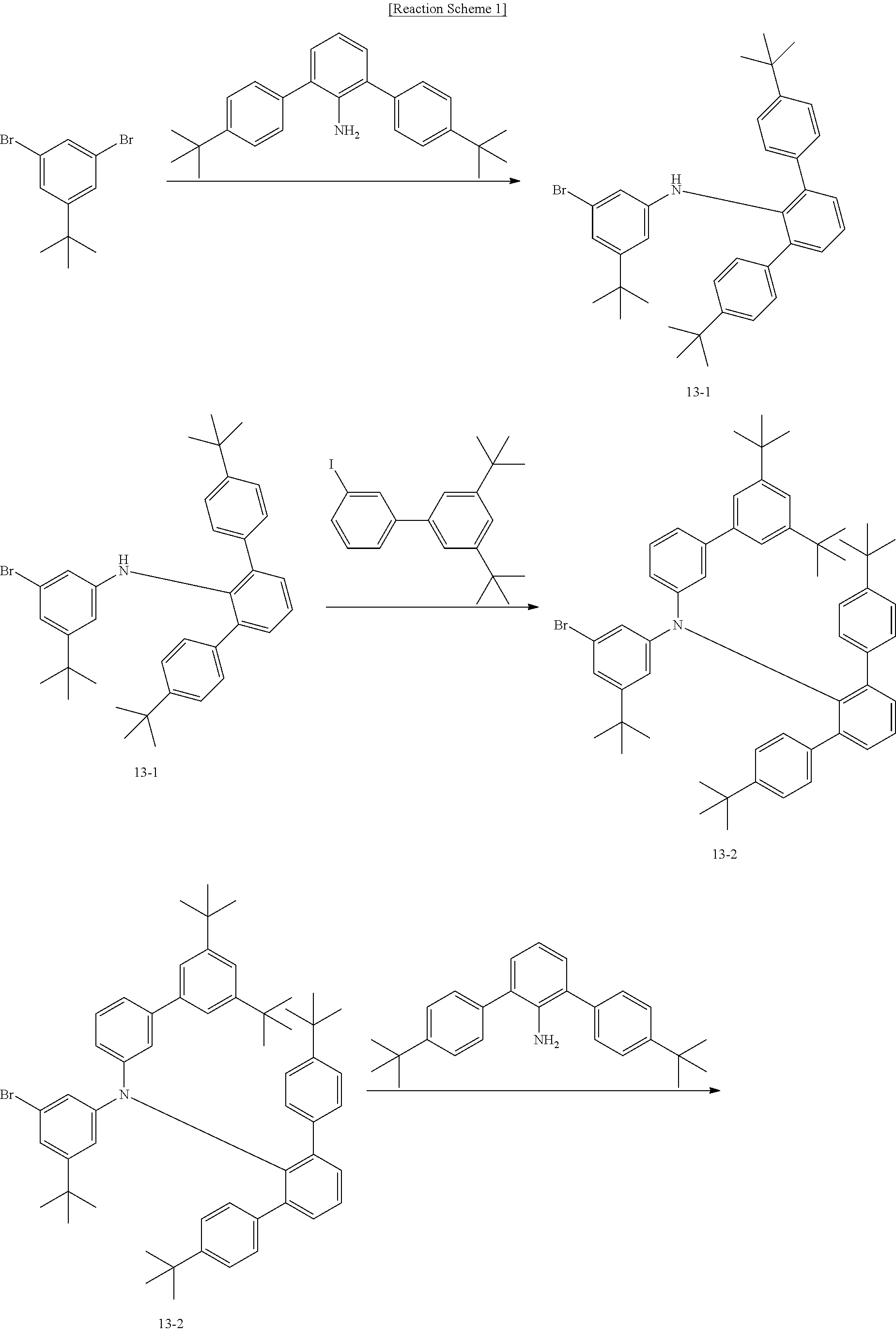

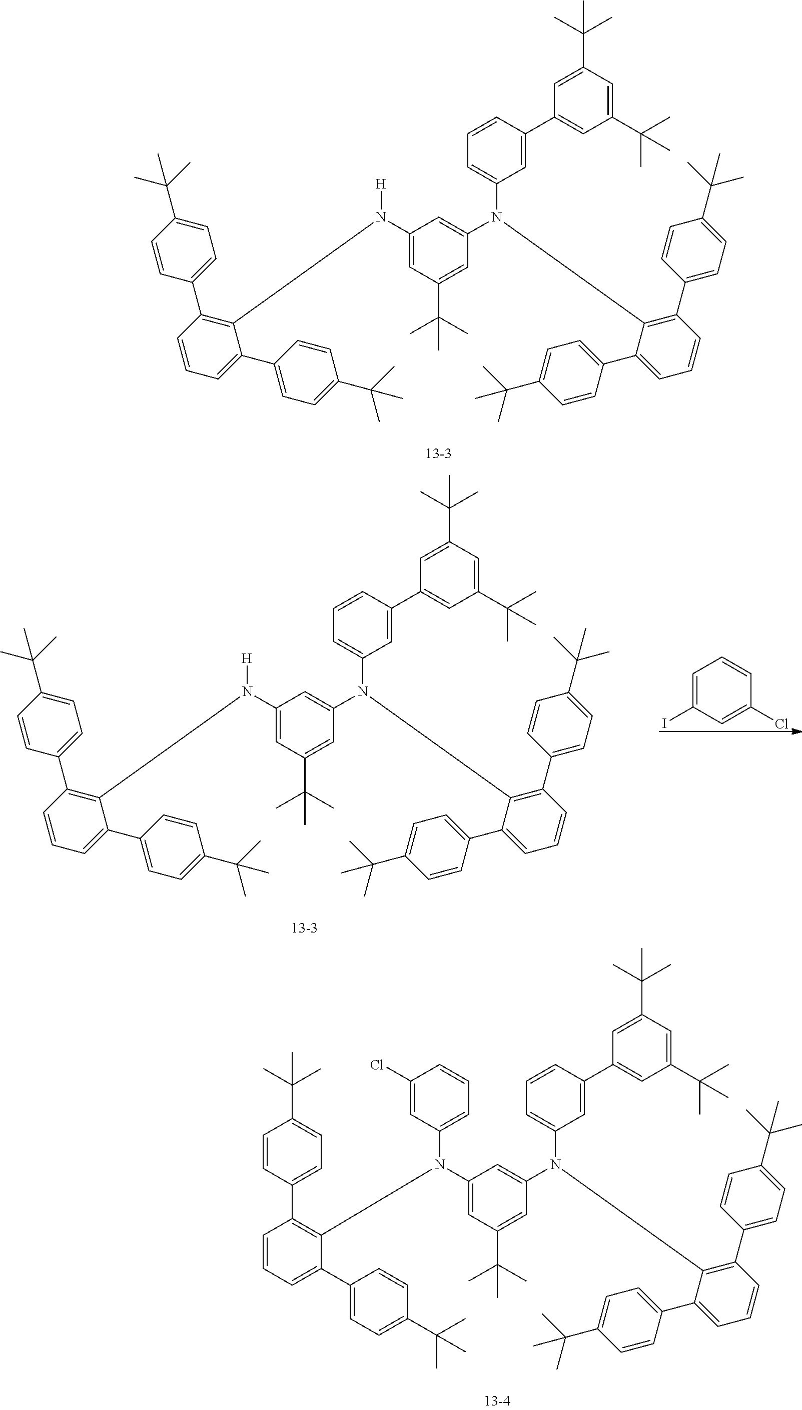

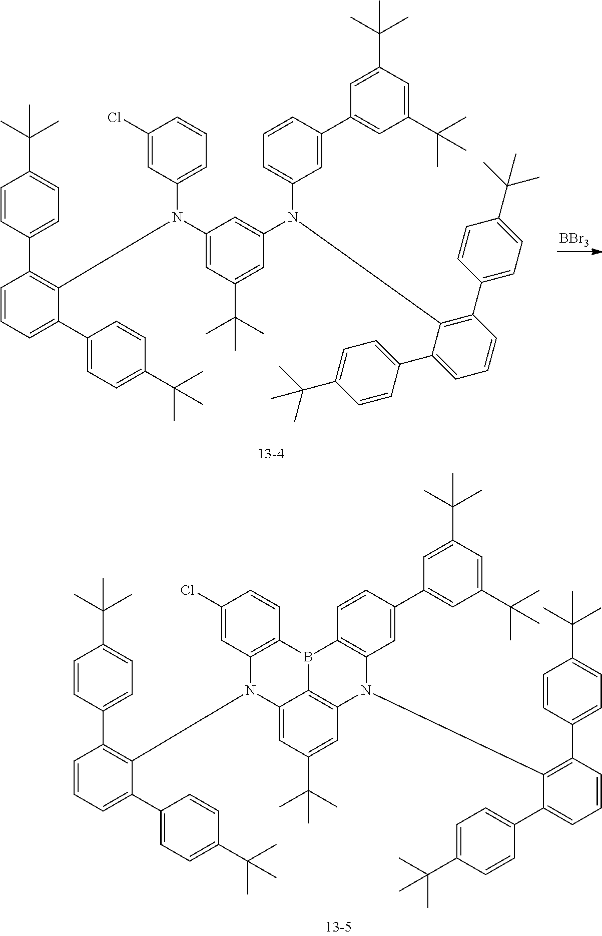

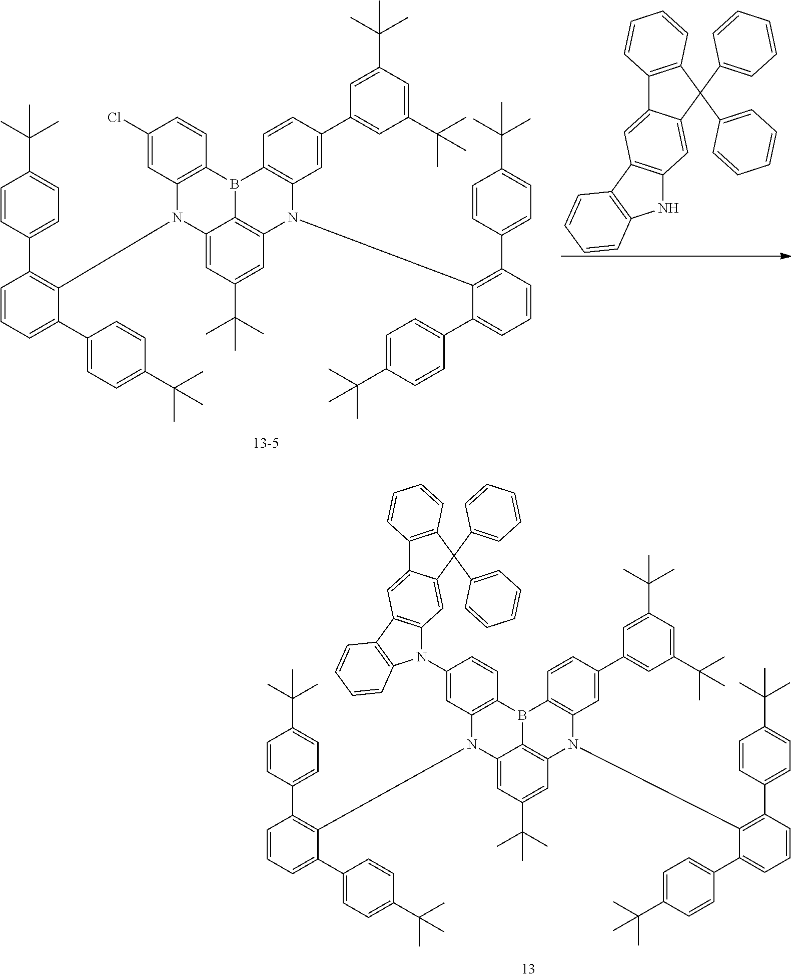

### <Synthesis of Intermediate 13-1>

In a nitrogen atmosphere, 1,3-dibromo-5-(tert-butyl)benzene (1 eq), 4,4″-di-tert-butyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling the reaction solution, water and ethyl acetate were added thereto to collect organic layers, and the reaction solution was dried over magnesium sulfate (MgSO₄) and filtered. In the filtrate, the solvent was removed under reduced pressure to obtain a product. The obtained product was purified and separated by column chromatography using silica gel to give Intermediate 13-1. (yield: 71%)

### <Synthesis of Intermediate 13-2>

In a nitrogen atmosphere, Intermediate 13-1 (1 eq), 3,5-di-tert-butyl-3′-iodo-1,1′-biphenyl (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 13-2. (yield: 75%)

### <Synthesis of Intermediate 13-3>

In a nitrogen atmosphere, Intermediate 13-2 (1 eq), 4,4″-di-tert-butyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 13-3. (yield: 65%)

### <Synthesis of Intermediate 13-4>

In a nitrogen atmosphere, Intermediate 13-3 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 13-4. (yield: 69%)

### <Synthesis of Intermediate 13-5>

In a nitrogen atmosphere, Intermediate 13-4 (1 eq) was dissolved in o-dichlorobenzene, cooled using water-ice, and BBr₃ (5 eq) was slowly added dropwise thereto, and the reaction solution was stirred at about 180° C. for about 12 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 13-5. (yield: 55%)

### <Synthesis of Compound 13>

In a nitrogen atmosphere, Intermediate 13-5 (1 eq), 7,7-diphenyl-5,7-dihydroindeno[2,1-b]carbazole (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 13. (yield: 60%)

### (2) Synthesis of Compound 20

Compound 20 according to an embodiment may be synthesized by, for example, the steps shown in Reaction Scheme 2 below:

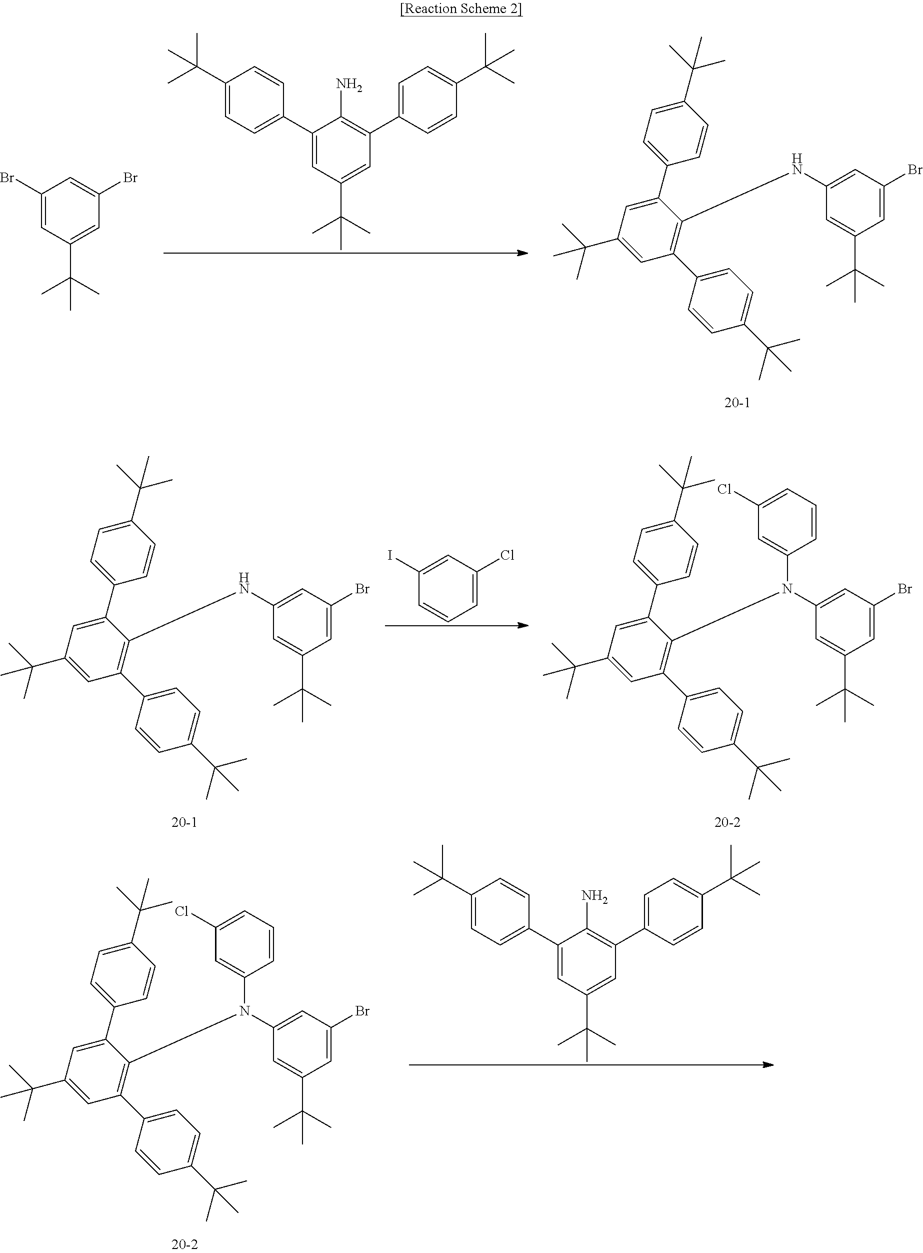

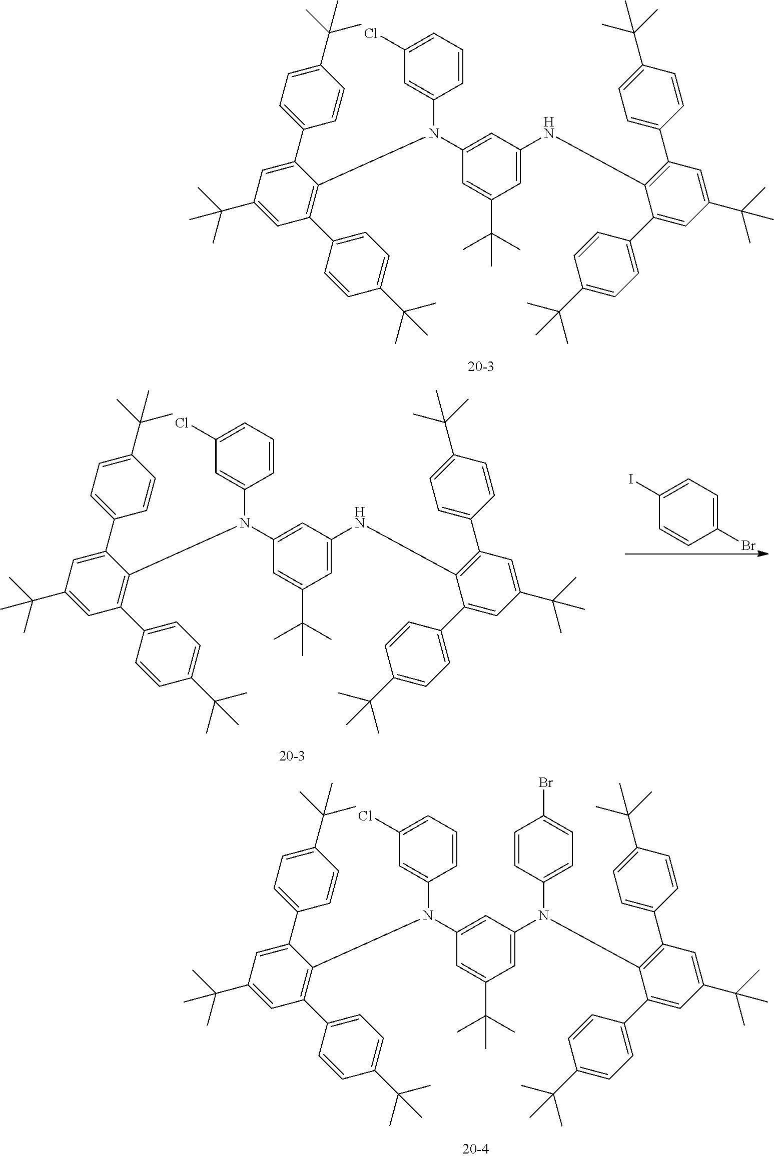

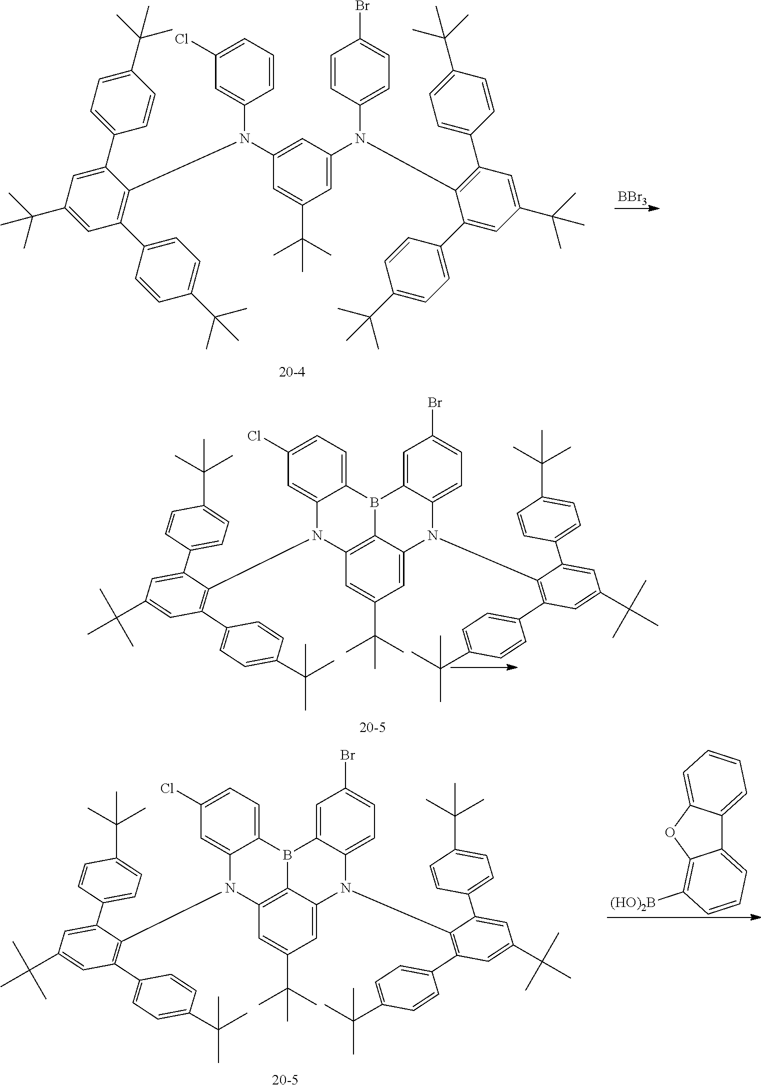

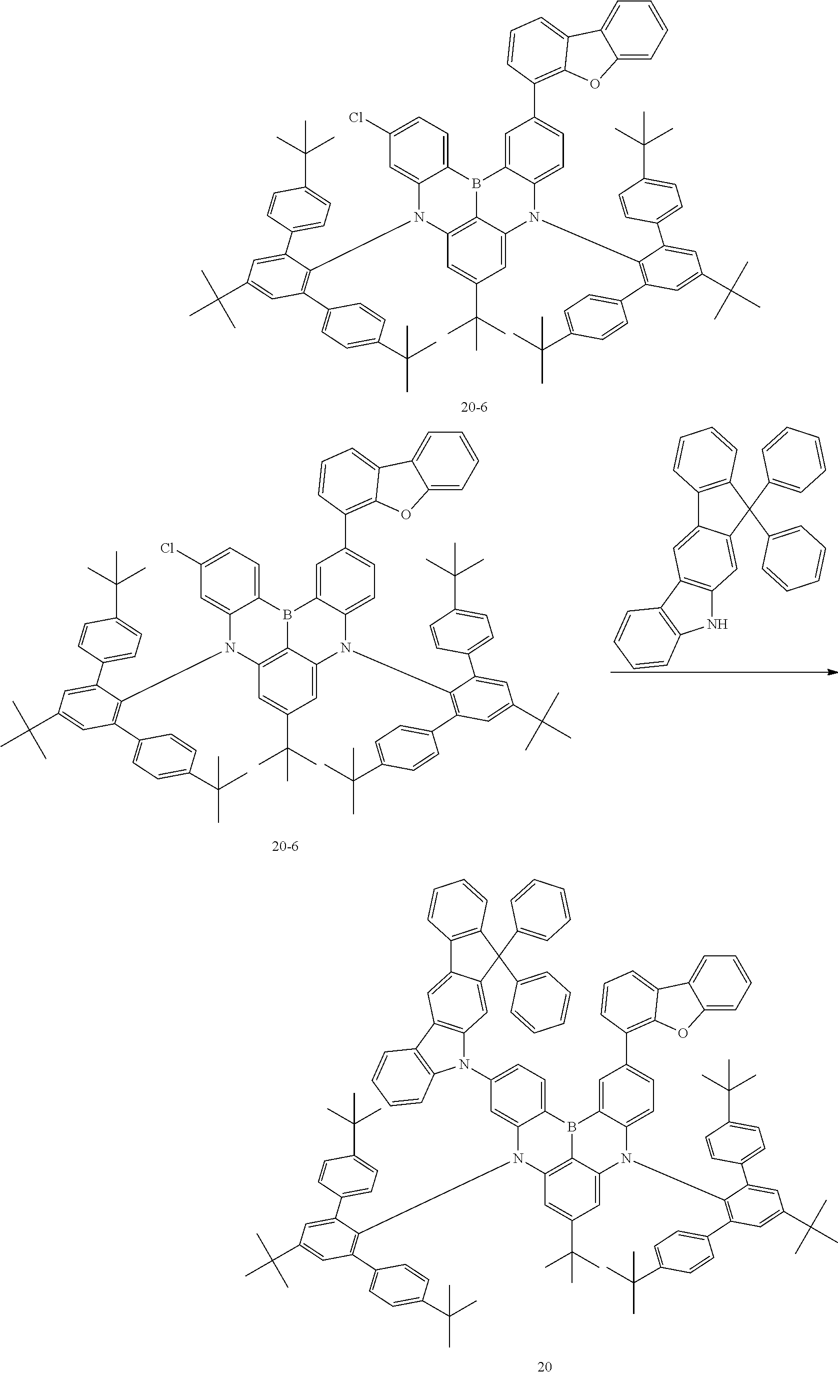

### <Synthesis of Intermediate 20-1>

In a nitrogen atmosphere, 1,3-dibromo-5-(tert-butyl)benzene (1 eq), 4,4″,5′-tri-tert-butyl-[1,1′: 3′,1″-terphenyl]-2′-amine (1.1 eq), Pd₂ (dba) 3 (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 20-1. (yield: 65%)

### <Synthesis of Intermediate 20-2>

In a nitrogen atmosphere, Intermediate 20-1 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 20-2. (yield: 68%)

### <Synthesis of Intermediate 20-3>

In a nitrogen atmosphere, Intermediate 20-2 (1 eq), 4,4″,5′-tri-tert-butyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 20-3. (yield: 63%)

### <Synthesis of Intermediate 20-4>

In a nitrogen atmosphere, Intermediate 20-3 (1 eq), 1-bromo-4-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 20-4. (yield: 68%)

### <Synthesis of Intermediate 20-5>

In a nitrogen atmosphere, Intermediate 20-4 (1 eq) was dissolved in o-dichlorobenzene, cooled using water-ice, and BBr₃ (5 eq) was slowly added dropwise thereto, and the reaction solution was stirred at about 180° C. for about 24 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 20-5. (yield: 42%)

### <Synthesis of Intermediate 20-6>

In a nitrogen atmosphere, Intermediate 20-5 (1 eq) was added to dibenzo[b,d]furan-4-ylboronic acid (1.1 eq), Pd(PPh₃)₄ (2.9 g, 0.05 eq), and potassium carbonate (2 eq), and the resulting mixture was dissolved in 500 mL of toluene and 200 mL of H₂O and the reactant was stirred at about 100° C. for about 12 hours. The reaction solution was cooled and extracted by adding water (300 mL) to collect organic layers, and the organic layers were dried over MgSO₄ and filtered. In the filtrate, the solvent was removed under reduced pressure to obtain a solid. The obtained solid was purified and recrystallized by silica gel column chromatography using CH₂Cl₂ and hexane as eluent to obtain Intermediate 20-6. (yield: 70%)

### <Synthesis of Compound 20>

In a nitrogen atmosphere, Intermediate 20-6 (1 eq), 7,7-diphenyl-5,7-dihydroindeno[2,1-b]carbazole (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 20. (yield: 72%)

### (3) Synthesis of Compound 99

Compound 99 according to an embodiment may be synthesized by, for example, the steps shown in Reaction Scheme 3 below:

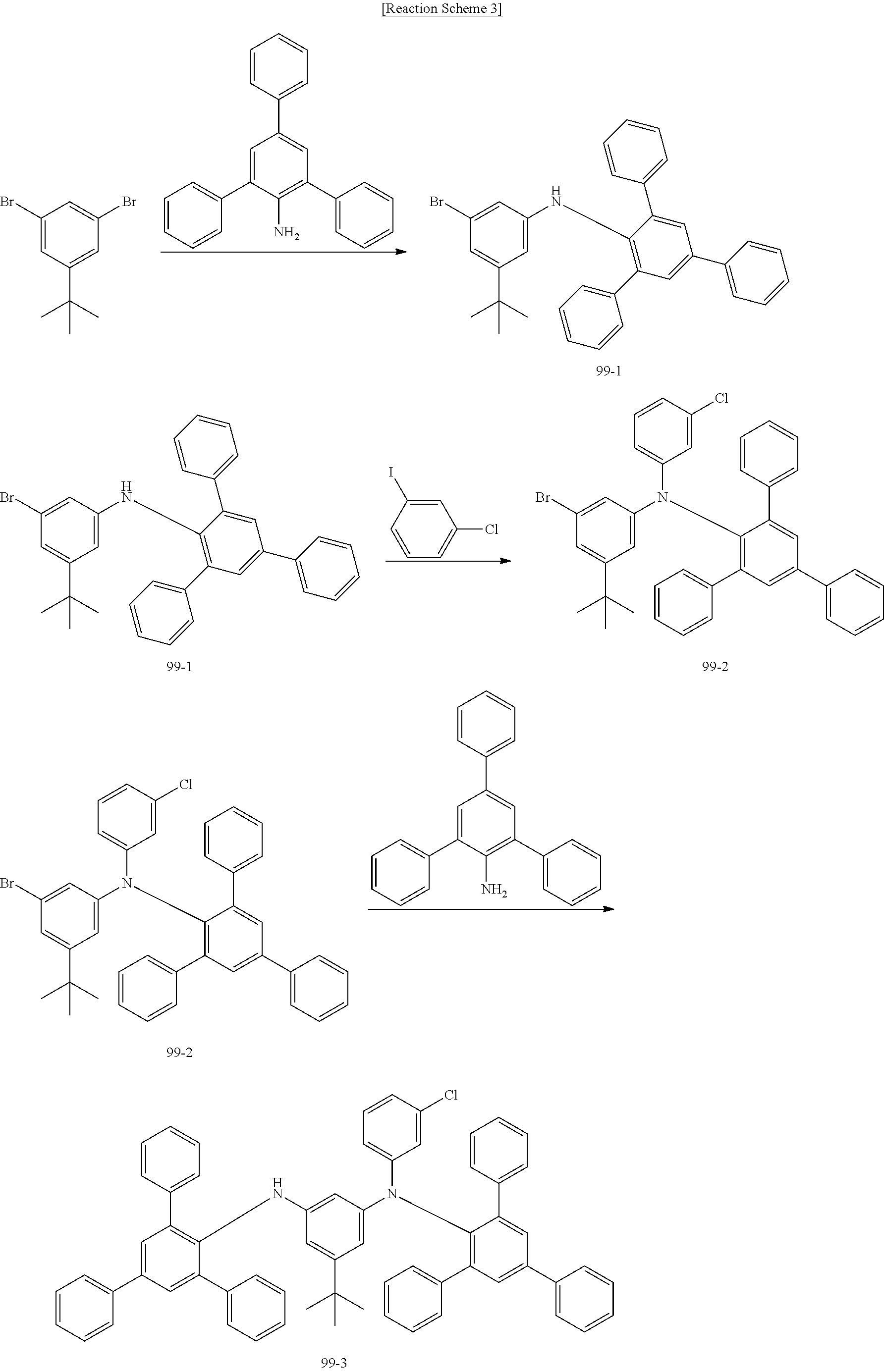

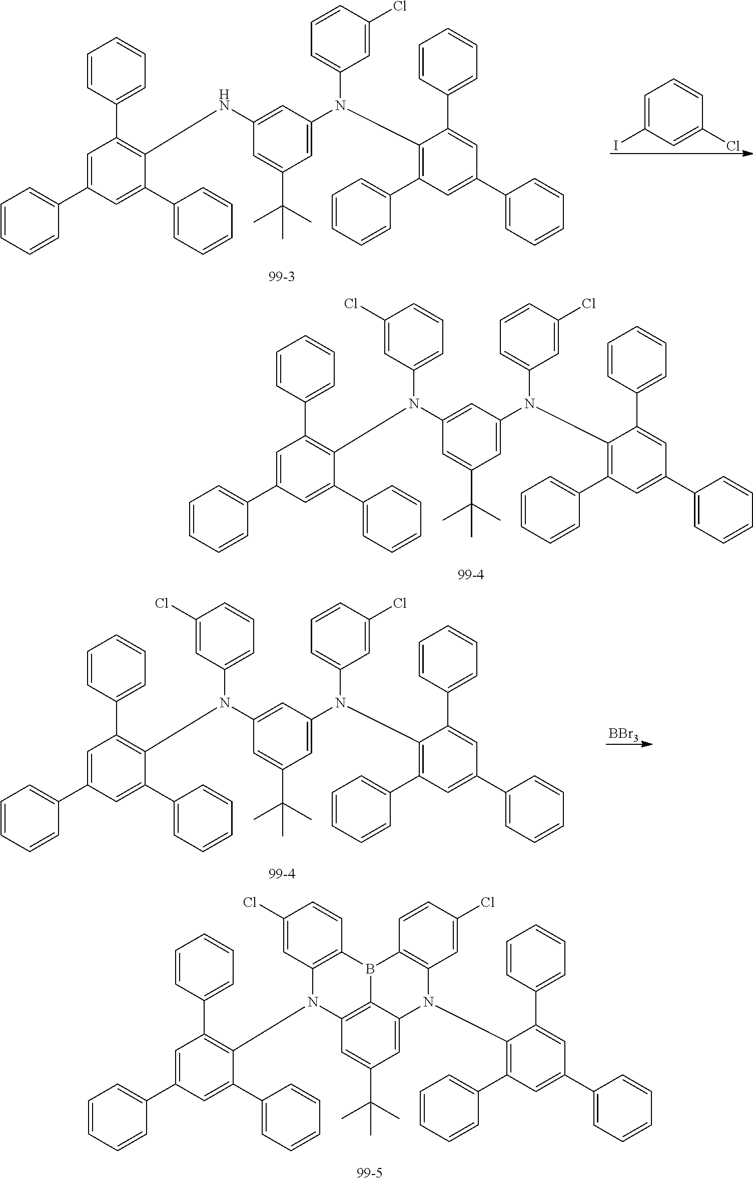

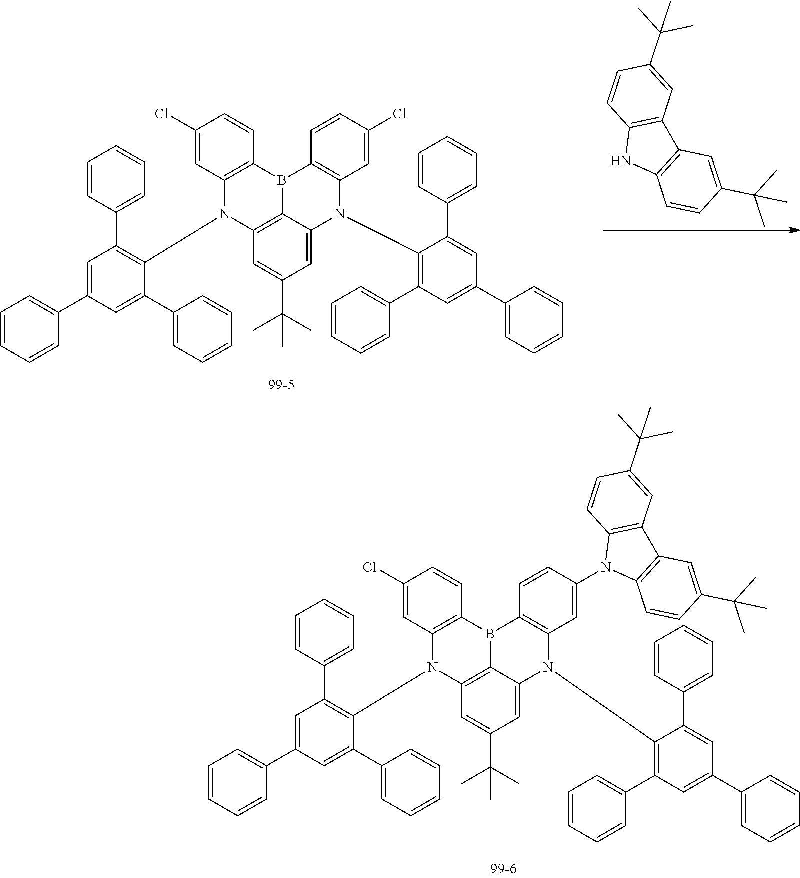 [SMILES: CC(C)(C)c1cc2c3c(c1)N(c1c(-c4ccccc4)cc(-c4ccccc4)cc1-c1ccccc1)c1cc(Cl)ccc1B3c1ccc(Cl)cc1N2c1c(-c2ccccc2)cc(-c2ccccc2)cc1-c1ccccc1 ; CC(C)(C)c1ccc2[nH]c3ccc(C(C)(C)C)cc3c2c1 ; CC(C)(C)c1cc2c3c(c1)N(c1c(-c4ccccc4)cc(-c4ccccc4)cc1-c1ccccc1)c1cc(-n4c5ccc(C(C)(C)C)cc5c5cc(C(C)(C)C)ccc54)ccc1B3c1ccc(Cl)cc1N2c1c(-c2ccccc2)cc(-c2ccccc2)cc1-c1ccccc1]

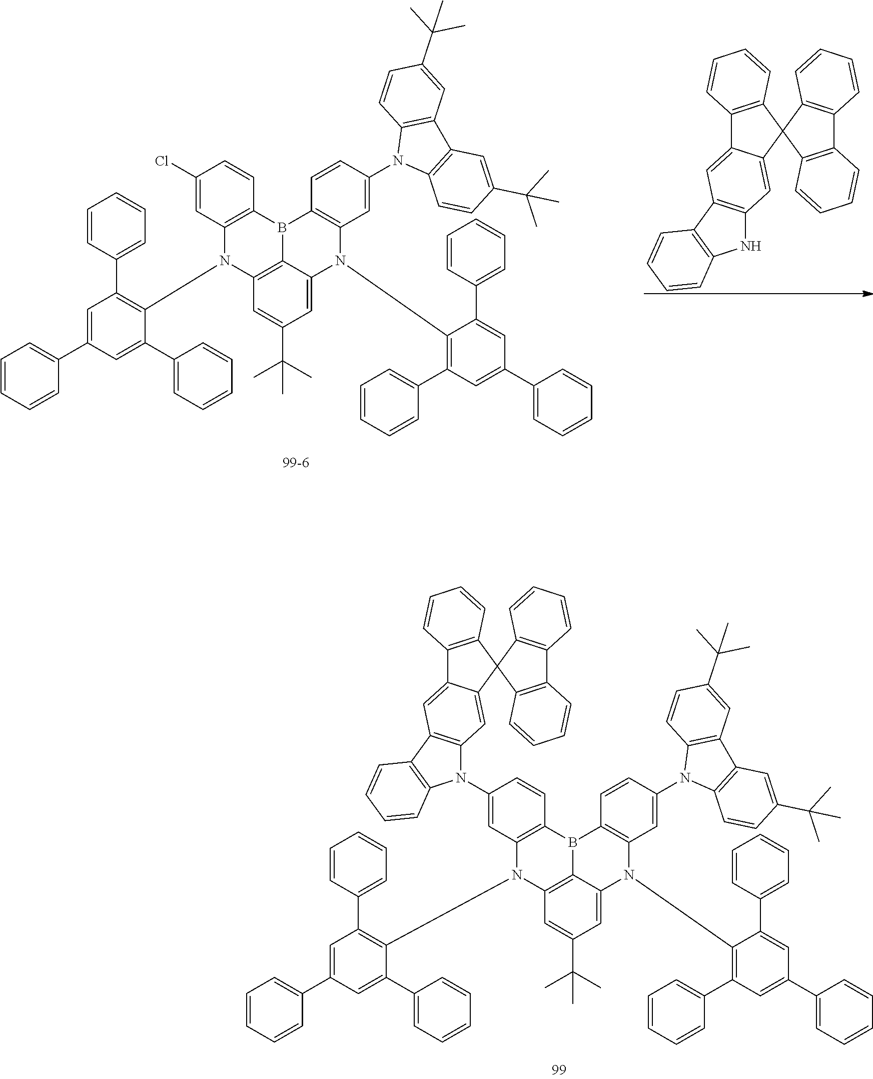 [SMILES: CC(C)(C)c1cc2c3c(c1)N(c1c(-c4ccccc4)cc(-c4ccccc4)cc1-c1ccccc1)c1cc(-n4c5ccc(C(C)(C)C)cc5c5cc(C(C)(C)C)ccc54)ccc1B3c1ccc(Cl)cc1N2c1c(-c2ccccc2)cc(-c2ccccc2)cc1-c1ccccc1 ; c1ccc2c(c1)-c1ccccc1C21c2ccccc2-c2cc3c(cc21)[nH]c1ccccc13 ; CC(C)(C)c1cc2c3c(c1)N(c1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1]

### <Synthesis of Intermediate 99-1>

In a nitrogen atmosphere, 1,3-dibromo-5-(tert-butyl)benzene (1 eq), 5′-phenyl-[1,1′: 3′, 1″-terphenyl]-2′-amine (1.1 eq), Pd₂ (dba) 3 (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 99-1. (yield: 68%)

### <Synthesis of Intermediate 99-2>

In a nitrogen atmosphere, Intermediate 99-1 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 99-2. (yield: 71%)

### <Synthesis of Intermediate 99-3>

In a nitrogen atmosphere, Intermediate 99-2 (1 eq), 5′-phenyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 99-3. (yield: 60%)

### <Synthesis of Intermediate 99-4>

In a nitrogen atmosphere, Intermediate 20-3 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 99-4. (yield: 65%)

### <Synthesis of Intermediate 99-5>

In a nitrogen atmosphere, Intermediate 99-4 (1 eq) was dissolved in o-dichlorobenzene, cooled using water-ice, and BBr₃ (5 eq) was slowly added dropwise thereto, and the reaction solution was stirred at about 180° C. for about 24 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 99-5. (yield: 46%)

### <Synthesis of Intermediate 99-6>

In a nitrogen atmosphere, Intermediate 99-5 (1 eq) was added to 3,6-di-tert-butyl-9H-carbazole (1.2 eq), Pd₂(dba)₃ (0.05 eq), tris-tert-butyl phosphine (0.1 eq), and sodium tert-butoxide (3 eq) and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 99-6. (yield: 66%)

### <Synthesis of Compound 99>

In a nitrogen atmosphere, Intermediate 99-6 (1 eq), 5′H-spiro[fluorene-9,7′-indeno[2,1-b]carbazole] (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 99. (yield: 71%)

### (4) Synthesis of Compound 106

Compound 106 according to an embodiment may be synthesized by, for example, the steps shown in Reaction Scheme 4 below:

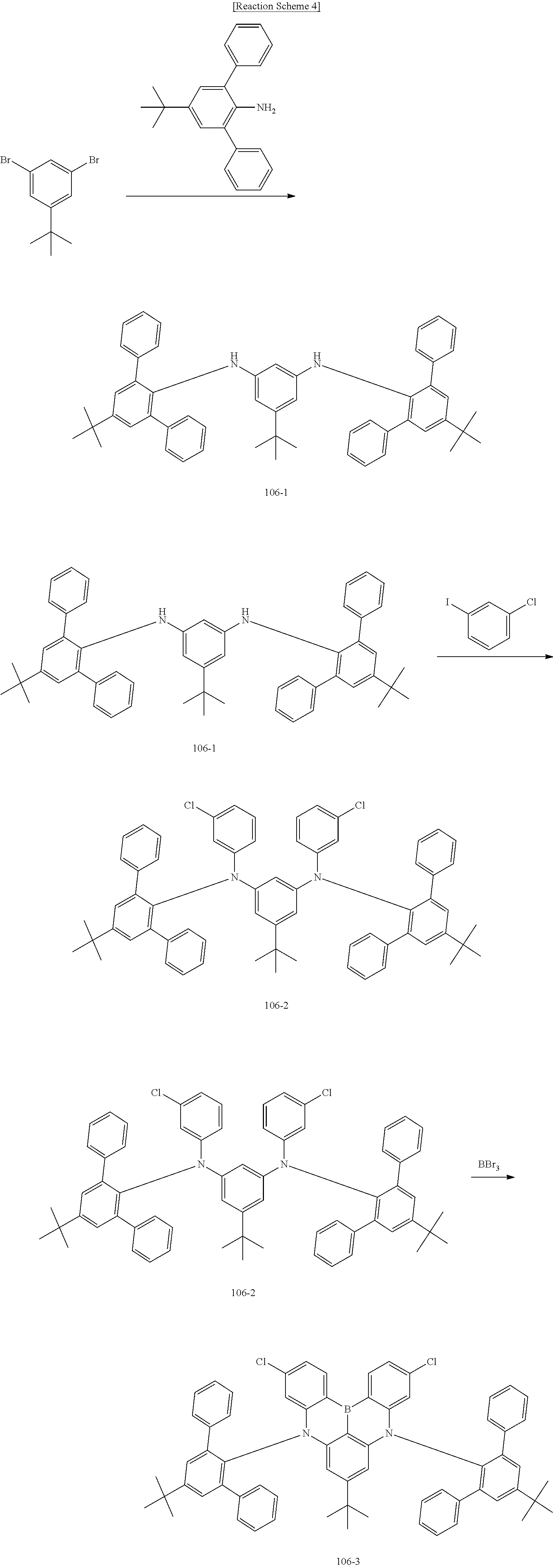

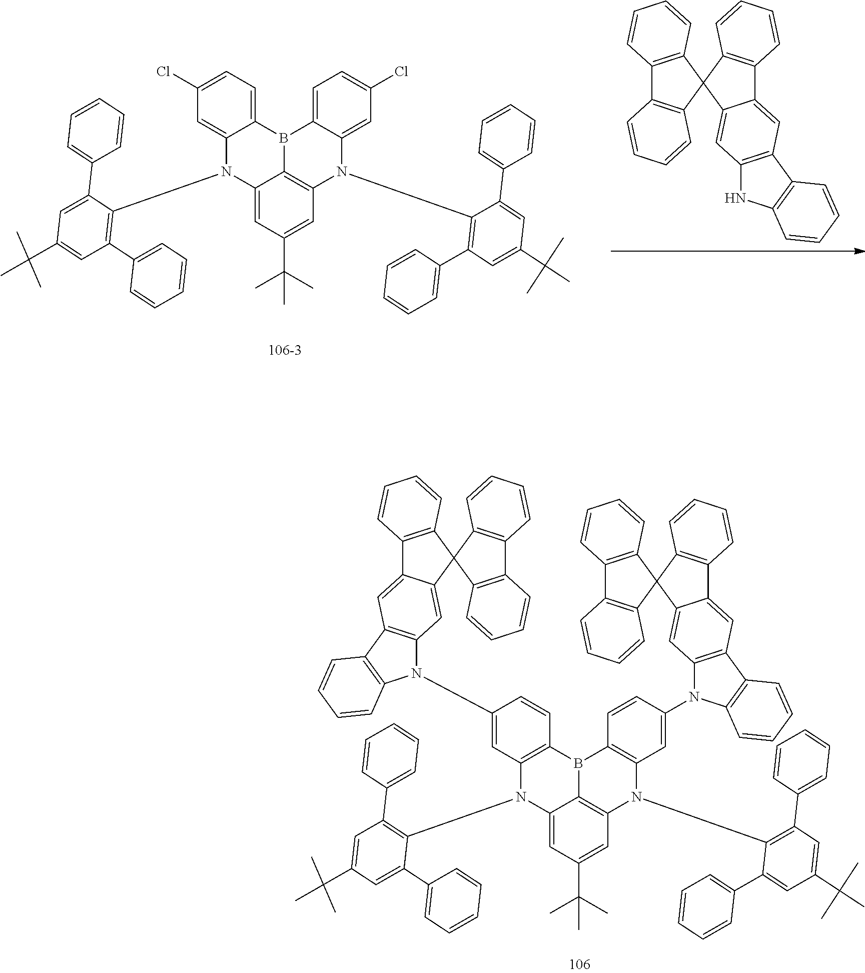

### <Synthesis of Intermediate 106-1>

In a nitrogen atmosphere, 1,3-dibromo-5-(tert-butyl)benzene (1 eq), 5′-(tert-butyl)-[1,1′:3′,1″-terphenyl]-2′-amine (2.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 106-1. (yield: 66%)

### <Synthesis of Intermediate 106-2>

In a nitrogen atmosphere, Intermediate 106-1 (1 eq), 1-chloro-3-iodobenzene (2.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 106-2. (yield: 62%)

### <Synthesis of Intermediate 106-3>

In a nitrogen atmosphere, Intermediate 106-2 (1 eq) was dissolved in o-dichlorobenzene, cooled using water-ice, and BBr₃ (5 eq) was slowly added dropwise thereto, and the reaction solution was stirred at about 180° C. for about 24 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 106-3. (yield: 49%)

### <Synthesis of Compound 106>

In a nitrogen atmosphere, Intermediate 106-3 (1 eq), 5′H-spiro[fluorene-9,7′-indeno[2,1-b]carbazole] (2.4 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 106. (yield: 74%)

### (5) Synthesis of Compound 119

Compound 119 according to an embodiment may be synthesized by, for example, the steps shown in Reaction Scheme 5 below:

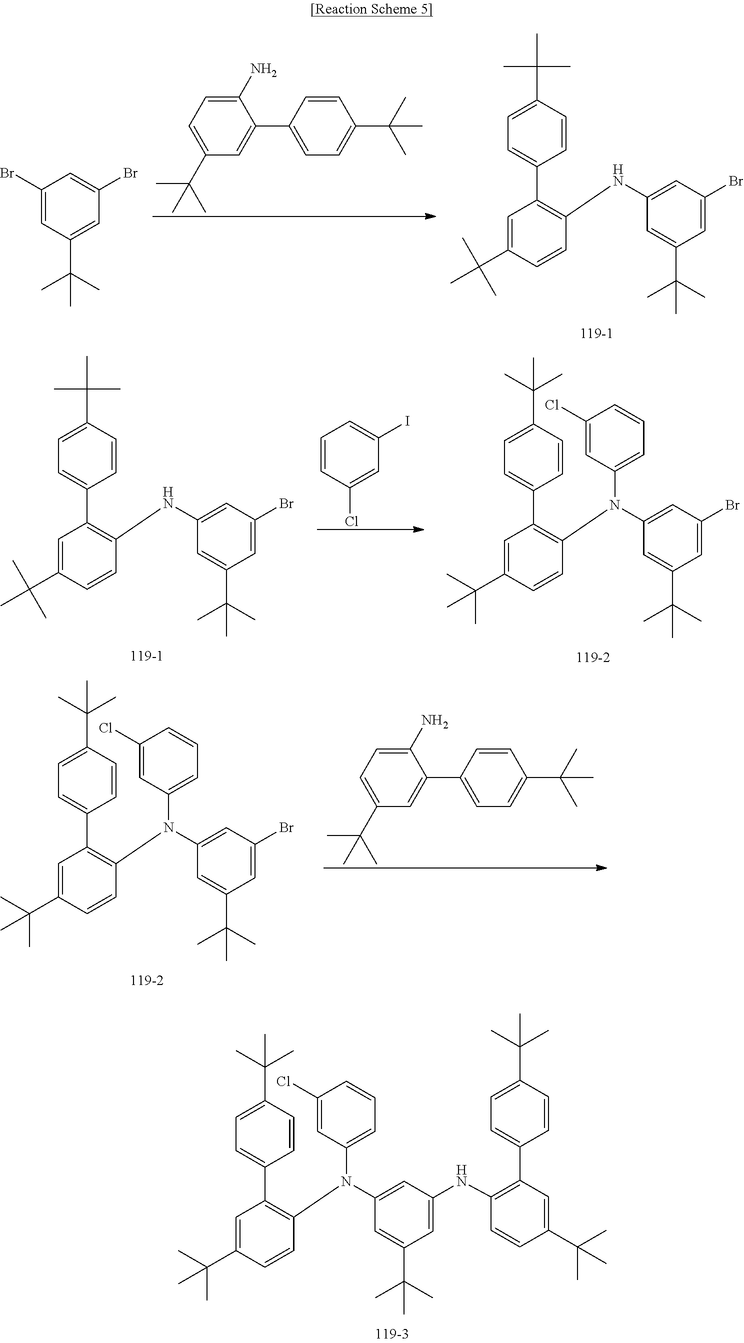

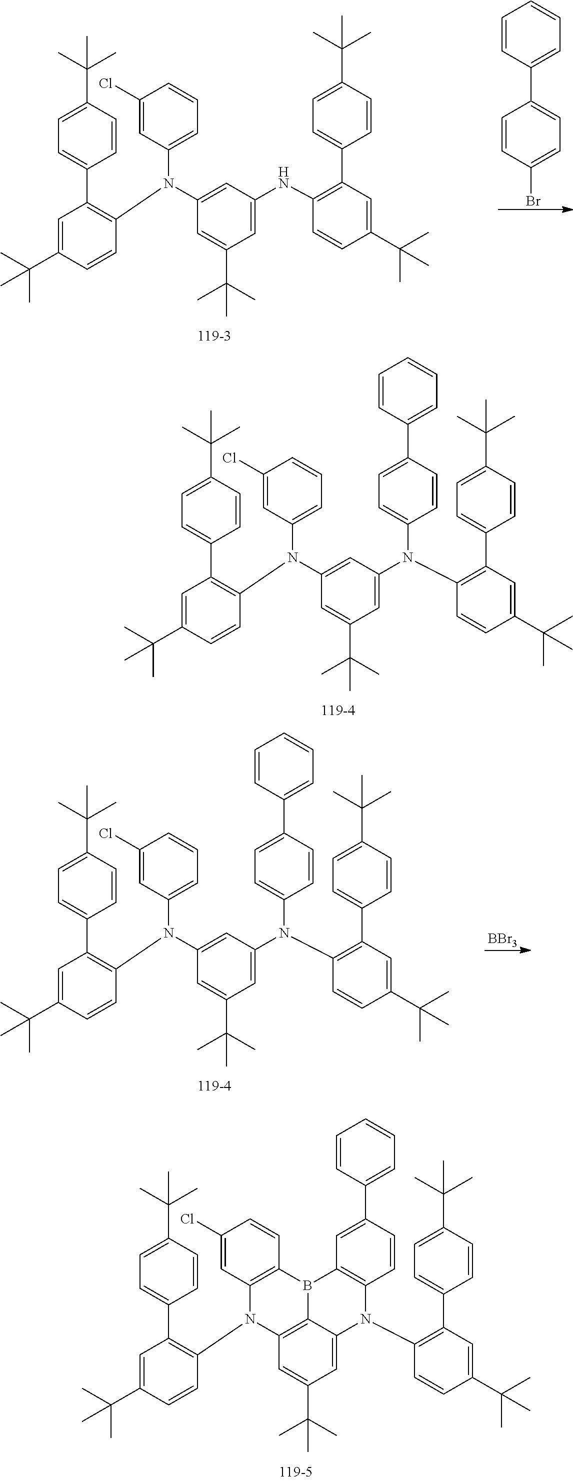

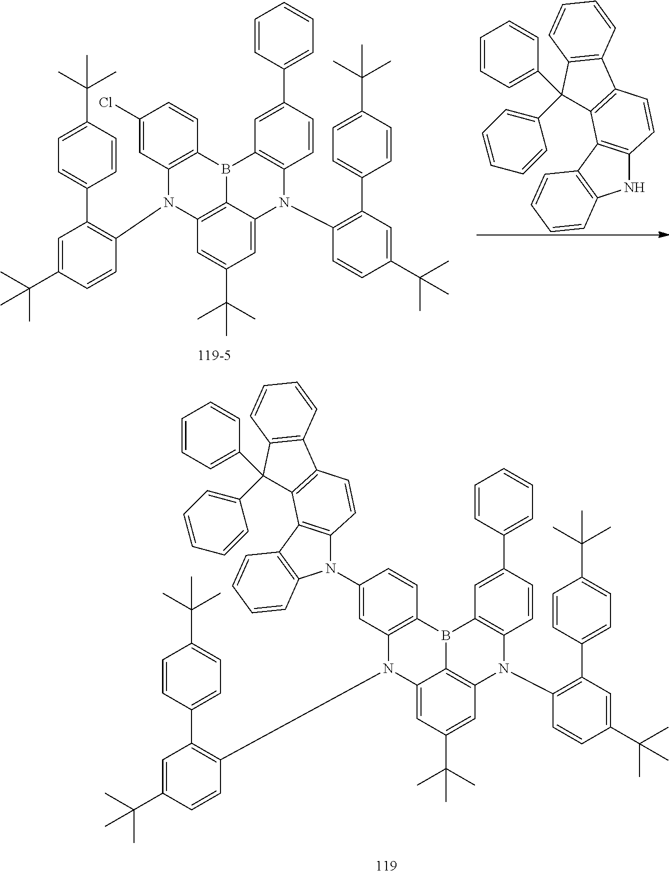

### <Synthesis of Intermediate 119-1>

In a nitrogen atmosphere, 1,3-dibromo-5-(tert-butyl)benzene (1 eq), 4′,5-di-tert-butyl-[1,1′-biphenyl]-2-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 119-1. (yield. 71%)

### <Synthesis of Intermediate 119-2>

In a nitrogen atmosphere, Intermediate 119-1(1 eq), 1-chloro-3-iodobenzene (1.2 eq), pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Intermediate 119-2. (yield: 52%)

### <Synthesis of Intermediate 119-3>

In a nitrogen atmosphere, Intermediate 119-2 (1 eq), 4′,5-di-tert-butyl-[1,1′-biphenyl]-2-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Intermediate 119-3. (yield: 61%)

### <Synthesis of Intermediate 119-4>

In a nitrogen atmosphere, Intermediate 119-3 (1 eq), 4-bromo-1,1′-biphenyl (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Intermediate 119-4. (yield: 58%)

### <Synthesis of Intermediate 119-5>

In a nitrogen atmosphere, Intermediate 119-4 (1 eq) was dissolved in o-dichlorobenzene, cooled using water-ice, and BBr₃ (5 eq) was slowly added dropwise thereto, and the reaction solution was stirred at about 180° C. for about 24 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 119-5. (yield: 43%)

### <Synthesis of Compound 119>

In a nitrogen atmosphere, Intermediate 119-5 (1 eq), 12,12-diphenyl-5,12-dihydroindeno[1,2-c]carbazole (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 119. (yield: 60%)

### (6) Synthesis of Compound 133

Compound 133 according to an embodiment may be synthesized by, for example, the steps shown in Reaction Scheme 6 below:

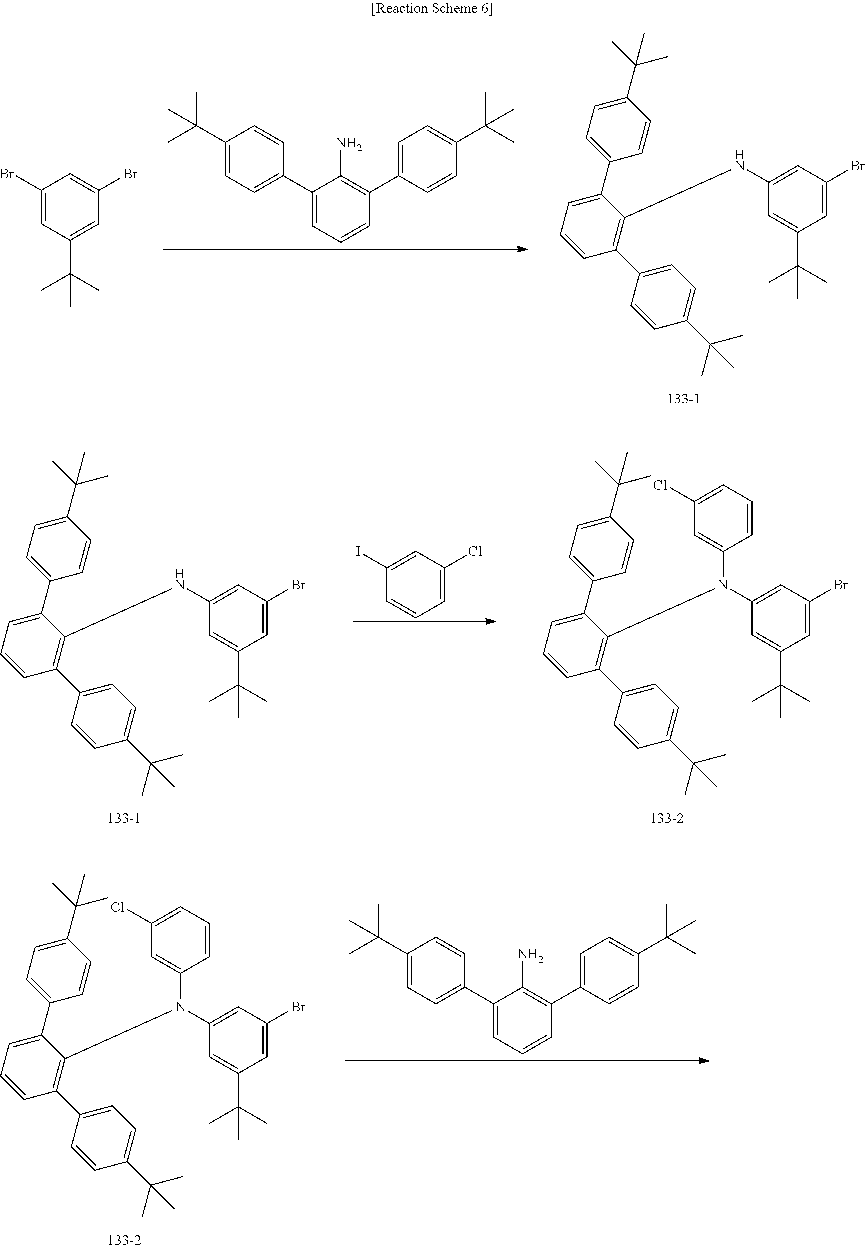

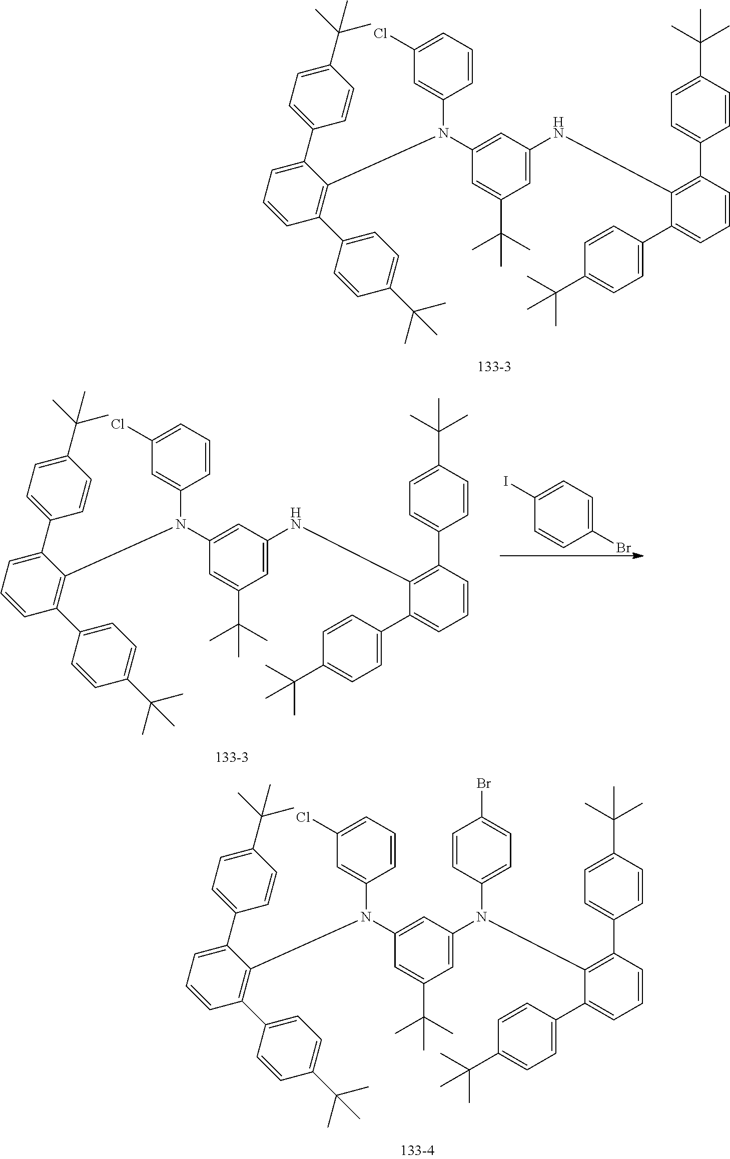

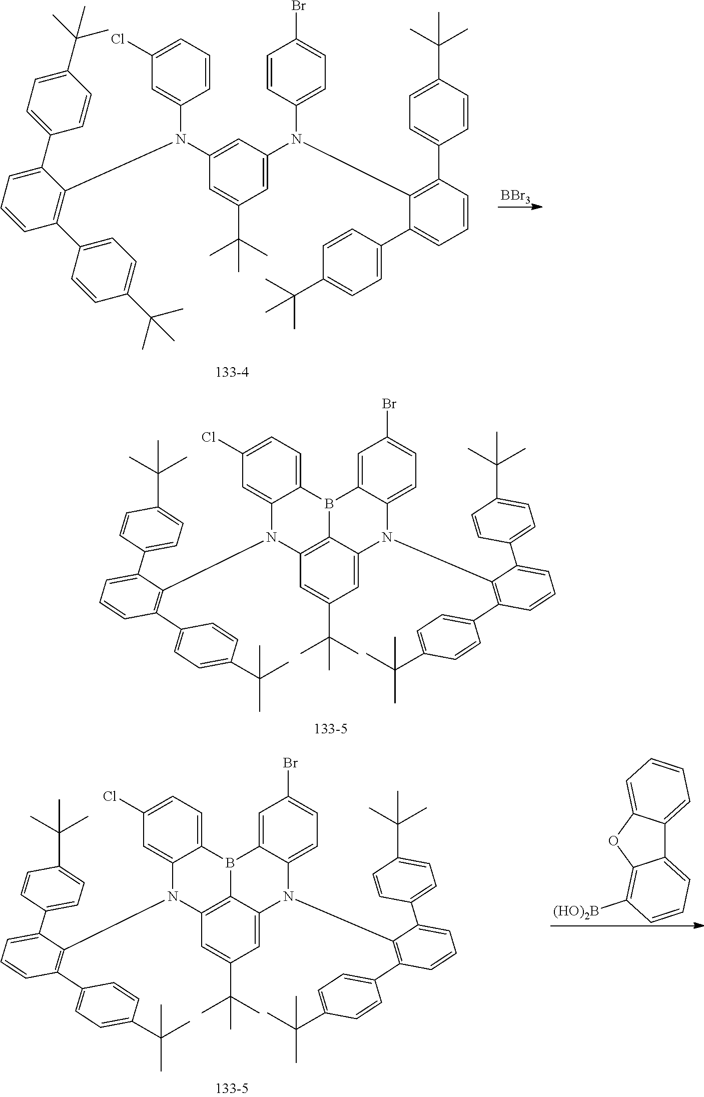

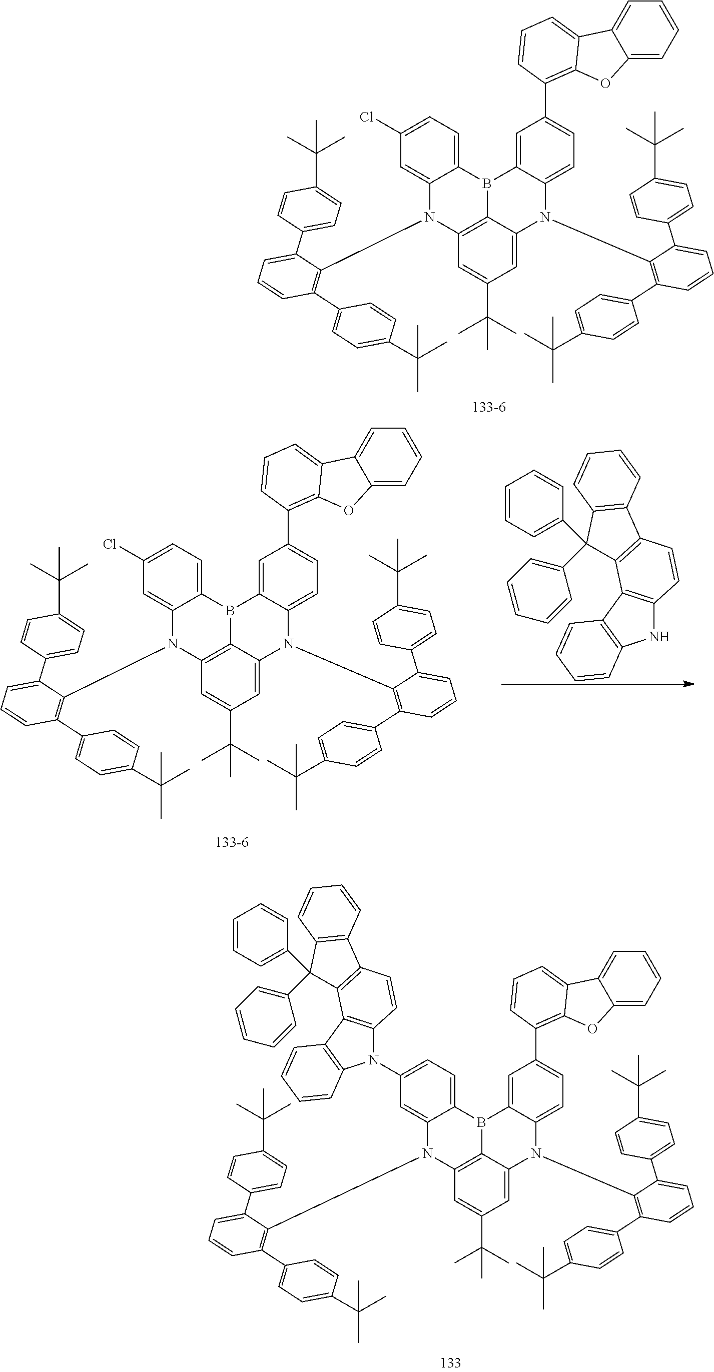

### <Synthesis of Intermediate 133-1>

In a nitrogen atmosphere, 1,3-dibromo-5-(tert-butyl)benzene (1 eq), 4,4″-di-tert-butyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 133-1. (yield: 70%)

### <Synthesis of Intermediate 133-2>

In a nitrogen atmosphere, Intermediate 133-1 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 133-2. (yield: 66%)

### <Synthesis of Intermediate 133-3>

In a nitrogen atmosphere, Intermediate 133-2 (1 eq), 4,4″-di-tert-butyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 133-3. (yield: 68%)

### <Synthesis of Intermediate 133-4>

In a nitrogen atmosphere, Intermediate 133-3 (1 eq), 1-bromo-4-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 133-4. (yield: 60%)

### <Synthesis of Intermediate 133-5>

In a nitrogen atmosphere, Intermediate 133-4 (1 eq) was dissolved in o-dichlorobenzene, cooled using water-ice, and BBr₃ (5 eq) was slowly added dropwise thereto, and the reaction solution was stirred at about 180° C. for about 24 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 133-5. (yield: 47%)

### <Synthesis of Intermediate 133-6>

In a nitrogen atmosphere, Intermediate 133-5 (1 eq) was added to dibenzo[b,d]furan-4-ylboronic acid (1.1 eq), Pd(PPh₃)₄ (2.9 g, 0.05 eq), and potassium carbonate(2 eq), and dissolved in 500 mL of toluene and 200 mL of H₂O, and the reaction solution was stirred at about 100° C. for about 12 hours. The reaction solution was cooled and extracted by adding water (300 mL) to collect organic layers, and the organic layers were dried over MgSO₄ and filtered. In the filtrate, the solvent was removed under reduced pressure to obtain a solid. The obtained solid was purified and recrystallized by silica gel column chromatography using CH₂Cl₂ and hexane as eluent to obtain Intermediate 133-6. (yield: 73%)

### <Synthesis of Compound 133>

In a nitrogen atmosphere, Intermediate 133-6 (1 eq), 12,12-diphenyl-5,12-dihydroindeno[1,2-c]carbazole (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 133. (yield: 70%)

### (7) Synthesis of Compound 179

Compound 179 according to an embodiment may be synthesized by, for example, the steps shown in Reaction Scheme 7 below:

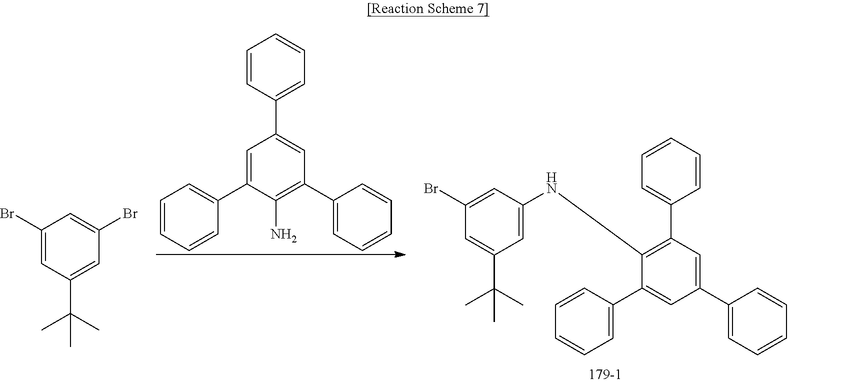

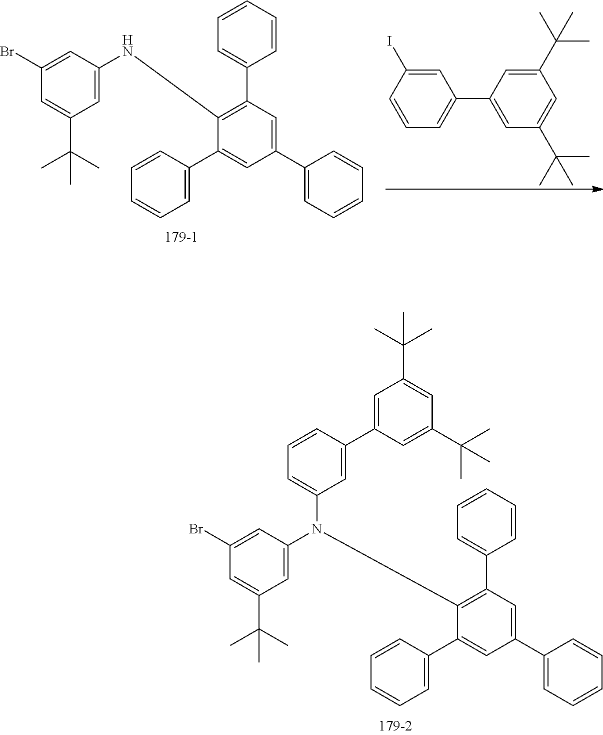 [SMILES: CC(C)(C)c1cc(Br)cc(Nc2c(-c3ccccc3)cc(-c3ccccc3)cc2-c2ccccc2)c1 ; CC(C)(C)c1cc(-c2cccc(I)c2)cc(C(C)(C)C)c1 ; CC(C)(C)c1cc(Br)cc(N(c2cccc(-c3cc(C(C)(C)C)cc(C(C)(C)C)c3)c2)c2c(-c3ccccc3)cc(-c3ccccc3)cc2-c2ccccc2)c1]

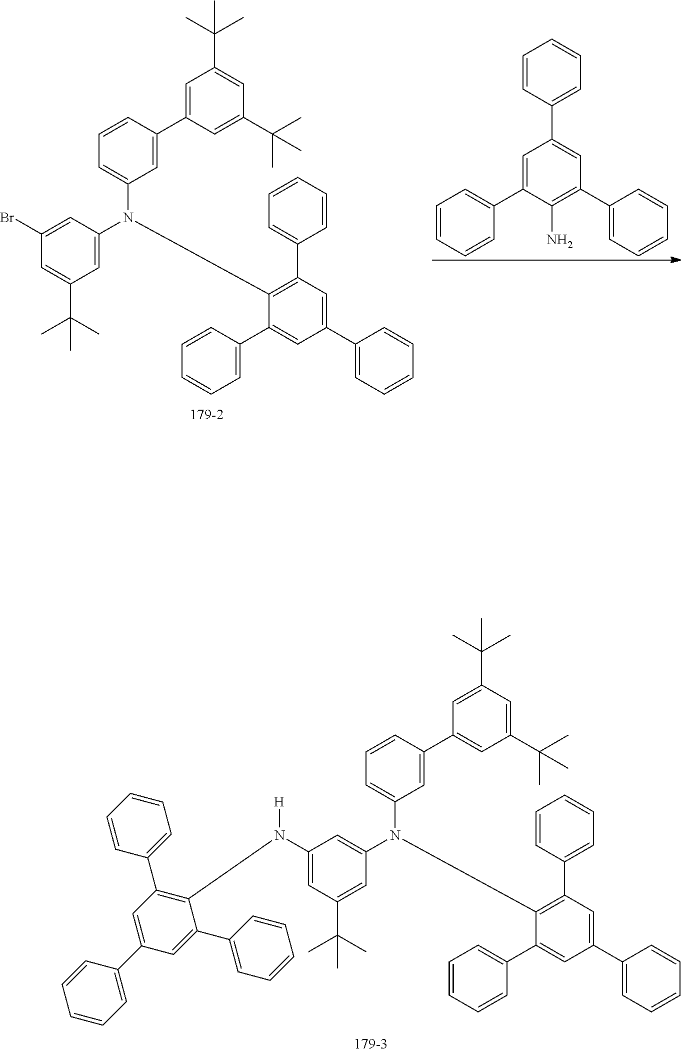 [SMILES: CC(C)(C)c1cc(Br)cc(N(c2cccc(-c3cc(C(C)(C)C)cc(C(C)(C)C)c3)c2)c2c(-c3ccccc3)cc(-c3ccccc3)cc2-c2ccccc2)c1 ; Nc1c(-c2ccccc2)cc(-c2ccccc2)cc1-c1ccccc1 ; CC(C)(C)c1cc(Nc2c(-c3ccccc3)cc(-c3ccccc3)cc2-c2ccccc2)cc(N(c2cccc(-c3cc(C(C)(C)C)cc(C(C)(C)C)c3)c2)c2c(-c3ccccc3)cc(-c3ccccc3)cc2-c2ccccc2)c1]

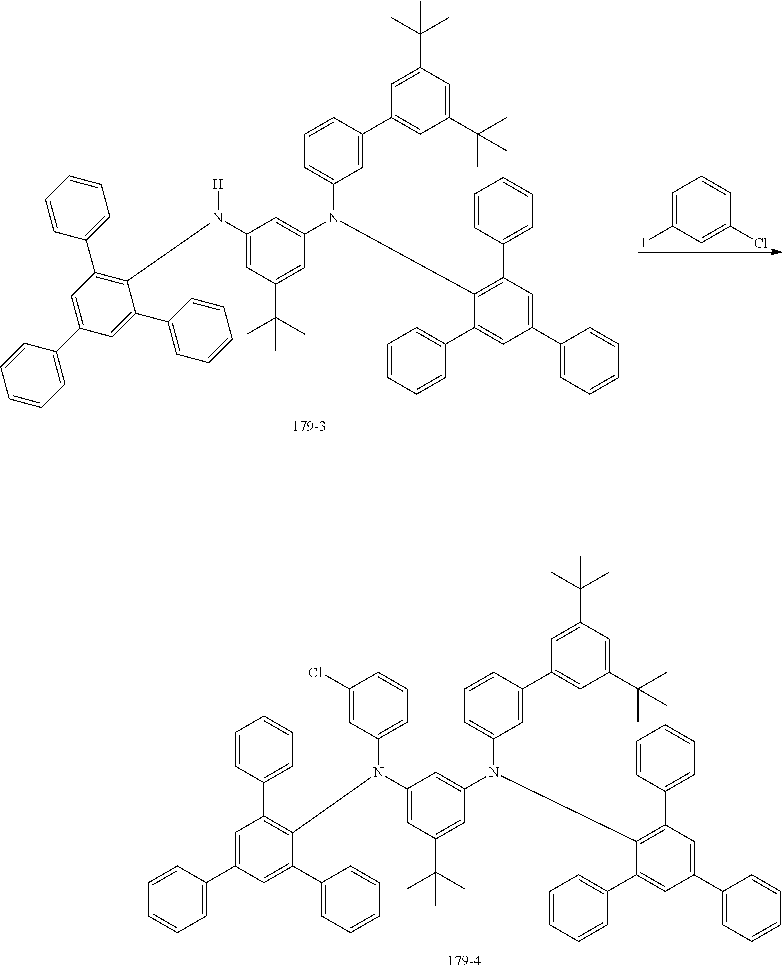 [SMILES: CC(C)(C)c1cc(Nc2c(-c3ccccc3)cc(-c3ccccc3)cc2-c2ccccc2)cc(N(c2cccc(-c3cc(C(C)(C)C)cc(C(C)(C)C)c3)c2)c2c(-c3ccccc3)cc(-c3ccccc3)cc2-c2ccccc2)c1 ; Clc1cccc(I)c1 ; CC(C)(C)c1cc(N(c2cccc(Cl)c2)c2c(-c3ccccc3)cc(-c3ccccc3)cc2-c2ccccc2)cc(N(c2cccc(-c3cc(C(C)(C)C)cc(C(C)(C)C)c3)c2)c2c(-c3ccccc3)cc(-c3ccccc3)cc2-c2ccccc2)c1]

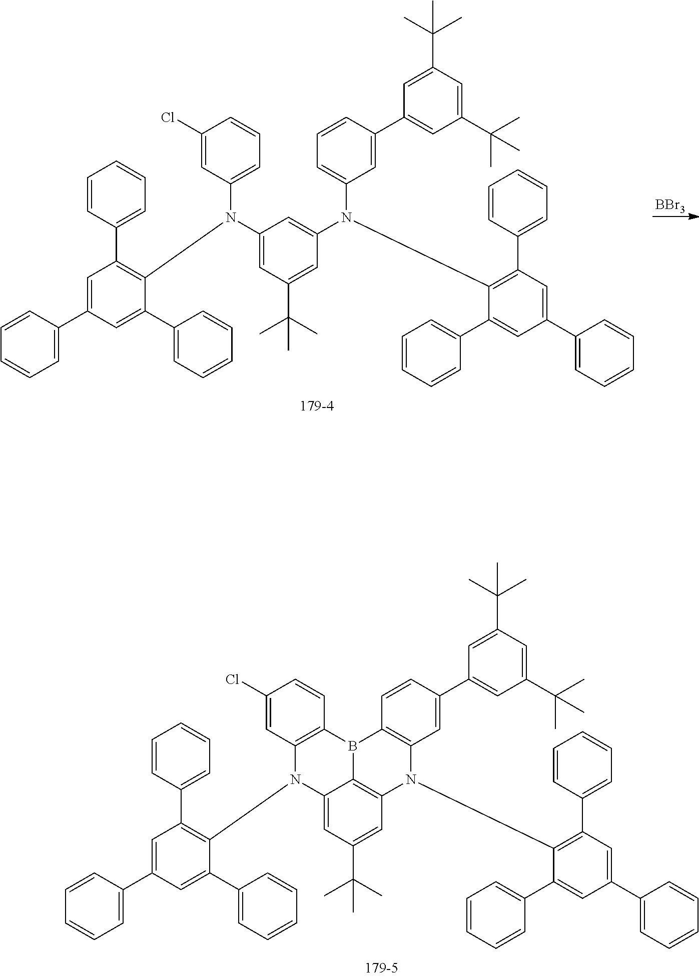 [SMILES: CC(C)(C)c1cc(N(c2cccc(Cl)c2)c2c(-c3ccccc3)cc(-c3ccccc3)cc2-c2ccccc2)cc(N(c2cccc(-c3cc(C(C)(C)C)cc(C(C)(C)C)c3)c2)c2c(-c3ccccc3)cc(-c3ccccc3)cc2-c2ccccc2)c1 ; "BBr3" ; CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(Cl)cc2N4c2c(-c3ccccc3)cc(-c3ccccc3)cc2-c2ccccc2)cc(C(C)(C)C)c1]

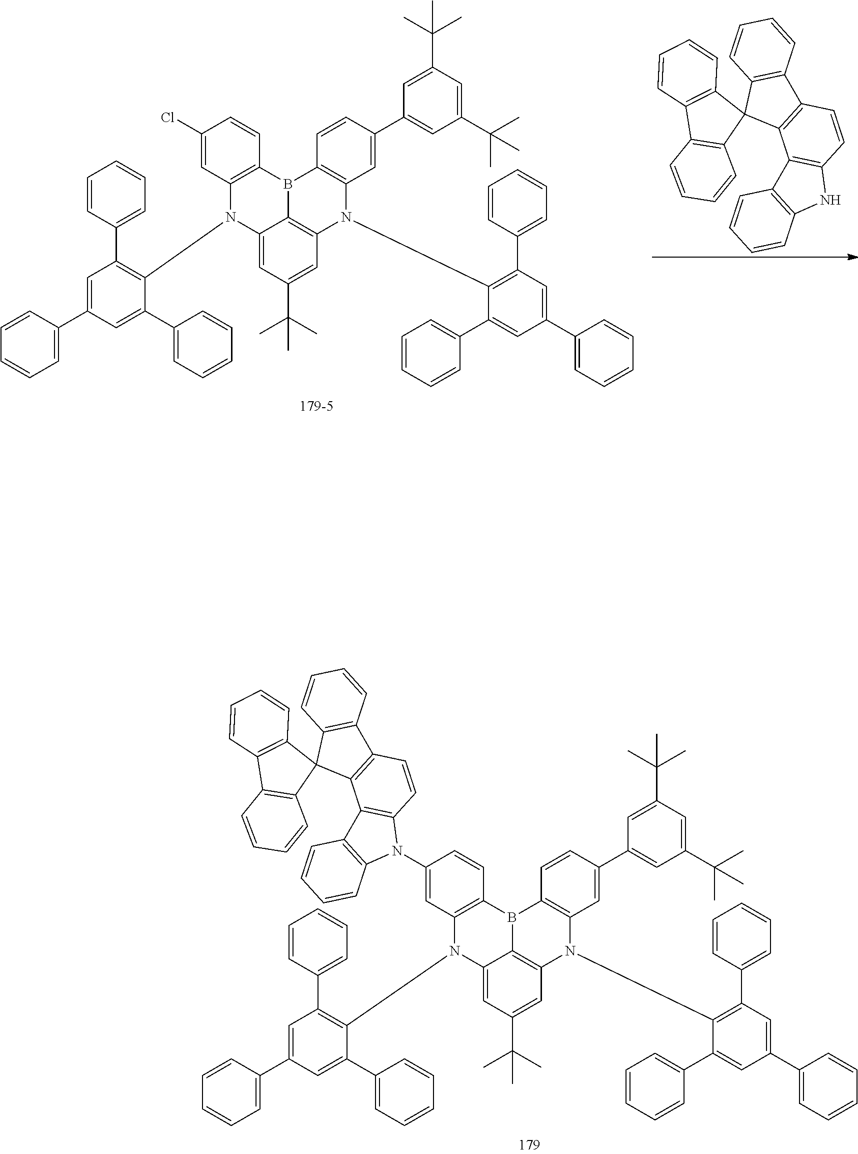 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(Cl)cc2N4c2c(-c3ccccc3)cc(-c3ccccc3)cc2-c2ccccc2)cc(C(C)(C)C)c1 ; c1ccc2c(c1)-c1ccccc1C21c2ccccc2-c2ccc3[nH]c4ccccc4c3c21 ; CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2c(-c3ccccc3)cc(-c3ccccc3)cc2-c2ccccc2)cc(C(C)(C)C)c1]

### <Synthesis of Intermediate 179-1>

In a nitrogen atmosphere, 1,3-dibromo-5-(tert-butyl)benzene (1 eq), 5′-phenyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling the reaction solution, water and ethyl acetate were added thereto to collect organic layers, and the reaction solution was dried over magnesium sulfate (MgSO₄) and filtered. In the filtrate, the solvent was removed under reduced pressure to obtain a product. The obtained product was purified and separated by column chromatography using silica gel to give Intermediate 179-1. (yield: 65%)

### <Synthesis of Intermediate 179-2>

In a nitrogen atmosphere, Intermediate 179-1 (1 eq), 3,5-di-tert-butyl-3′-iodo-1,1′-biphenyl (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Intermediate 179-2. (yield: 72%)

### <Synthesis of Intermediate 179-3>

In a nitrogen atmosphere, Intermediate 179-2 (1 eq), 5′-phenyl-[1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 179-3. (yield: 70%)

### <Synthesis of Intermediate 179-4>

In a nitrogen atmosphere, Intermediate 179-3 (1 eq), 1-chloro-3-iodobenzene (1.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 179-4. (yield: 66%)

### <Synthesis of Intermediate 179-5>

In a nitrogen atmosphere, Intermediate 179-4 (1 eq) was dissolved in o-dichlorobenzene, cooled using water-ice, and BBr₃ (5 eq) was slowly added dropwise thereto, and the reaction solution was stirred at about 180° C. for about 12 hours. The reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 179-5. (yield: 56%)

### <Synthesis of Compound 179>

In a nitrogen atmosphere, Intermediate 179-5 (1 eq), 5′H-spiro[fluorene-9,12′-indeno[1,2-c]carbazole] (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 179. (yield: 66%)

### (8) Synthesis of Compound 209

Compound 209 according to an embodiment may be synthesized by, for example, the steps shown in Reaction Scheme 8 below:

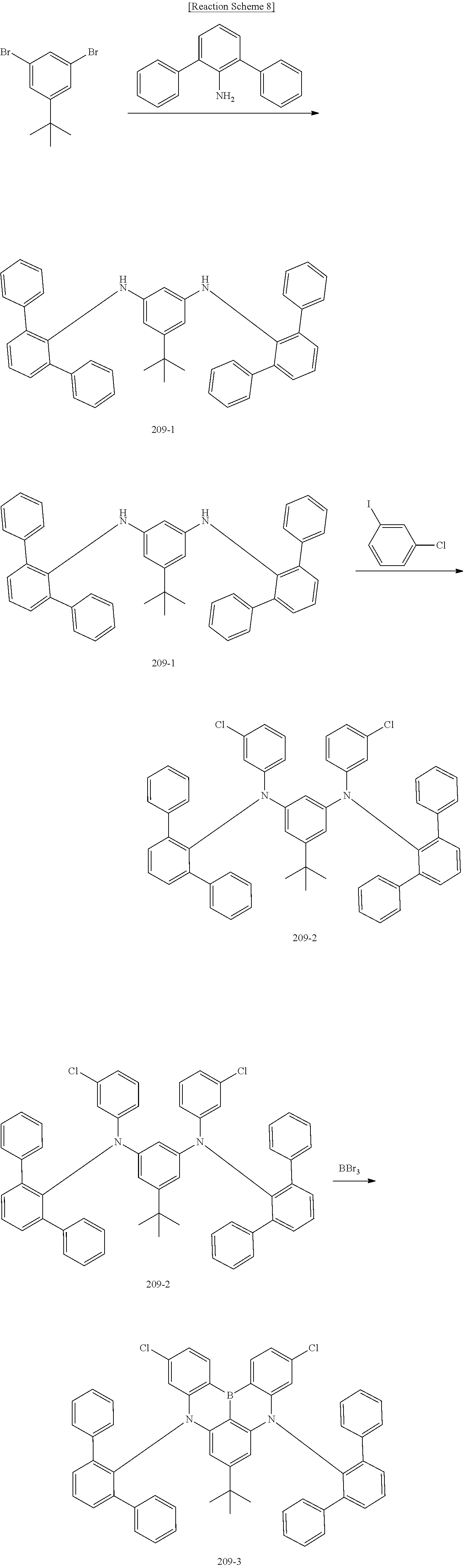

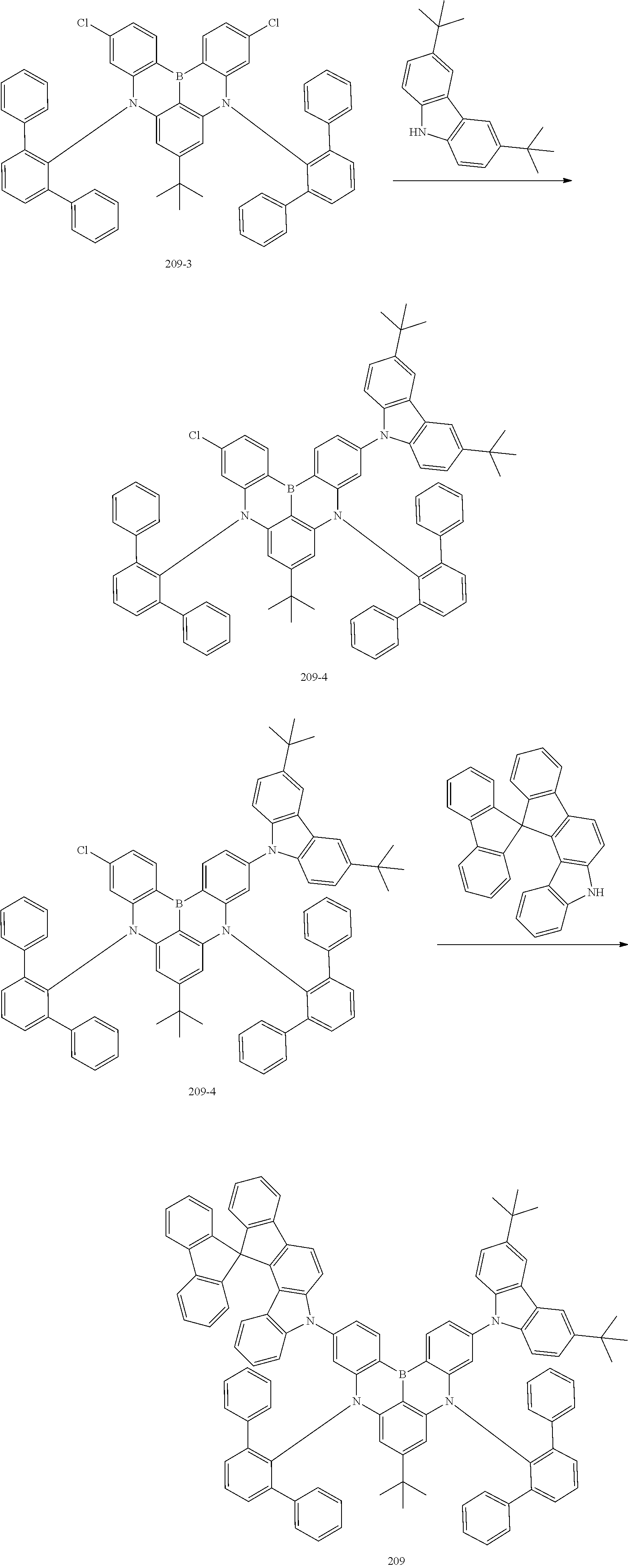

### <Synthesis of Intermediate 209-1>

In a nitrogen atmosphere, 1,3-dibromo-5-(tert-butyl)benzene (1 eq), [1,1′:3′,1″-terphenyl]-2′-amine (1.1 eq), Pd₂(dba)₃ (0.05 eq), tris-tert-butyl phosphine (0.1 eq), and sodium tert-butoxide (1.5 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 209-1. (yield: 72%)

### <Synthesis of Intermediate 209-2>

In a nitrogen atmosphere, Intermediate 209-1 (1 eq), 3-iodochlorobenzene (2.2 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to give Intermediate 209-2. (yield: 65%)

### <Synthesis of Intermediate 209-3>

In a nitrogen atmosphere, Intermediate 209-2 (1 eq) was dissolved in o-dichlorobenzene, cooled using water-ice, and BBr₃ (5 eq) was slowly added dropwise thereto, and the reaction solution was stirred at about 180° C. for about 24 hours. After the reaction solution was cooled, the reaction was terminated by adding triethylamine (5 eq), the reaction solution was extracted with H₂O/CH₂Cl₂ to collect organic layers, and the organic layers were dried over MgSO₄ and filtered. In the filtrate, the solvent was removed under reduced pressure to obtain a reaction product. The reaction product thus obtained was purified and recrystallized by silica gel column chromatography to obtain Intermediate 209-3. (yield: 58%)

### <Synthesis of Intermediate 209-4>

In a nitrogen atmosphere, Intermediate 209-3 (1 eq), 3,6-di-tert-butyl-9H-carbazole (1.1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and recrystallized by column chromatography using silica gel to obtain Intermediate 209-4. (yield: 49%)

### <Synthesis of Compound 209>

In a nitrogen atmosphere, Intermediate 209-4 (1 eq), 5′H-spiro[fluorene-9,12′-indeno[1,2-c]carbazole] (1.1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 1 day. After cooling, the reaction solution was extracted by adding water and ethyl acetate to collect organic layers, and the organic layers were dried over MgSO₄ and filtered. In the filtrate, the solvent was removed under reduced pressure to obtain a product. The obtained product was purified and separated by column chromatography using silica gel to obtain Compound 209. (yield: 57%)

### 2. Manufacture and Evaluation of Light Emitting Elements

### (1) Manufacture of Light Emitting Elements

Light emitting elements including a fused polycyclic compound according to an embodiment or a Comparative Example Compound in the emission layer were manufactured as follows. The light emitting elements of Examples 1-1 to 1-8 were respectively manufactured using Compounds 13, 20, 99, 106, 119, 133, 179, and 209, which are fused polycyclic compounds according to embodiments, as a dopant material in an emission layer, and the light emitting elements of Examples 2-1 to 2-4 were respectively manufactured using Compounds 13, 106, 119, and 209, which are fused polycyclic compounds according to embodiments, as a dopant material in an emission layer. The light emitting elements of Comparative Examples 1-1 and 1-2 were respectively manufactured using Comparative Example Compounds CX1 and CX2 as a dopant material for an emission layer, and the light emitting elements of Comparative Examples 2-1 and 2-2 were respectively manufactured using Comparative Example Compounds CX1 and CX2 as a dopant material for an emission layer.

A glass substrate (made by Corning Co.), on which an ITO electrode of about 15 Ω/cm² (about 1,200 Å) was formed as a first electrode (anode), was cut to a size of about 50 mm×50 mm×0.7 mm, cleansed by ultrasonic waves using isopropyl alcohol and pure water for about five minutes each, and irradiated with ultraviolet rays for about 30 minutes and exposed to ozone and cleansed. The glass substrate was installed on a vacuum deposition apparatus.

On the first electrode, NPD was deposited to form a 300-Å thick hole injection layer; and on the hole injection layer, Compound H-1-1 was deposited to form a 200-Å thick hole transport layer. On the hole transport layer, CzSi was deposited to form a 100-Å thick emission-auxiliary layer.

On the emission-auxiliary layer, a host mixture, a sensitizer, and a dopant were respectively co-deposited at a weight ratio of about 85:14:1 to form a 200-Å thick emission layer. In the forming of the emission layer, materials as shown in Tables 1 and 2 below were used as the host and the sensitizer, and the host mixture includes a hole transporting (HT) host and an electron transporting (ET) host at a weight ratio of about 5:5. The light emitting elements of Examples 1-1 to 1-8 have different host materials and a different sensitizer from Examples 2-1 to 2-4.

On the emission layer, TSPO1 was deposited to form a 200-Å thick hole blocking layer; and on the hole blocking layer, TPBi was deposited to form a 300-Å hick electron transport layer. On the electron transport layer, LiF was deposited to form a 10-Å thick electron injection layer, and on the electron injection layer, Al was deposited to form a 3,000-Å thick second electrode (cathode), thereby manufacturing a light emitting element.

### [Materials Used to Manufacture Light Emitting Elements]

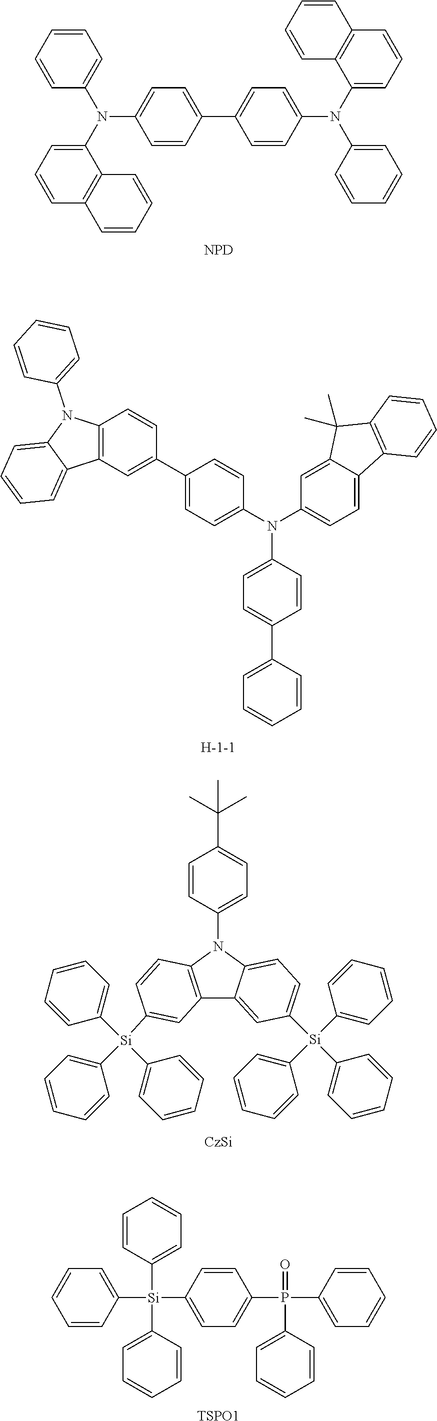

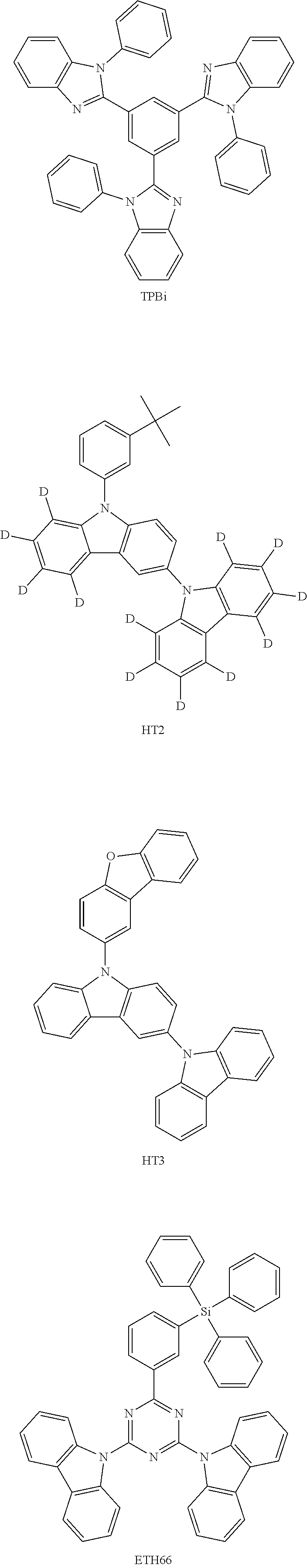

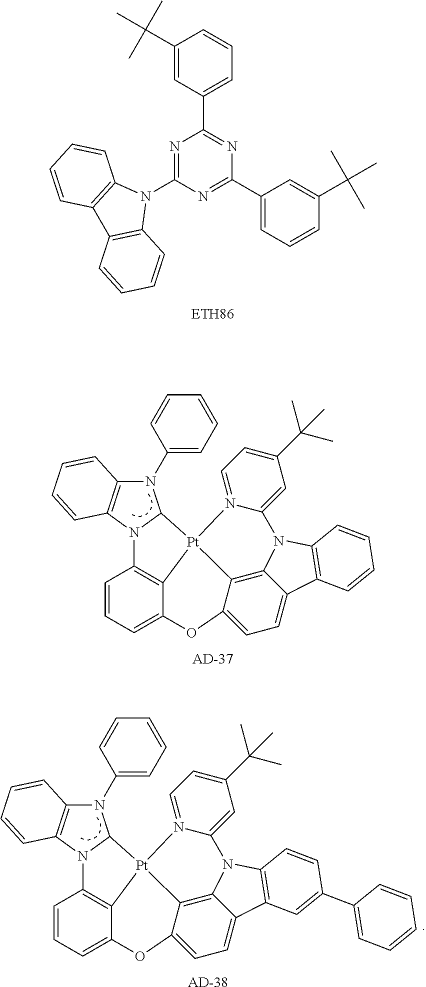

### Example Compounds

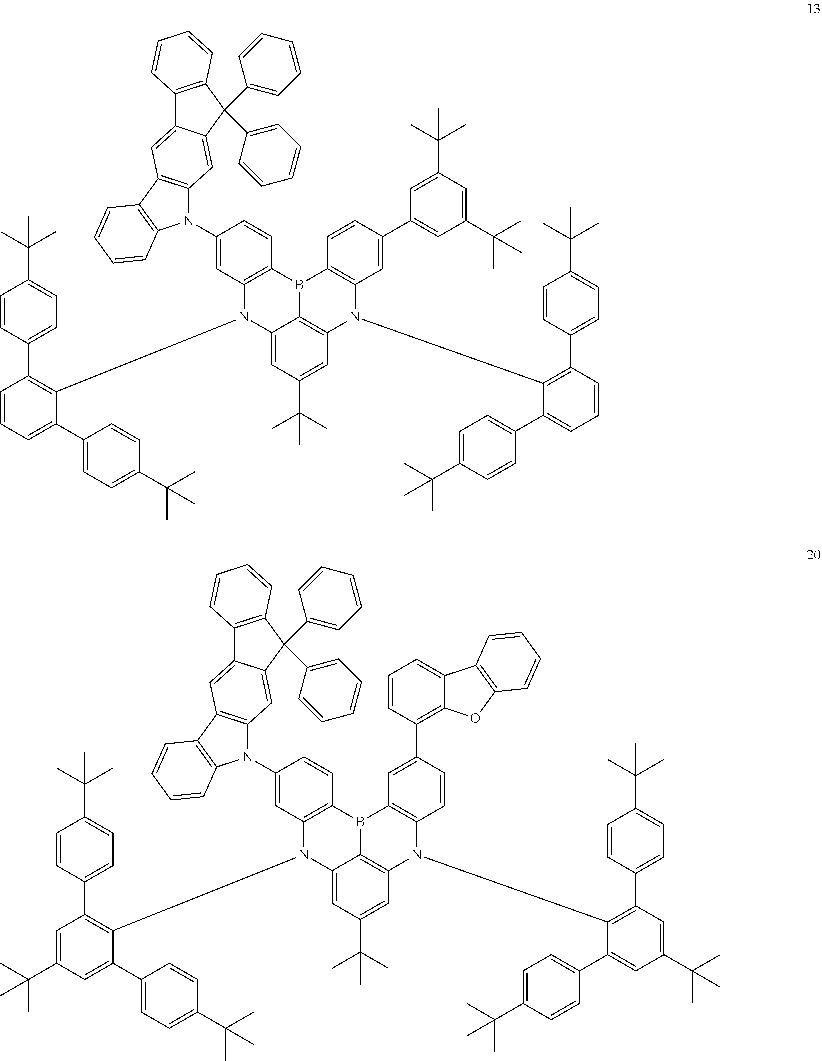

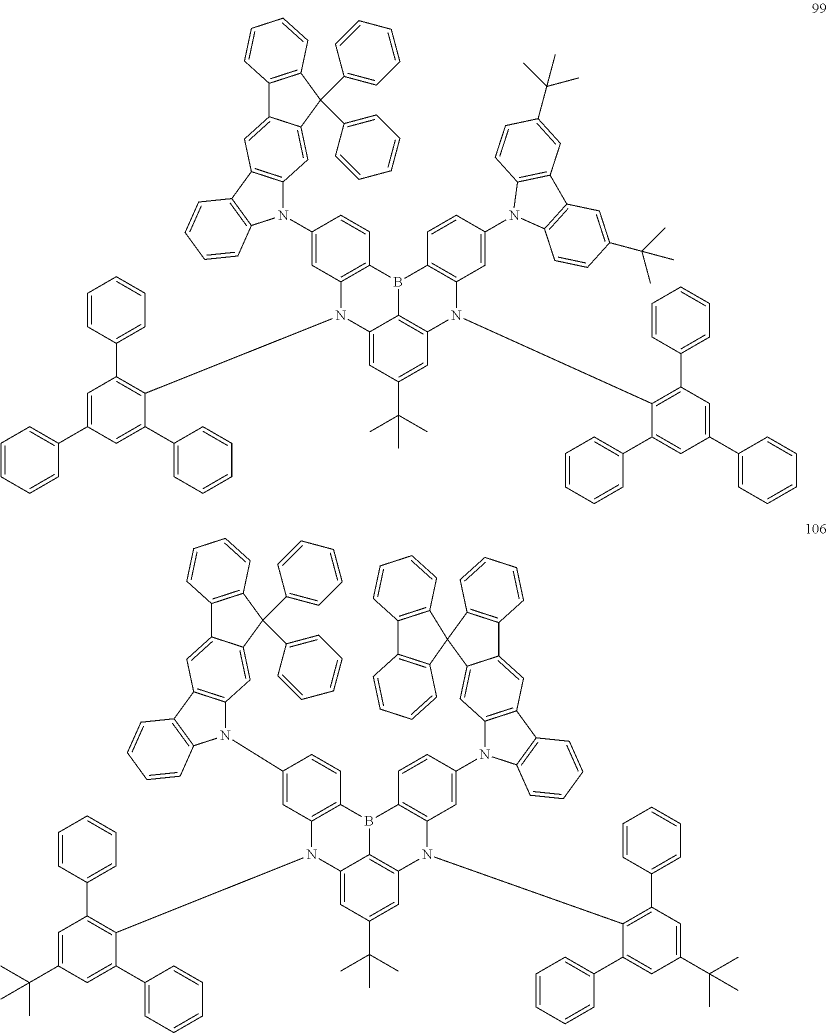 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1 ; CC(C)(C)c1cc(-c2ccccc2)c(N2c3cc(-n4c5ccccc5c5cc6c(cc54)C(c4ccccc4)(c4ccccc4)c4ccccc4-6)ccc3B3c4ccc(-n5c6ccccc6c6cc7c(cc65)C5(c6ccccc6-c6ccccc65)c5ccccc5-7)cc4N(c4c(-c5ccccc5)cc(C(C)(C)C)cc4-c4ccccc4)c4cc(C(C)(C)C)cc2c43)c(-c2ccccc2)c1]

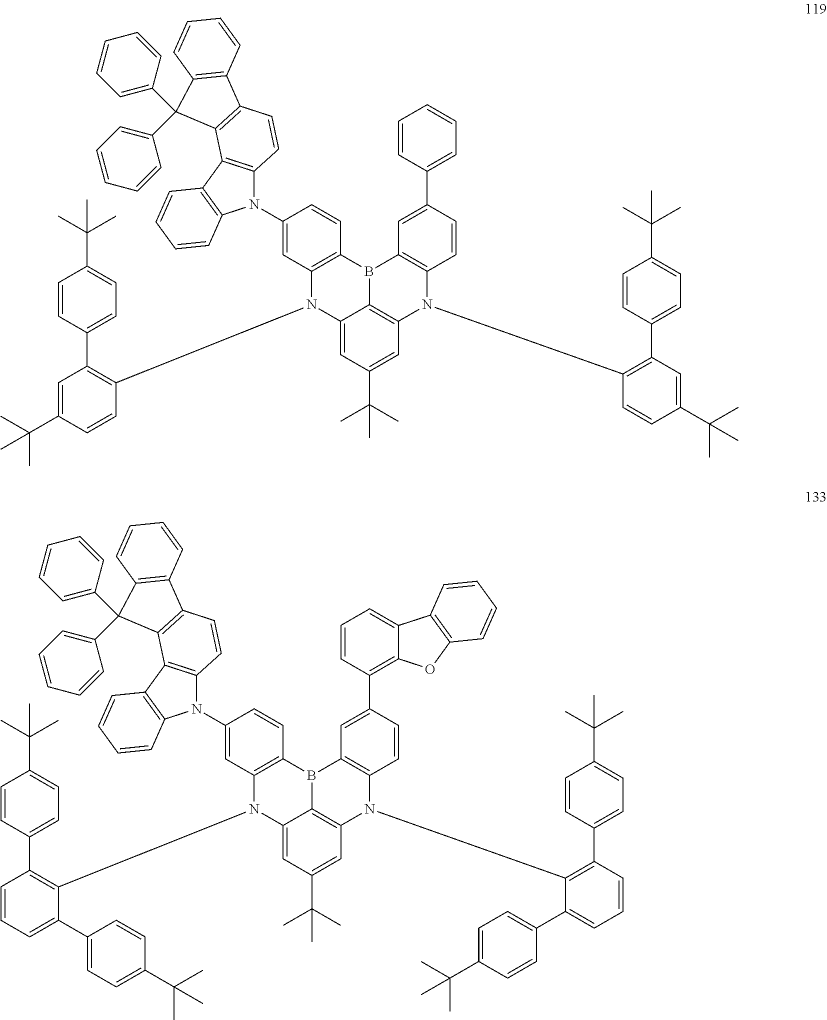 [SMILES: CC(C)(C)c1ccc(-c2cc(C(C)(C)C)ccc2N2c3ccc(-c4ccccc4)cc3B3c4ccc(-n5c6ccccc6c6c7c(ccc65)-c5ccccc5C7(c5ccccc5)c5ccccc5)cc4N(c4ccc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3ccc(-c4cccc5c4oc4ccccc45)cc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1]

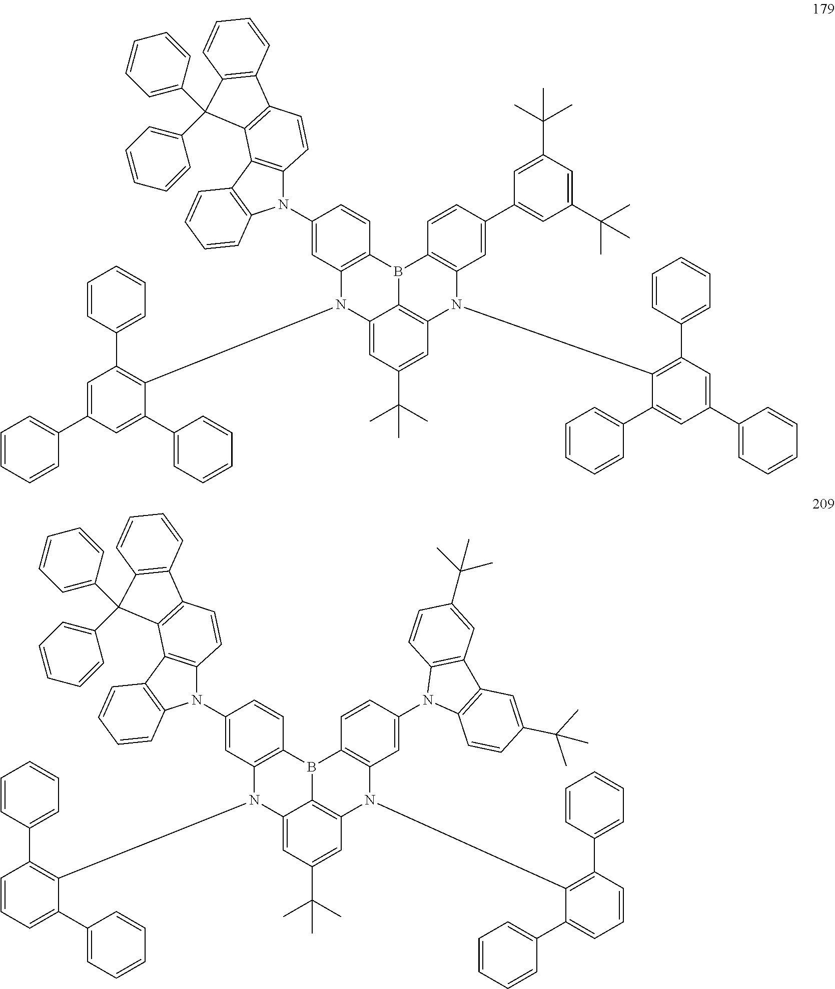 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5c6c(ccc53)-c3ccccc3C6(c3ccccc3)c3ccccc3)cc2N4c2c(-c3ccccc3)cc(-c3ccccc3)cc2-c2ccccc2)cc(C(C)(C)C)c1 ; CC(C)(C)c1cc2c3c(c1)N(c1c(-c4ccccc4)cccc1-c1ccccc1)c1cc(-n4c5ccccc5c5c6c(ccc54)-c4ccccc4C6(c4ccccc4)c4ccccc4)ccc1B3c1ccc(-n3c4ccc(C(C)(C)C)cc4c4cc(C(C)(C)C)ccc43)cc1N2c1c(-c2ccccc2)cccc1-c1ccccc1]

### Comparative Example Compounds

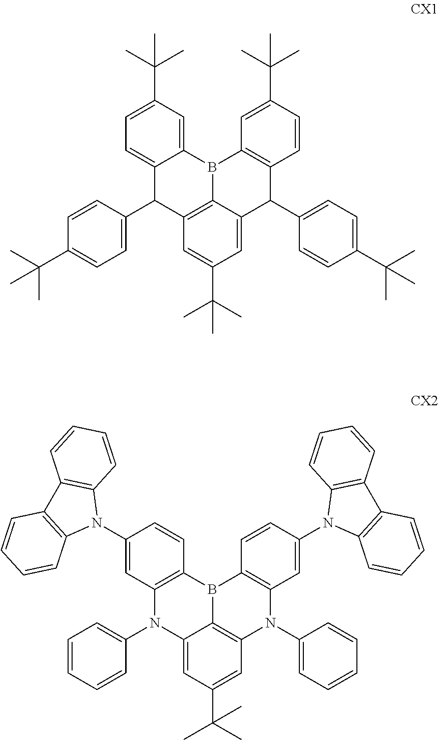 [SMILES: CC(C)(C)c1ccc(C2c3ccc(C(C)(C)C)cc3B3c4cc(C(C)(C)C)ccc4C(c4ccc(C(C)(C)C)cc4)c4cc(C(C)(C)C)cc2c43)cc1 ; CC(C)(C)c1cc2c3c(c1)N(c1ccccc1)c1cc(-n4c5ccccc5c5ccccc54)ccc1B3c1ccc(-n3c4ccccc4c4ccccc43)cc1N2c1ccccc1]

### (2) Evaluation of Light Emitting Elements

The light emitting elements of the Comparative Examples and the Examples were evaluated and the results are shown in Tables 1 and 2 below. Tables 1 and 2 show the results of measuring the driving voltage, luminous efficiency, light emission color, and service life at a current density of 10 mA/cm² using V7000 OLED IVL Test System (Polaronix). For the service life (T95), the time taken for a reduction from an initial brightness of 100% o to 95% o brightness was measured, and a relative service life was calculated on the basis of Comparative Examples 1-1 and 2-1, and the results are shown in Tables 1 and 2 below.

TABLE 1

| | Host | | | Driving | Luminous | | Service |
|---|---|---|---|---|---|---|---|
| | (HT:ET = | | | voltage | efficiency | Emission | life |
| | 5:5) | Sensitizer | Dopant | (V) | (cd/A) | color | (T95) |
| Example 1-1 | HT2/ETH66 | AD-37 | Compound 13 | 4.5 | 24.5 | Blue | 4.5 |
| Example 1-2 | HT2/ETH66 | AD-37 | Compound 20 | 4.3 | 25.1 | Blue | 4.7 |
| Example 1-3 | HT2/ETH66 | AD-37 | Compound 99 | 4.1 | 25.8 | Blue | 5.1 |
| Example 1-4 | HT2/ETH66 | AD-37 | Compound 106 | 4.1 | 25.4 | Blue | 5.2 |
| Example 1-5 | HT2/ETH66 | AD-37 | Compound 119 | 4.4 | 24.1 | Blue | 4.6 |
| Example 1-6 | HT2/ETH66 | AD-37 | Compound 133 | 4.2 | 25.3 | Blue | 4.8 |
| Example 1-7 | HT2/ETH66 | AD-37 | Compound 179 | 4.4 | 24.7 | Blue | 4.7 |
| Example 1-8 | HT2/ETH66 | AD-37 | Compound 209 | 4.2 | 25.1 | Blue | 4.9 |
| Comparative | HT2/ETH66 | AD-37 | Comparative | 5.1 | 16.0 | Blue | 1.0 |
| Example 1-1 | | | Example | | | | |
| | | | Compound CX1 | | | | |
| Comparative | HT2/ETH66 | AD-37 | Comparative | 4.7 | 21.3 | Blue | 3.3 |
| Example 1-2 | | | Example | | | | |
| | | | Compound CX2 | | | | |

TABLE 2

| | Host | | | Driving | Luminous | | Service |
|---|---|---|---|---|---|---|---|
| | (HT:ET = | | | voltage | efficiency | Emission | life |
| | 5:5) | Sensitizer | Dopant | (V) | (cd/A) | color | (T95) |
| Example 2-1 | HT3/ETH86 | AD-38 | Compound 13 | 4.7 | 21.3 | Blue | 4.2 |
| Example 2-2 | HT3/ETH86 | AD-38 | Compound 106 | 4.2 | 24.1 | Blue | 4.9 |
| Example 2-3 | HT3/ETH86 | AD-38 | Compound 119 | 4.7 | 21.7 | Blue | 4.3 |
| Example 2-4 | HT3/ETH86 | AD-38 | Compound 209 | 4.4 | 23.4 | Blue | 4.8 |
| Comparative | HT3/ETH86 | AD-38 | Comparative | 5.4 | 14.3 | Blue | 1.0 |
| Example 2-1 | | | Example | | | | |
| | | | Compound CX1 | | | | |
| Comparative | HT3/ETH86 | AD-38 | Comparative | 4.9 | 18.5 | Blue | 3.1 |
| Example 2-2 | | | Example | | | | |
| | | | Compound CX2 | | | | |

Referring to Table 1, it may be seen that the light emitting elements of Comparative Example 1-1, Comparative Example 1-2, and Examples 1-1 to 1-8 emit blue light. It may be seen that the light emitting elements of Examples 1-1 to 1-8 have lower driving voltages, higher luminous efficiencies, and longer service lives, as compared to the light emitting elements of Comparative Examples 1-1 and 1-2.

Referring to Table 2, it may be seen that the light emitting elements of Comparative Example 2-1, Comparative Example 2-2, and Examples 2-1 to 2-4 emit blue light. It may be seen that the light emitting elements of Examples 2-1 to 2-4 have lower driving voltages, higher luminous efficiencies, and longer service lives, as compared to the light emitting elements of Comparative Examples 2-1 and 2-2.

The light emitting elements of Examples 1-1 to 1-8 respectively include Compounds 13, 20, 99, 106, 119, 133, 179, and 209, and the light emitting elements of Examples 2-1 to 2-4 respectively include Compounds 13, 106, 119, and 209. Compounds 13, 20, 99, 106, 119, 133, 179, and 209 are fused polycyclic compounds according to embodiments.

Compounds 13, 20, 99, 106, 119, 133, 179, and 209 each include a pentacyclic fused ring core as a central structure and include an indenocarbazole moiety and a biphenyl moiety (or terphenyl moiety) each bonded to the central structure. The pentacyclic fused ring core includes two nitrogen atoms and a boron atom as ring-forming atoms. Accordingly, Compounds 13, 20, 99, 106, 119, 133, 179, and 209 may have excellent material stability, may prevent Dexter energy transfer, and may accelerate RISC. Accordingly, it may be seen that the light emitting element including the fused polycyclic compound according to an embodiment will exhibit low driving voltage, high luminous efficiency, and long service life characteristics.

The light emitting elements of Comparative Example 1-1 and Comparative Example 2-1 each include Comparative Compound CX1, and Comparative Compound CX1 includes a pentacyclic fused ring core as a central structure, but does not include an indenocarbazole moiety and a biphenyl moiety (or terphenyl moiety). Accordingly, the light emitting elements of Comparative Example 1-1 and Comparative Example 2-1 show higher driving voltages, lower luminous efficiencies, and shorter service lives than the light emitting element of the Examples.

The light emitting elements of Comparative Examples 1-2 and 2-2 each include Comparative Example Compound CX2. Comparative Example Compound CX2 includes a pentacyclic fused ring core as a central structure, but does not include an indenocarbazole moiety and a biphenyl moiety (or terphenyl moiety). Comparative Example Compound CX2 has a deeper HOMO energy level value and lower concentration of triplet excitons than Comparative Example Compound CX1 due to the introduction of a carbazole substituent. Accordingly, the light emitting element of Comparative Example 2-2 including Comparative Example Compound CX2 shows a lower driving voltage and a longer service life than the light emitting element of Comparative Example 1-1. However, Comparative Example Compound CX2 does not include a bulky substituent such as an indenocarbazole moiety, and thus Dexter energy transfer occurs. As such, it shows a higher driving voltage, lower luminous efficiency, and shorter service life than the light emitting element of the Examples.

The display device according to an embodiment may include the light emitting element according to an embodiment. The light emitting element may include the fused polycyclic compound according to an embodiment. The fused polycyclic compound may include a central structure and an indenocarbazole moiety and a biphenyl moiety (or terphenyl moiety) bonded to the central structure. The central structure may be a pentacyclic fused ring core that includes two nitrogen atoms and a boron atom as ring-forming atoms. Accordingly, the fused polycyclic compound may exhibit excellent material stability, may prevent Dexter energy transfer, and may accelerate RISC. The light emitting element including the fused polycyclic compound according to an embodiment may exhibit a low driving voltage, high luminous efficiency, and long service life.

The light emitting element according to an embodiment and a display device including the same may include the fused polycyclic compound according to an embodiment, thereby exhibiting high efficiency and long service life characteristics.

The fused polycyclic compound according to an embodiment may contribute to high efficiency and long service life of the light emitting element.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises a first compound represented by Formula 1: 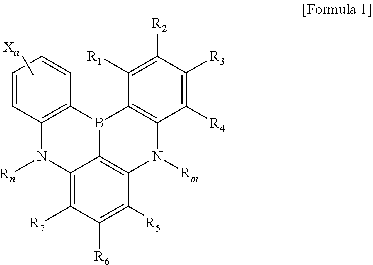
wherein in Formula 1,
R₁ to R₇ are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
Xₐ is a group represented by Formula 2, and
Rₙ and Rₘ are each independently a group represented by Formula 3; 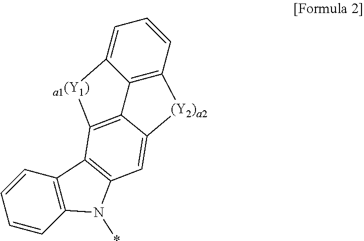
wherein in Formula 2,
one of a1 and a2 is 1,
the other of a1 and a2 is 0,
Y₁ and Y₂ are each independently C(Rₐ)(R_{b}),
Rₐ and R_{b} are each independently a substituted or unsubstituted aryl group having 6 to 20 ring-forming carbon atoms, or are bonded to each other to form a ring, and
-* represents a binding site to a neighboring atom; and 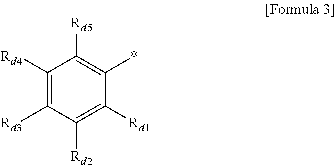
wherein in Formula 3,
R_{d1} to R_{d5} are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
-* represents a binding site to a neighboring atom.

2. The light emitting element of claim 1, wherein the emission layer further comprises at least one of a second compound represented by Formula HT-1, a third compound represented by Formula ET-1, and a fourth compound represented by Formula D-1: 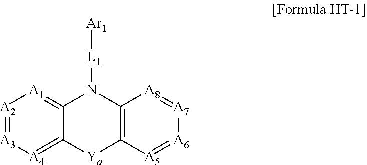
wherein in Formula HT-1,
A₁ to A₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Ar₁ is a substituted or unsubstituted aryl group having 6 to 30 ring-forming carbon atoms or a substituted or unsubstituted heteroaryl group having 2 to 30 ring-forming carbon atoms,
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring; 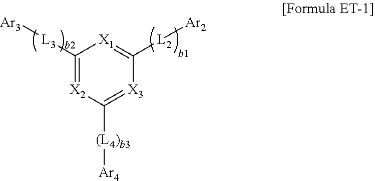
wherein in Formula ET-1,
at least one of X₁ to X₃ is each N,
the remainder of X₁ to X₃ are each independently C(R₅₆),
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group of 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms; 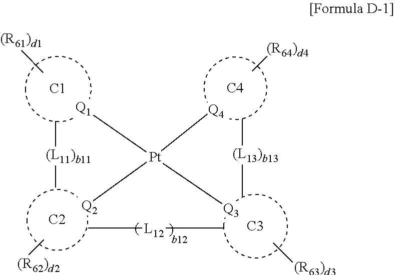
wherein in Formula D-1,
Q₁ to Q₄ are each independently C or N,
C₁ to C₄ are each independently a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
L₁₁ to L₁₃ are each independently a direct linkage, *—O—*, *—S—*, 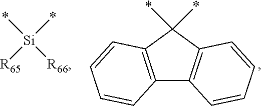
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer from 0 to 4.

3. The light emitting element of claim 1, wherein the first compound is represented by one of Formula 1-1 to Formula 1-4: 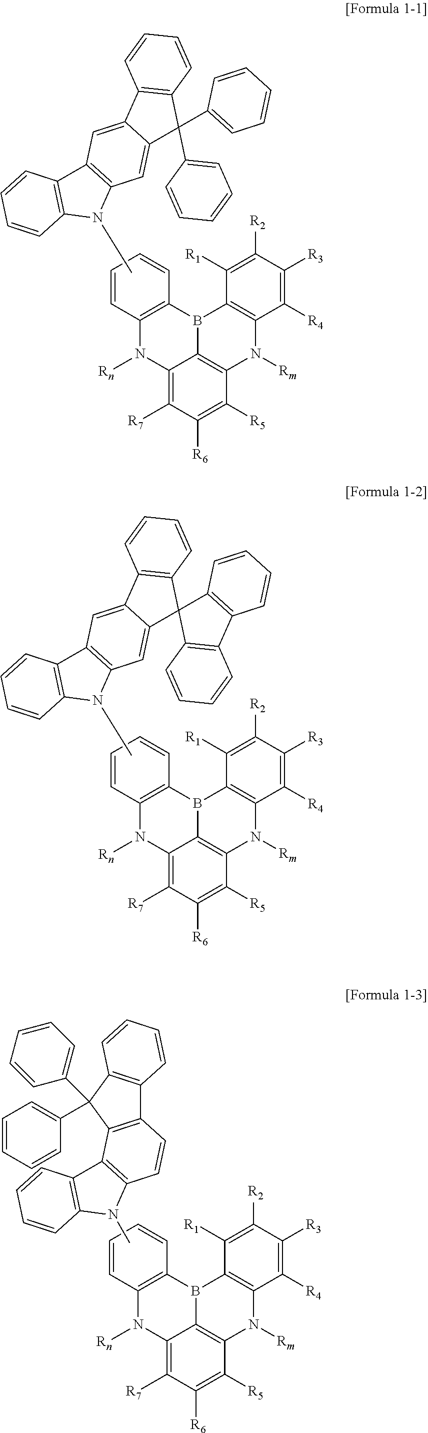 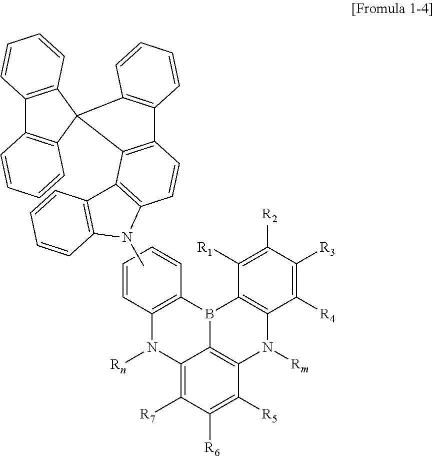
wherein in Formula 1-1 to Formula 1-4, Rₙ, Rₘ, and R₁ to R₇ are the same as defined in Formula 1.

4. The light emitting element of claim 1, wherein the first compound is represented by Formula 1-A: 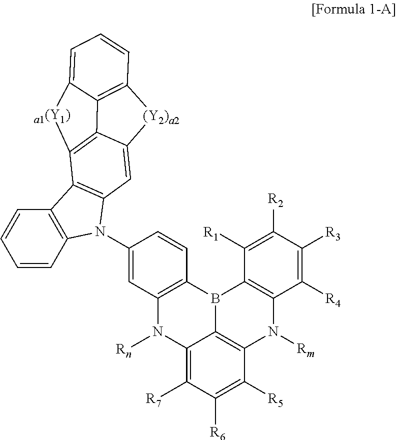
wherein in Formula 1-A,
Rₙ, Rₘ, R₁ to R₇, Y₁, Y₂, a1, and a2 are the same as defined in Formula 1 and Formula 2.

5. The light emitting element of claim 4, wherein the first compound is represented by Formula 1-A1: 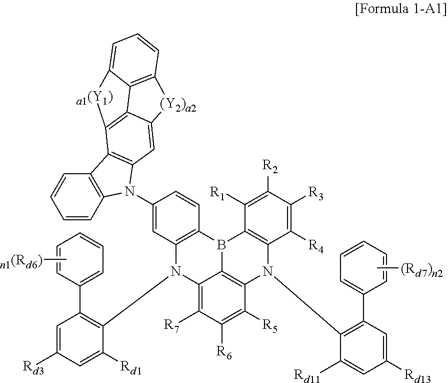
wherein in Formula 1-A1,
n1 and n2 are each independently an integer from 0 to 5,
R_{d6} and R_{d7} are each independently a hydrogen atom, a deuterium atom, or a substituted or unsubstituted alkyl group having 1 to 30 carbon atoms,
R_{d11} and R_{d13} are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
R₁ to R₇, Y₁, Y₂, a1, a2, R_{d1}, and R_{d3} are the same as defined in Formula 1, Formula 2, and Formula 3.

6. The light emitting element of claim 1, wherein the group represented by Formula 3 is represented by one of Formula 3-1 to Formula 3-8: 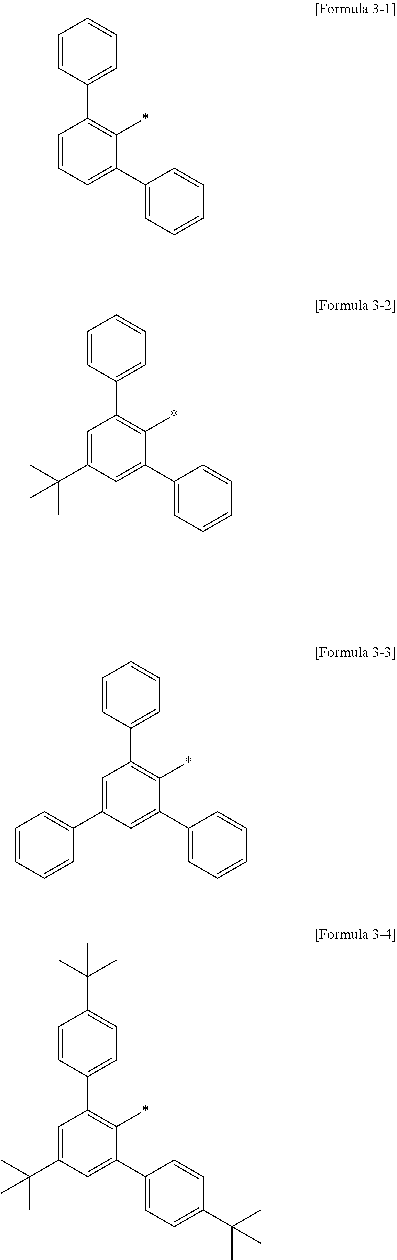 [SMILES: *c1c(-c2ccccc2)cccc1-c1ccccc1 ; *c1c(-c2ccccc2)cc(C(C)(C)C)cc1-c1ccccc1 ; *c1c(-c2ccccc2)cc(-c2ccccc2)cc1-c1ccccc1 ; *c1c(-c2ccc(C(C)(C)C)cc2)cc(C(C)(C)C)cc1-c1ccc(C(C)(C)C)cc1] 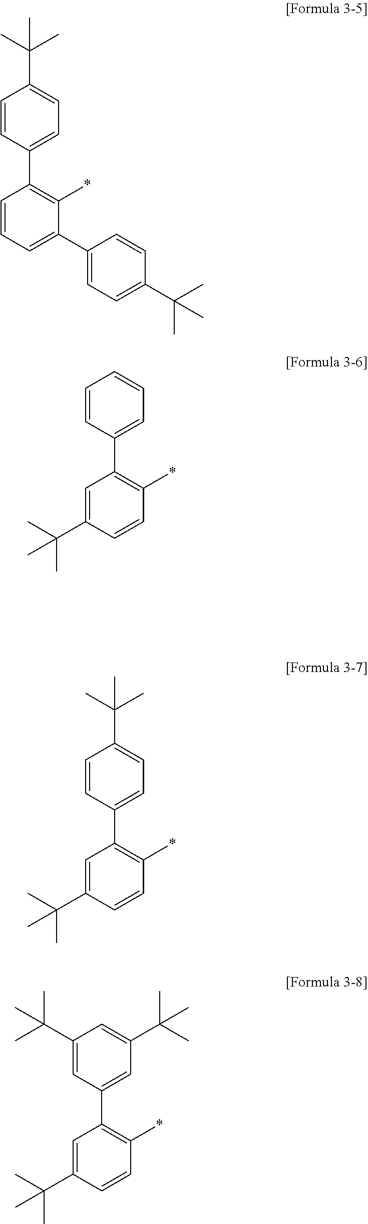
wherein in Formula 3-1 to Formula 3-8,
-* represents a binding site to a neighboring atom.

7. The light emitting element of claim 1, wherein in Formula 1, R₂ and R₃ are each independently a hydrogen atom, a substituted or unsubstituted phenyl group, a substituted or unsubstituted dibenzofuran group, a substituted or unsubstituted carbazole group, or a group represented by Formula 2.

8. The light emitting element of claim 1, wherein in Formula 1, R₂ and R₃ are each independently a group represented by one of Formula R-1 to Formula R-10: 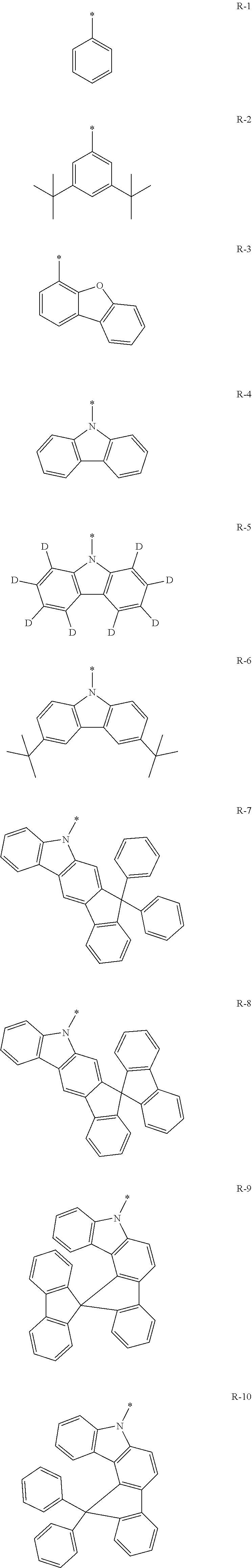
wherein in Formula R-5,
D represents a deuterium atom, and
wherein in Formula R-1 to Formula R-10,
-* represents a binding site to a neighboring atom.

9. The light emitting element of claim 1, wherein in Formula 1, R₆ is a hydrogen atom or a substituted or unsubstituted t-butyl group.

10. The light emitting element of claim 1, wherein the first compound includes at least one compound selected from Compound Group 1: 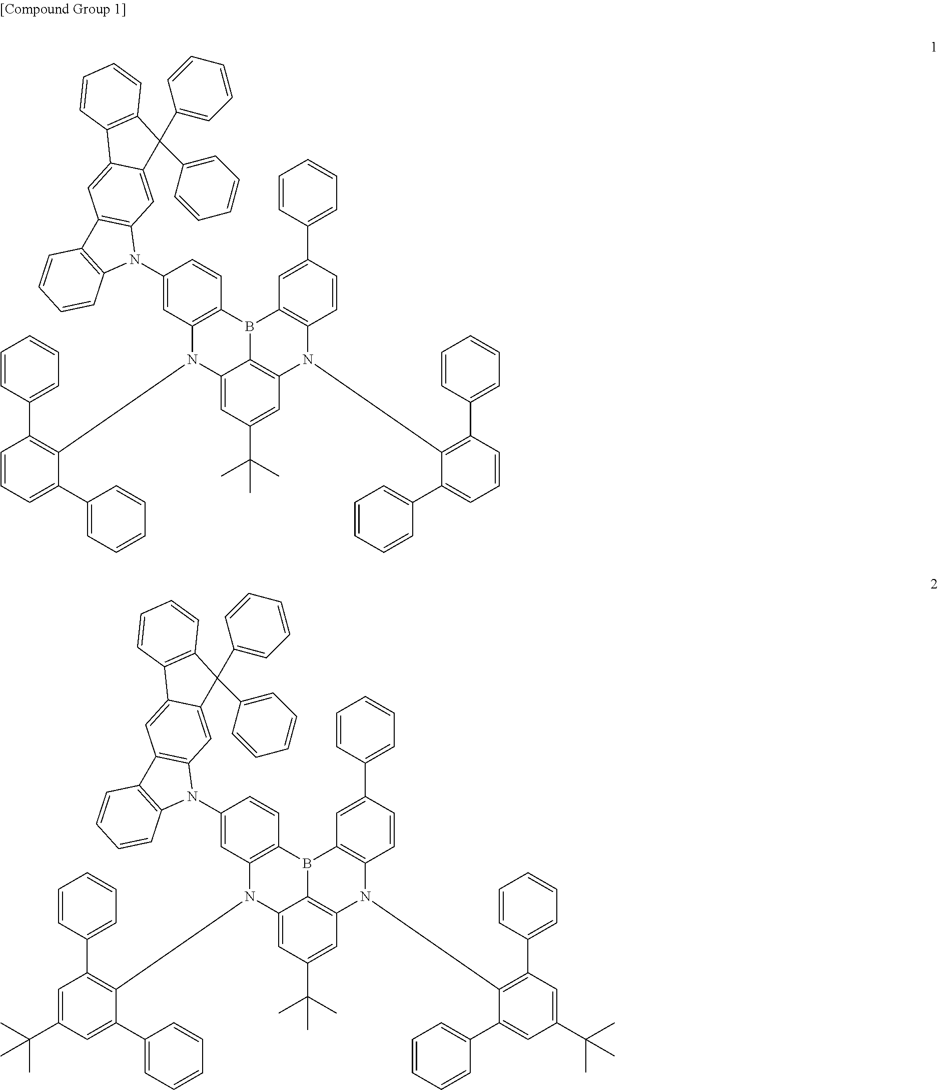 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1cc(-c3ccccc3)ccc1N2c1c(-c2ccccc2)cccc1-c1ccccc1 ; CC(C)(C)c1cc(-c2ccccc2)c(N2c3ccc(-c4ccccc4)cc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1] 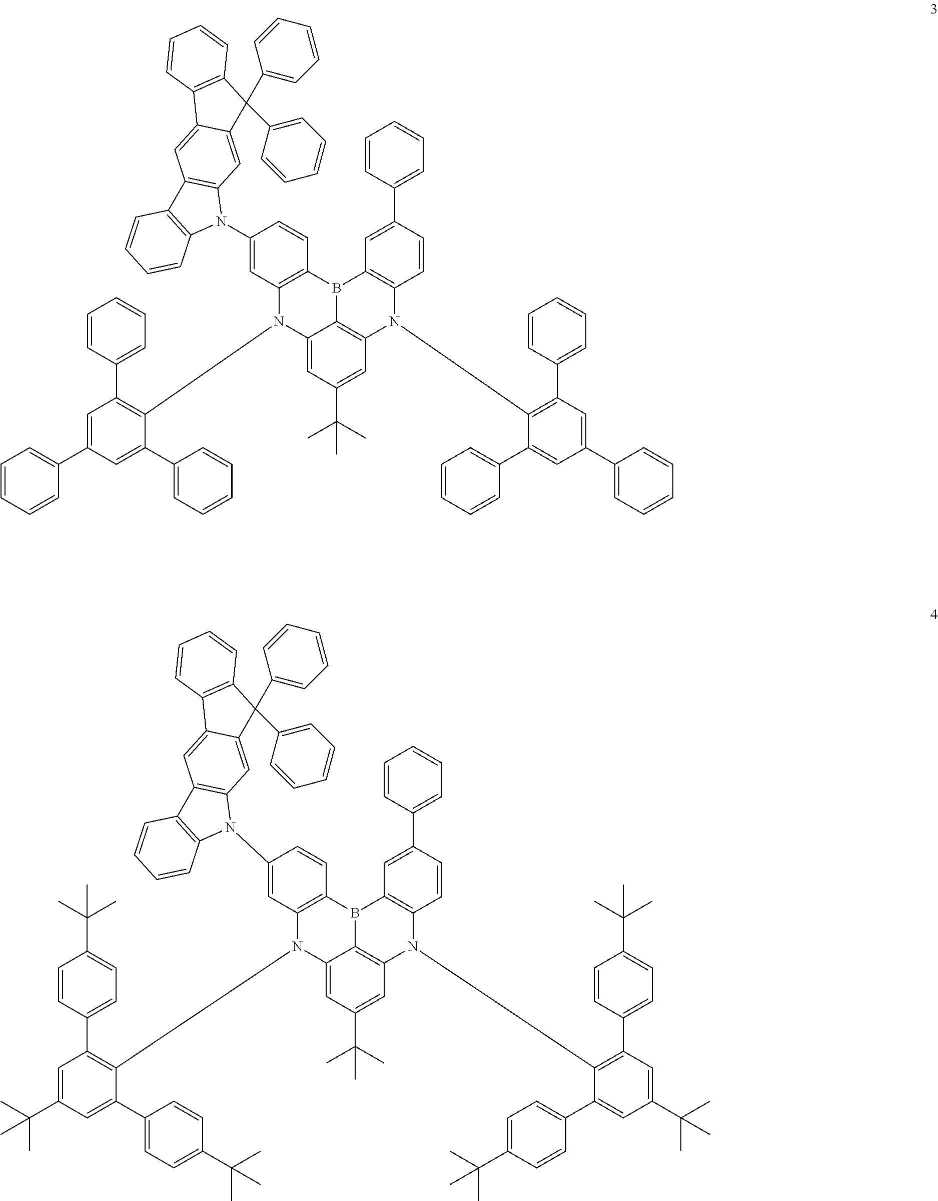 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1cc(-c3ccccc3)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4ccccc4)cc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 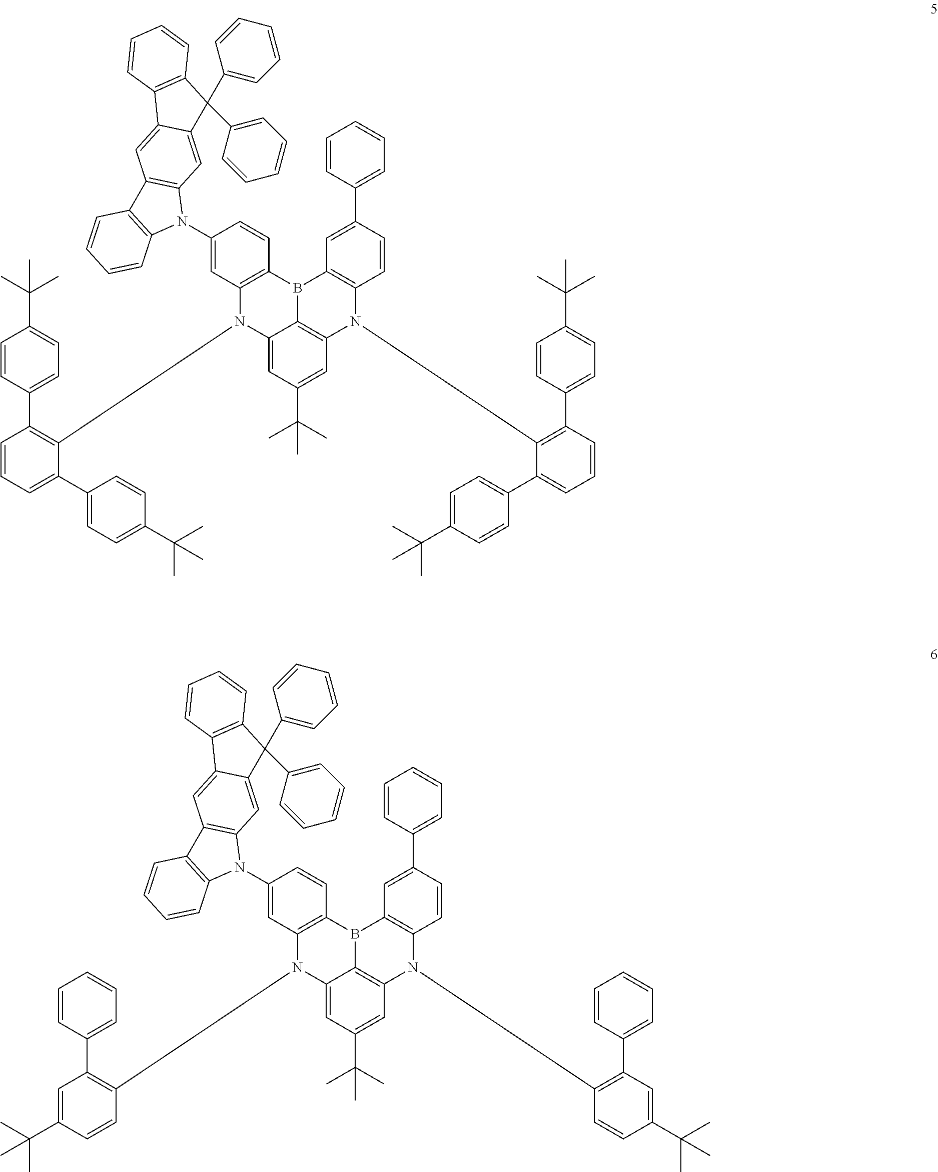 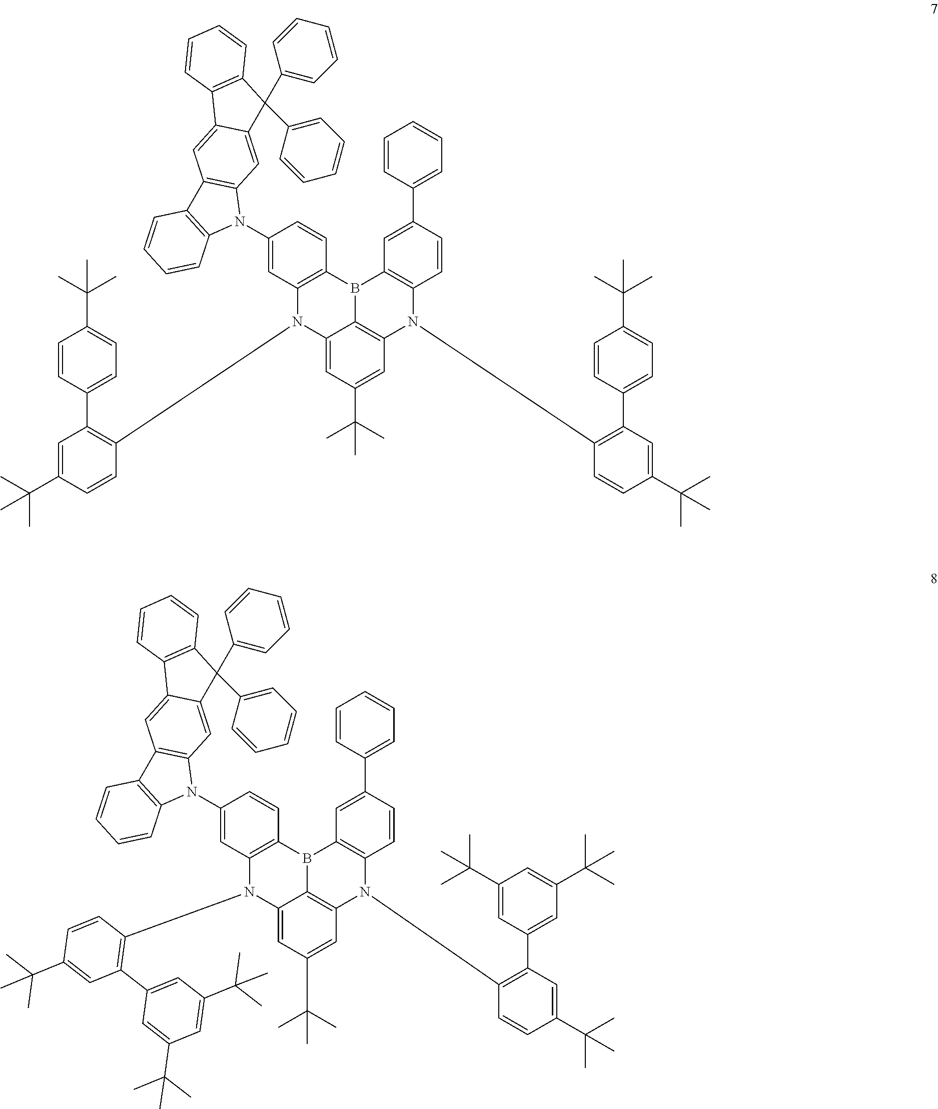 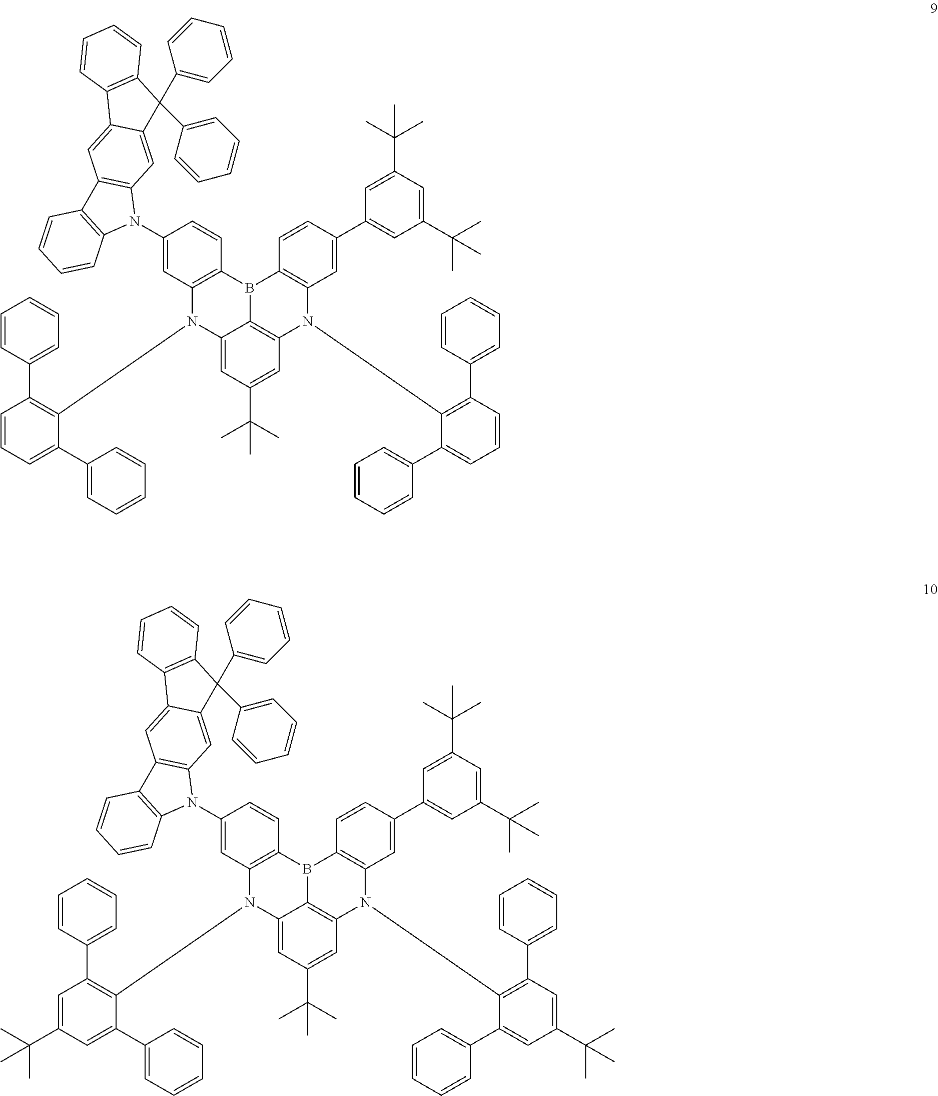 [SMILES: CC(C)(C)c1cc(-c2ccc3c(c2)N(c2c(-c4ccccc4)cccc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cccc2-c2ccccc2)cc(C(C)(C)C)c1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cc(C(C)(C)C)cc2-c2ccccc2)cc(C(C)(C)C)c1] 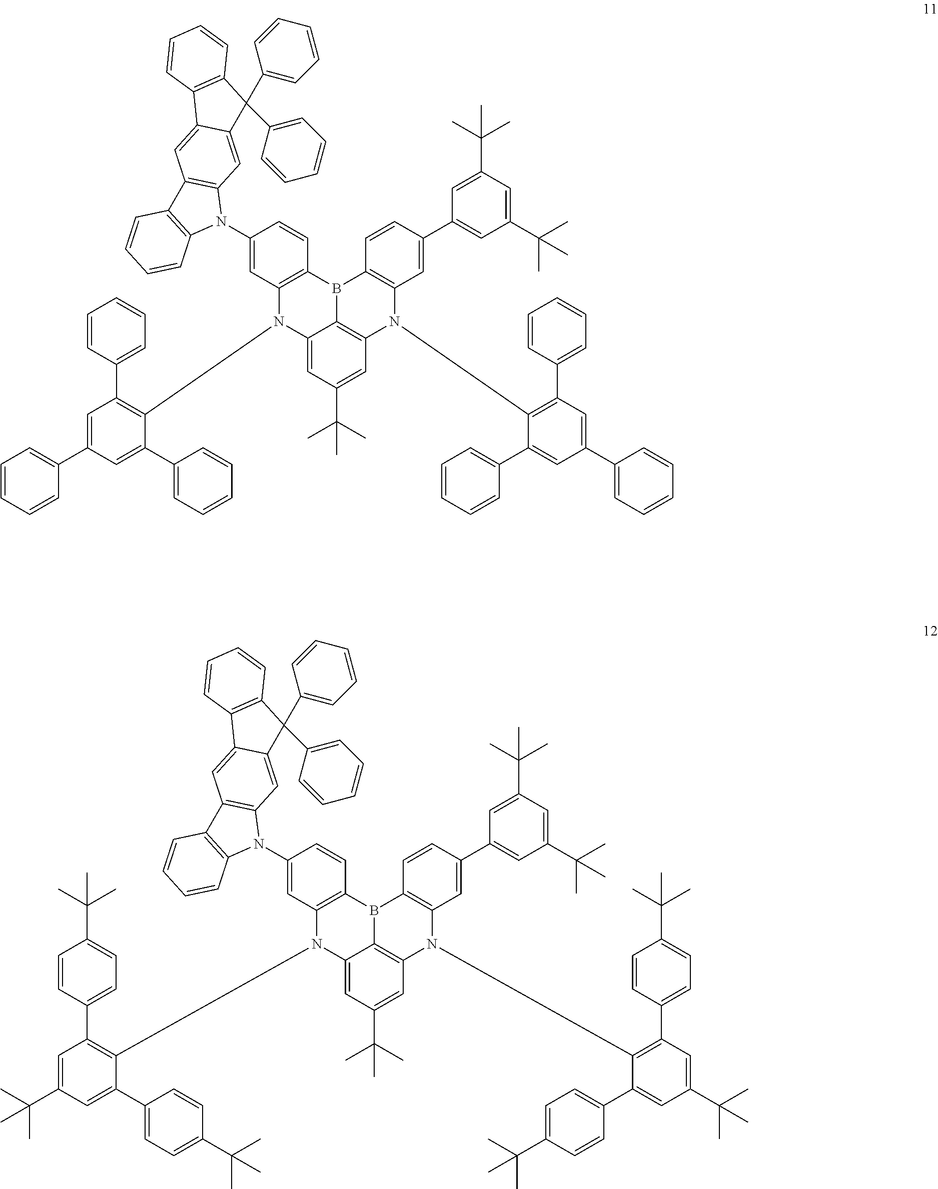 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5cc6c(cc53)C(c3ccccc3)(c3ccccc3)c3ccccc3-6)cc2N4c2c(-c3ccccc3)cc(-c3ccccc3)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 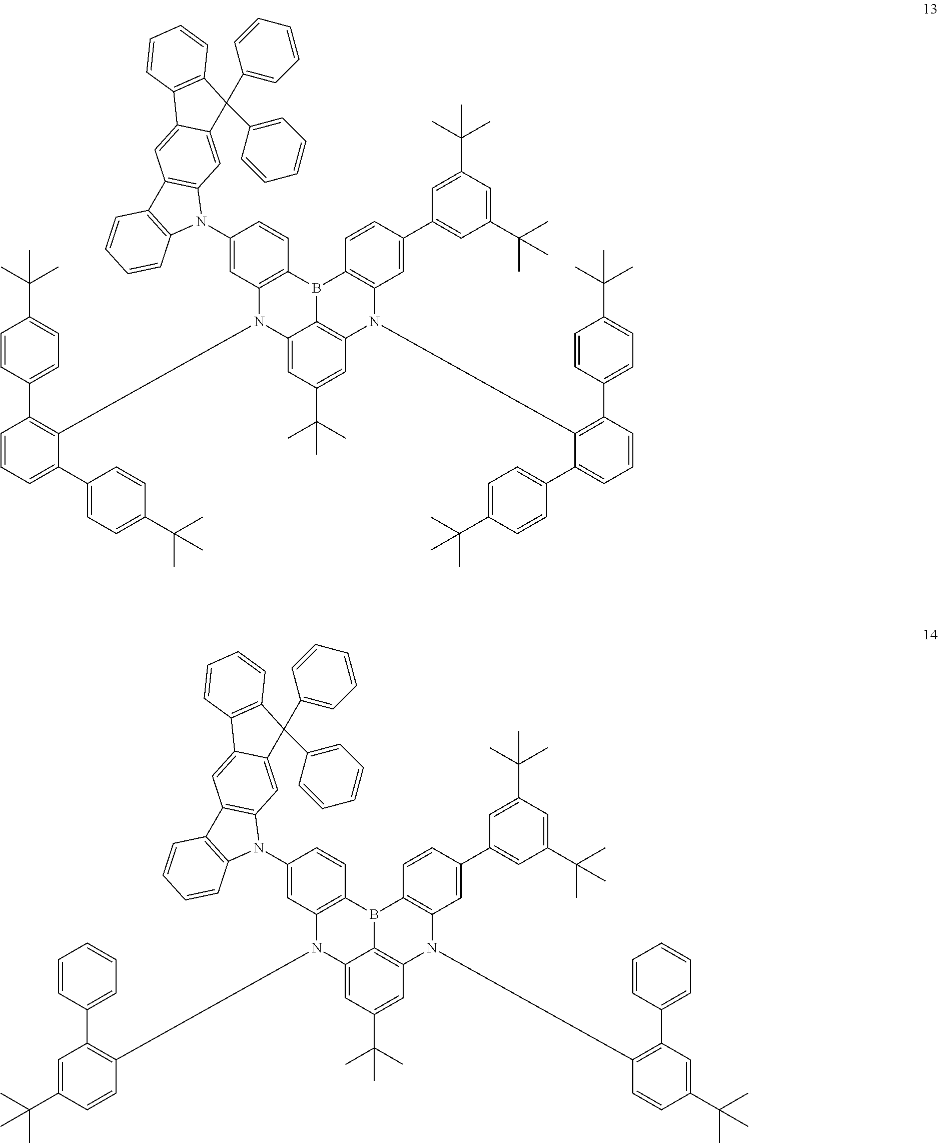 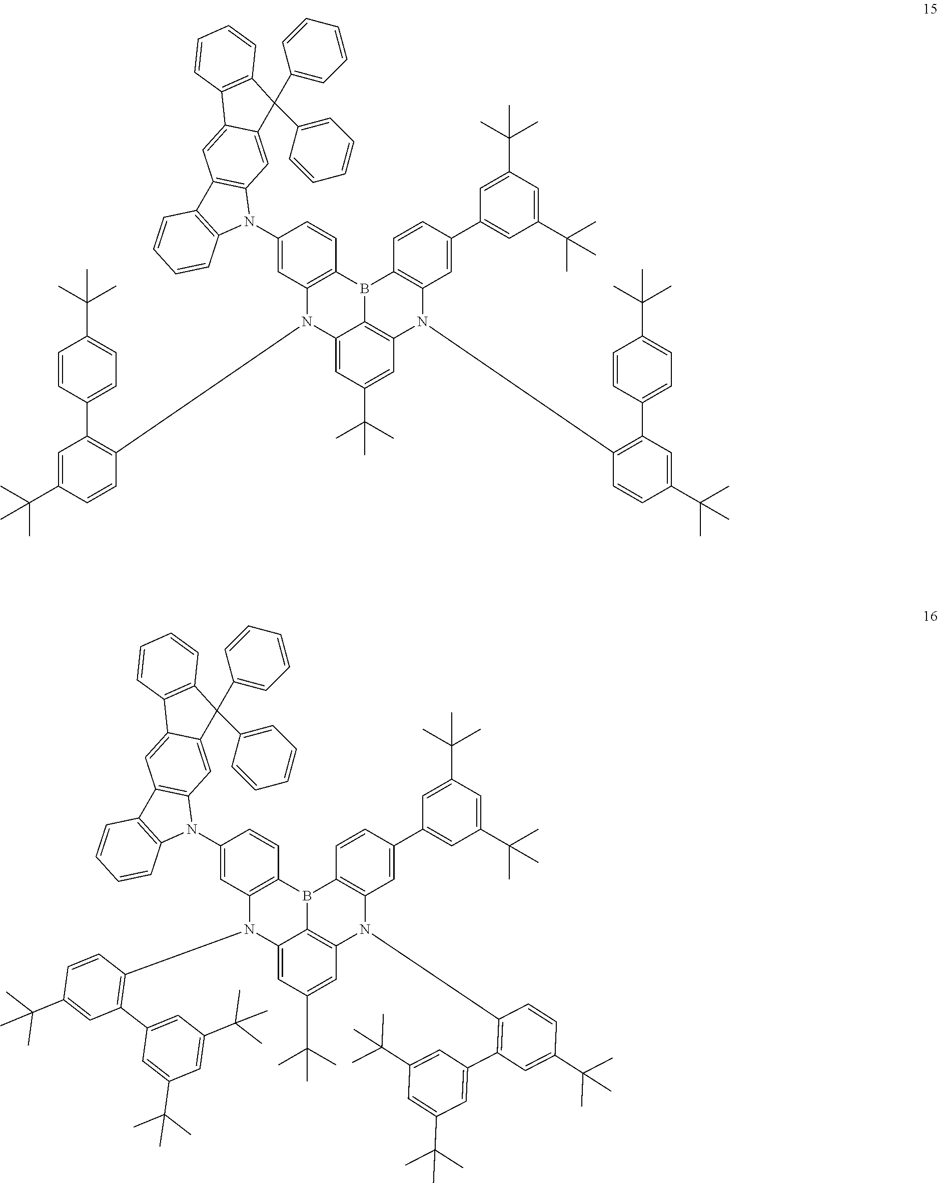 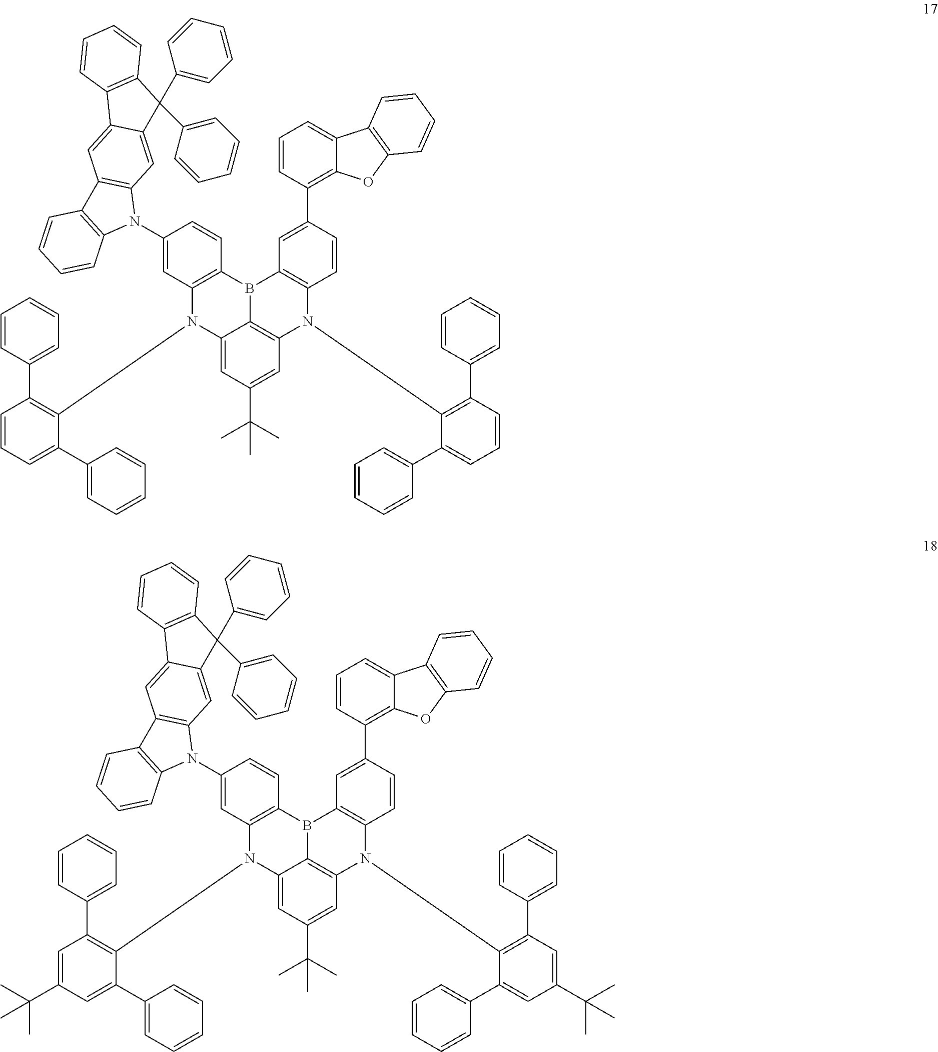 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1cc(-c3cccc4c3oc3ccccc34)ccc1N2c1c(-c2ccccc2)cccc1-c1ccccc1 ; CC(C)(C)c1cc(-c2ccccc2)c(N2c3ccc(-c4cccc5c4oc4ccccc45)cc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1] 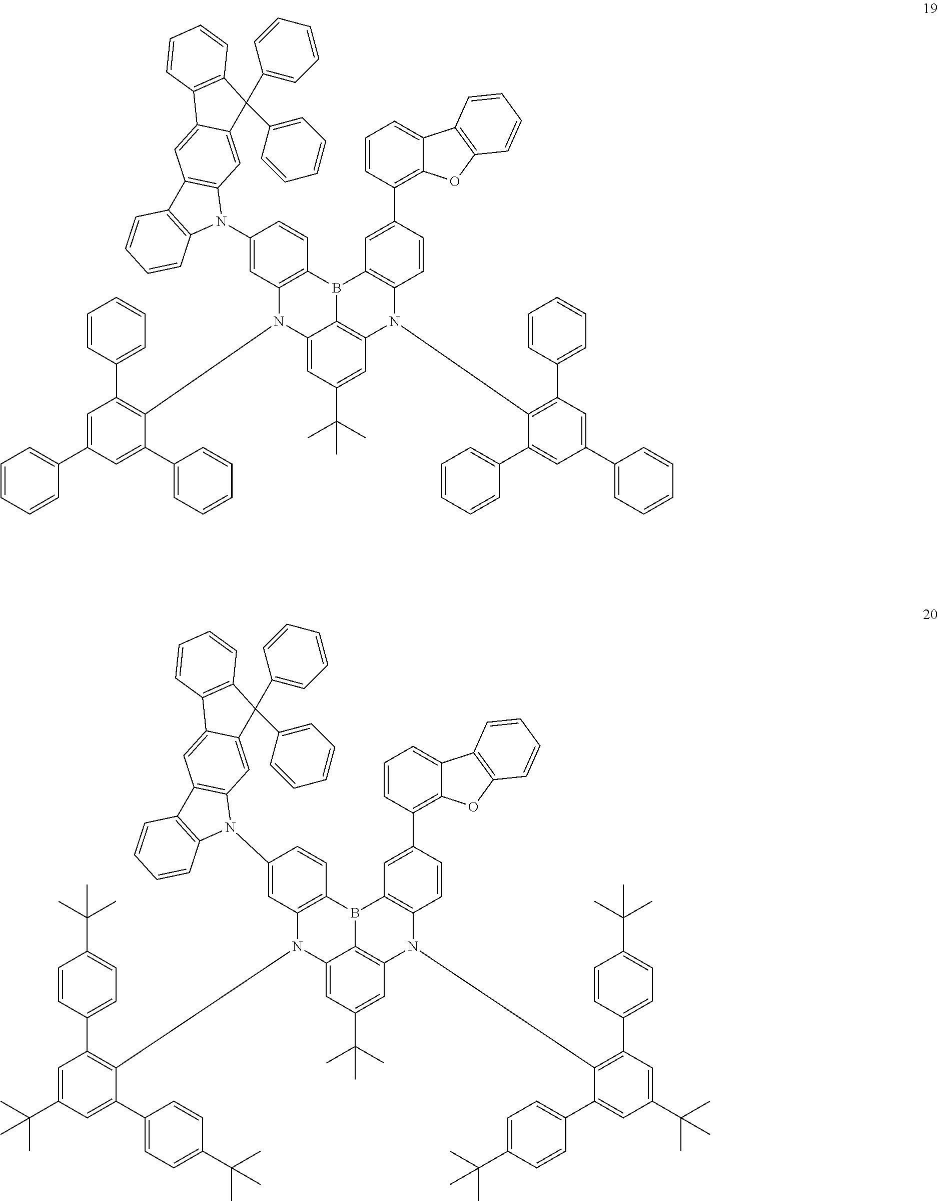 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1cc(-c3cccc4c3oc3ccccc34)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4cccc5c4oc4ccccc45)cc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 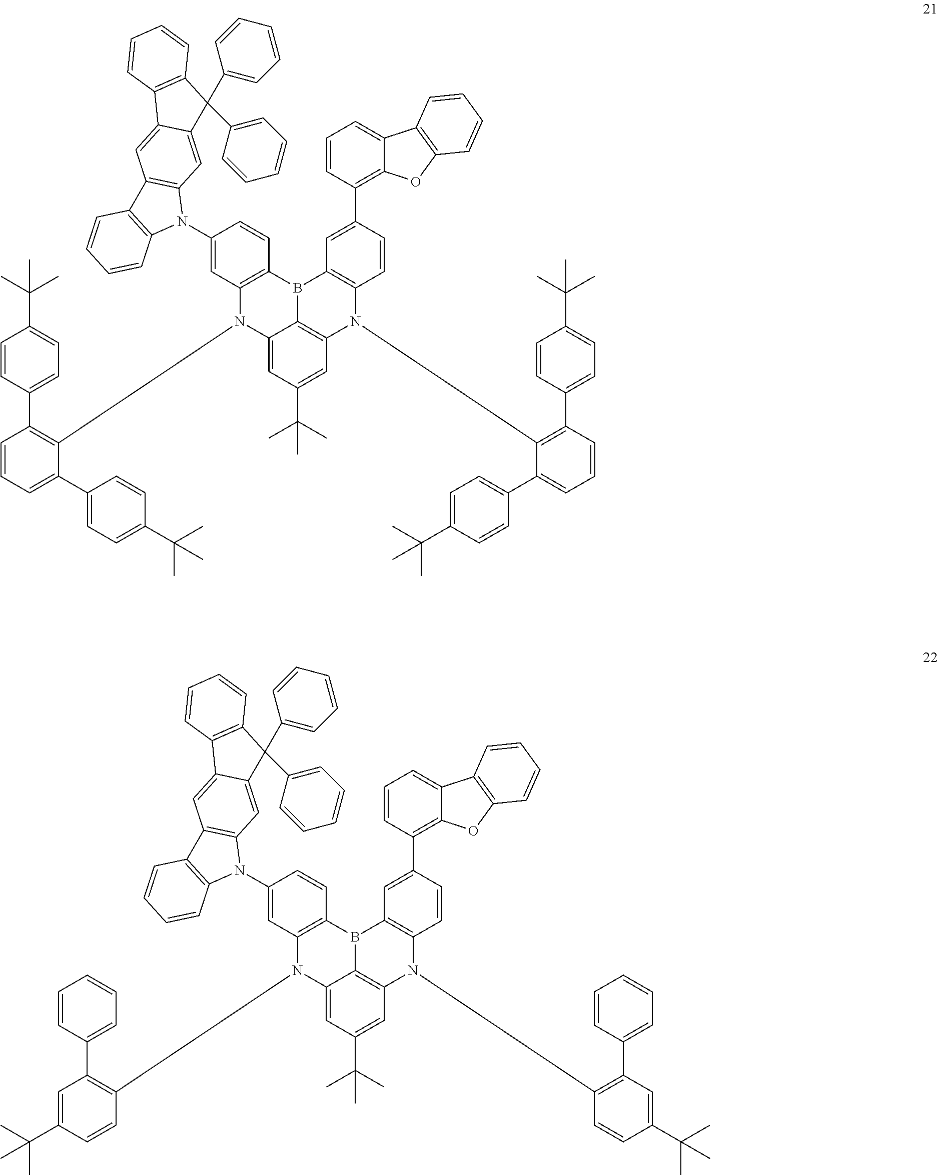 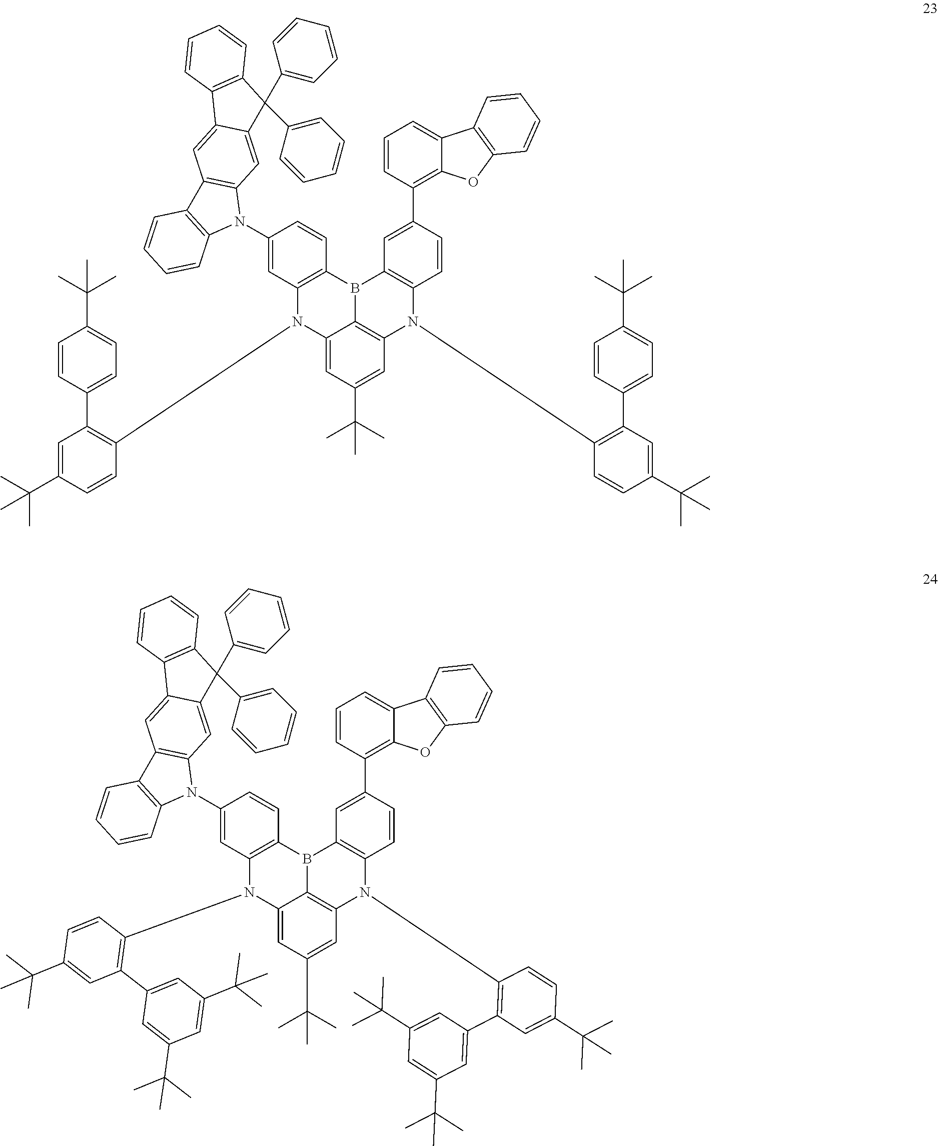 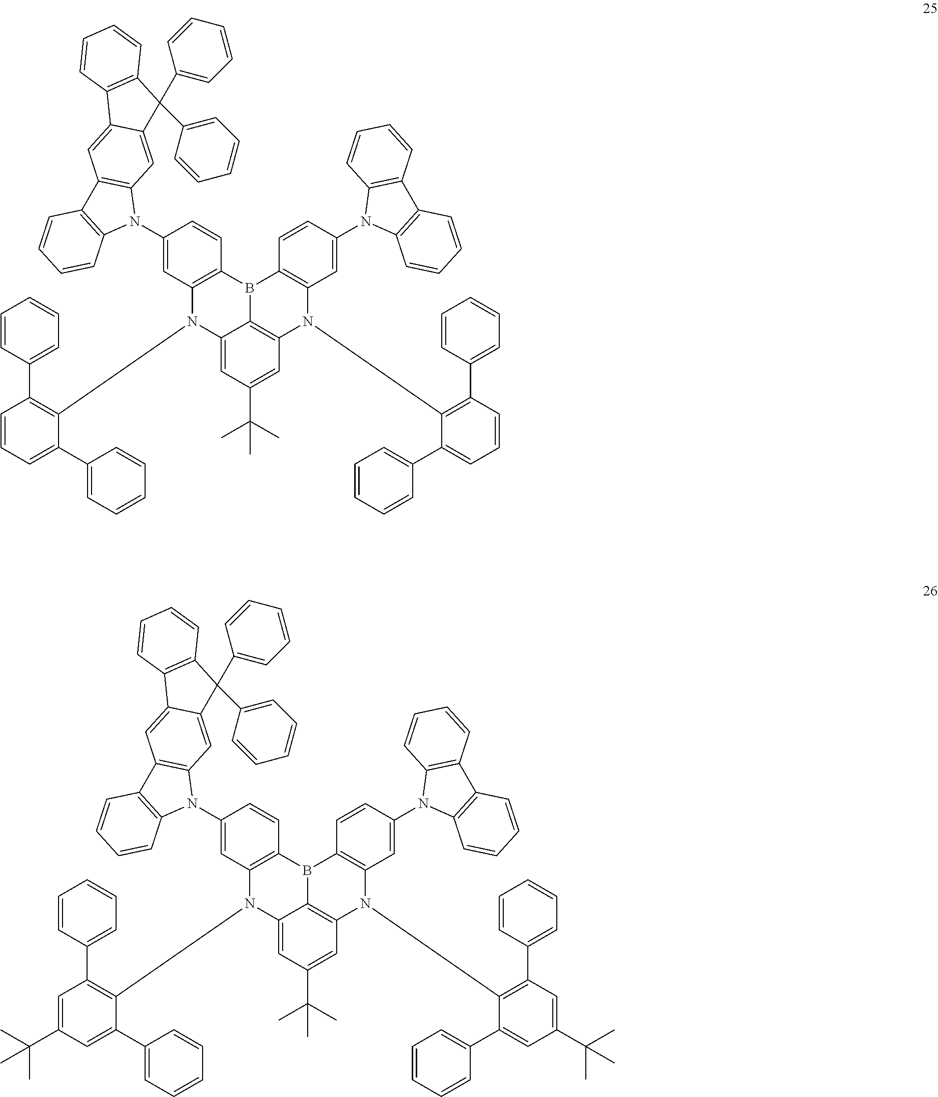 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1ccc(-n3c4ccccc4c4ccccc43)cc1N2c1c(-c2ccccc2)cccc1-c1ccccc1 ; CC(C)(C)c1cc(-c2ccccc2)c(N2c3cc(-n4c5ccccc5c5ccccc54)ccc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1] 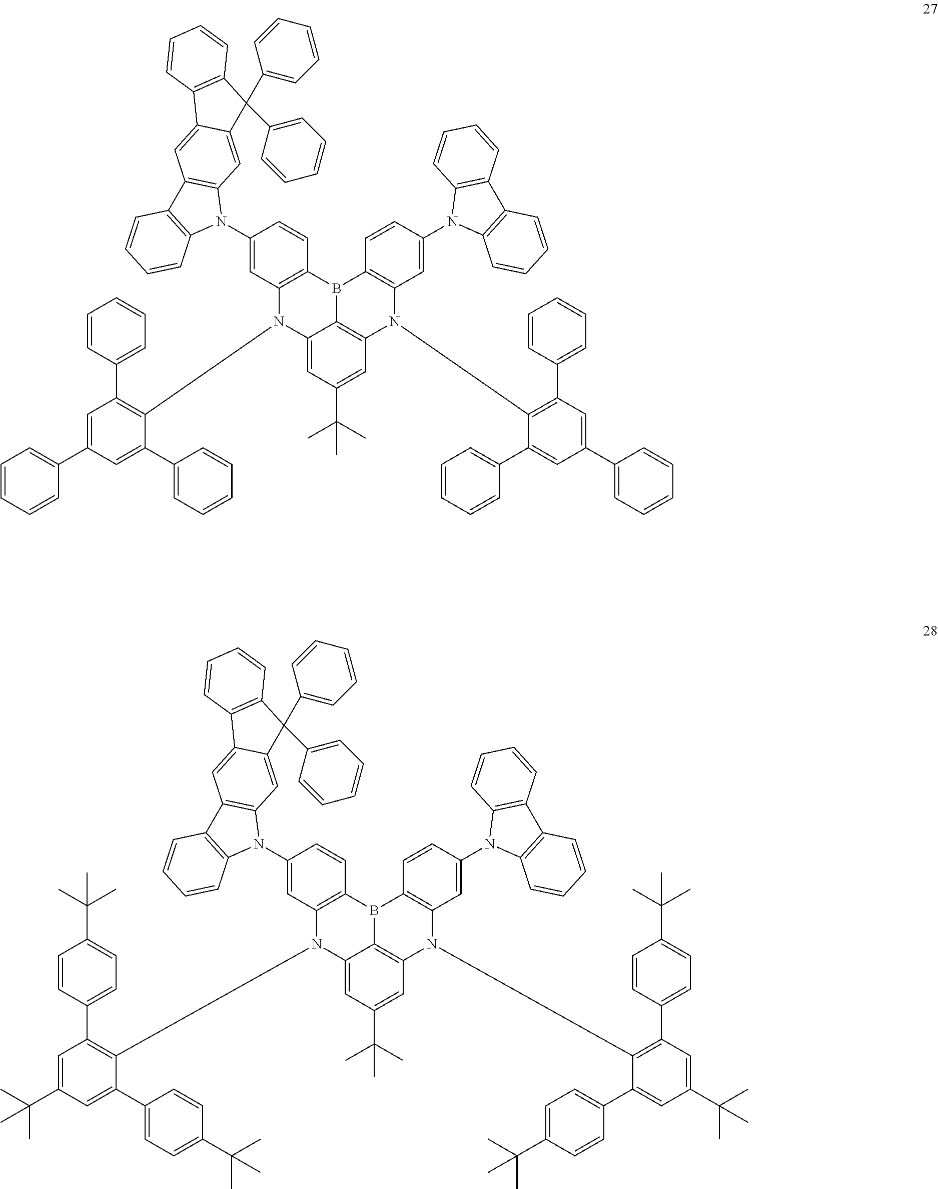 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1ccc(-n3c4ccccc4c4ccccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 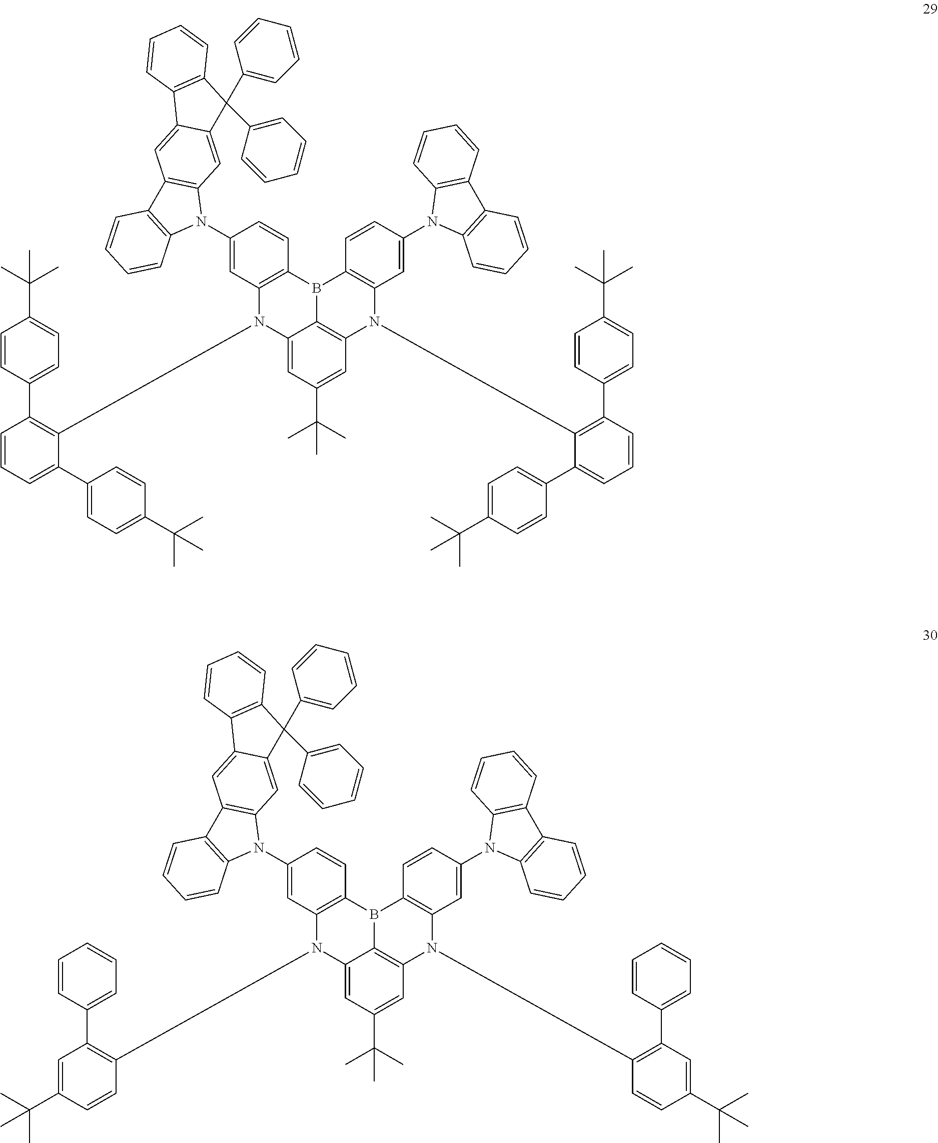 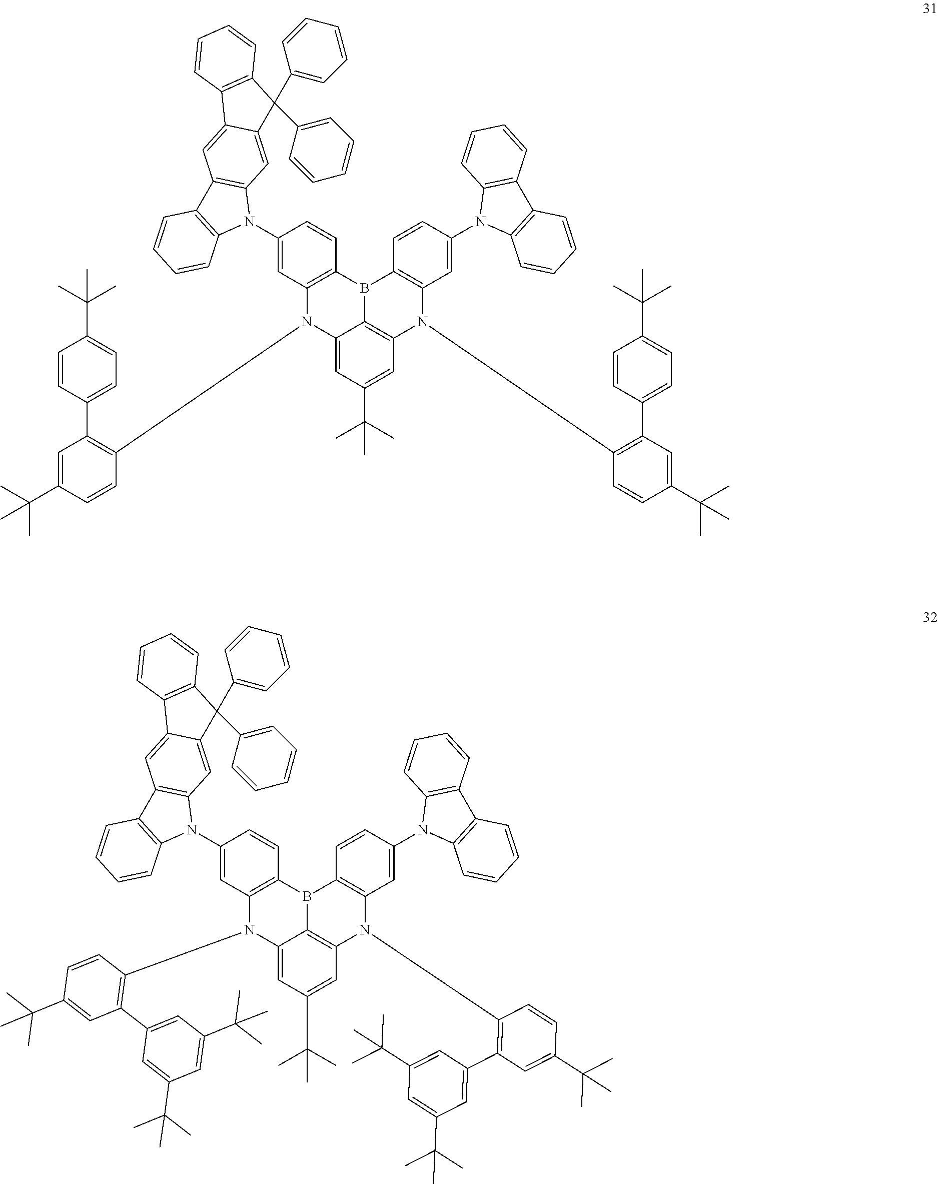 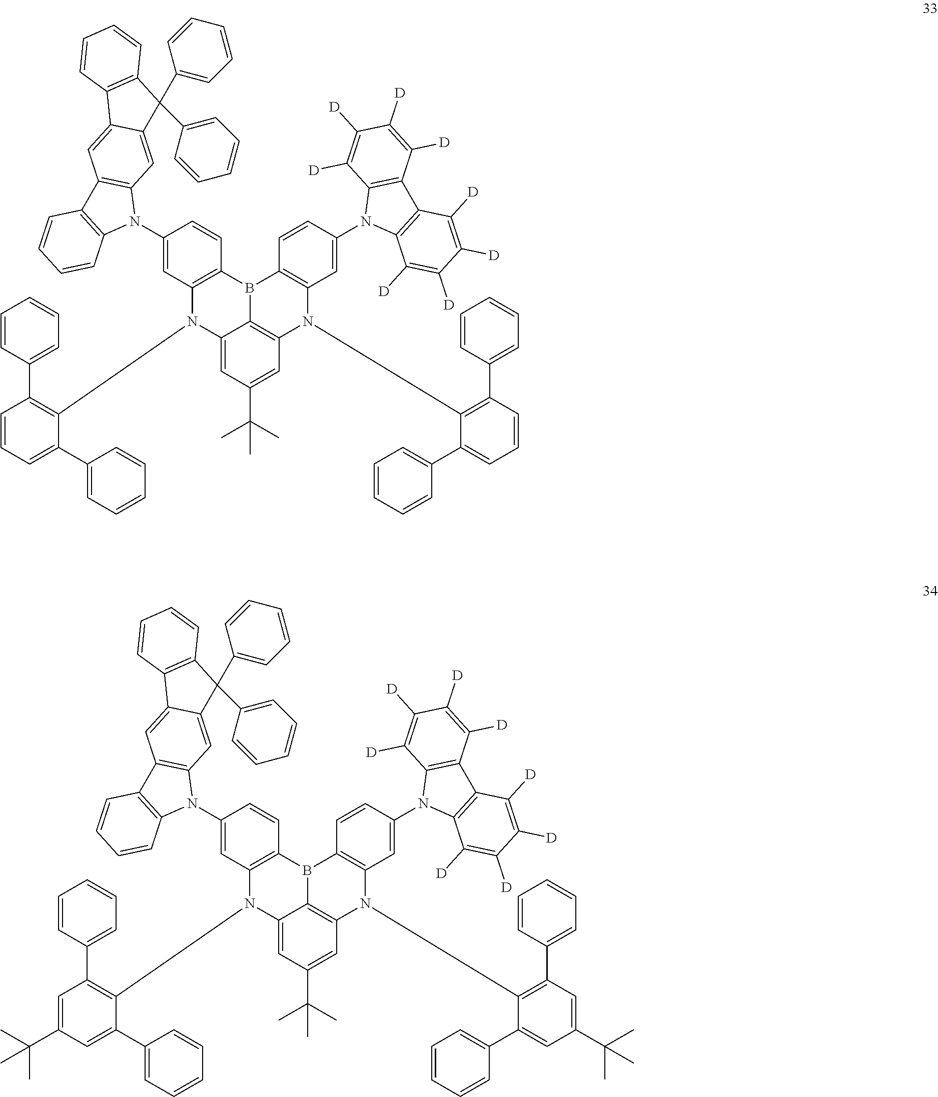 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4cc5c(cc42)C(c2ccccc2)(c2ccccc2)c2ccccc2-5)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4cc5c(cc42)C(c2ccccc2)(c2ccccc2)c2ccccc2-5)cc1N3c1c(-c2ccccc2)cc(C(C)(C)C)cc1-c1ccccc1] 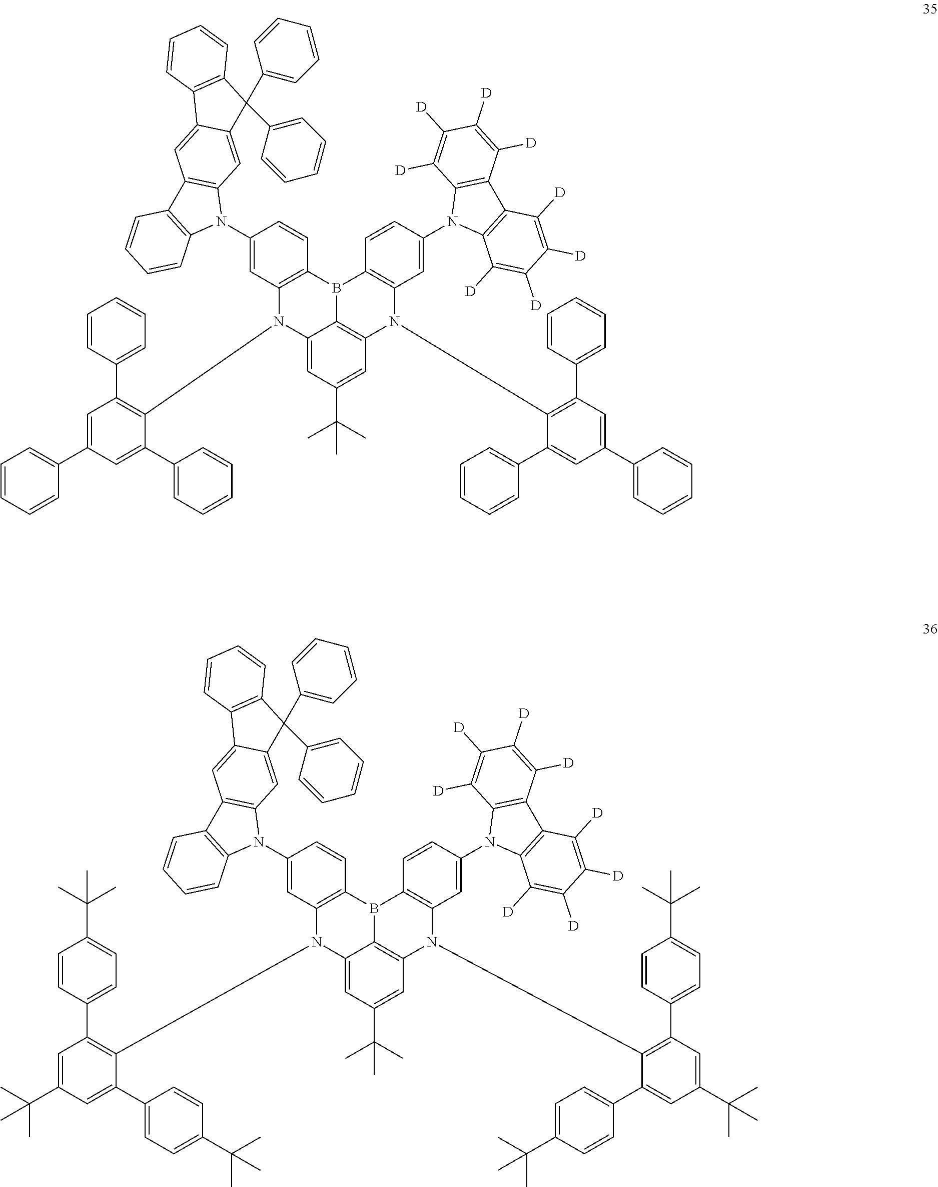 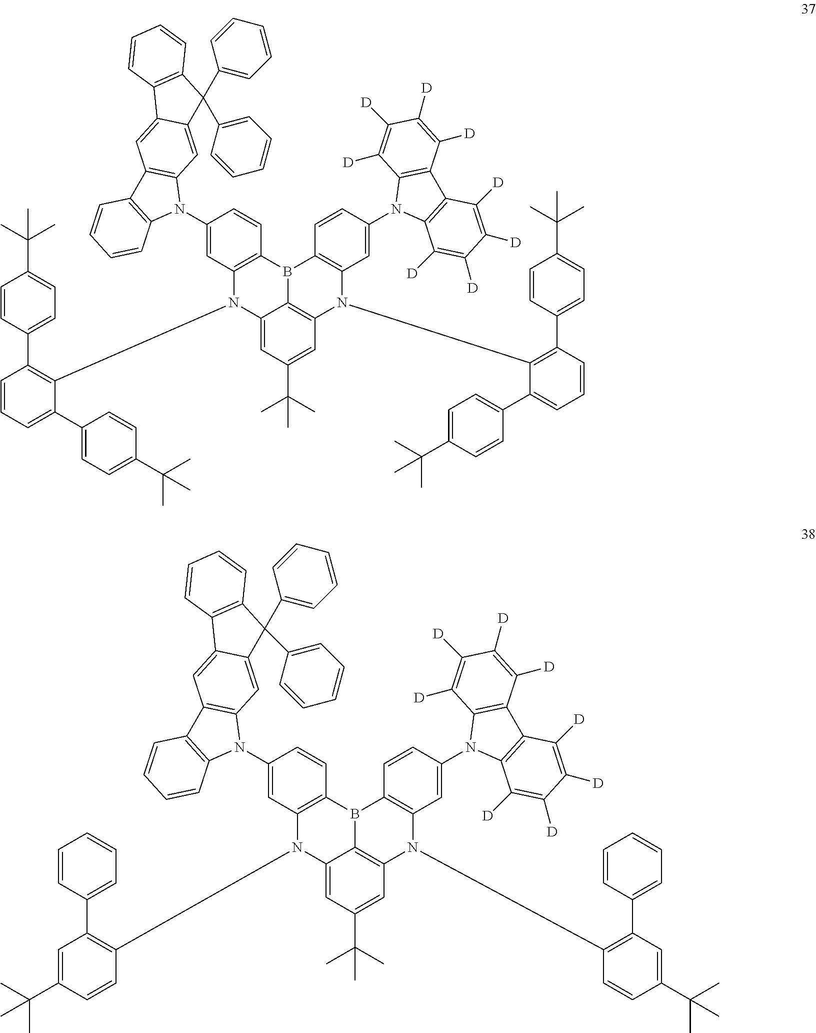 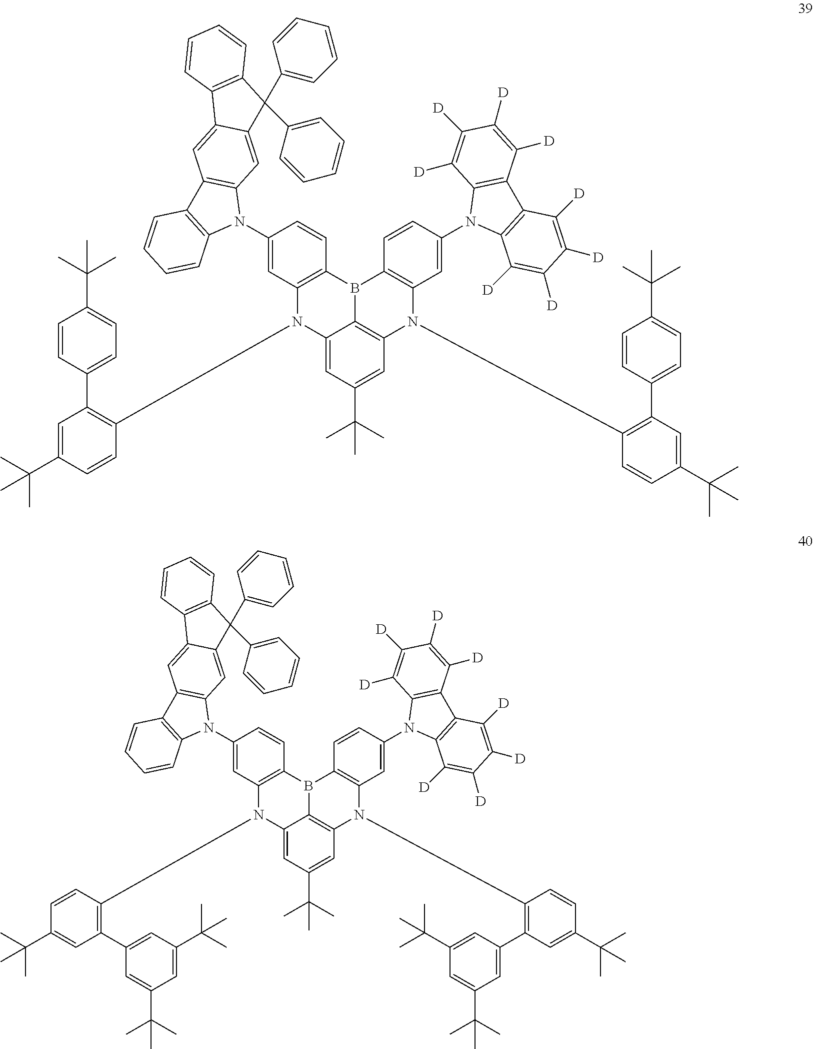 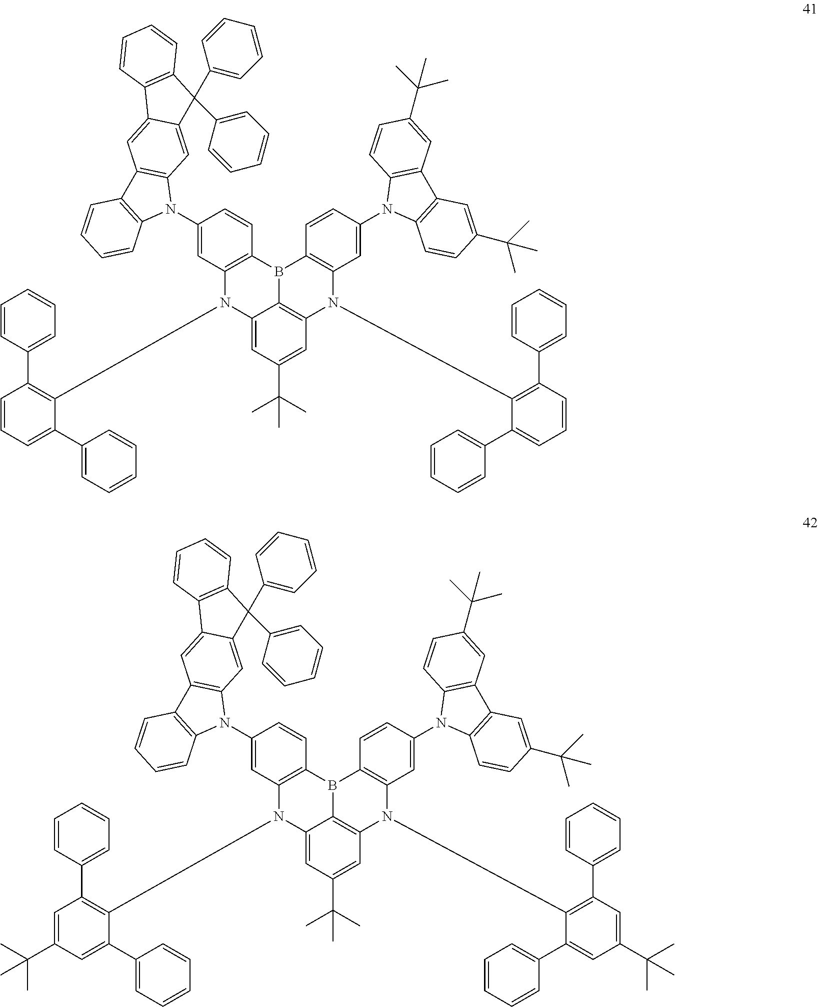 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1ccc(-n3c4ccc(C(C)(C)C)cc4c4cc(C(C)(C)C)ccc43)cc1N2c1c(-c2ccccc2)cccc1-c1ccccc1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccccc6c6cc7c(cc65)C(c5ccccc5)(c5ccccc5)c5ccccc5-7)cc4N(c4c(-c5ccccc5)cc(C(C)(C)C)cc4-c4ccccc4)c4cc(C(C)(C)C)cc2c43)c(-c2ccccc2)c1] 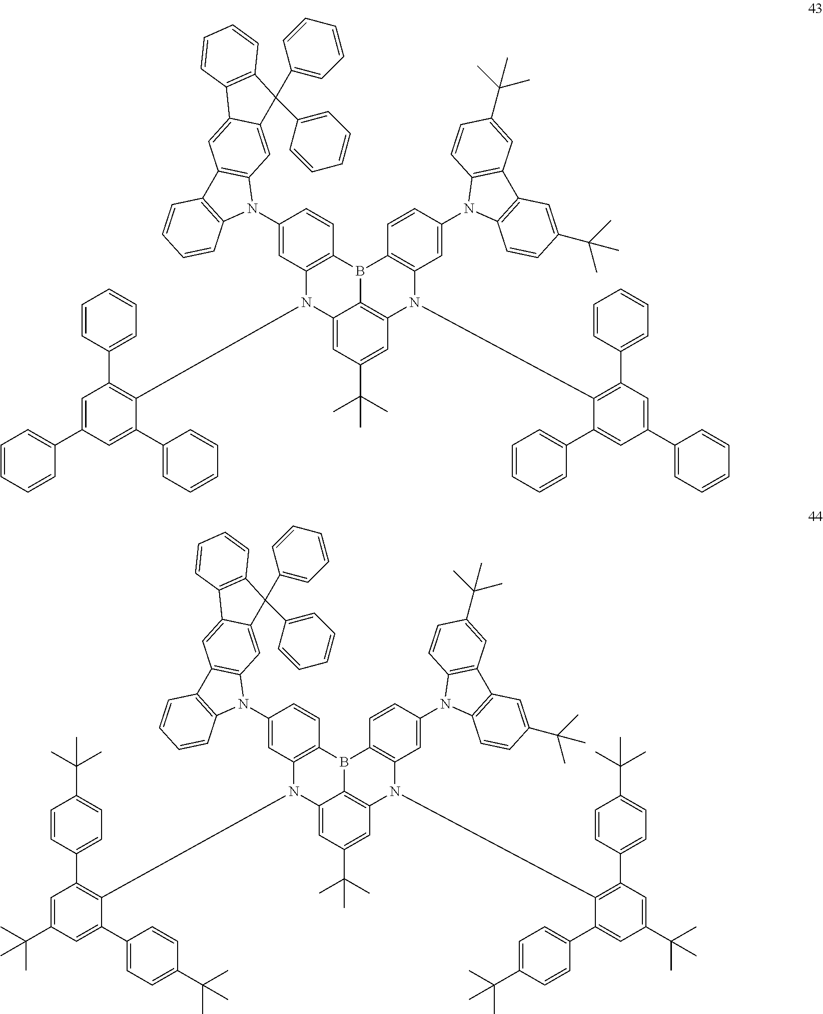 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C(c4ccccc4)(c4ccccc4)c4ccccc4-6)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6cc7c(cc65)C(c5ccccc5)(c5ccccc5)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 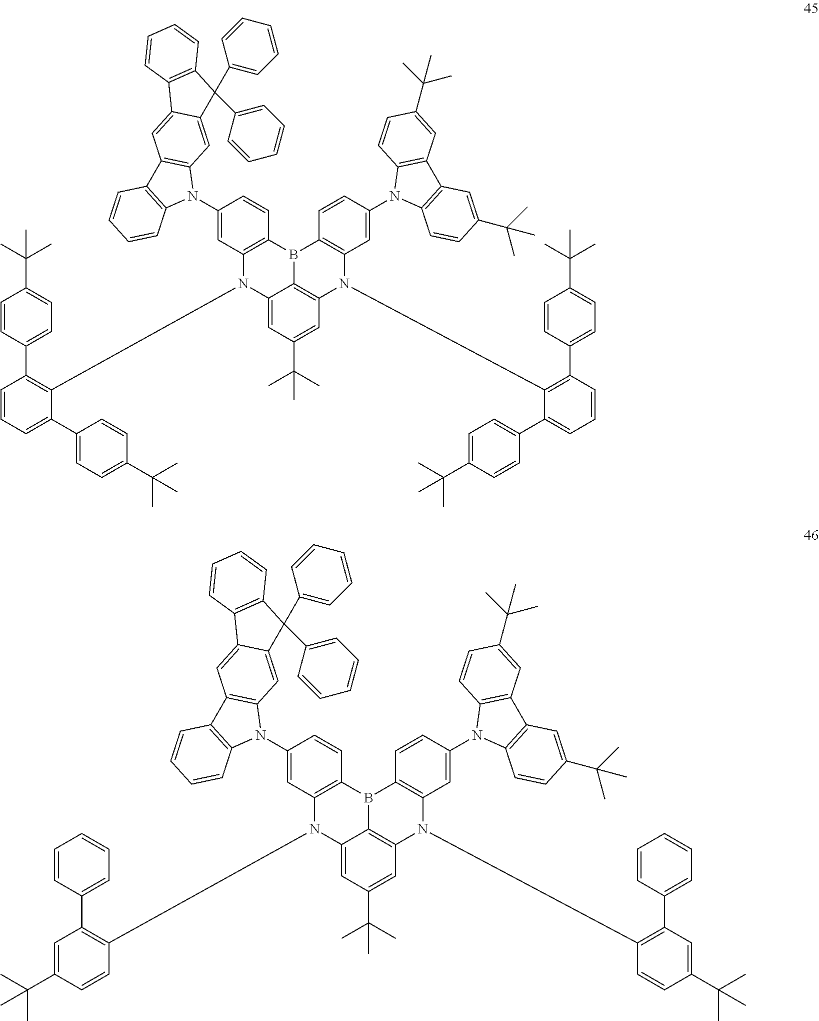 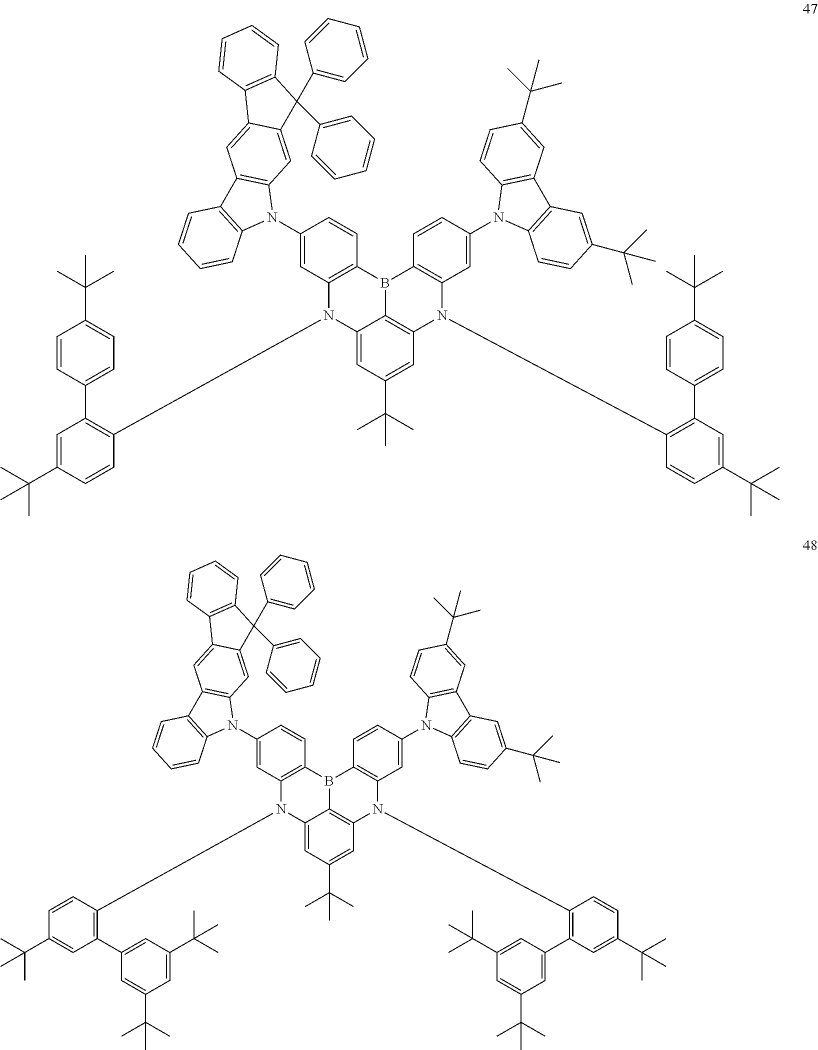 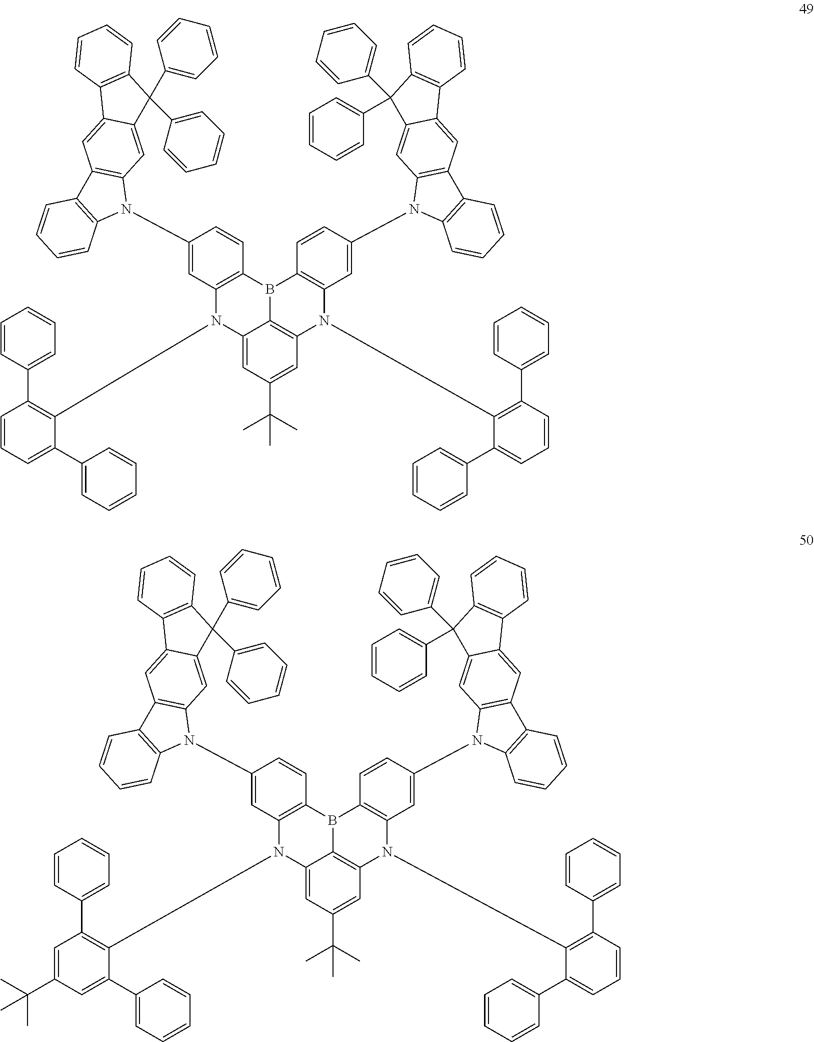 [SMILES: CC(C)(C)c1cc2c3c(c1)N(c1c(-c4ccccc4)cccc1-c1ccccc1)c1cc(-n4c5ccccc5c5cc6c(cc54)C(c4ccccc4)(c4ccccc4)c4ccccc4-6)ccc1B3c1ccc(-n3c4ccccc4c4cc5c(cc43)C(c3ccccc3)(c3ccccc3)c3ccccc3-5)cc1N2c1c(-c2ccccc2)cccc1-c1ccccc1 ; CC(C)(C)c1cc(-c2ccccc2)c(N2c3cc(-n4c5ccccc5c5cc6c(cc54)C(c4ccccc4)(c4ccccc4)c4ccccc4-6)ccc3B3c4ccc(-n5c6ccccc6c6cc7c(cc65)C(c5ccccc5)(c5ccccc5)c5ccccc5-7)cc4N(c4c(-c5ccccc5)cccc4-c4ccccc4)c4cc(C(C)(C)C)cc2c43)c(-c2ccccc2)c1] 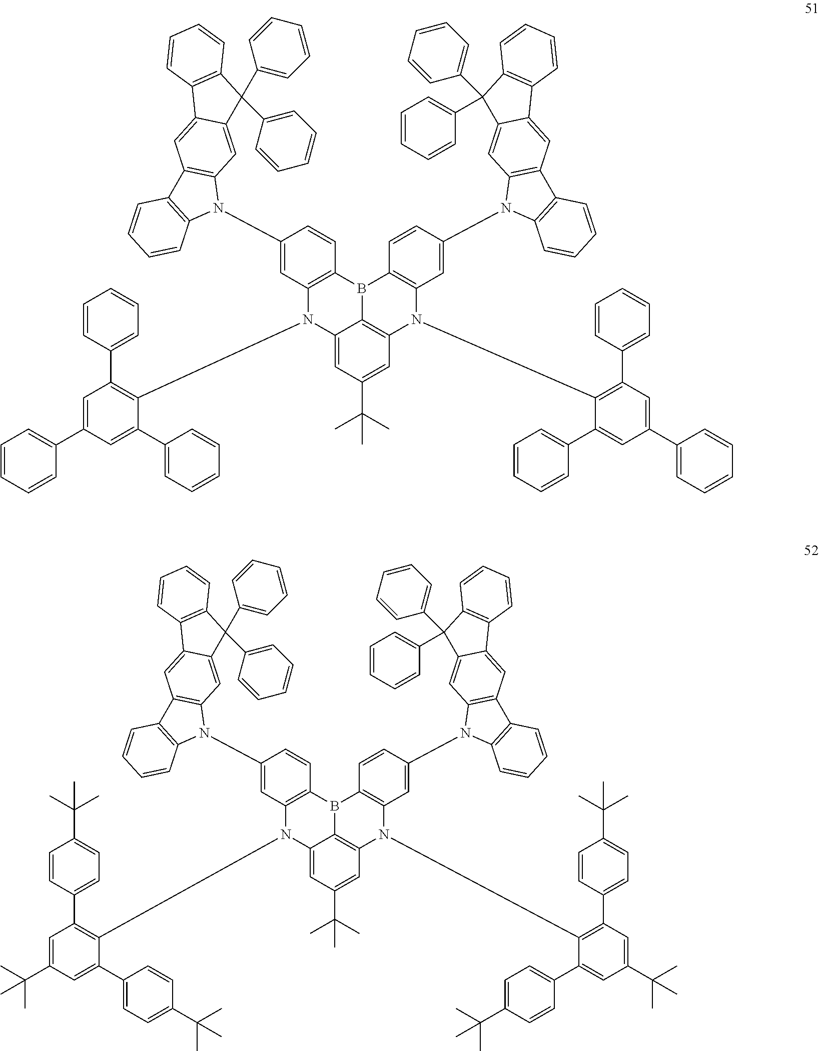 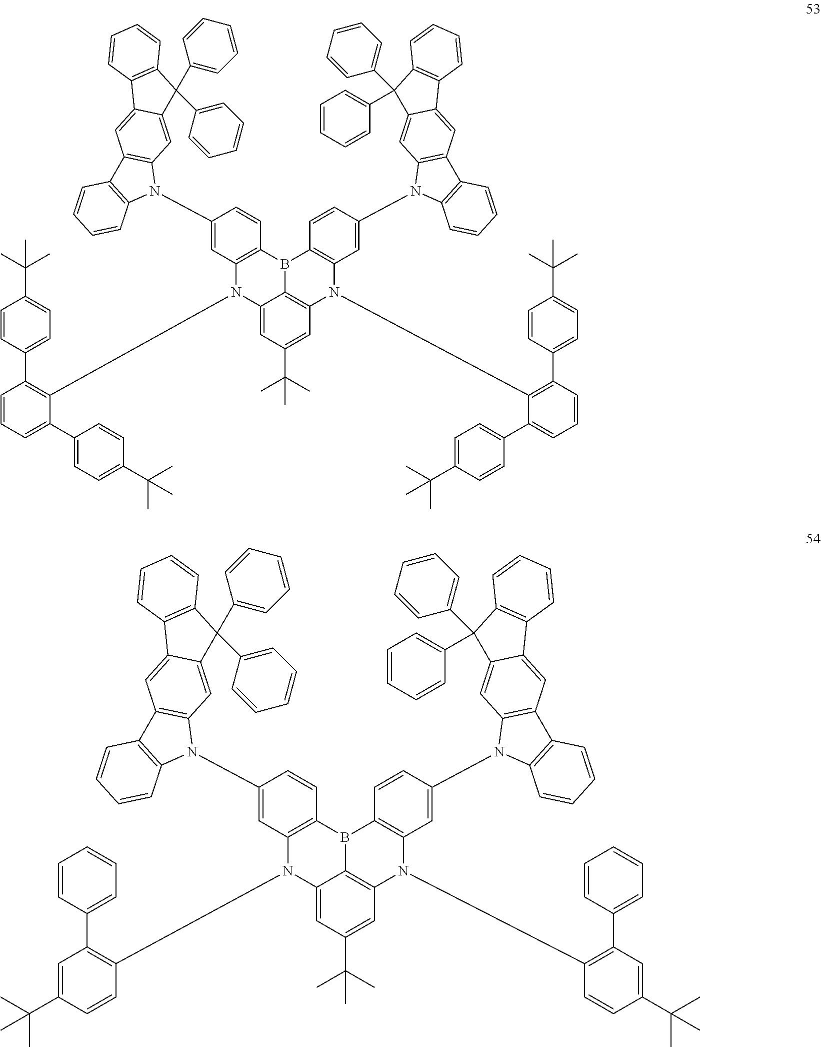 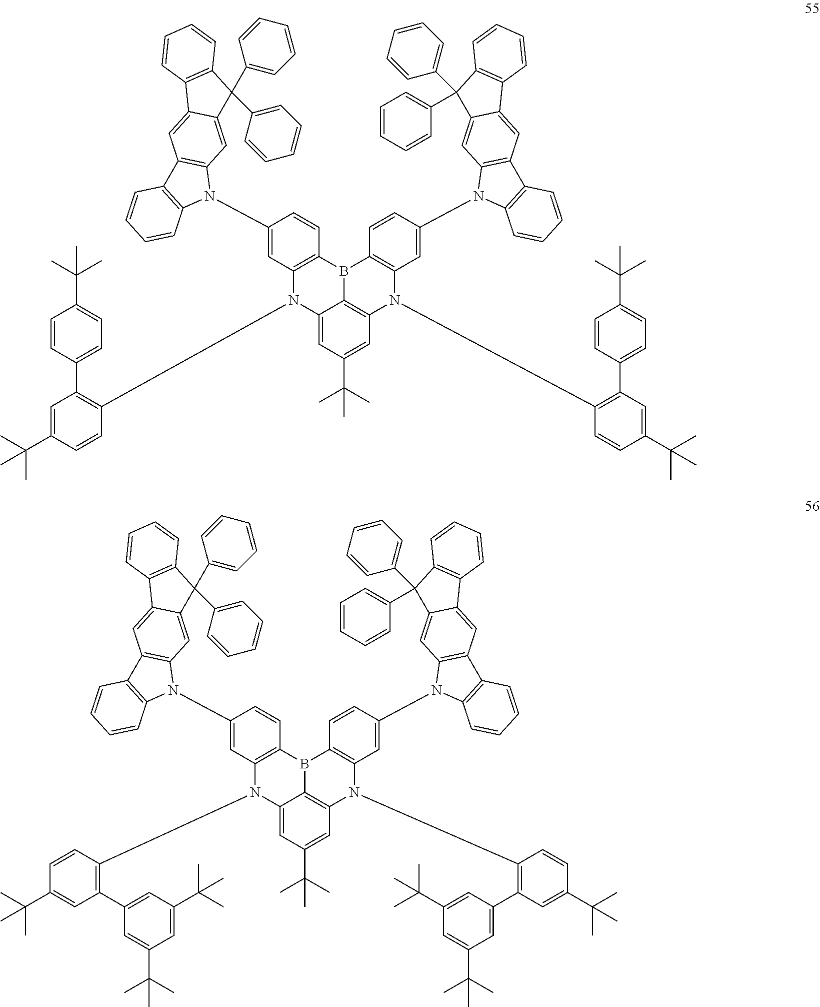 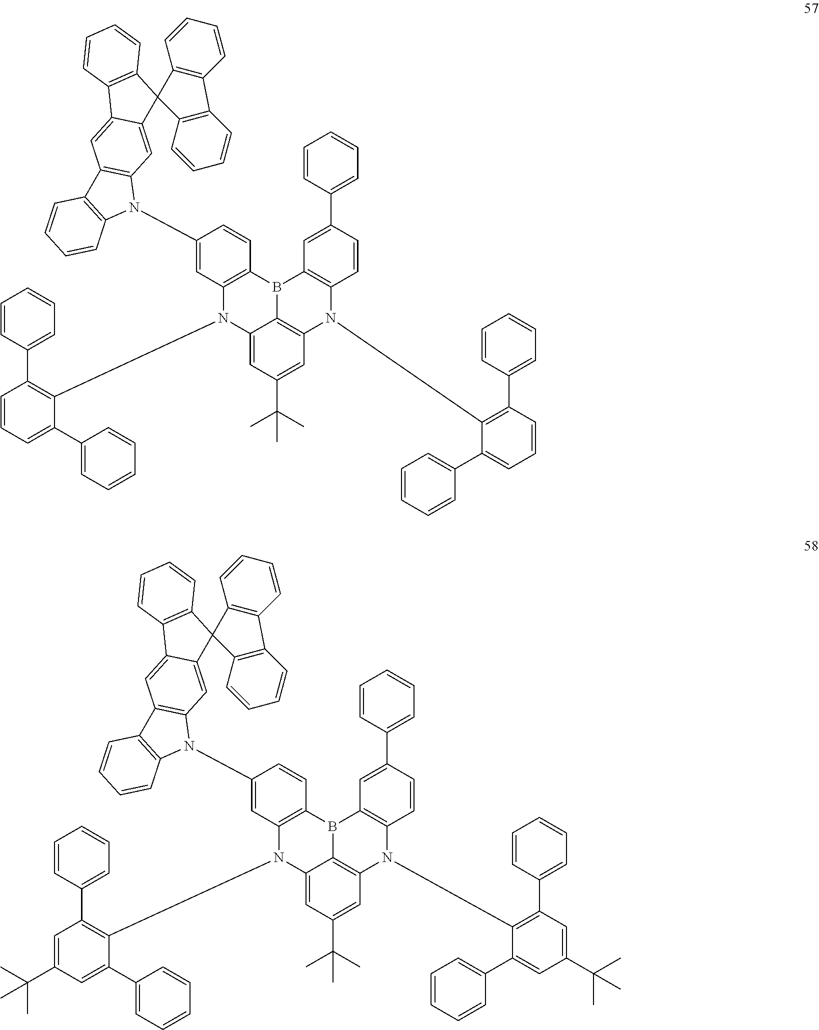 [SMILES: CC(C)(C)c1cc2c3c(c1)N(c1c(-c4ccccc4)cccc1-c1ccccc1)c1cc(-n4c5ccccc5c5cc6c(cc54)C4(c5ccccc5-c5ccccc54)c4ccccc4-6)ccc1B3c1cc(-c3ccccc3)ccc1N2c1c(-c2ccccc2)cccc1-c1ccccc1 ; CC(C)(C)c1cc(-c2ccccc2)c(N2c3ccc(-c4ccccc4)cc3B3c4ccc(-n5c6ccccc6c6cc7c(cc65)C5(c6ccccc6-c6ccccc65)c5ccccc5-7)cc4N(c4c(-c5ccccc5)cc(C(C)(C)C)cc4-c4ccccc4)c4cc(C(C)(C)C)cc2c43)c(-c2ccccc2)c1] 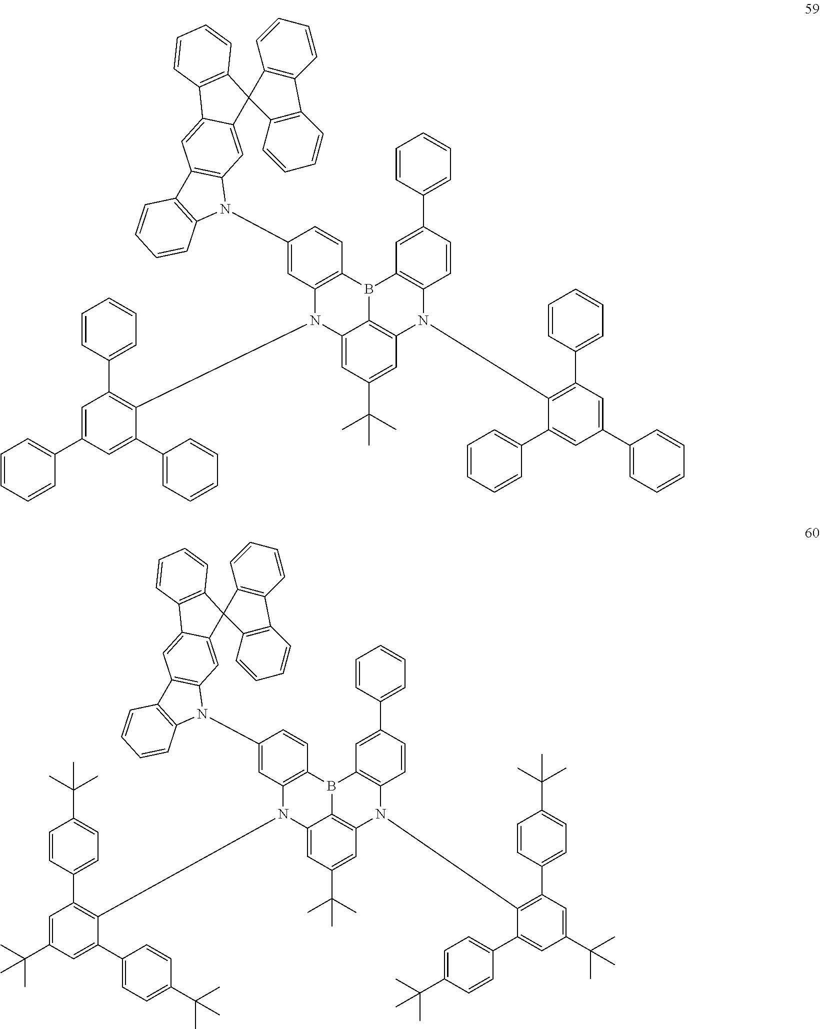 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1cc(-c3ccccc3)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4ccccc4)cc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 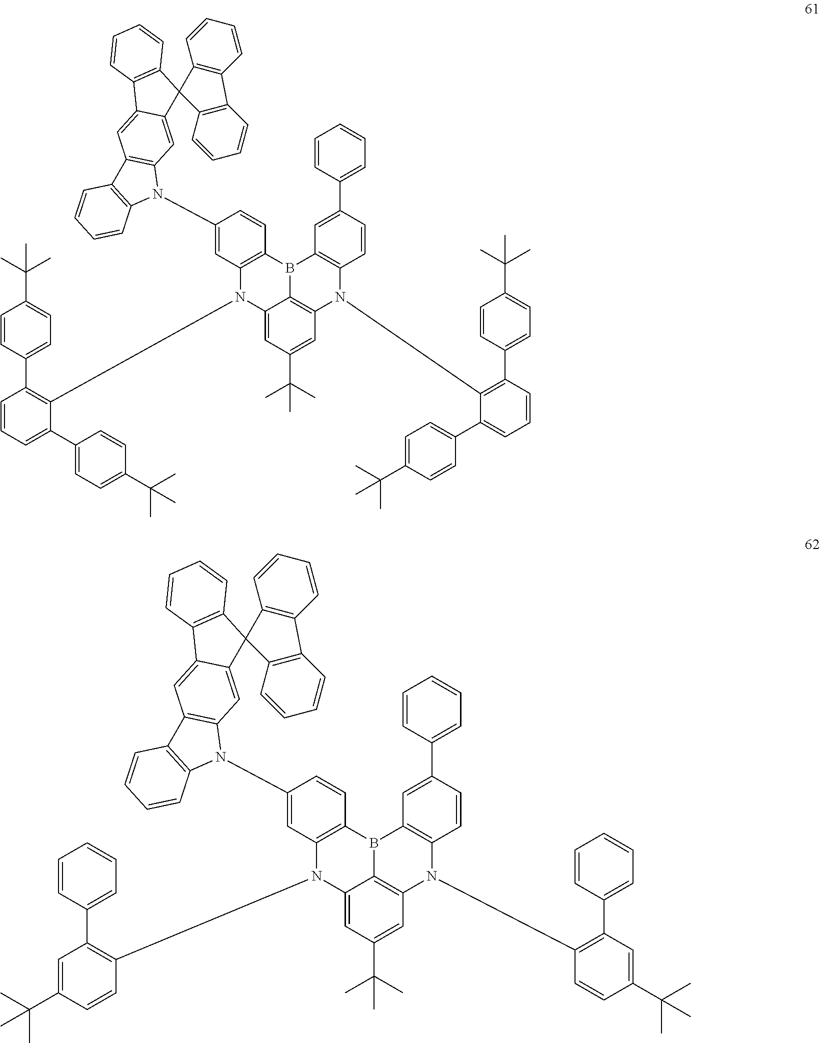 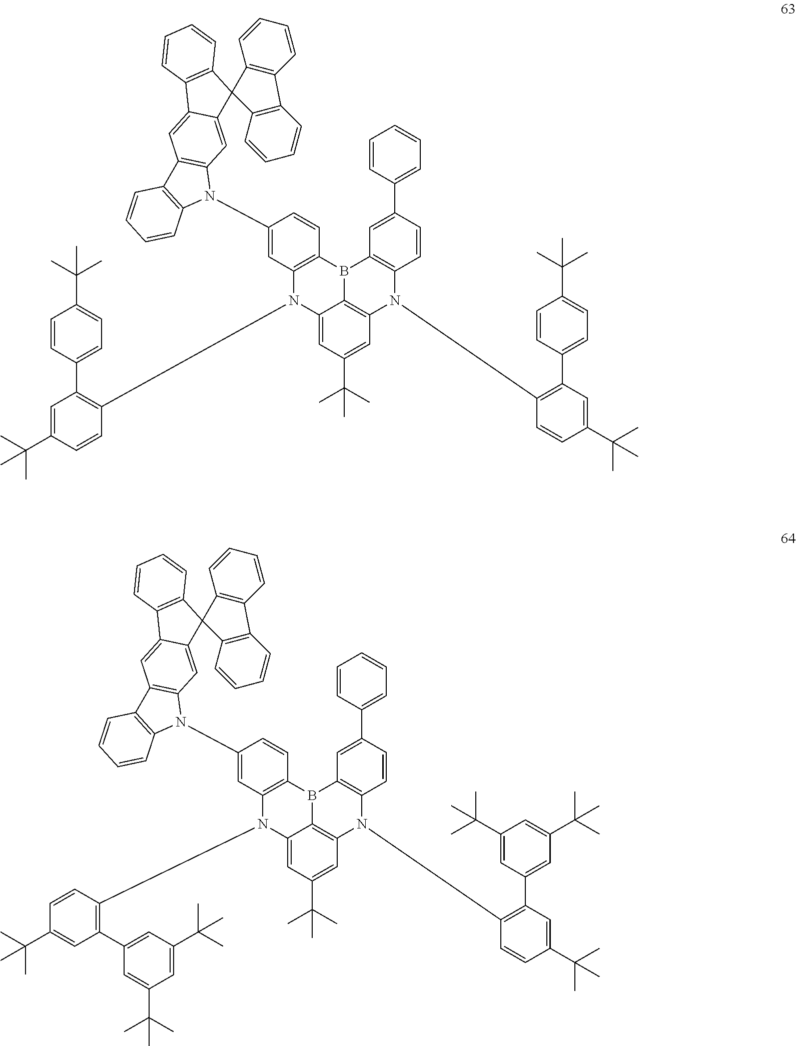 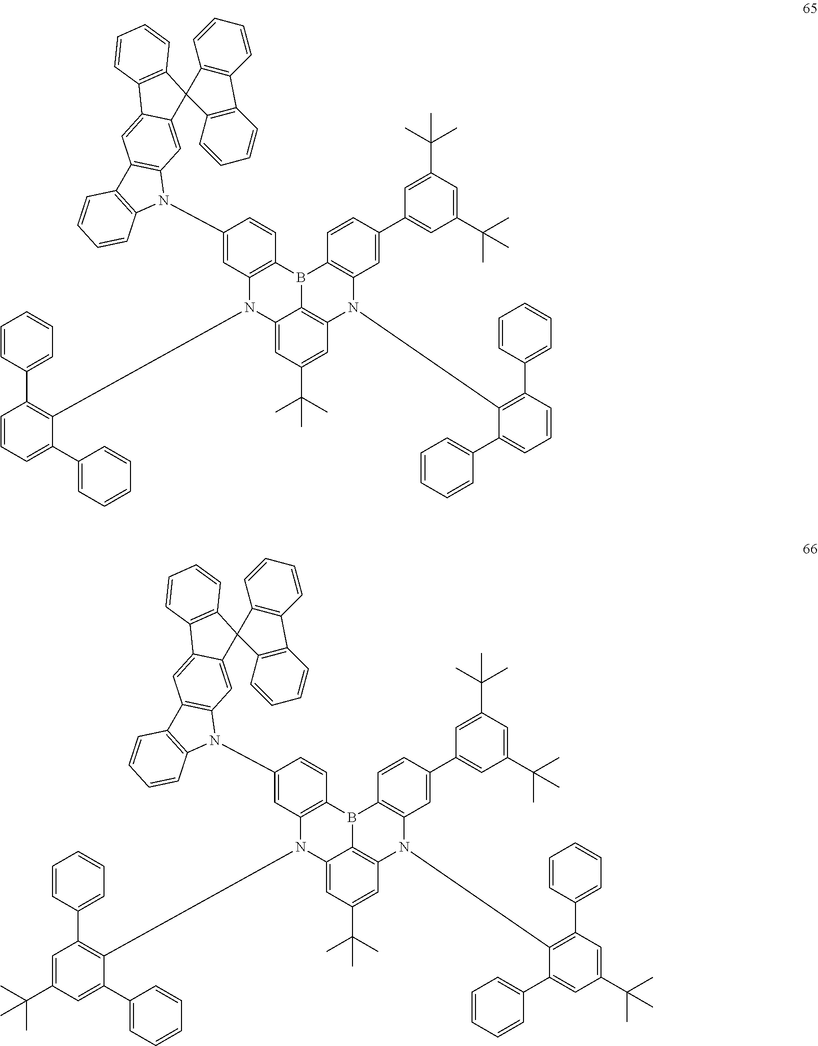 [SMILES: CC(C)(C)c1cc(-c2ccc3c(c2)N(c2c(-c4ccccc4)cccc2-c2ccccc2)c2cc(C(C)(C)C)cc4c2B3c2ccc(-n3c5ccccc5c5cc6c(cc53)C3(c5ccccc5-c5ccccc53)c3ccccc3-6)cc2N4c2c(-c3ccccc3)cccc2-c2ccccc2)cc(C(C)(C)C)c1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccccc5c5cc6c(cc53)C3(c5ccccc5-c5ccccc53)c3ccccc3-6)cc2N4c2c(-c3ccccc3)cc(C(C)(C)C)cc2-c2ccccc2)cc(C(C)(C)C)c1] 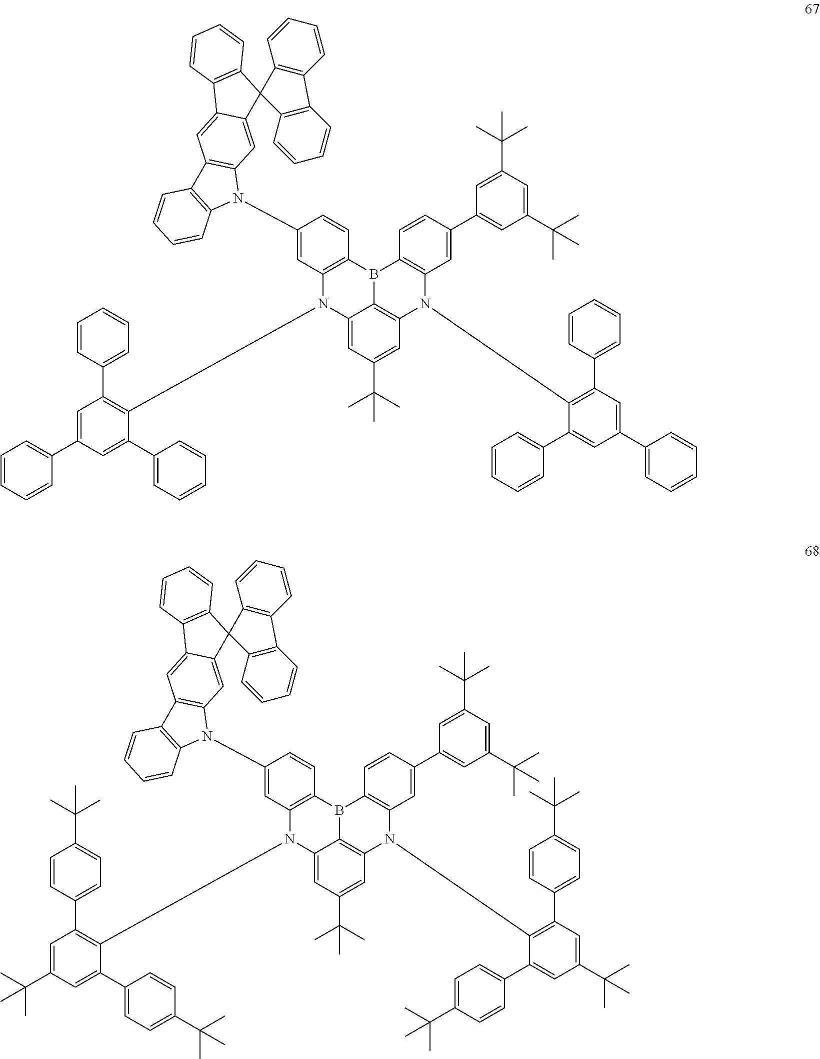 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5cc6c(cc53)C3(c5ccccc5-c5ccccc53)c3ccccc3-6)cc2N4c2c(-c3ccccc3)cc(-c3ccccc3)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 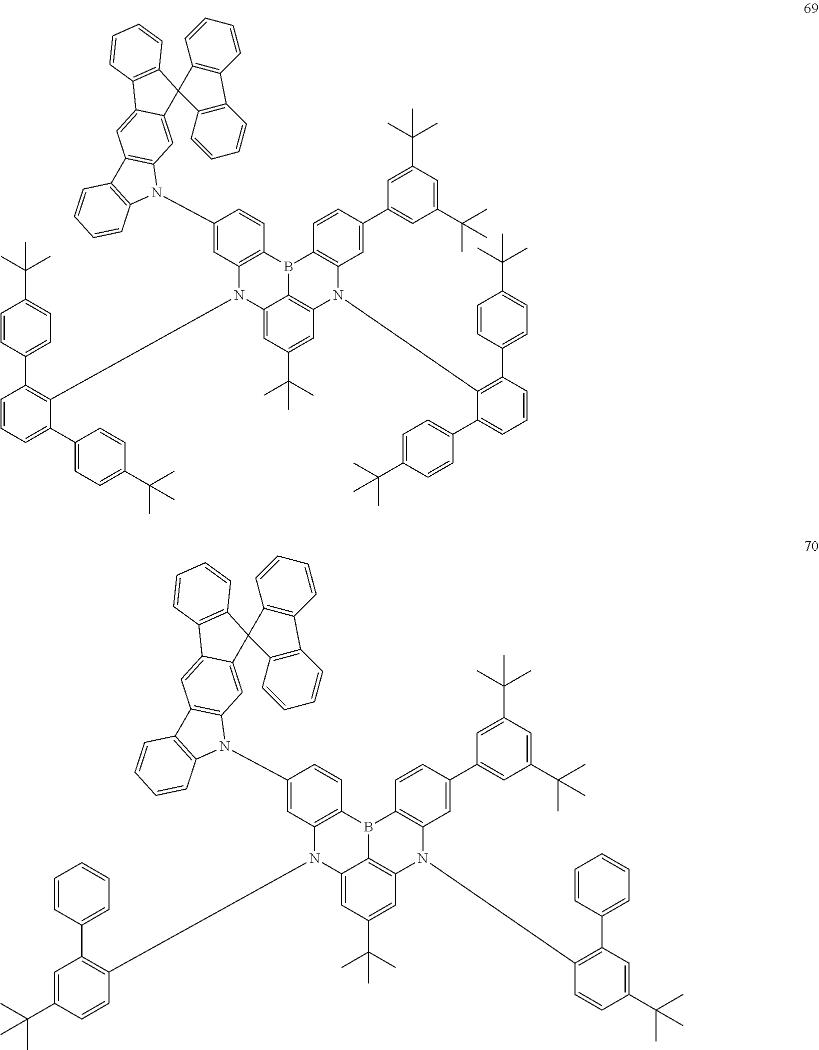 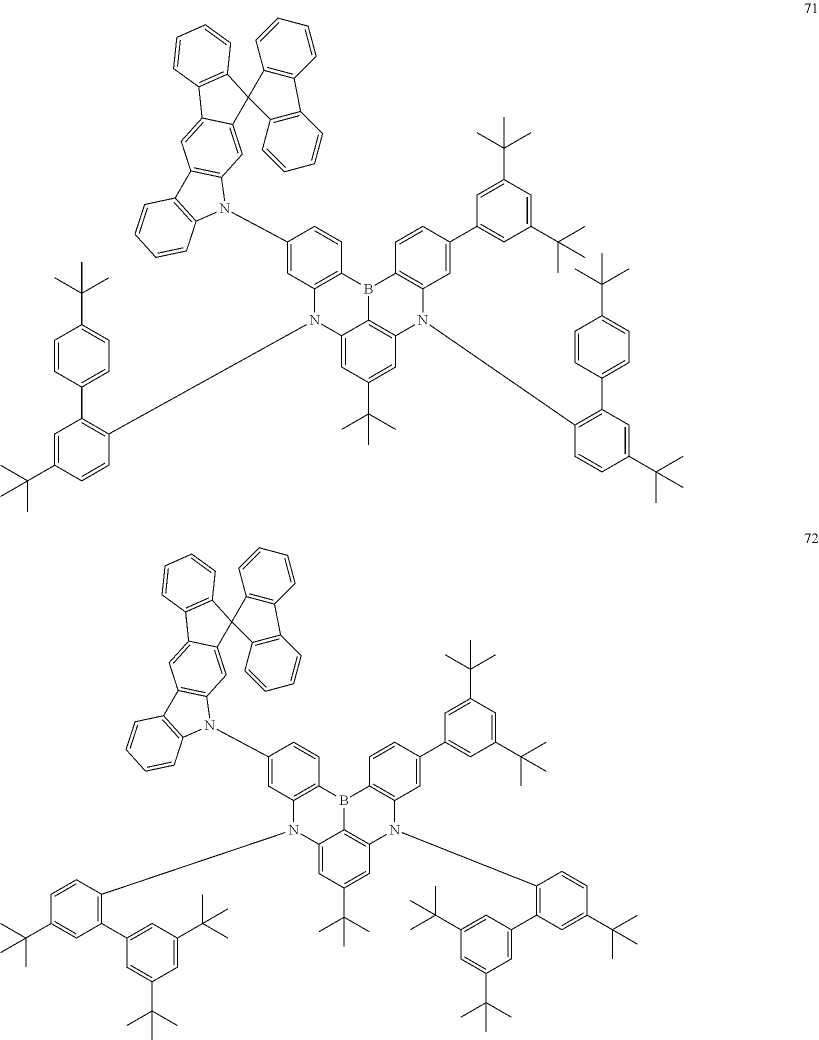 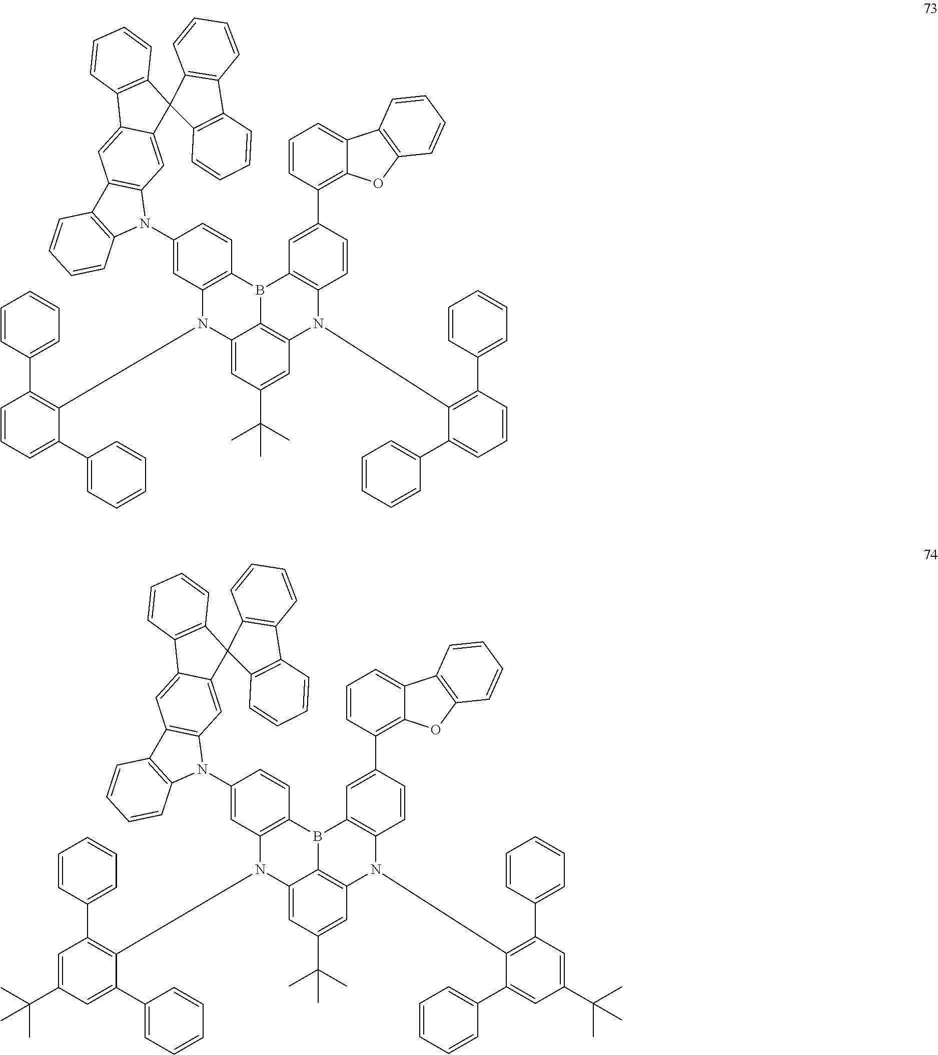 [SMILES: CC(C)(C)c1cc2c3c(c1)N(c1c(-c4ccccc4)cccc1-c1ccccc1)c1cc(-n4c5ccccc5c5cc6c(cc54)C4(c5ccccc5-c5ccccc54)c4ccccc4-6)ccc1B3c1cc(-c3cccc4c3oc3ccccc34)ccc1N2c1c(-c2ccccc2)cccc1-c1ccccc1 ; CC(C)(C)c1cc(-c2ccccc2)c(N2c3ccc(-c4cccc5c4oc4ccccc45)cc3B3c4ccc(-n5c6ccccc6c6cc7c(cc65)C5(c6ccccc6-c6ccccc65)c5ccccc5-7)cc4N(c4c(-c5ccccc5)cc(C(C)(C)C)cc4-c4ccccc4)c4cc(C(C)(C)C)cc2c43)c(-c2ccccc2)c1] 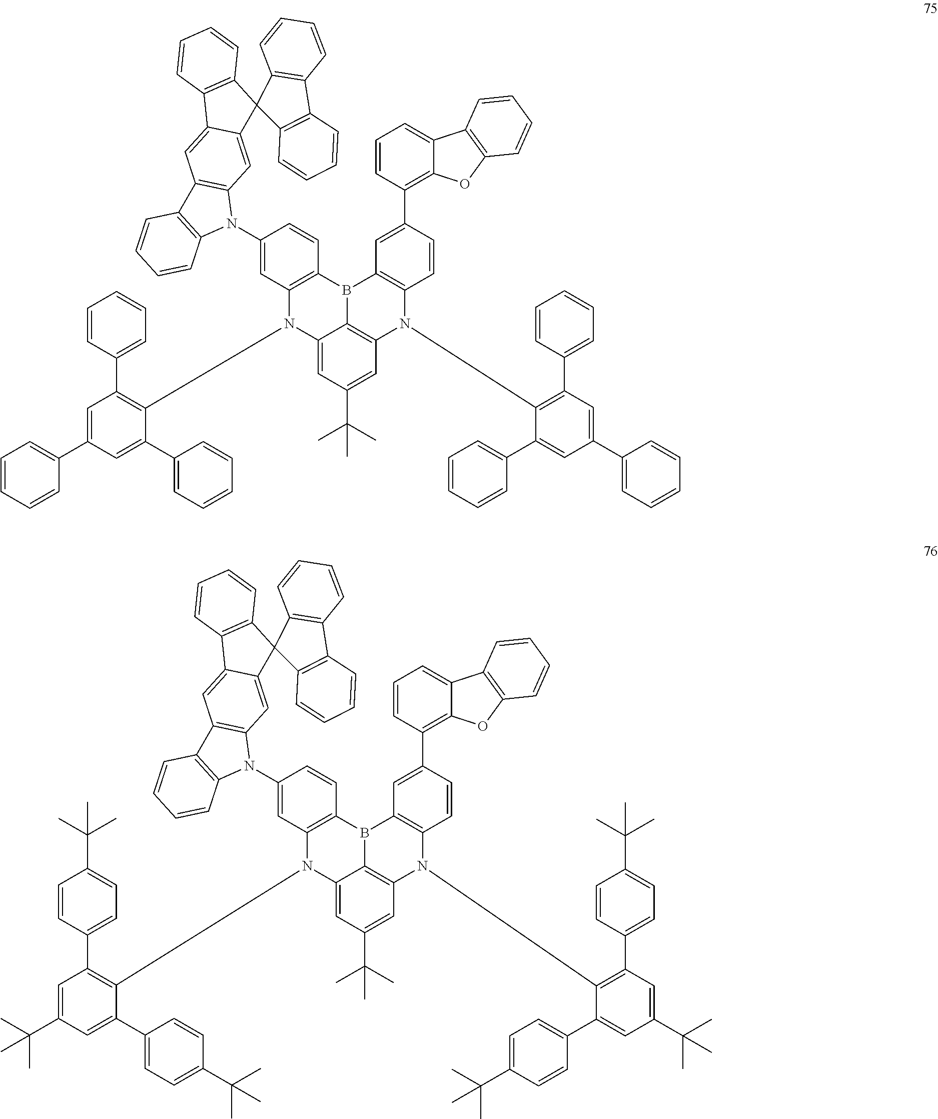 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1cc(-c3cccc4c3oc3ccccc34)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4cccc5c4oc4ccccc45)cc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 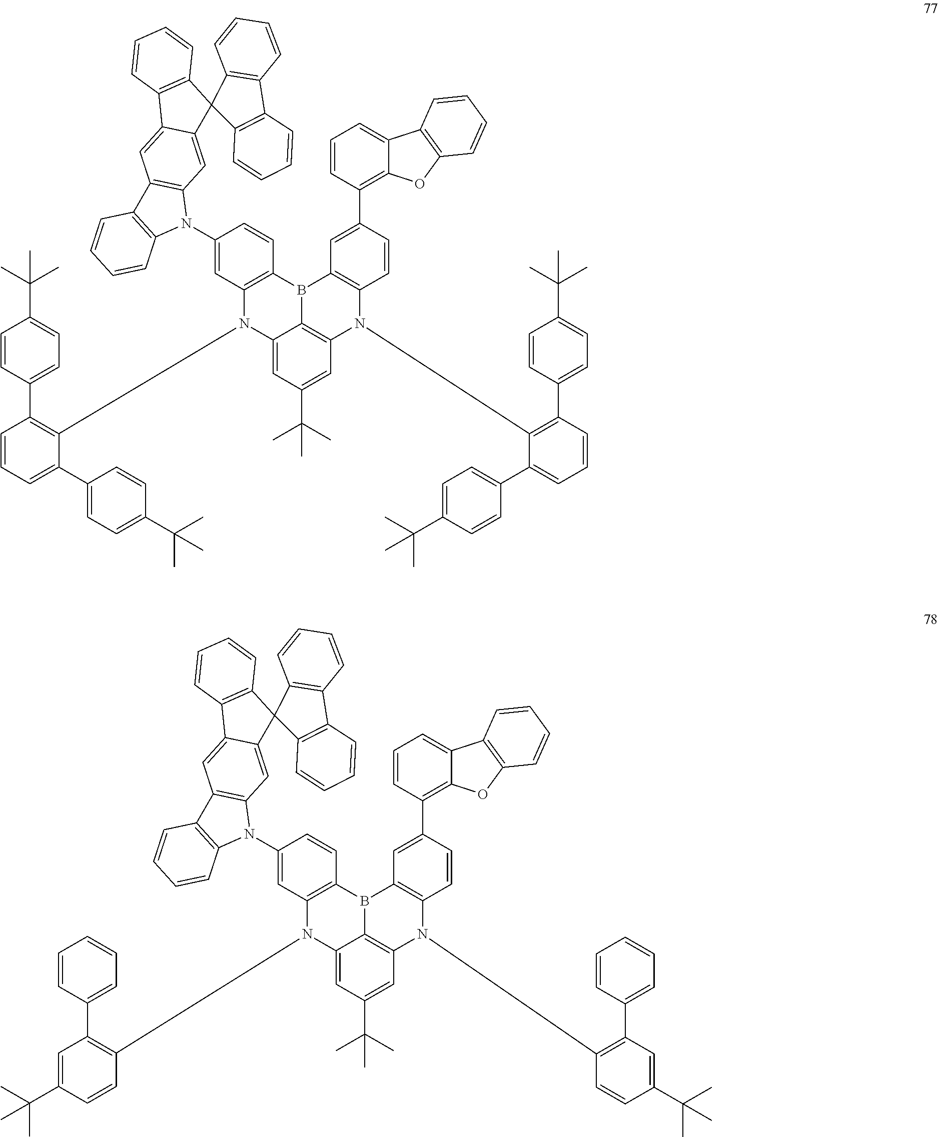 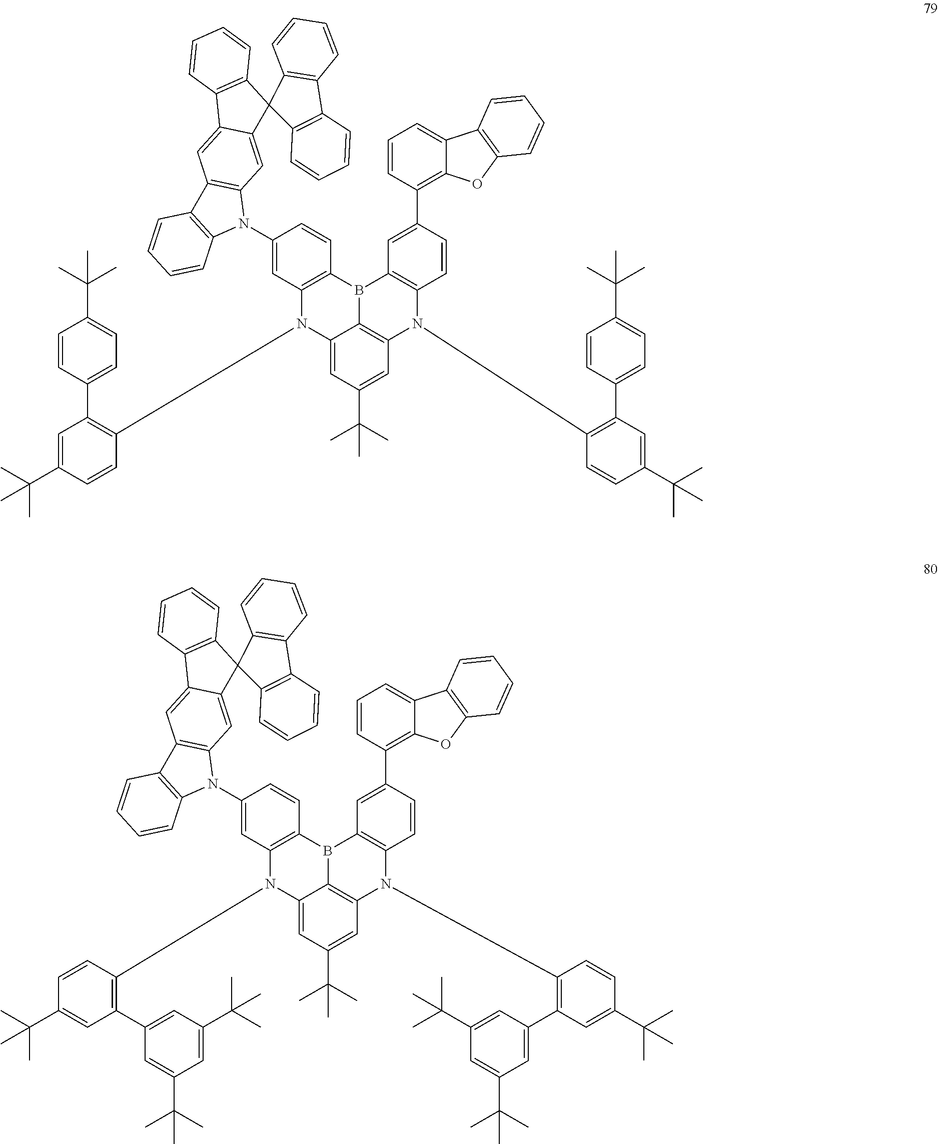 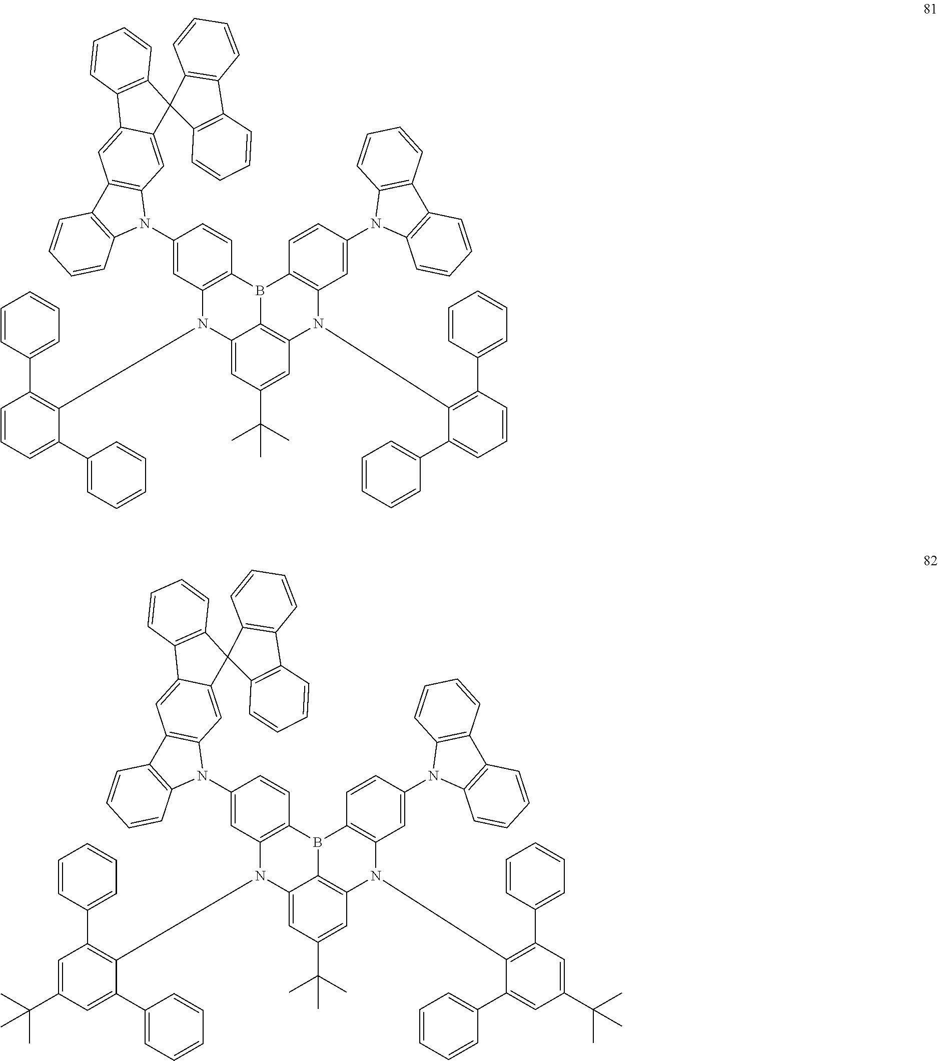 [SMILES: CC(C)(C)c1cc2c3c(c1)N(c1c(-c4ccccc4)cccc1-c1ccccc1)c1cc(-n4c5ccccc5c5cc6c(cc54)C4(c5ccccc5-c5ccccc54)c4ccccc4-6)ccc1B3c1ccc(-n3c4ccccc4c4ccccc43)cc1N2c1c(-c2ccccc2)cccc1-c1ccccc1 ; CC(C)(C)c1cc(-c2ccccc2)c(N2c3cc(-n4c5ccccc5c5ccccc54)ccc3B3c4ccc(-n5c6ccccc6c6cc7c(cc65)C5(c6ccccc6-c6ccccc65)c5ccccc5-7)cc4N(c4c(-c5ccccc5)cc(C(C)(C)C)cc4-c4ccccc4)c4cc(C(C)(C)C)cc2c43)c(-c2ccccc2)c1] 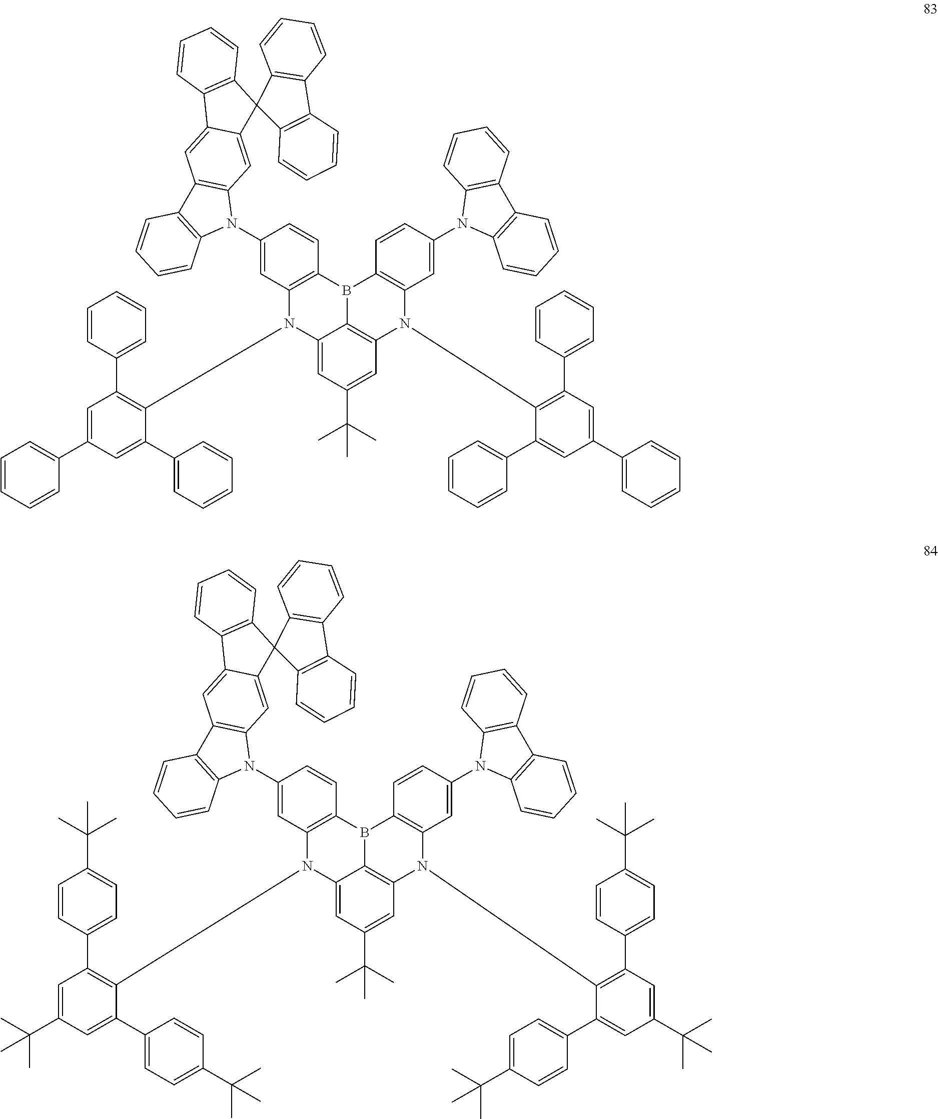 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1ccc(-n3c4ccccc4c4ccccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 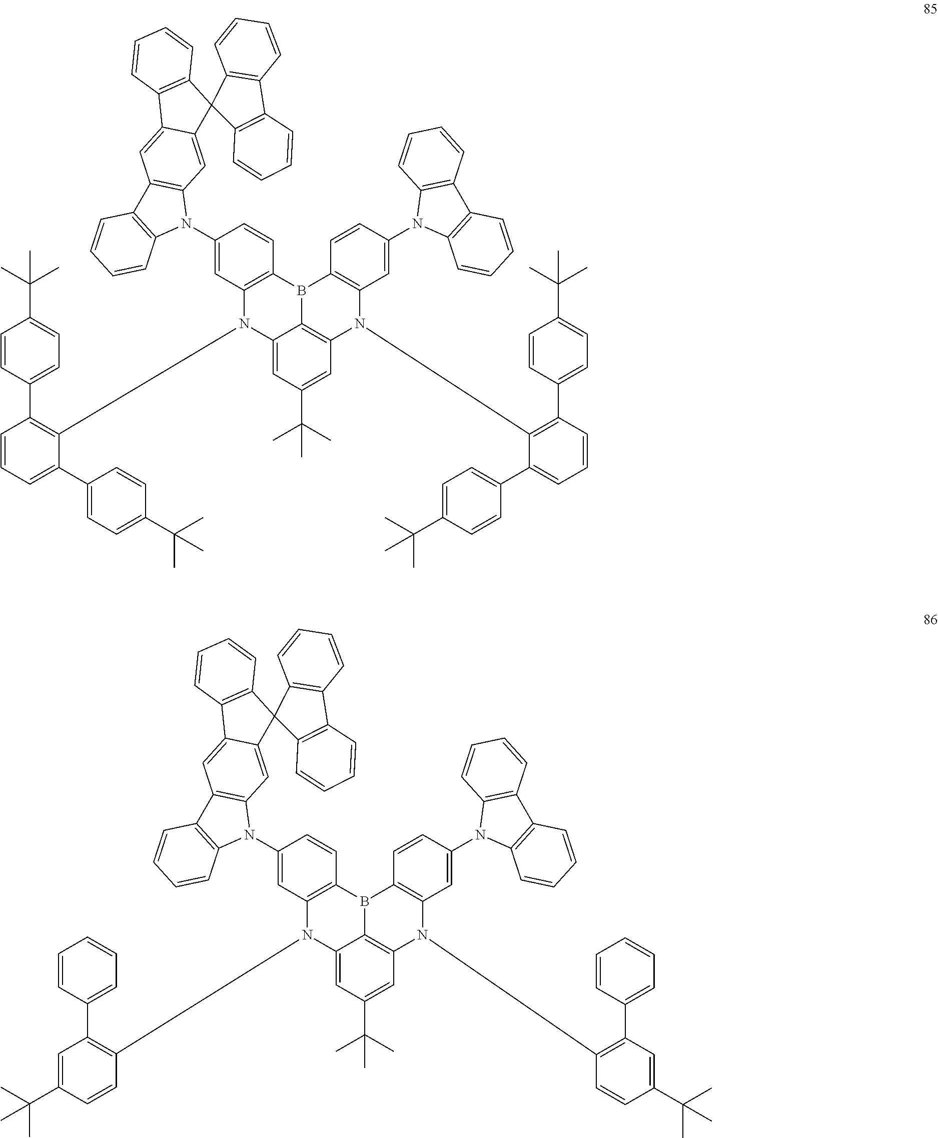 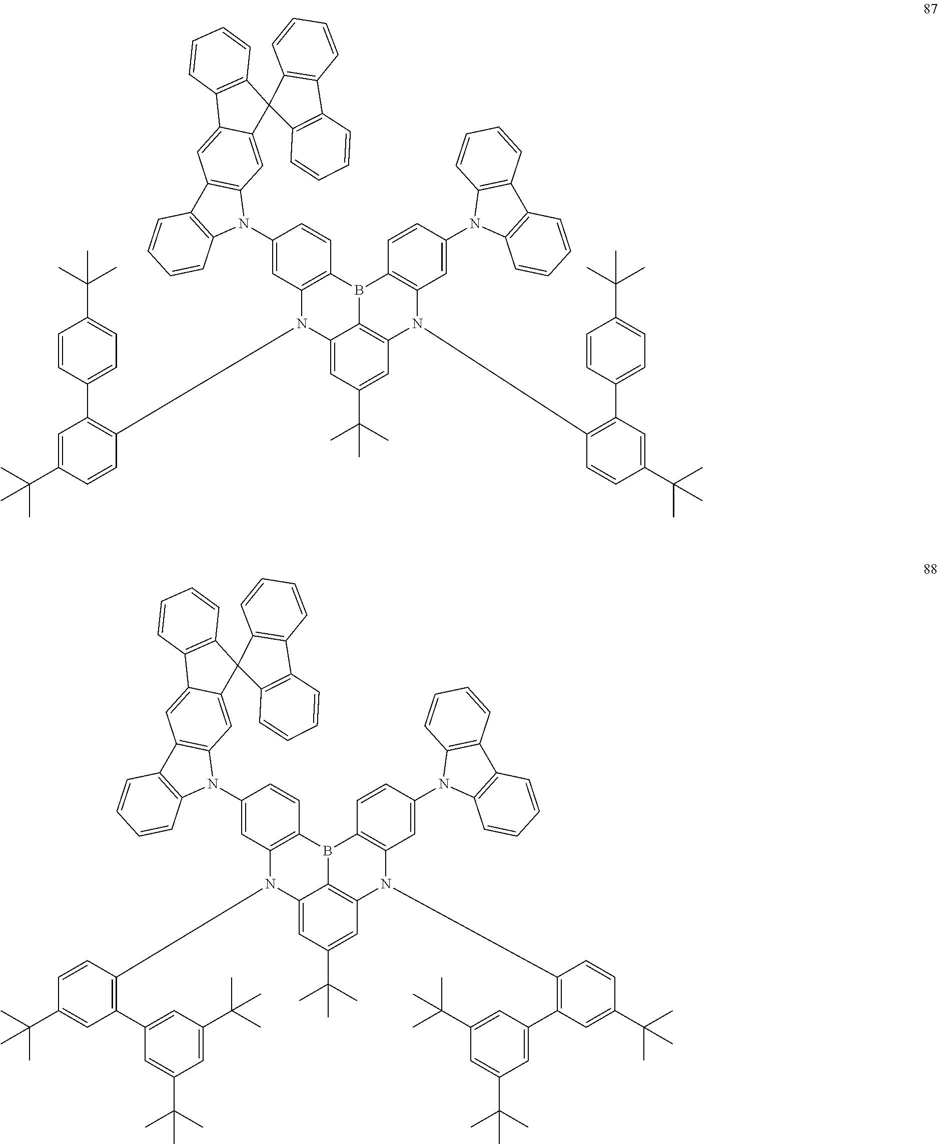 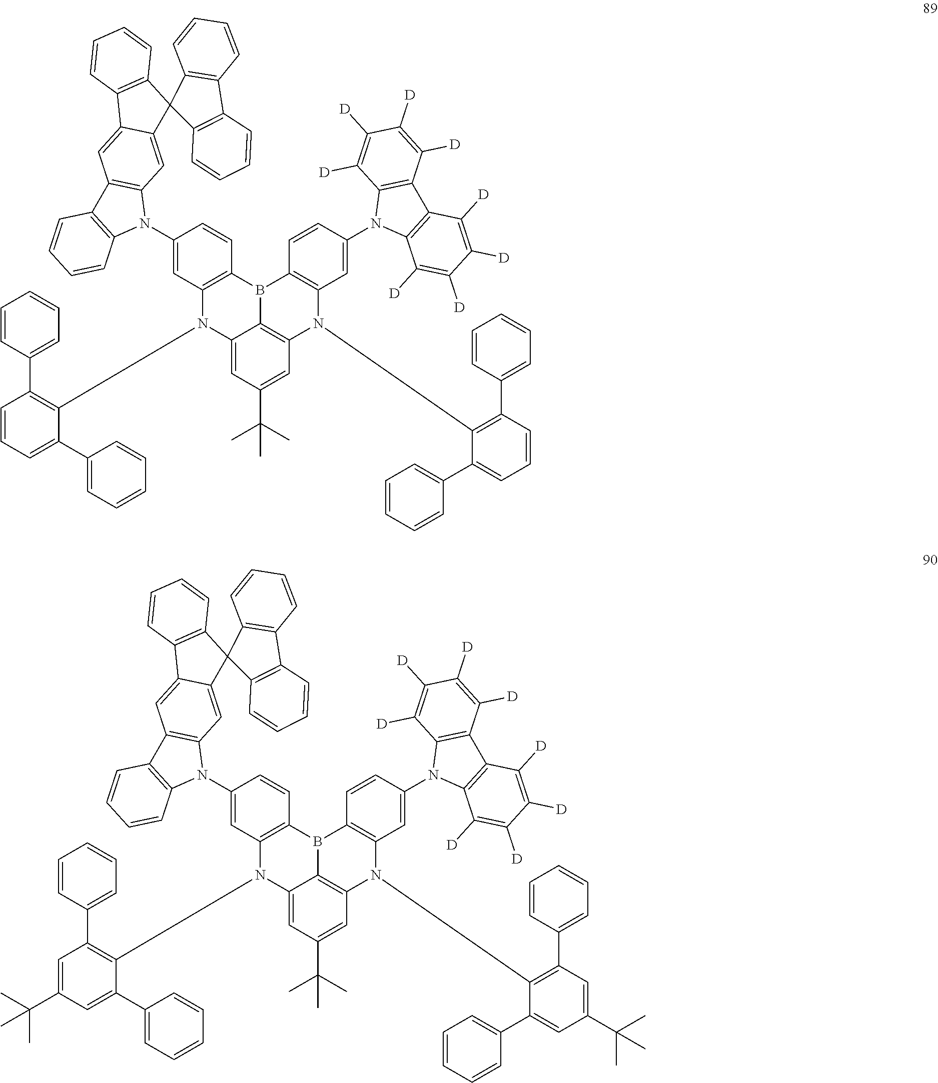 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4cc5c(cc42)C2(c4ccccc4-c4ccccc42)c2ccccc2-5)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4cc5c(cc42)C2(c4ccccc4-c4ccccc42)c2ccccc2-5)cc1N3c1c(-c2ccccc2)cc(C(C)(C)C)cc1-c1ccccc1] 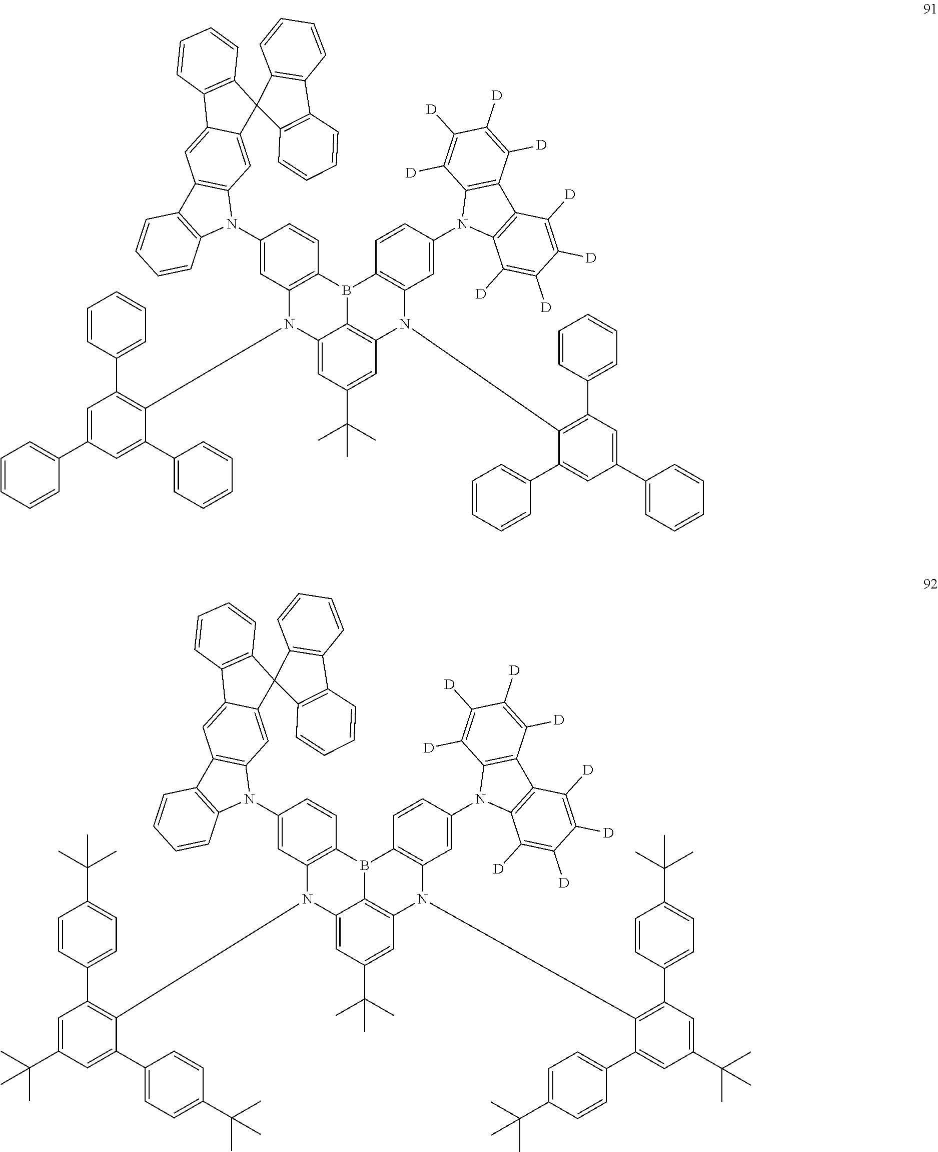 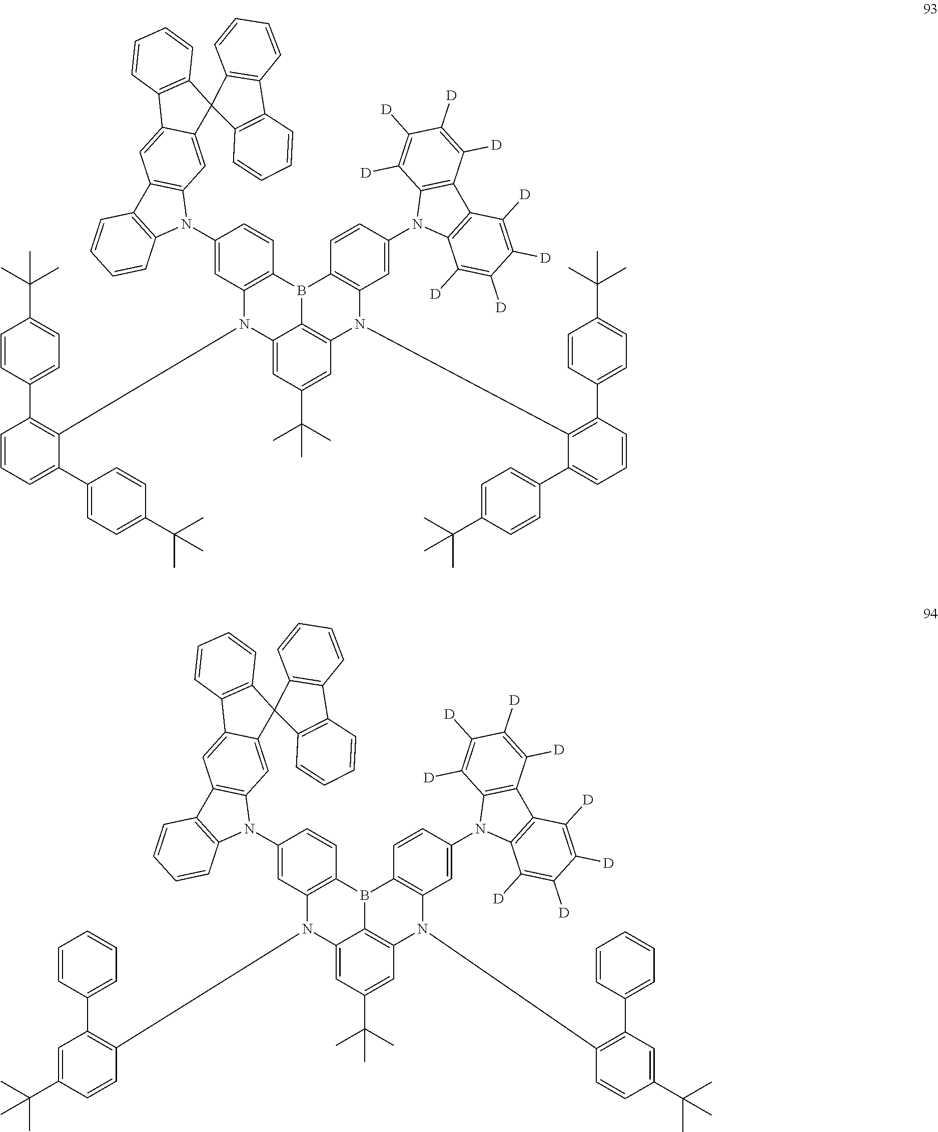 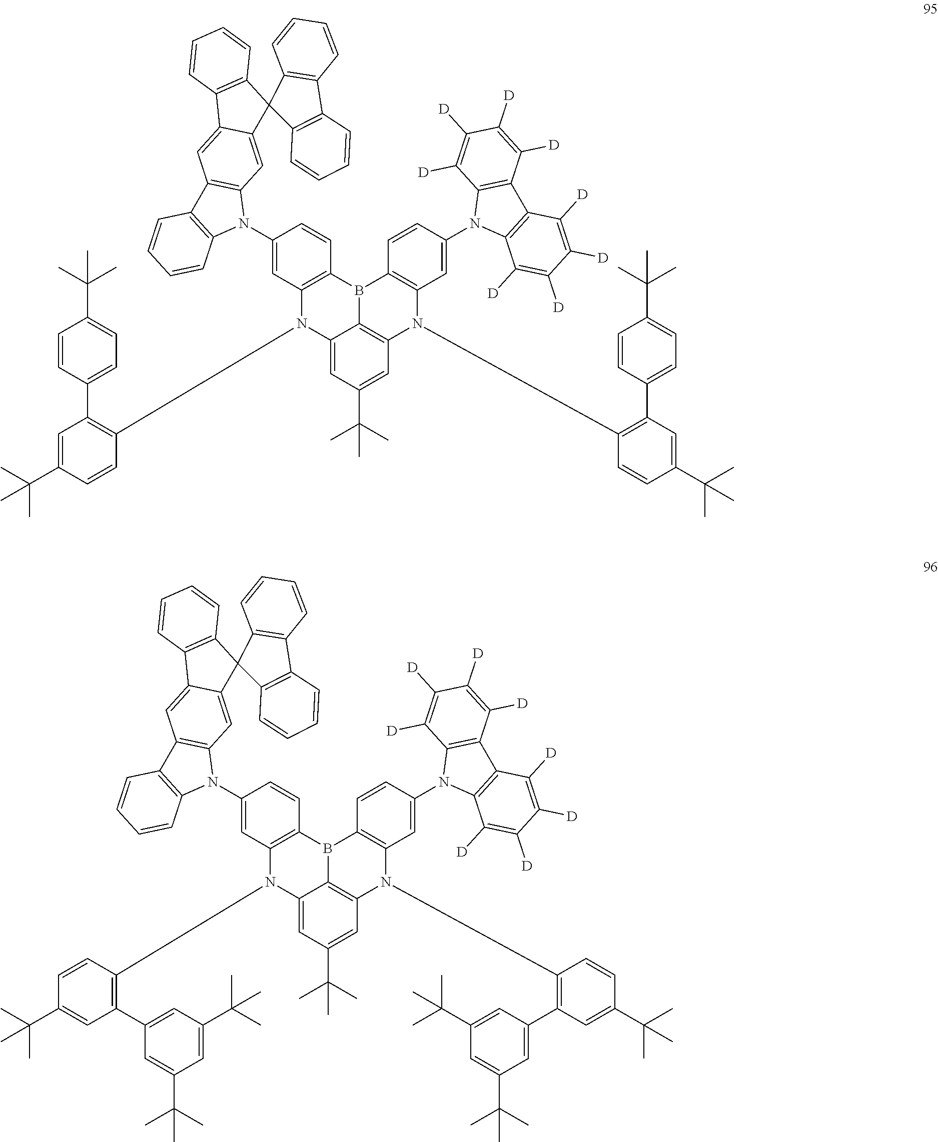 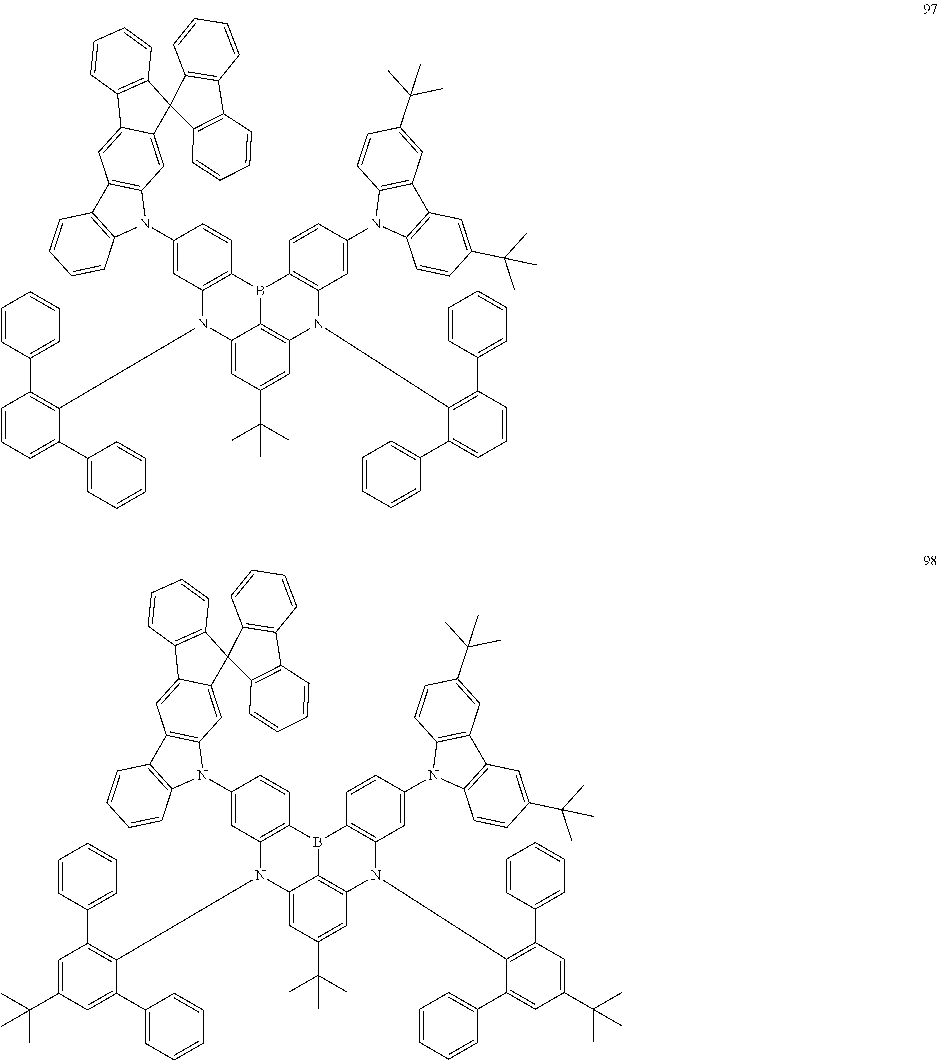 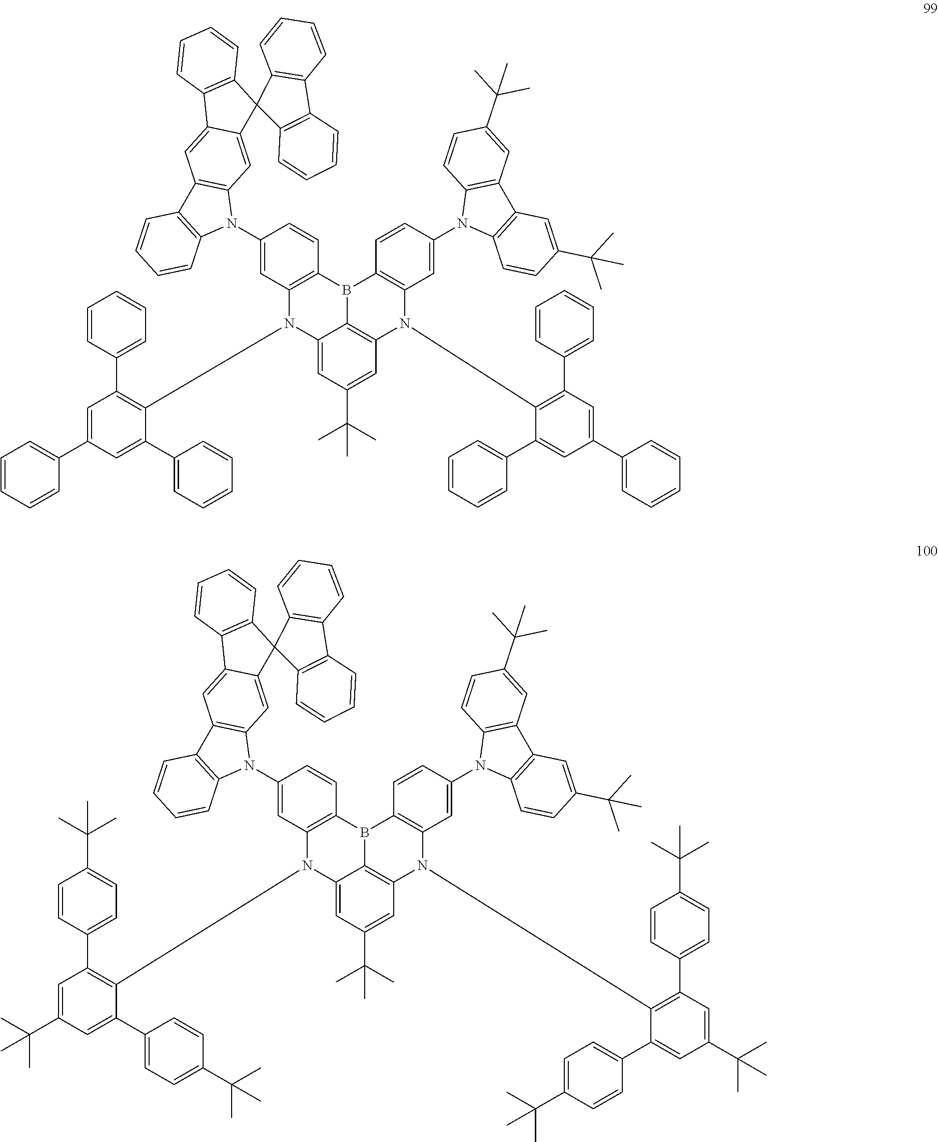 [SMILES: CC(C)(C)c1cc2c3c(c1)N(c1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 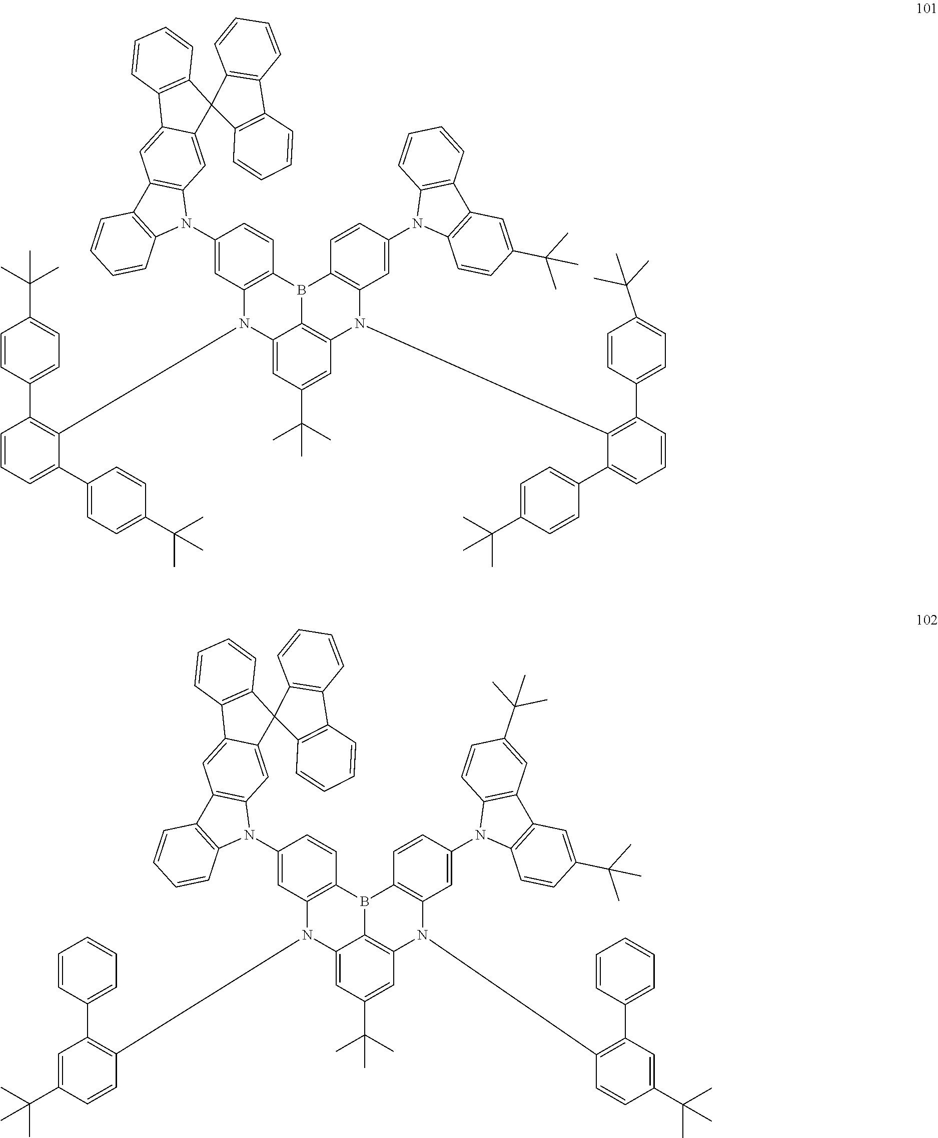 [SMILES: CC(C)(C)c1ccc(-c2cccc(-c3ccc(C(C)(C)C)cc3)c2N2c3cc(-n4c5ccccc5c5cc(C(C)(C)C)ccc54)ccc3B3c4ccc(-n5c6ccccc6c6cc7c(cc65)C5(c6ccccc6-c6ccccc65)c5ccccc5-7)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3cc(-n4c5ccc(C(C)(C)C)cc5c5cc(C(C)(C)C)ccc54)ccc3B3c4ccc(-n5c6ccccc6c6cc7c(cc65)C5(c6ccccc6-c6ccccc65)c5ccccc5-7)cc4N(c4ccc(C(C)(C)C)cc4-c4ccccc4)c4cc(C(C)(C)C)cc2c43)c(-c2ccccc2)c1] 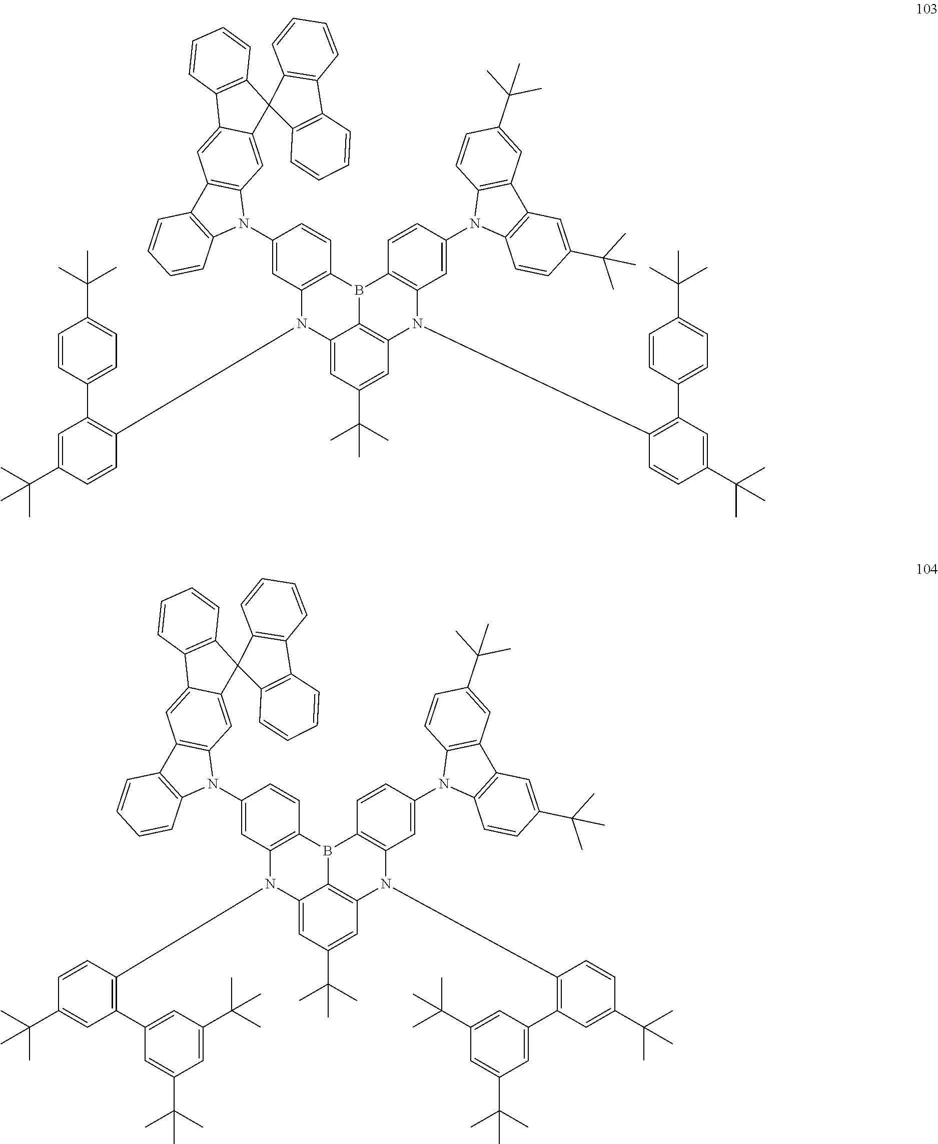 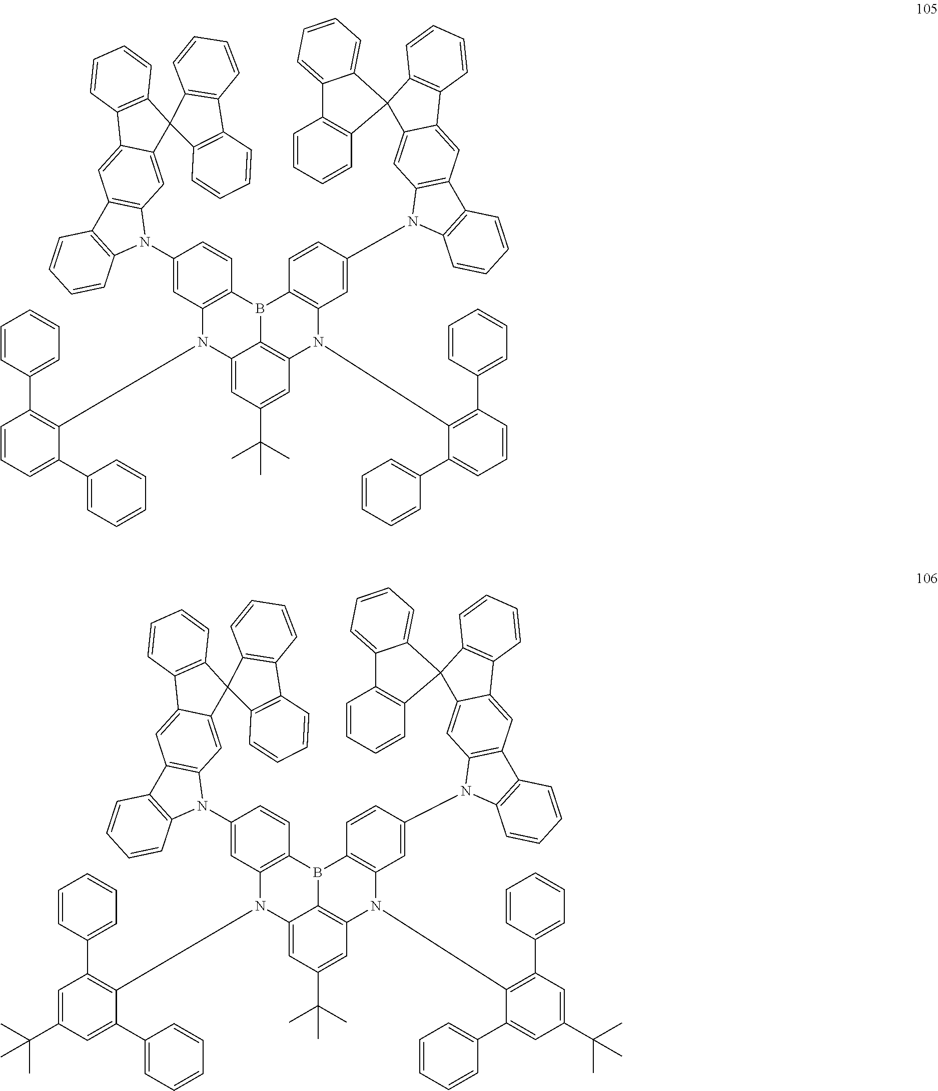 [SMILES: CC(C)(C)c1cc2c3c(c1)N(c1c(-c4ccccc4)cccc1-c1ccccc1)c1cc(-n4c5ccccc5c5cc6c(cc54)C4(c5ccccc5-c5ccccc54)c4ccccc4-6)ccc1B3c1ccc(-n3c4ccccc4c4cc5c(cc43)C3(c4ccccc4-c4ccccc43)c3ccccc3-5)cc1N2c1c(-c2ccccc2)cccc1-c1ccccc1 ; CC(C)(C)c1cc(-c2ccccc2)c(N2c3cc(-n4c5ccccc5c5cc6c(cc54)C4(c5ccccc5-c5ccccc54)c4ccccc4-6)ccc3B3c4ccc(-n5c6ccccc6c6cc7c(cc65)C5(c6ccccc6-c6ccccc65)c5ccccc5-7)cc4N(c4c(-c5ccccc5)cc(C(C)(C)C)cc4-c4ccccc4)c4cc(C(C)(C)C)cc2c43)c(-c2ccccc2)c1] 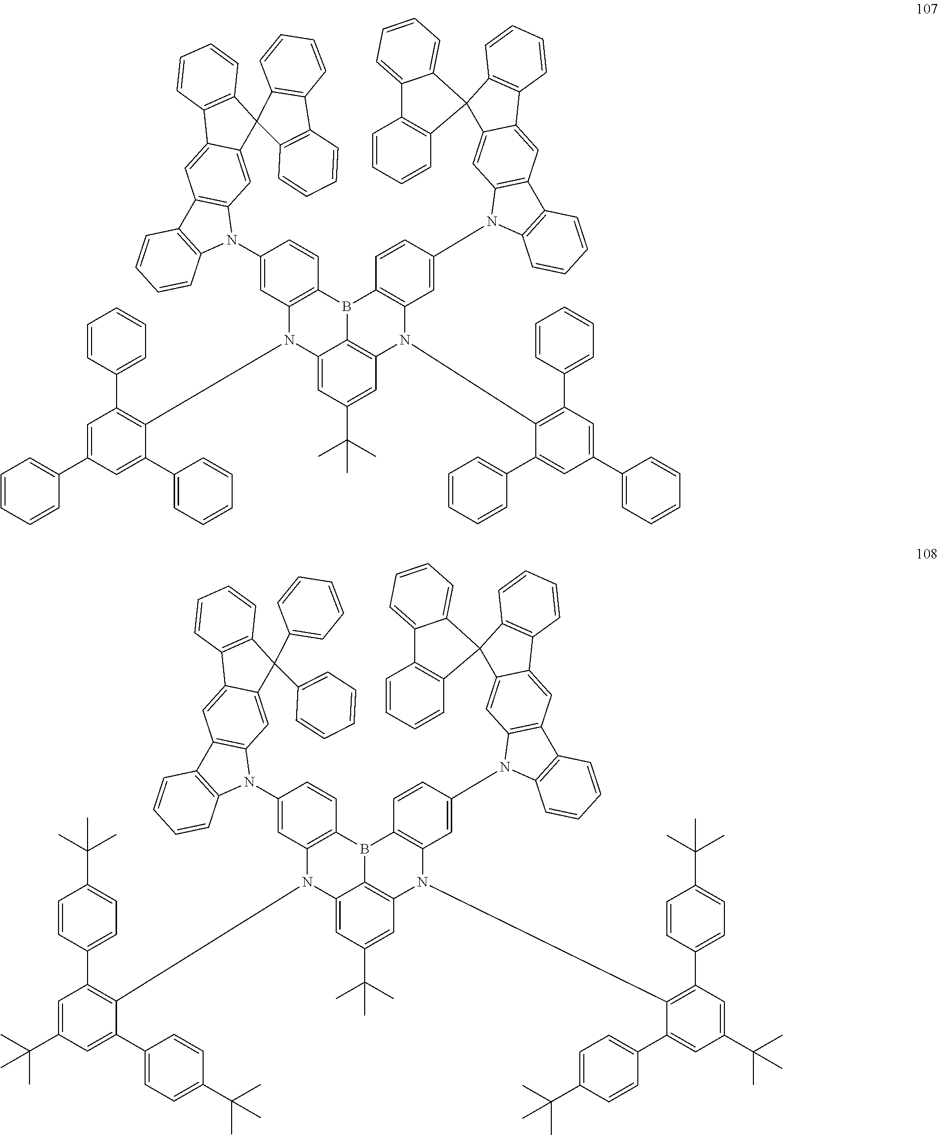 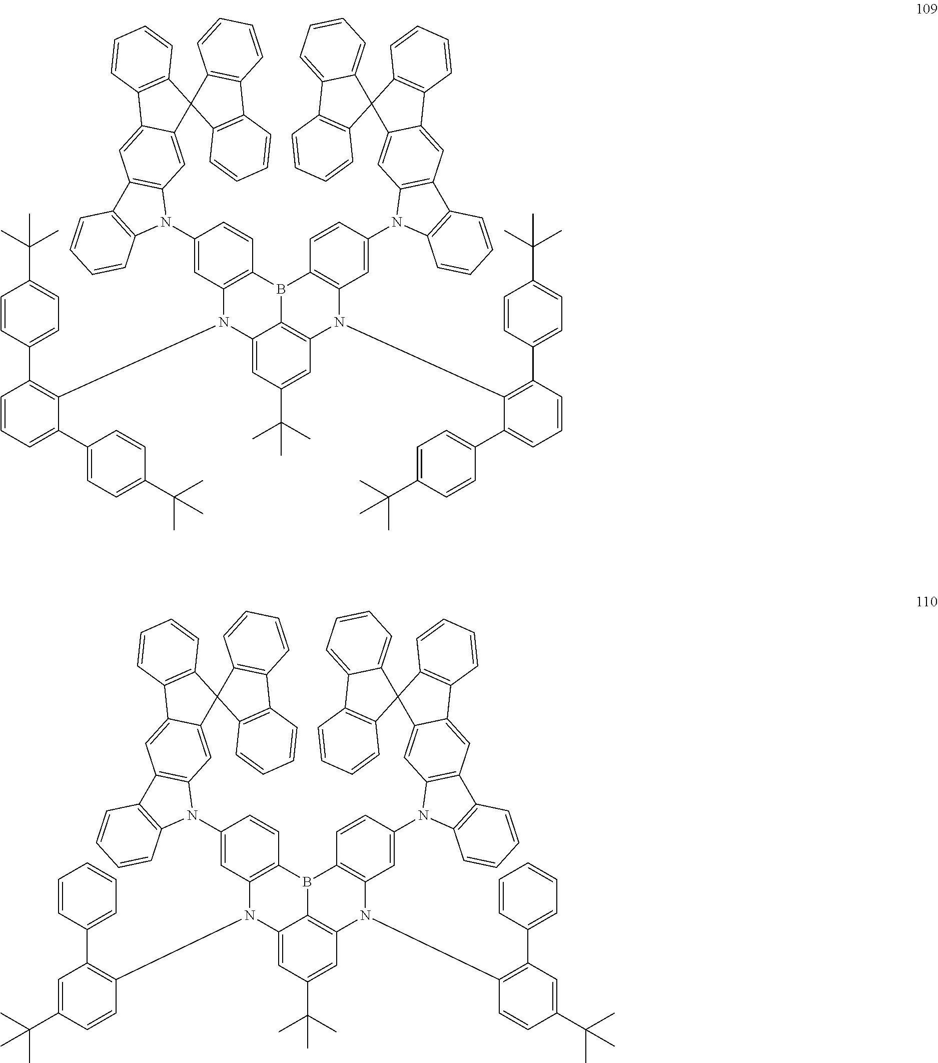 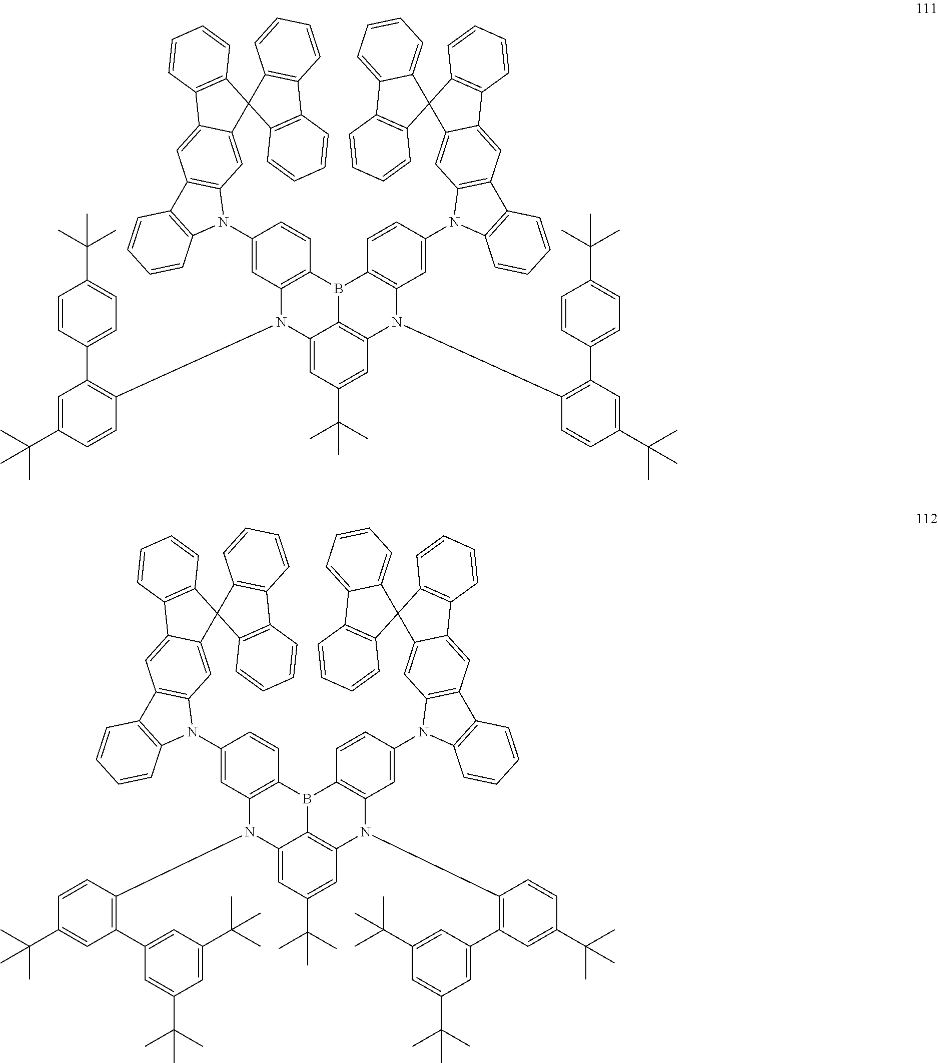 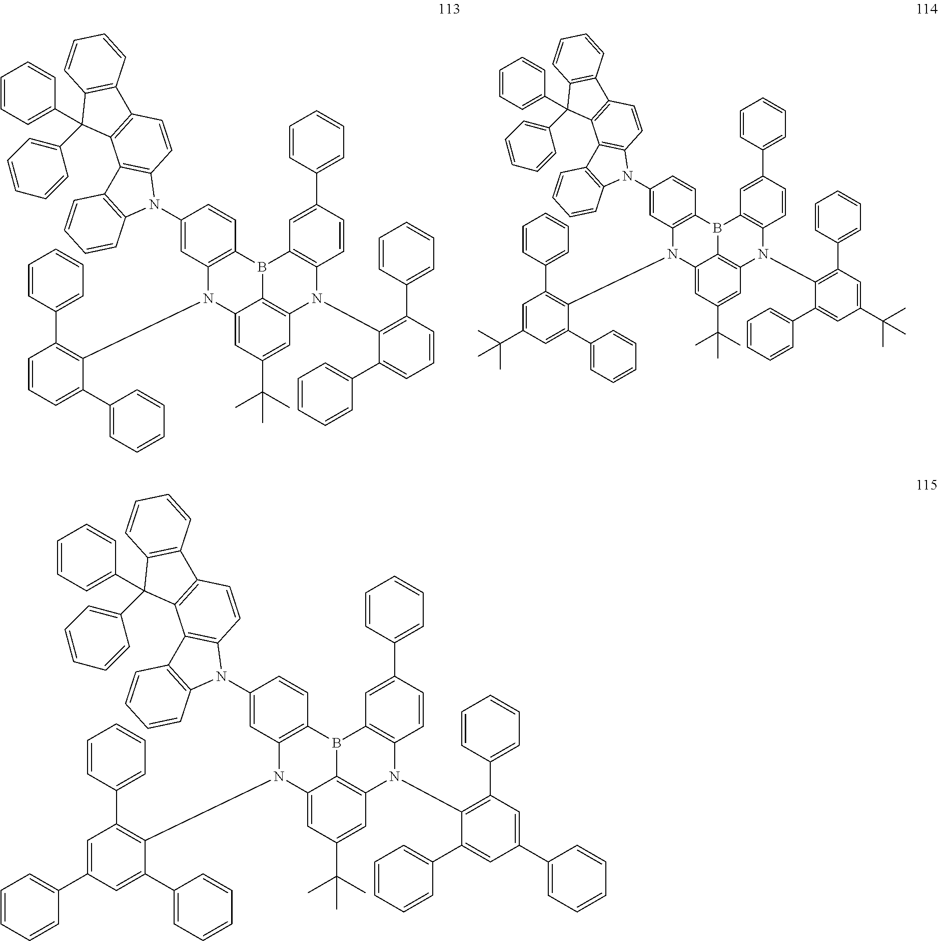 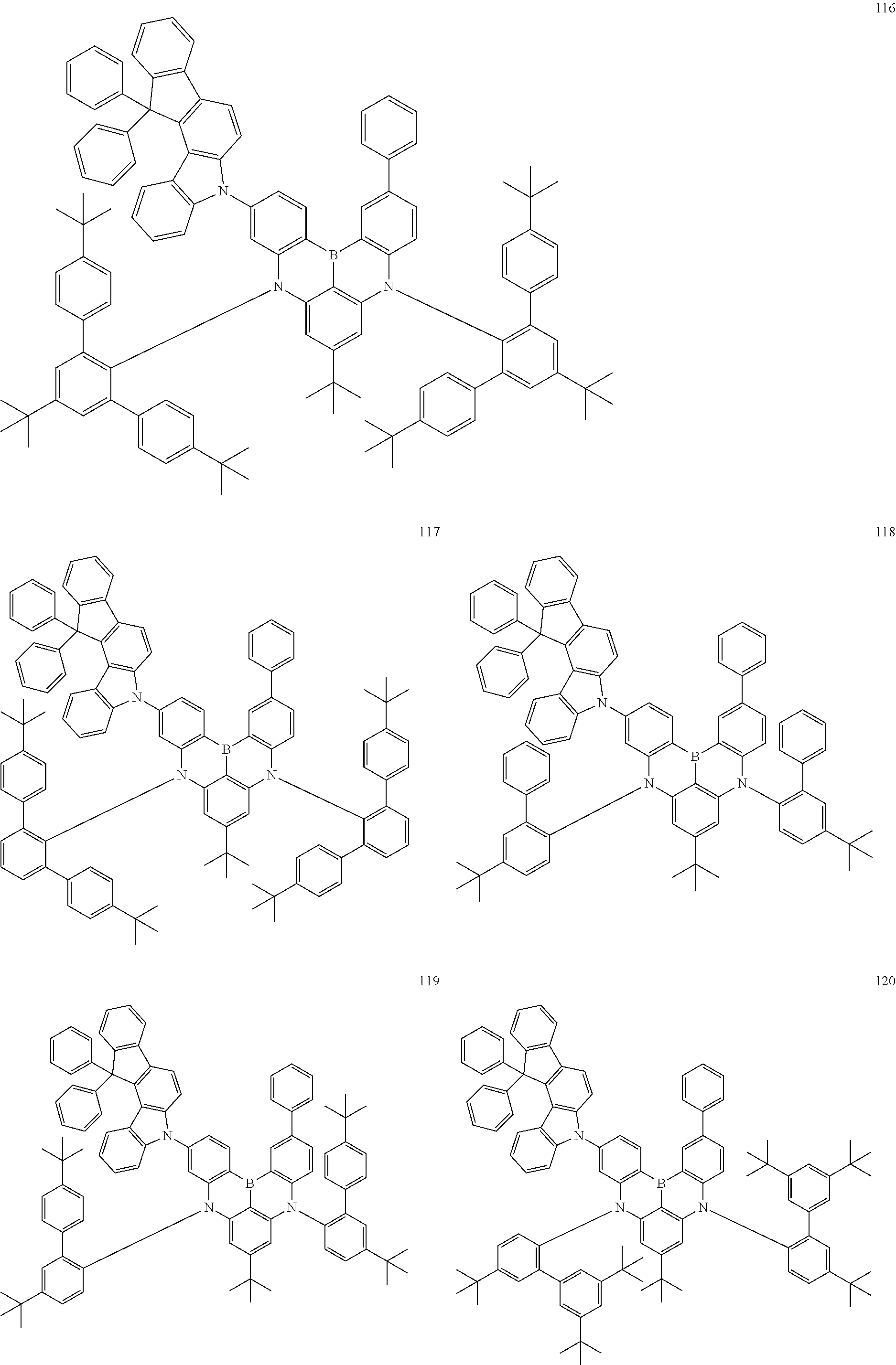 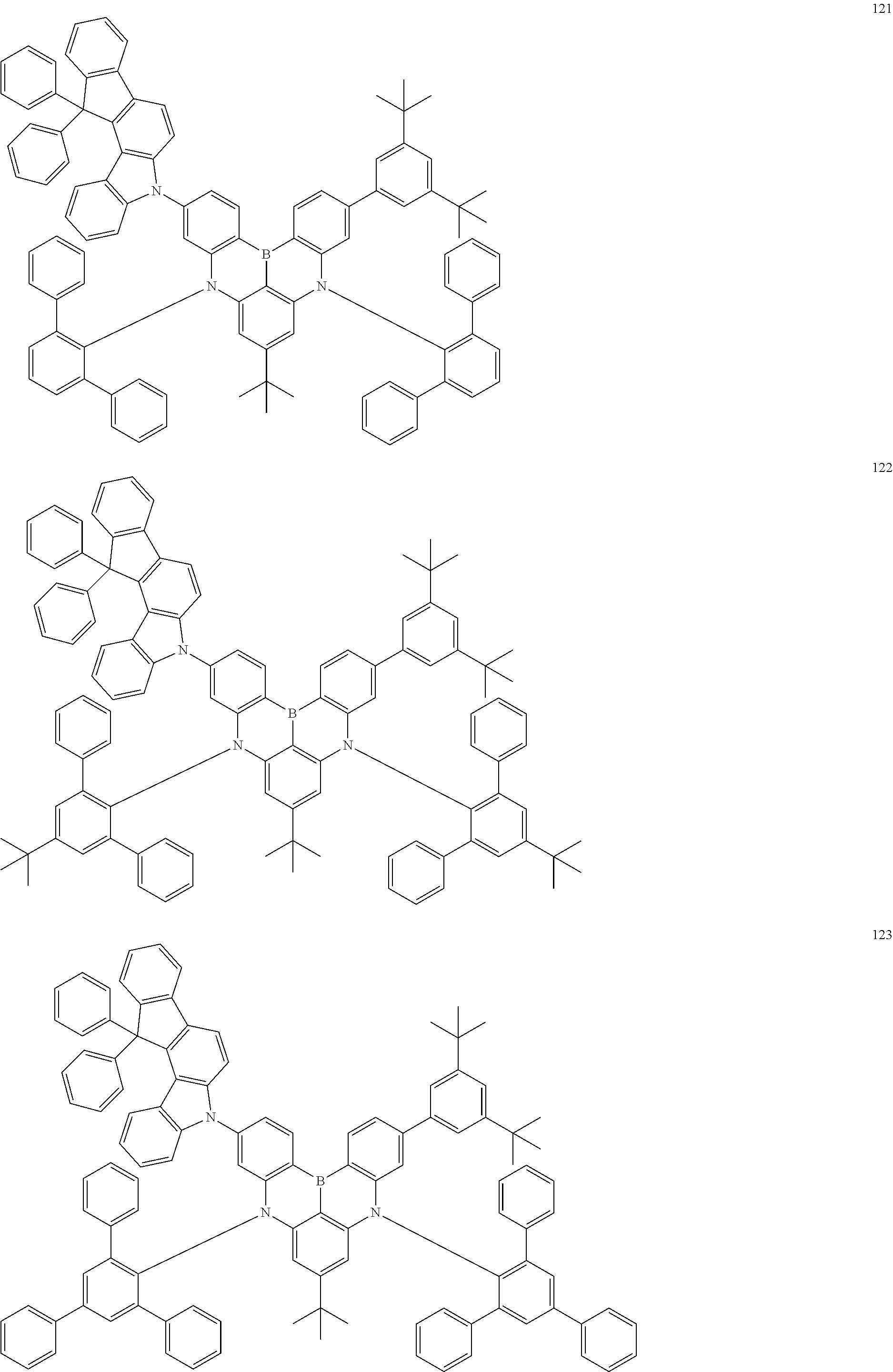 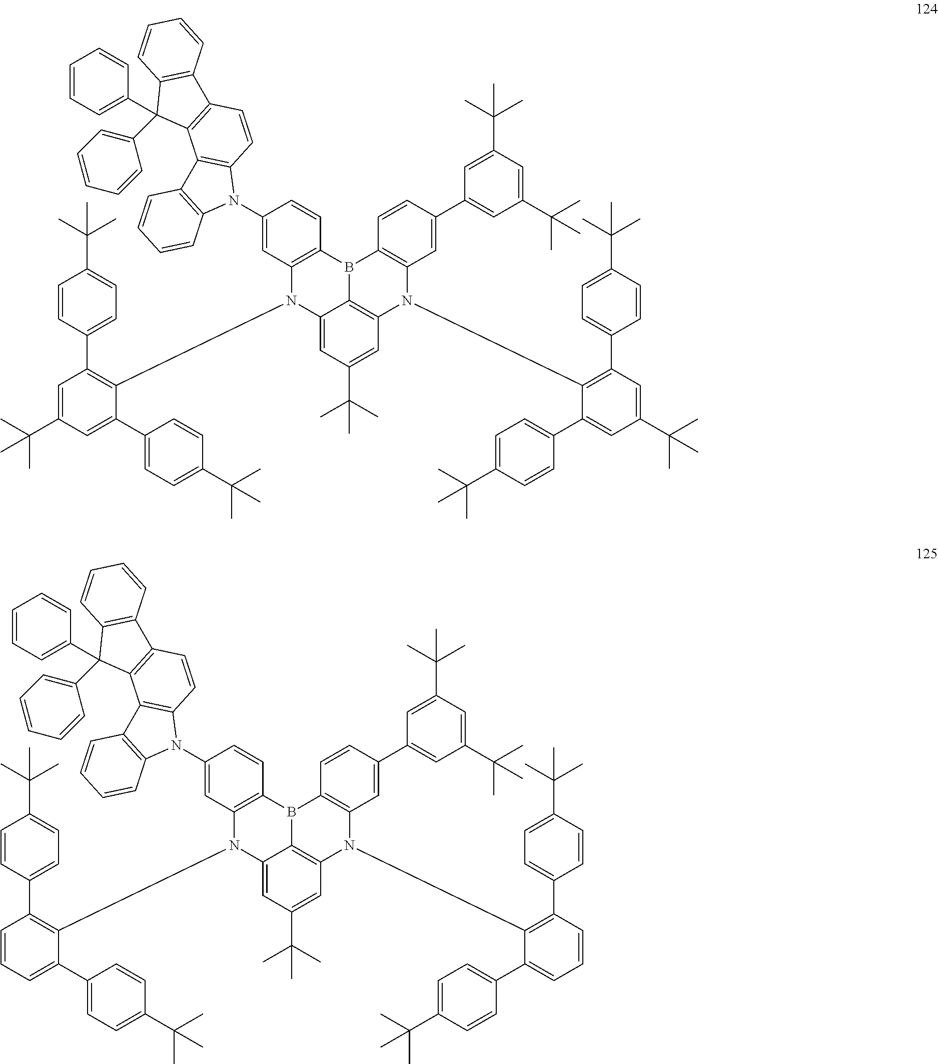 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1] 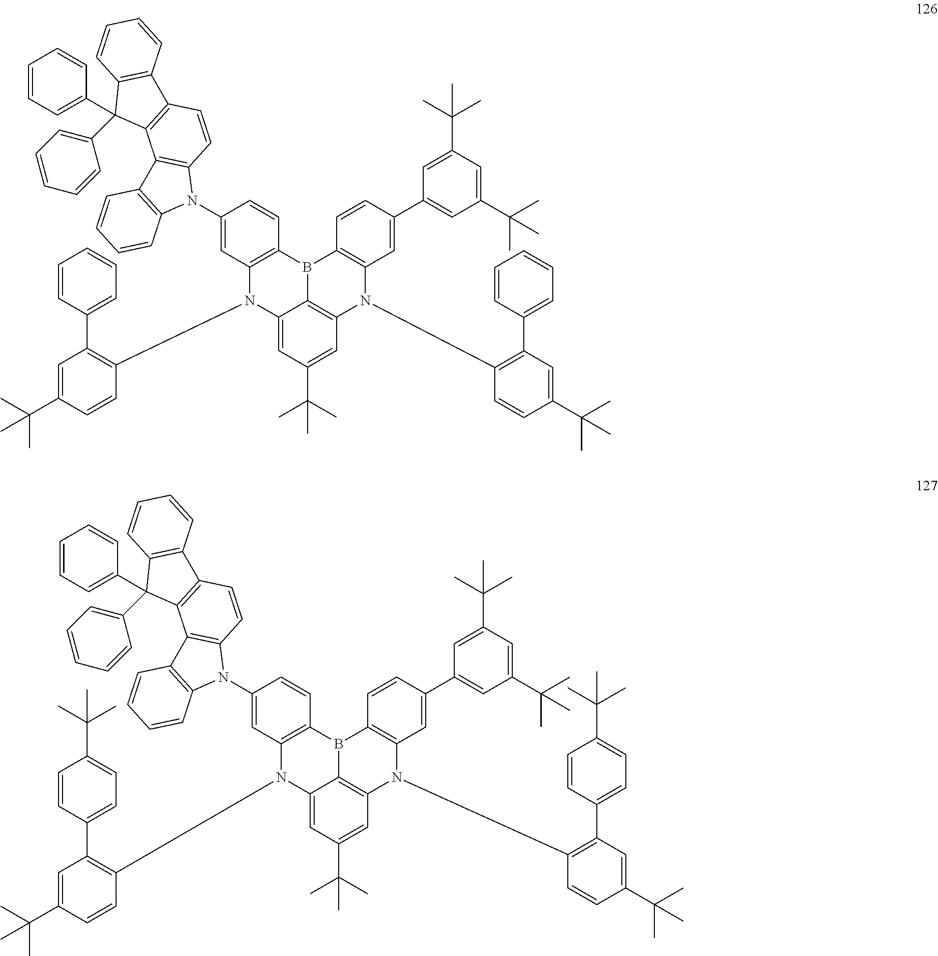 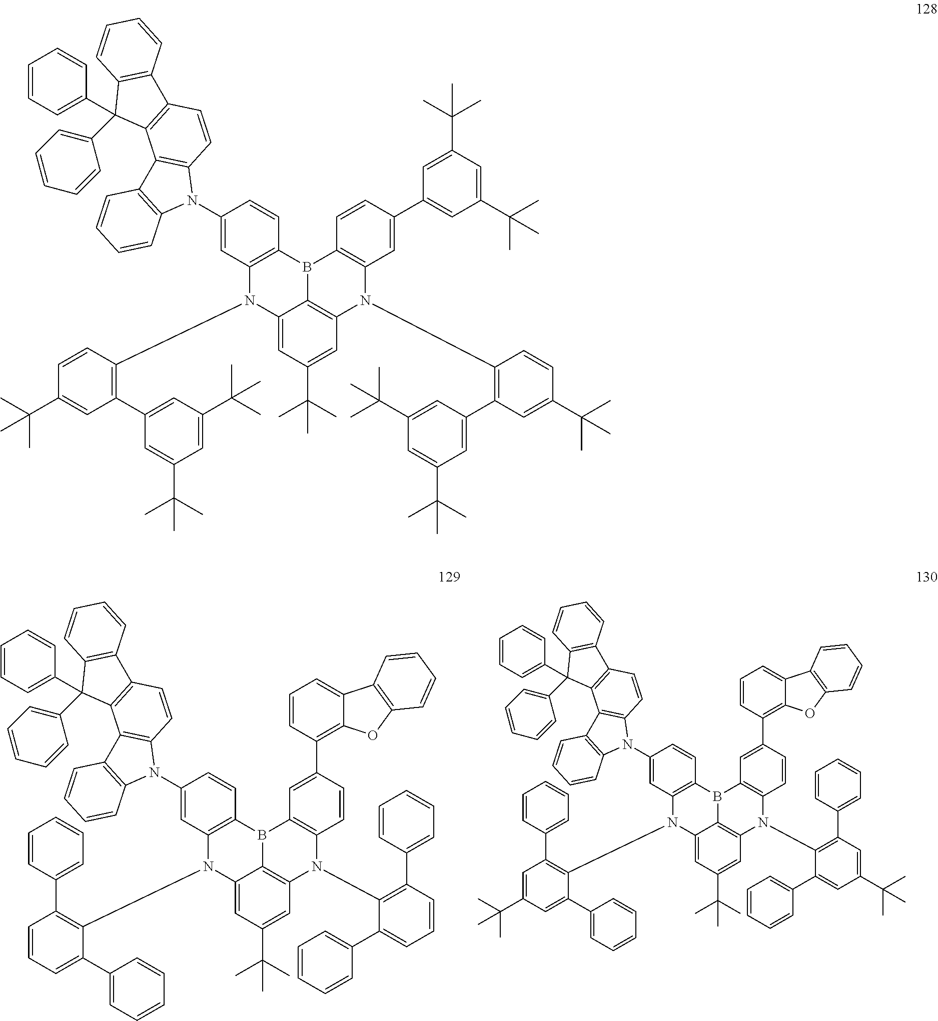 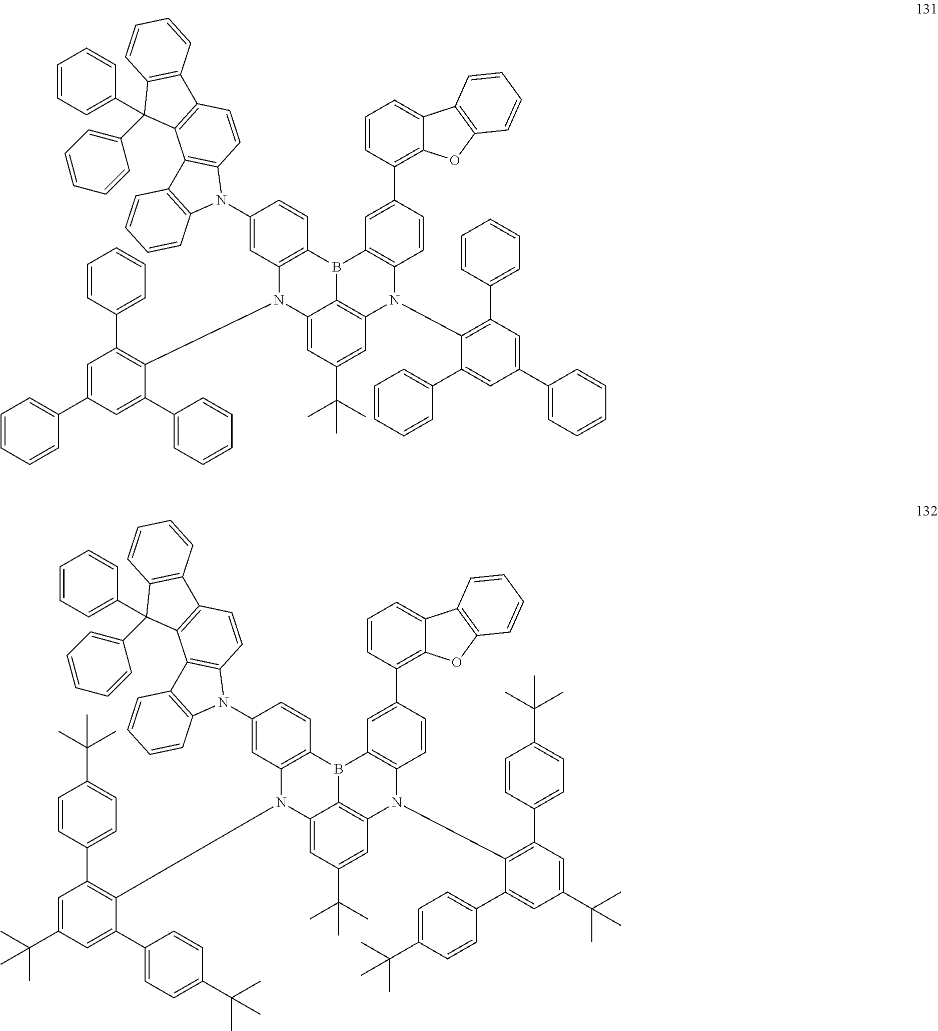 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C6(c4ccccc4)c4ccccc4)ccc1B3c1cc(-c3cccc4c3oc3ccccc34)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4cccc5c4oc4ccccc45)cc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 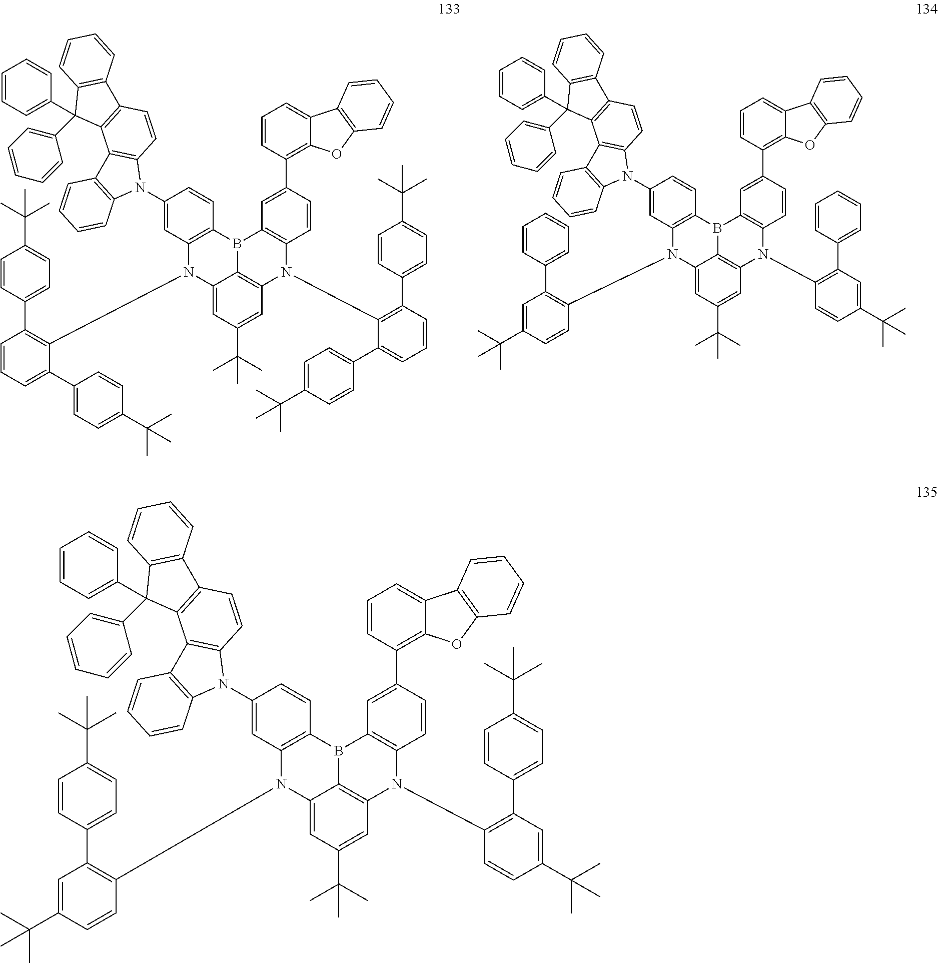 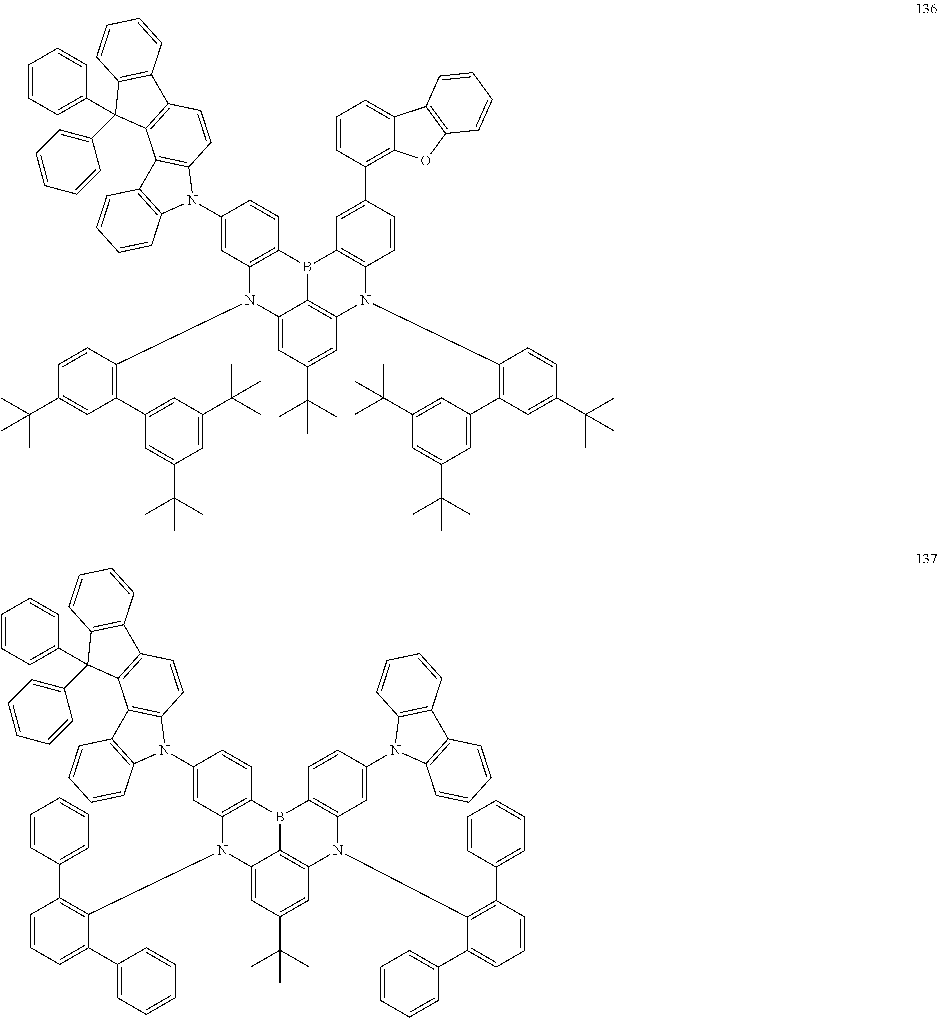 [SMILES: CC(C)(C)c1cc(-c2cc(C(C)(C)C)ccc2N2c3ccc(-c4cccc5c4oc4ccccc45)cc3B3c4ccc(-n5c6ccccc6c6c7c(ccc65)-c5ccccc5C7(c5ccccc5)c5ccccc5)cc4N(c4ccc(C(C)(C)C)cc4-c4cc(C(C)(C)C)cc(C(C)(C)C)c4)c4cc(C(C)(C)C)cc2c43)cc(C(C)(C)C)c1 ; CC(C)(C)c1cc2c3c(c1)N(c1c(-c4ccccc4)cccc1-c1ccccc1)c1cc(-n4c5ccccc5c5c6c(ccc54)-c4ccccc4C6(c4ccccc4)c4ccccc4)ccc1B3c1ccc(-n3c4ccccc4c4ccccc43)cc1N2c1c(-c2ccccc2)cccc1-c1ccccc1] 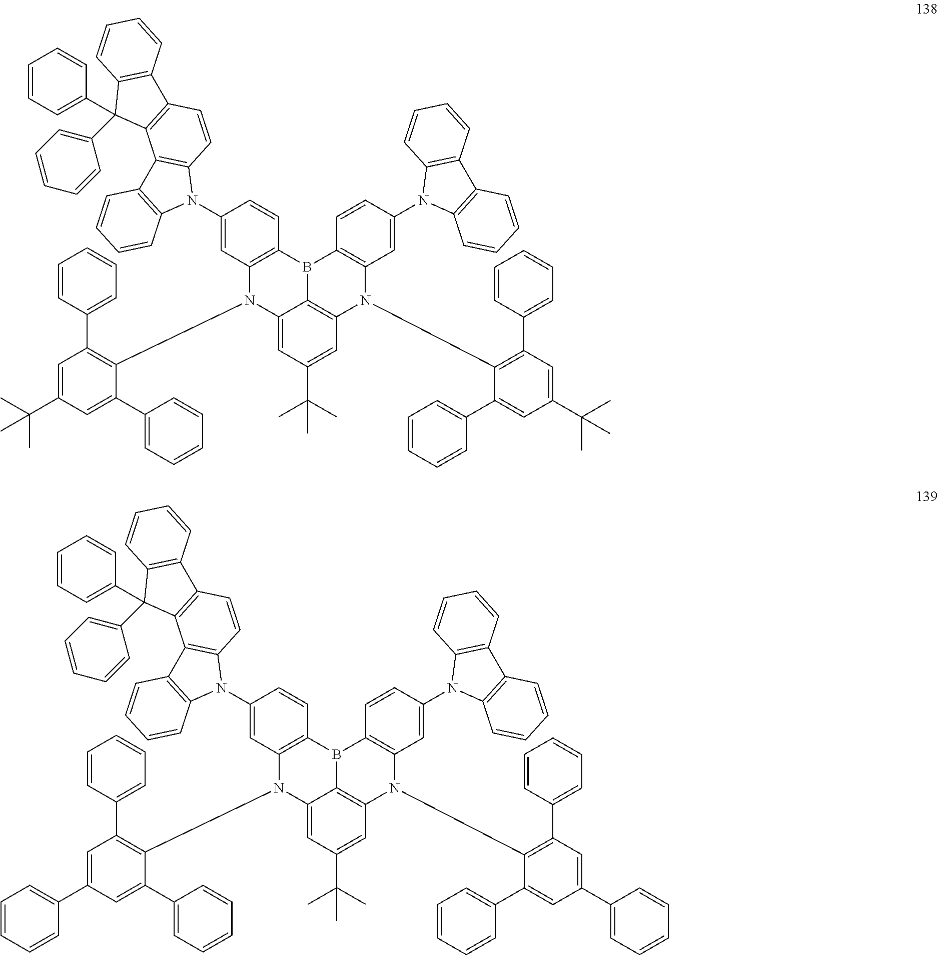 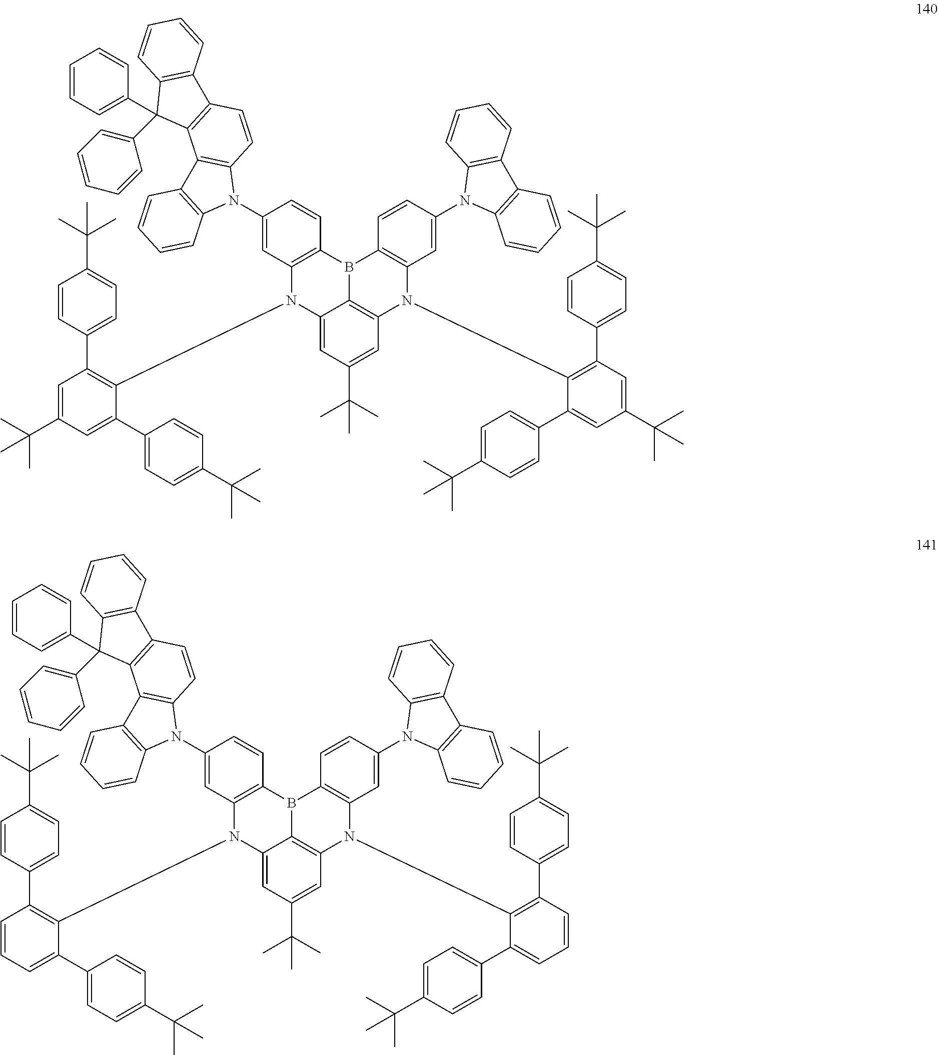 [SMILES: CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3cc(-n4c5ccccc5c5ccccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1] 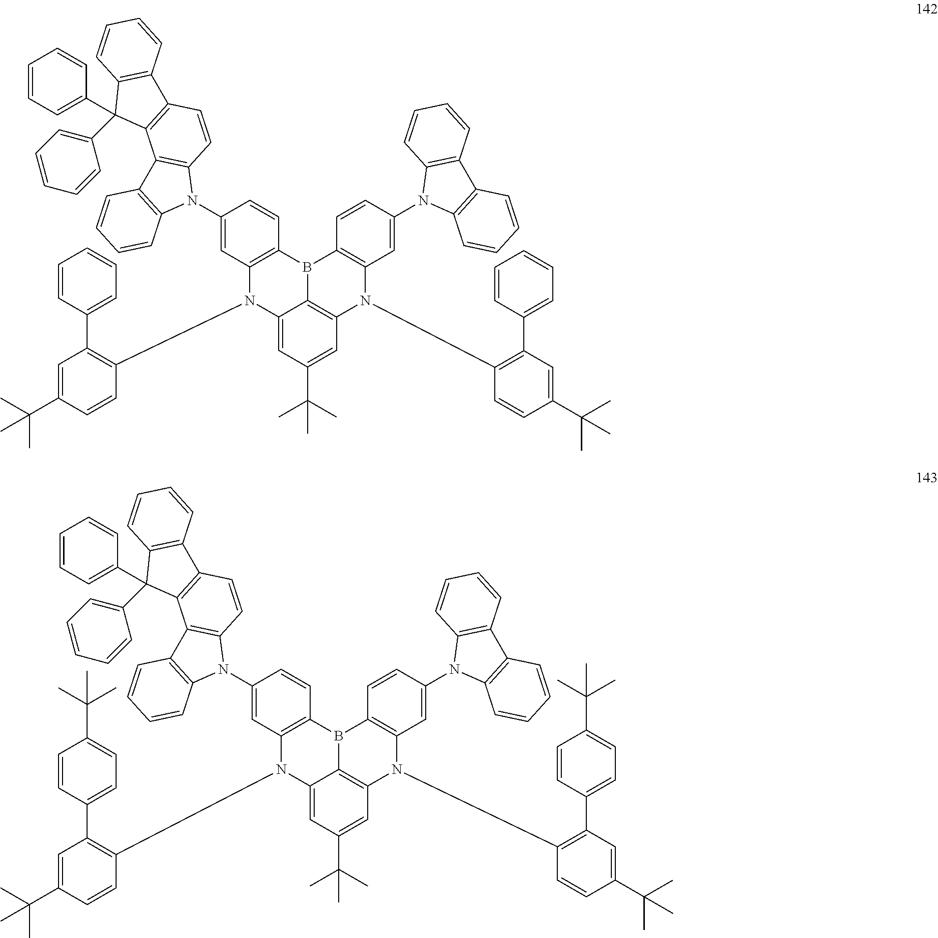 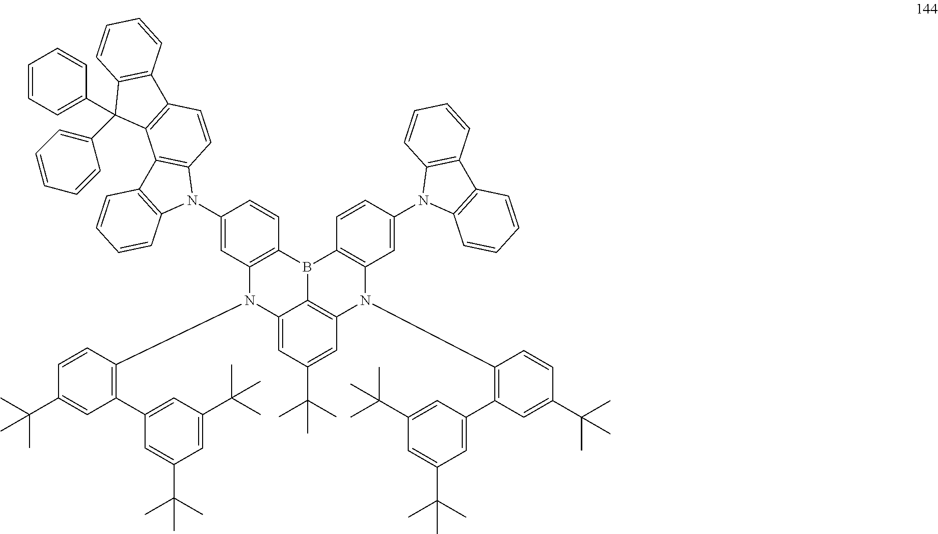 [SMILES: CC(C)(C)c1cc(-c2cc(C(C)(C)C)ccc2N2c3cc(-n4c5ccccc5c5ccccc54)ccc3B3c4ccc(-n5c6ccccc6c6c7c(ccc65)-c5ccccc5C7(c5ccccc5)c5ccccc5)cc4N(c4ccc(C(C)(C)C)cc4-c4cc(C(C)(C)C)cc(C(C)(C)C)c4)c4cc(C(C)(C)C)cc2c43)cc(C(C)(C)C)c1] 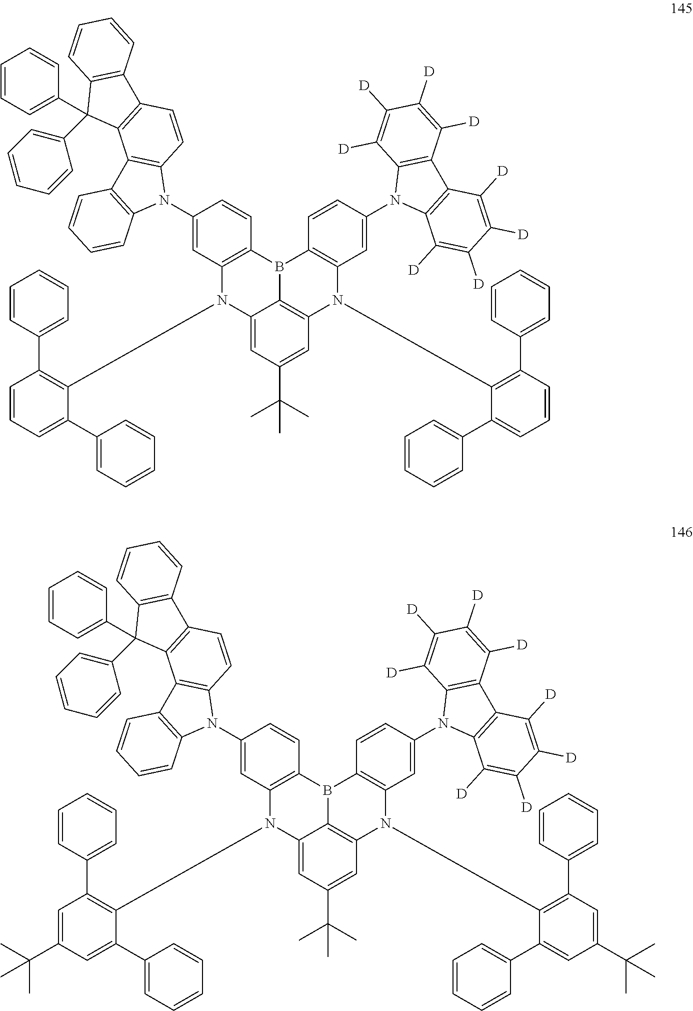 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4c5c(ccc42)-c2ccccc2C5(c2ccccc2)c2ccccc2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4c5c(ccc42)-c2ccccc2C5(c2ccccc2)c2ccccc2)cc1N3c1c(-c2ccccc2)cc(C(C)(C)C)cc1-c1ccccc1] 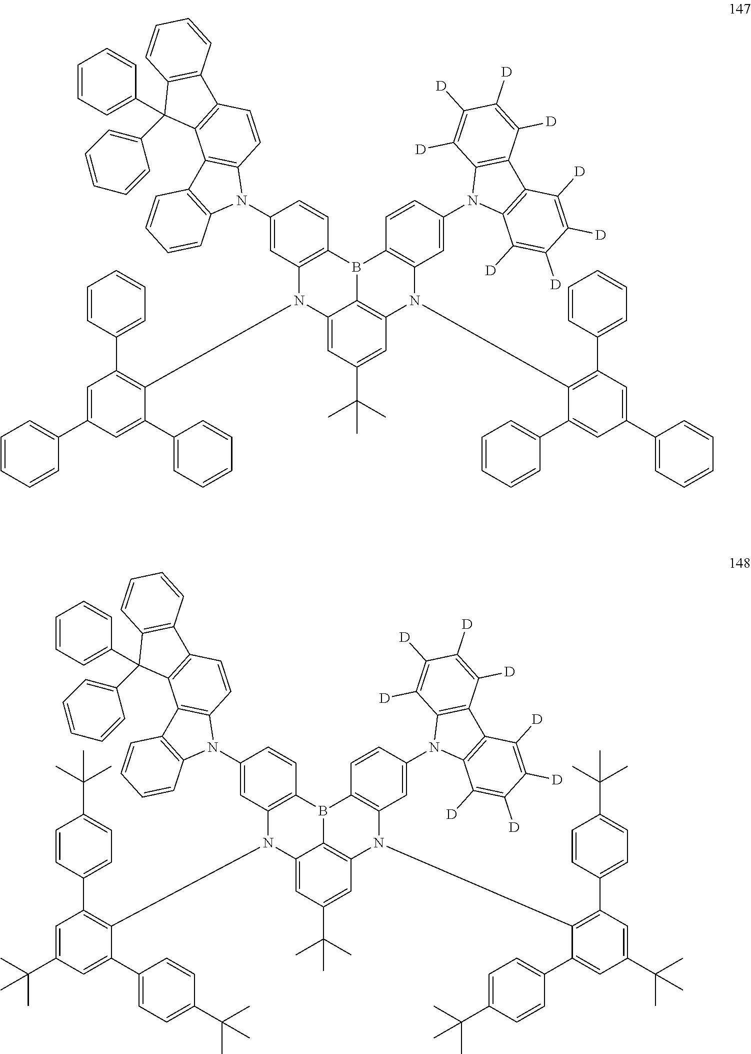 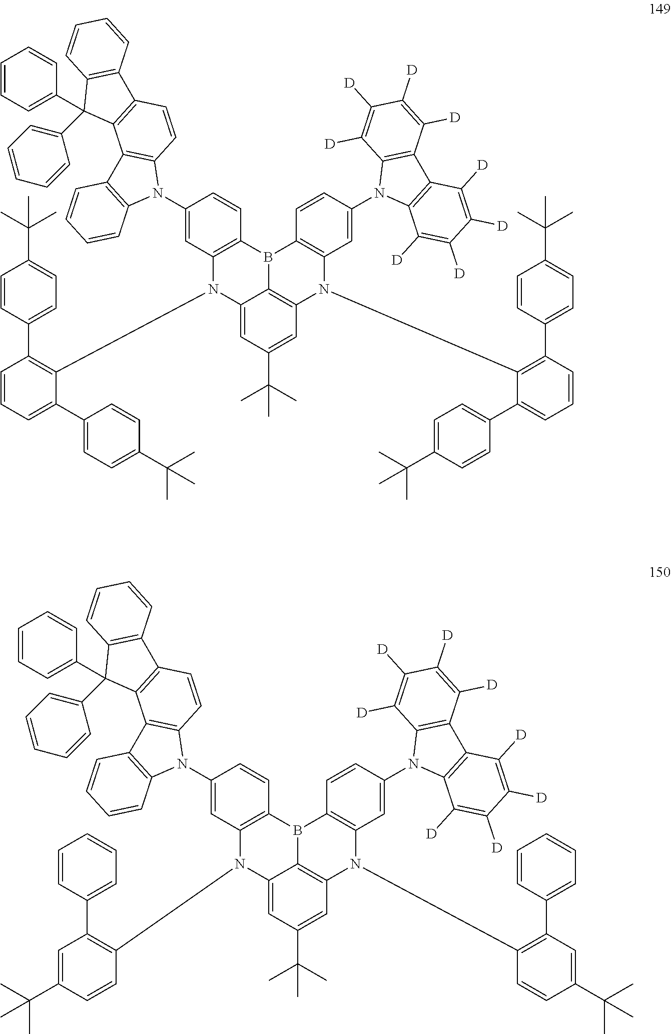 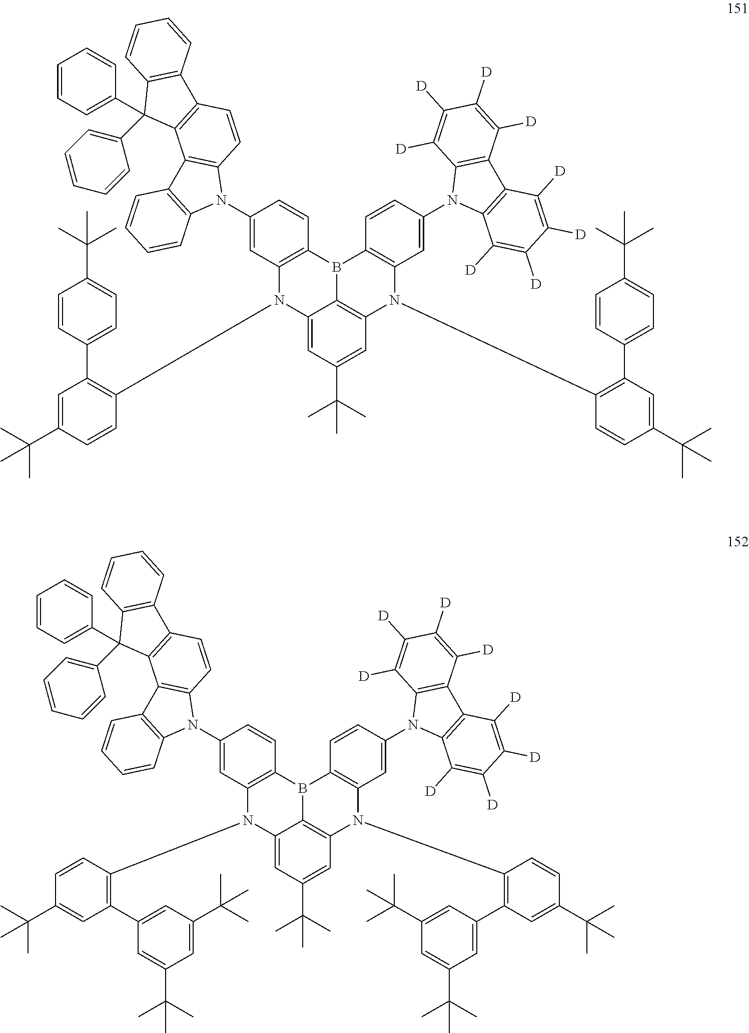 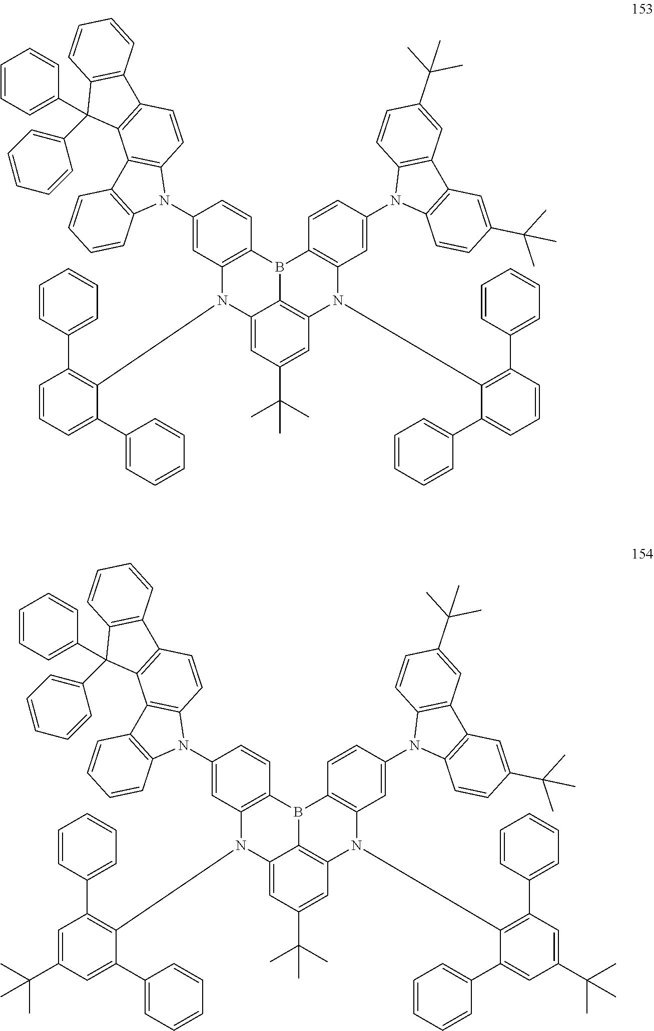 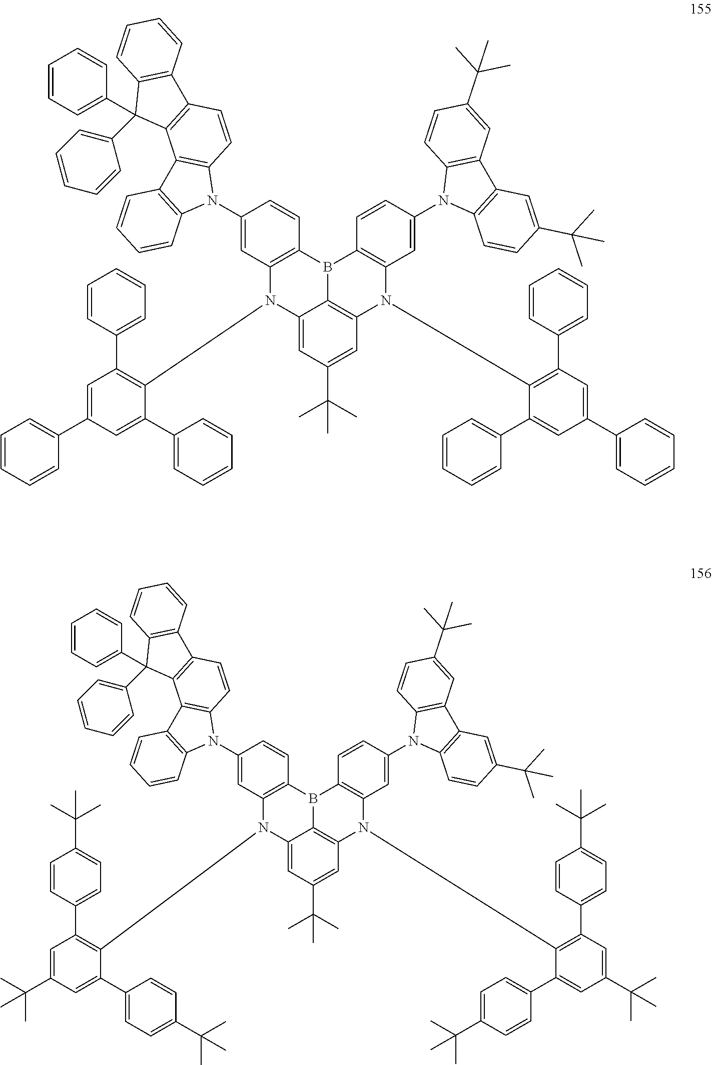 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C6(c4ccccc4)c4ccccc4)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 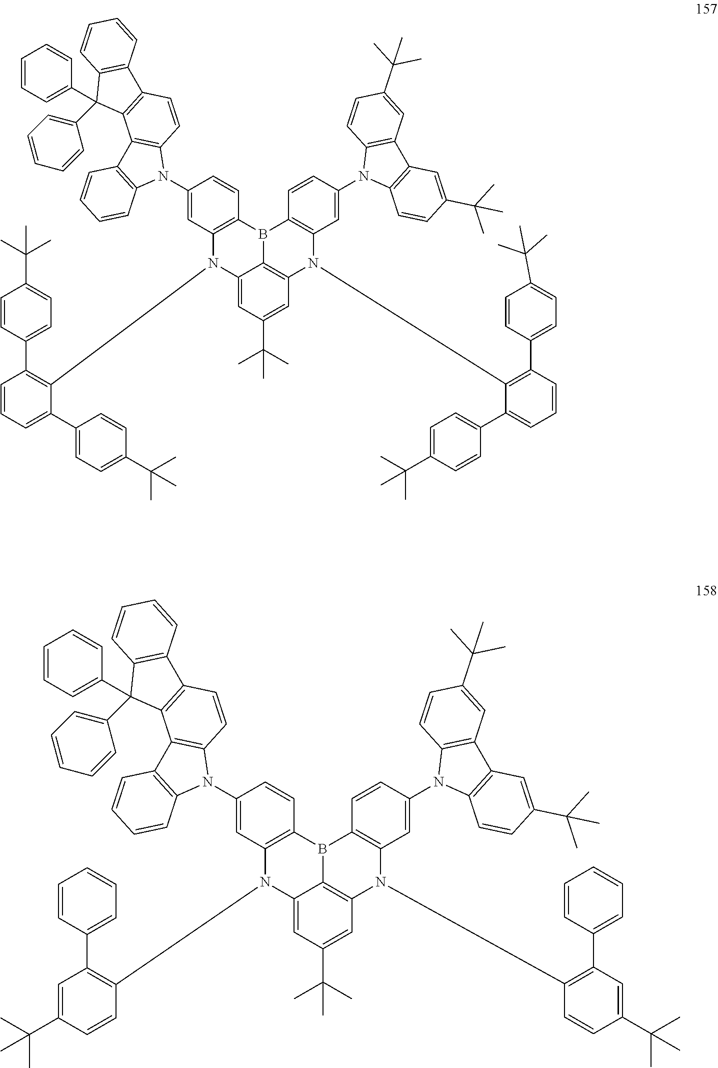 [SMILES: CC(C)(C)c1ccc(-c2cccc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4ccc(C(C)(C)C)cc4-c4ccccc4)c4cc(C(C)(C)C)cc2c43)c(-c2ccccc2)c1] 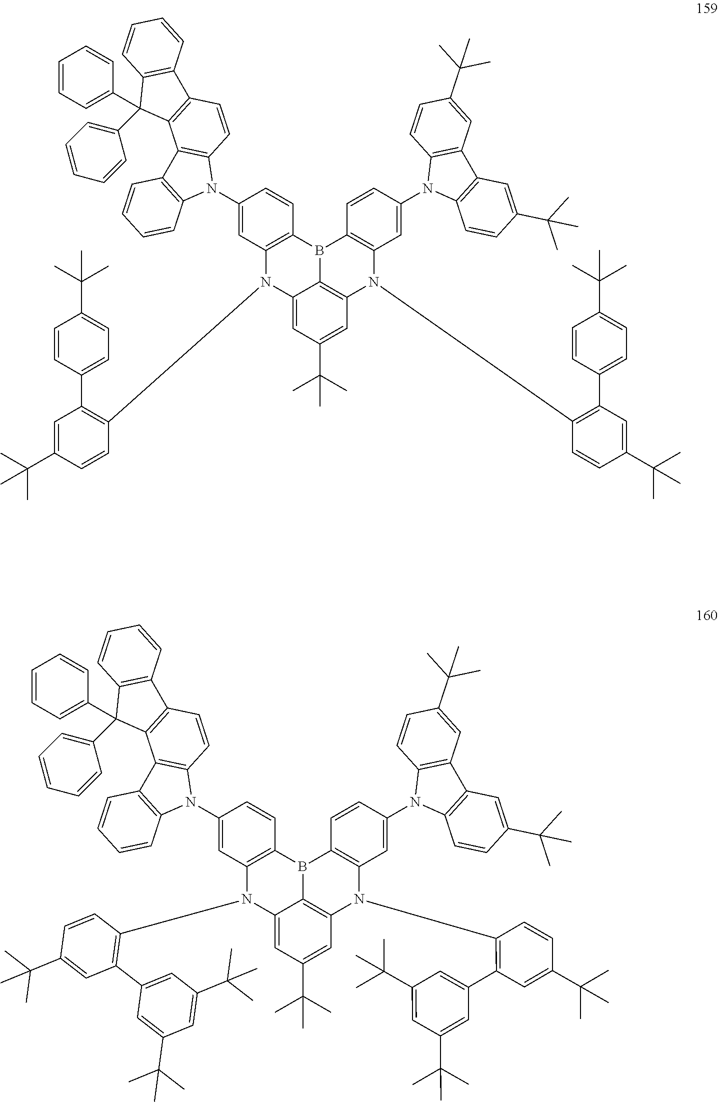 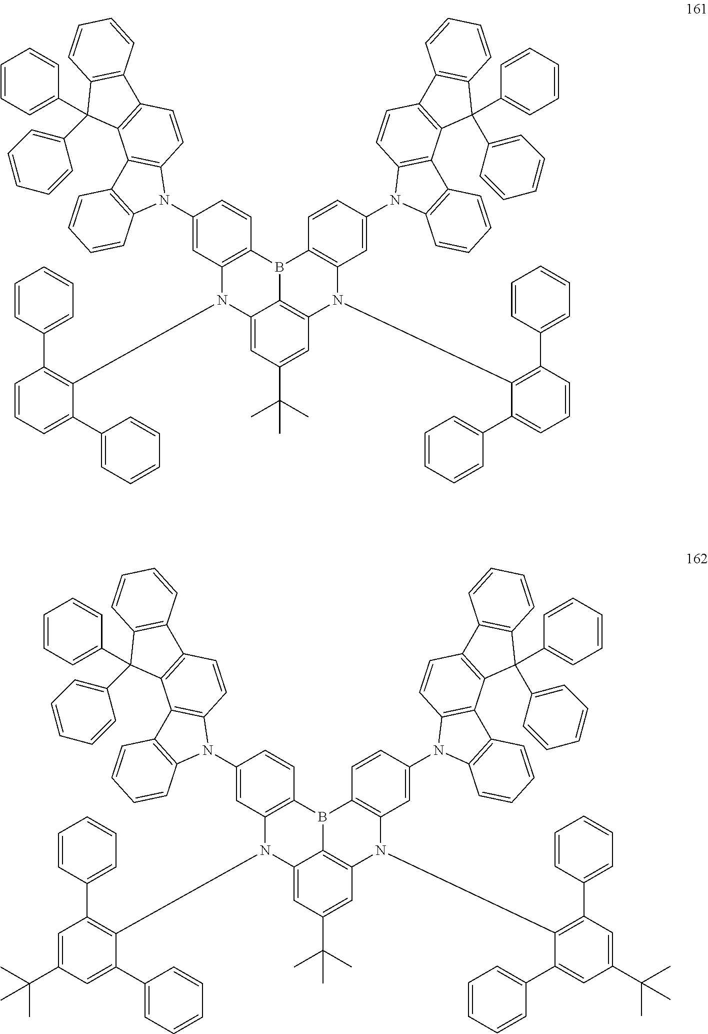 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C6(c4ccccc4)c4ccccc4)ccc1B3c1ccc(-n3c4ccccc4c4c5c(ccc43)-c3ccccc3C5(c3ccccc3)c3ccccc3)cc1N2c1c(-c2ccccc2)cccc1-c1ccccc1 ; CC(C)(C)c1cc(-c2ccccc2)c(N2c3cc(-n4c5ccccc5c5c6c(ccc54)-c4ccccc4C6(c4ccccc4)c4ccccc4)ccc3B3c4ccc(-n5c6ccccc6c6c7c(ccc65)-c5ccccc5C7(c5ccccc5)c5ccccc5)cc4N(c4c(-c5ccccc5)cc(C(C)(C)C)cc4-c4ccccc4)c4cc(C(C)(C)C)cc2c43)c(-c2ccccc2)c1] 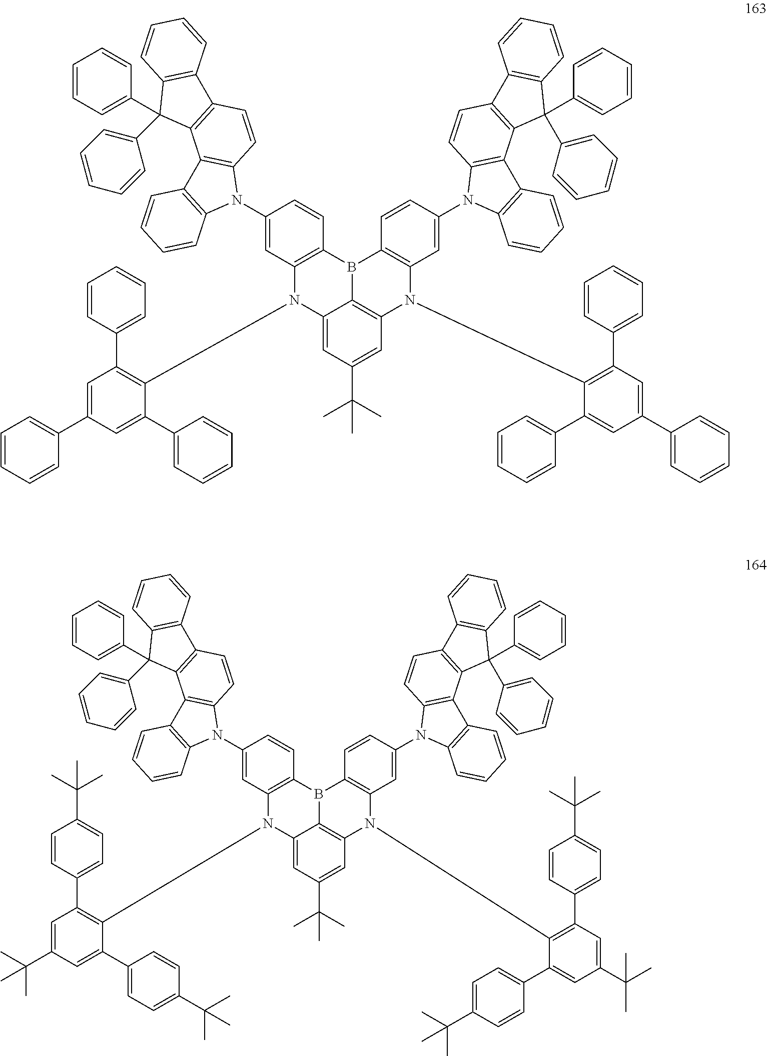 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C6(c4ccccc4)c4ccccc4)ccc1B3c1ccc(-n3c4ccccc4c4c5c(ccc43)-c3ccccc3C5(c3ccccc3)c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5c6c(ccc54)-c4ccccc4C6(c4ccccc4)c4ccccc4)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 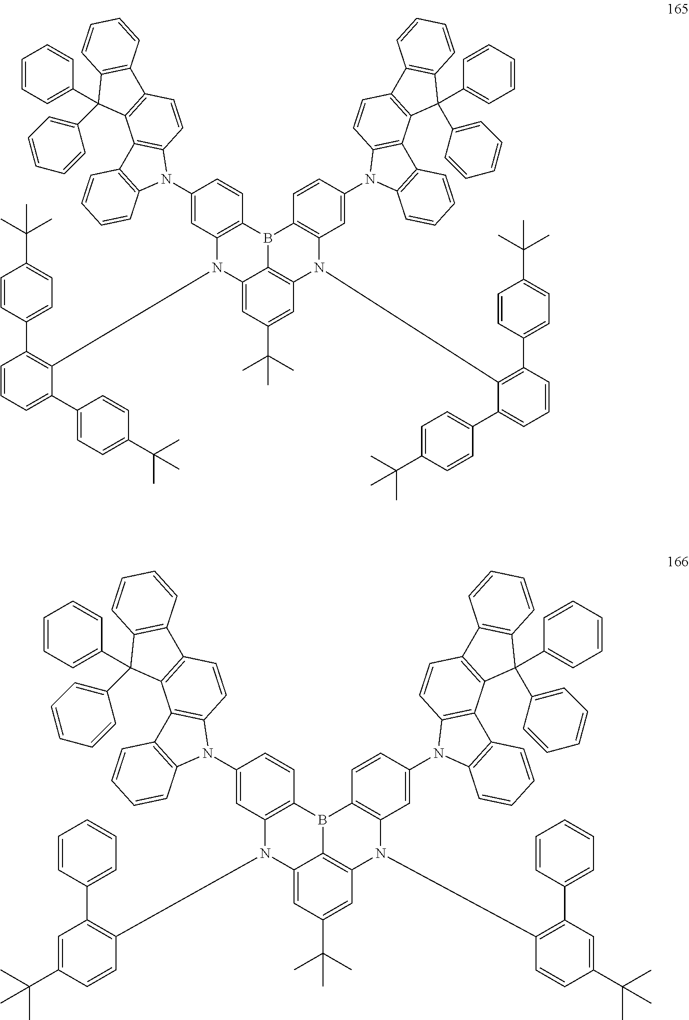 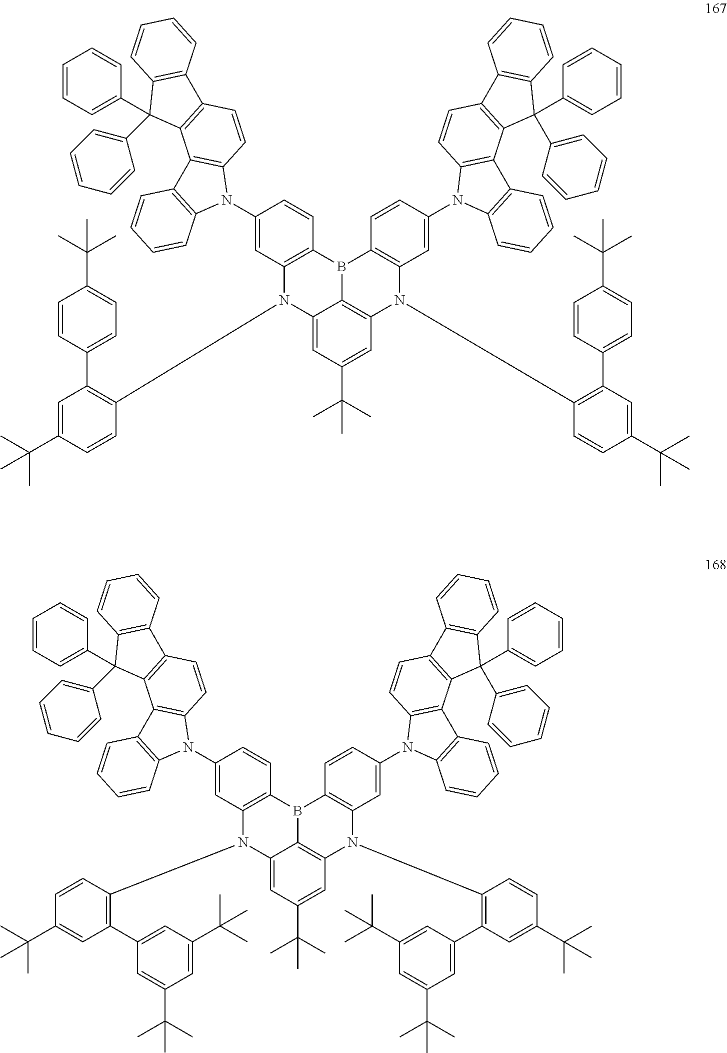 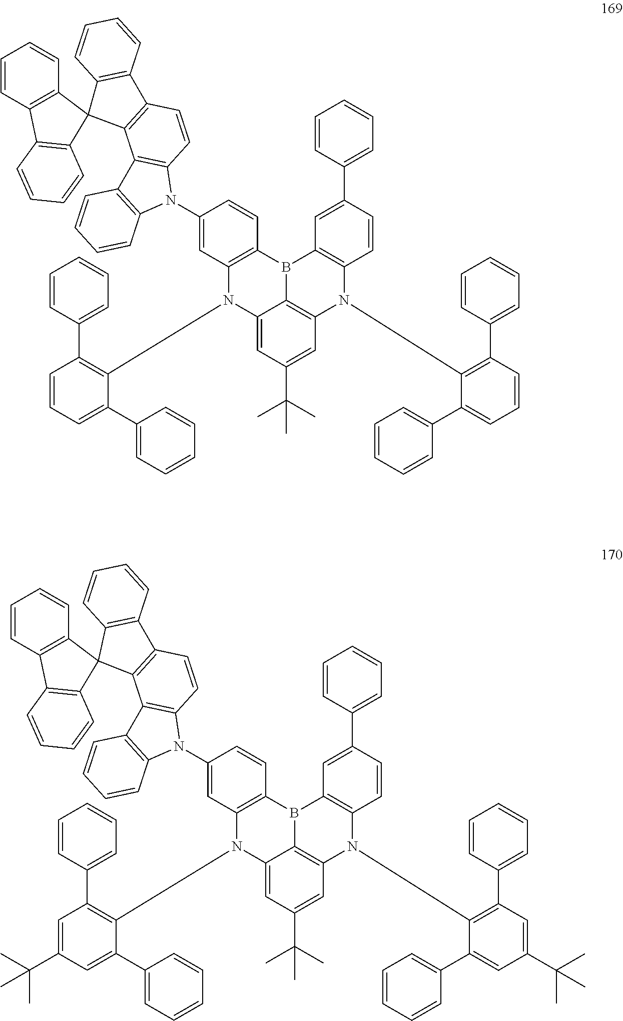 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1cc(-c3ccccc3)ccc1N2c1c(-c2ccccc2)cccc1-c1ccccc1 ; CC(C)(C)c1cc(-c2ccccc2)c(N2c3ccc(-c4ccccc4)cc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 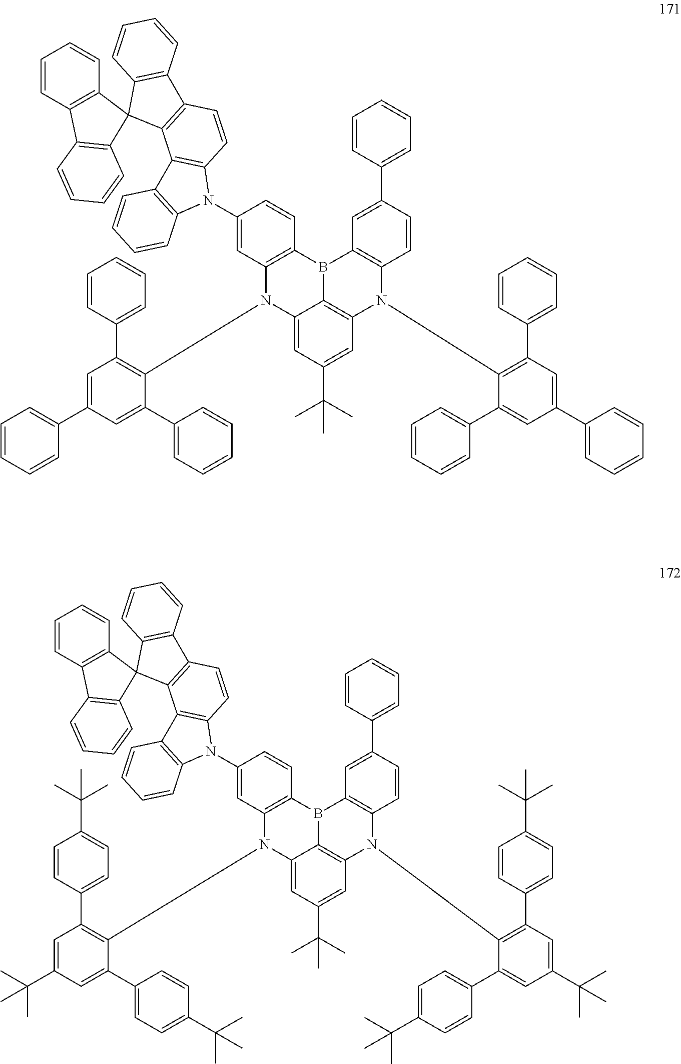 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1cc(-c3ccccc3)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4ccccc4)cc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 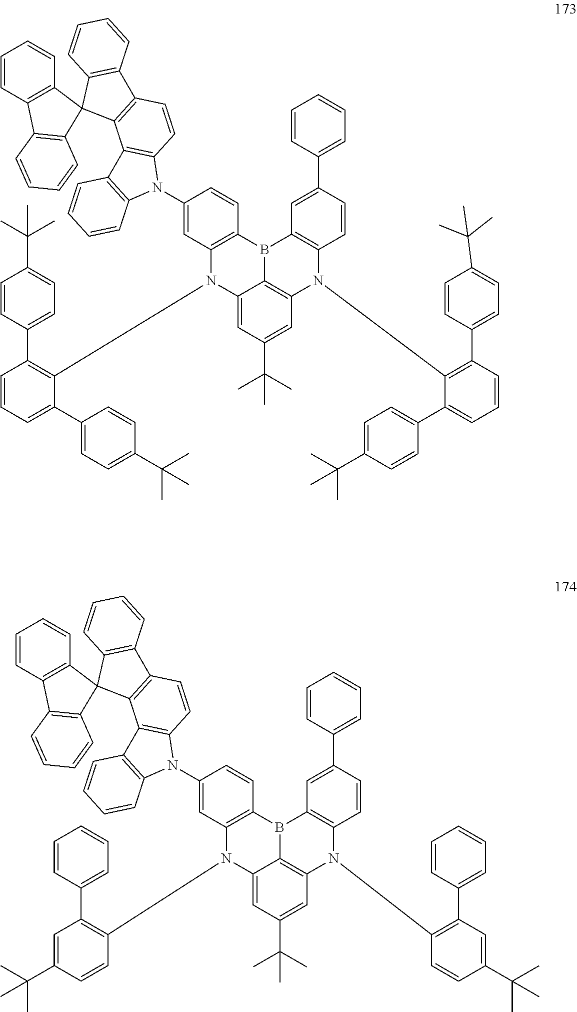 [SMILES: CC(C)(C)c1ccc(-c2cccc(-c3ccc(C(C)(C)C)cc3)c2N2c3ccc(-c4ccccc4)cc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3ccc(-c4ccccc4)cc3B3c4ccc(-n5c6ccccc6c6c7c(ccc65)-c5ccccc5C75c6ccccc6-c6ccccc65)cc4N(c4ccc(C(C)(C)C)cc4-c4ccccc4)c4cc(C(C)(C)C)cc2c43)c(-c2ccccc2)c1] 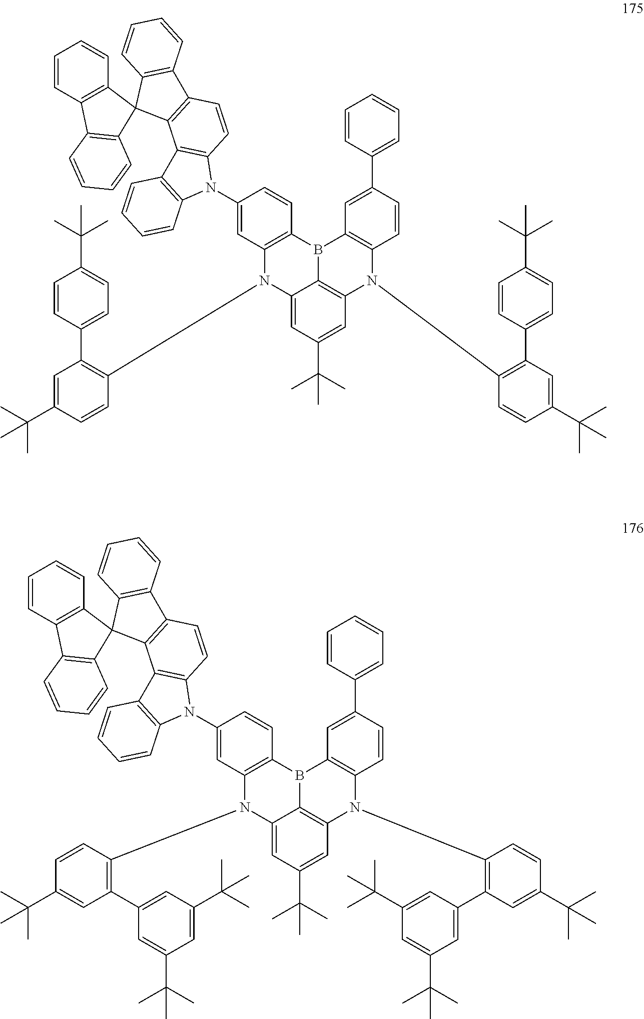 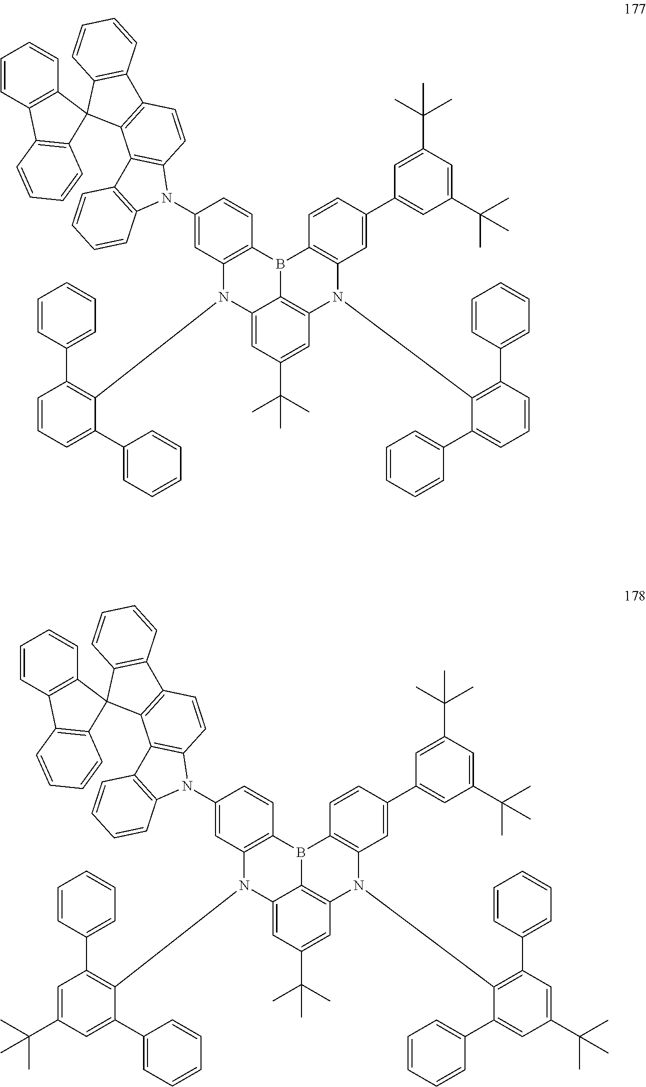 [SMILES: CC(C)(C)c1cc(-c2ccc3c(c2)N(c2c(-c4ccccc4)cccc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2c(-c3ccccc3)cccc2-c2ccccc2)cc(C(C)(C)C)c1 ; CC(C)(C)c1cc(-c2ccc3c(c2)N(c2c(-c4ccccc4)cc(C(C)(C)C)cc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2c(-c3ccccc3)cc(C(C)(C)C)cc2-c2ccccc2)cc(C(C)(C)C)c1] 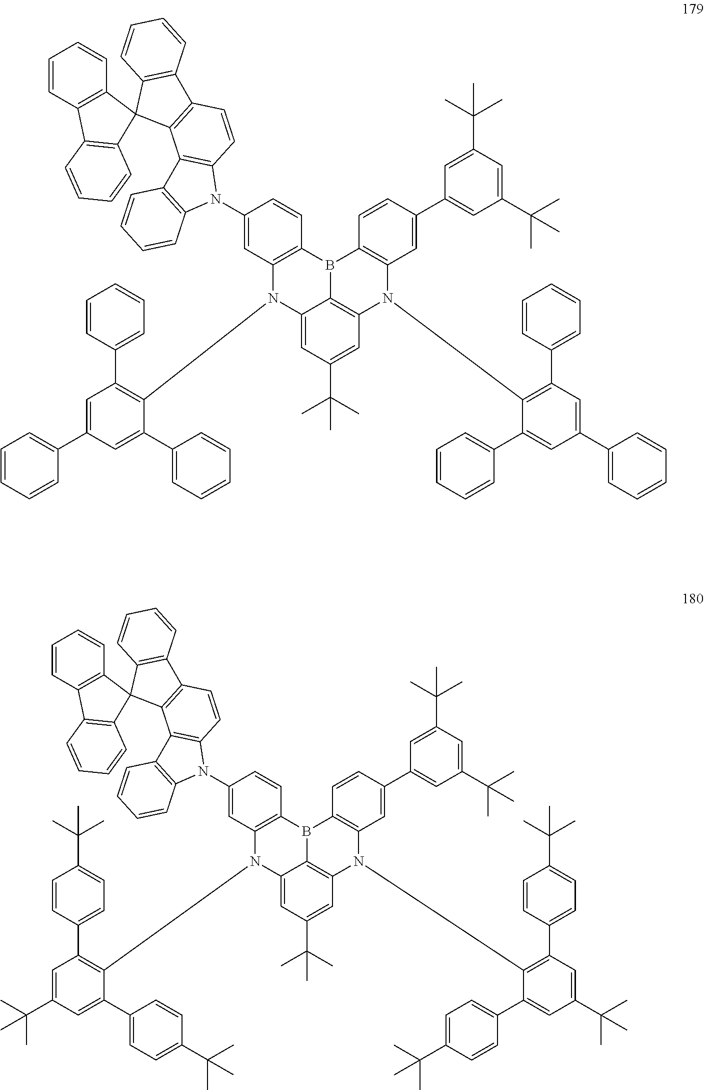 [SMILES: CC(C)(C)c1cc(-c2ccc3c(c2)N(c2c(-c4ccccc4)cc(-c4ccccc4)cc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2c(-c3ccccc3)cc(-c3ccccc3)cc2-c2ccccc2)cc(C(C)(C)C)c1 ; CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 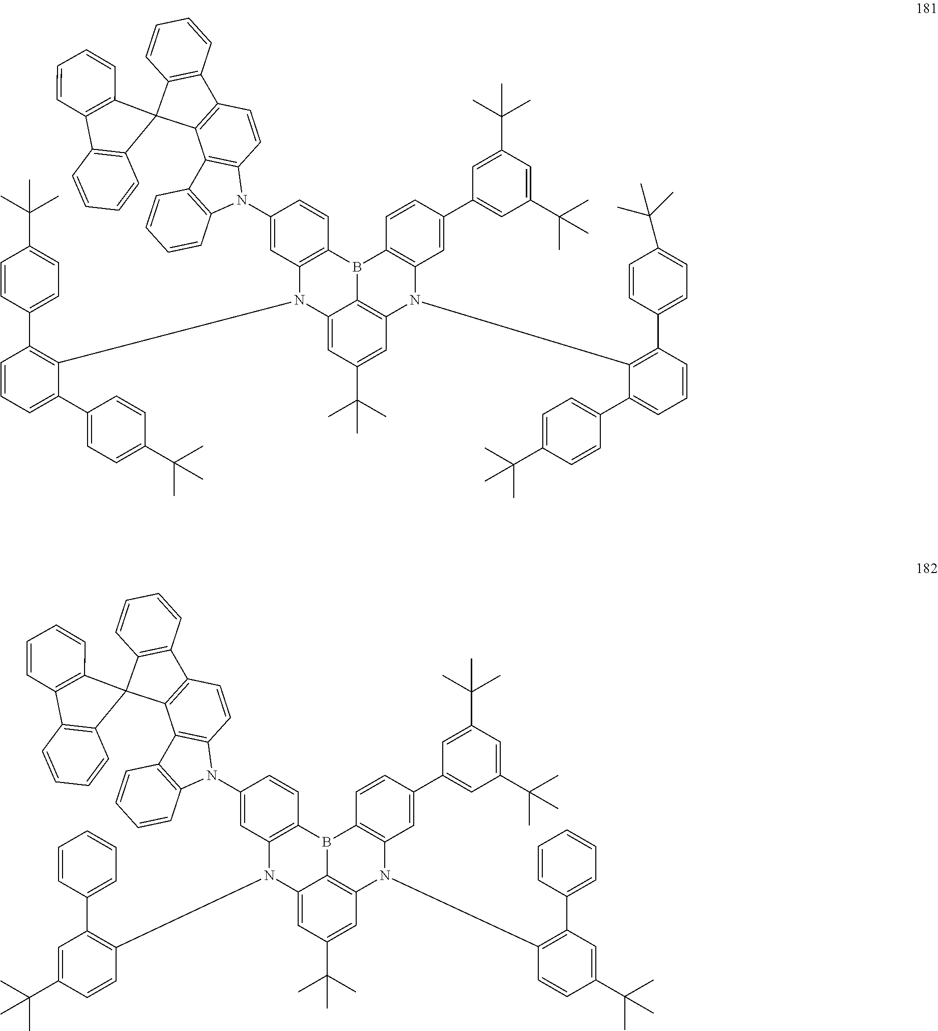 [SMILES: CC(C)(C)c1ccc(-c2cccc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1cc(-c2ccc3c(c2)N(c2ccc(C(C)(C)C)cc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2ccc(C(C)(C)C)cc2-c2ccccc2)cc(C(C)(C)C)c1] 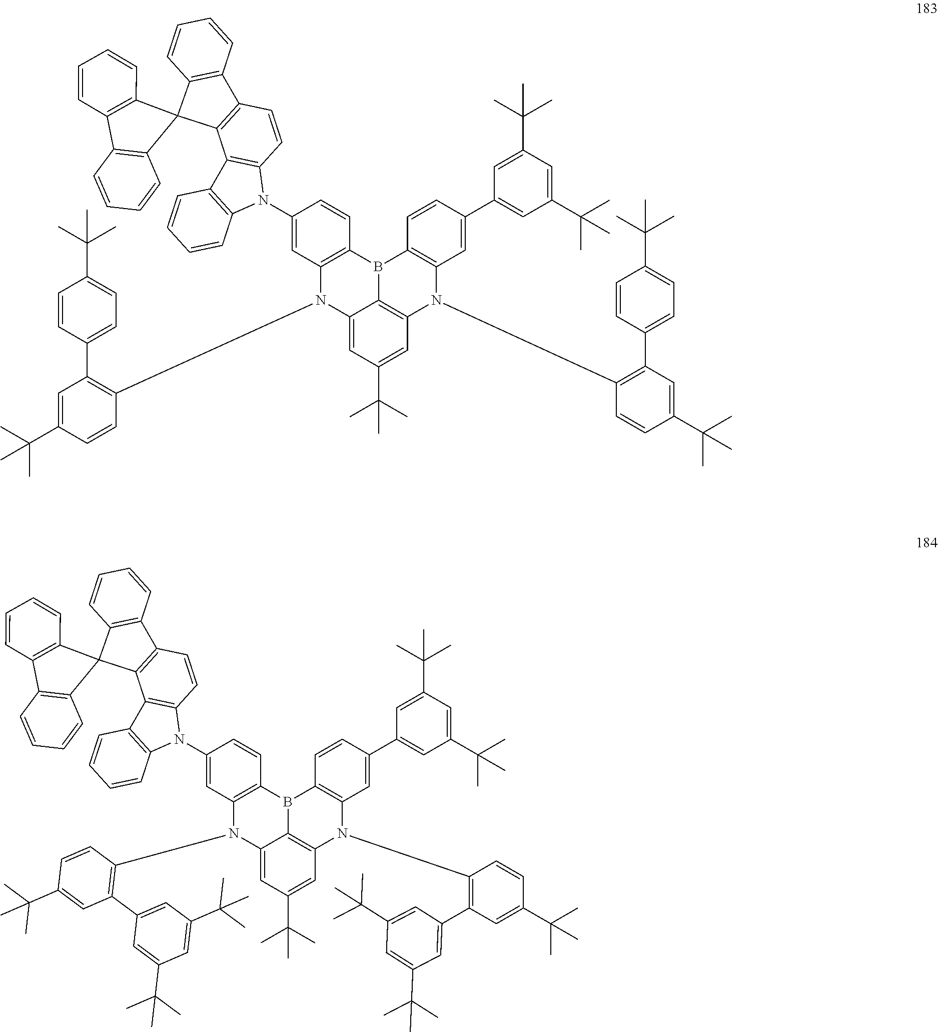 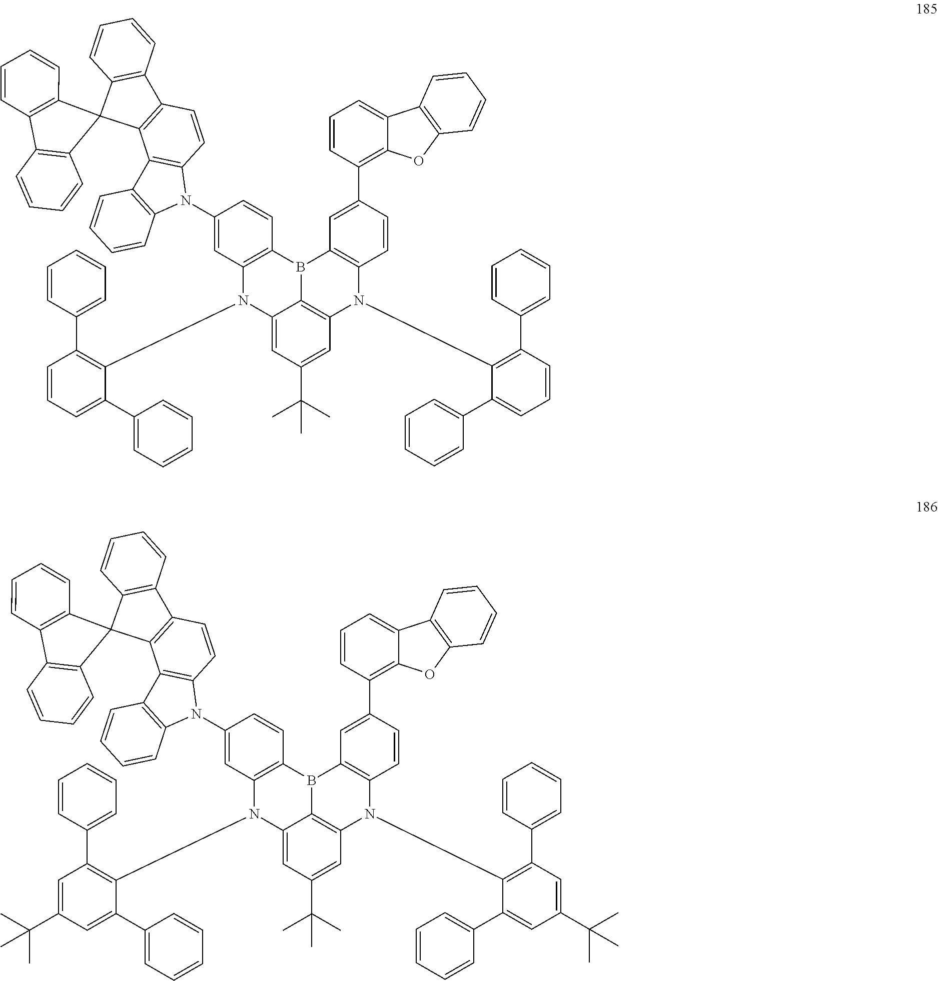 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1cc(-c3cccc4c3oc3ccccc34)ccc1N2c1c(-c2ccccc2)cccc1-c1ccccc1 ; CC(C)(C)c1cc(-c2ccccc2)c(N2c3ccc(-c4cccc5c4oc4ccccc45)cc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 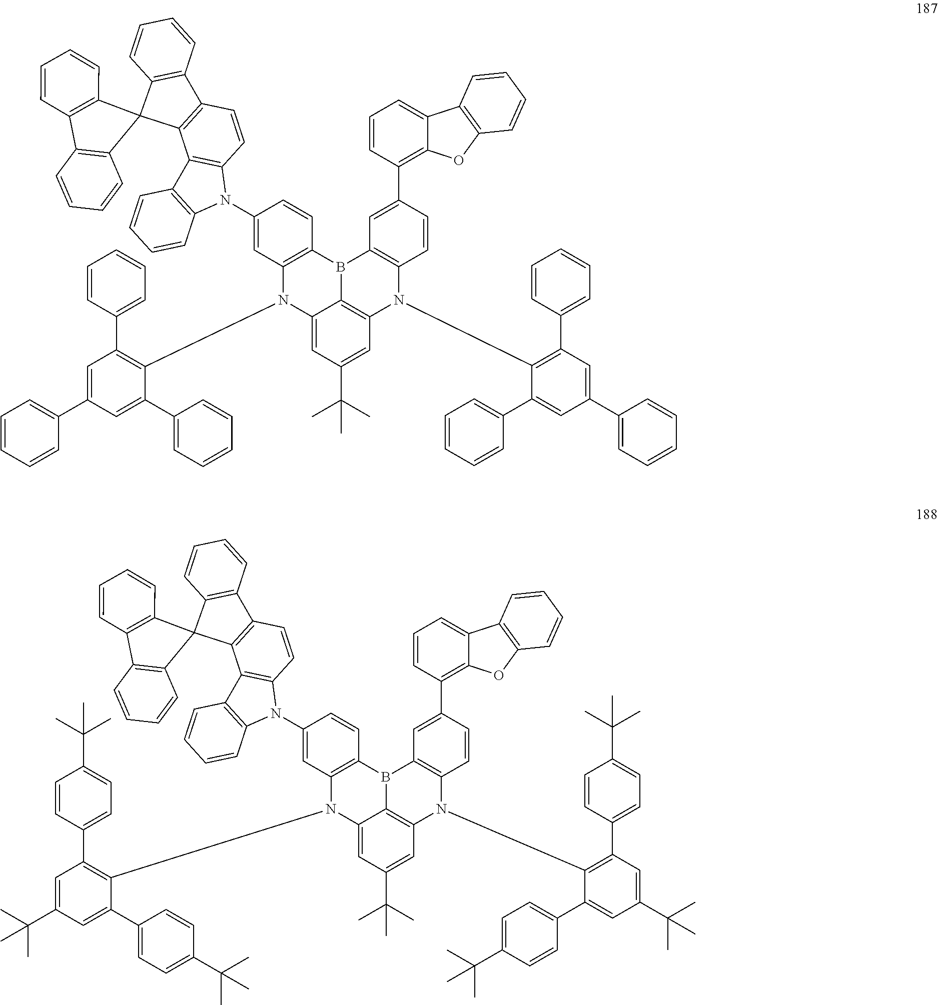 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1cc(-c3cccc4c3oc3ccccc34)ccc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3ccc(-c4cccc5c4oc4ccccc45)cc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 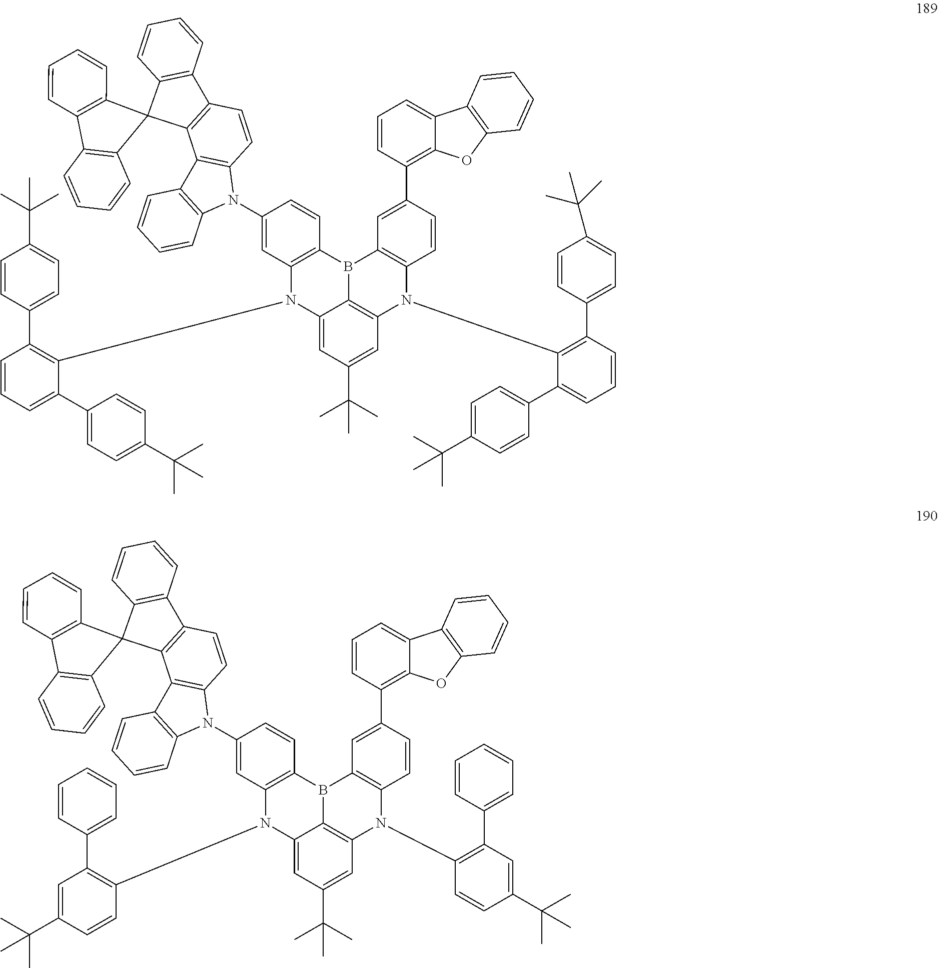 [SMILES: CC(C)(C)c1ccc(-c2cccc(-c3ccc(C(C)(C)C)cc3)c2N2c3ccc(-c4cccc5c4oc4ccccc45)cc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3ccc(-c4cccc5c4oc4ccccc45)cc3B3c4ccc(-n5c6ccccc6c6c7c(ccc65)-c5ccccc5C75c6ccccc6-c6ccccc65)cc4N(c4ccc(C(C)(C)C)cc4-c4ccccc4)c4cc(C(C)(C)C)cc2c43)c(-c2ccccc2)c1] 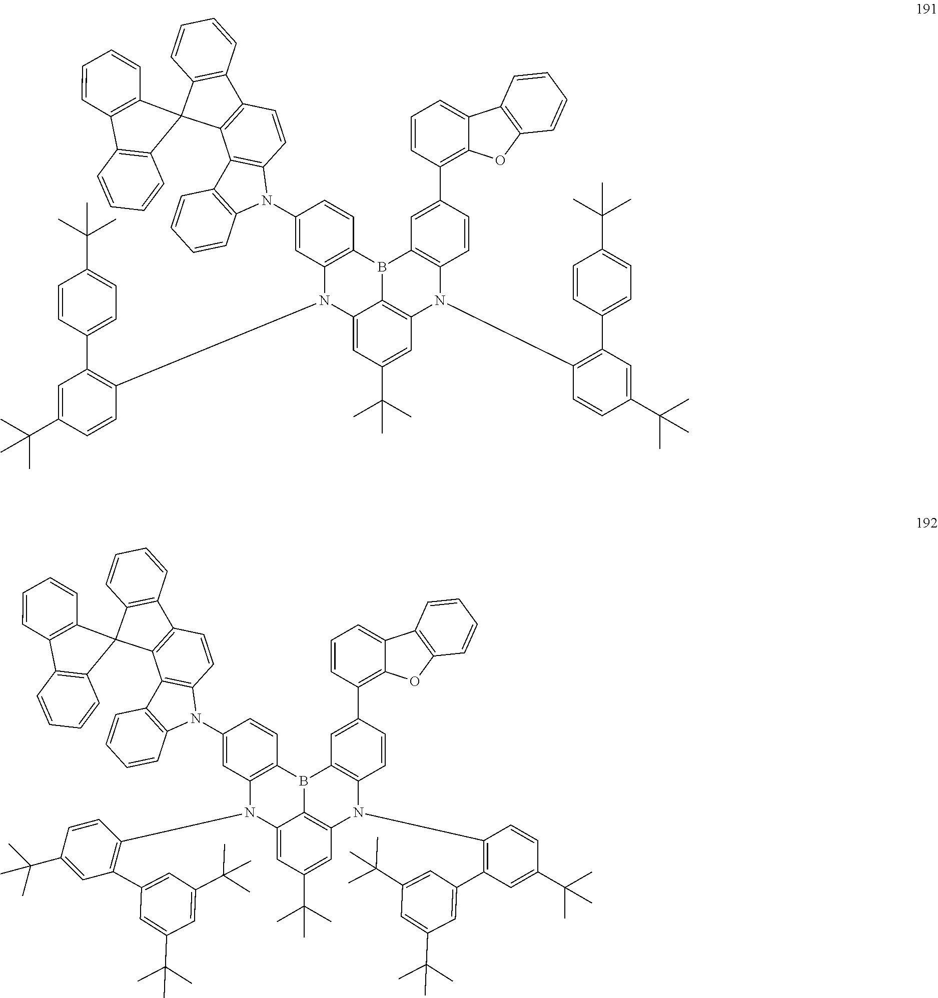 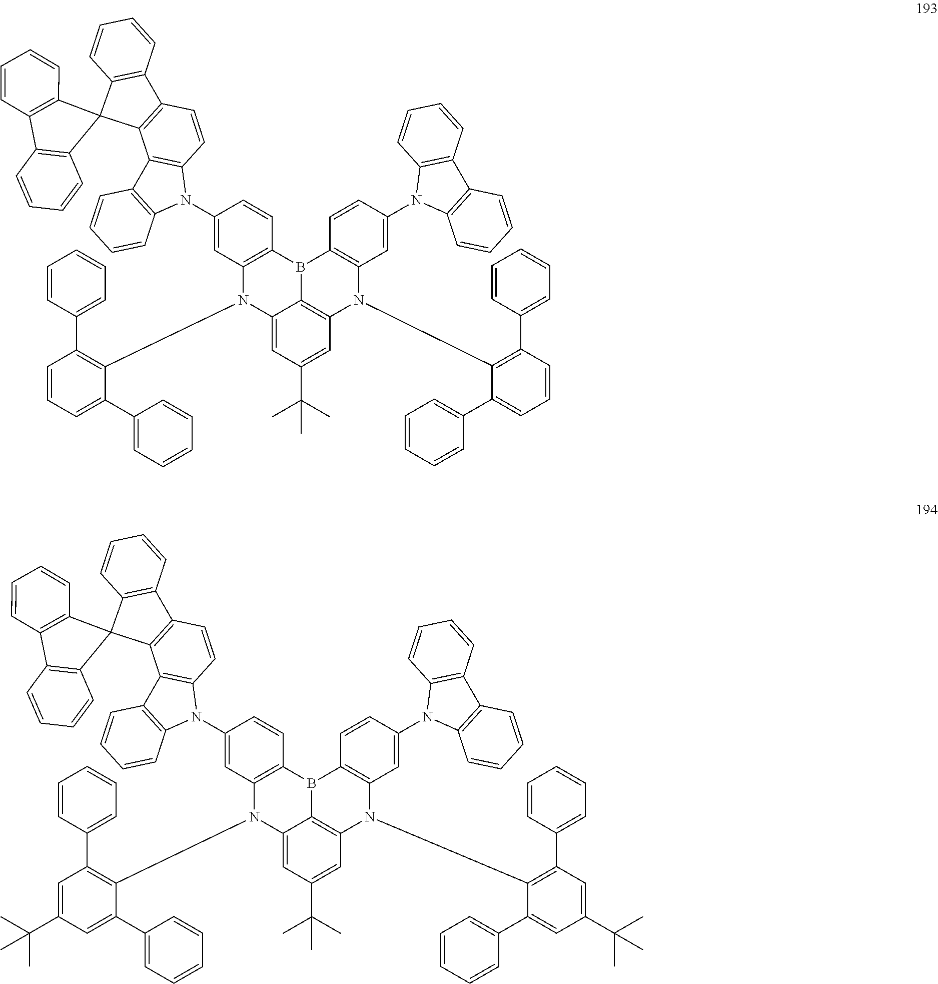 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccccc4c4ccccc43)cc1N2c1c(-c2ccccc2)cccc1-c1ccccc1 ; CC(C)(C)c1cc(-c2ccccc2)c(N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 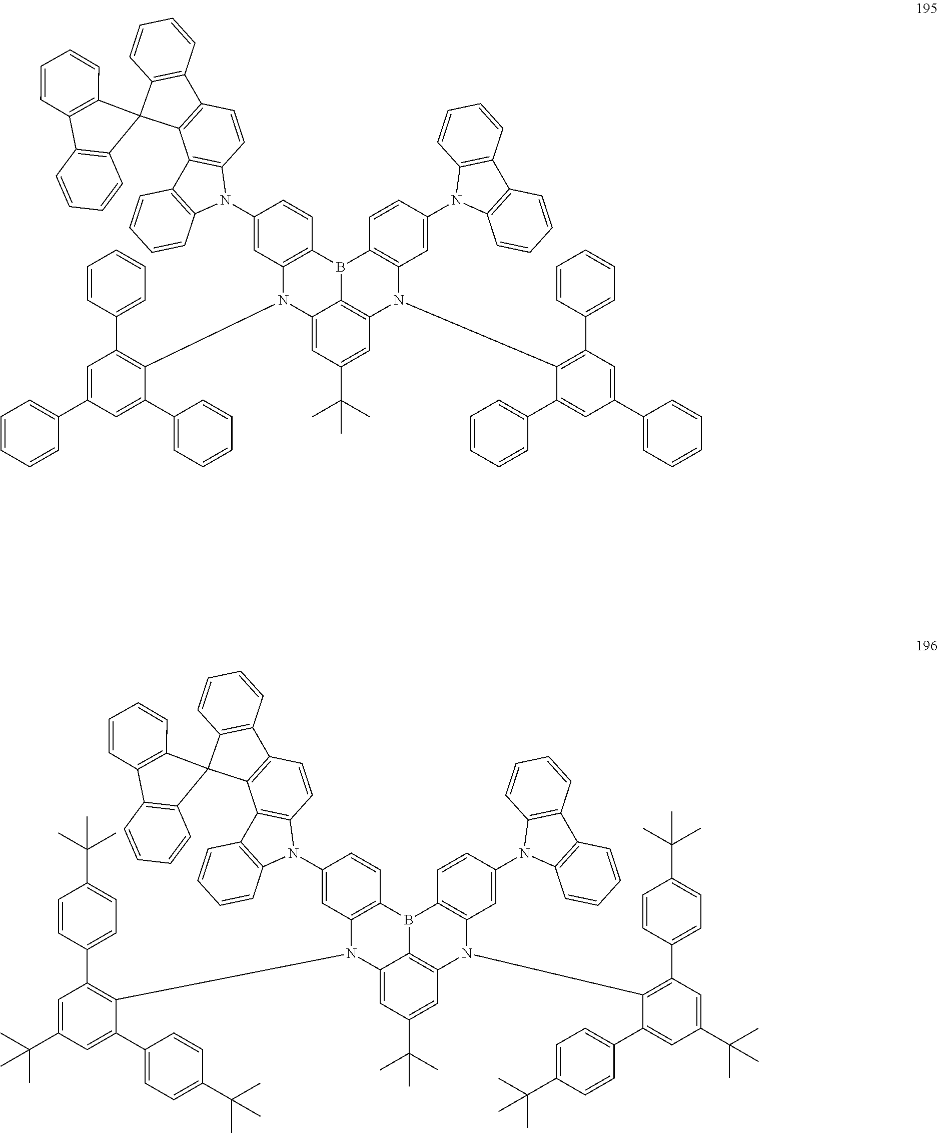 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1ccc(-n3c4ccccc4c4ccccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 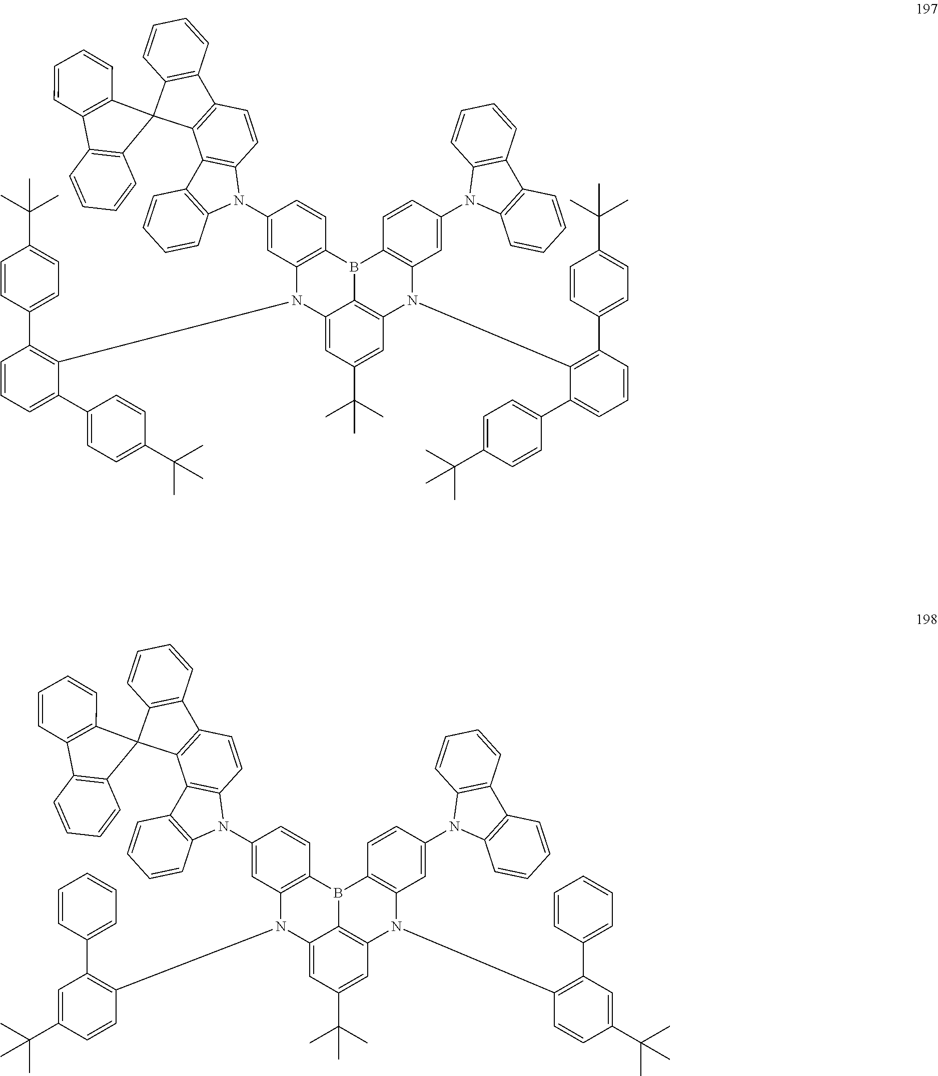 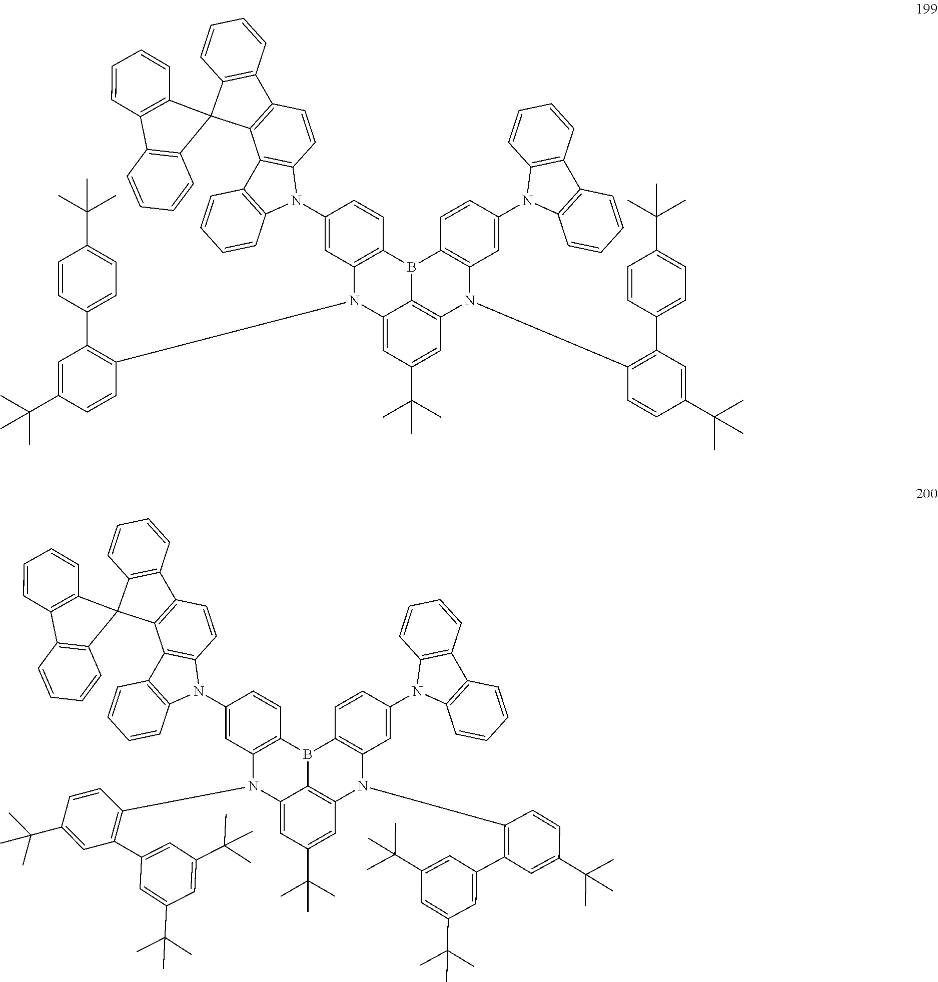 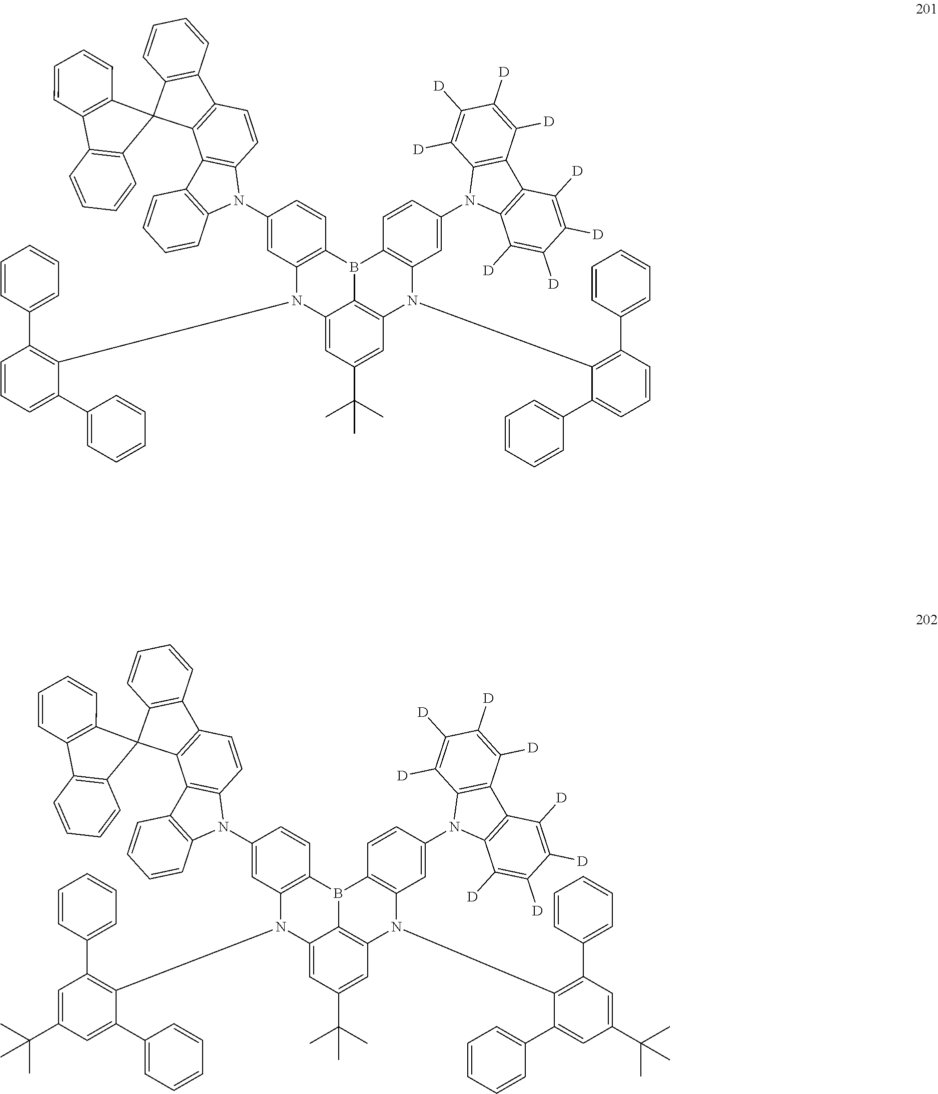 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cc(C(C)(C)C)cc1-c1ccccc1] 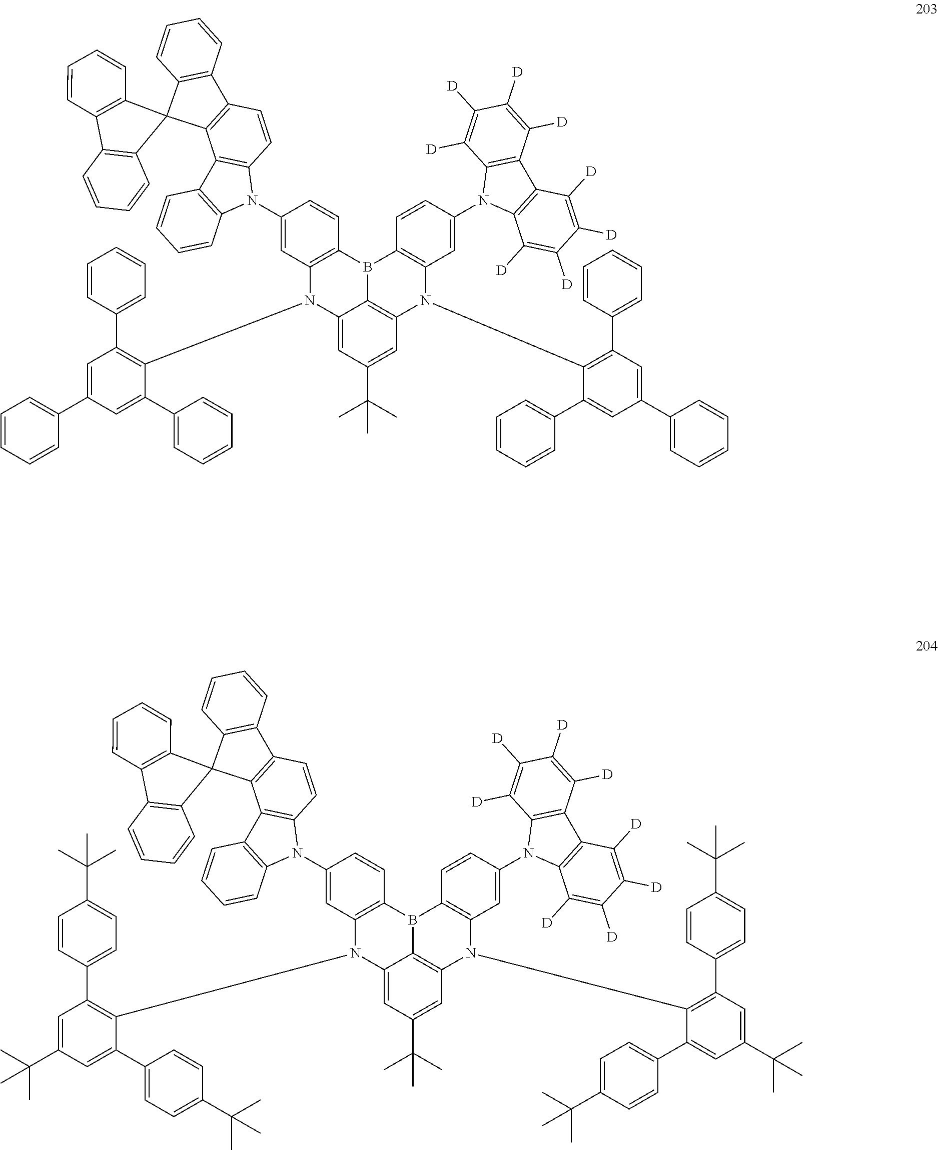 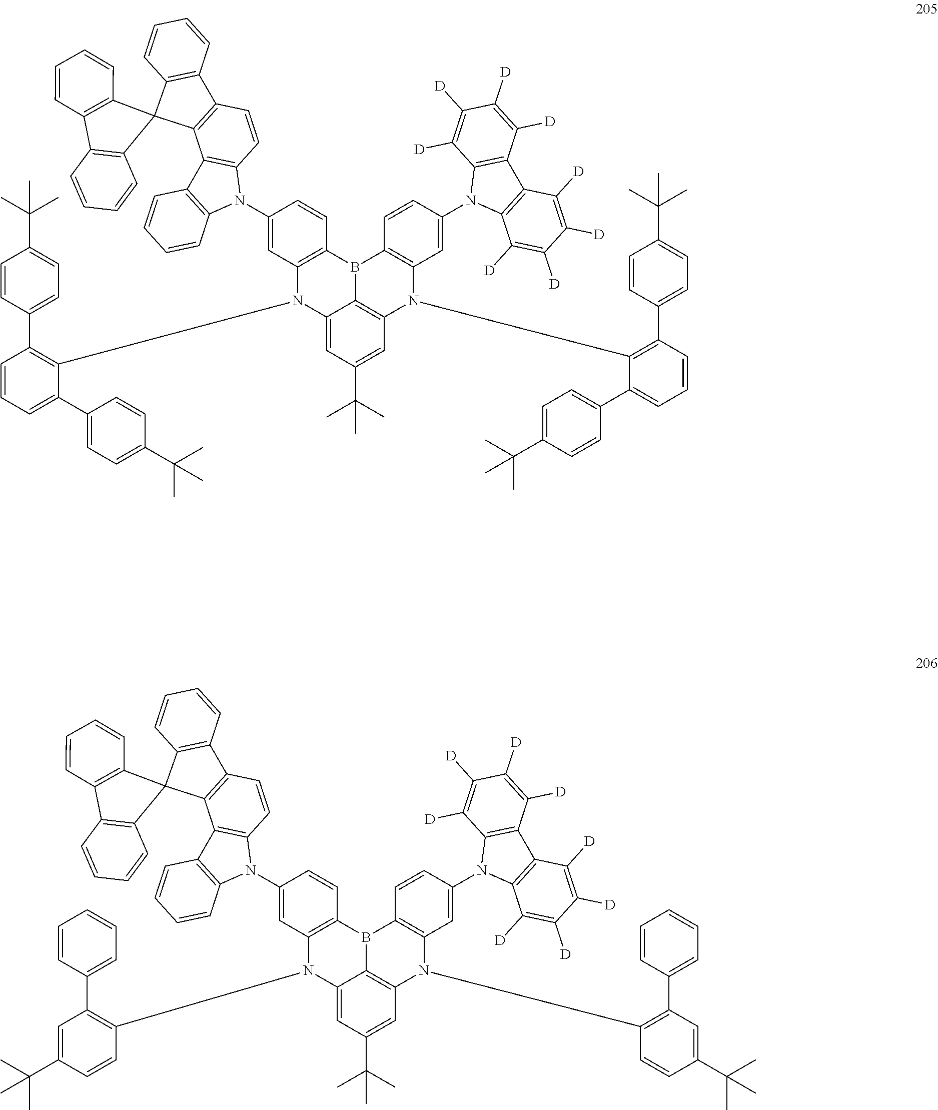 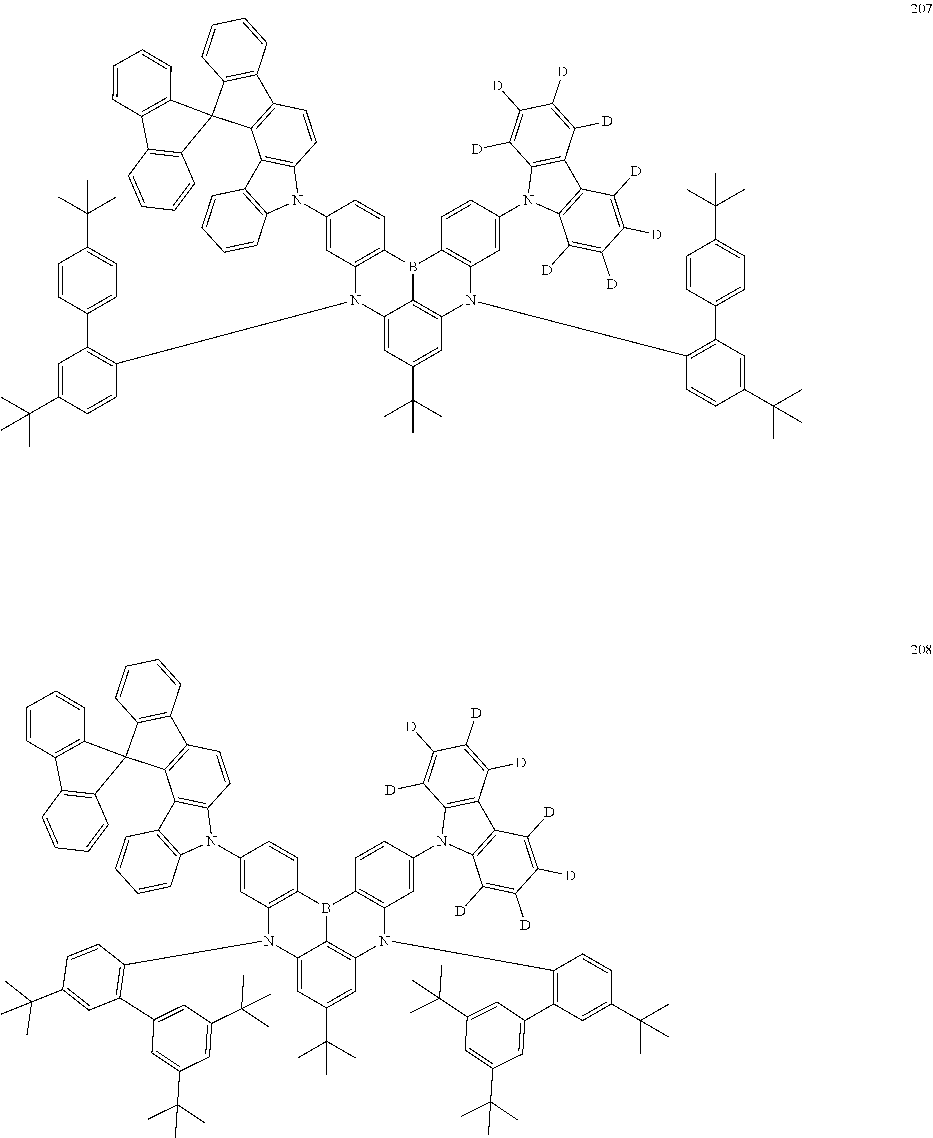 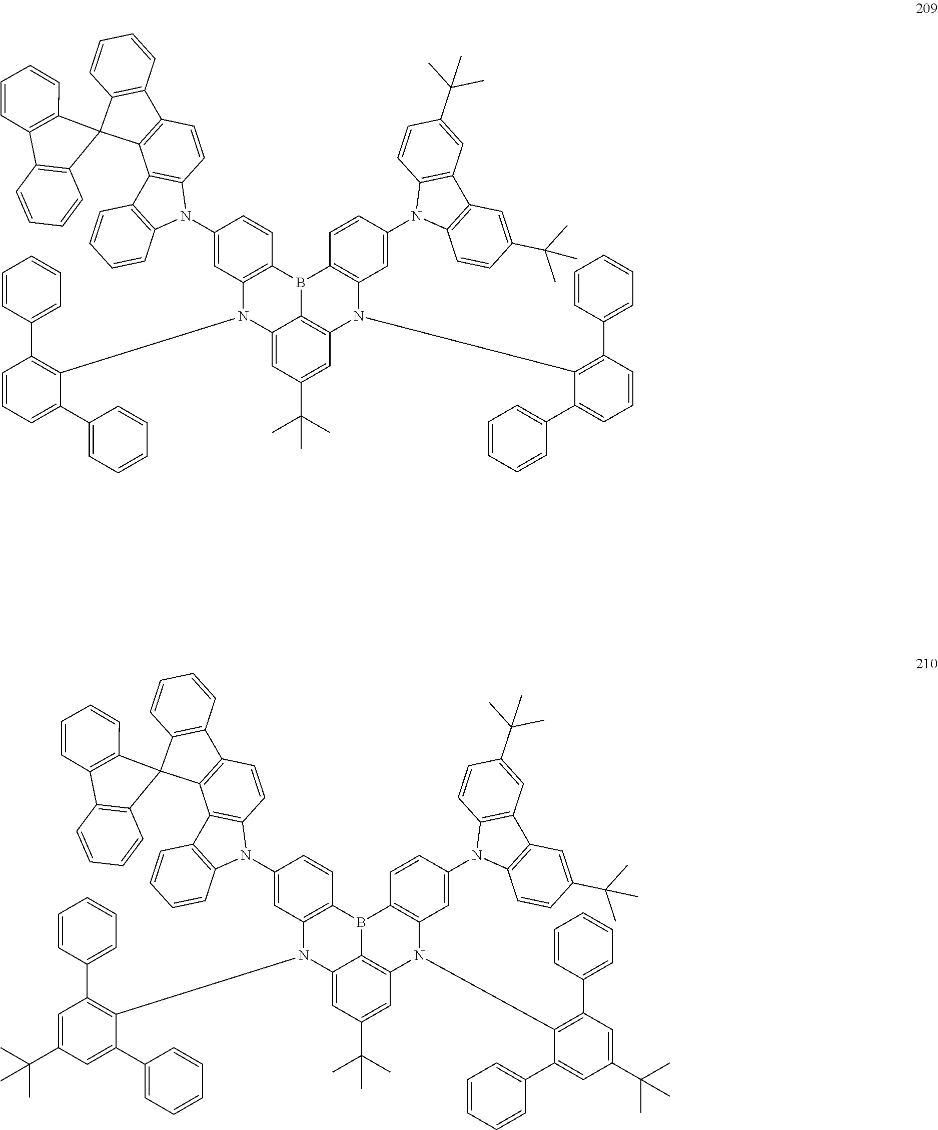 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccc(C(C)(C)C)cc4c4cc(C(C)(C)C)ccc43)cc1N2c1c(-c2ccccc2)cccc1-c1ccccc1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 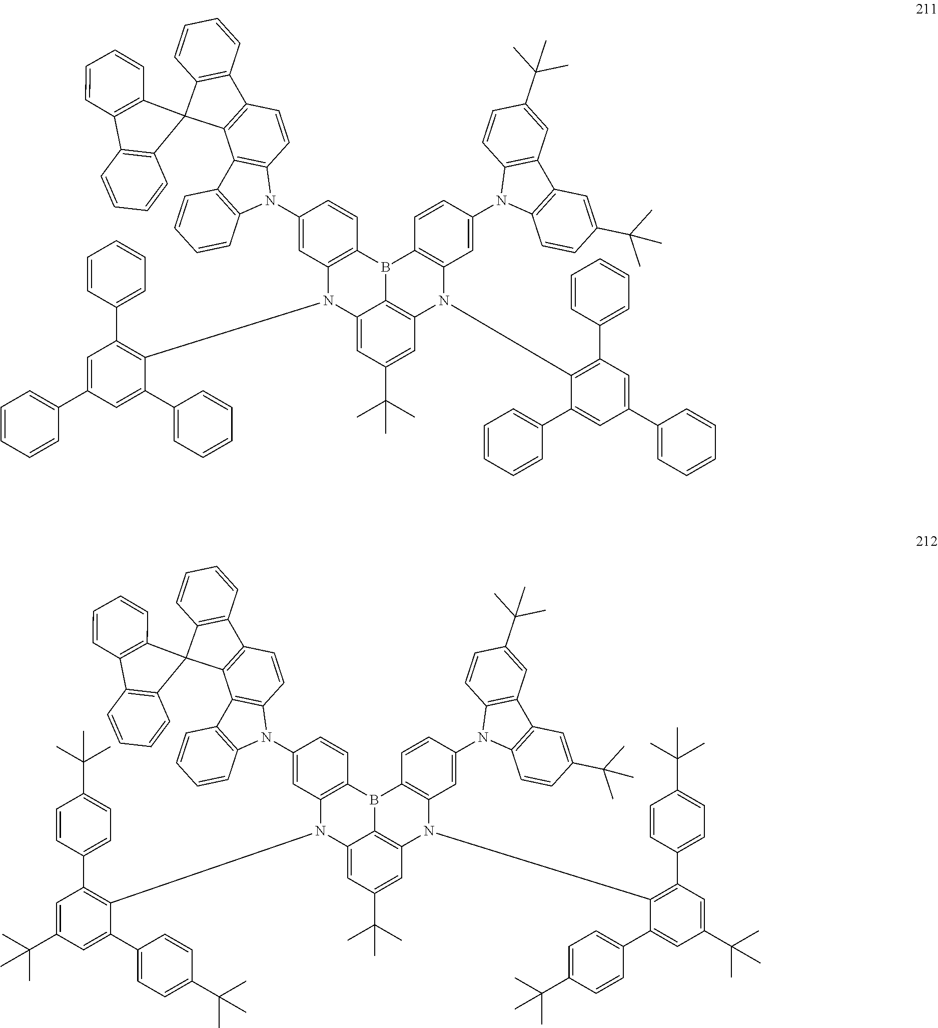 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 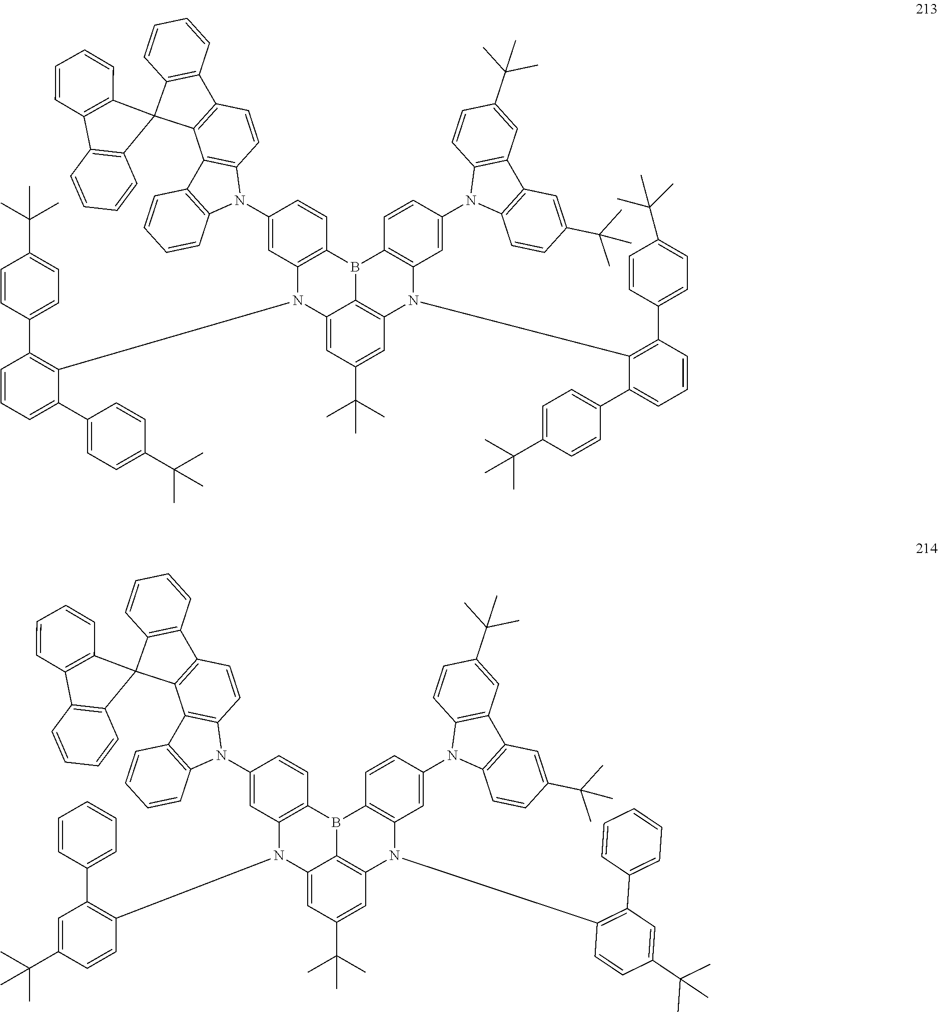 [SMILES: CC(C)(C)c1ccc(-c2cccc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4ccc(C(C)(C)C)cc4-c4ccccc4)c4cc(C(C)(C)C)cc2c43)c(-c2ccccc2)c1] 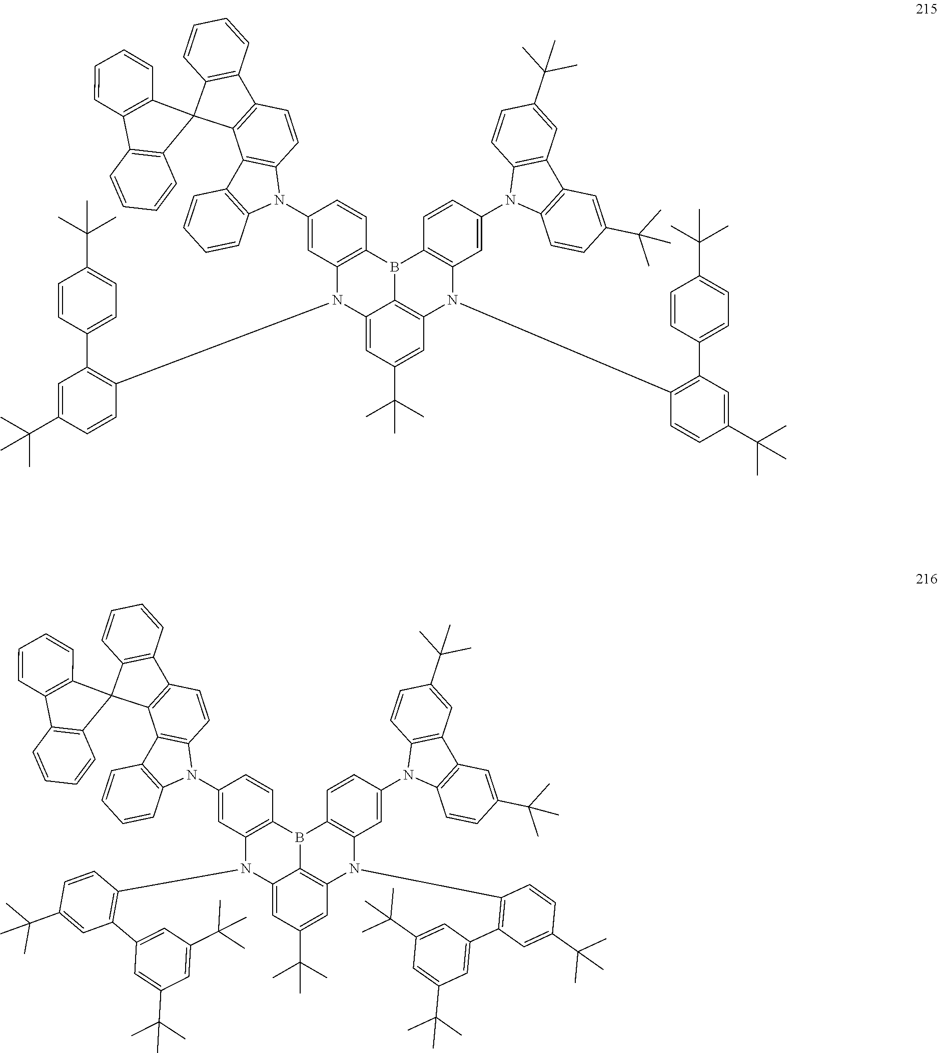 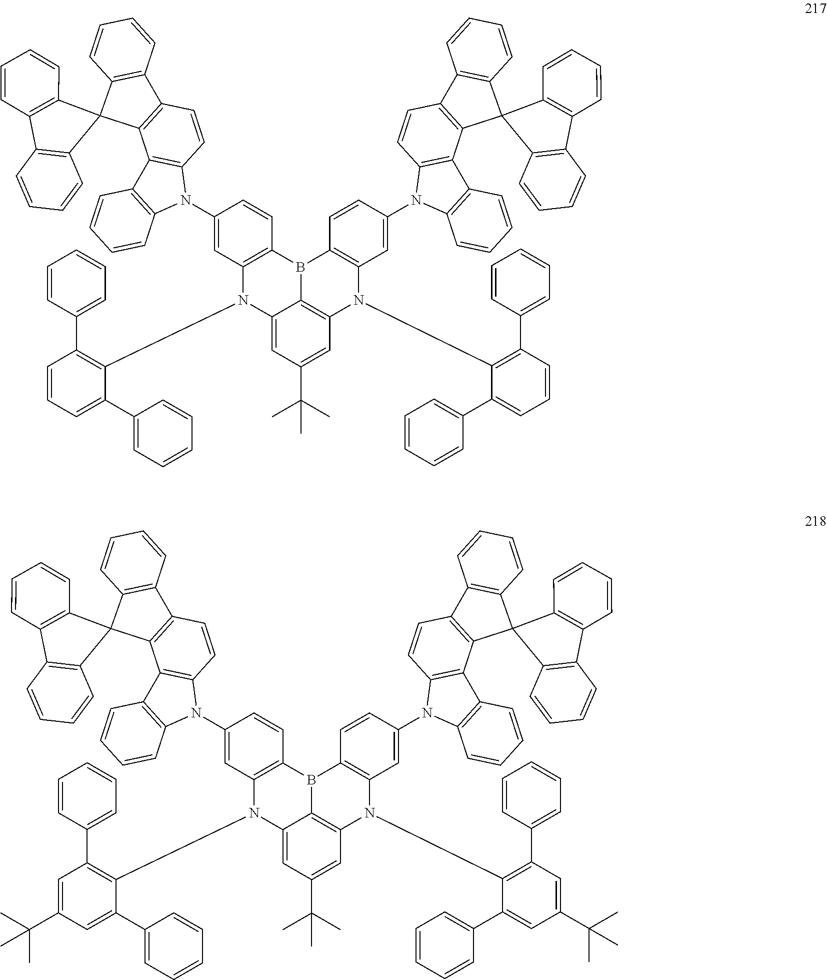 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccccc4c4c5c(ccc43)-c3ccccc3C53c4ccccc4-c4ccccc43)cc1N2c1c(-c2ccccc2)cccc1-c1ccccc1 ; CC(C)(C)c1cc(-c2ccccc2)c(N2c3cc(-n4c5ccccc5c5c6c(ccc54)-c4ccccc4C64c5ccccc5-c5ccccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 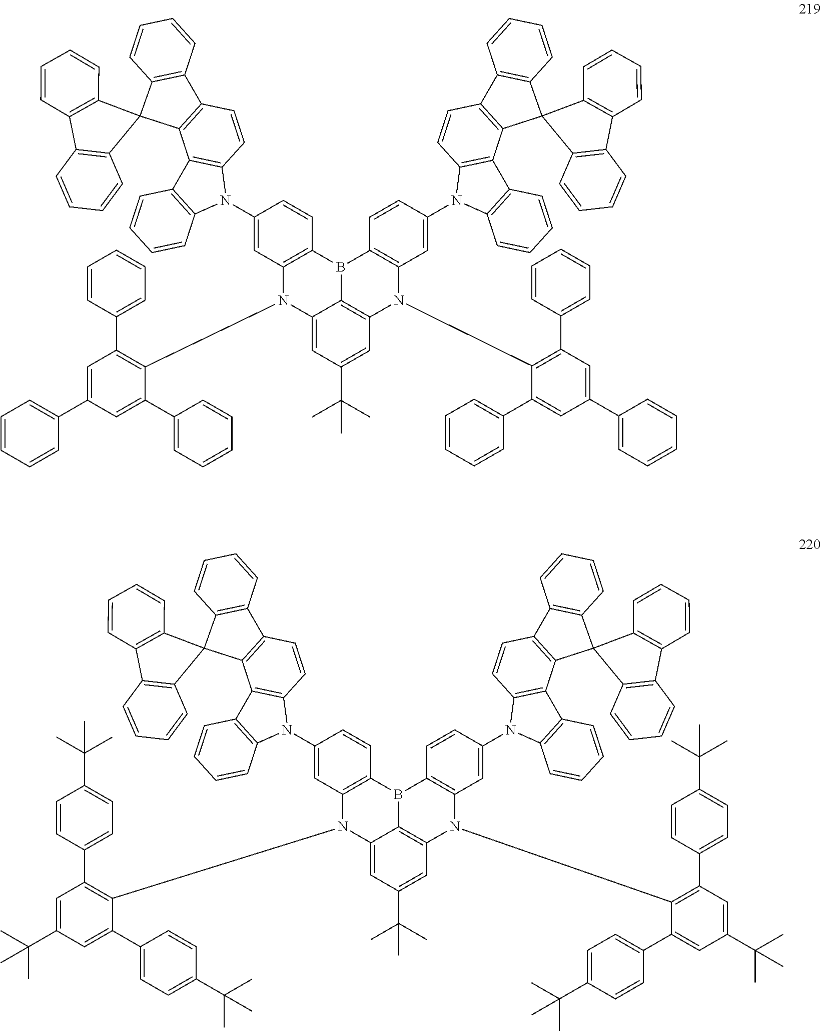 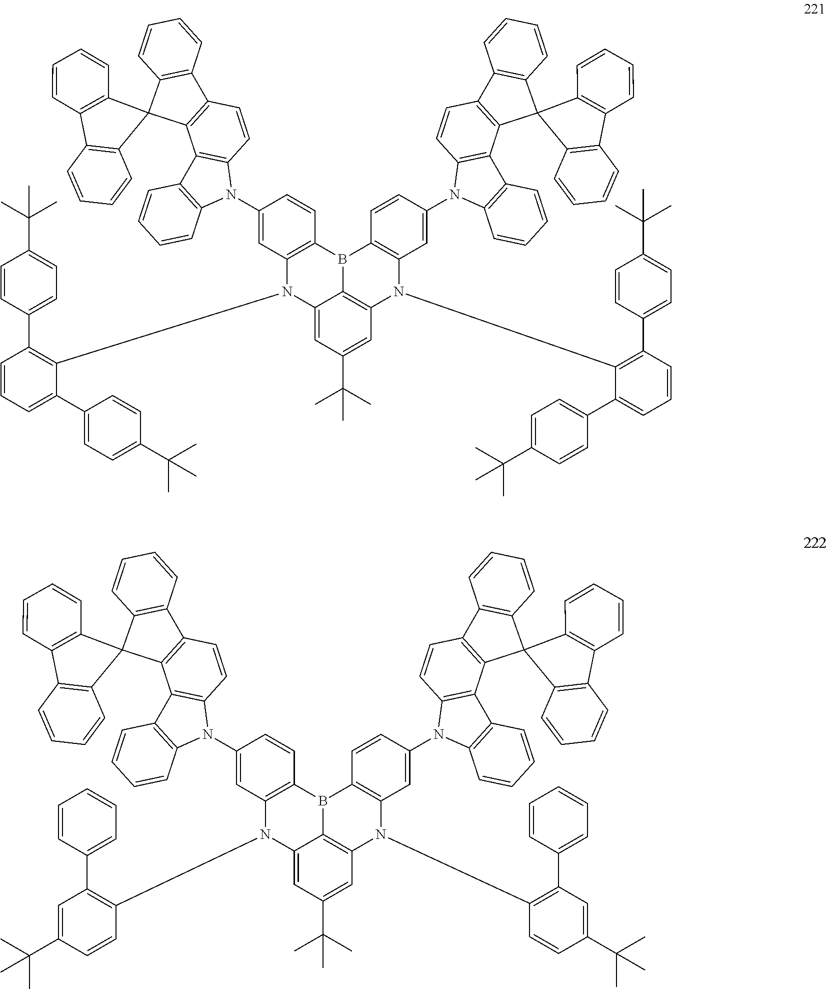 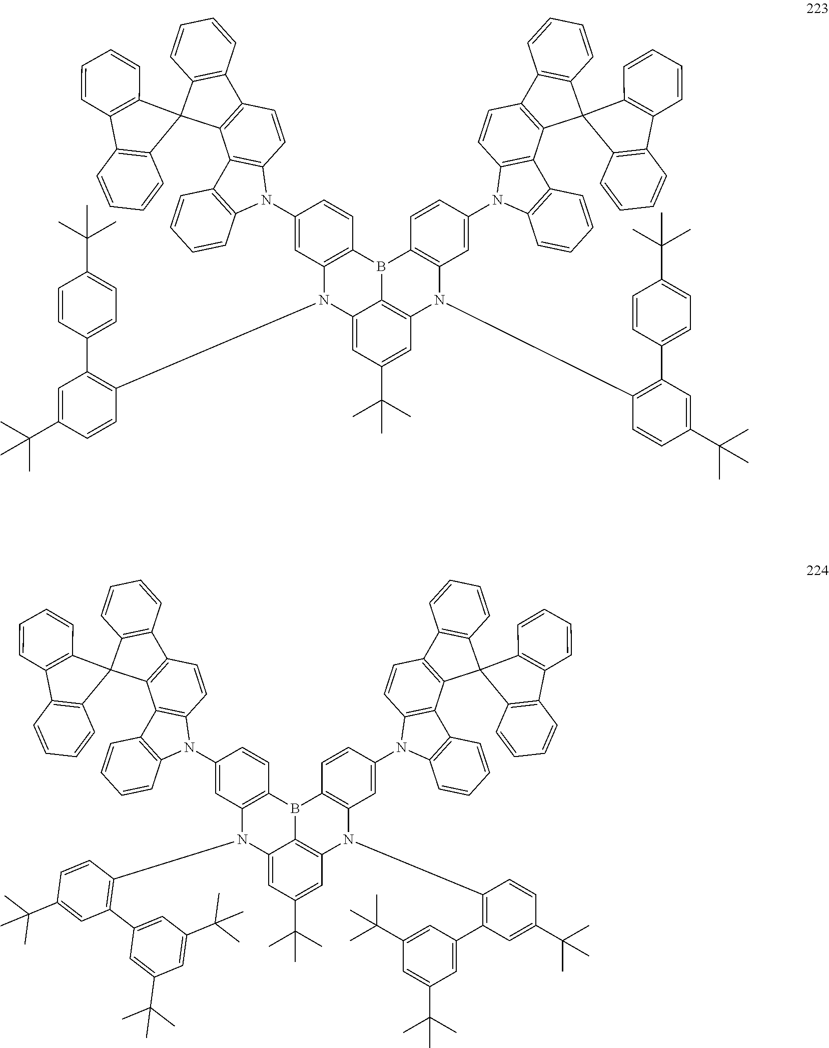
wherein in Compound Group 1,
D represents a deuterium atom.

11. A fused polycyclic compound represented by Formula 1. 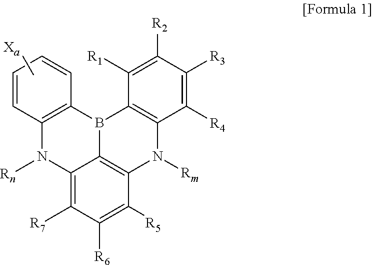
wherein in Formula 1,
R₁ to R₇ are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
Xₐ is a group represented by Formula 2, and
Rₙ and Rₘ are each independently a group represented by Formula 3; 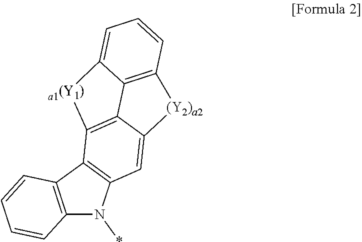
wherein in Formula 2,
one of a1 and a2 is 1,
the other of a1 and a2 is 0,
Y₁ and Y₂ are each independently C(Rₐ)(R_{b}),
Rₐ and R_{b} are each independently a substituted or unsubstituted aryl group having 6 to 20 ring-forming carbon atoms, or are bonded to each other to form a ring, and
-* represents a binding site to a neighboring atom; and 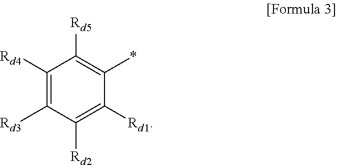
wherein in Formula 3,
R_{d1} to R_{d5} are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
-* represents a binding site to a neighboring atom.

12. The fused polycyclic compound of claim 11, wherein the fused polycyclic compound is represented by one of Formula 1-1 to Formula 1-4: 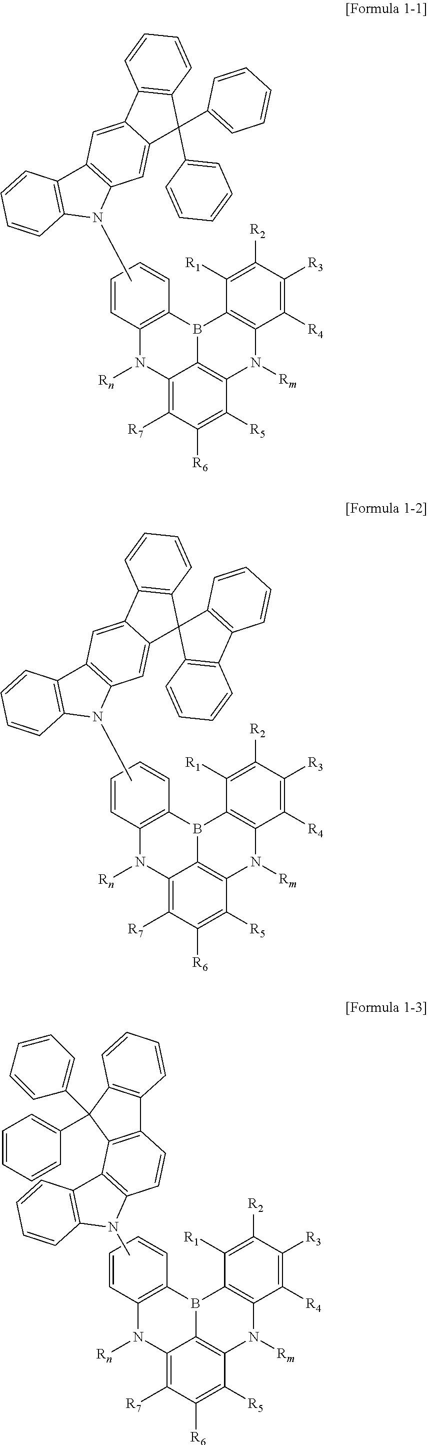 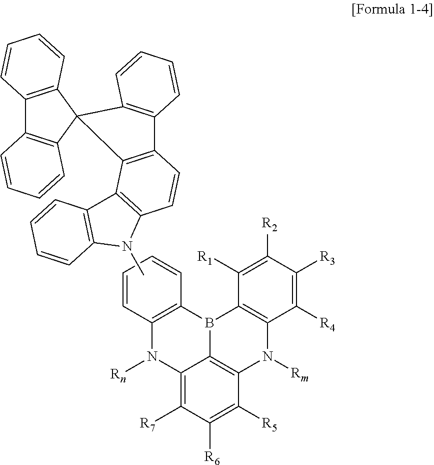
wherein in Formula 1-1 to Formula 1-4,
Rₙ, Rₘ, and R₁ to R₇ are the same as defined in Formula 1.

13. The fused polycyclic compound of claim 11, wherein the fused polycyclic compound is represented by Formula 1-A: 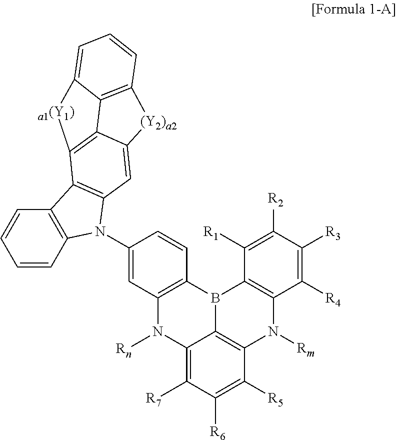
wherein in Formula 1-A,
Rₙ, Rₘ, R₁ to R₇, Y₁, Y₂, a1, and a2 are the same as defined in Formula 1 and Formula 2.

14. The fused polycyclic compound of claim 13, wherein the fused polycyclic compound is represented by Formula 1-A1: 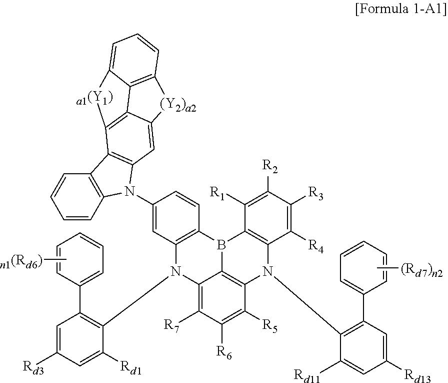
wherein in Formula 1-A1,
n1 and n2 are each independently an integer from 0 to 5,
R_{d6} and R_{d7} are each independently a hydrogen atom, a deuterium atom, or a substituted or unsubstituted alkyl group having 1 to 30 carbon atoms,
R_{d11} and R_{d13} are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
R₁ to R₇, Y₁, Y₂, a1, a2, R_{d1}, and R_{d3} are the same as defined in Formula 1, Formula 2, and Formula 3.

15. The fused polycyclic compound of claim 11, wherein the group represented by Formula 3 is represented by one of Formula 3-1 to Formula 3-8: 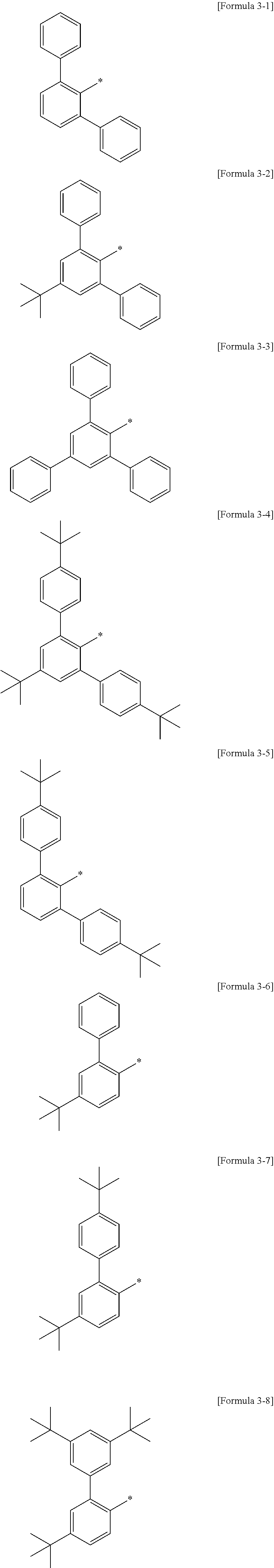
wherein in Formula 3-1 to Formula 3-8,
-* represents a binding site to a neighboring atom.

16. The fused polycyclic compound of claim 11, wherein in Formula 1, R₂ and R₃ are each independently a hydrogen atom, a substituted or unsubstituted phenyl group, a substituted or unsubstituted dibenzofuran group, a substituted or unsubstituted carbazole group, or a group represented by Formula 2.

17. The fused polycyclic compound of claim 11, wherein in Formula 1, R₂ and R₃ are each independently a group represented by one of Formula R-1 to Formula R-10: 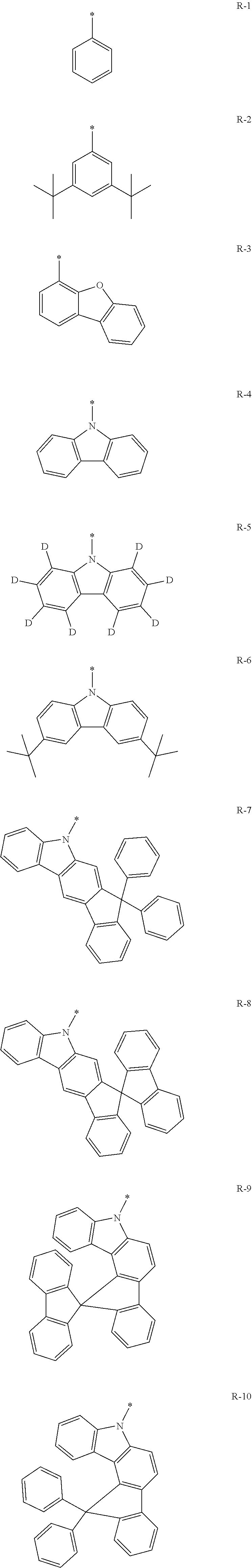
wherein in Formula R-5,
D represents a deuterium atom, and
wherein in Formula R-1 to Formula R-10,
-* represents a binding site to a neighboring atom.

18. The fused polycyclic compound of claim 11, wherein in Formula 1, R₆ is a hydrogen atom or a substituted or unsubstituted t-butyl group.

19. The fused polycyclic compound of claim 11, wherein the fused polycyclic compound is selected from Compound Group 1: 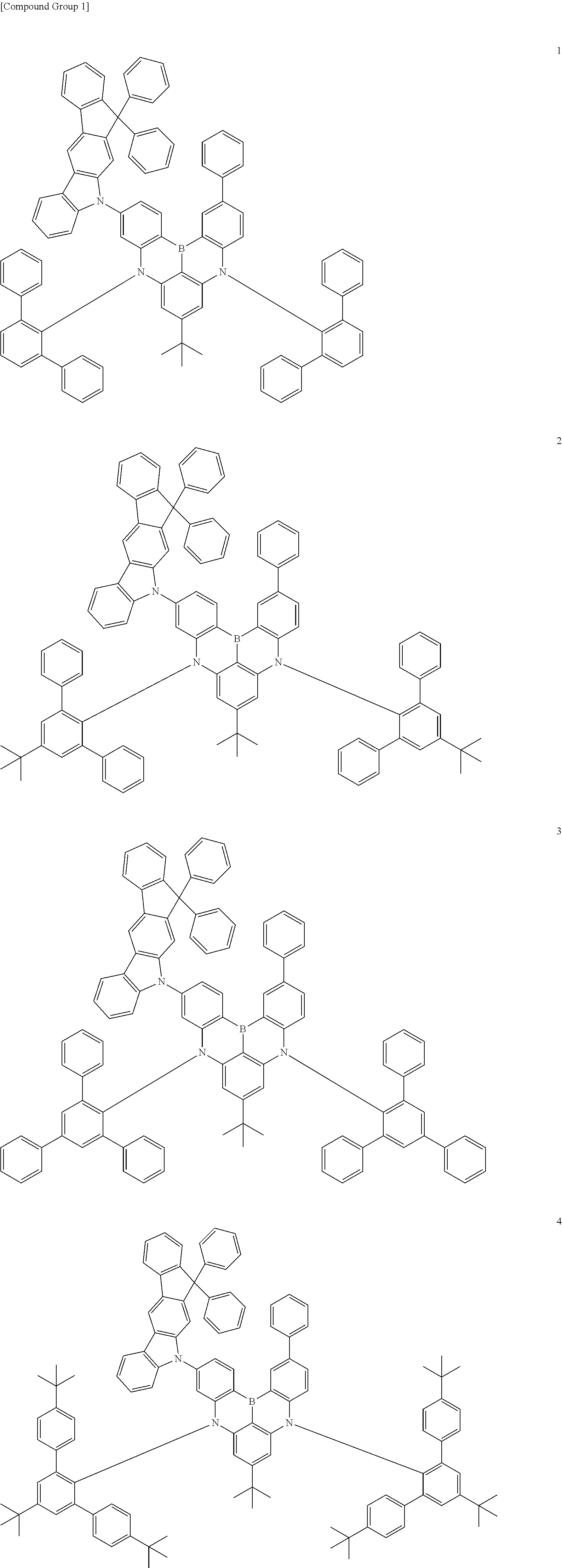 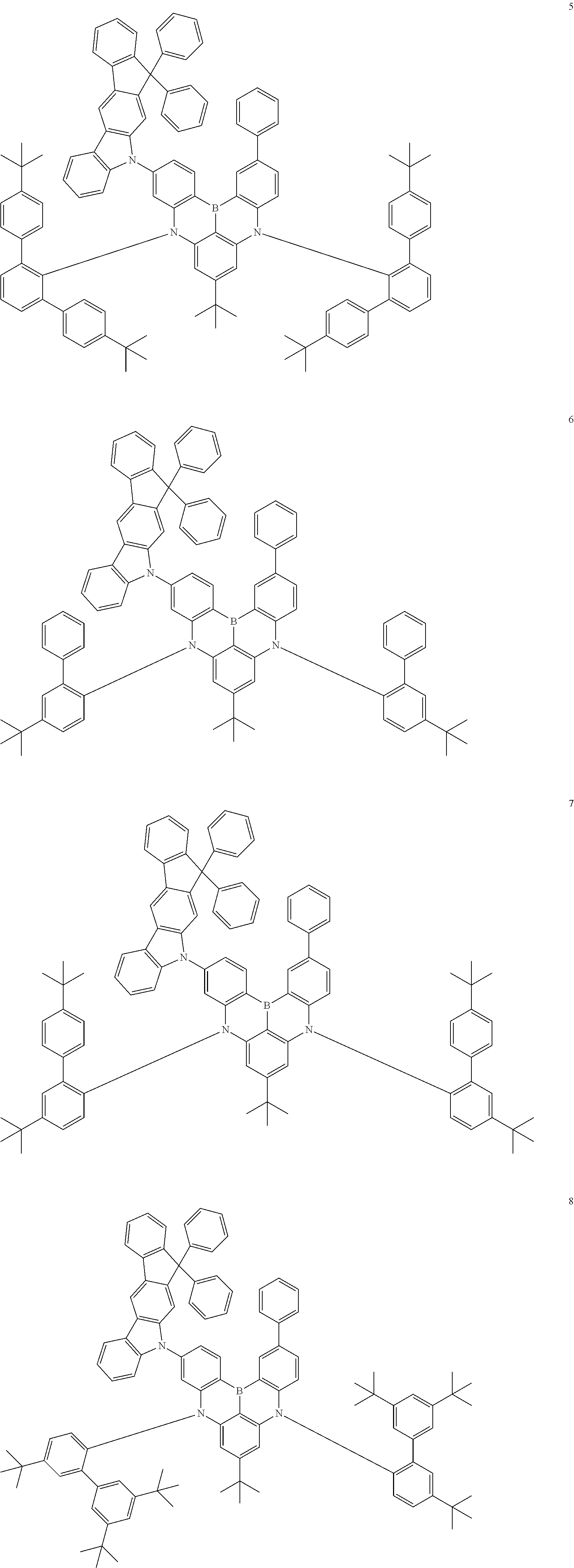 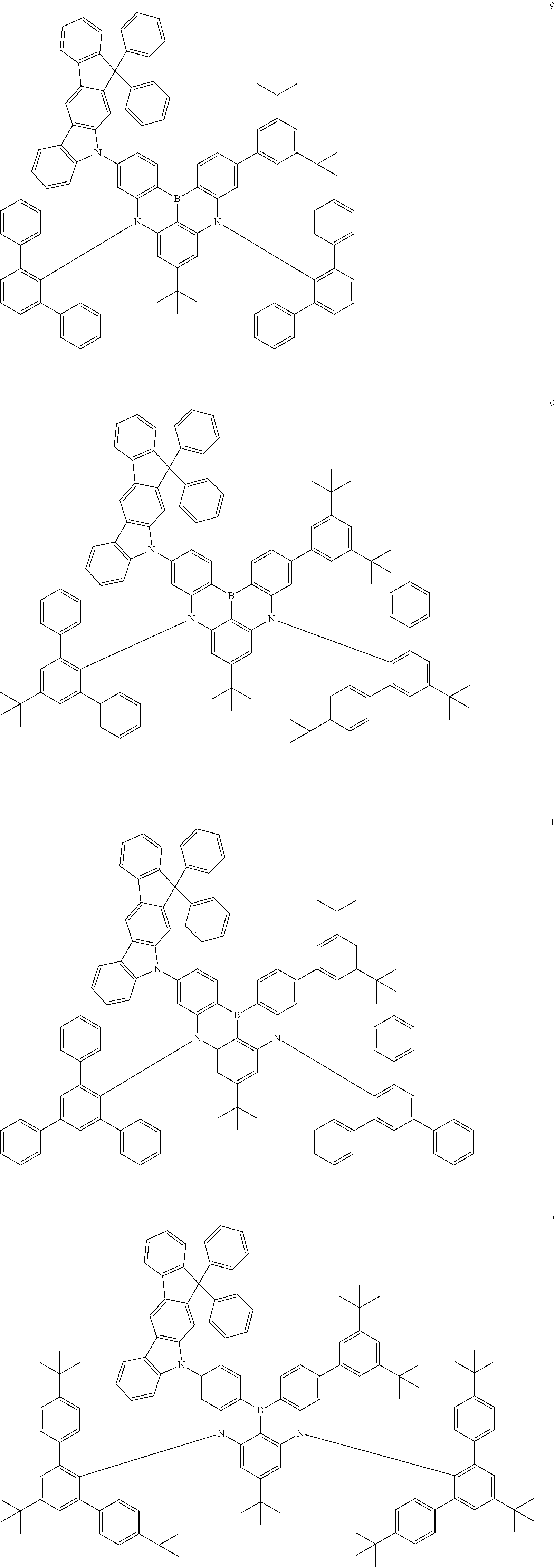 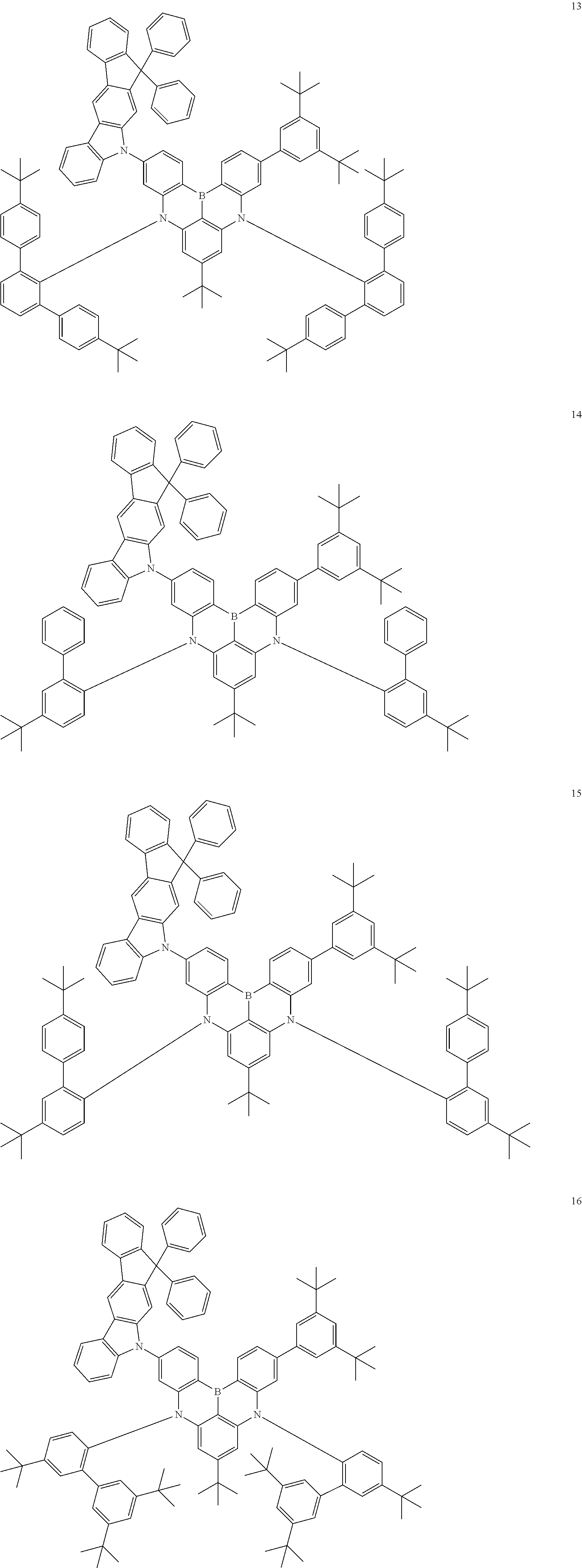 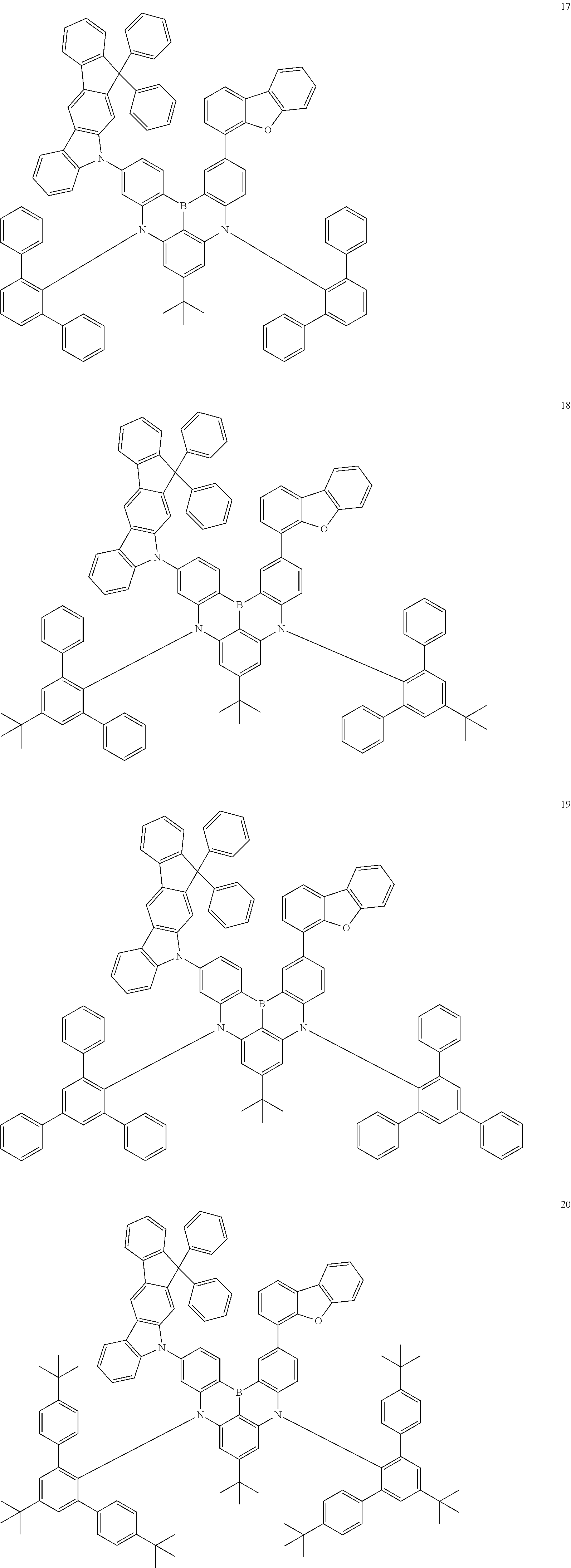 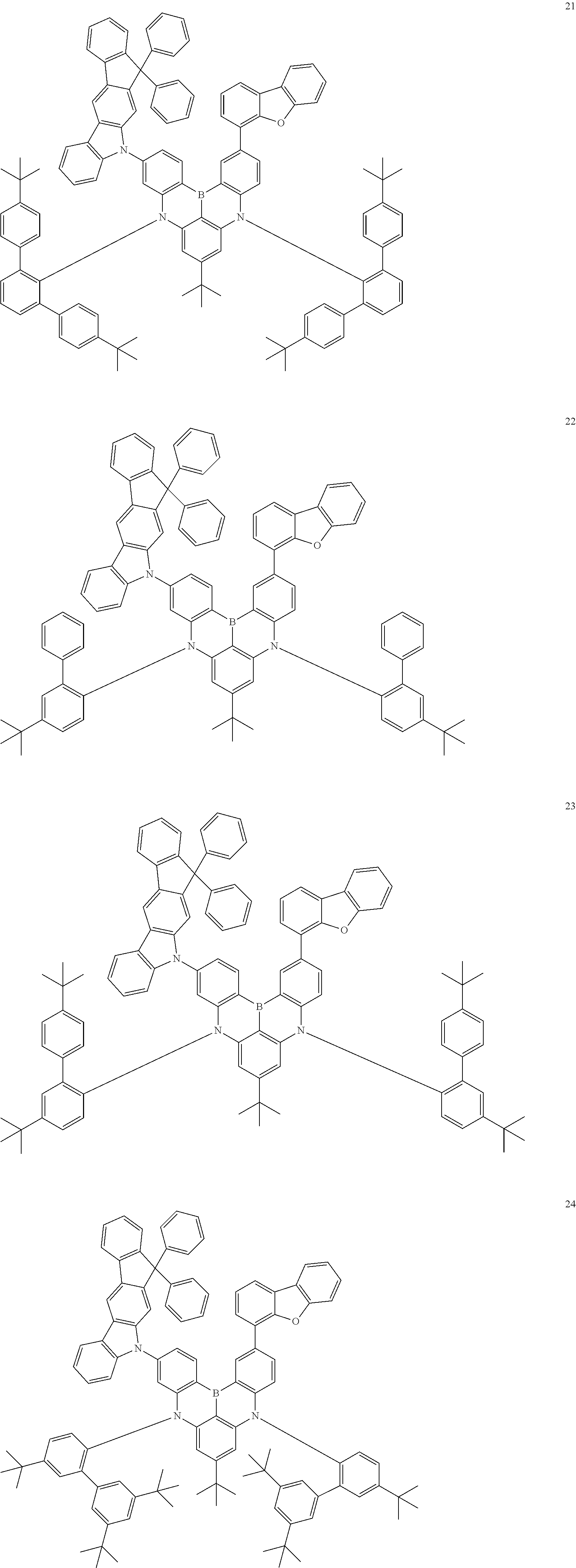 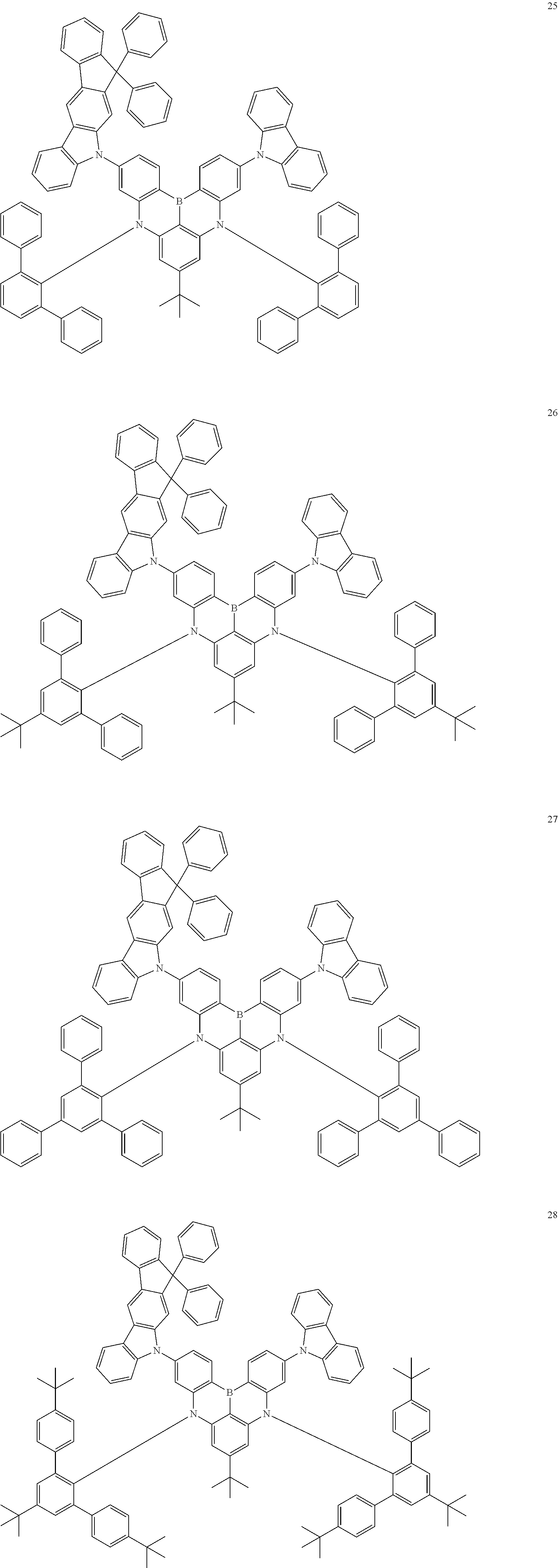 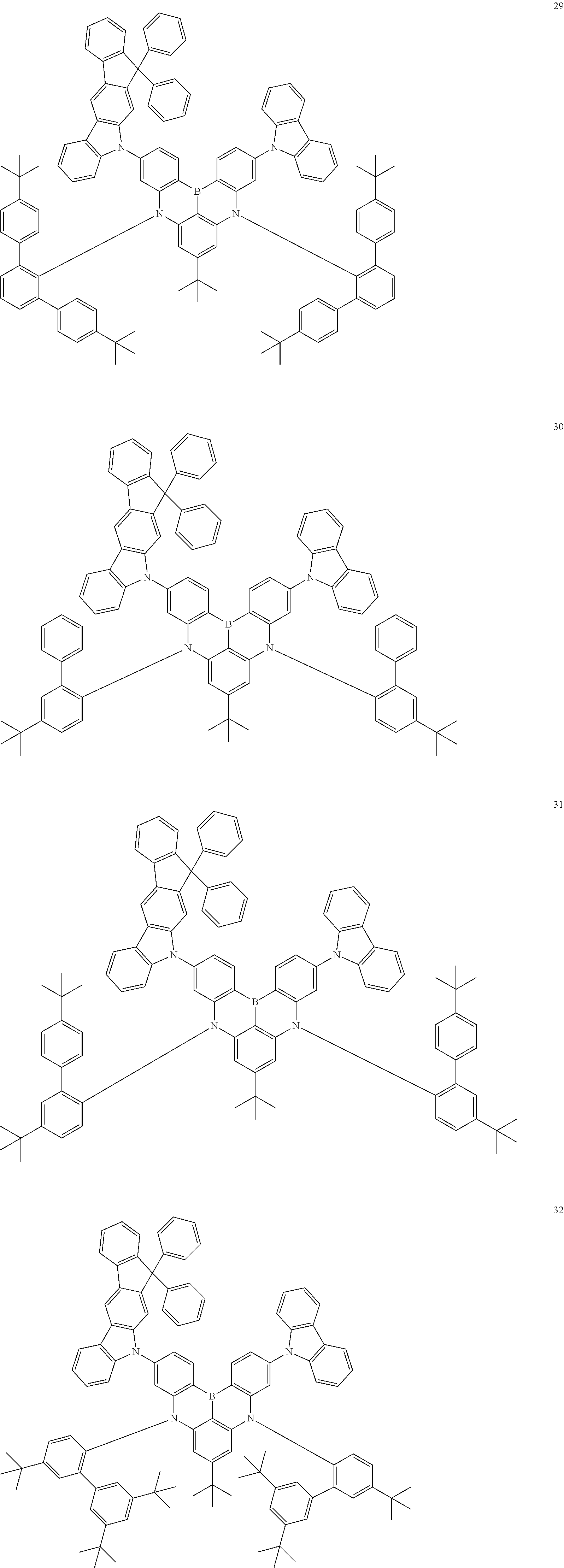 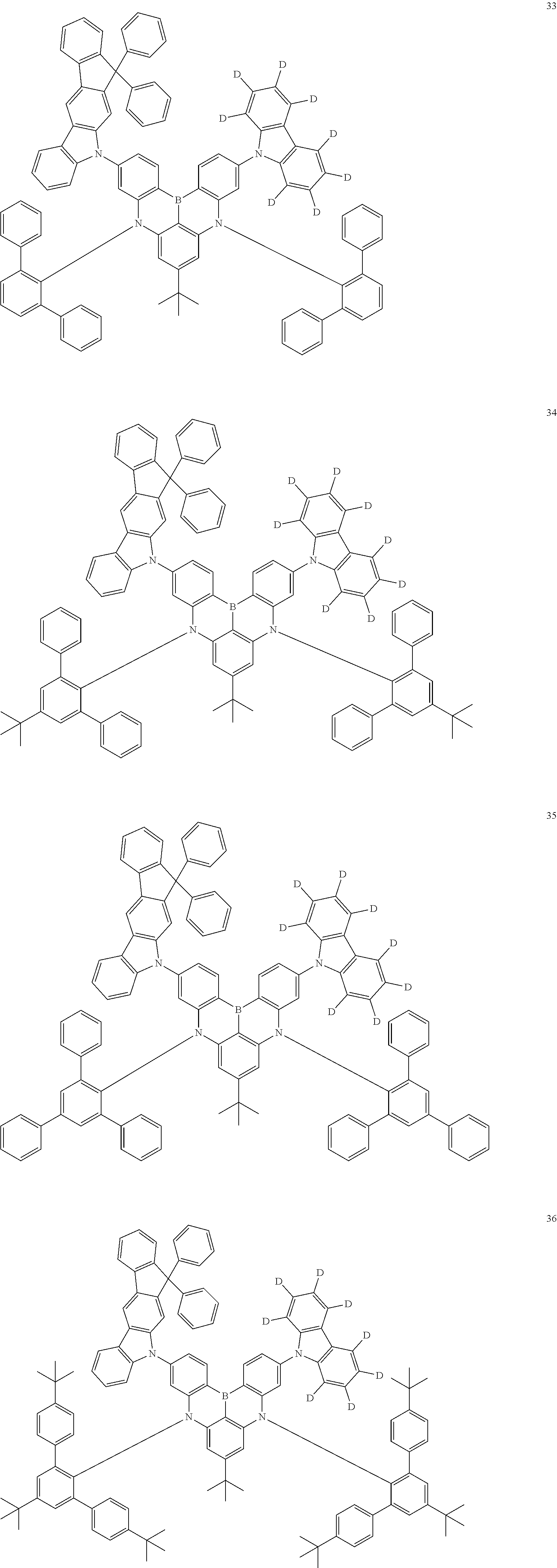 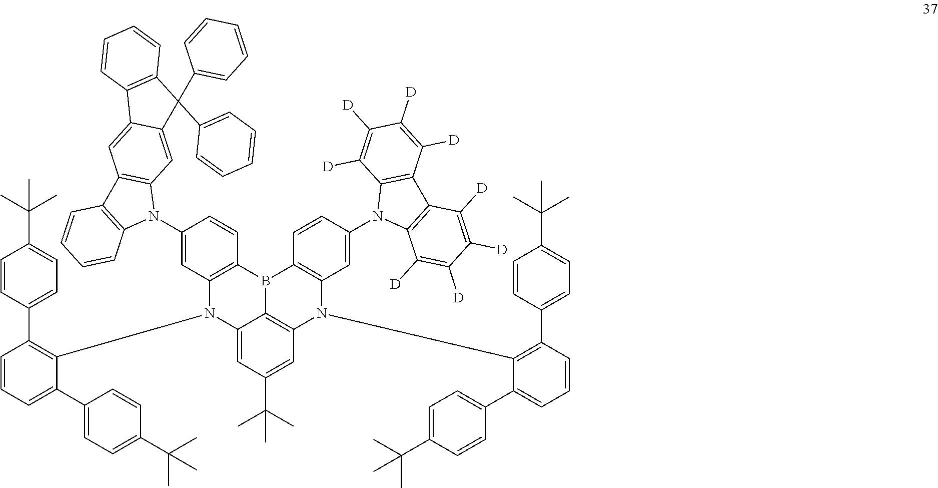 [SMILES: [2H]c1c([2H])c([2H])c2c(c1[2H])c1c([2H])c([2H])c([2H])c([2H])c1n2-c1ccc2c(c1)N(c1c(-c3ccc(C(C)(C)C)cc3)cccc1-c1ccc(C(C)(C)C)cc1)c1cc(C(C)(C)C)cc3c1B2c1ccc(-n2c4ccccc4c4cc5c(cc42)C(c2ccccc2)(c2ccccc2)c2ccccc2-5)cc1N3c1c(-c2ccc(C(C)(C)C)cc2)cccc1-c1ccc(C(C)(C)C)cc1] 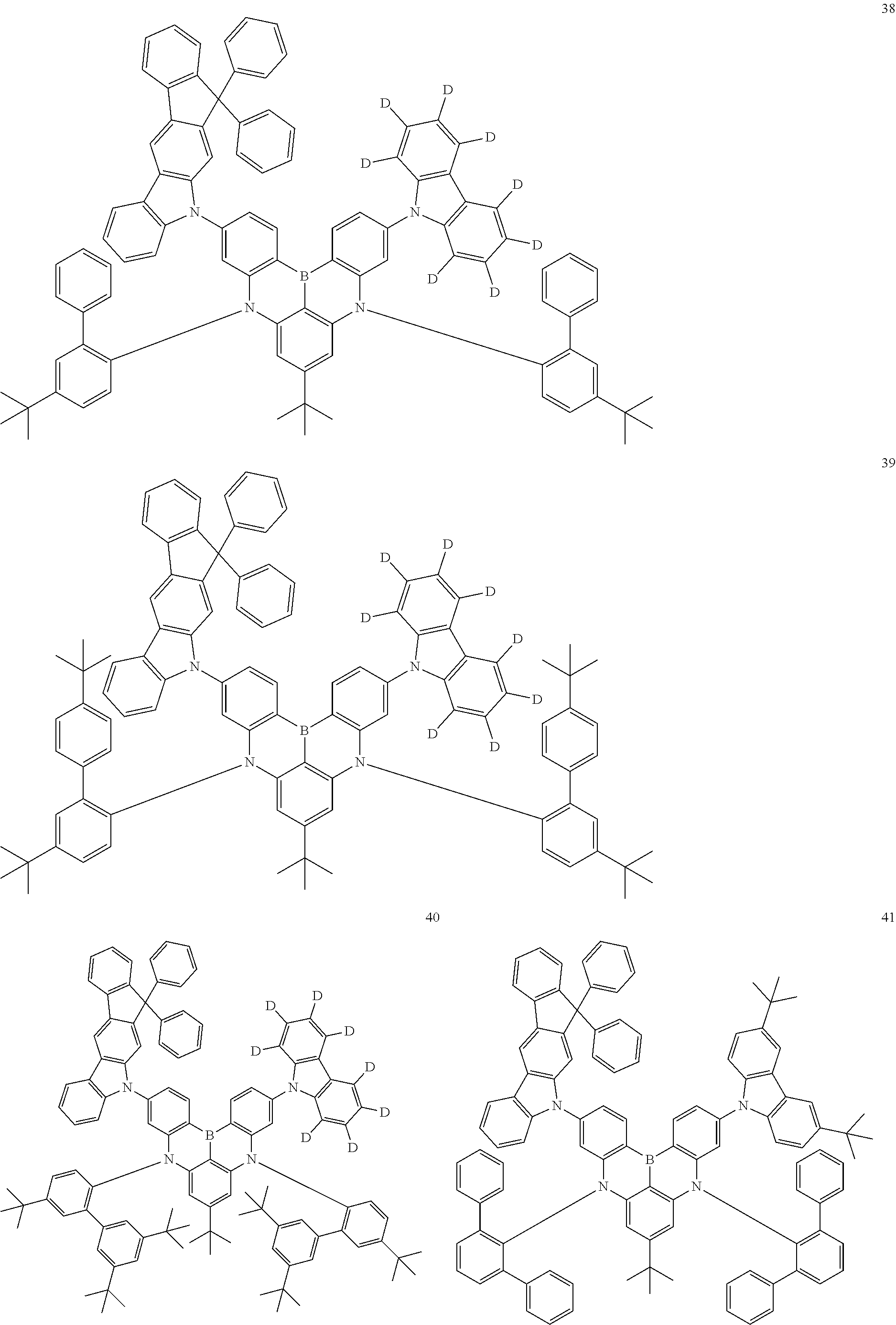 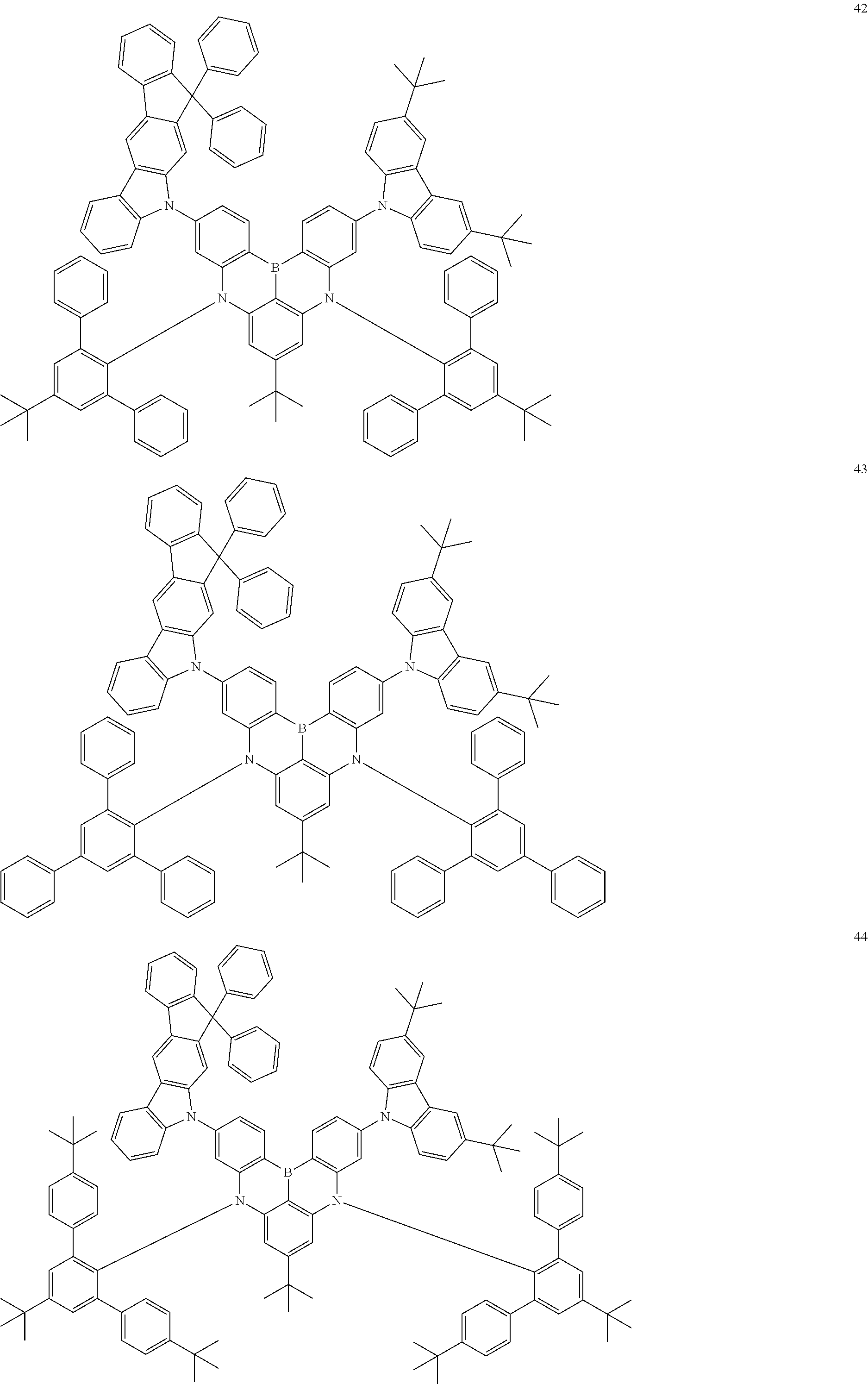 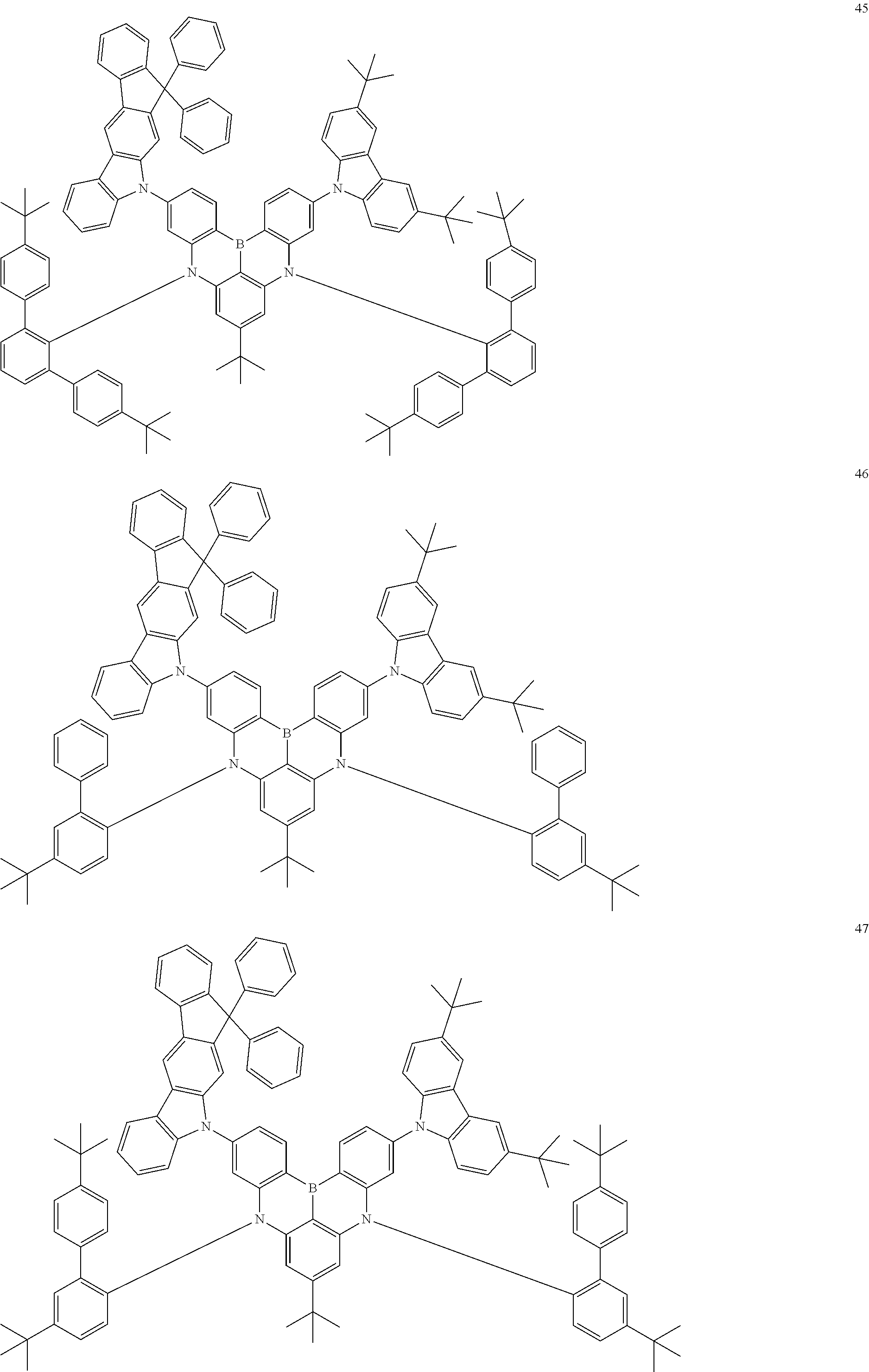 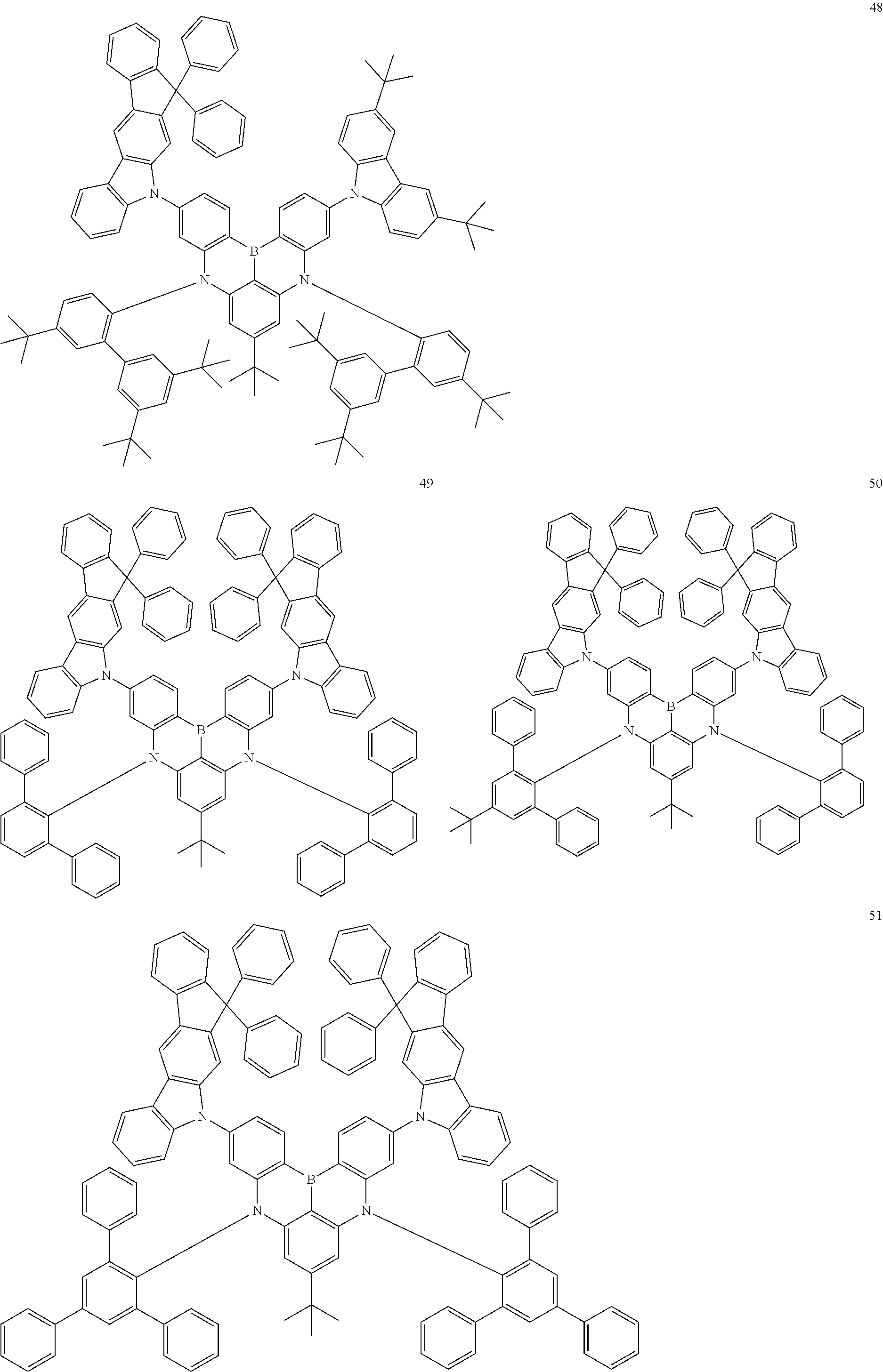 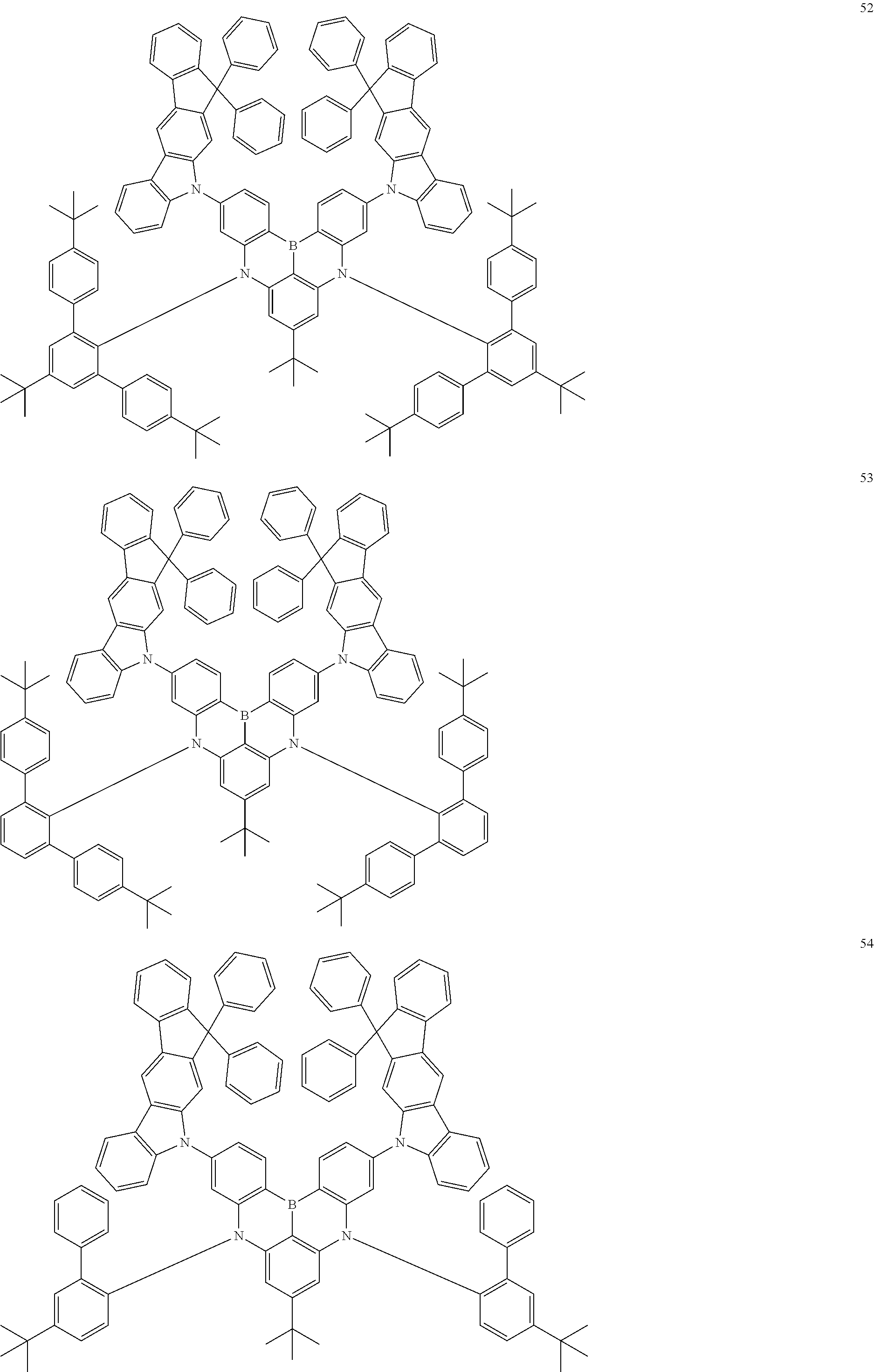 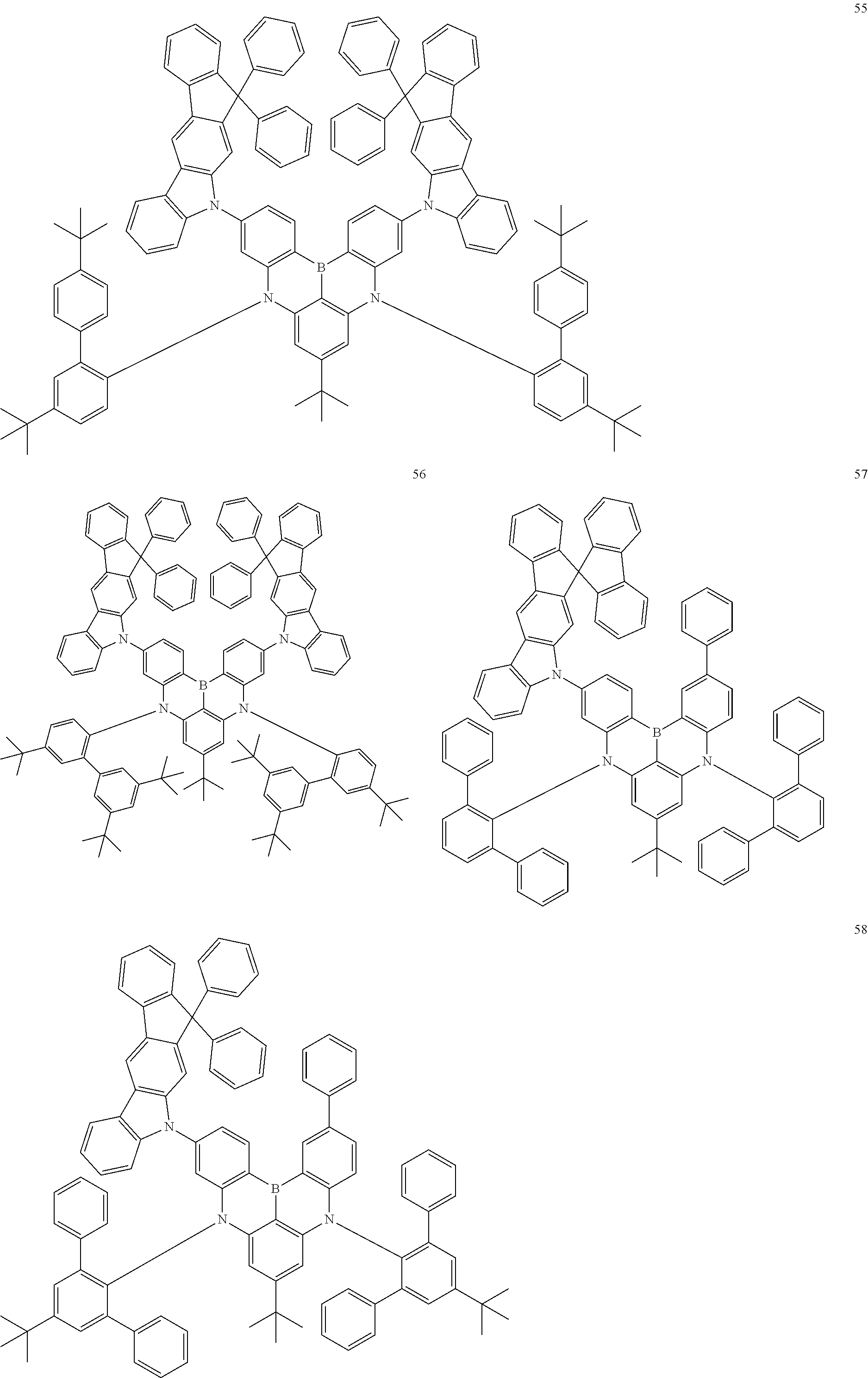 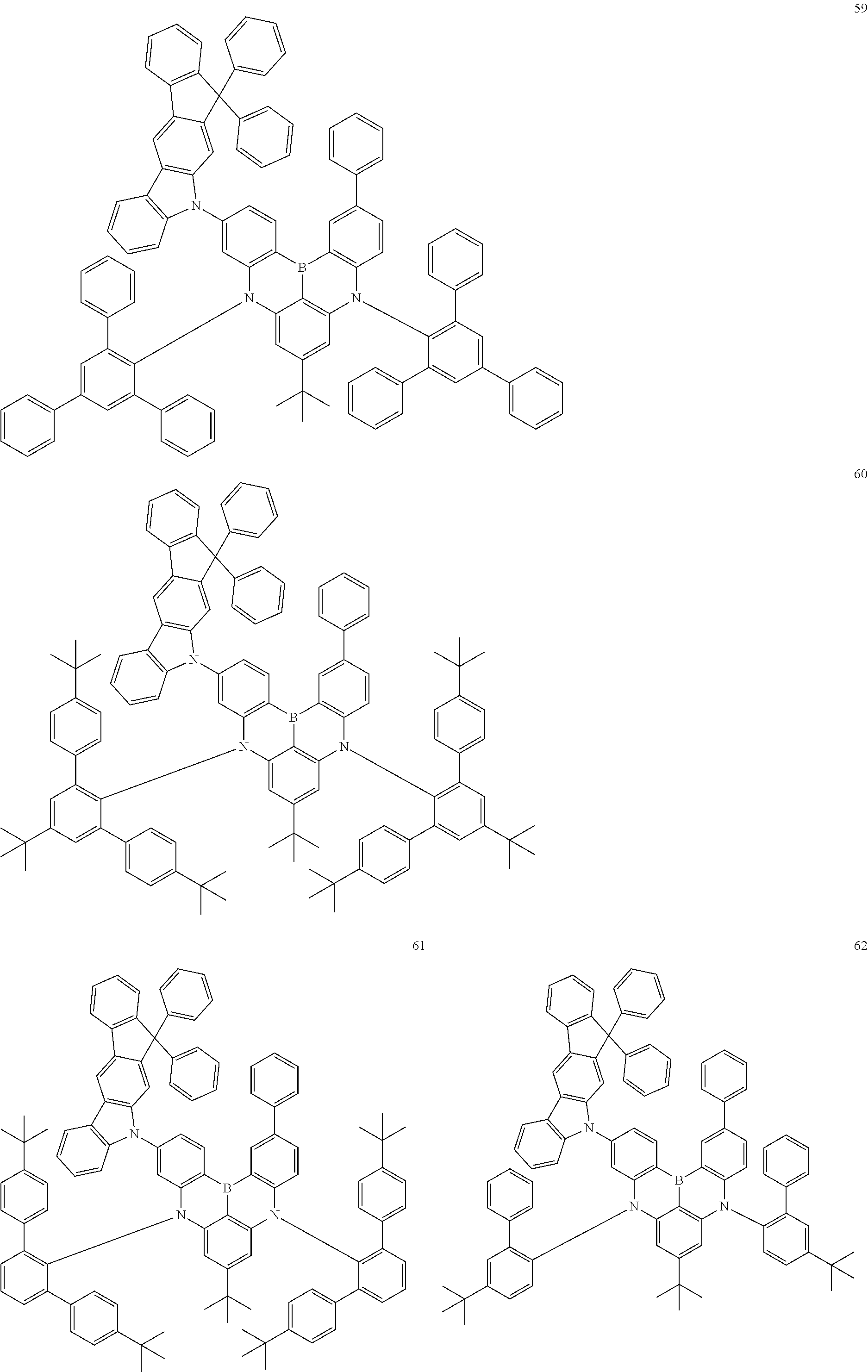 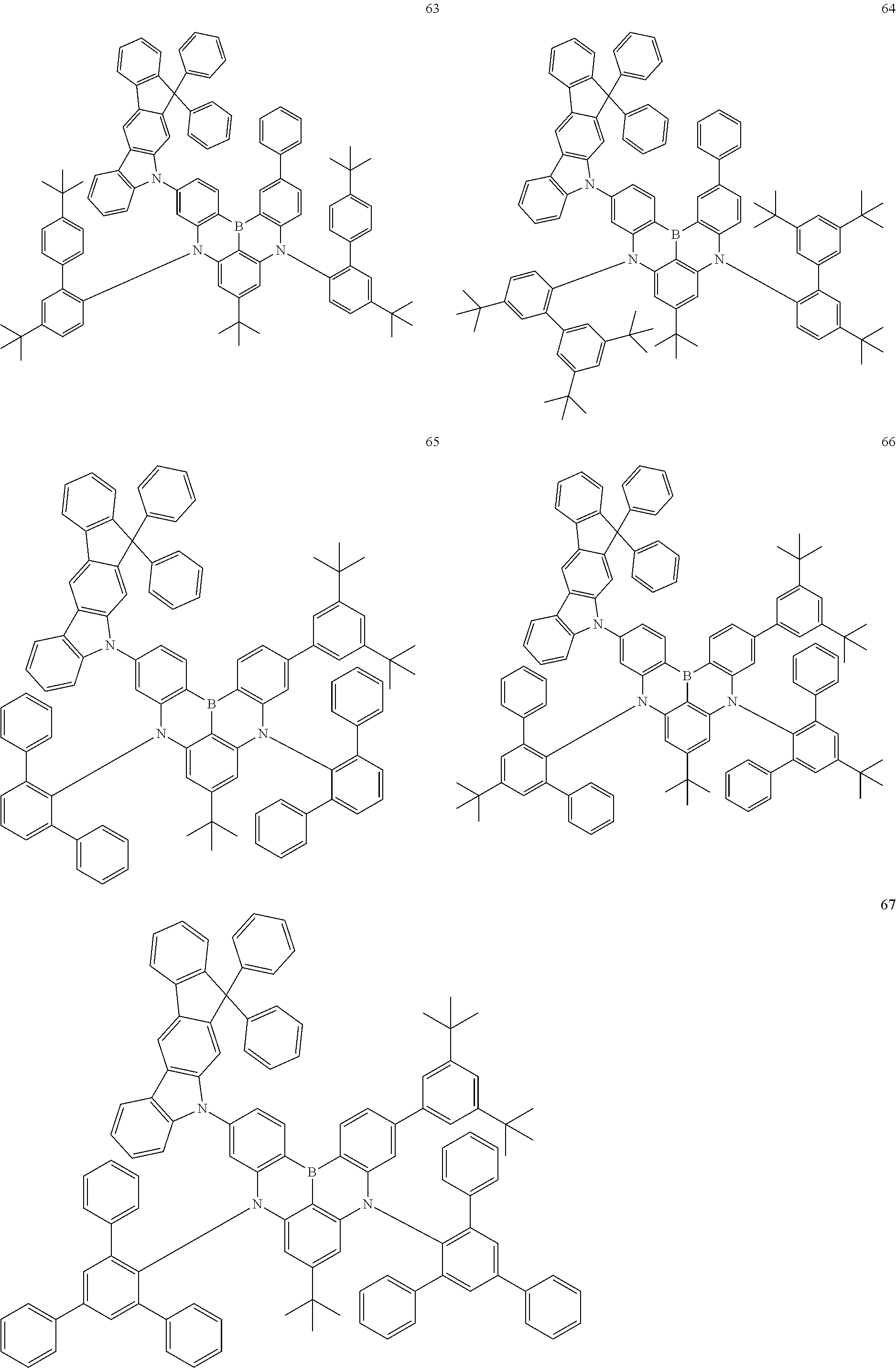 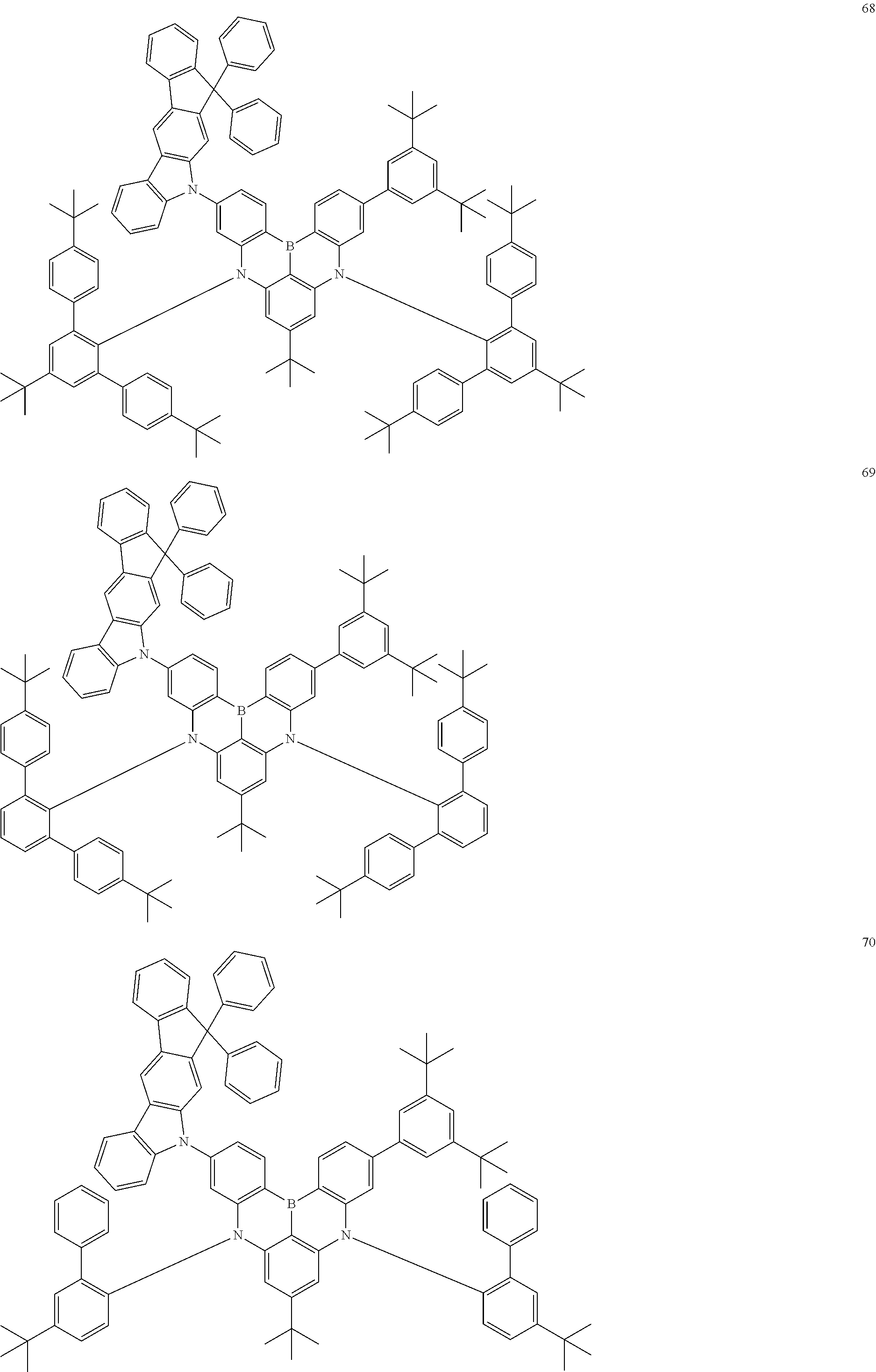 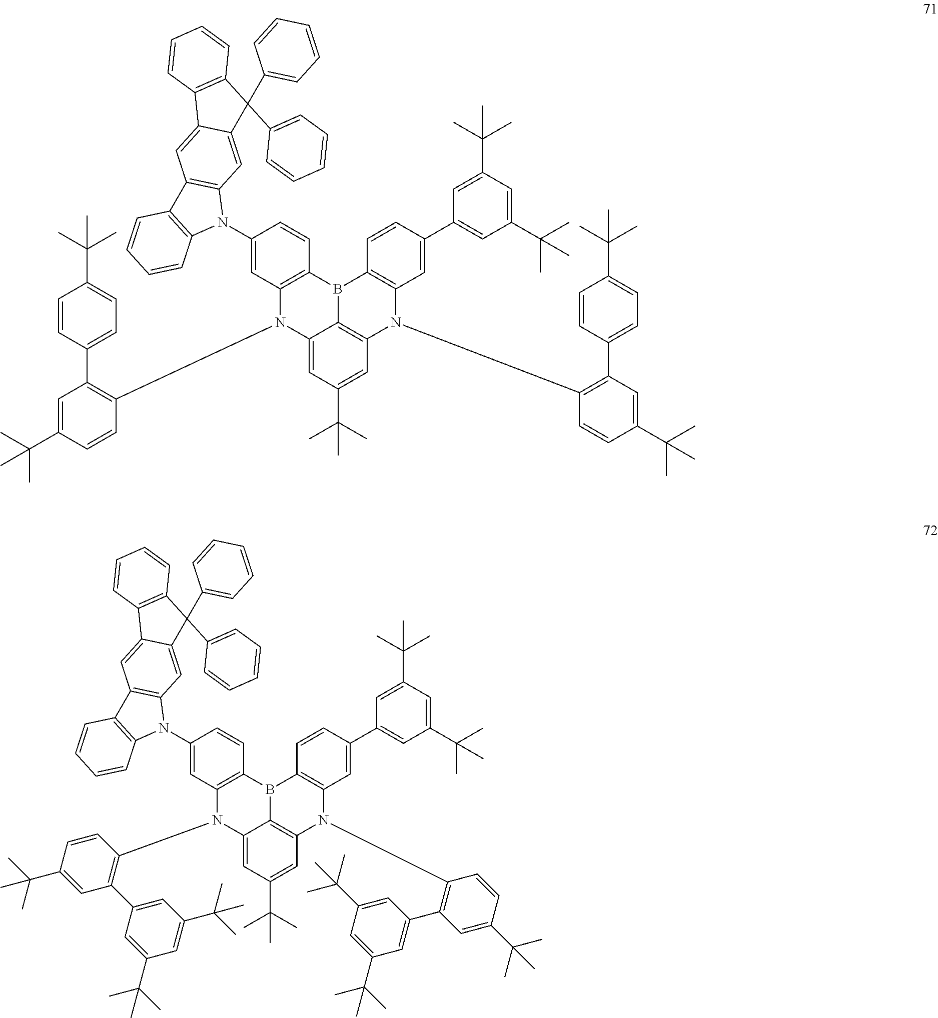 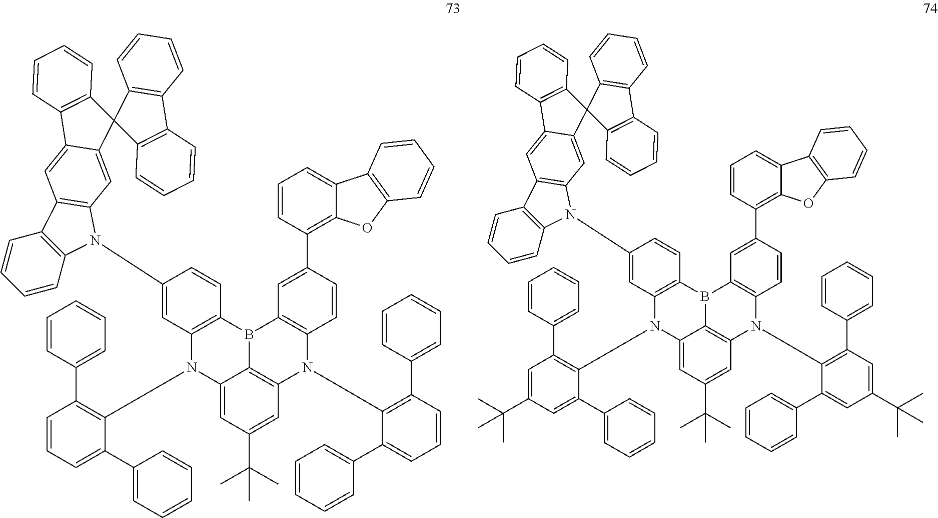 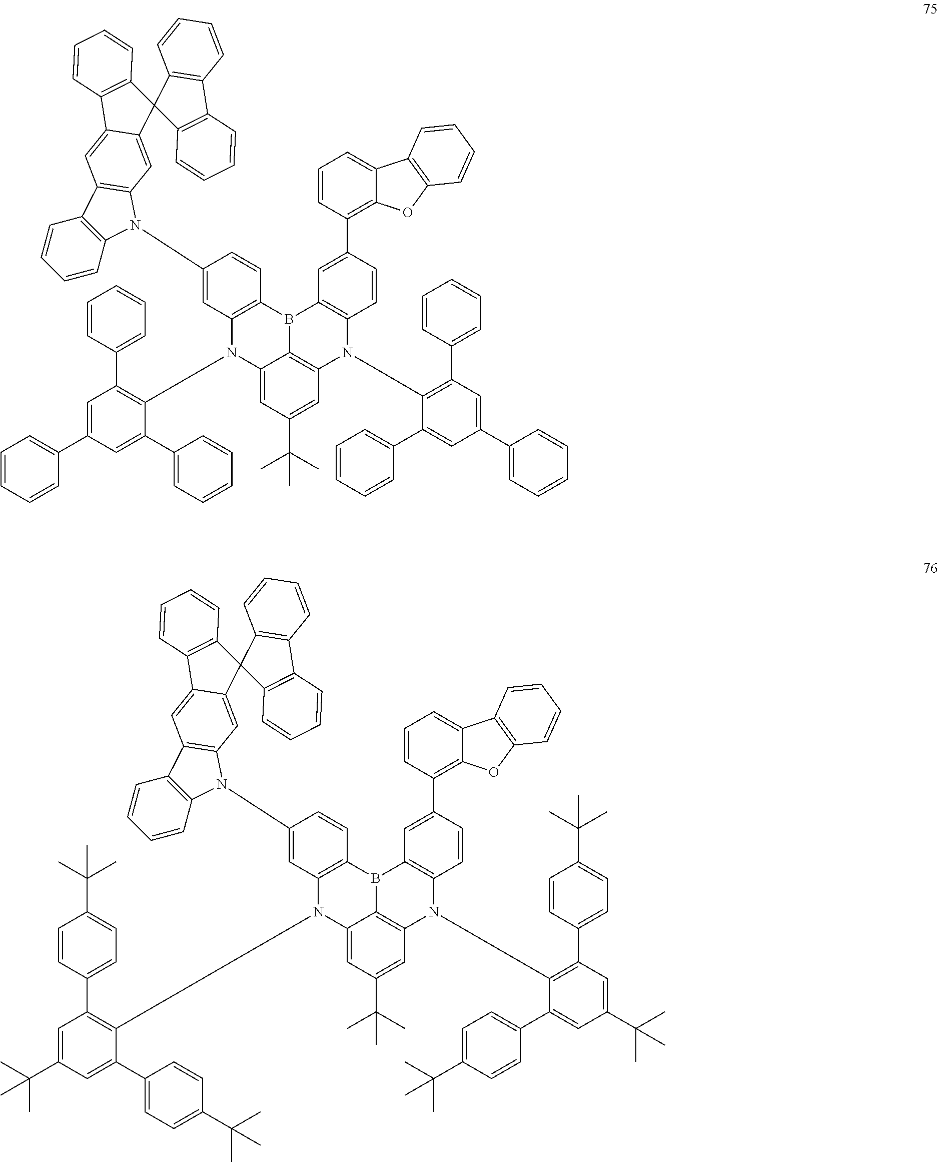 [SMILES: CC(C)(C)c1cc2c3c(c1)N(Cc1c(-c4ccccc4)cc(-c4ccccc4)cc1-c1ccccc1)c1ccc(-c4cccc5c4oc4ccccc45)cc1B3c1ccc(-n3c4ccccc4c4cc5c(cc43)C3(c4ccccc4-c4ccccc43)c3ccccc3-5)cc1N2CCc1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2CCCCCCN2c3cc(-n4c5ccccc5c5cc6c(cc54)C4(c5ccccc5-c5ccccc54)c4ccccc4-6)ccc3B3c4cc(-c5cccc6c5oc5ccccc56)ccc4N(CCCc4c(-c5ccc(C(C)(C)C)cc5)cc(C(C)(C)C)cc4-c4ccc(C(C)(C)C)cc4)c4cc(C(C)(C)C)cc2c43)cc1] 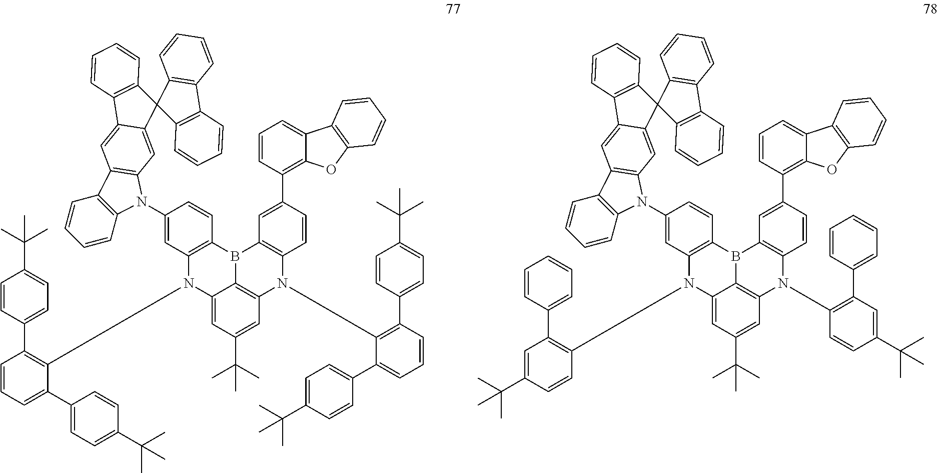 [SMILES: CC(C)(C)c1ccc(-c2cccc(-c3ccc(C(C)(C)C)cc3)c2CCCCCN2c3cc(-n4c5ccccc5c5cc6c(cc54)C4(c5ccccc5-c5ccccc54)c4ccccc4-6)ccc3B3c4cc(-c5cccc6c5oc5ccccc56)ccc4N(CCCc4c(-c5ccc(C(C)(C)C)cc5)cccc4-c4ccc(C(C)(C)C)cc4)c4cc(C(C)(C)C)cc2c43)cc1 ; CC(C)(C)c1ccc(CCCCN2c3cc(-n4c5ccccc5c5cc6c(cc54)C4(c5ccccc5-c5ccccc54)c4ccccc4-6)ccc3B3c4cc(-c5cccc6c5oc5ccccc56)ccc4N(Cc4ccc(C(C)(C)C)cc4-c4ccccc4)c4cc(C(C)(C)C)cc2c43)c(-c2ccccc2)c1] 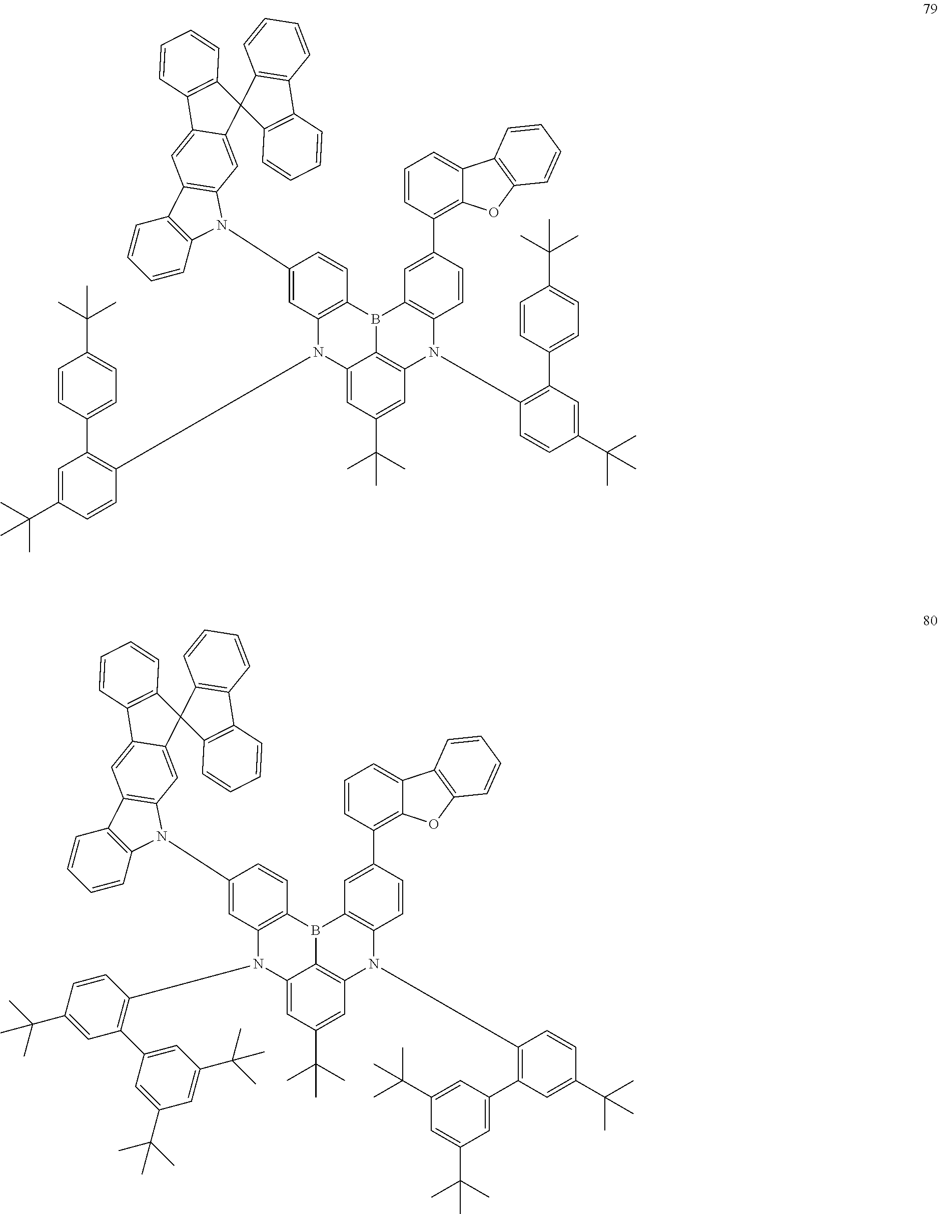 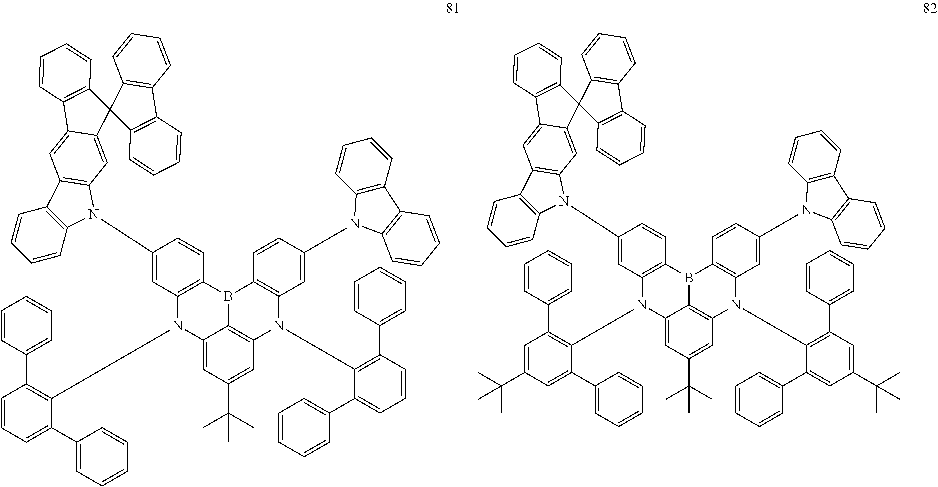 [SMILES: CC(C)(C)c1cc2c3c(c1)N(CCc1c(-c4ccccc4)cccc1-c1ccccc1)c1cc(Cn4c5ccccc5c5ccccc54)ccc1B3c1ccc(-n3c4ccccc4c4cc5c(cc43)C3(c4ccccc4-c4ccccc43)c3ccccc3-5)cc1N2CCCCc1c(-c2ccccc2)cccc1-c1ccccc1 ; CC(C)(C)c1cc(-c2ccccc2)c(CCN2c3cc(Cn4c5ccccc5c5ccccc54)ccc3B3c4ccc(-n5c6ccccc6c6cc7c(cc65)C5(c6ccccc6-c6ccccc65)c5ccccc5-7)cc4N(CCc4c(-c5ccccc5)cc(C(C)(C)C)cc4-c4ccccc4)c4cc(C(C)(C)C)cc2c43)c(-c2ccccc2)c1] 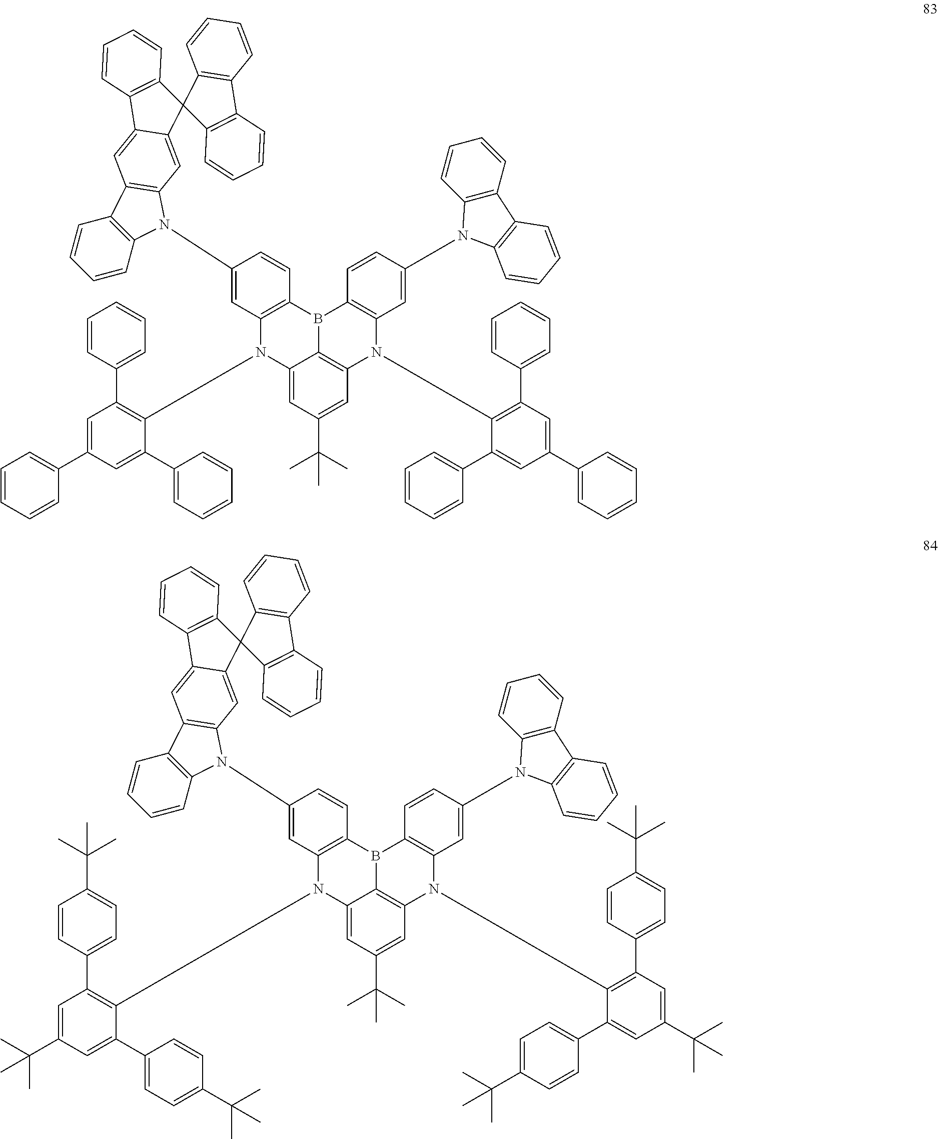 [SMILES: CC(C)(C)c1cc2c3c(c1)N(CCCc1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1ccc(Cn3c4ccccc4c4ccccc43)cc1N2CCCc1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2CCCCCCN2c3cc(-n4c5ccccc5c5cc6c(cc54)C4(c5ccccc5-c5ccccc54)c4ccccc4-6)ccc3B3c4ccc(Cn5c6ccccc6c6ccccc65)cc4N(CCCCCc4c(-c5ccc(C(C)(C)C)cc5)cc(C(C)(C)C)cc4-c4ccc(C(C)(C)C)cc4)c4cc(C(C)(C)C)cc2c43)cc1] 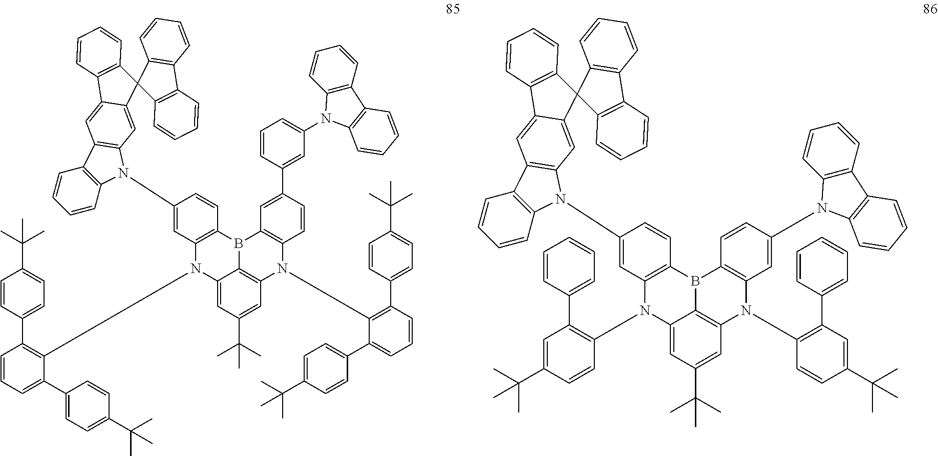 [SMILES: CC(C)(C)c1ccc(-c2cccc(-c3ccc(C(C)(C)C)cc3)c2CCCCCCN2c3cc(-n4c5ccccc5c5cc6c(cc54)C4(c5ccccc5-c5ccccc54)c4ccccc4-6)ccc3B3c4cc(-c5cccc(-n6c7ccccc7c7ccccc76)c5)ccc4N(CCCc4c(-c5ccc(C(C)(C)C)cc5)cccc4-c4ccc(C(C)(C)C)cc4)c4cc(C(C)(C)C)cc2c43)cc1 ; CC(C)(C)c1ccc(CN2c3cc(Cn4c5ccccc5c5ccccc54)ccc3B3c4ccc(-n5c6ccccc6c6cc7c(cc65)C5(c6ccccc6-c6ccccc65)c5ccccc5-7)cc4N(Cc4ccc(C(C)(C)C)cc4-c4ccccc4)c4cc(C(C)(C)C)cc2c43)c(-c2ccccc2)c1] 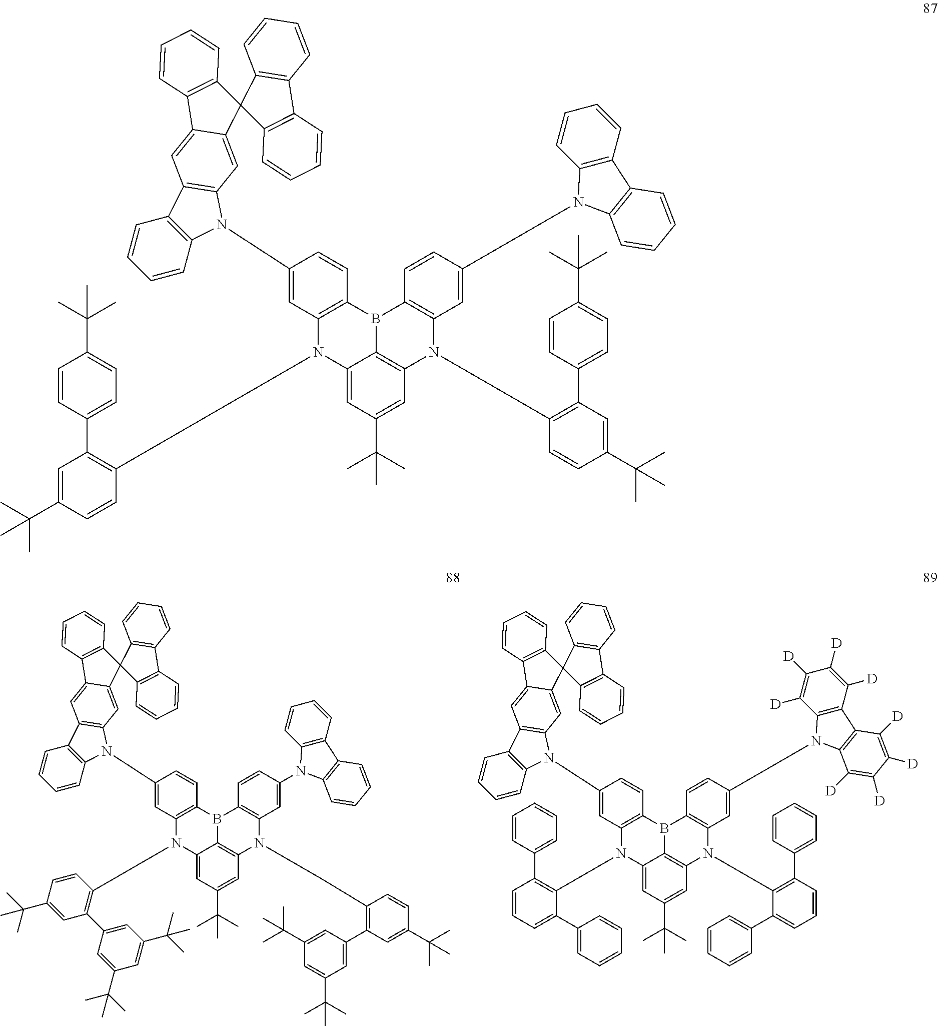 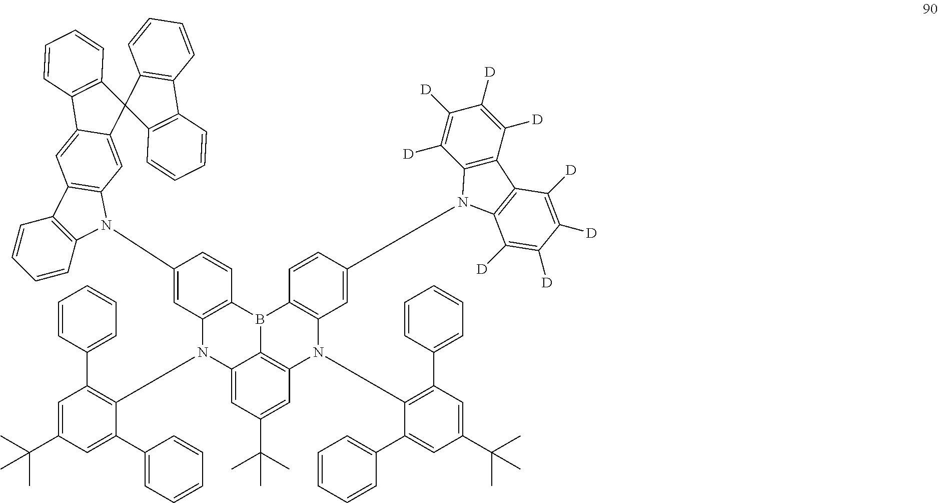 [SMILES: [2H]c1c([2H])c([2H])c2c(c1[2H])c1c([2H])c([2H])c([2H])c([2H])c1n2CCCc1ccc2c(c1)N(CCc1c(-c3ccccc3)cc(C(C)(C)C)cc1-c1ccccc1)c1cc(C(C)(C)C)cc3c1B2c1ccc(-n2c4ccccc4c4cc5c(cc42)C2(c4ccccc4-c4ccccc42)c2ccccc2-5)cc1N3CCc1c(-c2ccccc2)cc(C(C)(C)C)cc1-c1ccccc1] 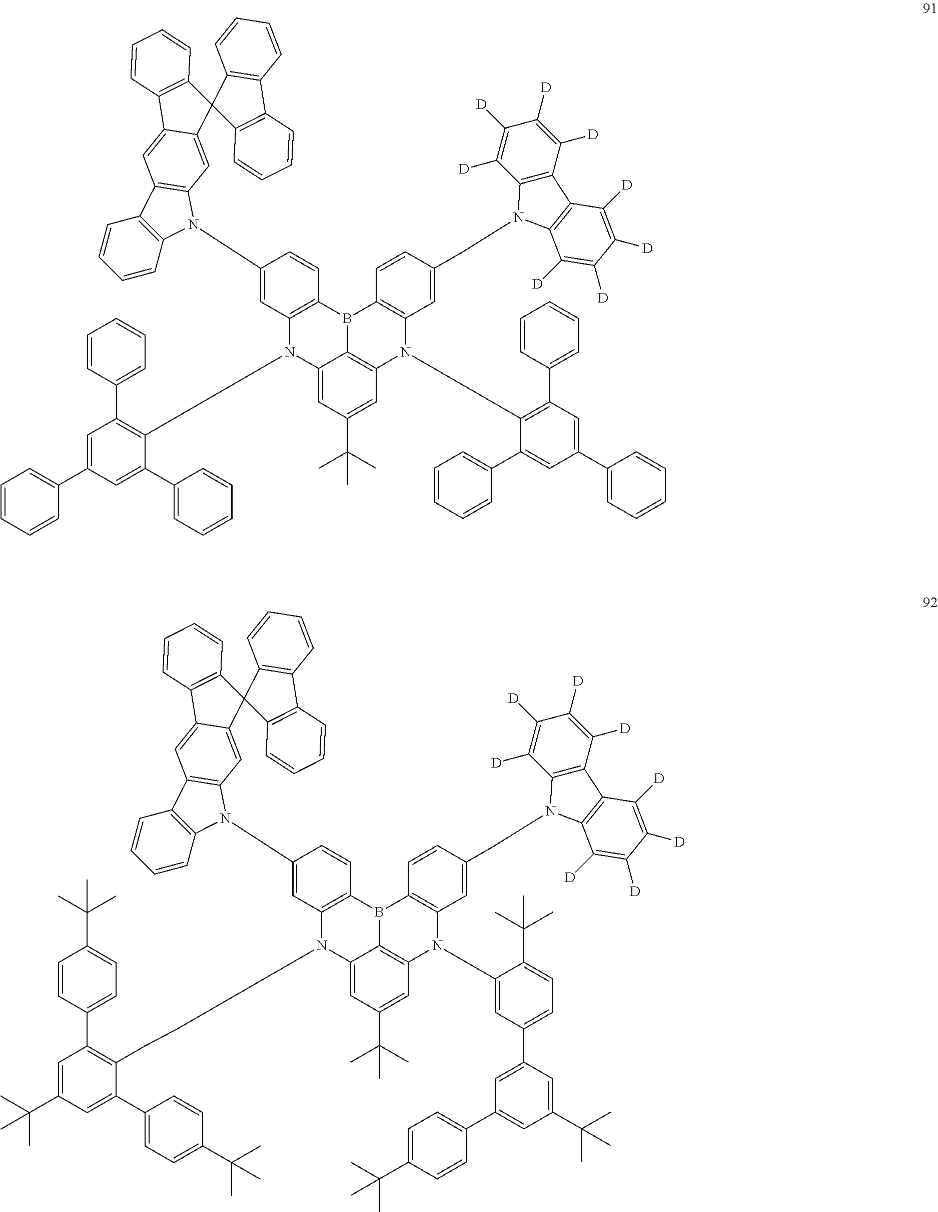 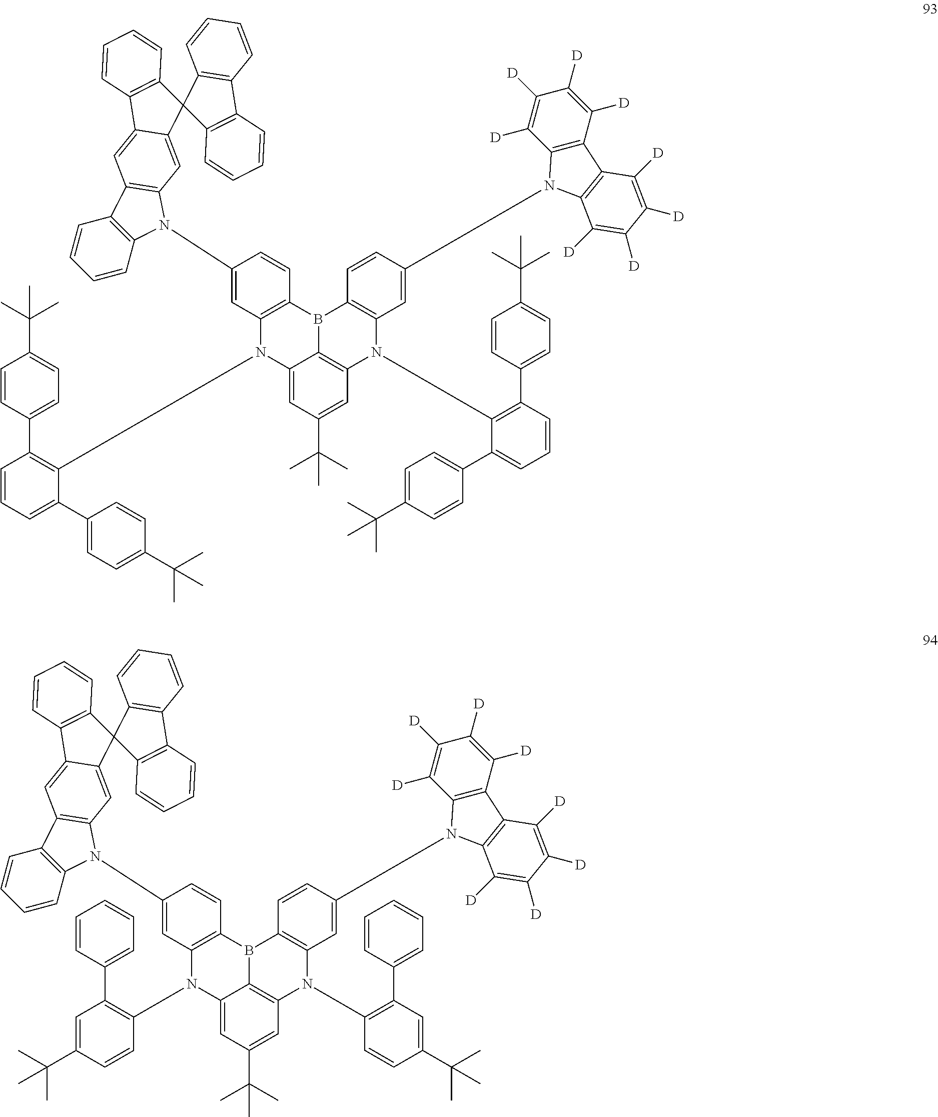 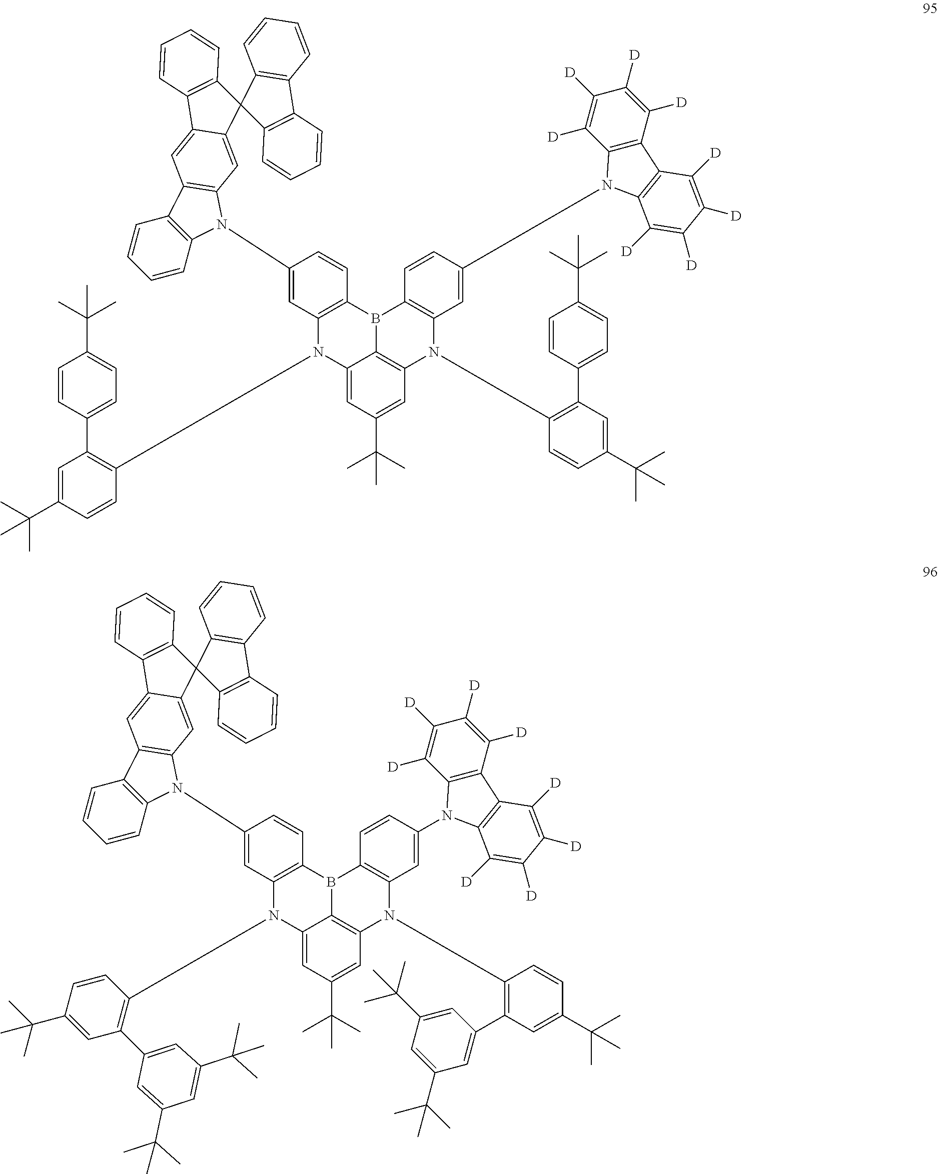 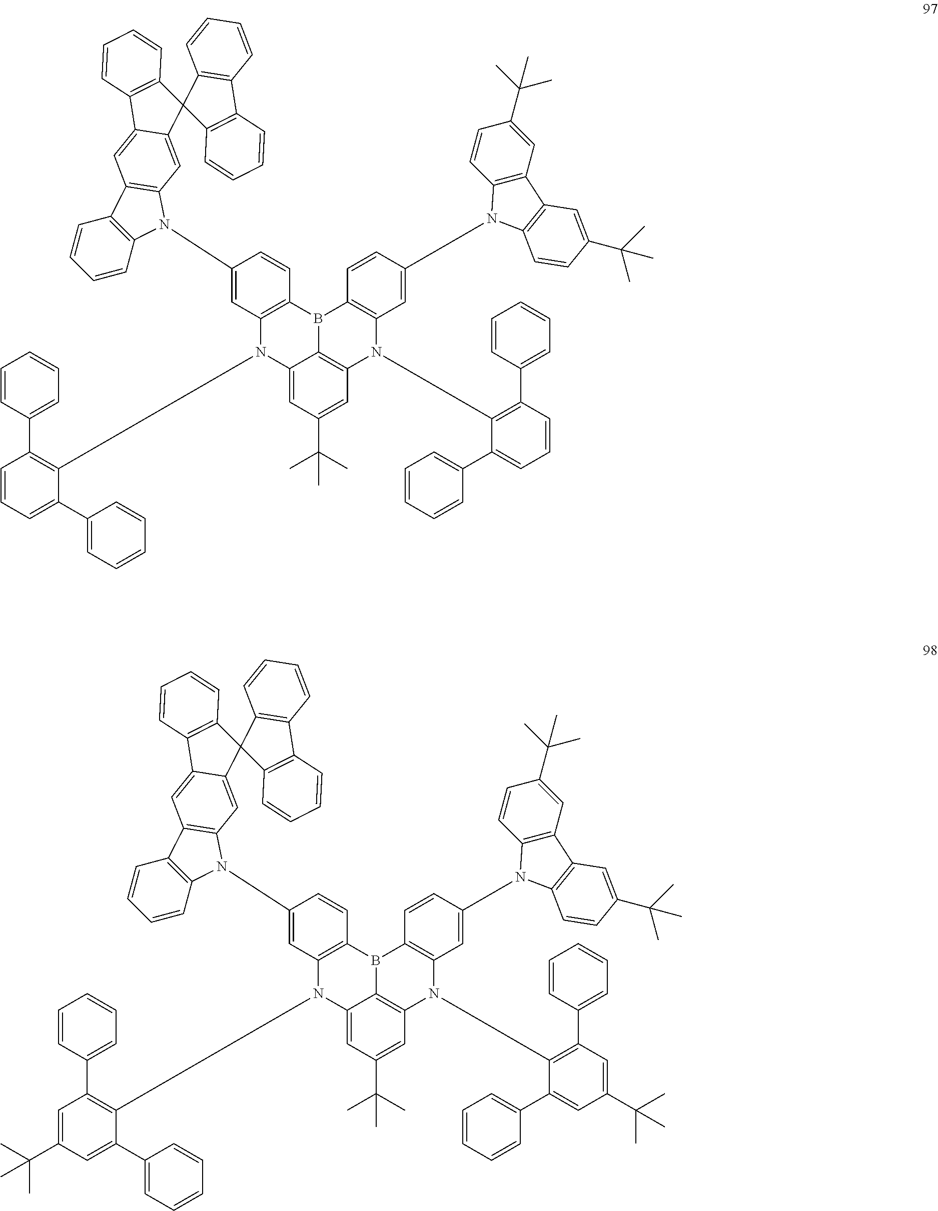 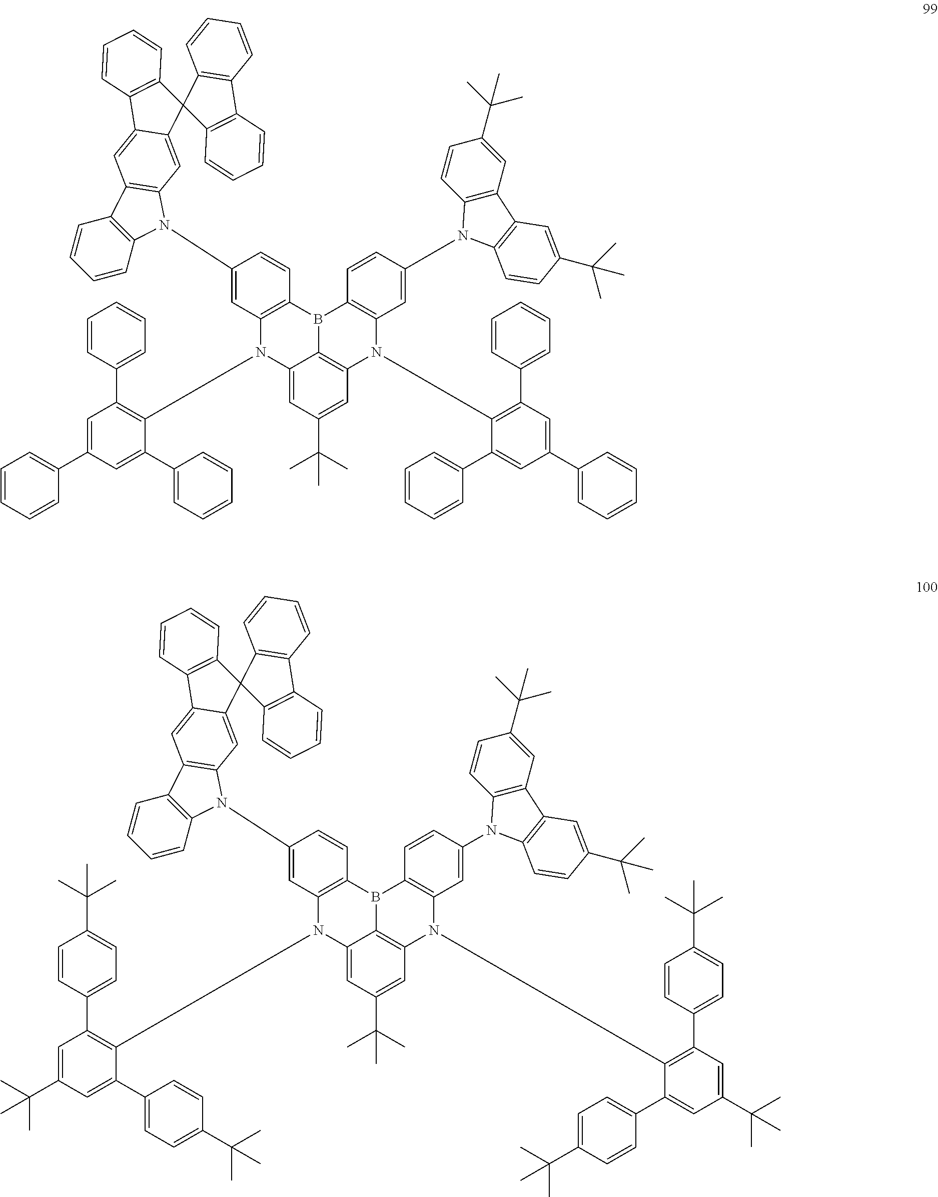 [SMILES: CC(C)(C)c1cc2c3c(c1)N(CCCc1c(-c4ccccc4)cc(-c4ccccc4)cc1-c1ccccc1)c1cc(-n4c5ccccc5c5cc6c(cc54)C4(c5ccccc5-c5ccccc54)c4ccccc4-6)ccc1B3c1ccc(Cn3c4ccc(C(C)(C)C)cc4c4cc(C(C)(C)C)ccc43)cc1N2CCCc1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2CCCCCCCN2c3cc(-n4c5ccc(C(C)(C)C)cc5c5cc(C(C)(C)C)ccc54)ccc3B3c4ccc(-n5c6ccccc6c6cc7c(cc65)C5(c6ccccc6-c6ccccc65)c5ccccc5-7)cc4N(CCCCCCc4c(-c5ccc(C(C)(C)C)cc5)cc(C(C)(C)C)cc4-c4ccc(C(C)(C)C)cc4)c4cc(C(C)(C)C)cc2c43)cc1] 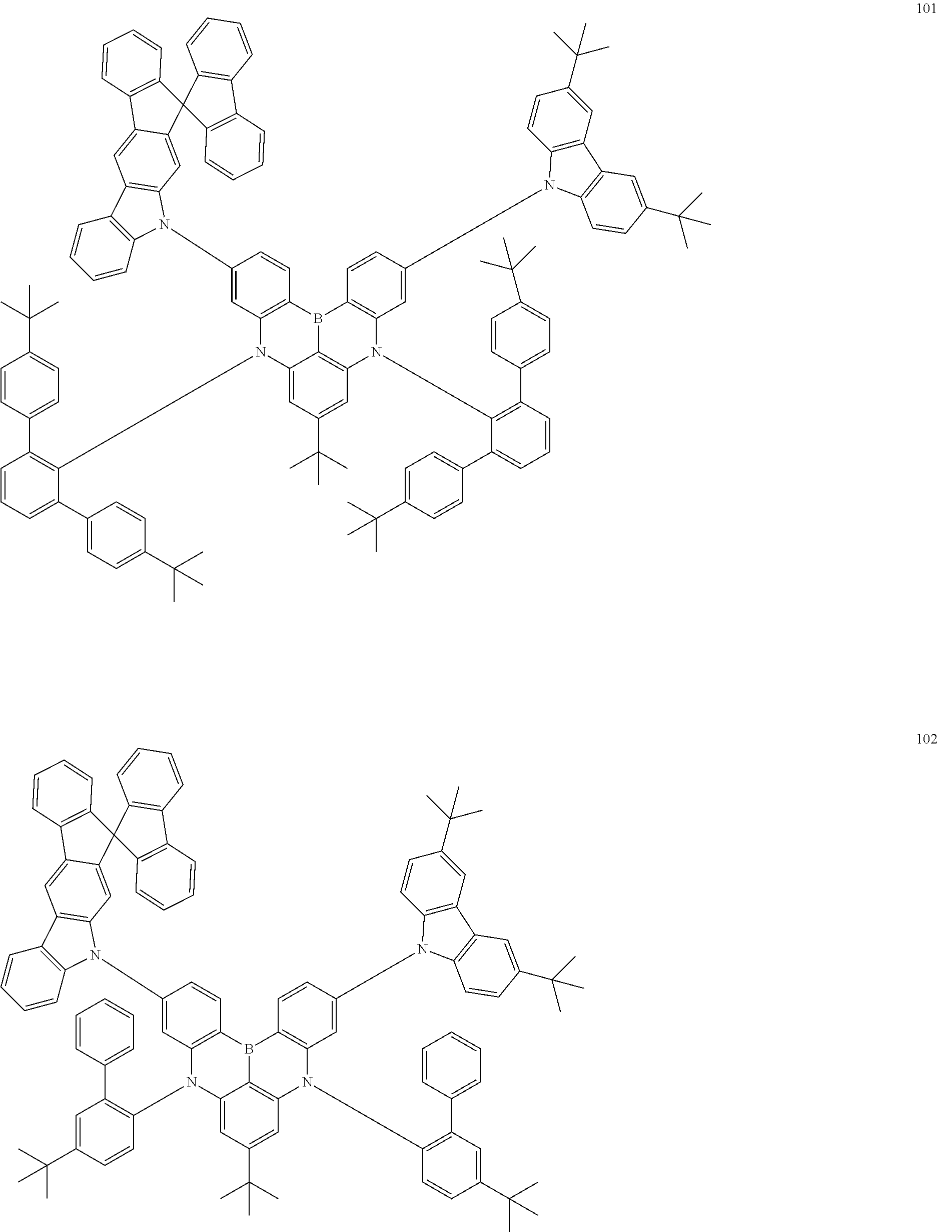 [SMILES: CC(C)(C)c1ccc(-c2cccc(-c3ccc(C(C)(C)C)cc3)c2CCCCCN2c3cc(-n4c5ccccc5c5cc6c(cc54)C4(c5ccccc5-c5ccccc54)c4ccccc4-6)ccc3B3c4ccc(CCCCn5c6ccc(C(C)(C)C)cc6c6cc(C(C)(C)C)ccc65)cc4N(CCCc4c(-c5ccc(C(C)(C)C)cc5)cccc4-c4ccc(C(C)(C)C)cc4)c4cc(C(C)(C)C)cc2c43)cc1 ; CC(C)(C)c1ccc(CCCN2c3cc(CCn4c5ccc(C(C)(C)C)cc5c5cc(C(C)(C)C)ccc54)ccc3B3c4ccc(-n5c6ccccc6c6cc7c(cc65)C5(c6ccccc6-c6ccccc65)c5ccccc5-7)cc4N(Cc4ccc(C(C)(C)C)cc4-c4ccccc4)c4cc(C(C)(C)C)cc2c43)c(-c2ccccc2)c1] 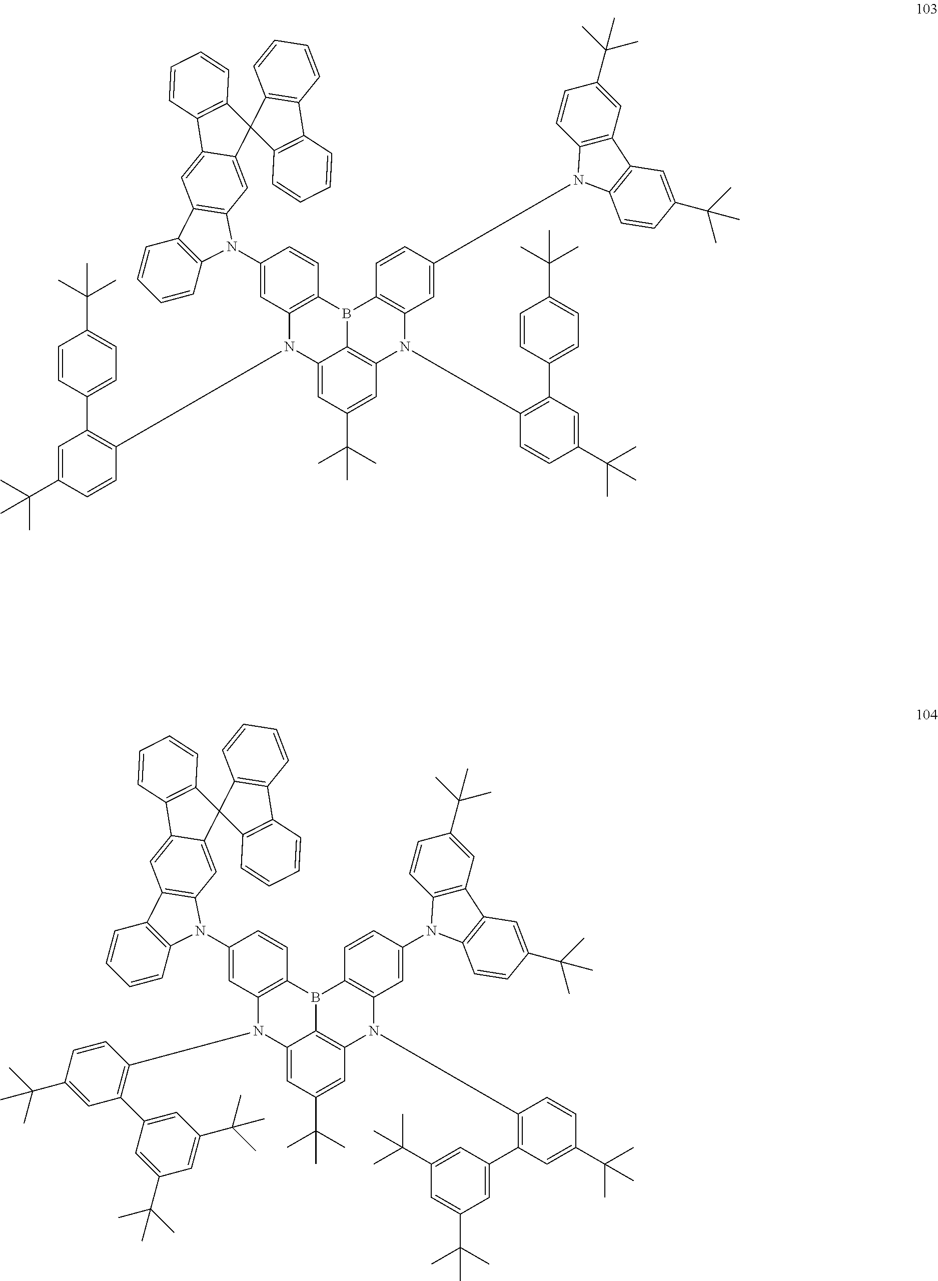 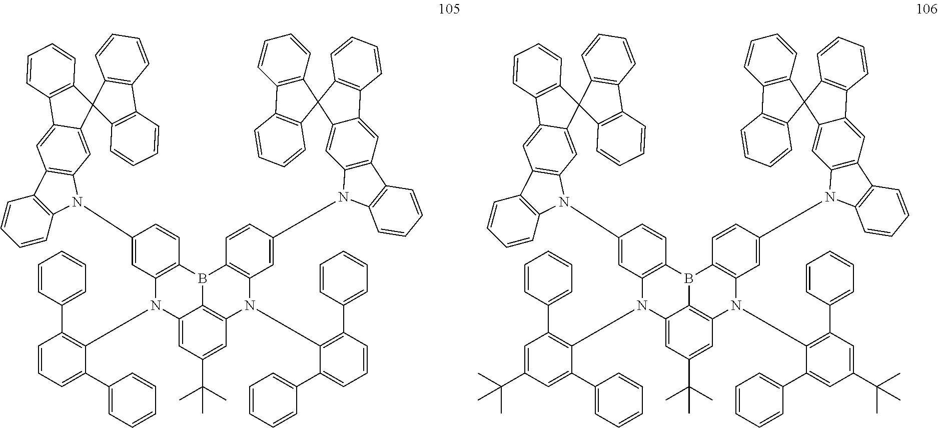 [SMILES: CC(C)(C)c1cc2c3c(c1)N(CCc1c(-c4ccccc4)cccc1-c1ccccc1)c1cc(-n4c5ccccc5c5cc6c(cc54)C4(c5ccccc5-c5ccccc54)c4ccccc4-6)ccc1B3c1ccc(CCn3c4ccccc4c4cc5c(cc43)C3(c4ccccc4-c4ccccc43)c3ccccc3-5)cc1N2CCc1c(-c2ccccc2)cccc1-c1ccccc1 ; CC(C)(C)c1cc(-c2ccccc2)c(CCN2c3cc(CCn4c5ccccc5c5cc6c(cc54)C4(c5ccccc5-c5ccccc54)c4ccccc4-6)ccc3B3c4ccc(-n5c6ccccc6c6cc7c(cc65)C5(c6ccccc6-c6ccccc65)c5ccccc5-7)cc4N(CCc4c(-c5ccccc5)cc(C(C)(C)C)cc4-c4ccccc4)c4cc(C(C)(C)C)cc2c43)c(-c2ccccc2)c1] 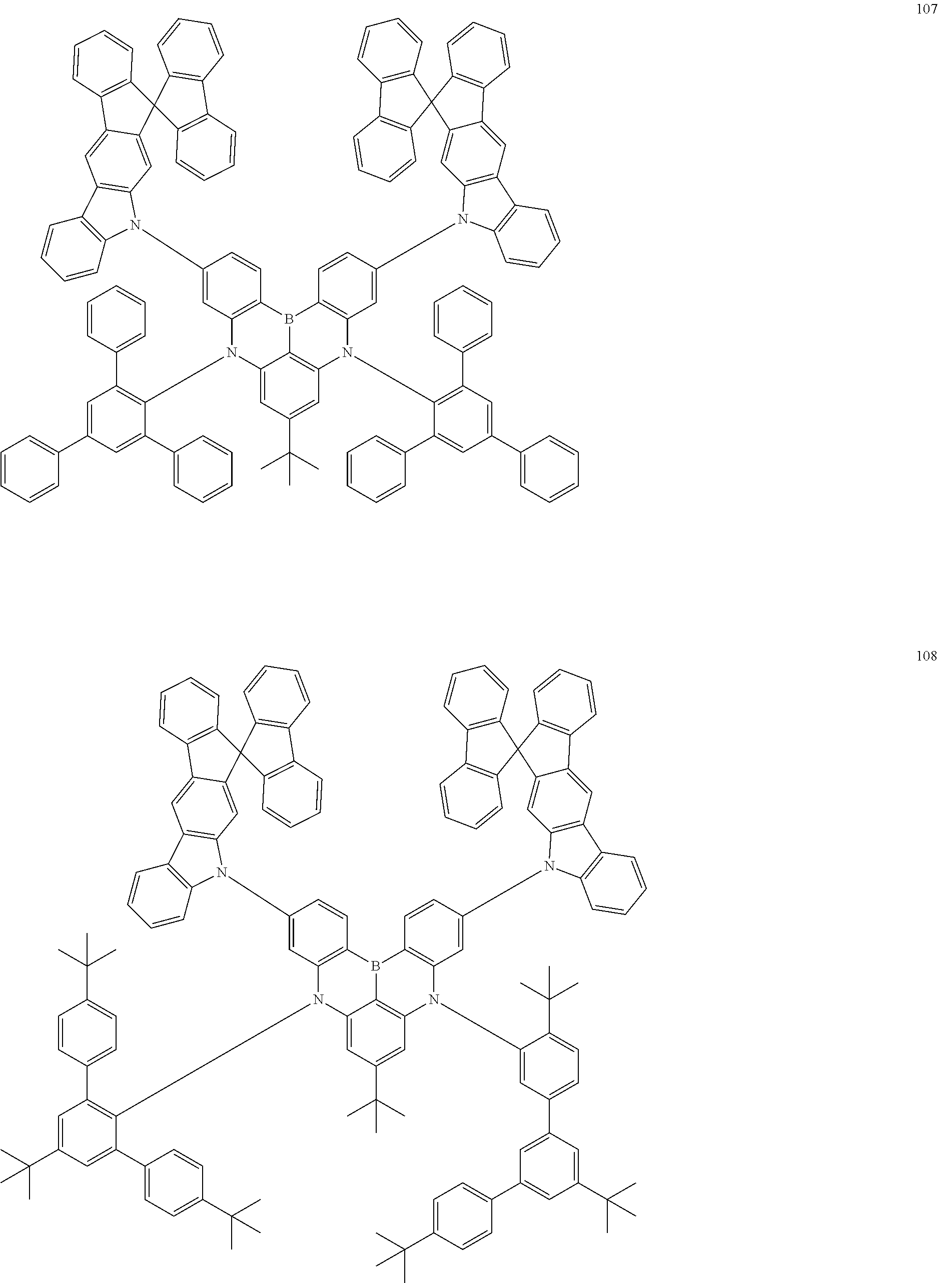 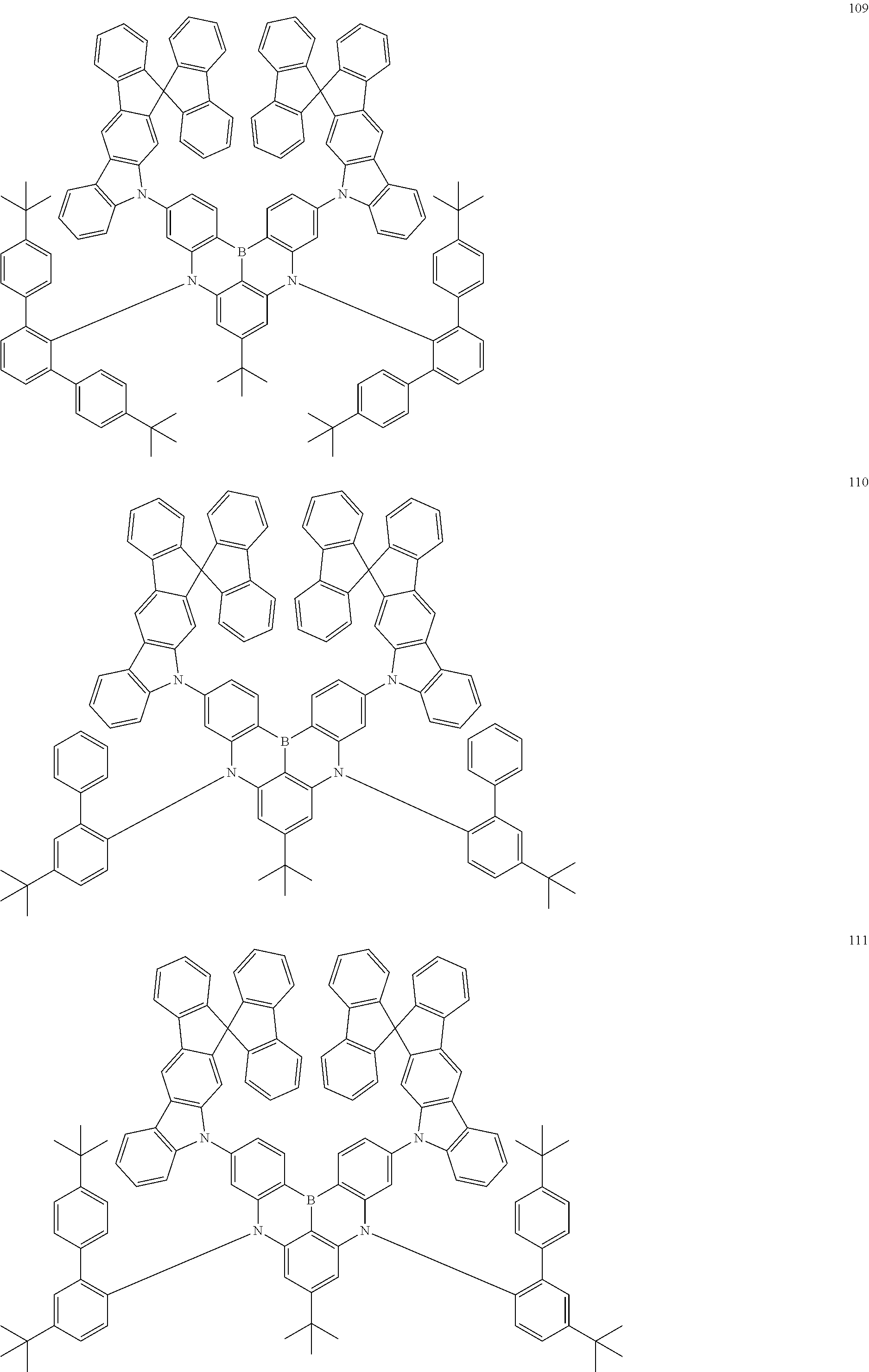 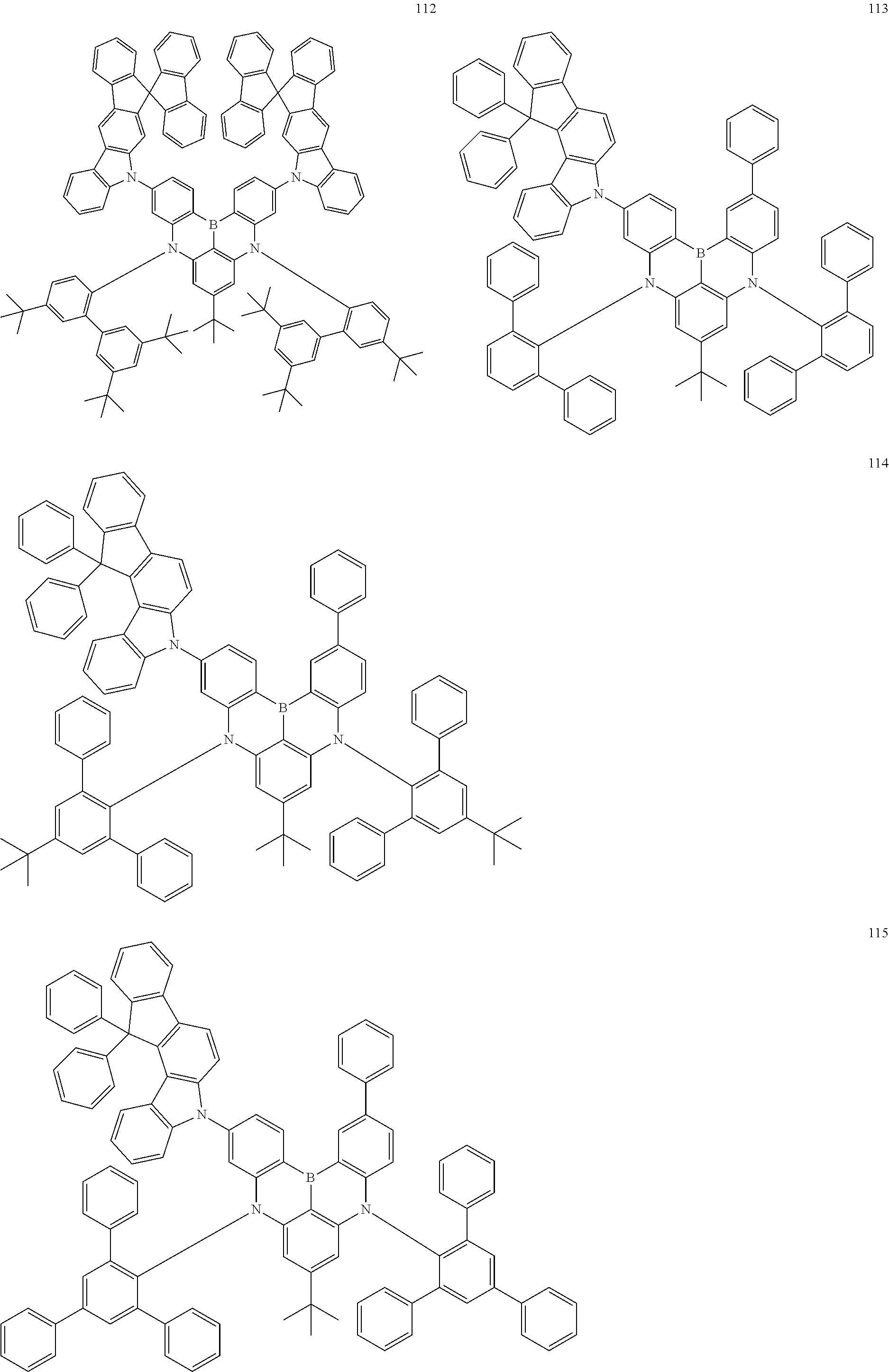 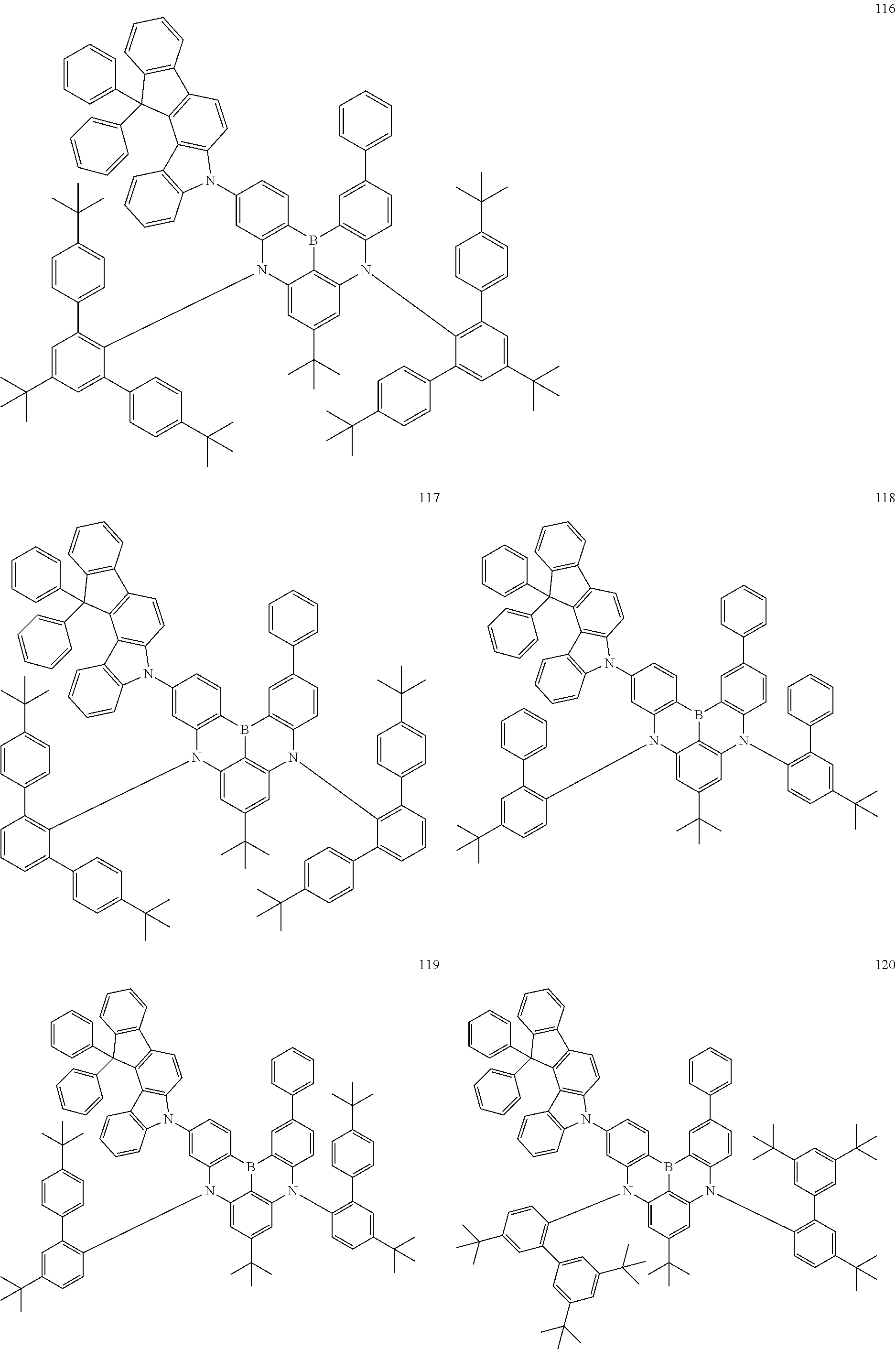 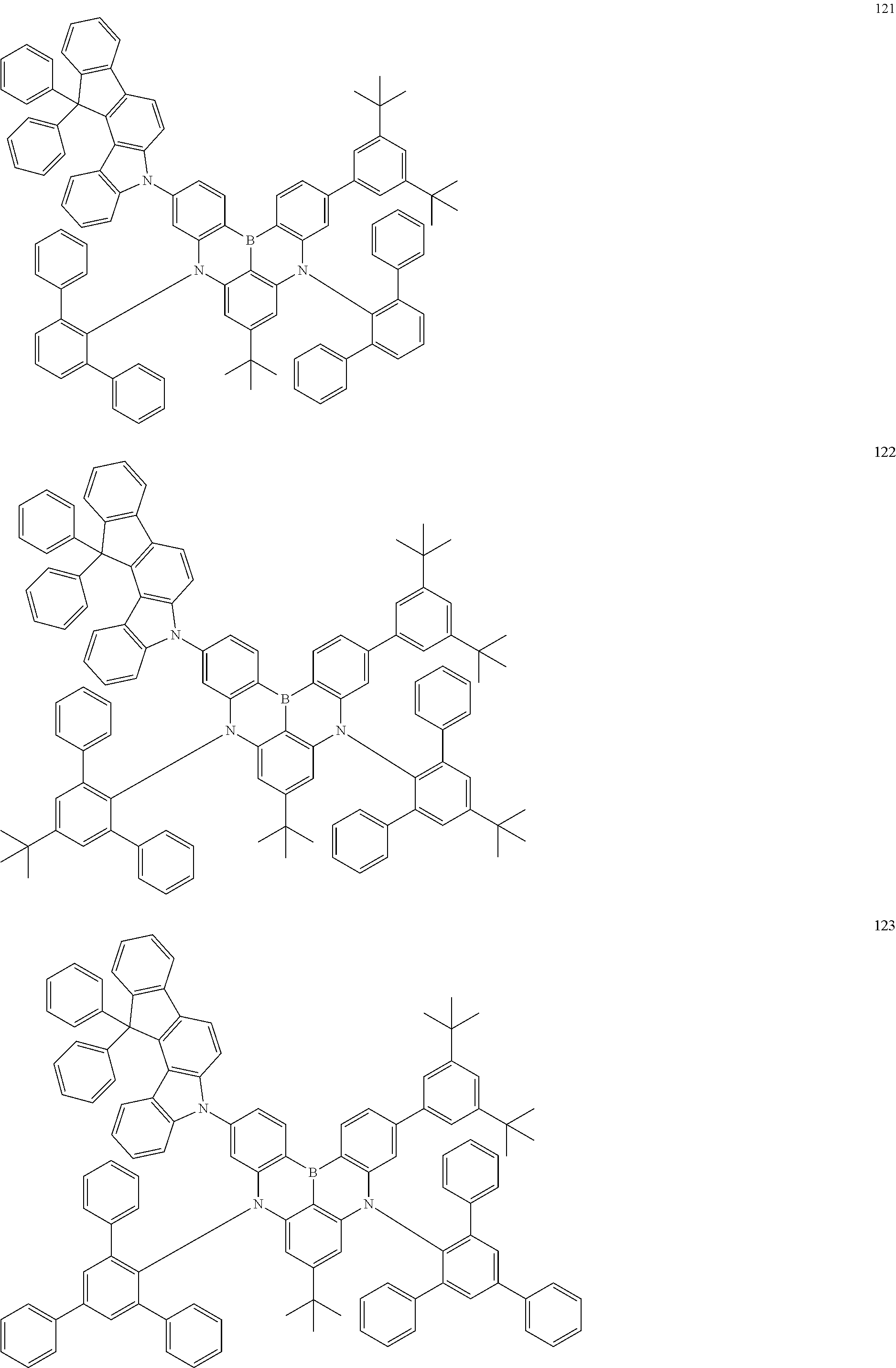 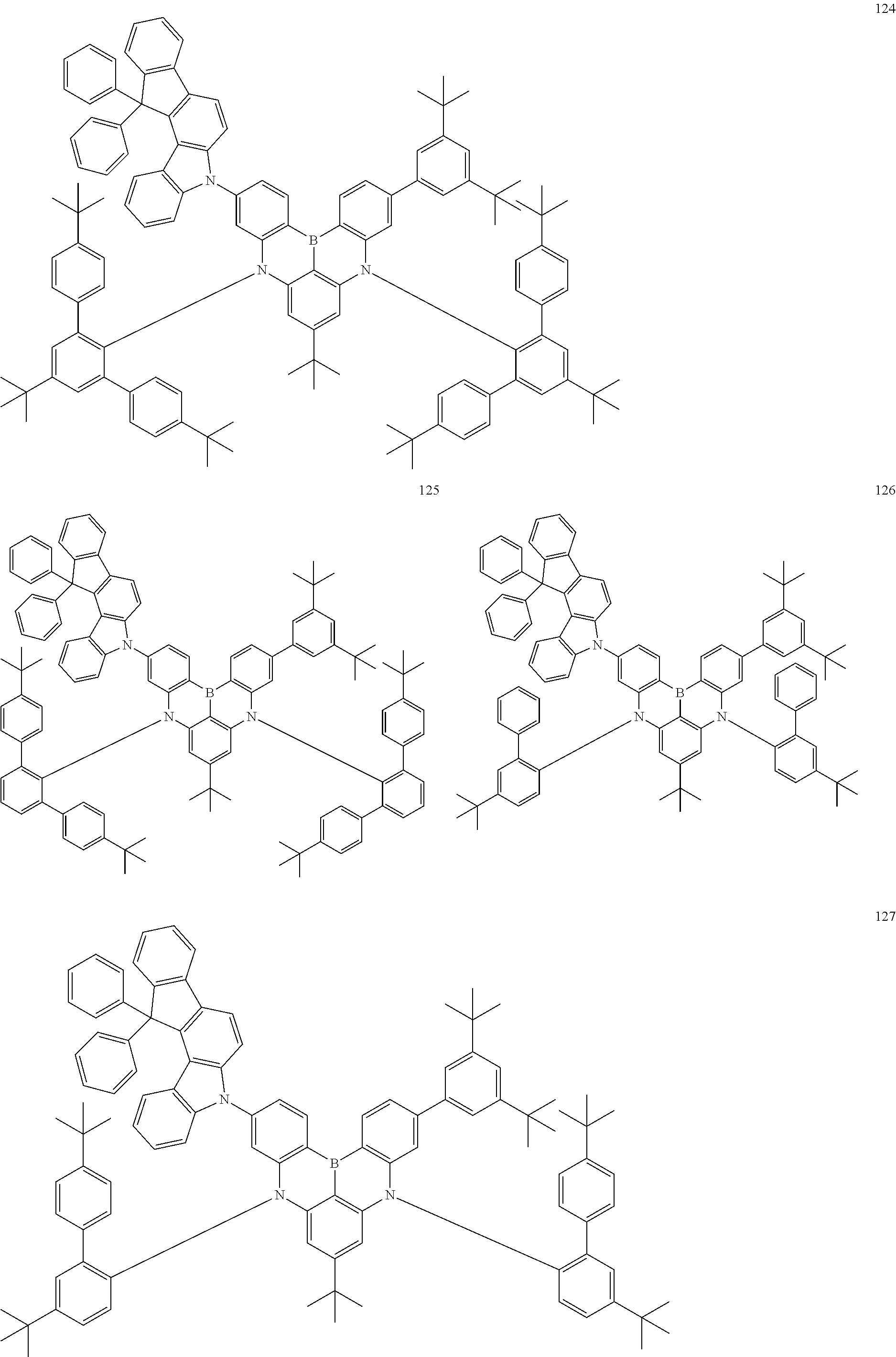 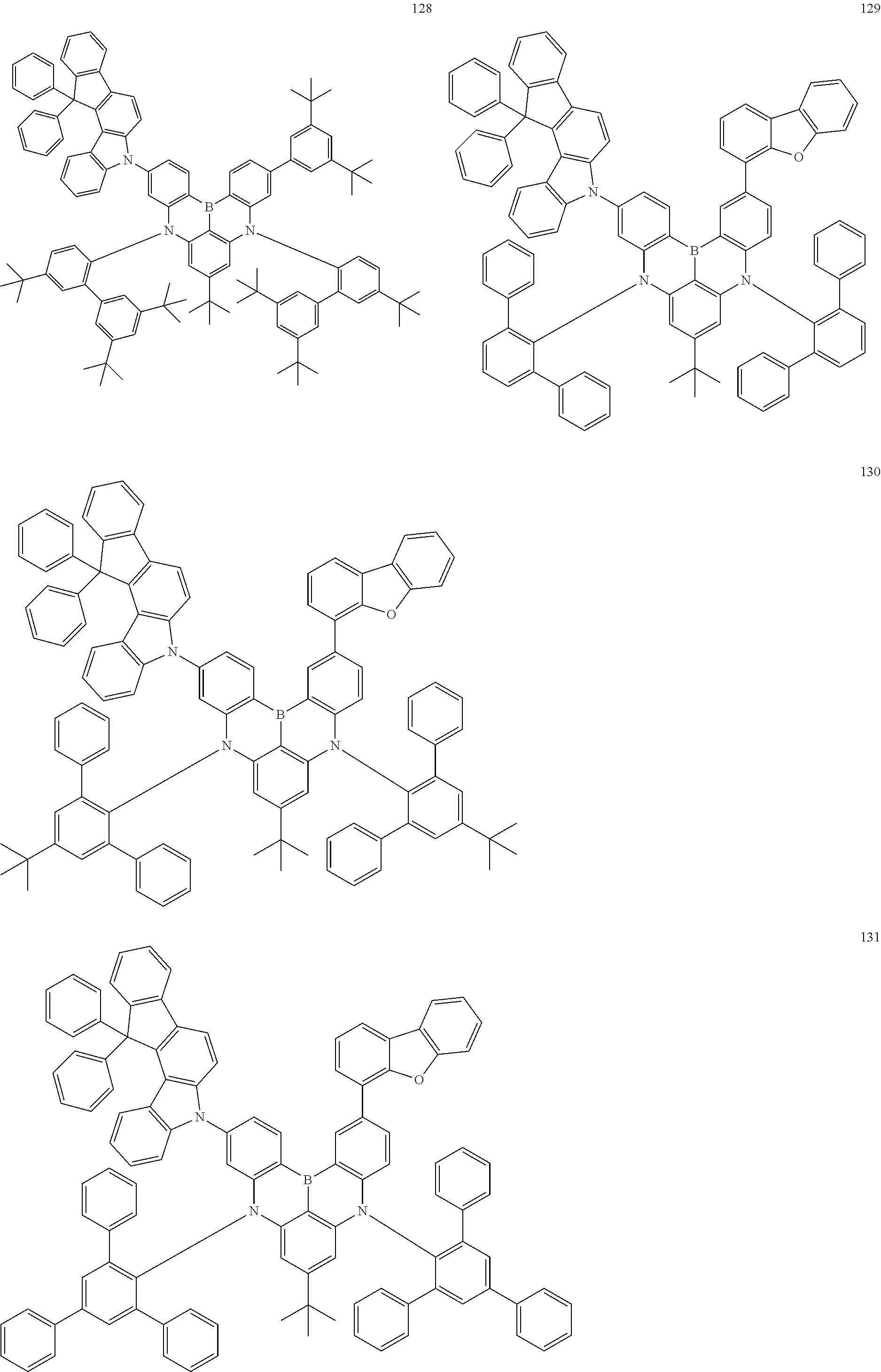 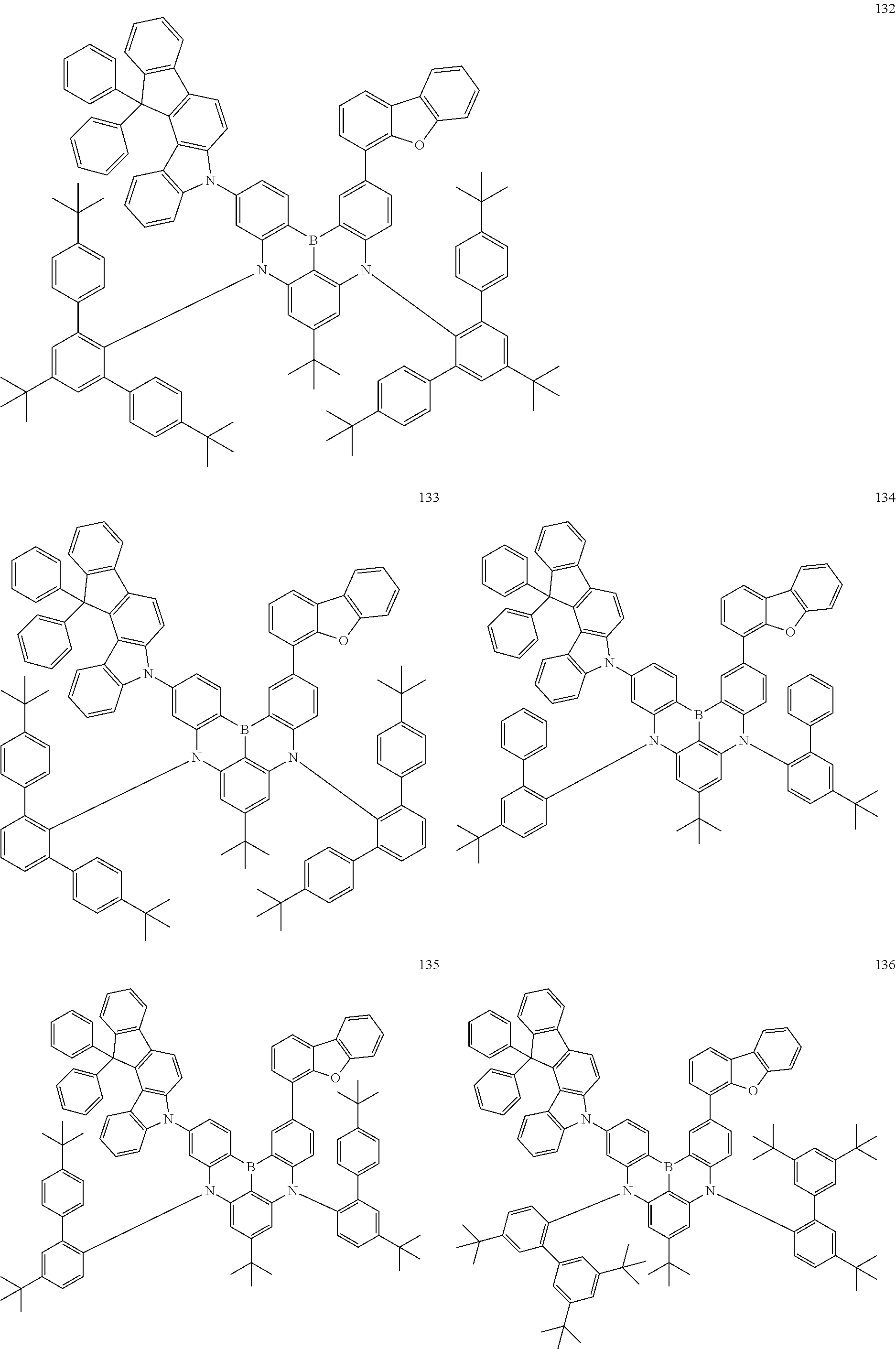 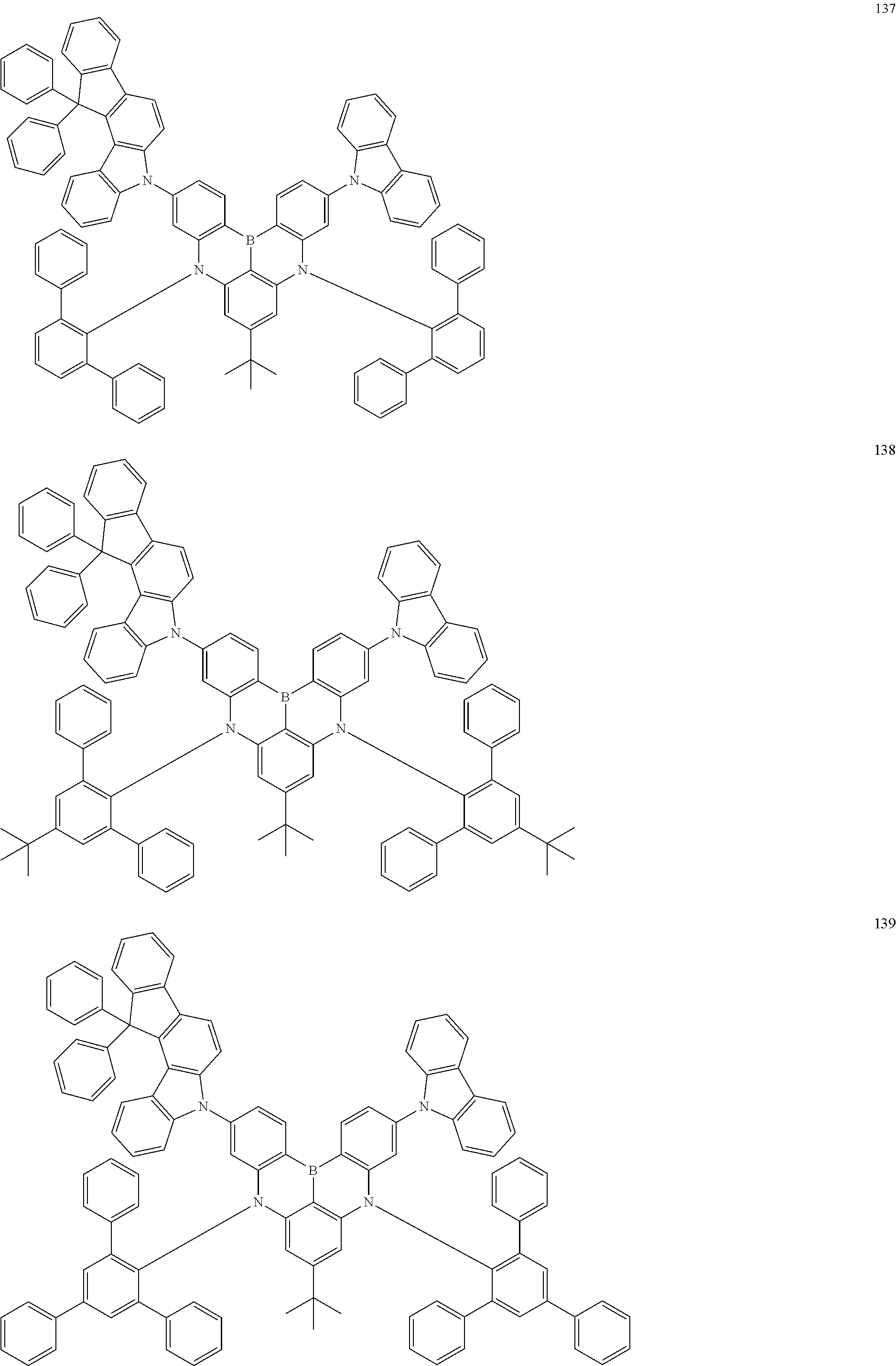 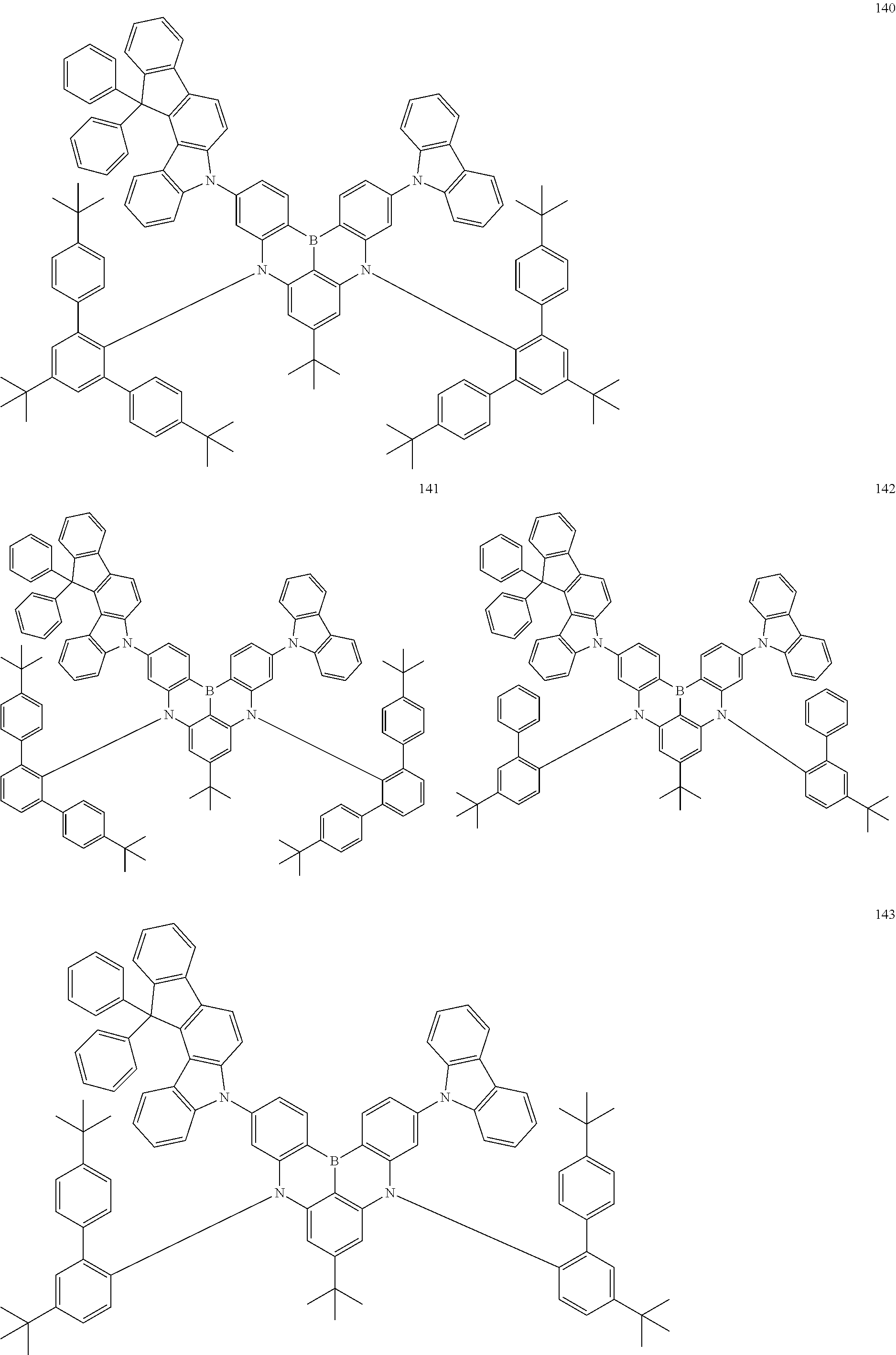 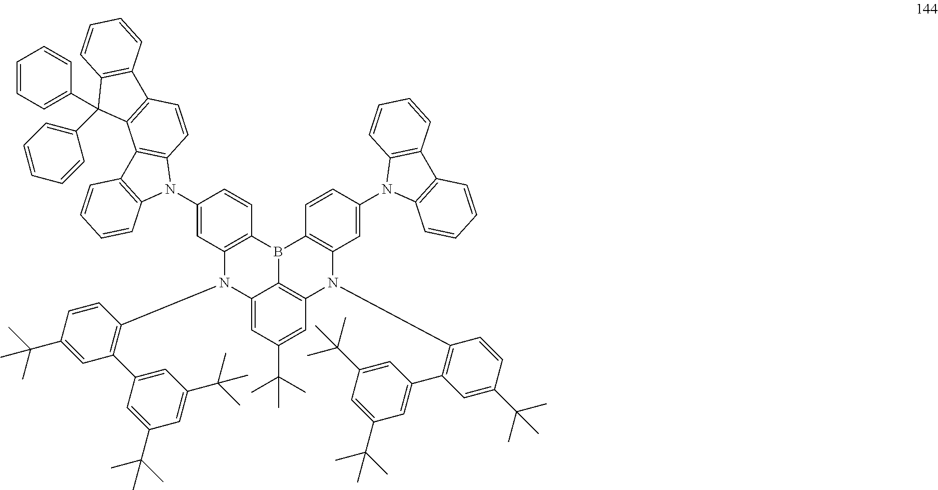 [SMILES: CC(C)(C)c1cc(-c2cc(C(C)(C)C)ccc2N2c3cc(-n4c5ccccc5c5ccccc54)ccc3B3c4ccc(-n5c6ccccc6c6c7c(ccc65)-c5ccccc5C7(c5ccccc5)c5ccccc5)cc4N(c4ccc(C(C)(C)C)cc4-c4cc(C(C)(C)C)cc(C(C)(C)C)c4)c4cc(C(C)(C)C)cc2c43)cc(C(C)(C)C)c1] 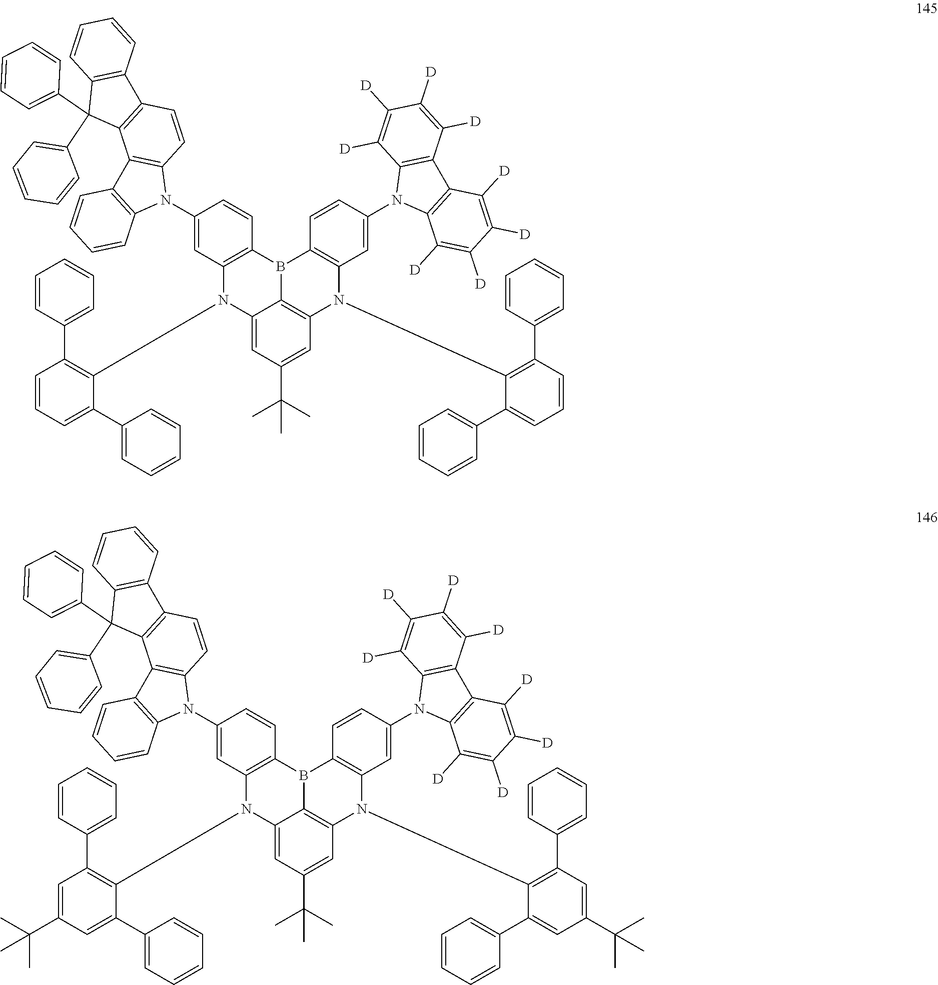 [SMILES: [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4c5c(ccc42)-c2ccccc2C5(c2ccccc2)c2ccccc2)cc1N3c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C(C)(C)C)cc3c1B2c1ccc(-n2c4ccccc4c4c5c(ccc42)-c2ccccc2C5(c2ccccc2)c2ccccc2)cc1N3c1c(-c2ccccc2)cc(C(C)(C)C)cc1-c1ccccc1] 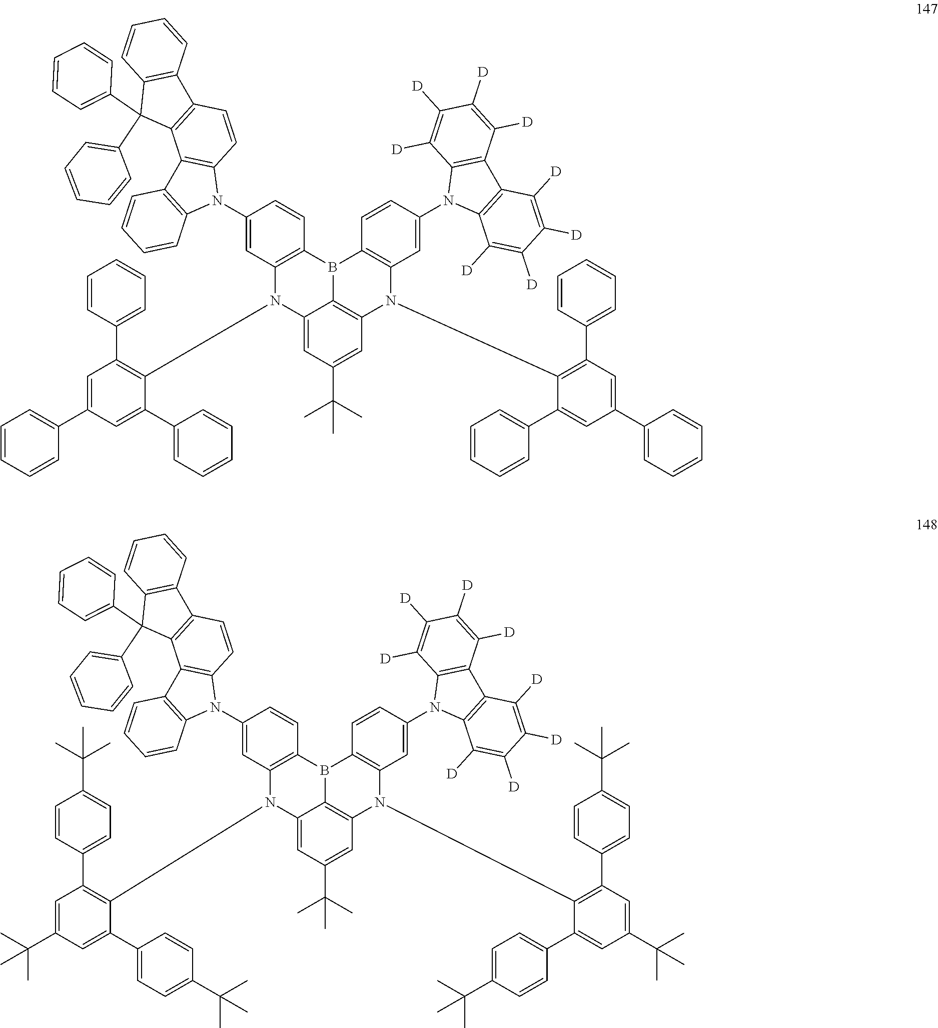 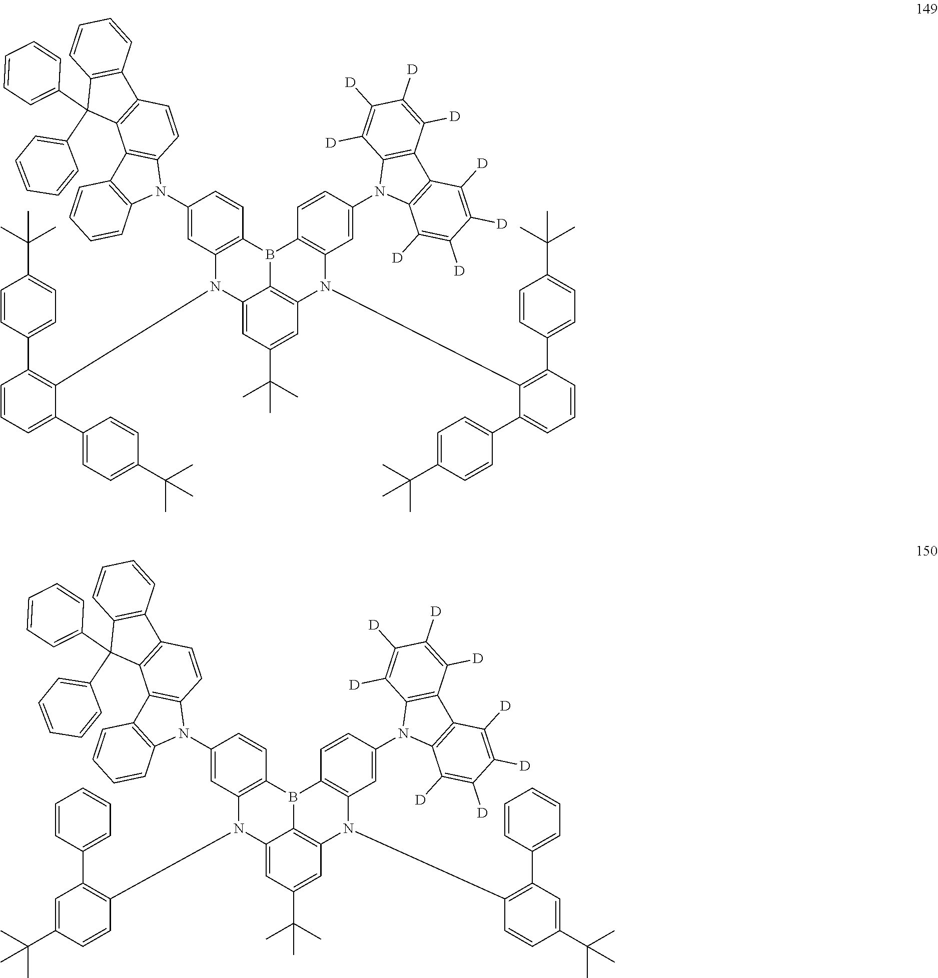 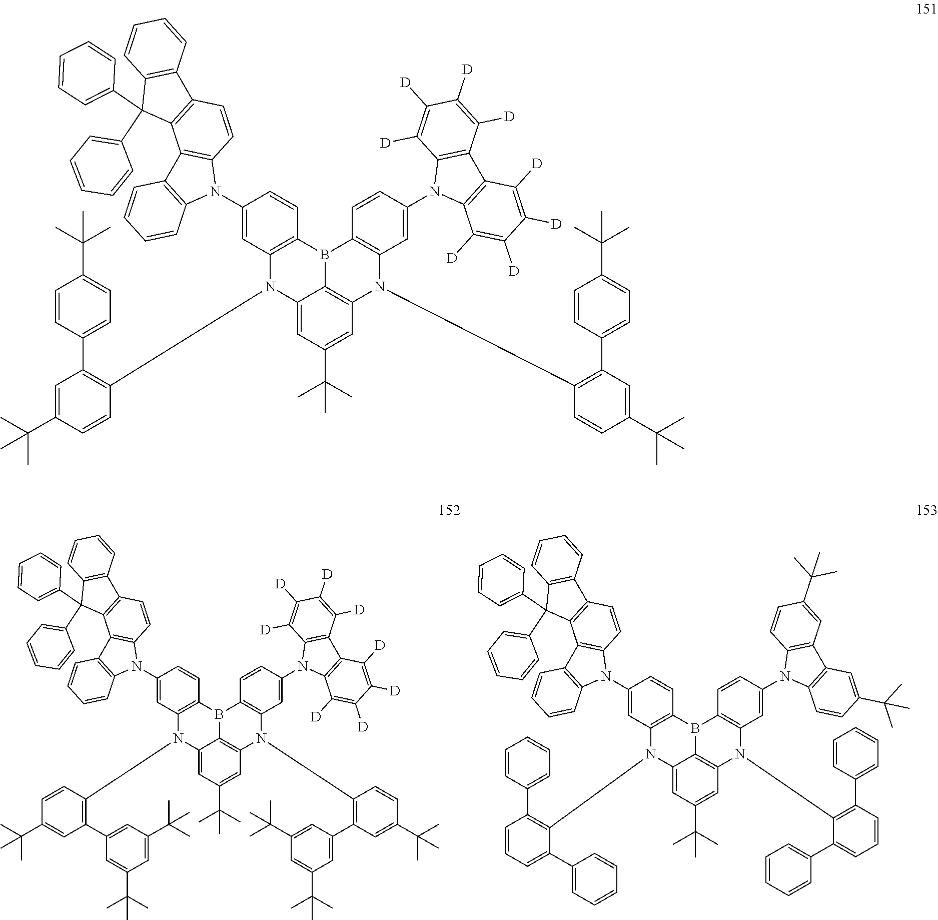 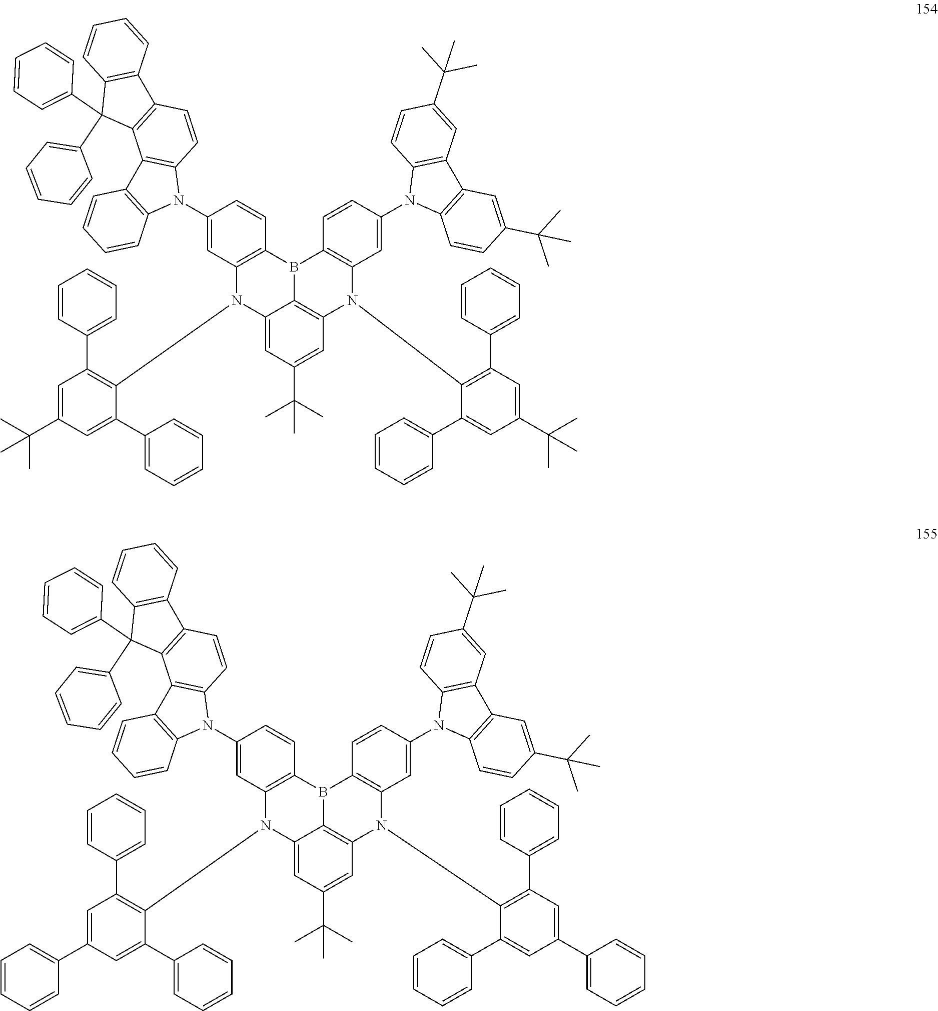 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C6(c4ccccc4)c4ccccc4)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1] 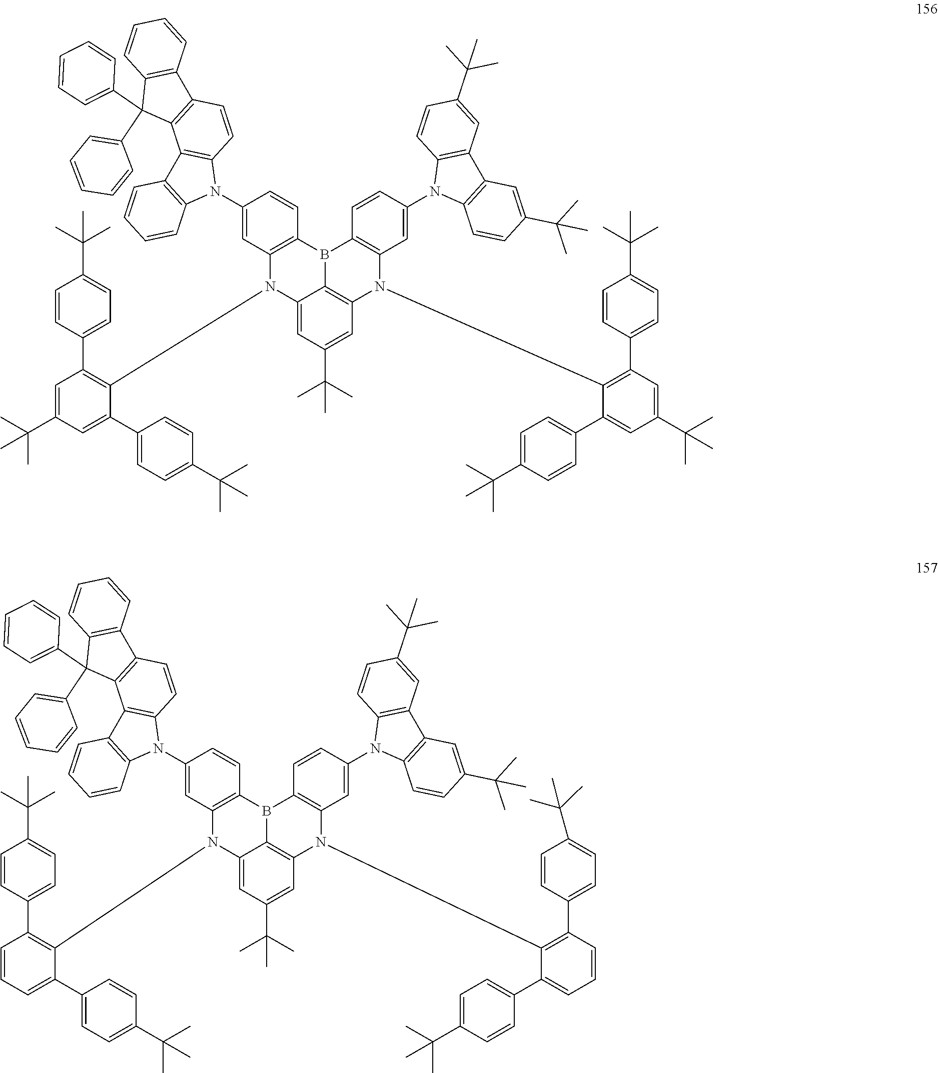 [SMILES: CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1] 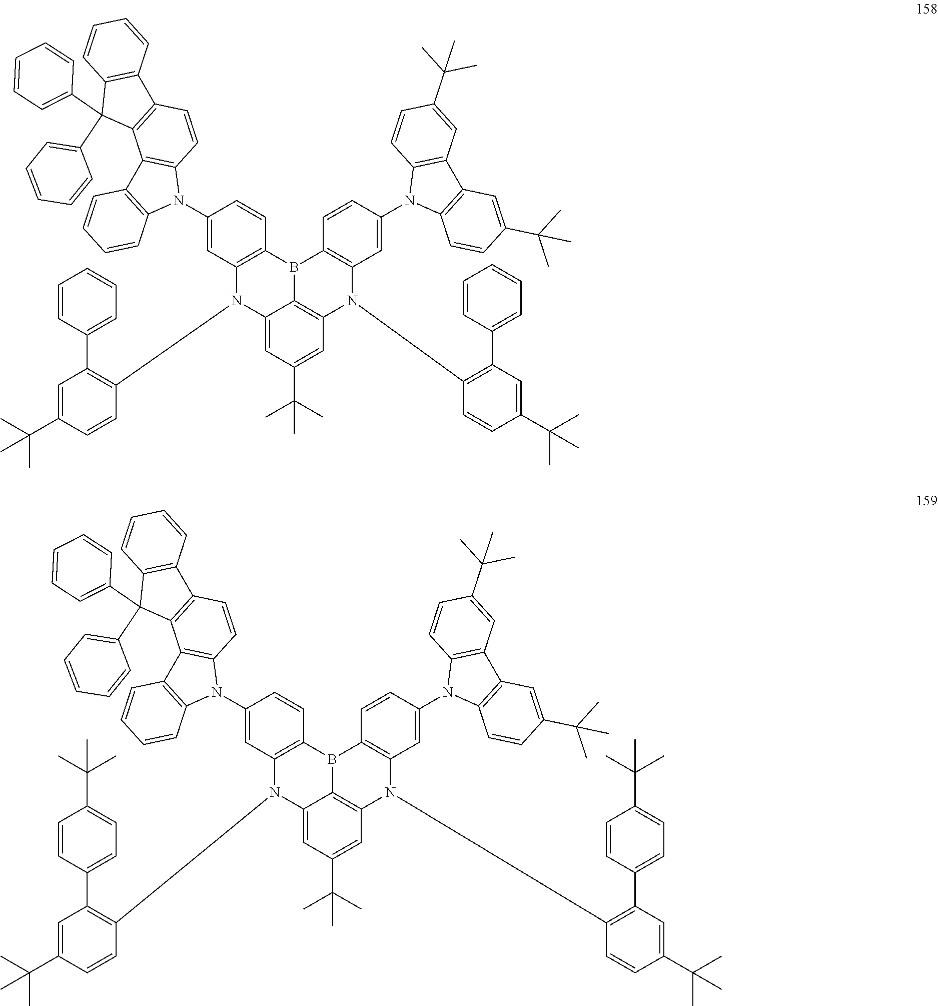 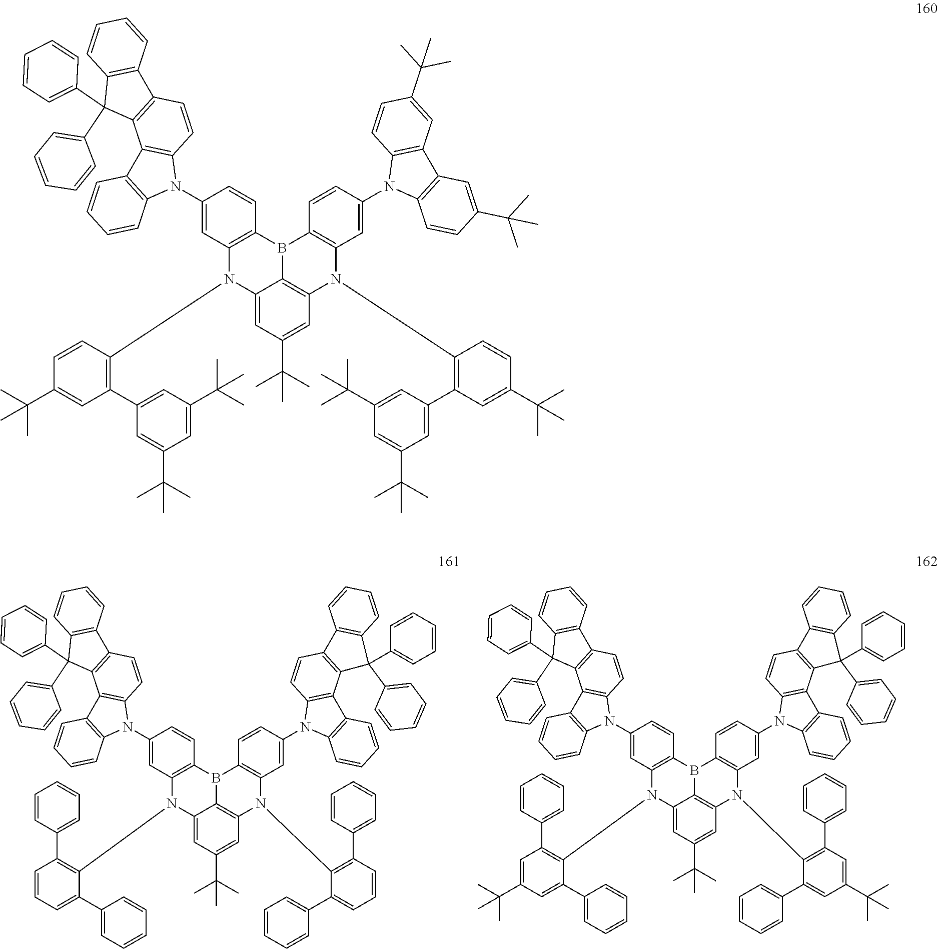 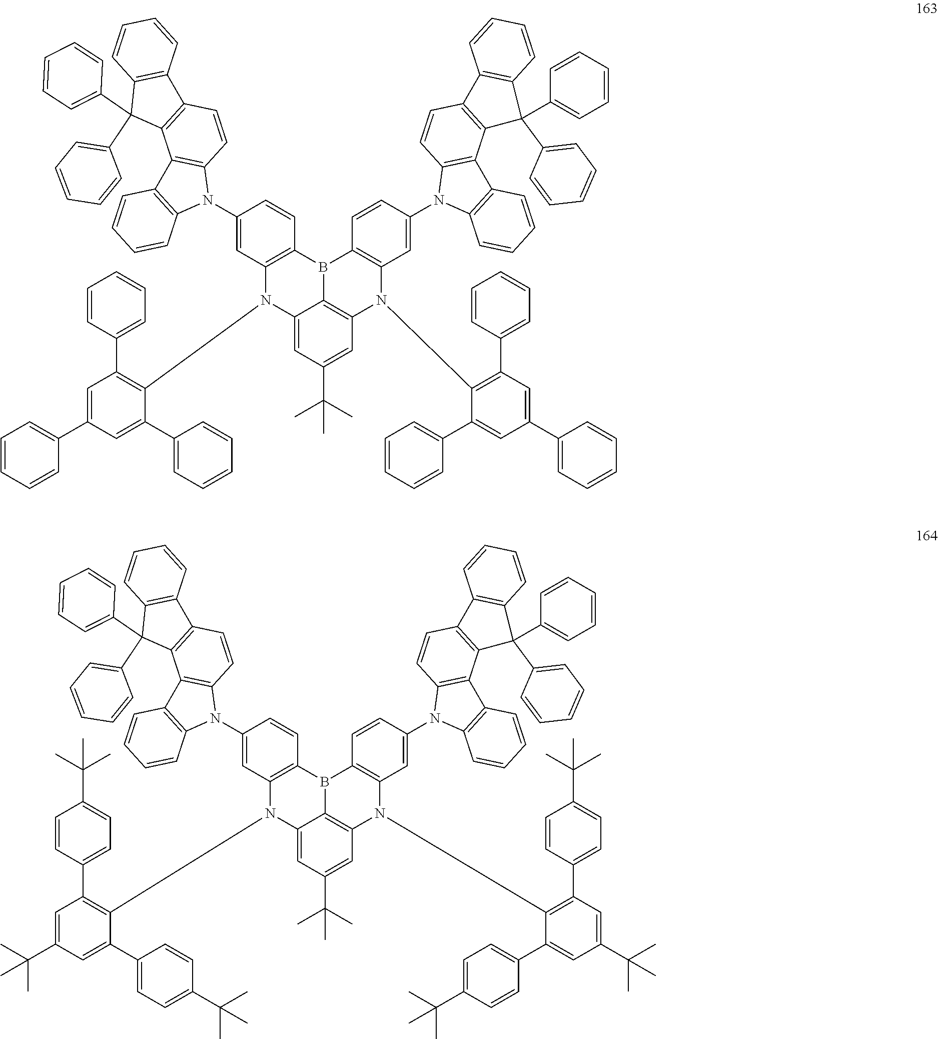 [SMILES: CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C6(c4ccccc4)c4ccccc4)ccc1B3c1ccc(-n3c4ccccc4c4c5c(ccc43)-c3ccccc3C5(c3ccccc3)c3ccccc3)cc1N2c1c(-c2ccccc2)cc(-c2ccccc2)cc1-c1ccccc1 ; CC(C)(C)c1ccc(-c2cc(C(C)(C)C)cc(-c3ccc(C(C)(C)C)cc3)c2N2c3cc(-n4c5ccccc5c5c6c(ccc54)-c4ccccc4C6(c4ccccc4)c4ccccc4)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 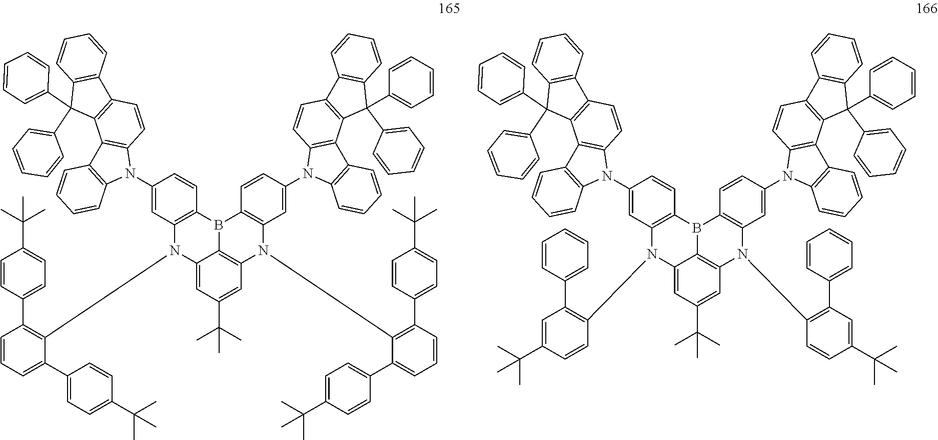 [SMILES: CC(C)(C)c1ccc(-c2cccc(-c3ccc(C(C)(C)C)cc3)c2N2c3cc(-n4c5ccccc5c5c6c(ccc54)-c4ccccc4C6(c4ccccc4)c4ccccc4)ccc3B3c4ccc(-n5c6ccccc6c6c7c(ccc65)-c5ccccc5C7(c5ccccc5)c5ccccc5)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1ccc(N2c3cc(-n4c5ccccc5c5c6c(ccc54)-c4ccccc4C6(c4ccccc4)c4ccccc4)ccc3B3c4ccc(-n5c6ccccc6c6c7c(ccc65)-c5ccccc5C7(c5ccccc5)c5ccccc5)cc4N(c4ccc(C(C)(C)C)cc4-c4ccccc4)c4cc(C(C)(C)C)cc2c43)c(-c2ccccc2)c1] 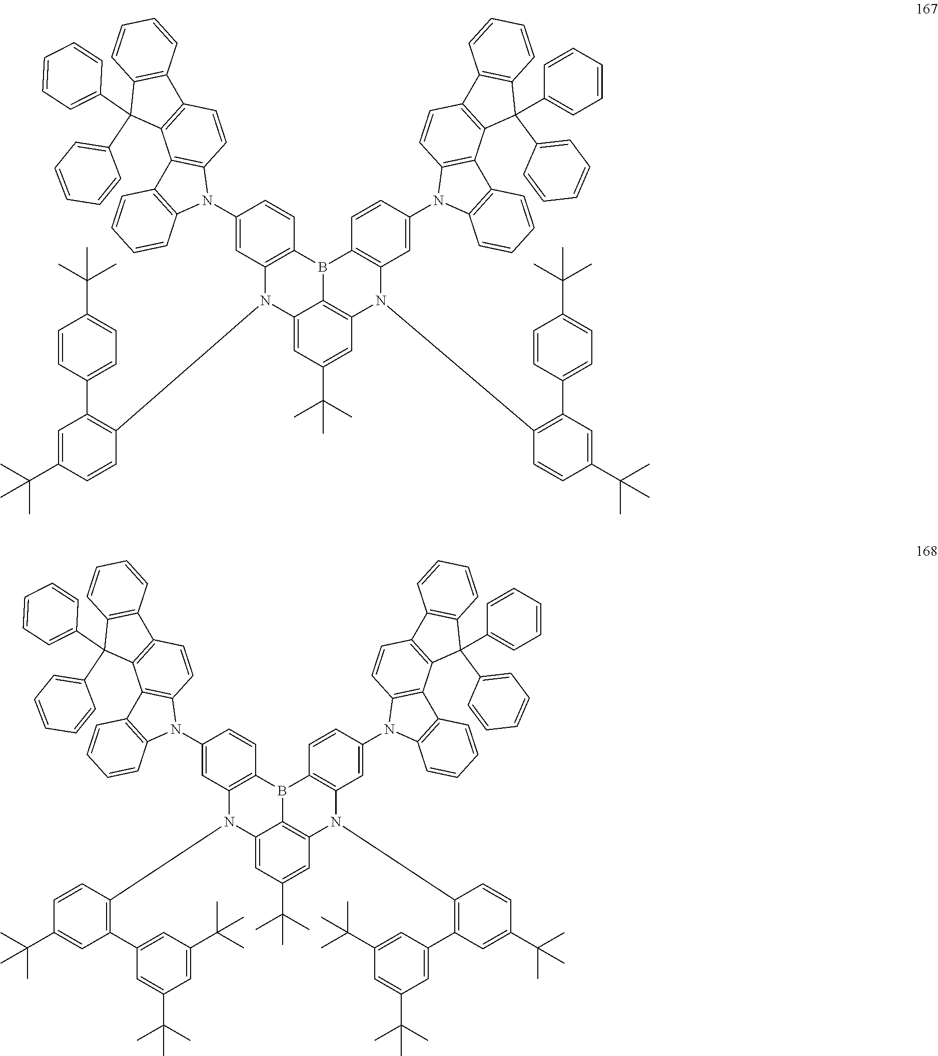 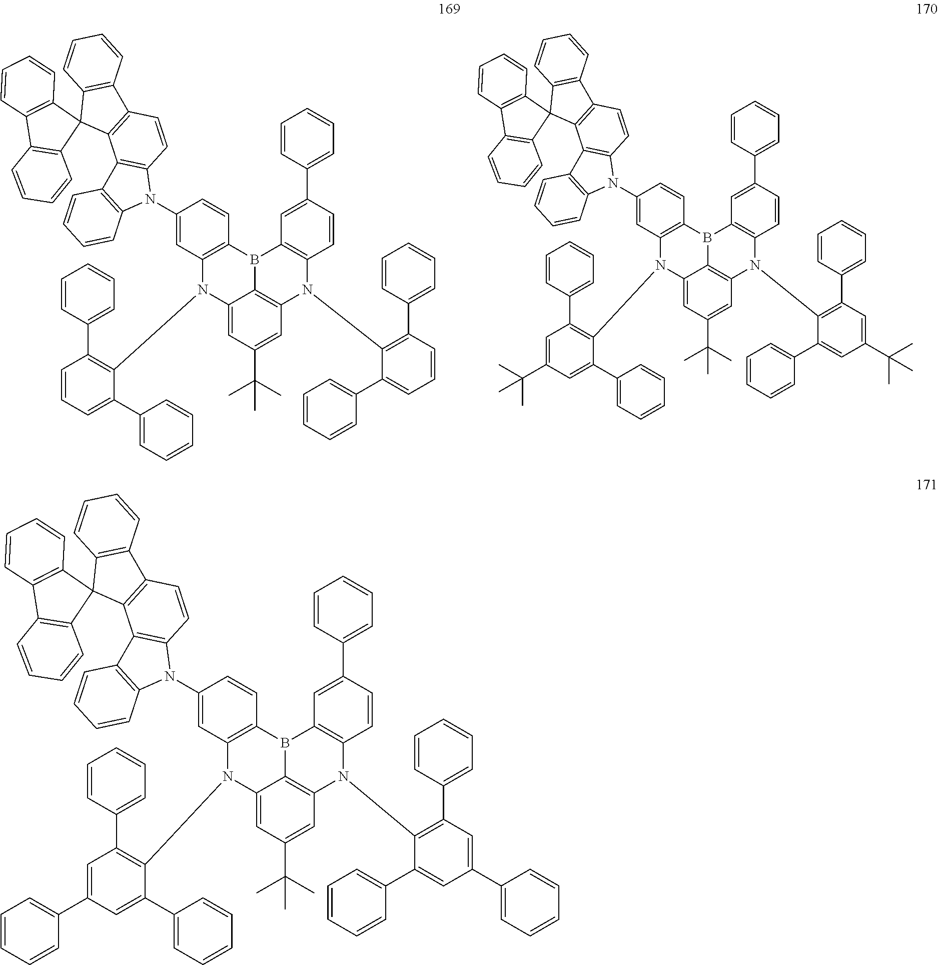 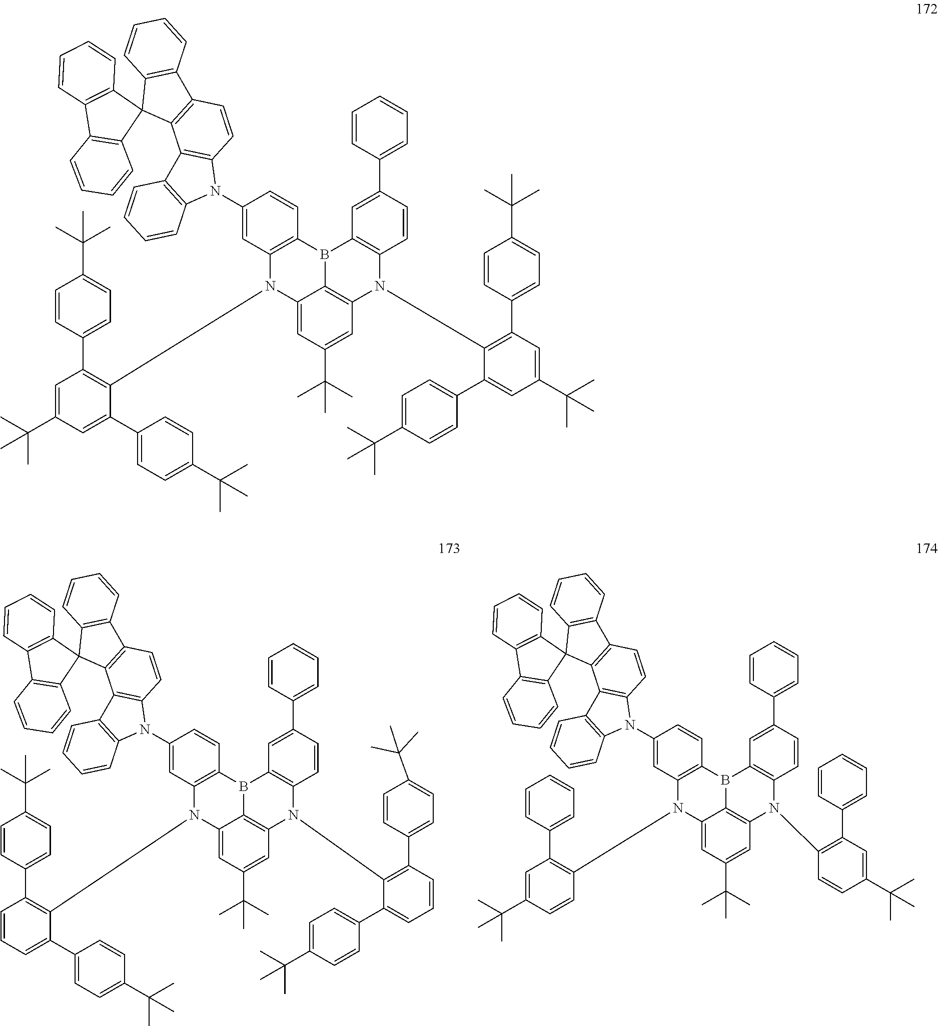 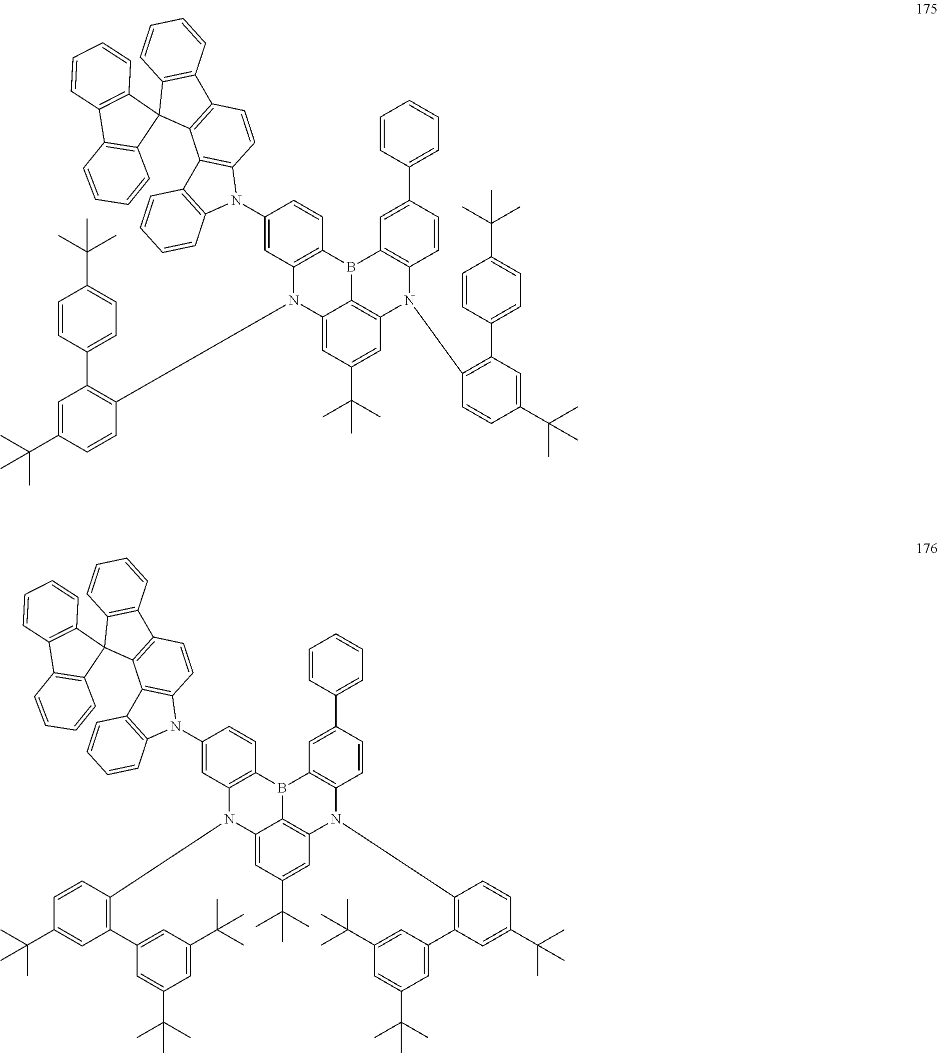 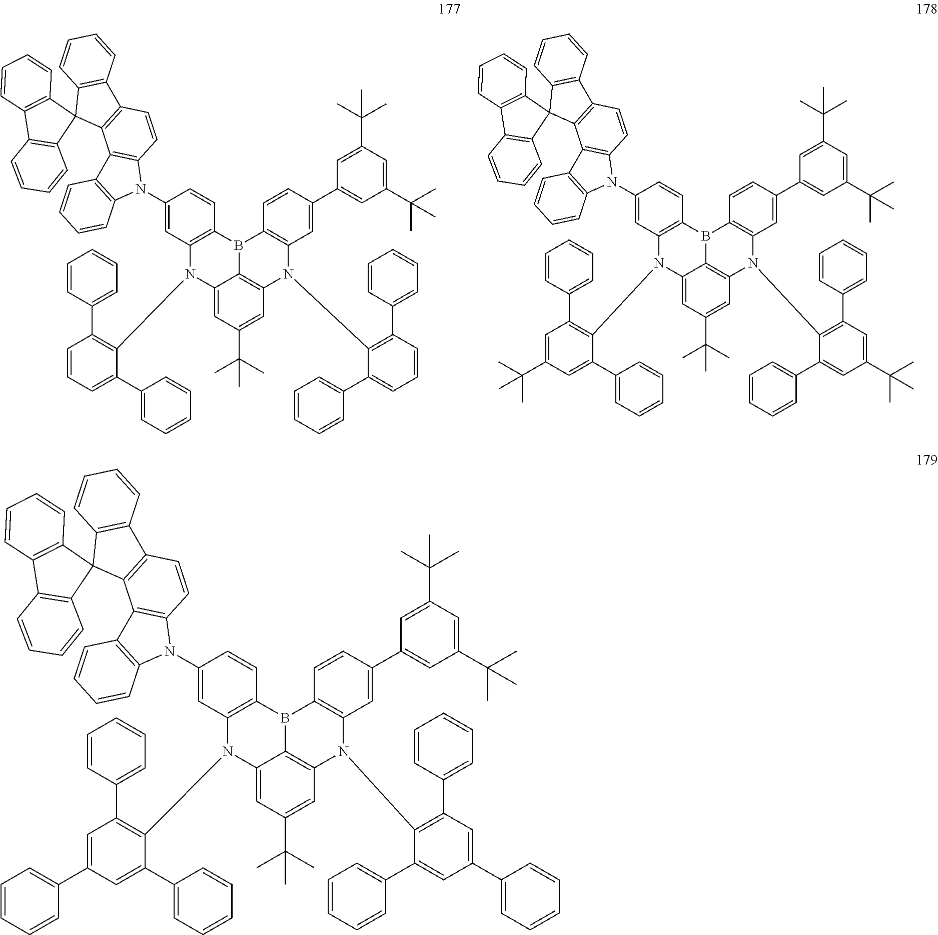 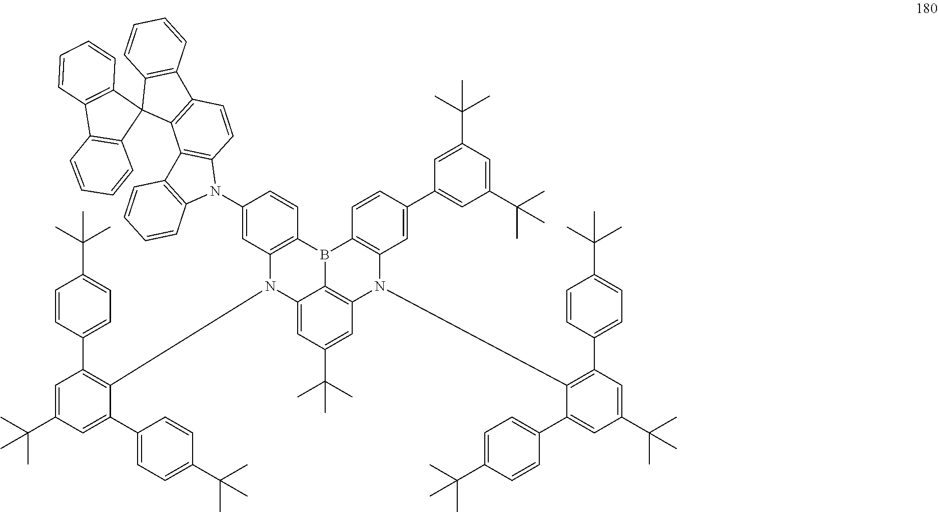 [SMILES: CC(C)(C)c1ccc(-c2cc(C(C)(C)C)cc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1] 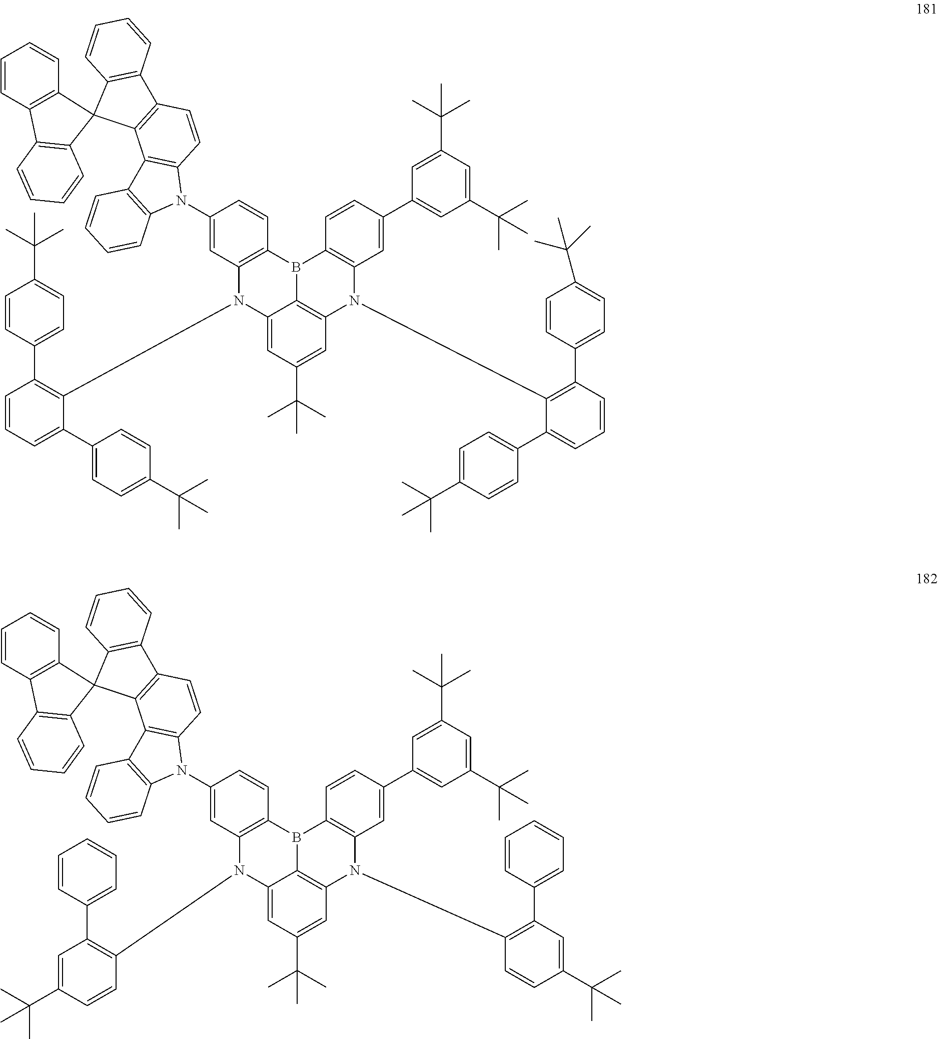 [SMILES: CC(C)(C)c1ccc(-c2cccc(-c3ccc(C(C)(C)C)cc3)c2N2c3cc(-c4cc(C(C)(C)C)cc(C(C)(C)C)c4)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1 ; CC(C)(C)c1cc(-c2ccc3c(c2)N(c2ccc(C(C)(C)C)cc2-c2ccccc2)c2cc(C(C)(C)C)cc4c2B3c2ccc(-n3c5ccccc5c5c6c(ccc53)-c3ccccc3C63c5ccccc5-c5ccccc53)cc2N4c2ccc(C(C)(C)C)cc2-c2ccccc2)cc(C(C)(C)C)c1] 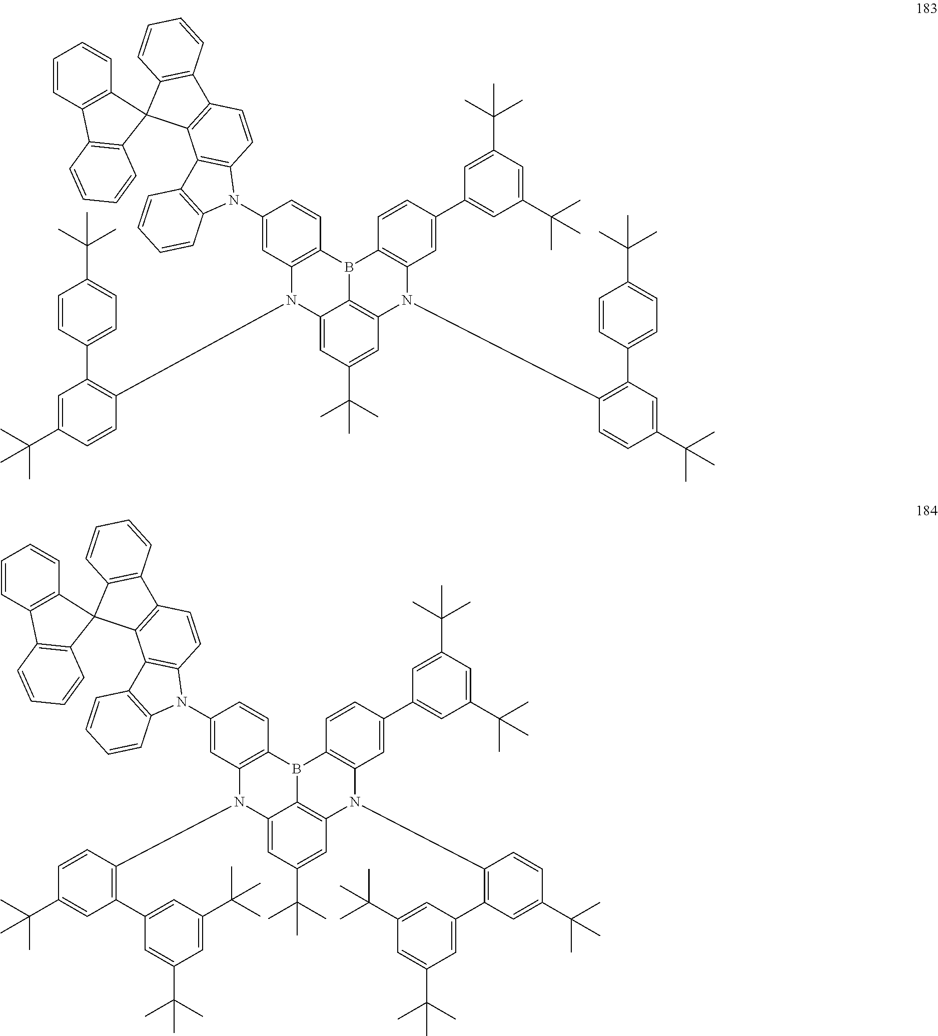 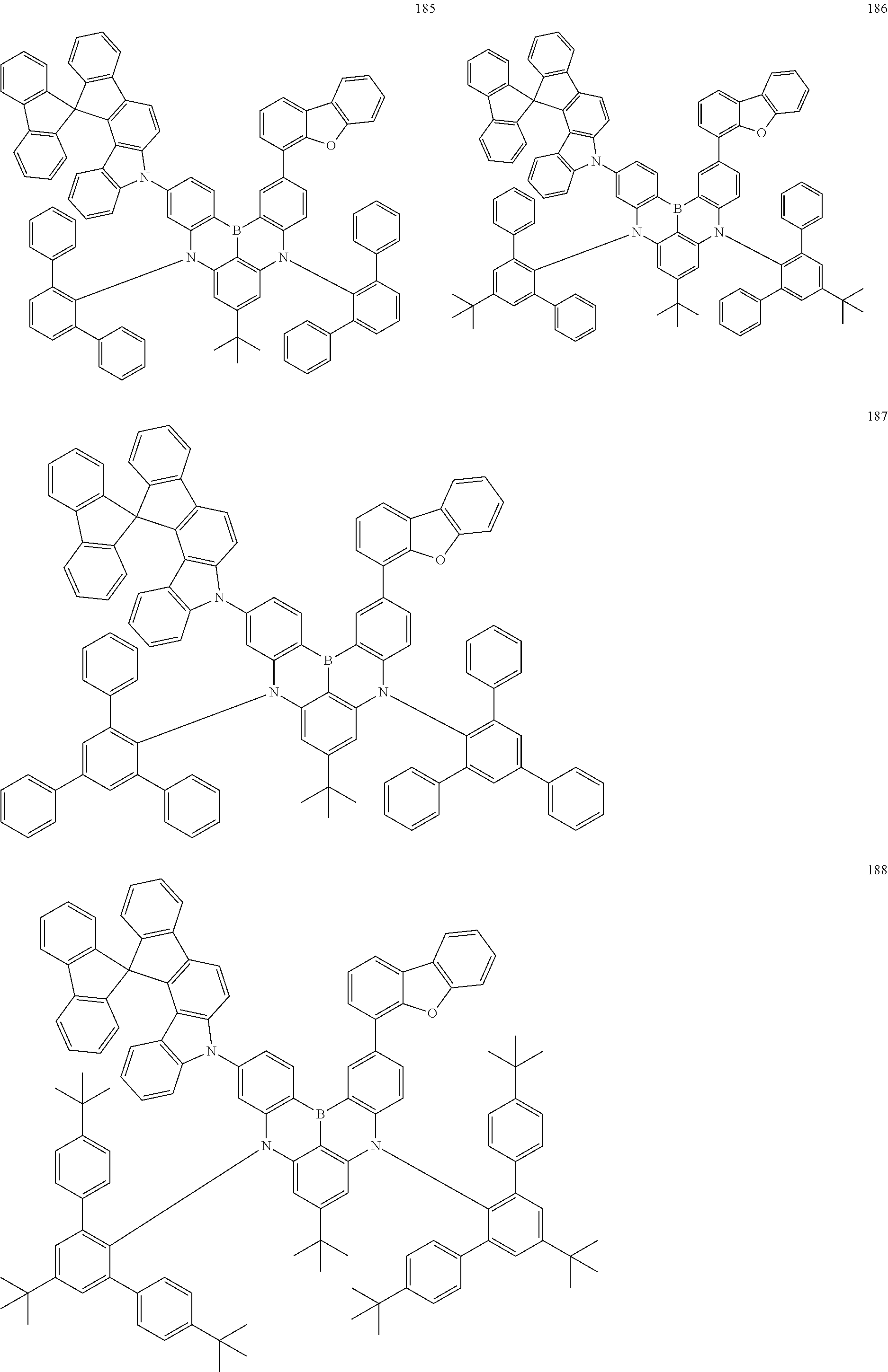 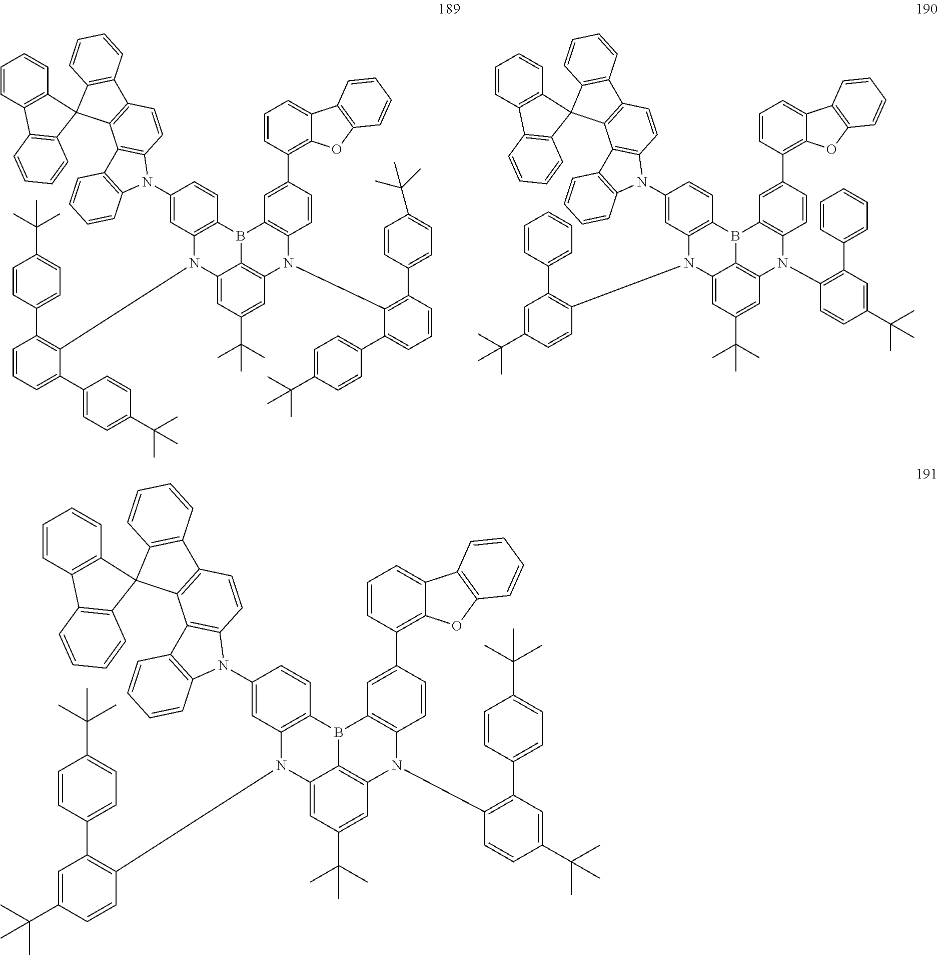 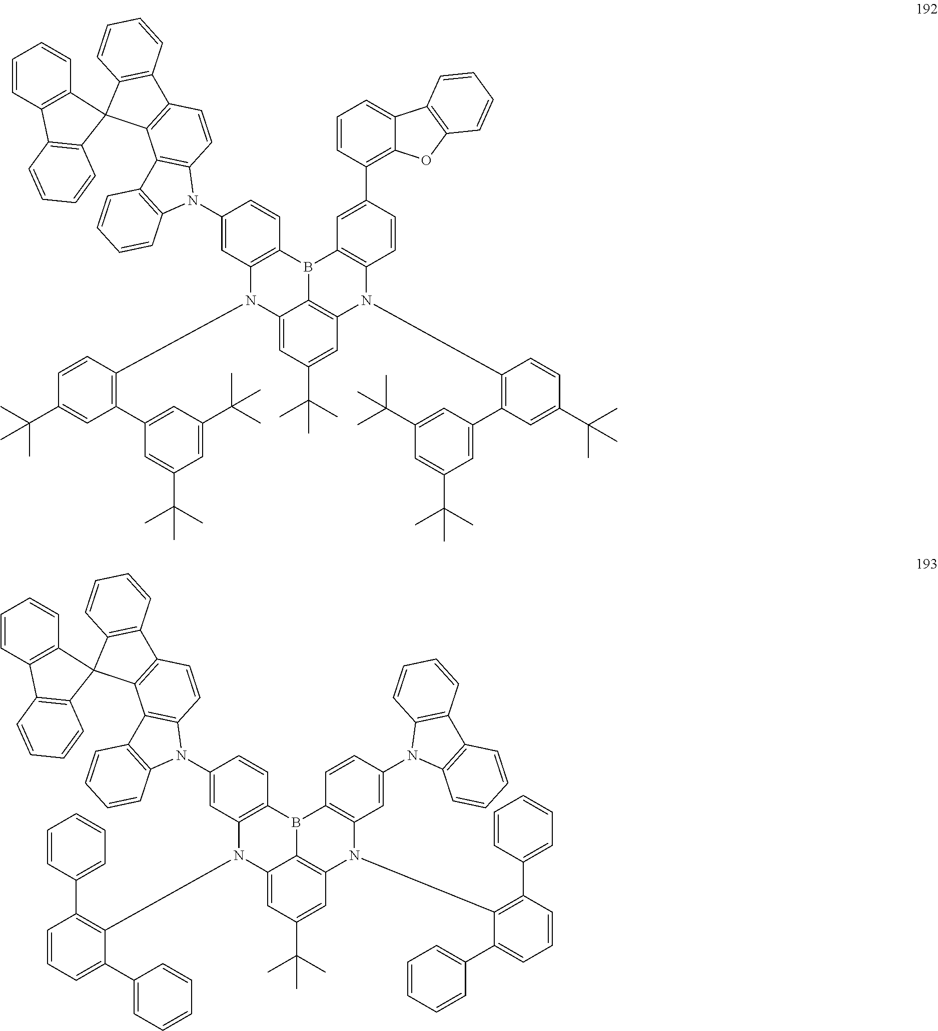 [SMILES: CC(C)(C)c1cc(-c2cc(C(C)(C)C)ccc2N2c3ccc(-c4cccc5c4oc4ccccc45)cc3B3c4ccc(-n5c6ccccc6c6c7c(ccc65)-c5ccccc5C75c6ccccc6-c6ccccc65)cc4N(c4ccc(C(C)(C)C)cc4-c4cc(C(C)(C)C)cc(C(C)(C)C)c4)c4cc(C(C)(C)C)cc2c43)cc(C(C)(C)C)c1 ; CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccccc4c4ccccc43)cc1N2c1c(-c2ccccc2)cccc1-c1ccccc1] 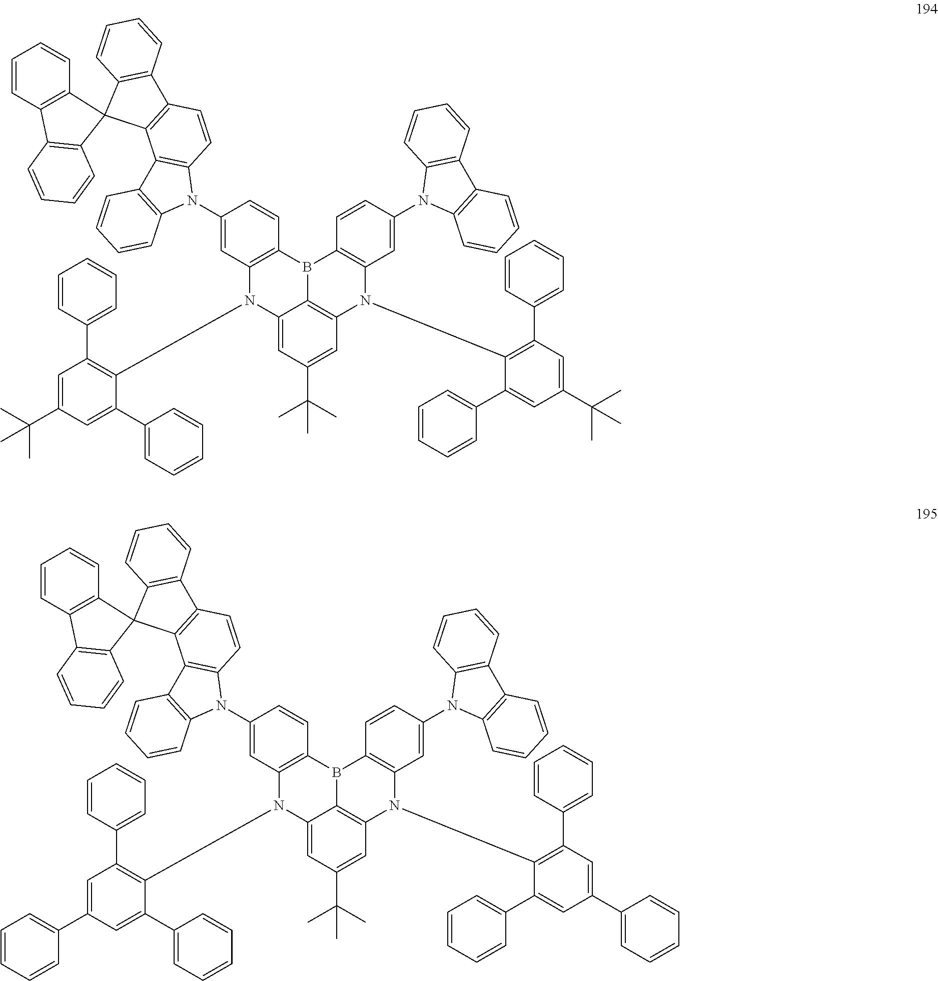 [SMILES: CC(C)(C)c1cc(-c2ccccc2)c(N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1ccc(-n3c4ccccc4c4ccccc43)cc1N2c1c(-c2ccccc2)cc(-c2ccccc2)cc1-c1ccccc1] 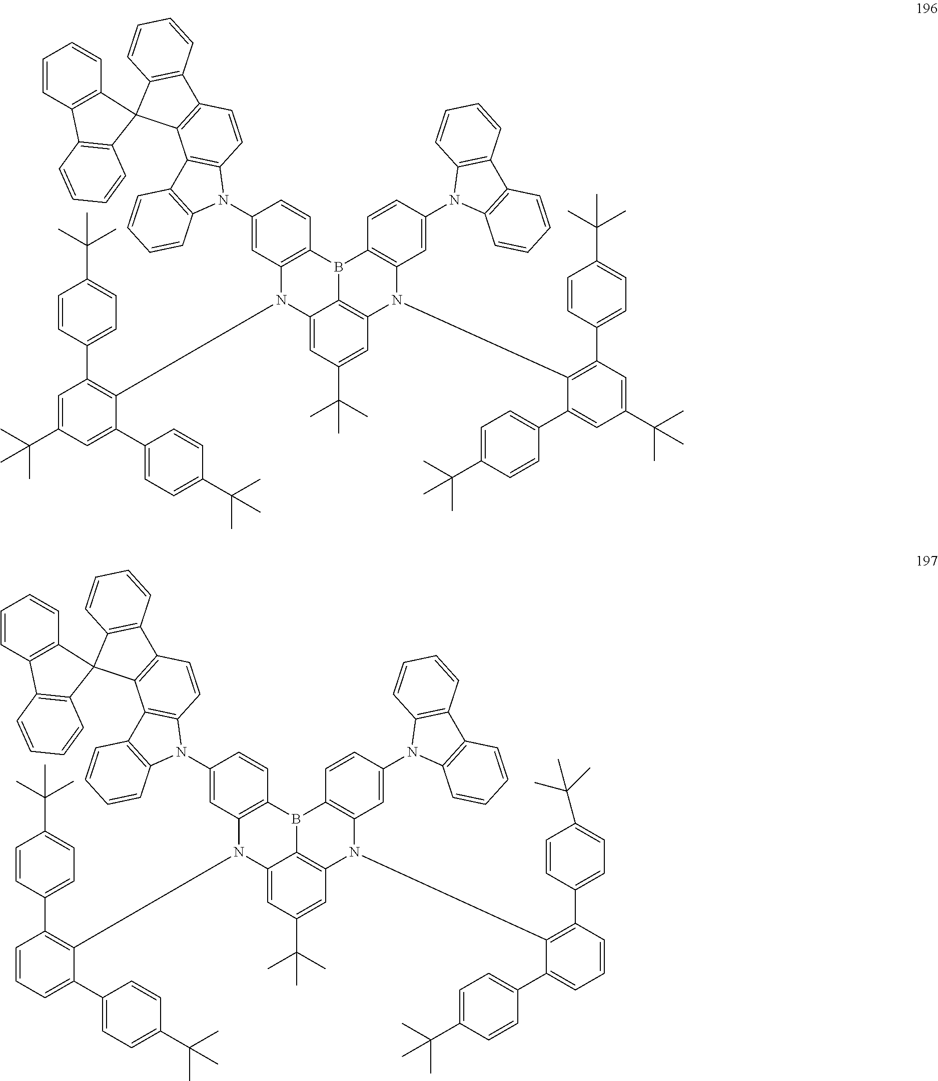 [SMILES: CC(C)(C)c1ccc(-c2cc(C(C)(C)C)cc(-c3ccc(C(C)(C)C)cc3)c2N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1] 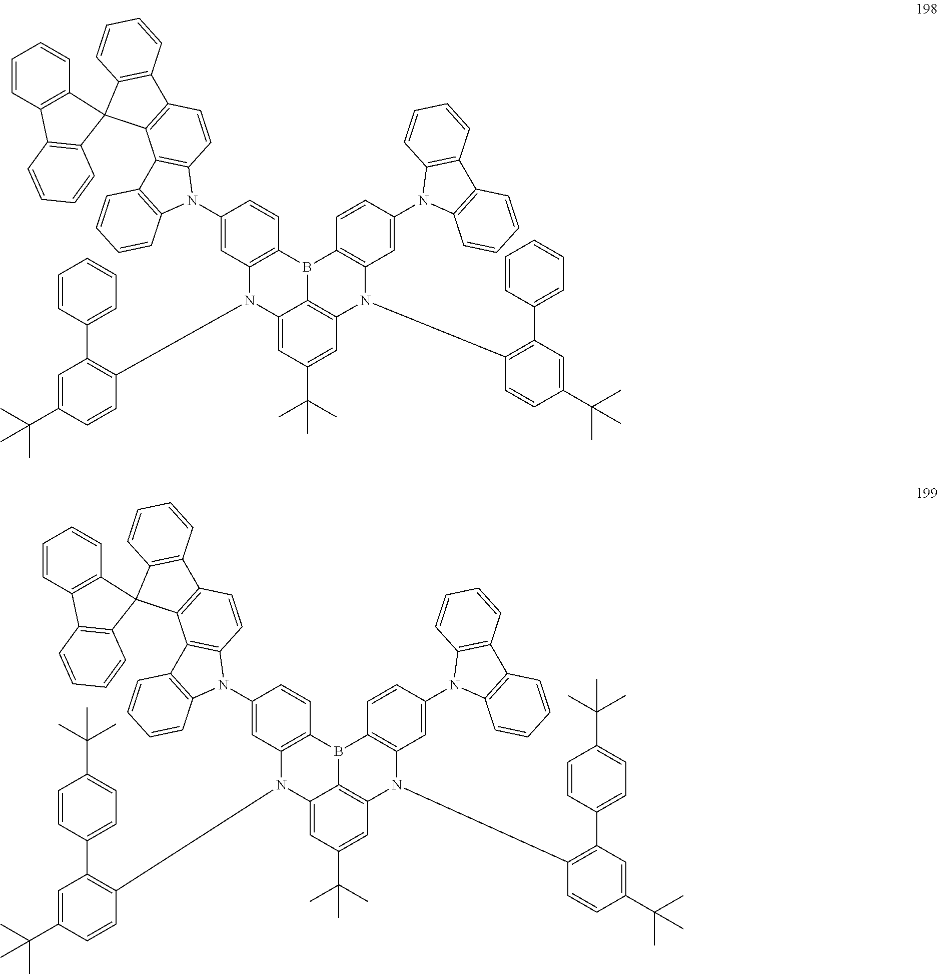 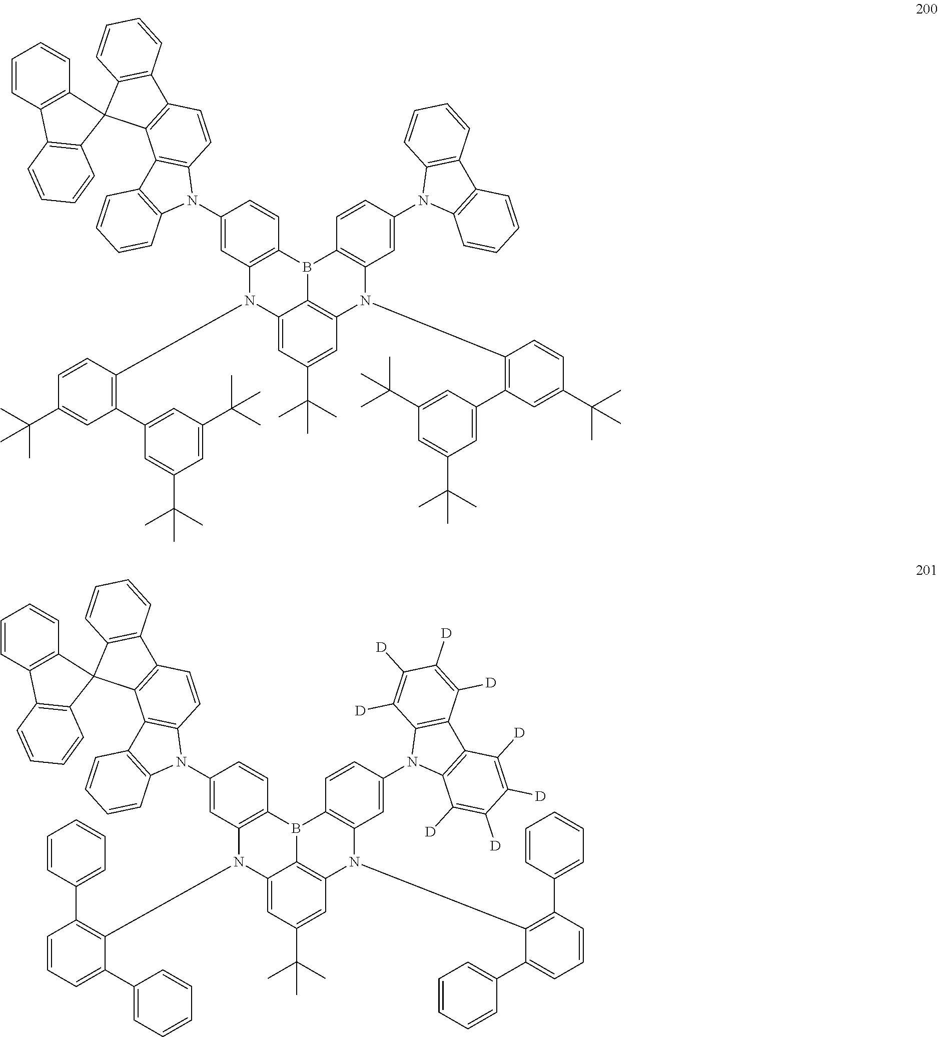 [SMILES: CC(C)(C)c1cc(-c2cc(C(C)(C)C)ccc2N2c3cc(-n4c5ccccc5c5ccccc54)ccc3B3c4ccc(-n5c6ccccc6c6c7c(ccc65)-c5ccccc5C75c6ccccc6-c6ccccc65)cc4N(c4ccc(C(C)(C)C)cc4-c4cc(C(C)(C)C)cc(C(C)(C)C)c4)c4cc(C(C)(C)C)cc2c43)cc(C(C)(C)C)c1 ; [2H]c1c([2H])c([2H])c2c(c1[2H])c1c([2H])c([2H])c([2H])c([2H])c1n2-c1ccc2c(c1)N(c1c(-c3ccccc3)cccc1-c1ccccc1)c1cc(C(C)(C)C)cc3c1B2c1ccc(-n2c4ccccc4c4c5c(ccc42)-c2ccccc2C52c4ccccc4-c4ccccc42)cc1N3c1c(-c2ccccc2)cccc1-c1ccccc1] 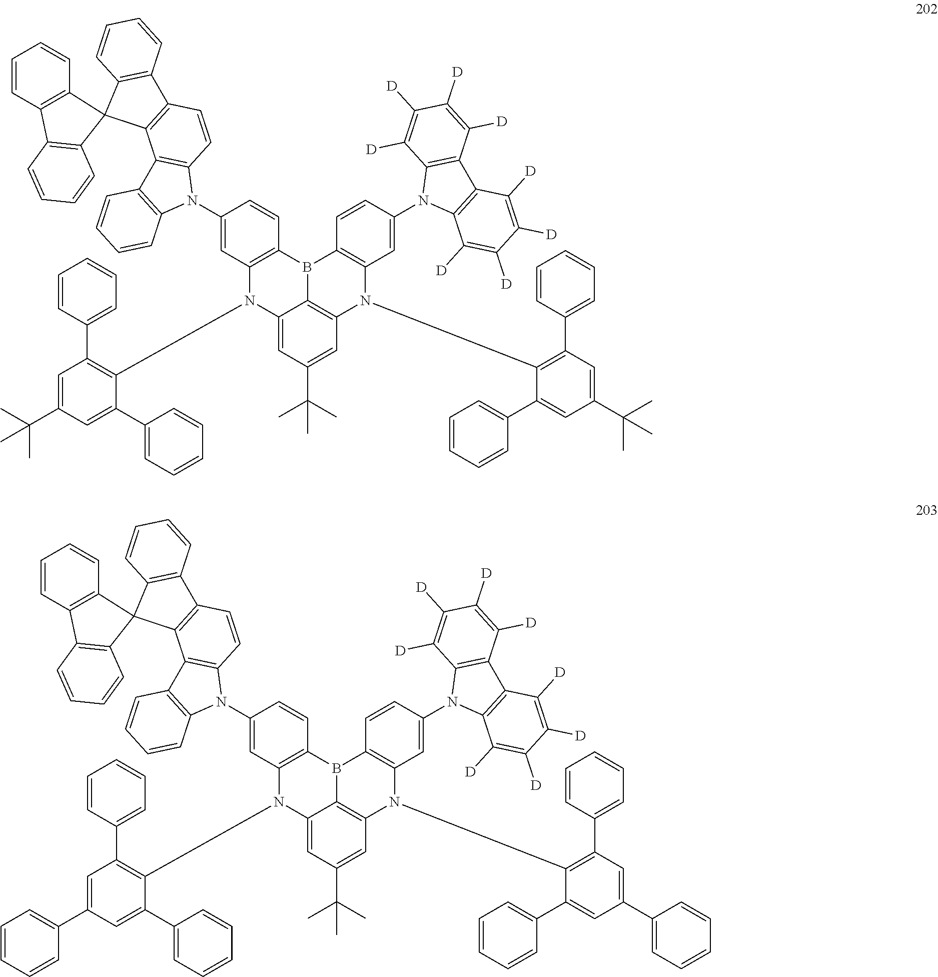 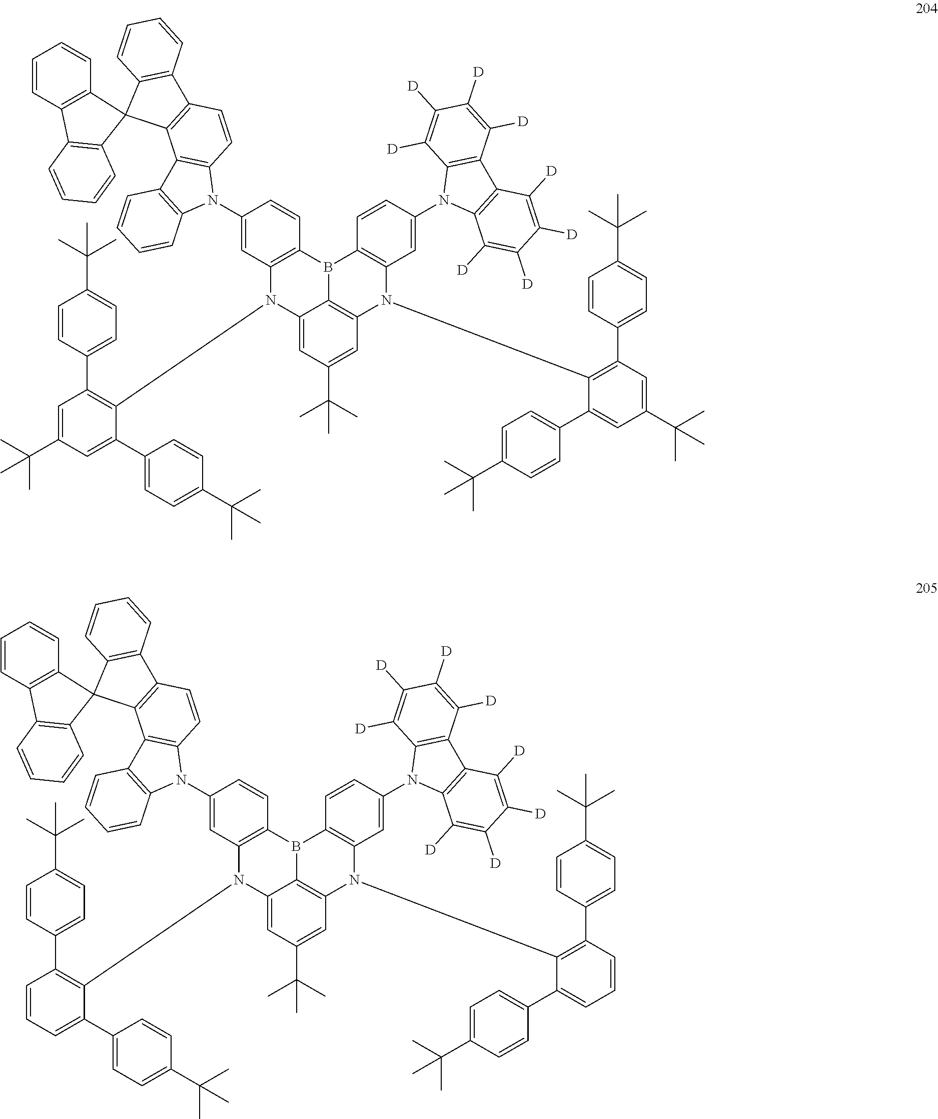 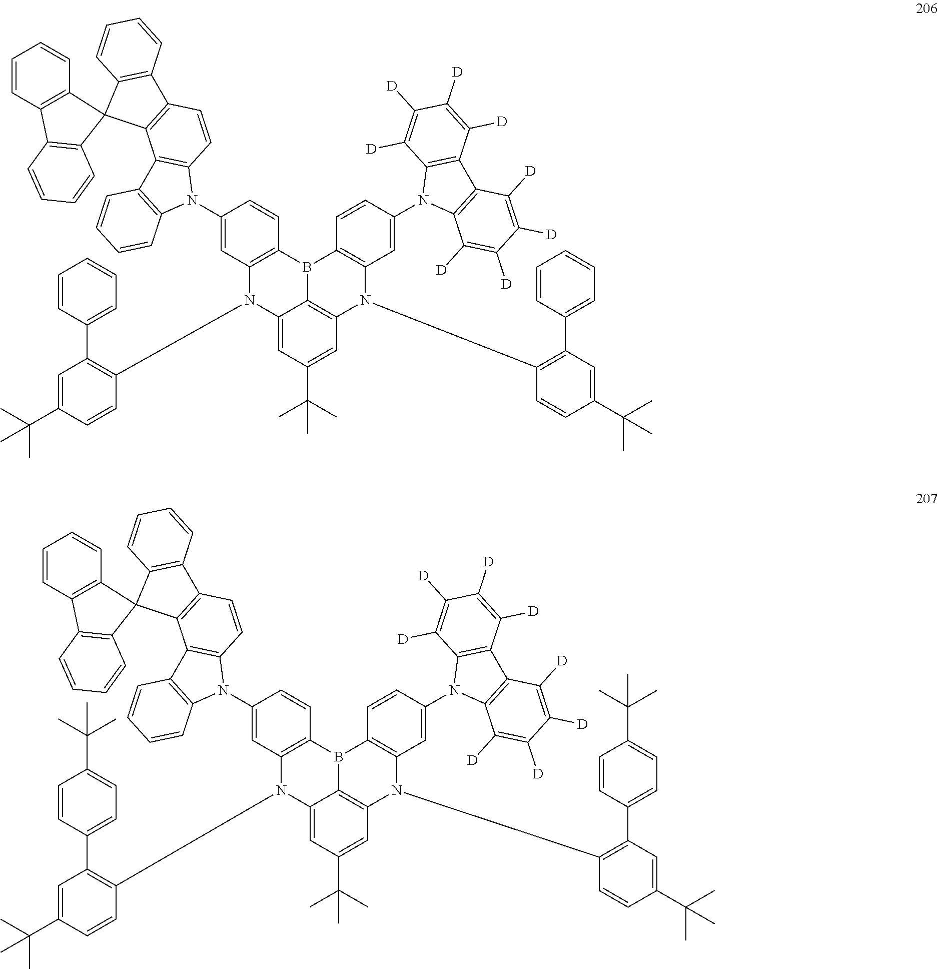 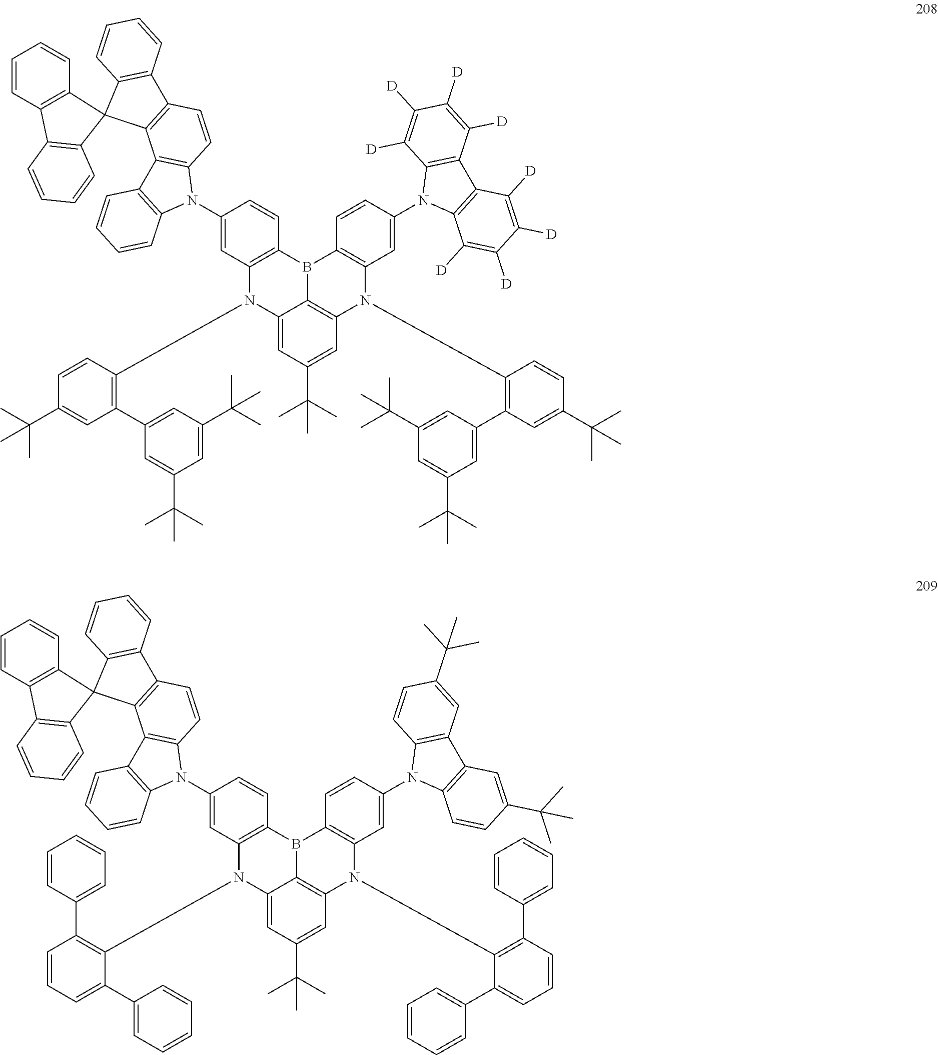 [SMILES: [2H]c1c([2H])c([2H])c2c(c1[2H])c1c([2H])c([2H])c([2H])c([2H])c1n2-c1ccc2c(c1)N(c1ccc(C(C)(C)C)cc1-c1cc(C(C)(C)C)cc(C(C)(C)C)c1)c1cc(C(C)(C)C)cc3c1B2c1ccc(-n2c4ccccc4c4c5c(ccc42)-c2ccccc2C52c4ccccc4-c4ccccc42)cc1N3c1ccc(C(C)(C)C)cc1-c1cc(C(C)(C)C)cc(C(C)(C)C)c1 ; CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccc(C(C)(C)C)cc4c4cc(C(C)(C)C)ccc43)cc1N2c1c(-c2ccccc2)cccc1-c1ccccc1] 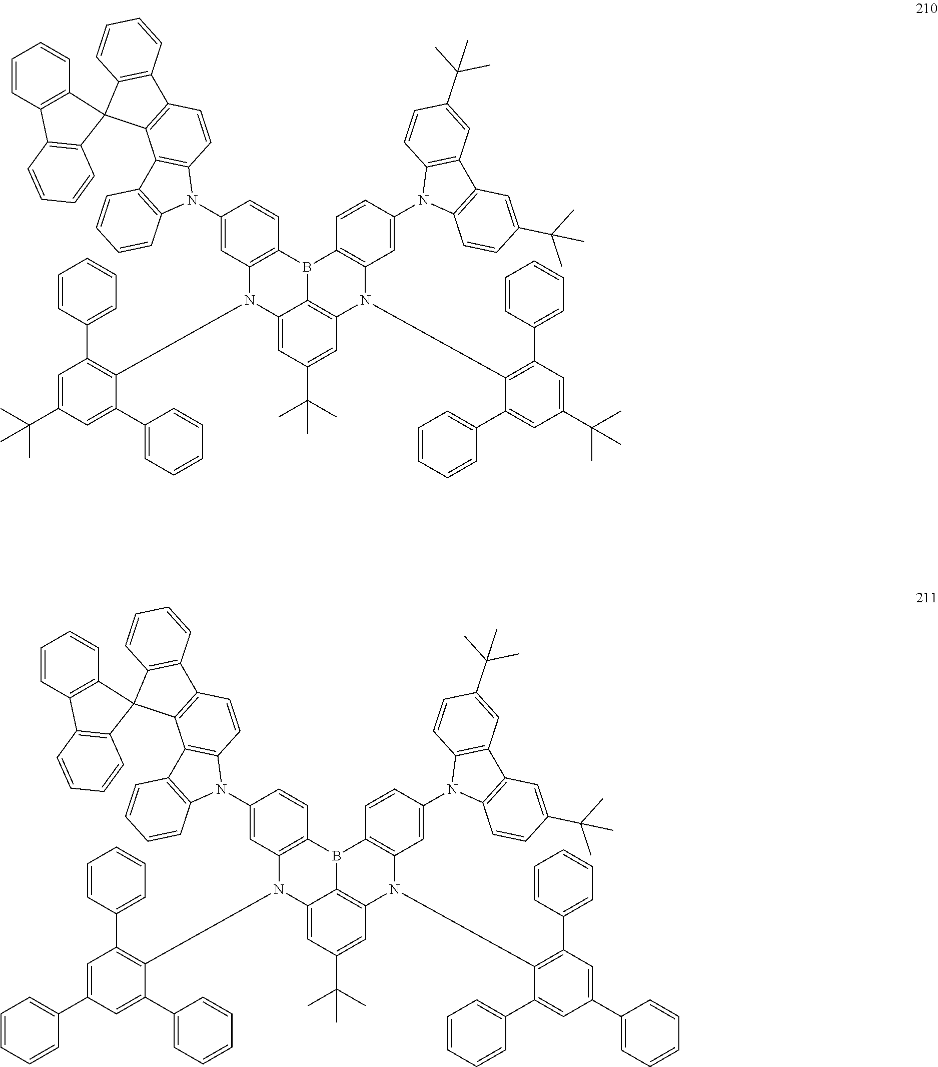 [SMILES: CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1 ; CC(C)(C)c1cc2c3c(c1)N(c1c(-c4ccccc4)cc(-c4ccccc4)cc1-c1ccccc1)c1cc(-n4c5ccccc5c5c6c(ccc54)-c4ccccc4C64c5ccccc5-c5ccccc54)ccc1B3c1ccc(-n3c4ccc(C(C)(C)C)cc4c4cc(C(C)(C)C)ccc43)cc1N2c1c(-c2ccccc2)cc(-c2ccccc2)cc1-c1ccccc1] 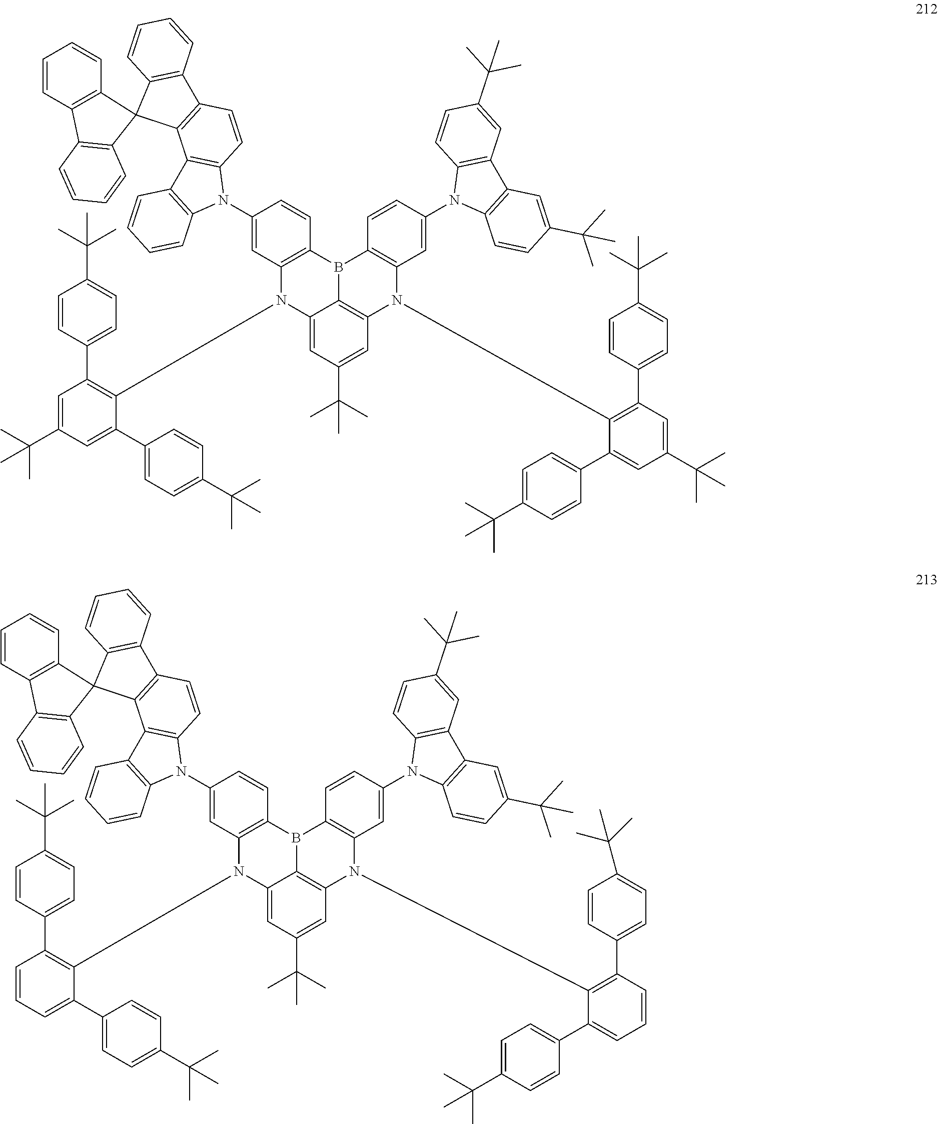 [SMILES: CC(C)(C)c1ccc(-c2cc(C(C)(C)C)cc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cc(C(C)(C)C)cc4-c4ccc(C(C)(C)C)cc4)c4cc(C(C)(C)C)cc2c43)cc1 ; CC(C)(C)c1ccc(-c2cccc(-c3ccc(C(C)(C)C)cc3)c2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4c(-c5ccc(C(C)(C)C)cc5)cccc4-c4ccc(C(C)(C)C)cc4)c4cc(C(C)(C)C)cc2c43)cc1] 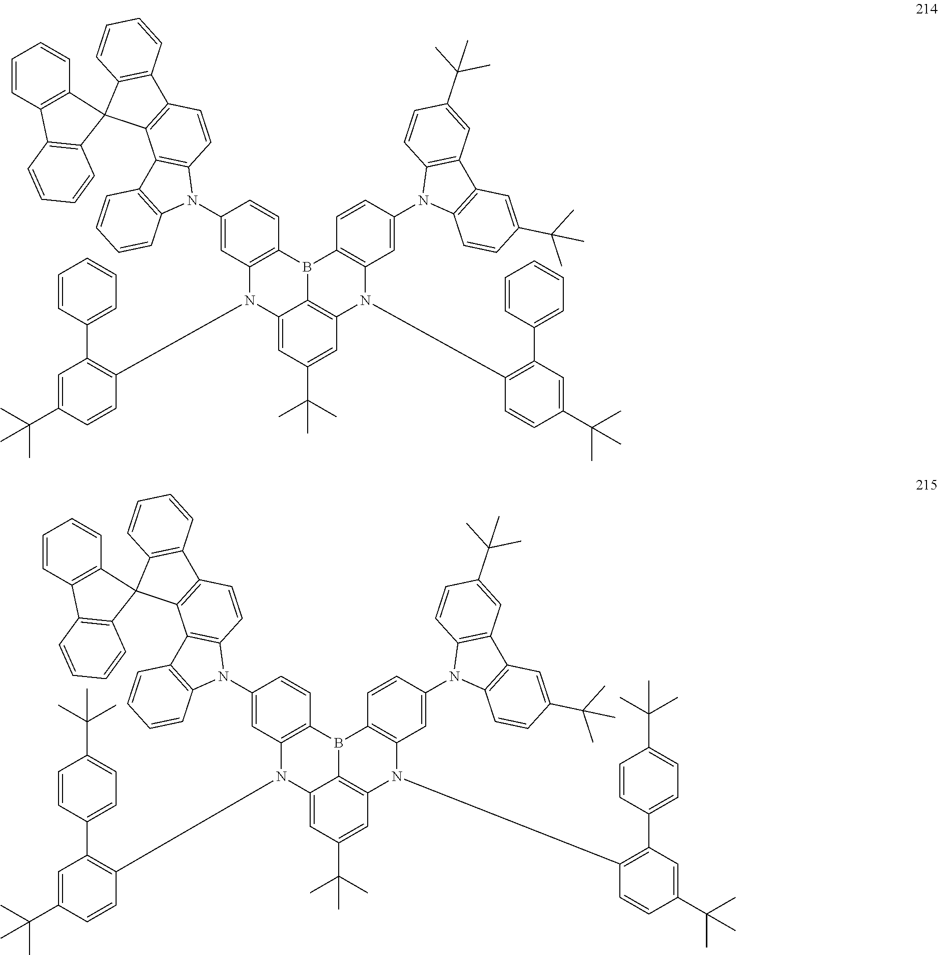 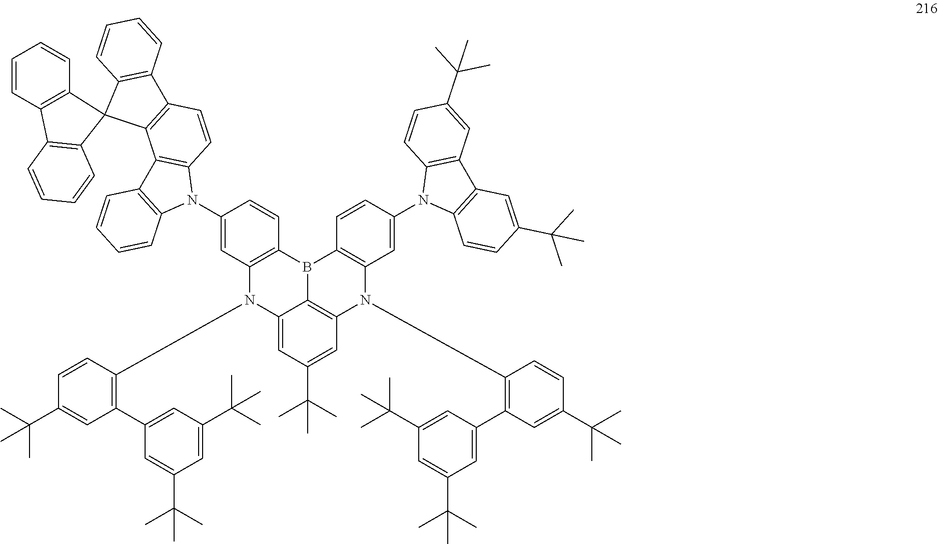 [SMILES: CC(C)(C)c1cc(-c2cc(C(C)(C)C)ccc2N2c3cc(-n4c5ccc(C(C)(C)C)cc5c5cc(C(C)(C)C)ccc54)ccc3B3c4ccc(-n5c6ccccc6c6c7c(ccc65)-c5ccccc5C75c6ccccc6-c6ccccc65)cc4N(c4ccc(C(C)(C)C)cc4-c4cc(C(C)(C)C)cc(C(C)(C)C)c4)c4cc(C(C)(C)C)cc2c43)cc(C(C)(C)C)c1] 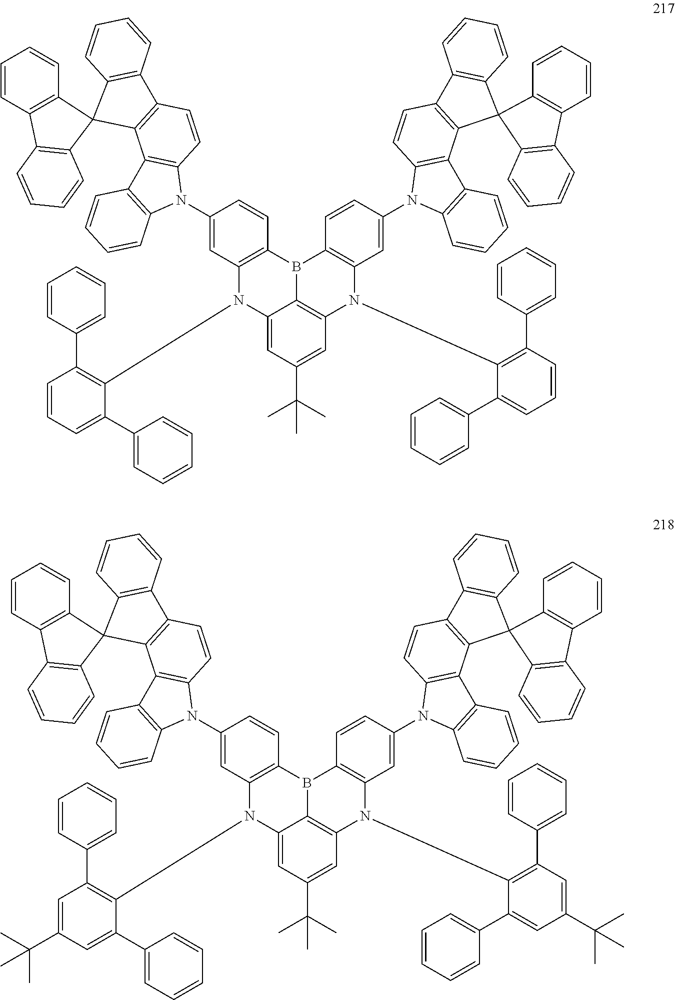 [SMILES: CC(C)(C)c1cc2c3c(c1)N(c1c(-c4ccccc4)cccc1-c1ccccc1)c1cc(-n4c5ccccc5c5c6c(ccc54)-c4ccccc4C64c5ccccc5-c5ccccc54)ccc1B3c1ccc(-n3c4ccccc4c4c5c(ccc43)-c3ccccc3C53c4ccccc4-c4ccccc43)cc1N2c1c(-c2ccccc2)cccc1-c1ccccc1 ; CC(C)(C)c1cc(-c2ccccc2)c(N2c3cc(-n4c5ccccc5c5c6c(ccc54)-c4ccccc4C64c5ccccc5-c5ccccc54)ccc3B3c4ccc(-n5c6ccccc6c6c7c(ccc65)-c5ccccc5C75c6ccccc6-c6ccccc65)cc4N(c4c(-c5ccccc5)cc(C(C)(C)C)cc4-c4ccccc4)c4cc(C(C)(C)C)cc2c43)c(-c2ccccc2)c1] 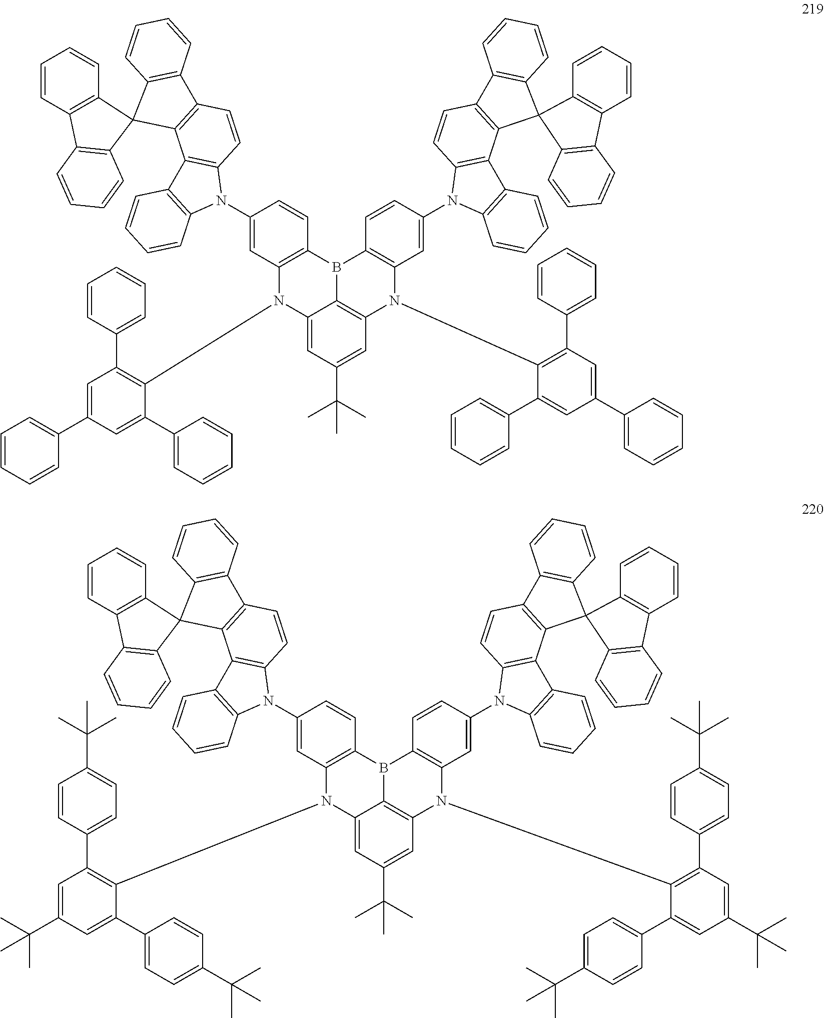 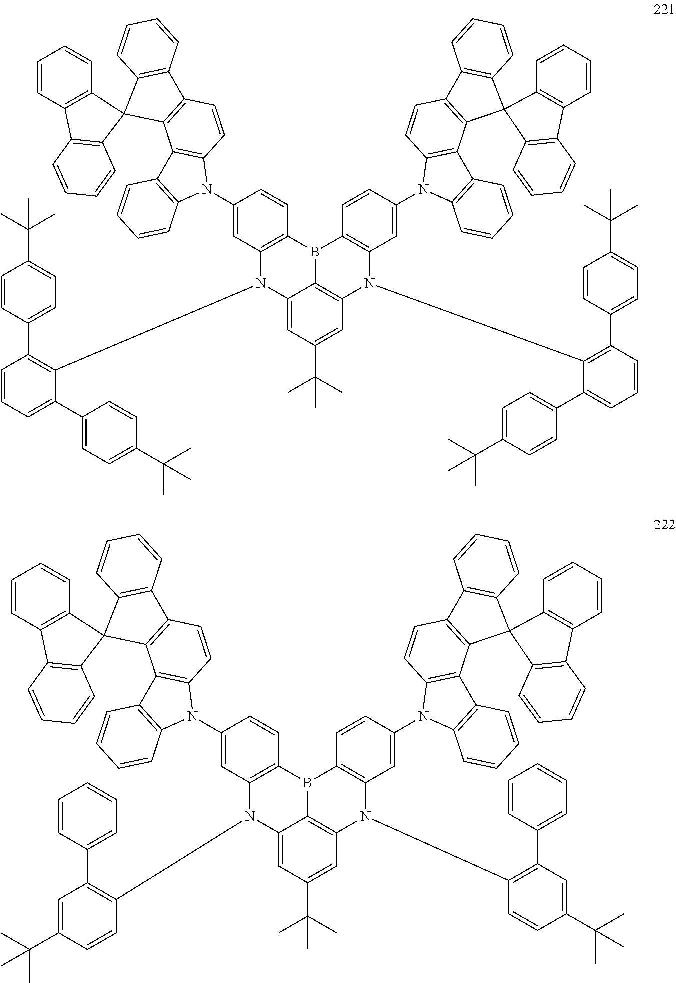 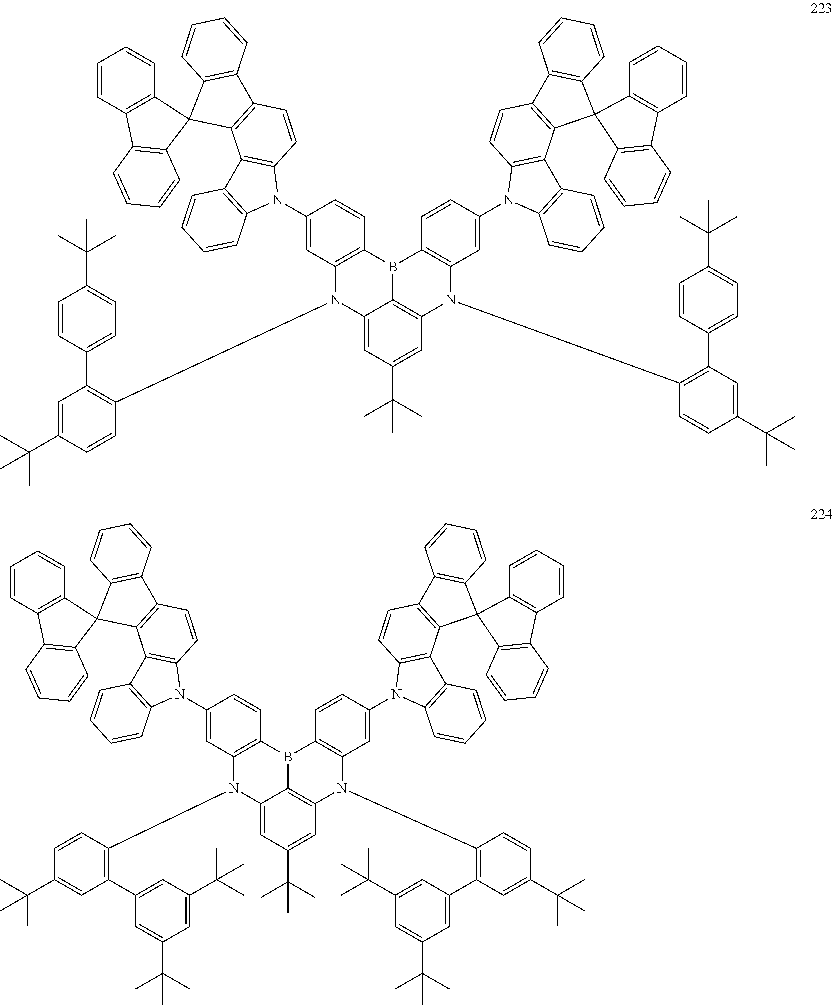
wherein in Compound Group 1 above,
D represents a deuterium atom.

20. A display device comprising:
a circuit layer disposed on a base layer; and
a display element layer disposed on the circuit layer, wherein
the display element layer comprises a light emitting element,
the light emitting element comprises
a first electrode;
a second electrode disposed on the first electrode; and
an emission layer disposed between the first electrode and the second electrode, the emission layer comprises a fused polycyclic compound represented by Formula 1: 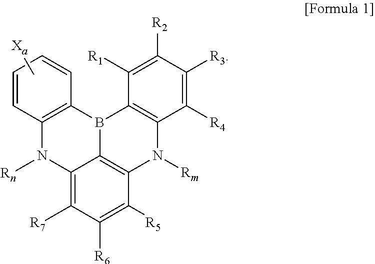
wherein in Formula 1,
R₁ to R₇ are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms,
Xₐ is a group represented by Formula 2, and
Rₙ and Rₘ are each independently a group represented by Formula 3; 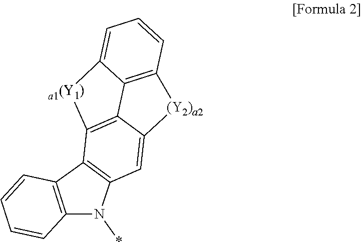
wherein in Formula 2,
one of a1 and a2 is 1,
the other of a1 and a2 is 0,
Y₁ and Y₂ are each independently C(Rₐ)(R_{b}),
Rₐ and R_{b} are each independently a substituted or unsubstituted aryl group having 6 to 20 ring-forming carbon atoms, or are bonded to each other to form a ring, and
-* represents a binding site to a neighboring atom; and 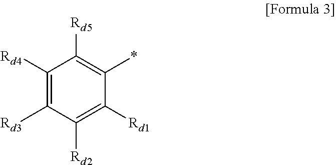
wherein in Formula 3,
R_{d1} to R_{d5} are each independently a hydrogen atom, a deuterium atom, a cyano group, a halogen atom, a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms, and
-* represents a binding site to a neighboring atom.

21. The display device of claim 20, wherein
the light emitting element comprises:
a first light emitting element that emits red light;
a second light emitting element that emits green light; and
a third light emitting element that emits blue light; and
the third light emitting element includes the fused polycyclic compound.

22. The display device of claim 20, further comprising:
a light control layer, wherein
the light control layer is disposed on the display element layer, and
the light control layer comprises quantum dots.
